(19) United States
(12) Patent Application Publication
(10) Pub. No.: US 2019/0326523 A1
(43) Pub. Date: Oct. 24, 2019

(54) TETRADENTATE CYCLIC-METAL PALLADIUM COMPLEX COMPRISING 4-ARYL-3,5-DISUBSTITUTED PYRAZOL, PREPARATION AND USE THEREOF

(71) Applicants: Zhejiang University of Technology, Hangzhou (CN); AAC Microtech (Changzhou) Co., Ltd., Changzhou (CN)

(72) Inventors: Guijie Li, Shenzhen (CN); Yuanbin She, Shenzhen (CN); Xiangdong Zhao, Shenzhen (CN); Shaohai Chen, Shenzhen (CN)

(21) Appl. No.: 16/112,882

(22) Filed: Aug. 27, 2018

(30) Foreign Application Priority Data
Apr. 23, 2018 (CN) 201810368397.8

(51) Int. Cl. H01L 51/00; C07F 15/00; C09K 11/06

(52) U.S. Cl. CPC H01L 51/0084; C07F 15/006; C09K 11/06; H01L 51/5016; C09K 2211/1029; C09K 2211/1044; C09K 2211/185

(57) ABSTRACT

The present disclosure relates to the field of blue phosphorescent tetradentate cyclic-metal palladium complex luminescent materials, and discloses a blue phosphorescent tetradentate cyclic-metal palladium complex based on 4-aryl-3,5-disubstituted pyrazol, preparation and use thereof. The complex may be a delayed fluorescent and/or phosphorescent emitter. The complex has characteristics of high thermal decomposition temperature, high luminous intensity, and deep blue light emission and a narrow emission spectrum, therefore there are a huge application prospects in the field of blue light, especially in deep blue phosphorescent materials.

### CROSS-REFERENCE TO RELATED APPLICATIONS

This application claims the priority benefit of Chinese Patent Applications Ser. No. 201810368397.8 filed on Apr. 23, 2018, the entire content of which is incorporated herein by reference.

### FIELD OF THE PRESENT DISCLOSURE

The present disclosure relates to the field of blue phosphorescent tetradentate cyclic-metal palladium complex luminescent materials, especially to a blue phosphorescent tetradentate cyclic-metal palladium complex based on 4-aryl-3,5-disubstituted pyrazol.

### DESCRIPTION OF RELATED ART

Compound capable of light absorbing and/or emitting may be ideally suited for a variety of optical and electroluminescent device, for example, including a light absorbing device such as a solar absorbing device and a photosensitive device, an organic light emitting diode (OLED), a light emitting device, or a device that can be capable of both light-absorbing and light-emitting and can be used as marker for biological applications. Many studies have focused on finding and optimizing organic and organometallic materials for using in optical and electroluminescent devices. Generally, research in this field aims to achieve many goals, including improvement of absorbing and emitting efficiency, and improvement of processing capability.

Despite significant advances in the study of chemical and electro-optic material, for example, red and green phosphorescent organometallic materials have been commercialized and applied to OLEDs, lighting equipment and lighting phosphorescent material in an advanced display, but there are still many shortcomings in the material available, including poor machinability, inefficient emission or absorption, and less desirable stability.

In addition, good blue light emitting materials are very scarce, and a great challenge is that the stability of the blue light devices is poor, and at the same time the choice of the host material has an important influence on the stability and efficiency of the devices. With respect to the red-green phosphorescent material, the lowest triplet energy level of the blue phosphorescent material is higher, which means that the triplet energy level of the host material in the blue light device needs to be higher. Therefore, the limitation of the host material in the blue device is another important issue for its development.

Generally, changes in chemical structure will affect the electronic structure of the compound, which in turn affects the optical properties of the compound (e.g., emission and absorption spectra), thus, which can be adjusted or regulated to the compound of the present disclosure to specific emission or absorption of energy. In some aspects, the optical properties of the compounds disclosed in the present disclosure can be adjusted by changing the structure of the ligand in the metal center. For example, compounds having ligand that bearing electron-donating substituent or electron-withdrawing substituent generally exhibit different optical properties, including different emission and absorption spectra.

Since the phosphorescent multi-dentate palladium metal complexes can be utilized simultaneously electroluminescence excited singlet and triplet excitons, obtained 100% of internal quantum efficiency, so that these complexes can be alternative luminescent material of OLEDs. Generally, the multi-dentate palladium metal complex comprises luminescent groups and secondary groups. If a conjugated group, such as aromatic ring substituent or heteroatom substituent group is introduced to the light emitting portion, the energy level of the highest molecular occupied molecular orbital (HOMO) and the lowest molecular occupied molecular orbital for the luminescent material is changed, simultaneously, further adjusting the energy gap between the HOMO orbital and LOMO orbital, also can adjust the emission spectral property of multi-dentate platinum metal complexes, for example, making it wider or narrower, or making it red shift or blue shift.

### SUMMARY

The object of the present disclosure is to provide a blue phosphorescent tetradentate cyclic-metal palladium complex based on 4-aryl-3,5-disubstituted pyrazol and use thereof.

The tetradentate cyclic-metal platinum complex comprising 4-aryl-3,5-disubstituted pyrazole is provided by some embodiments of the present disclosure, its structure is shown in formula (I):

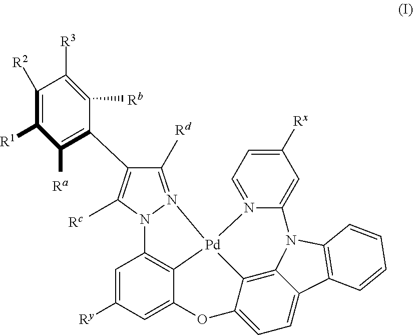

Wherein, R^{a}, R^{b}, R^{c} and R^{d} each are alkyl, alkoxy, cycloalkyl, ether, heterocyclyl, hydroxy, aryl, heteroaryl, aryloxy, mono- or di-alkylamino, mono- or di-arylamino, halogen, sulfydryl, cyano, independently, or combinations thereof;

R^{x} is alkyl, alkoxy, cycloalkyl, heterocyclyl, ether, mono- or di-alkylamino, mono- or di-arylamino, halogen, or combination thereof;

R^{y} is H, deuterium, alkyl, alkoxy, cycloalkyl, heterocyclyl, ether, mono- or di-alkylamino, mono- or di-arylamino, halogen, or combination thereof;

R¹, R², and R³ each are H, deuterium, alkyl, alkoxy, ether, cycloalkyl, heterocyclyl, hydroxy, aryl, heteroaryl, aryloxy, mono- or di-alkylamino, mono- or di-arylamino, halogen, sulfydryl, cyano, haloalkyl, independently, or combinations thereof.

Preferably, the tetradentate cyclic-metal palladium complex comprising 4-aryl-3,5-disubstituted pyrazol provided by some embodiments of the present disclosure,

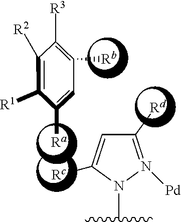

has a structure selected from the following structures:

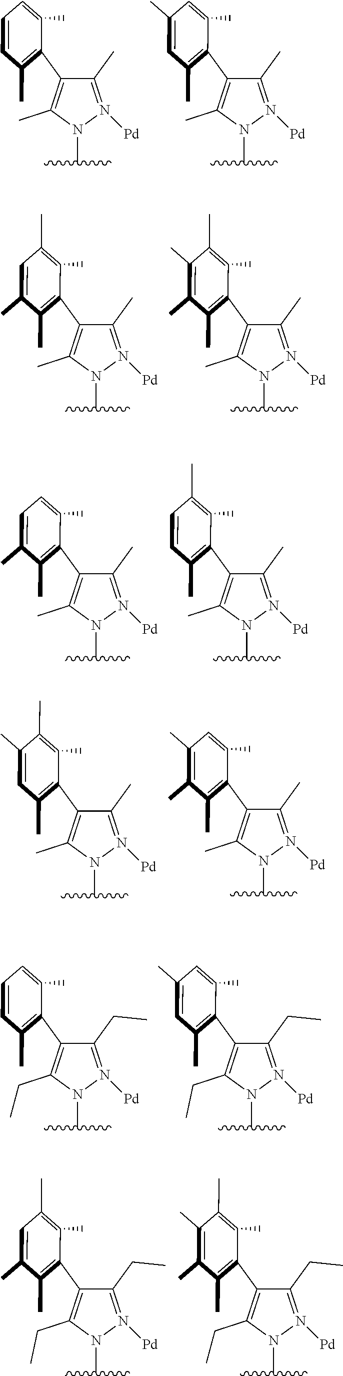

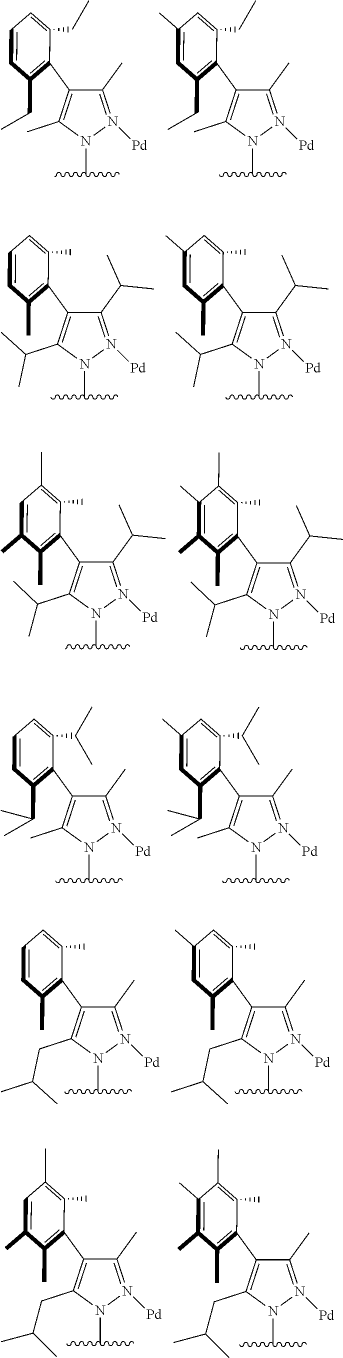

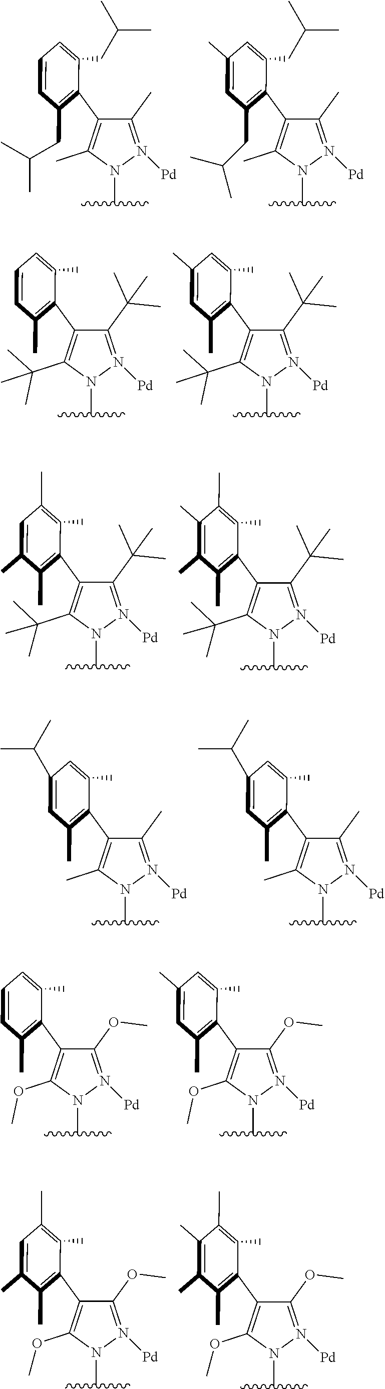

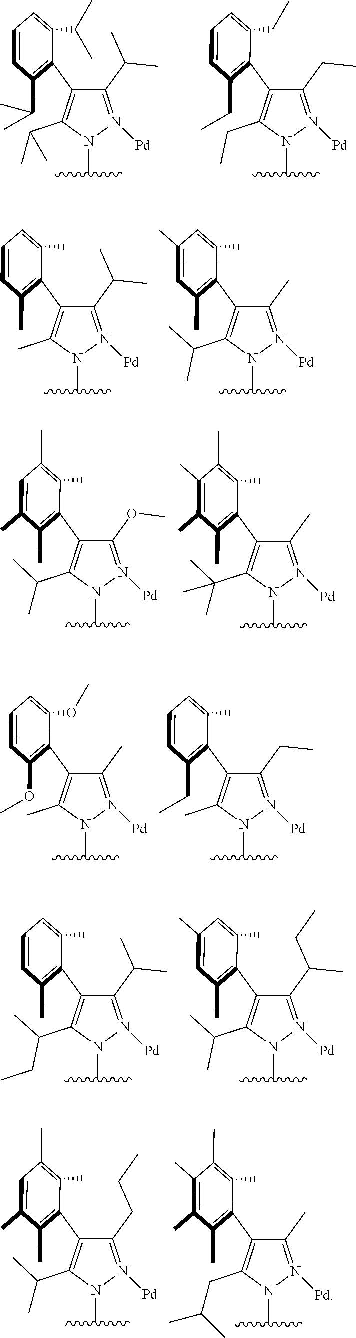

Preferably, the tetradentate cyclic-metal palladium complex comprising 4-aryl-3,5-disubstituted pyrazol provided by some embodiments of the present disclosure has a structure selected from the group consisting of Pd1˜Pd884:

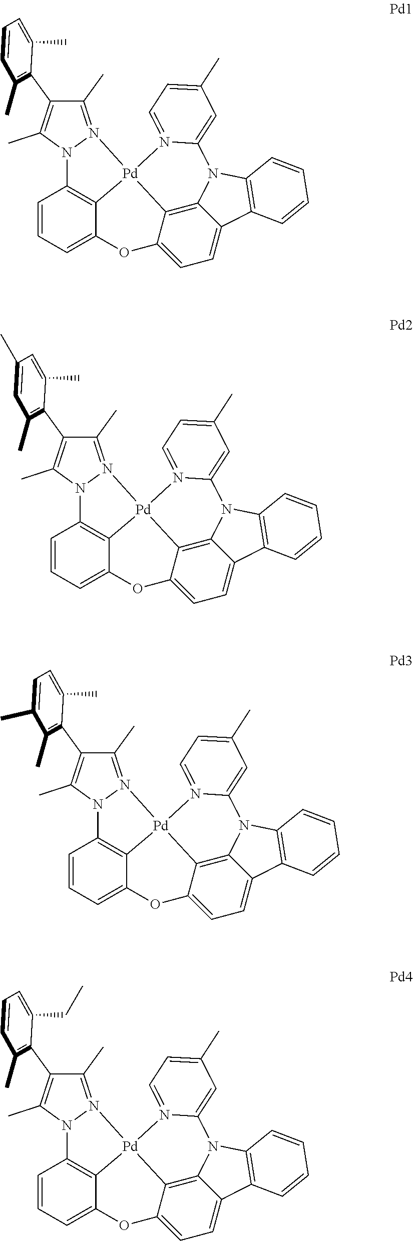

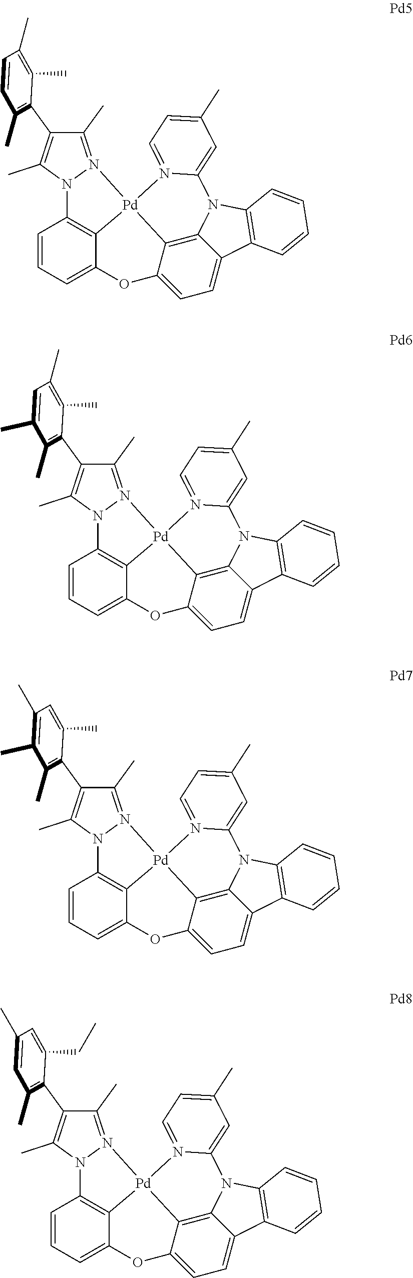

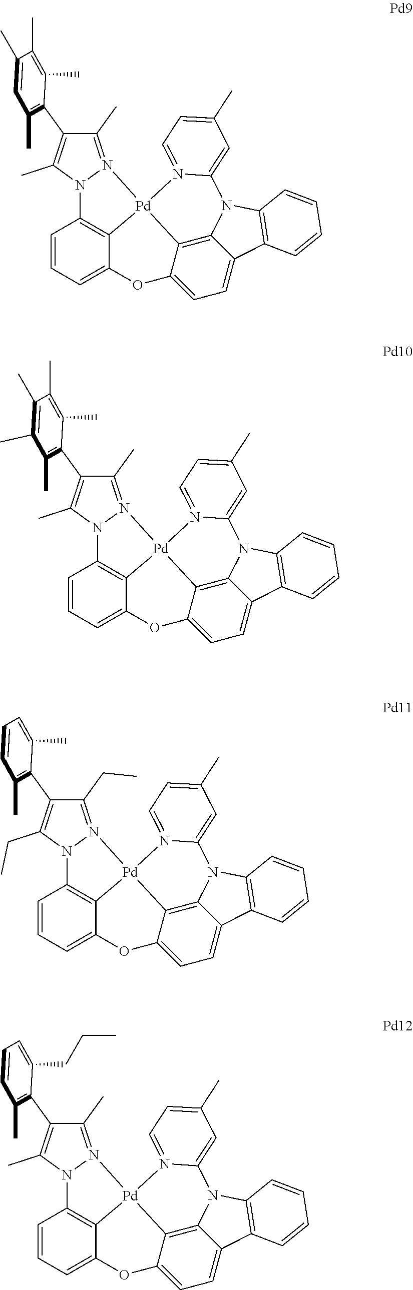

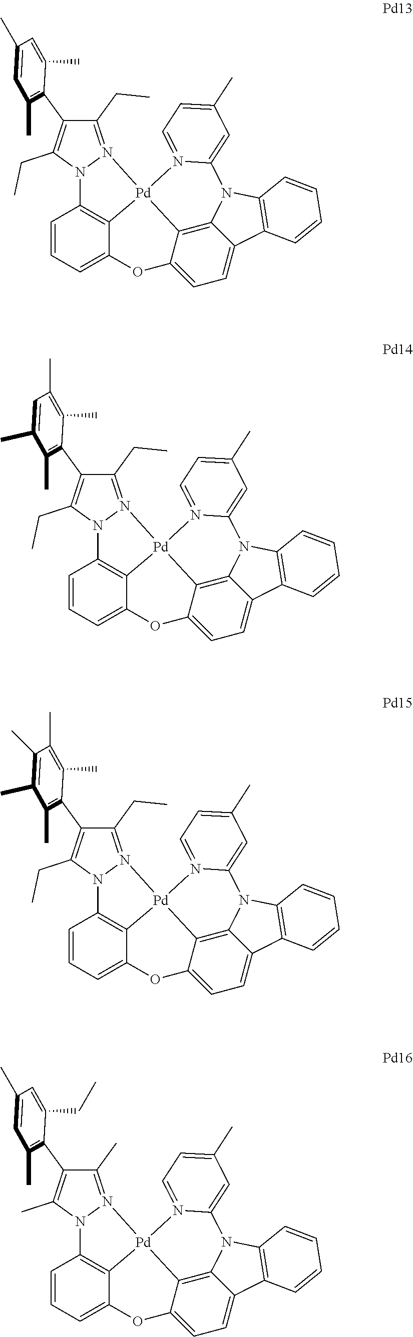

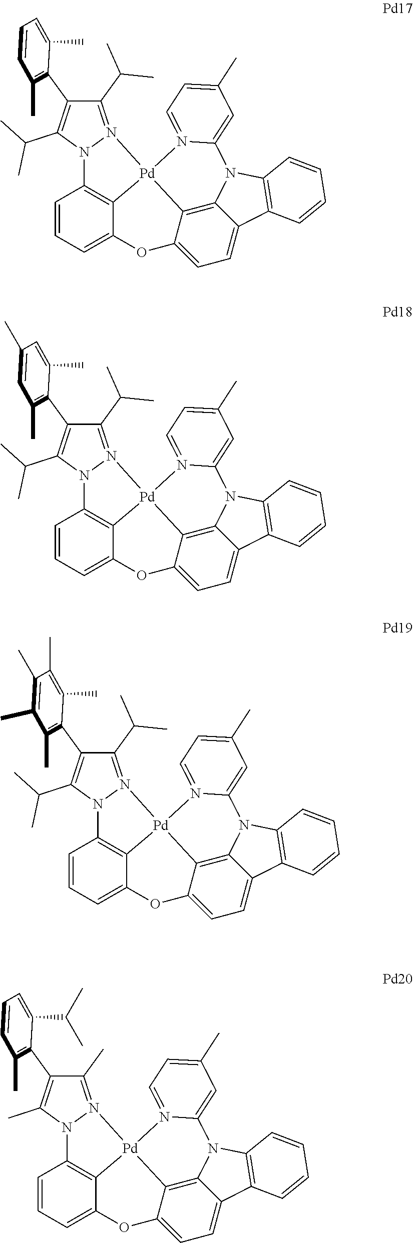

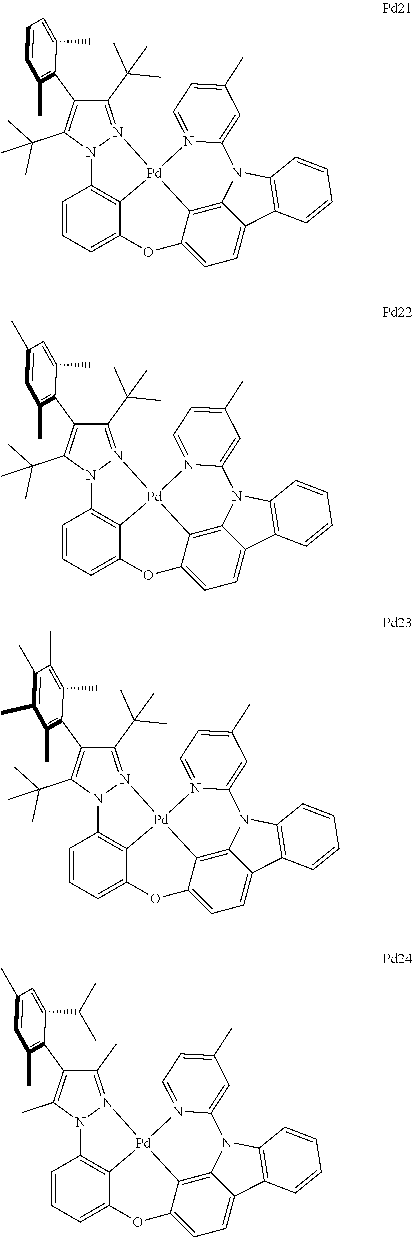

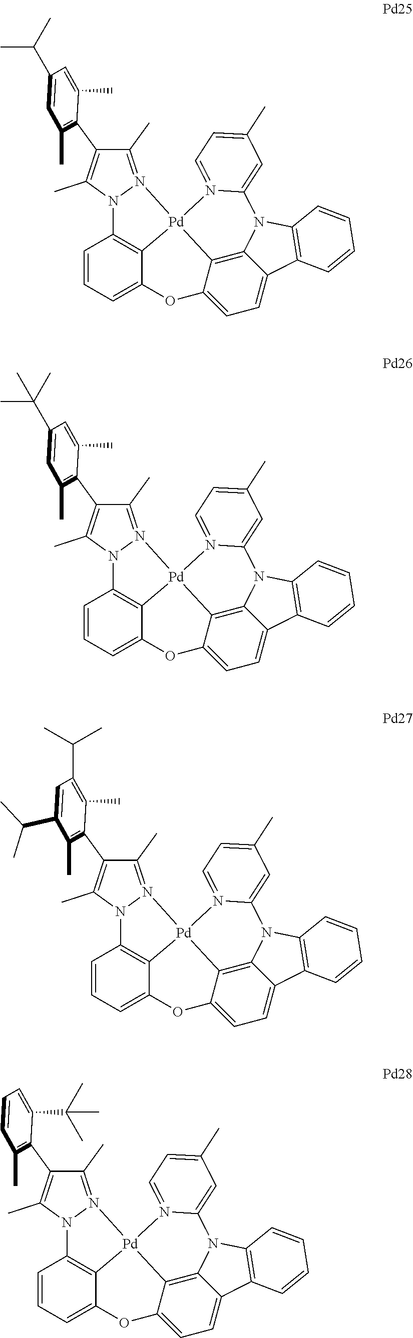

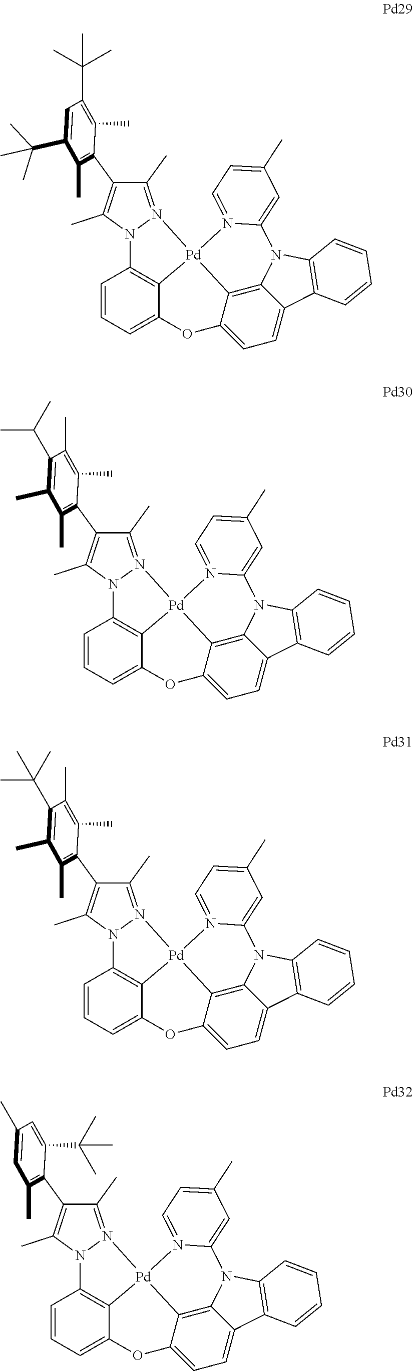

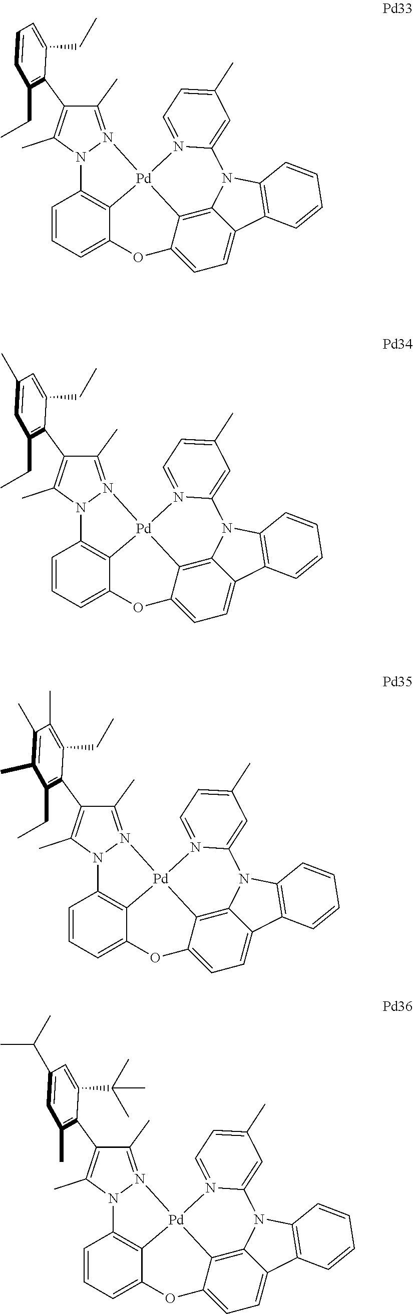

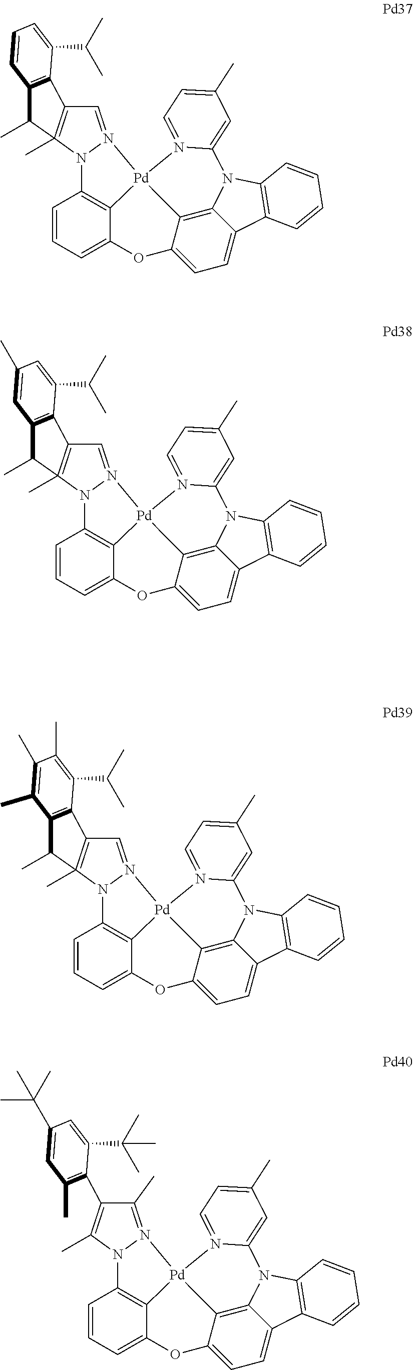

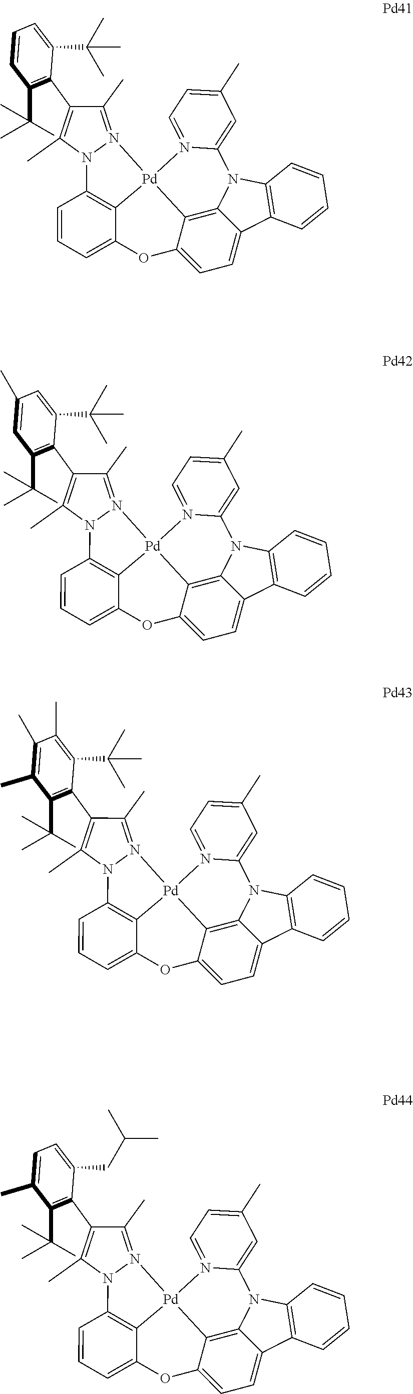

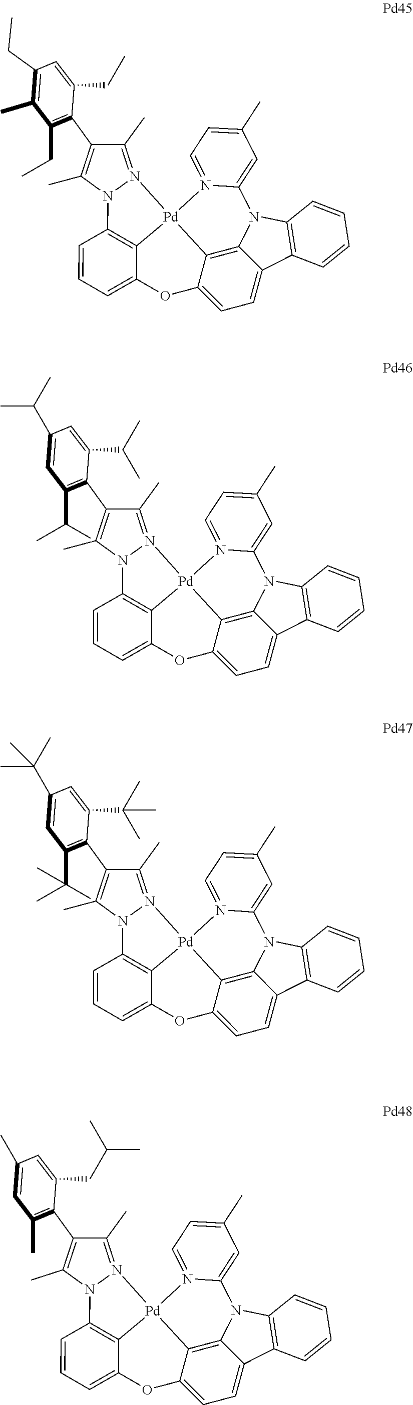

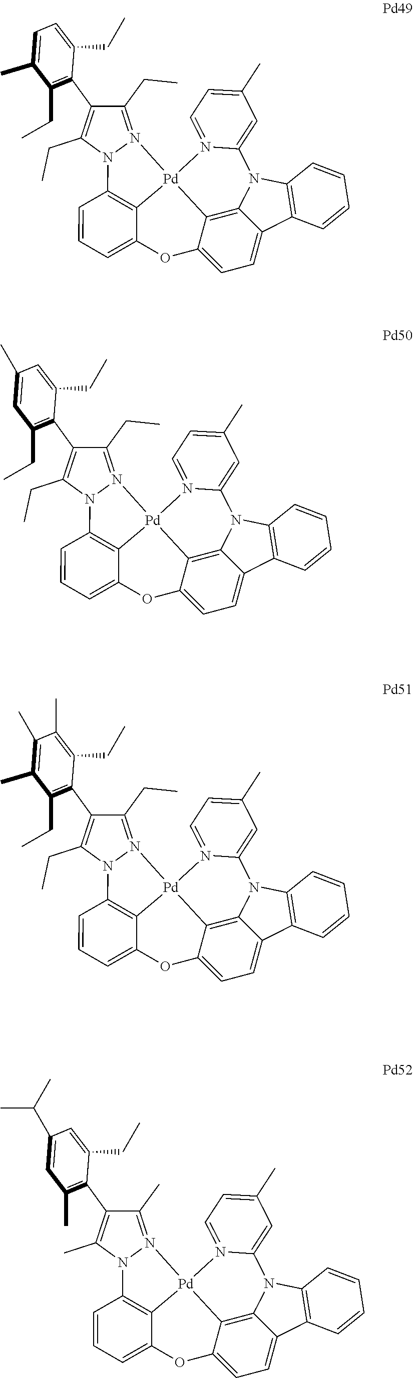

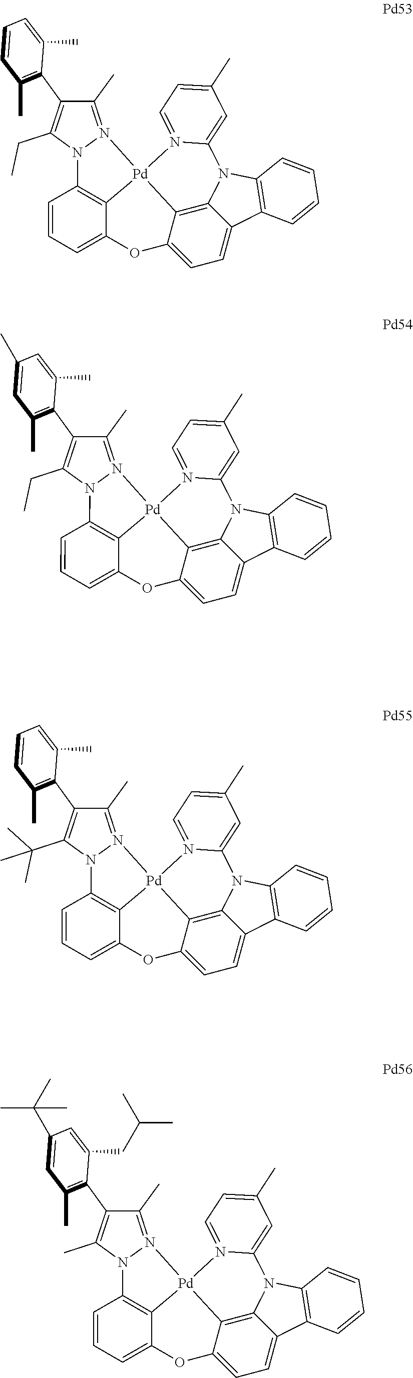

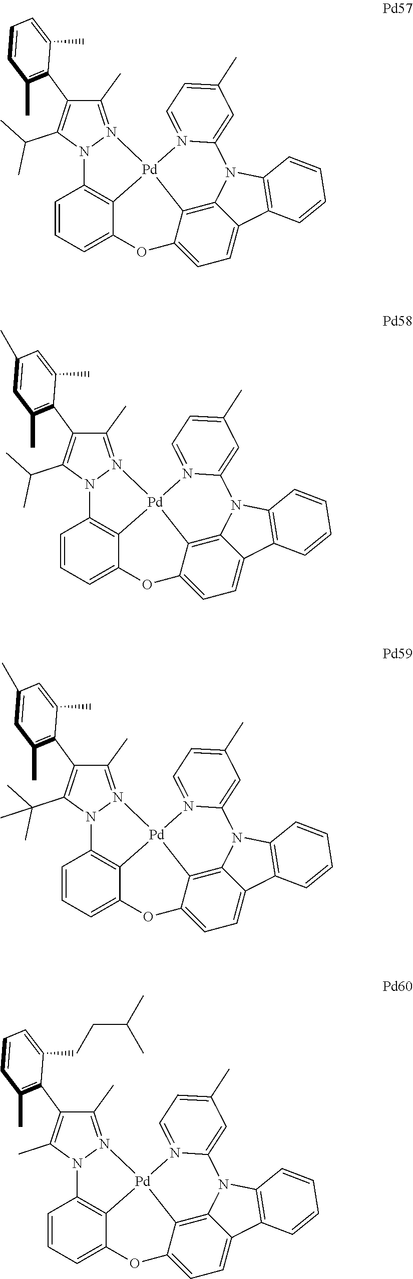

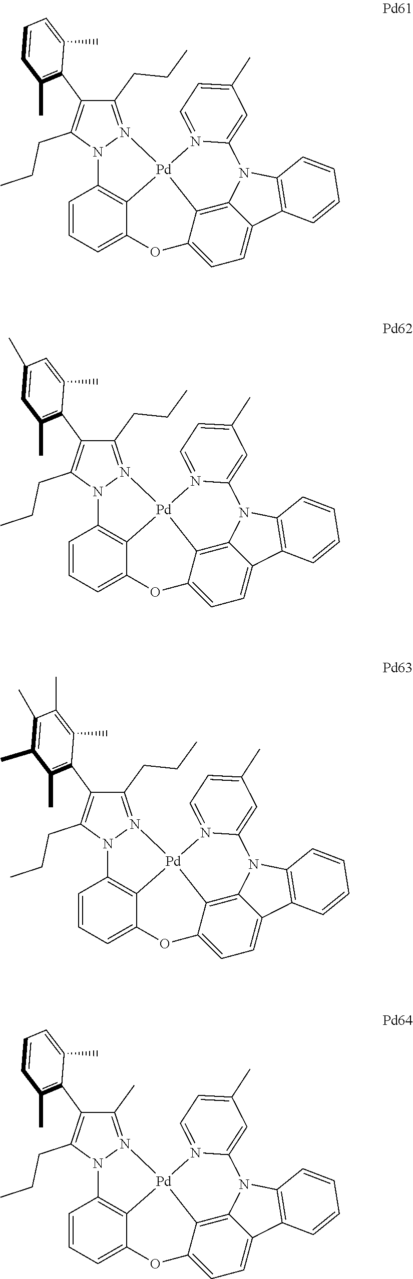

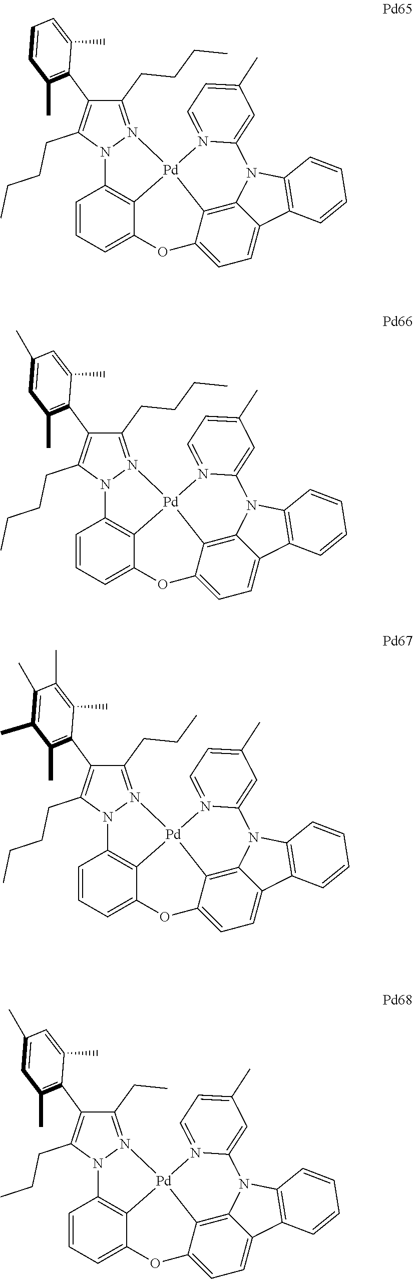

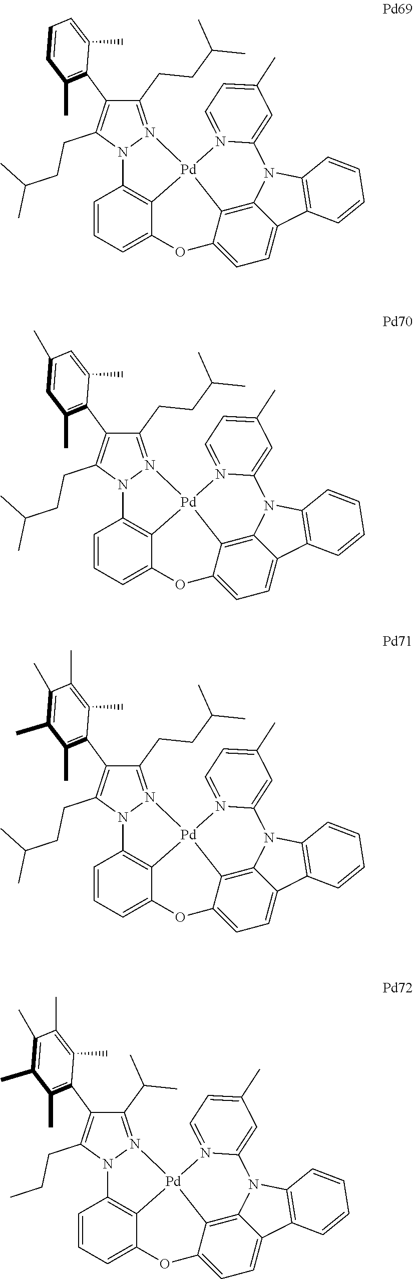

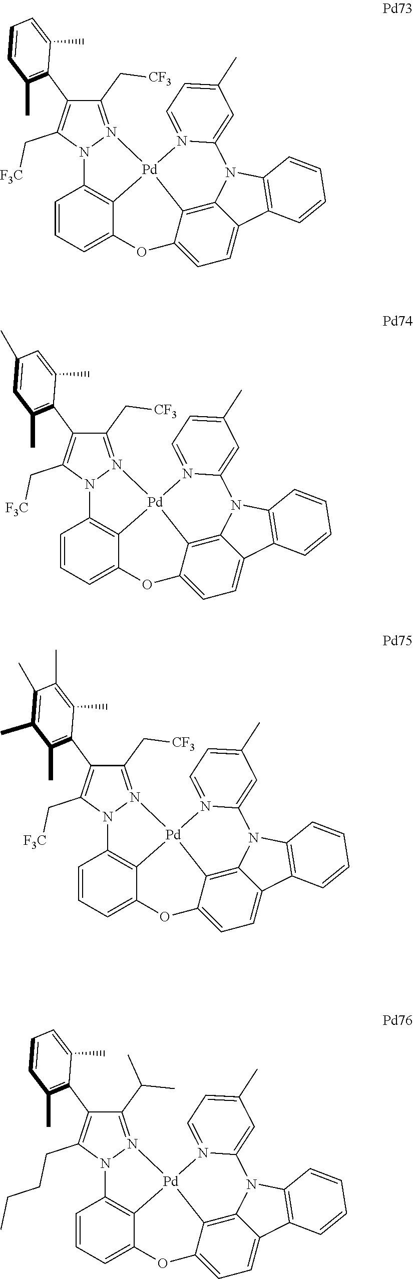

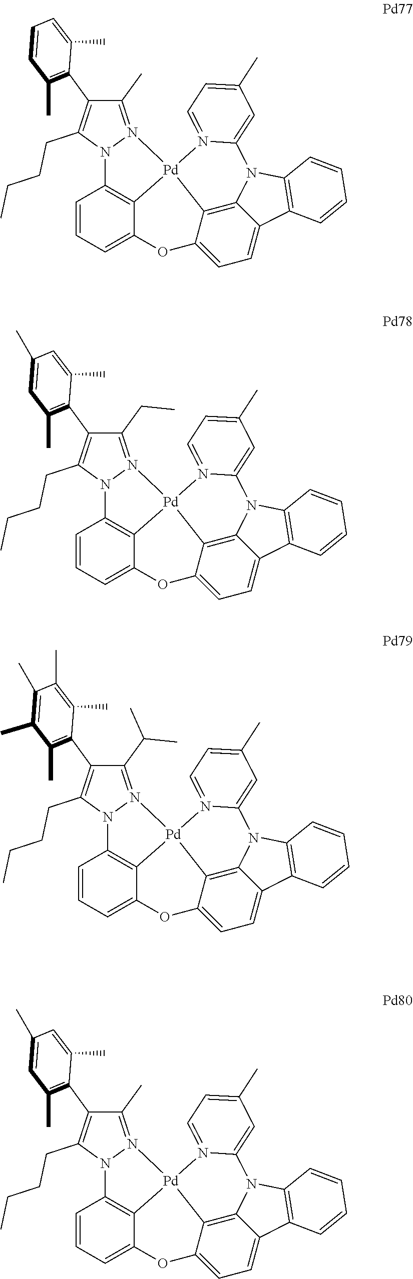

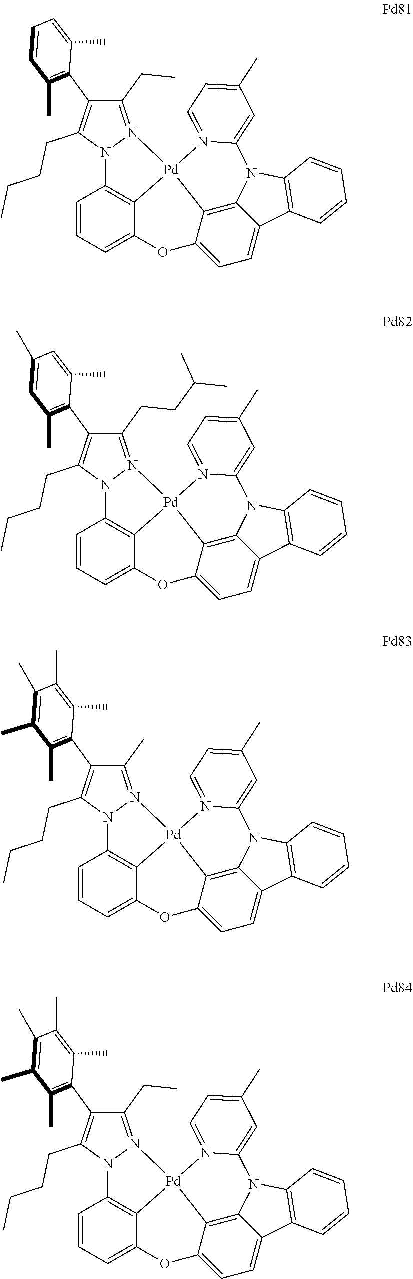

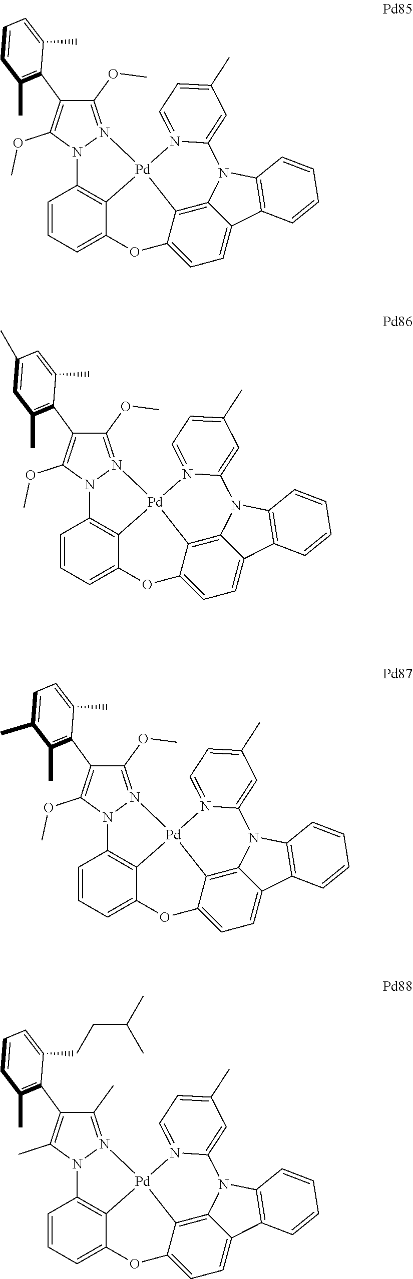

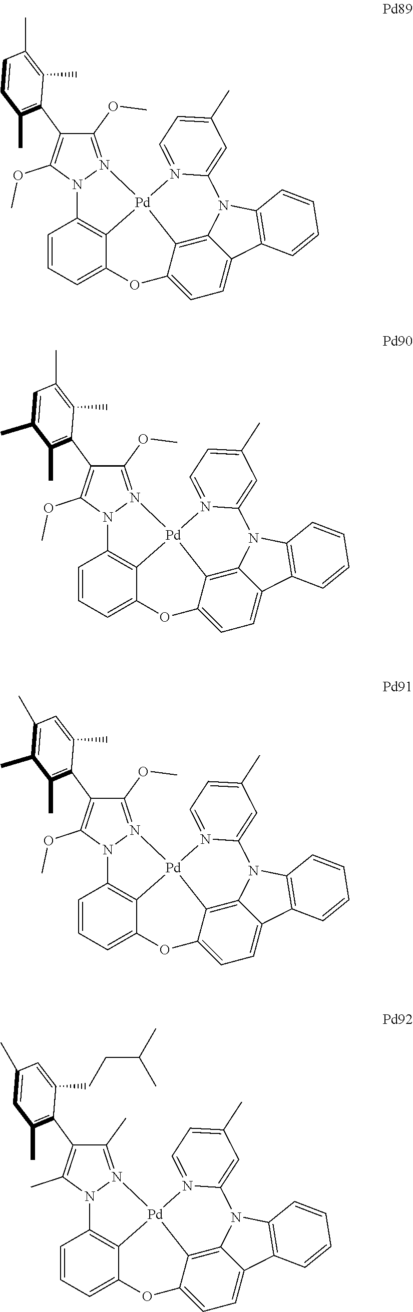

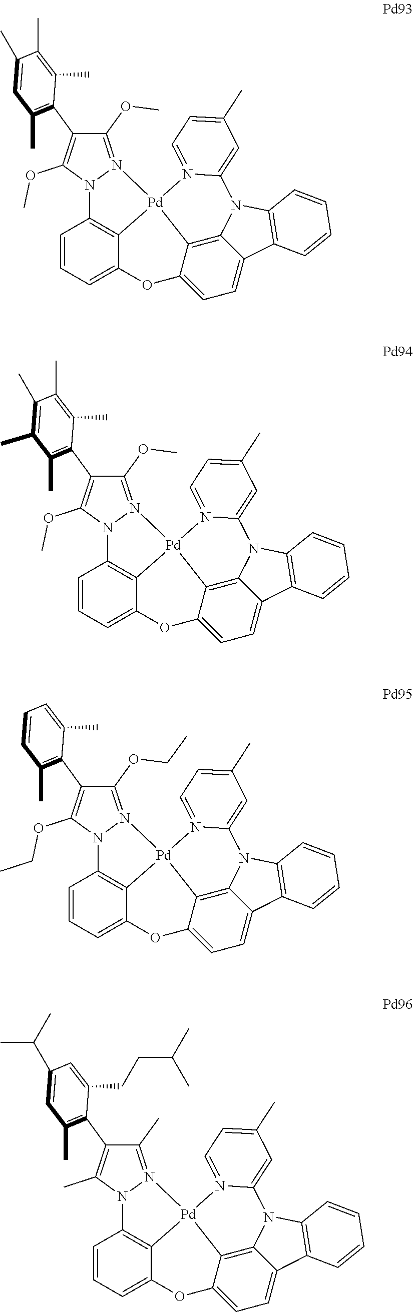

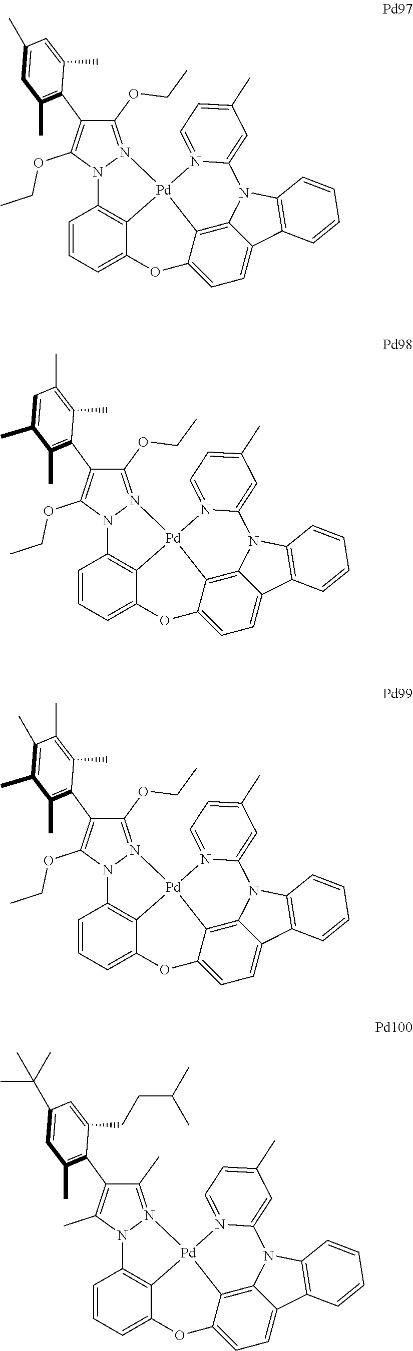

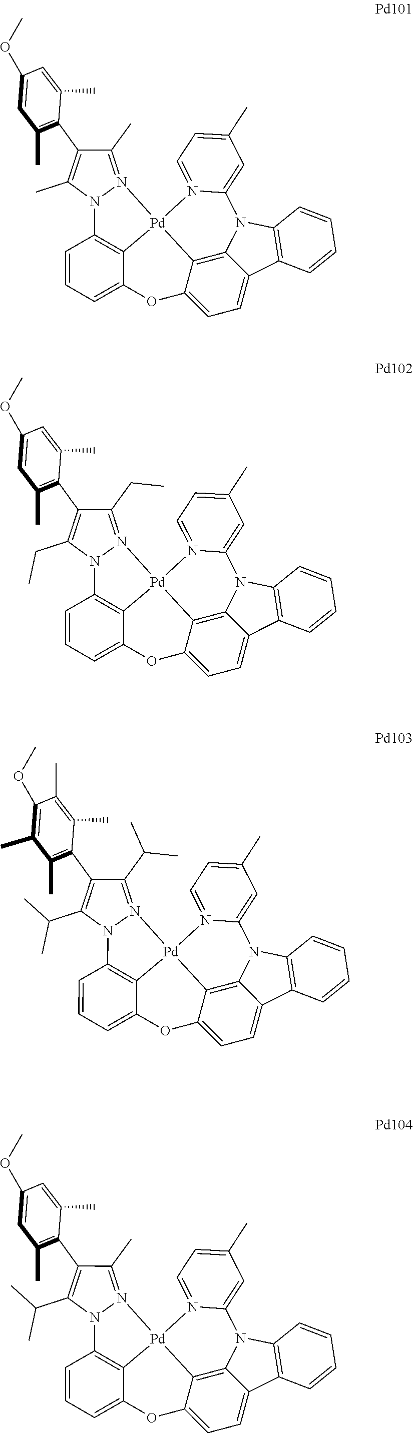

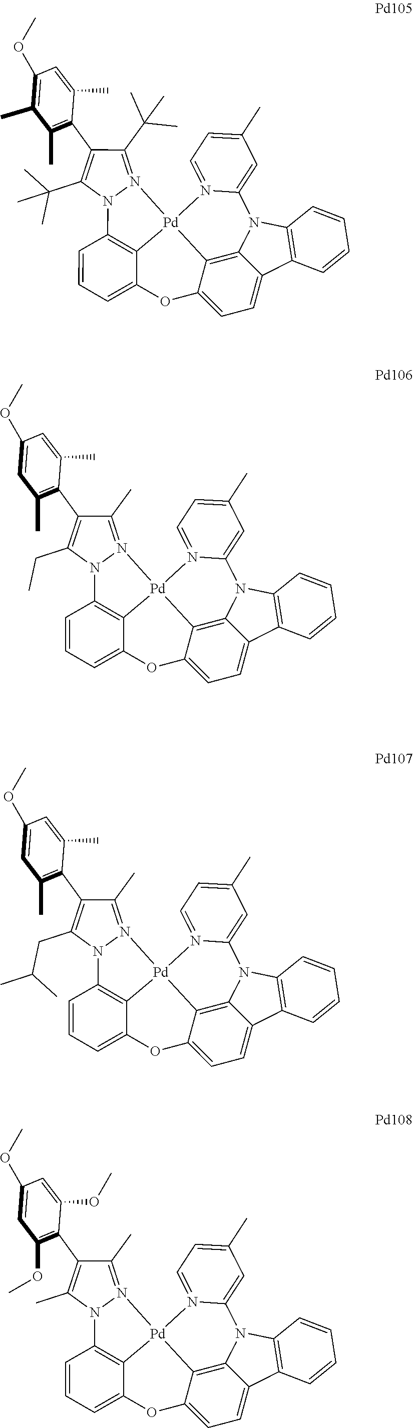

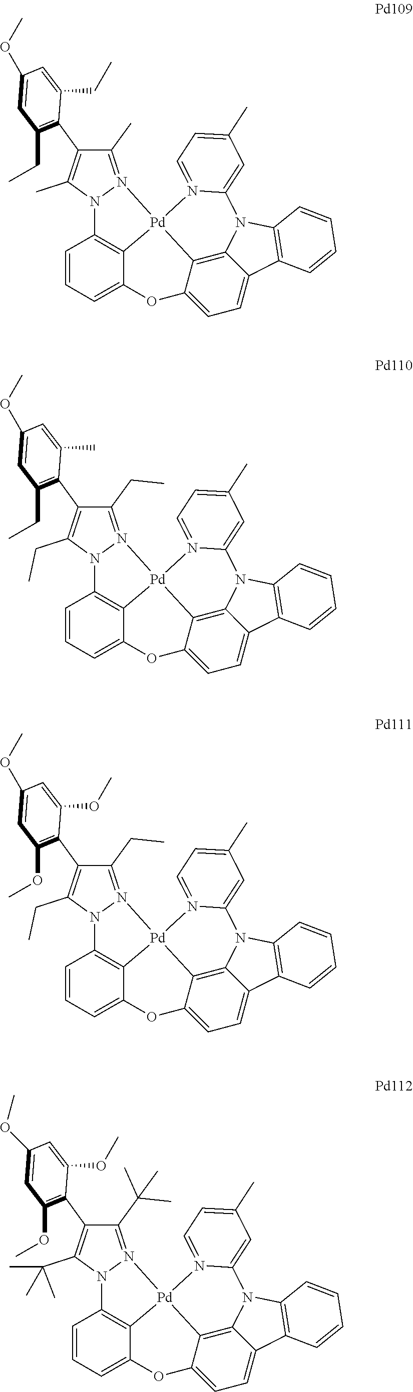

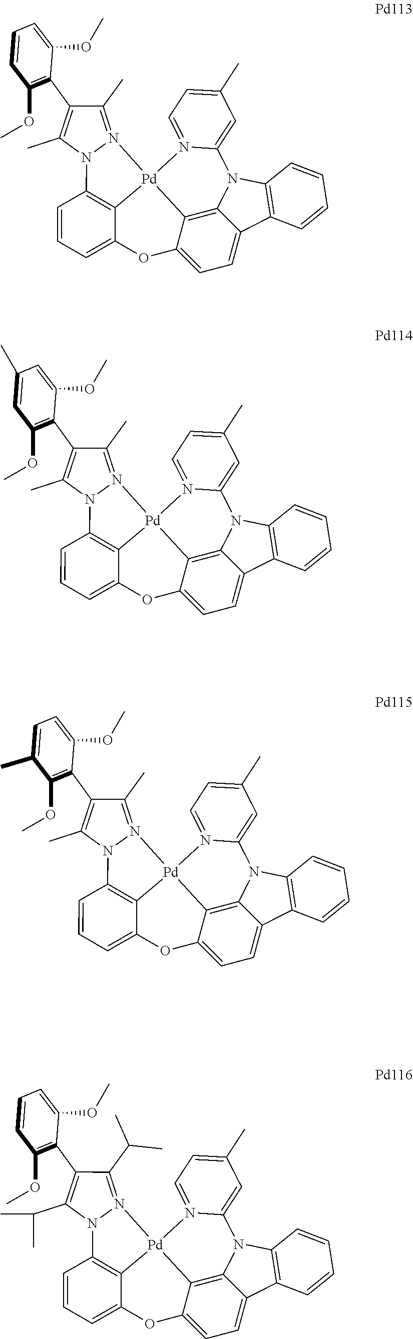

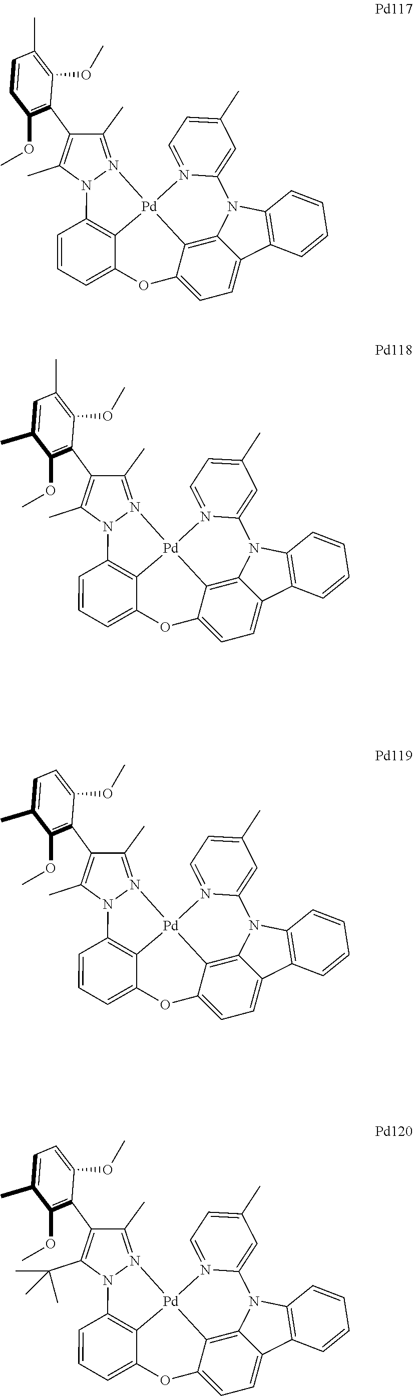

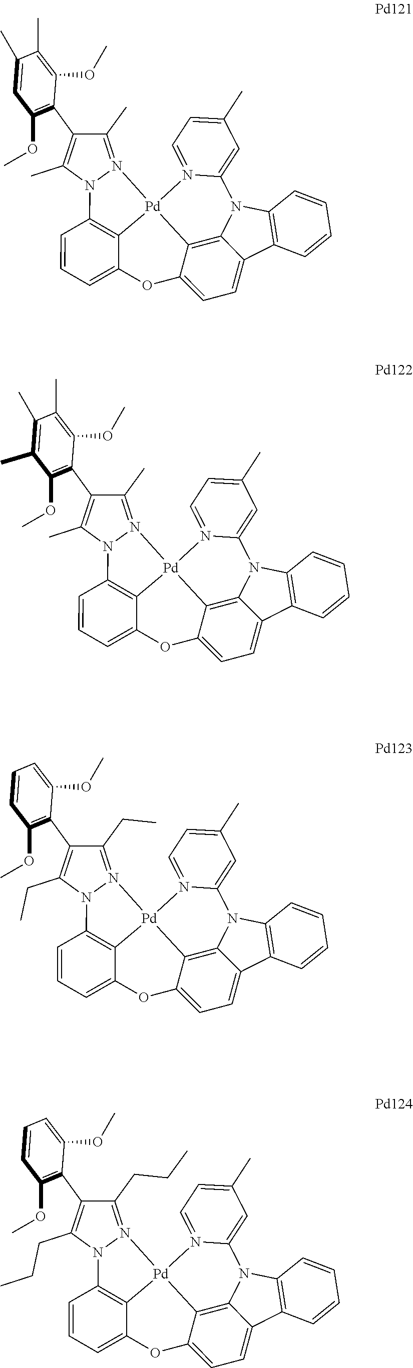

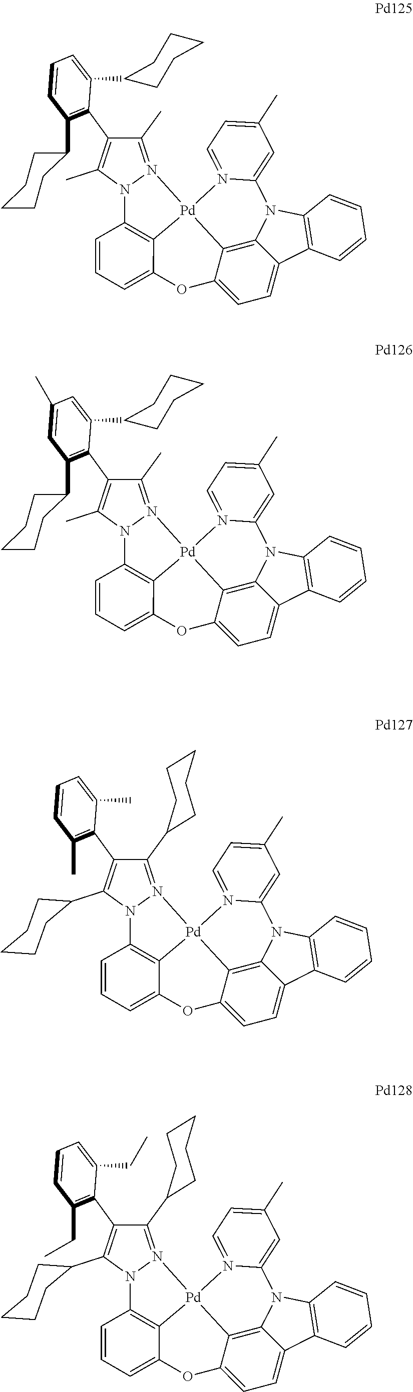

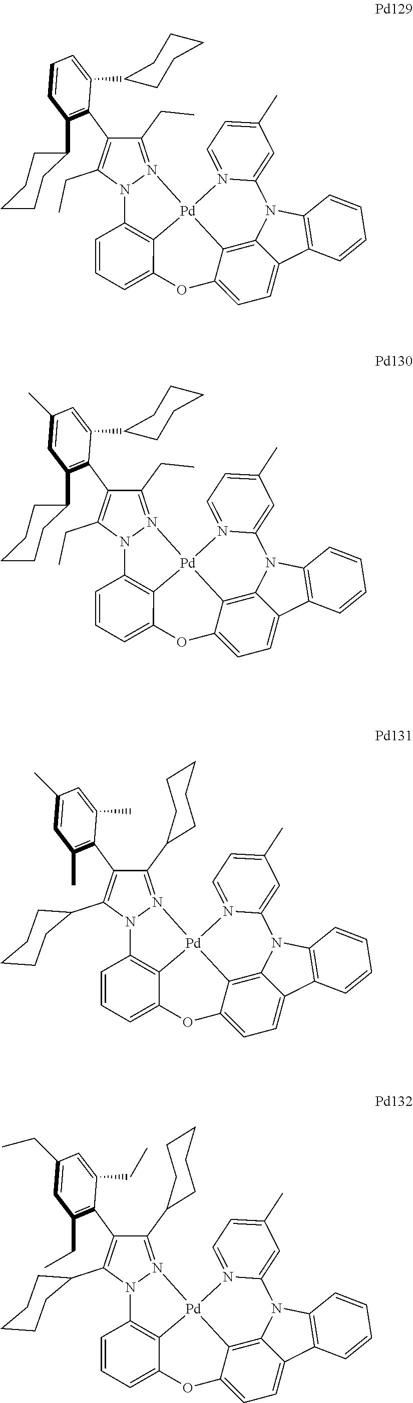

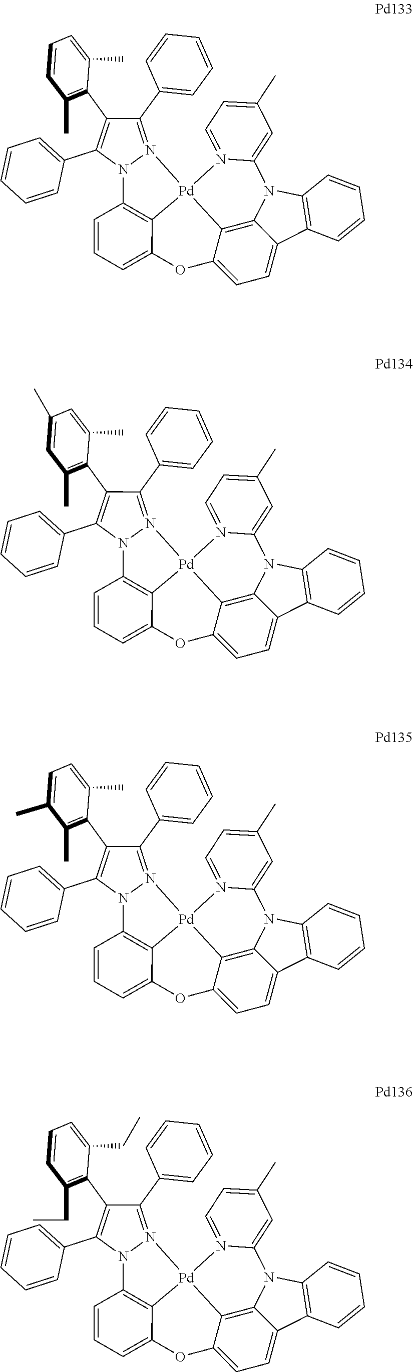

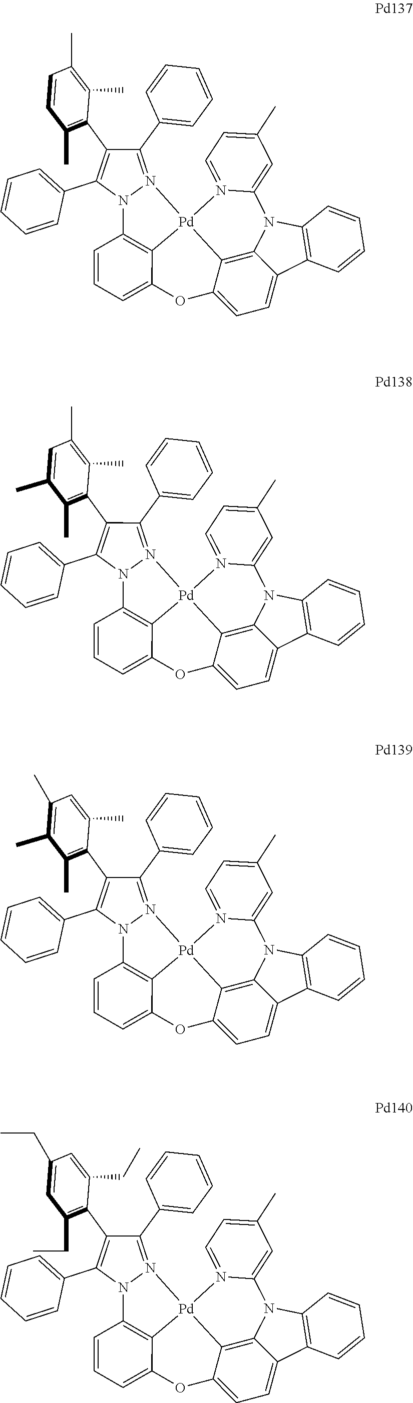

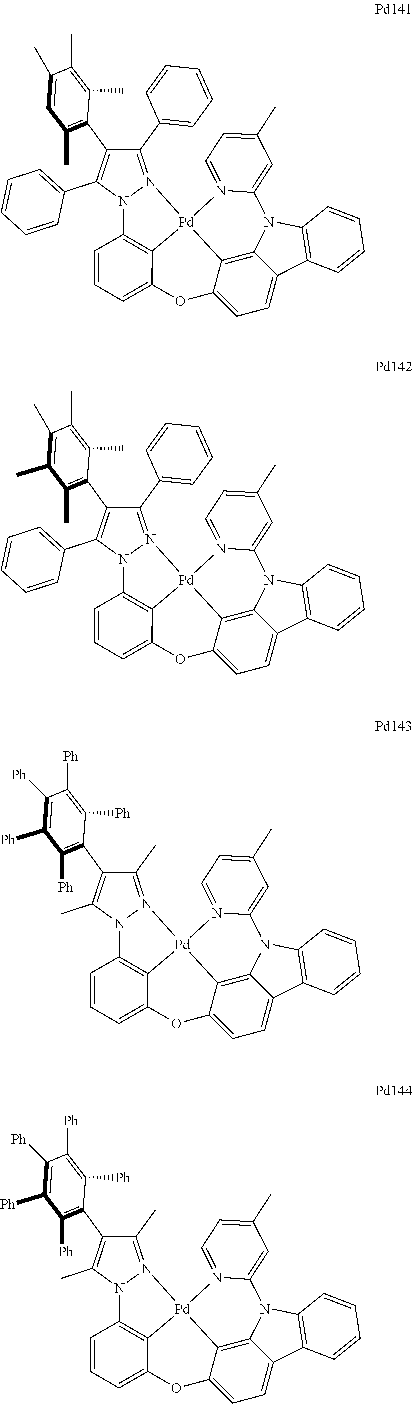

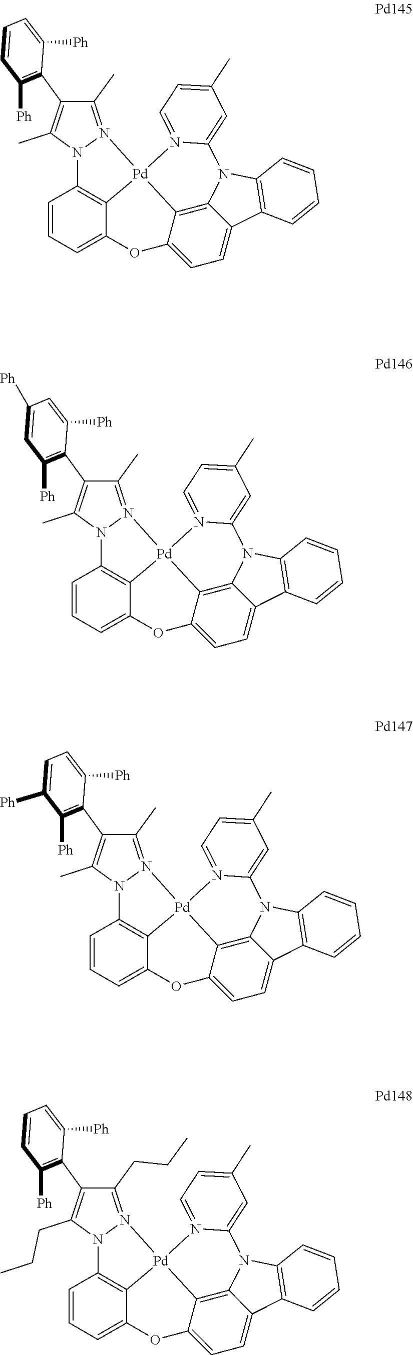

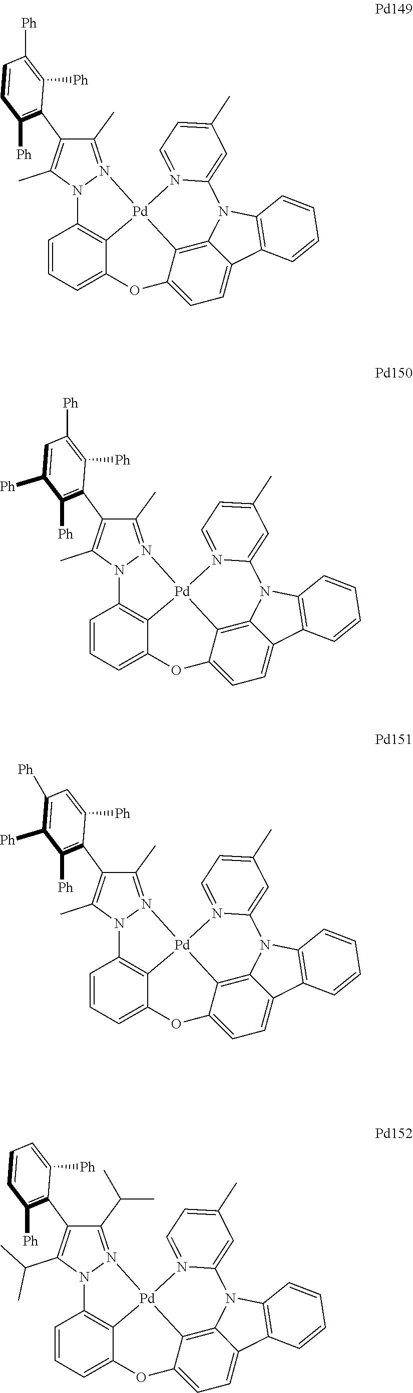

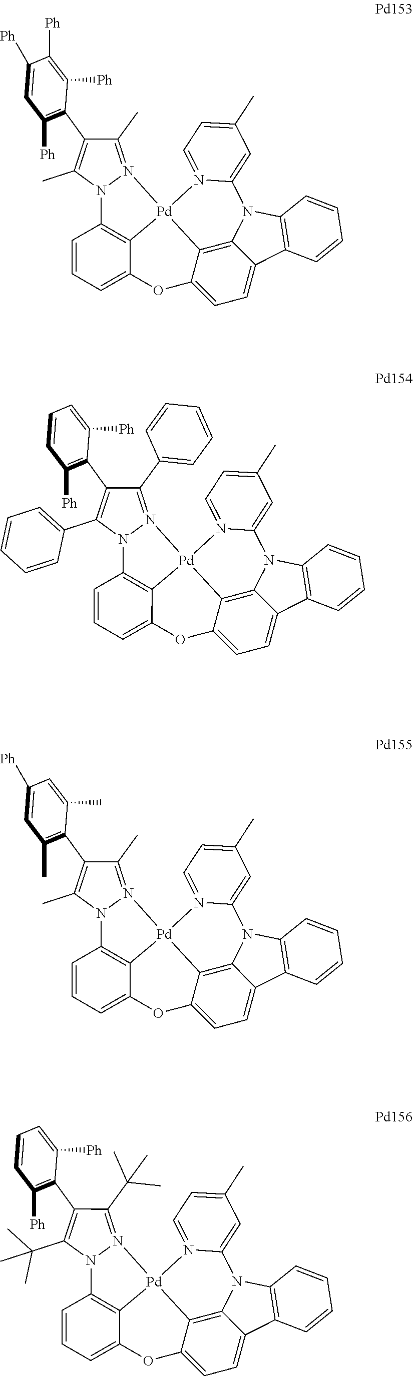

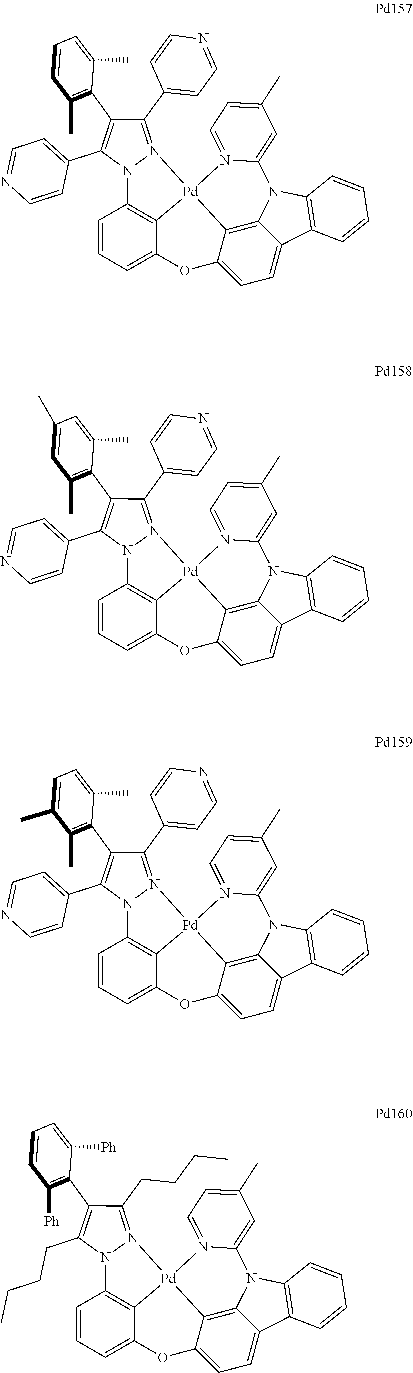

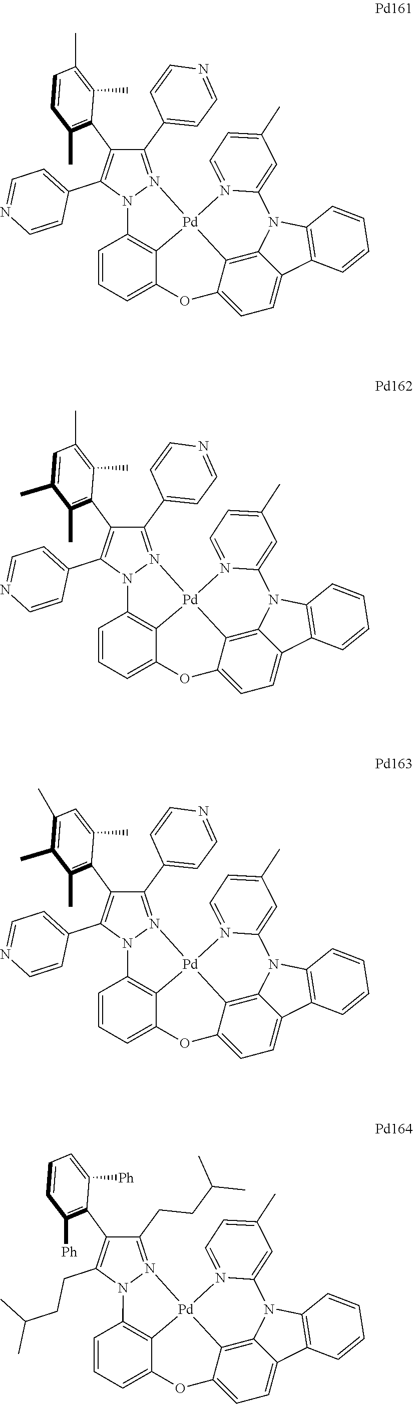

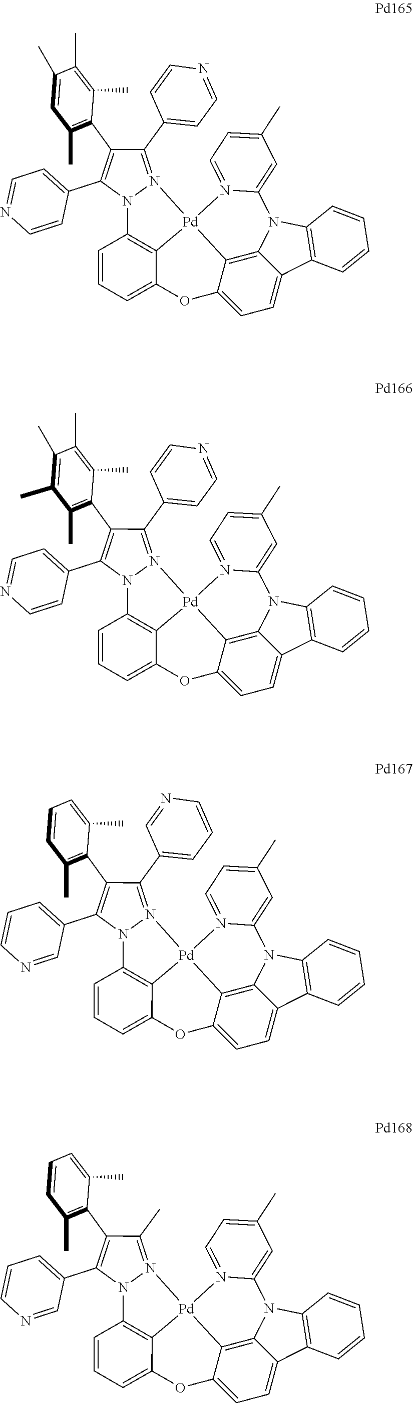

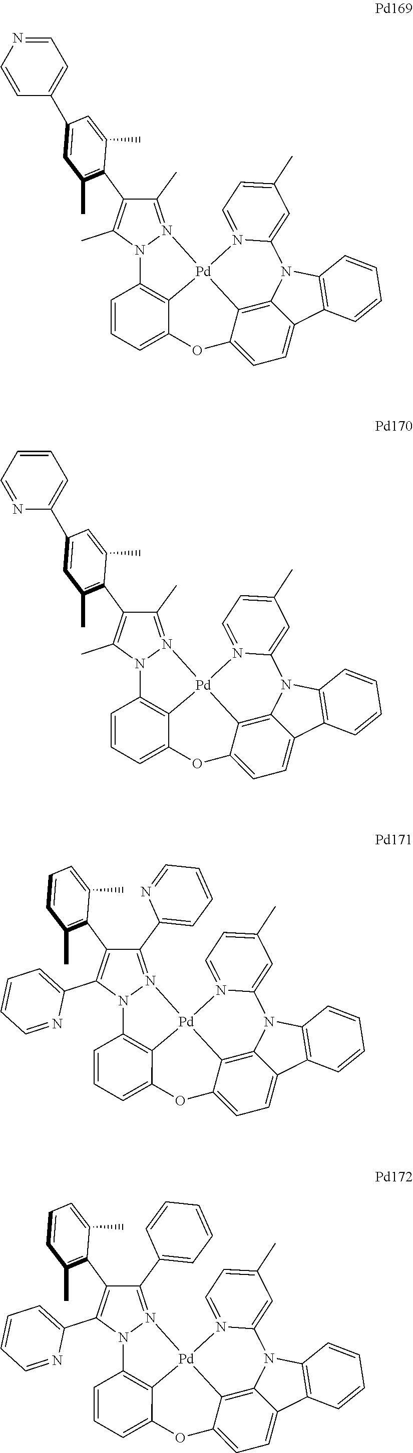

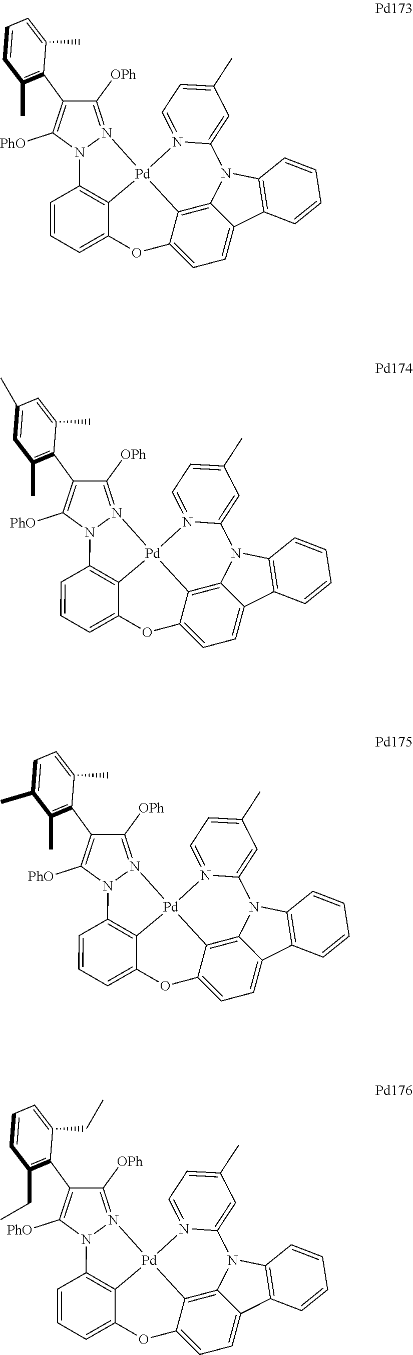

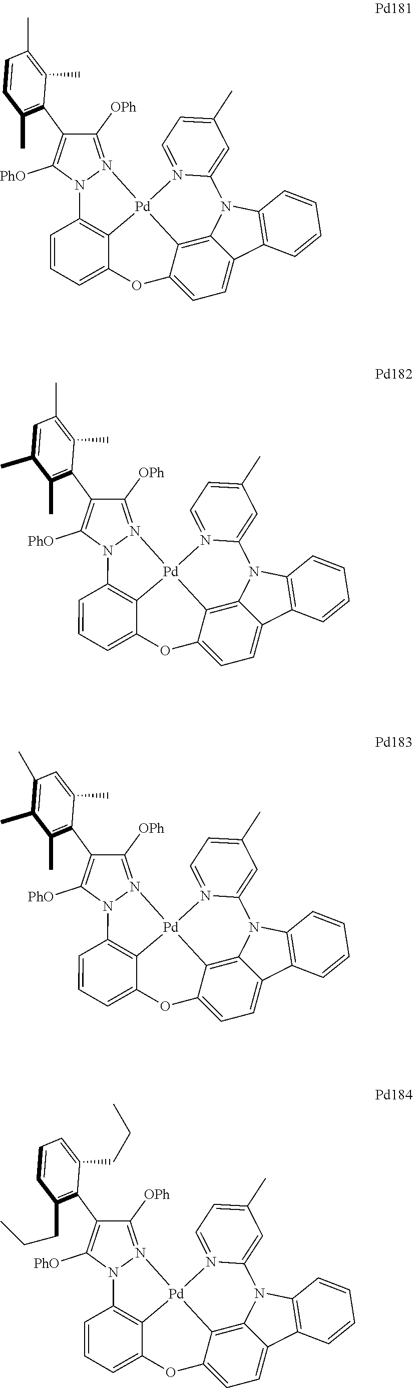

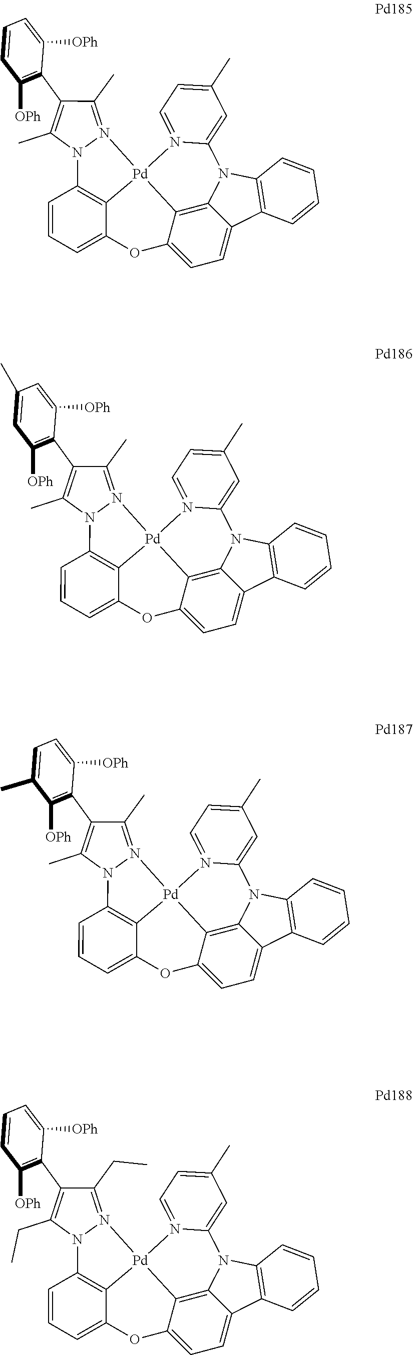

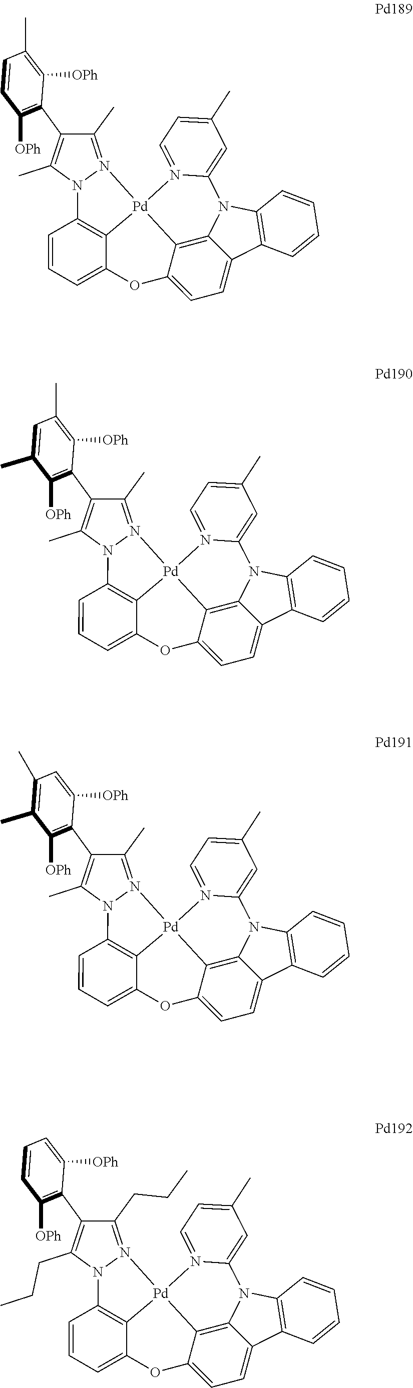

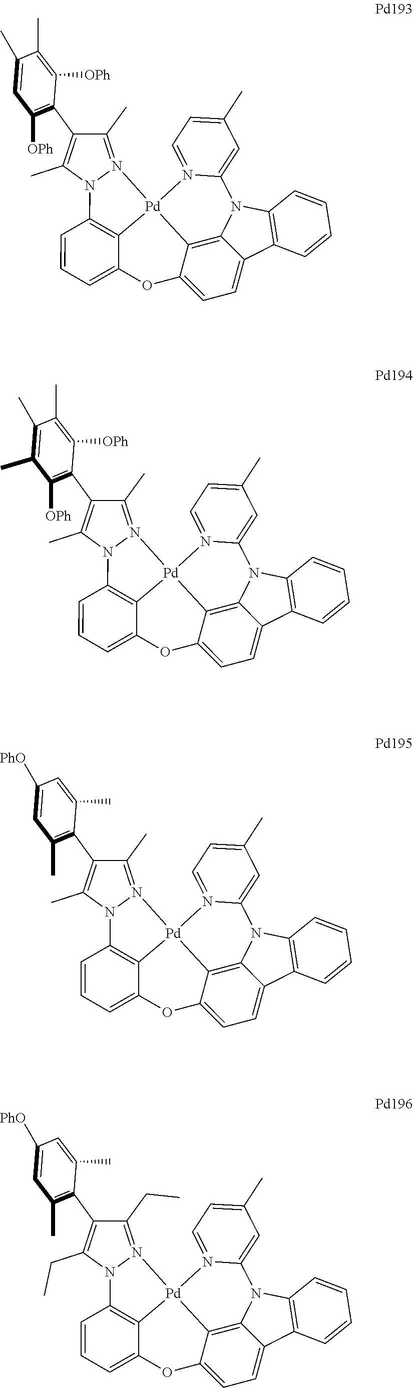

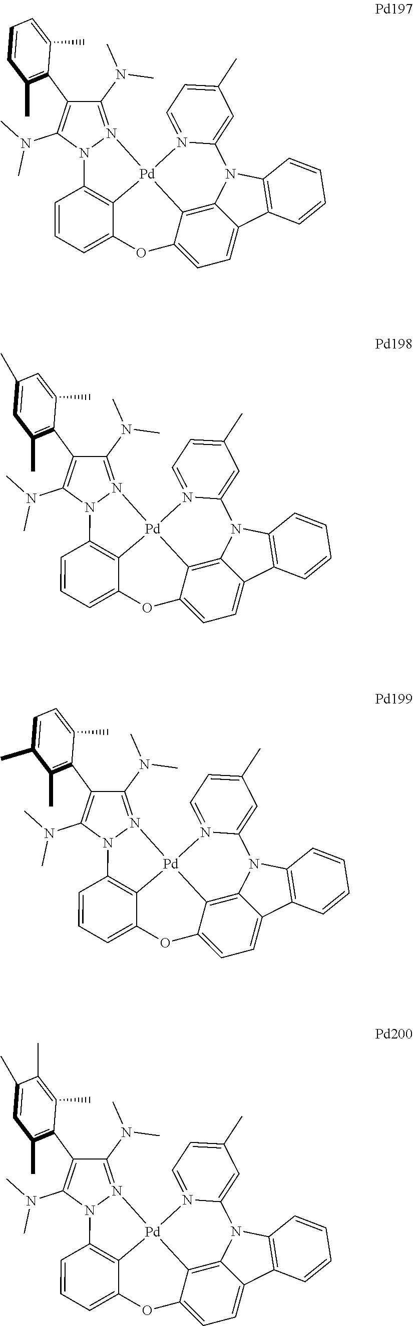

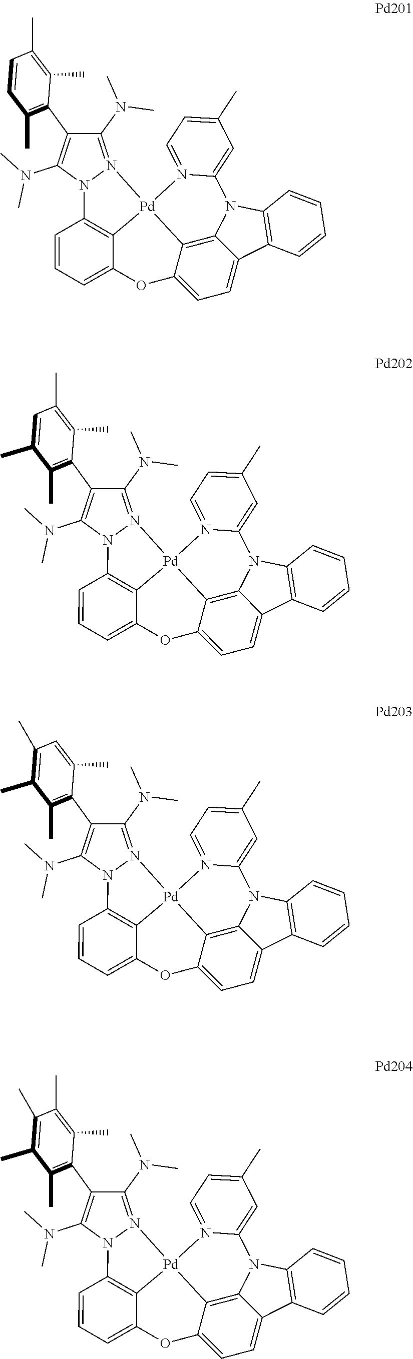

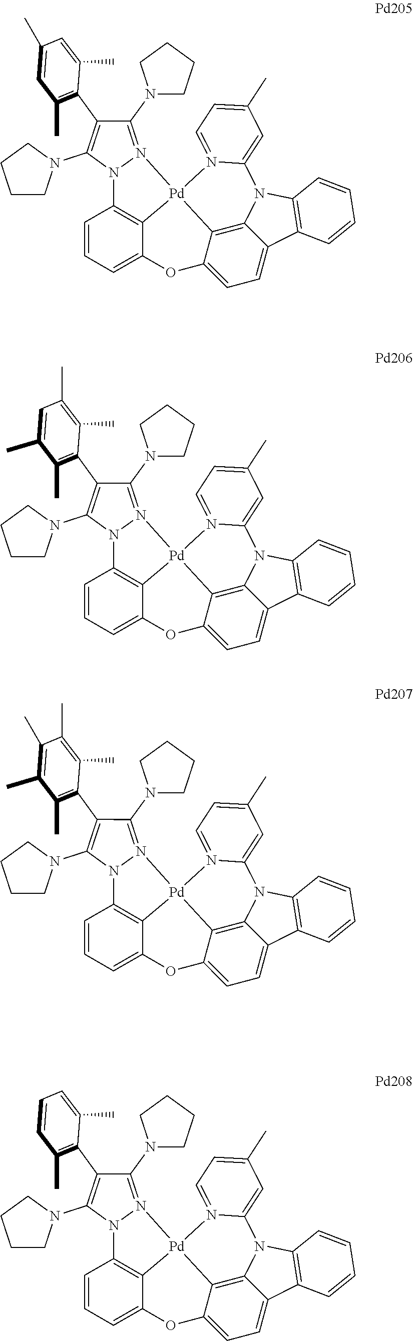

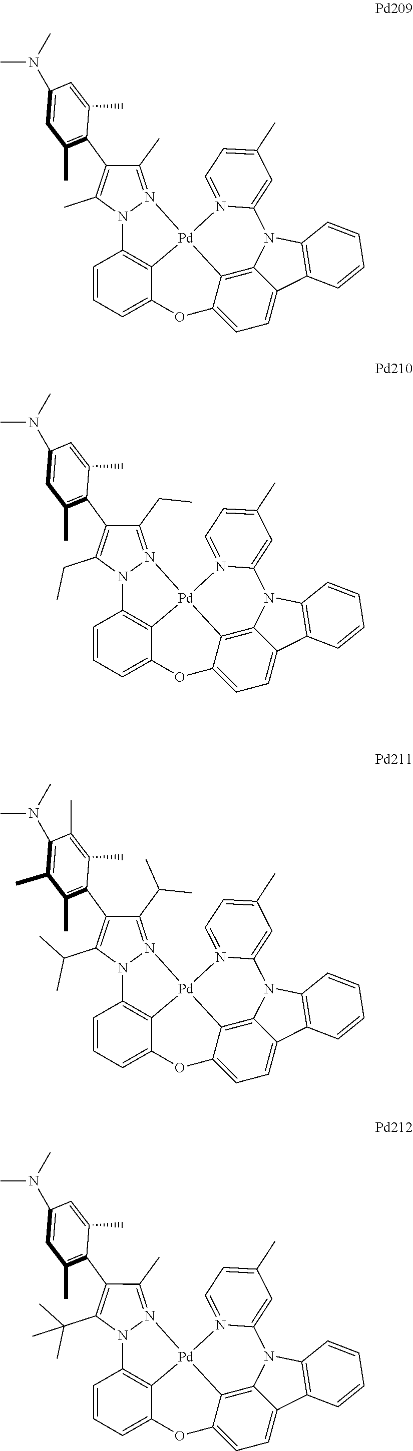

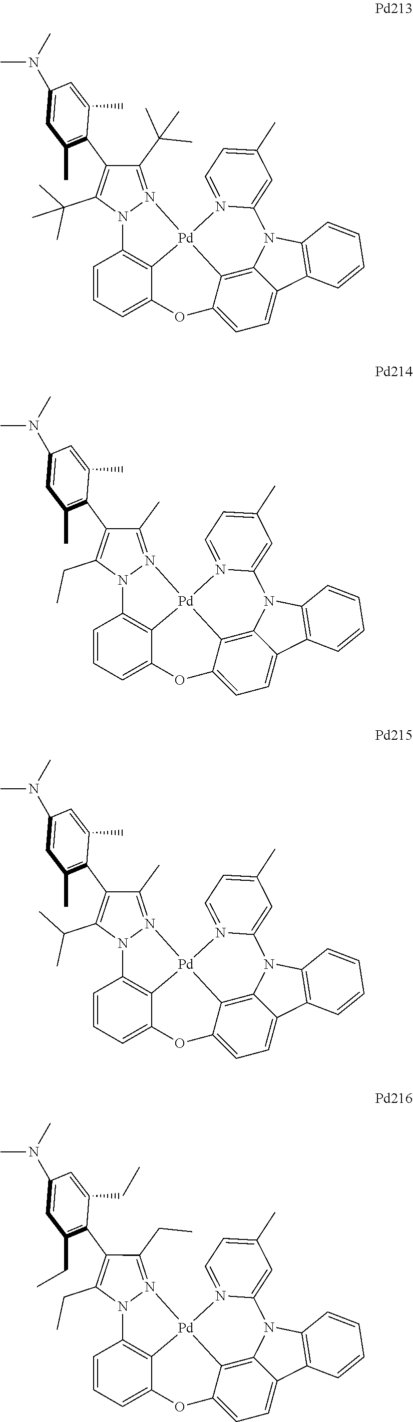

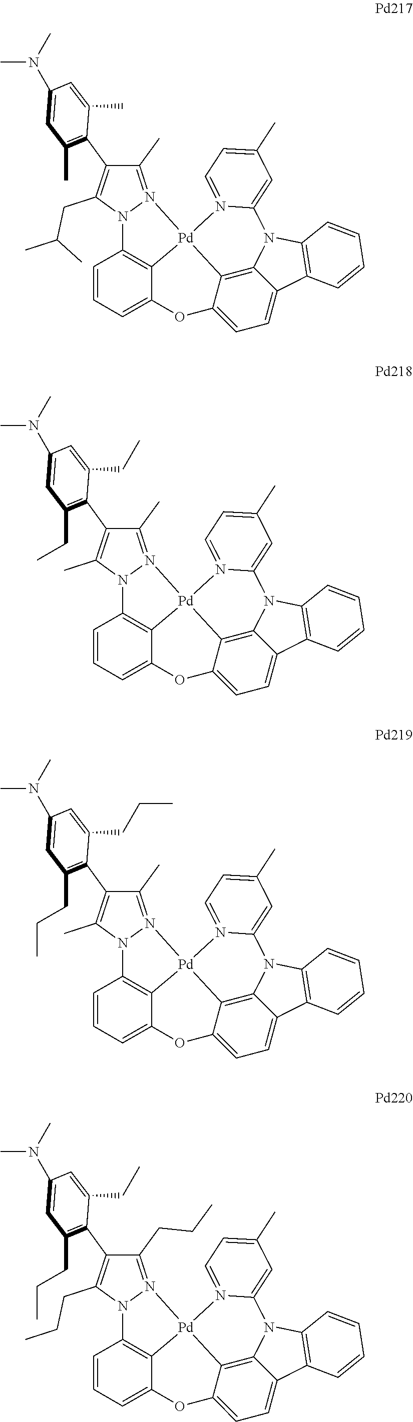

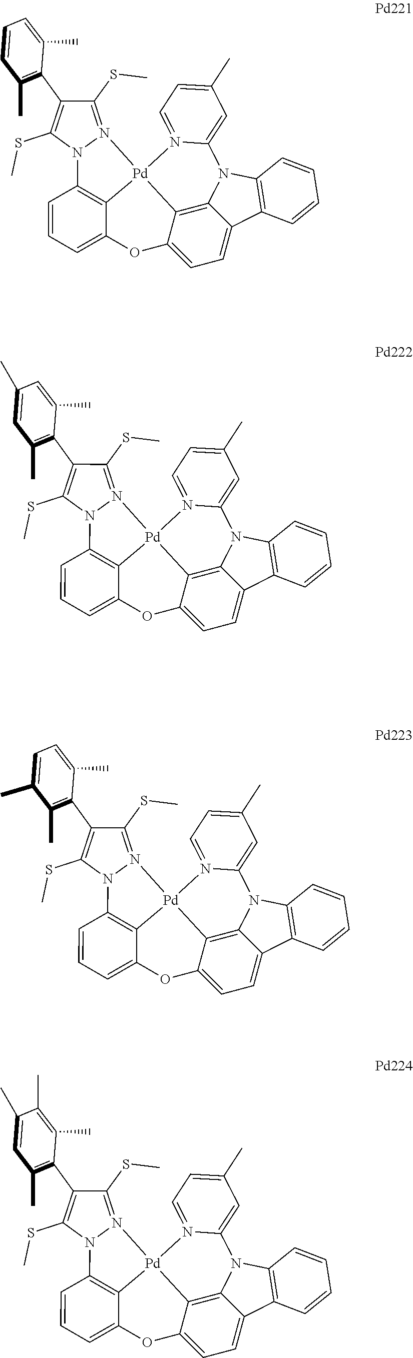

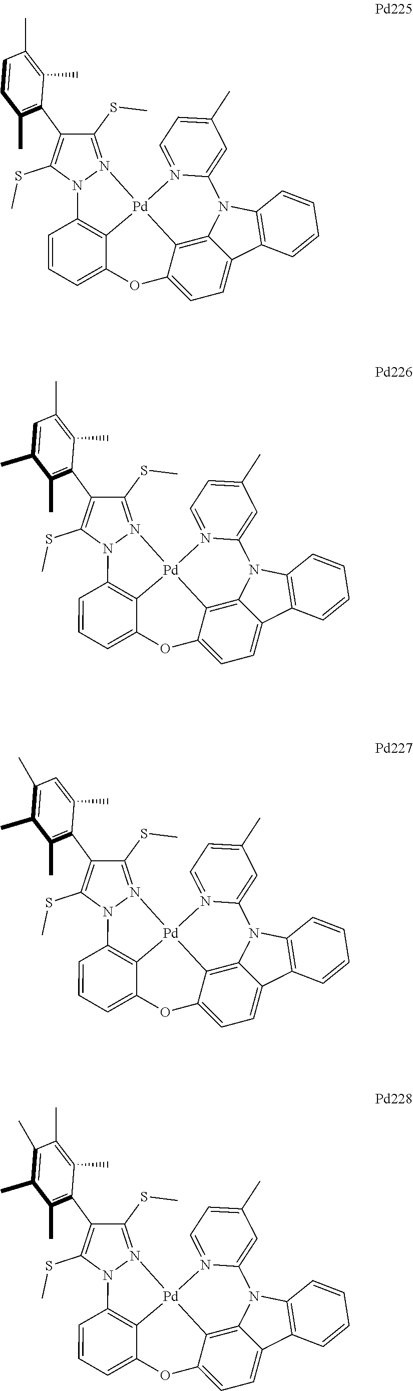

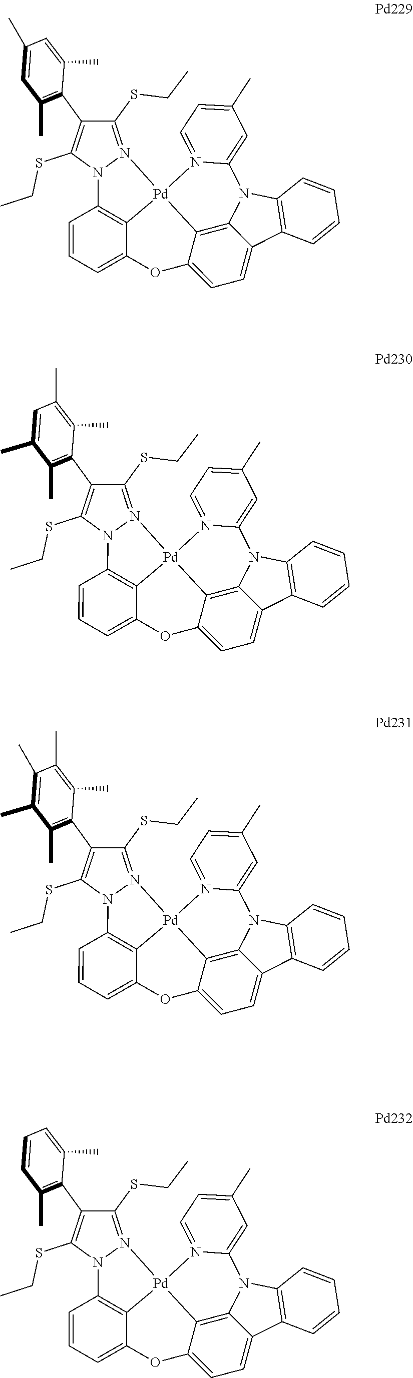

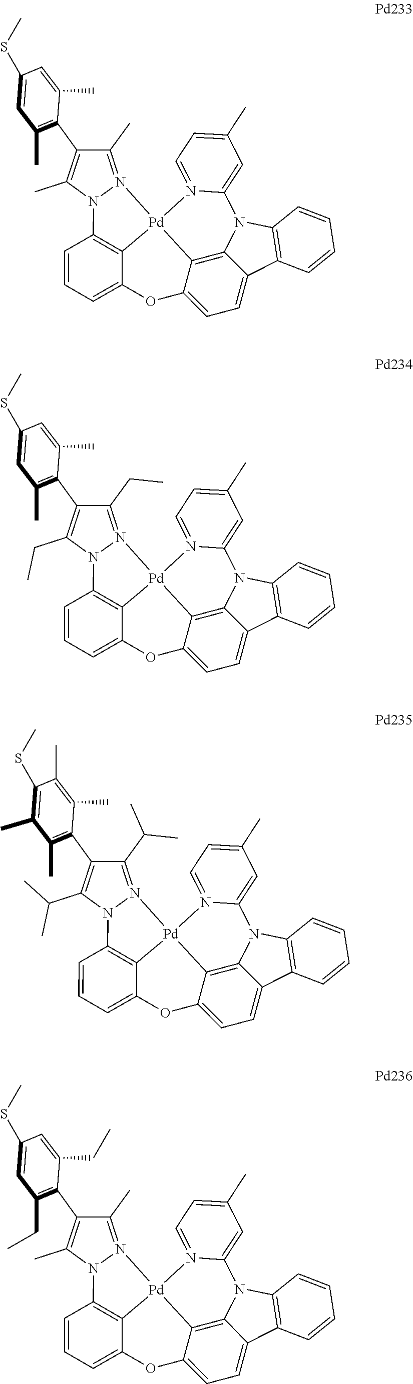

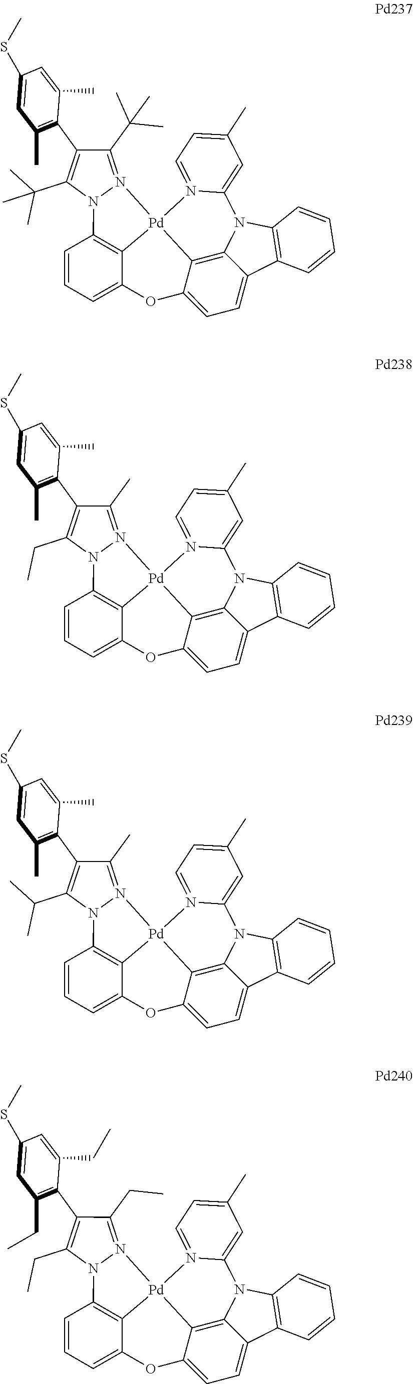

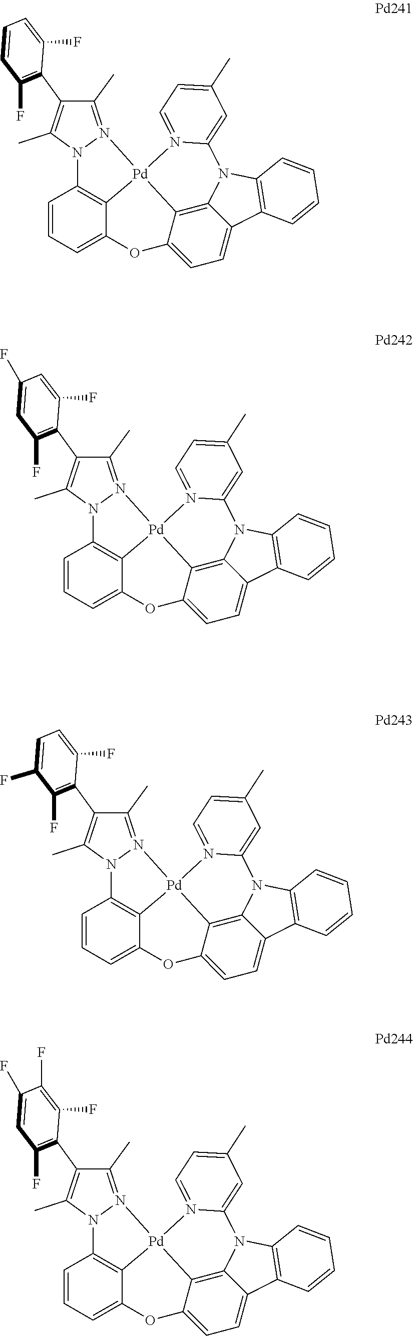

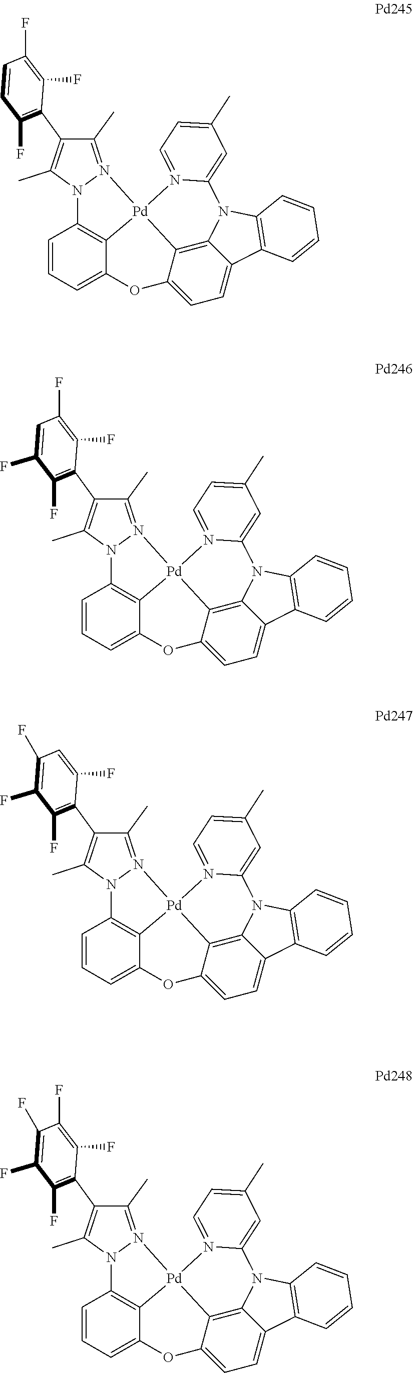

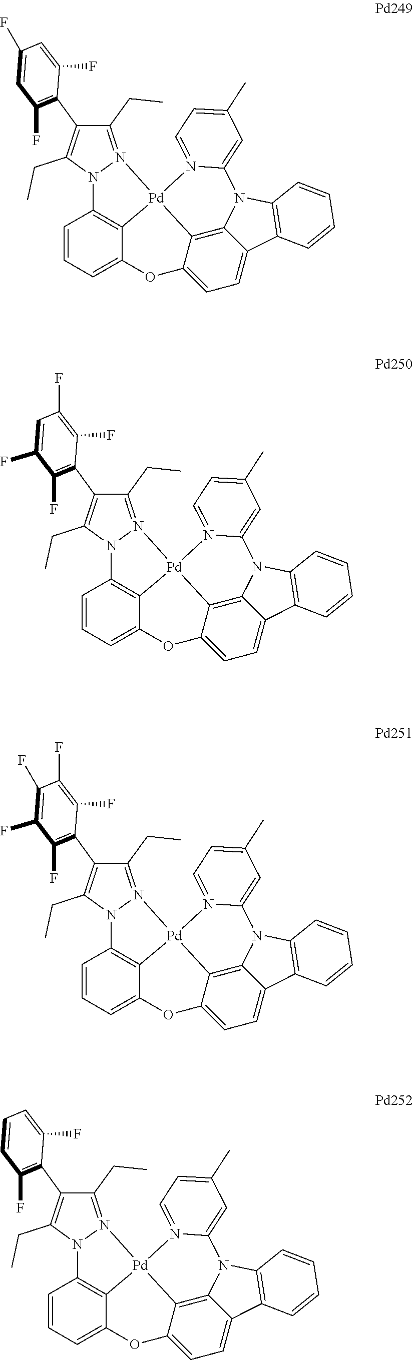

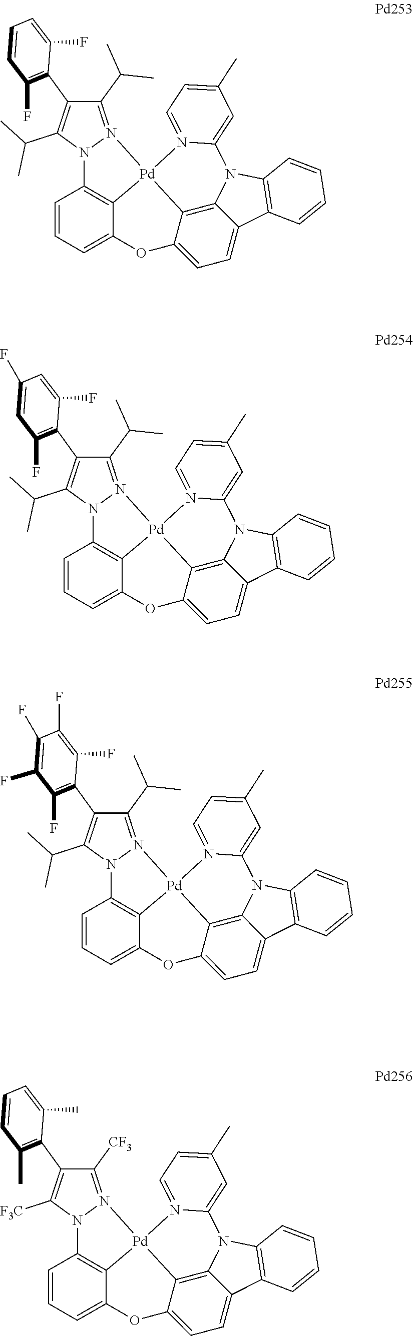

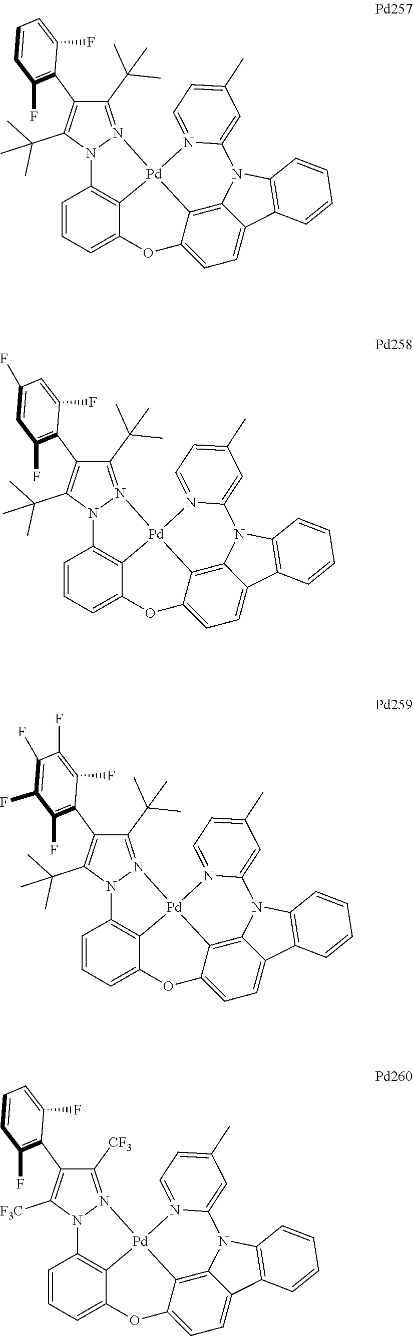

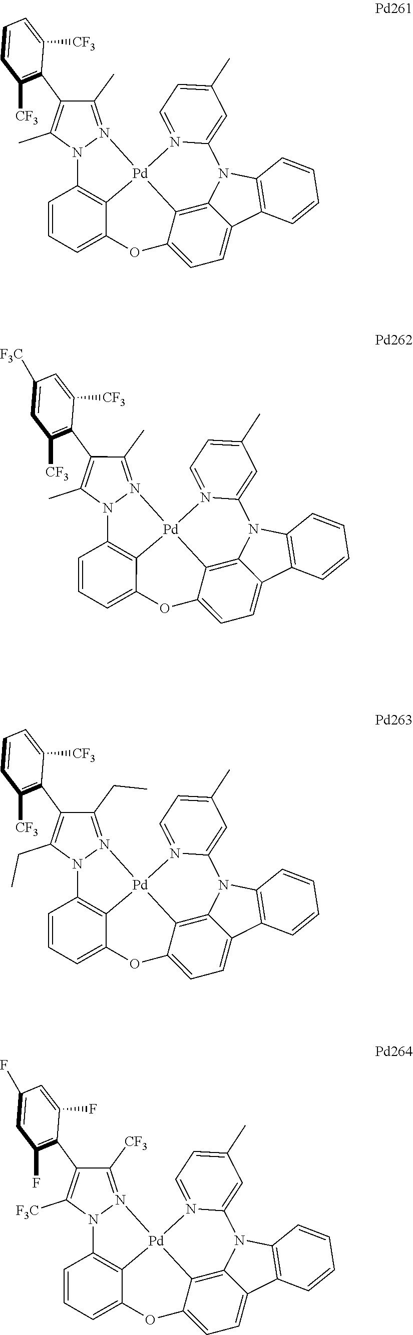

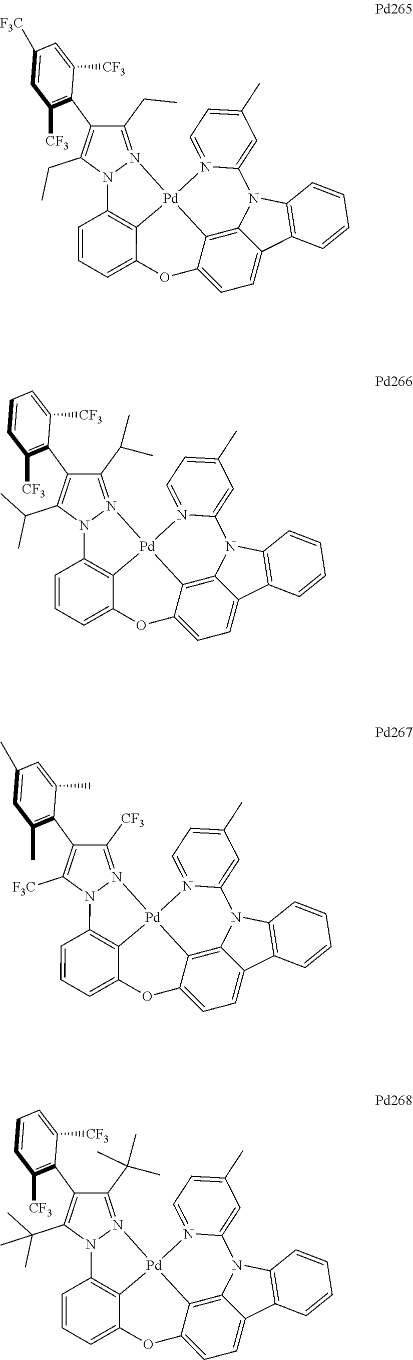

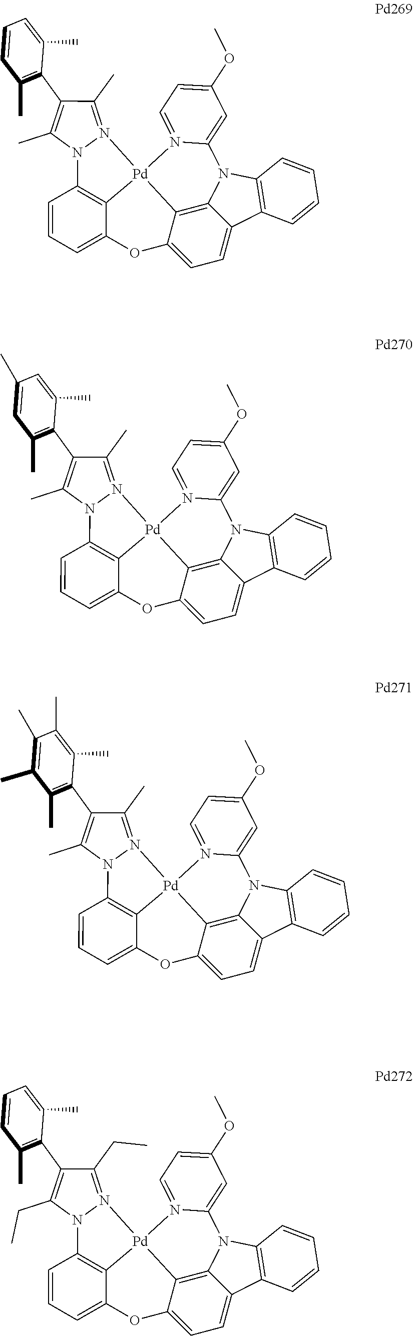

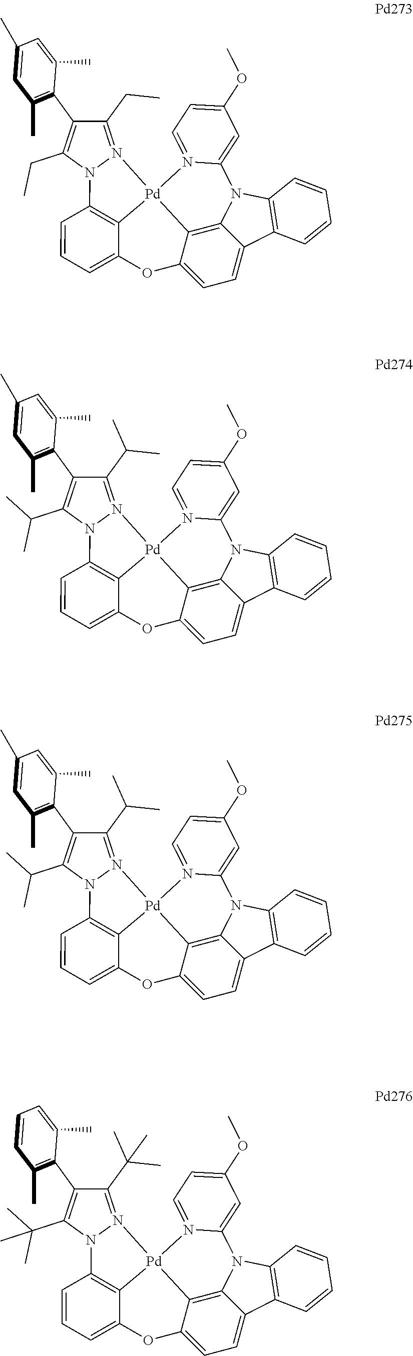

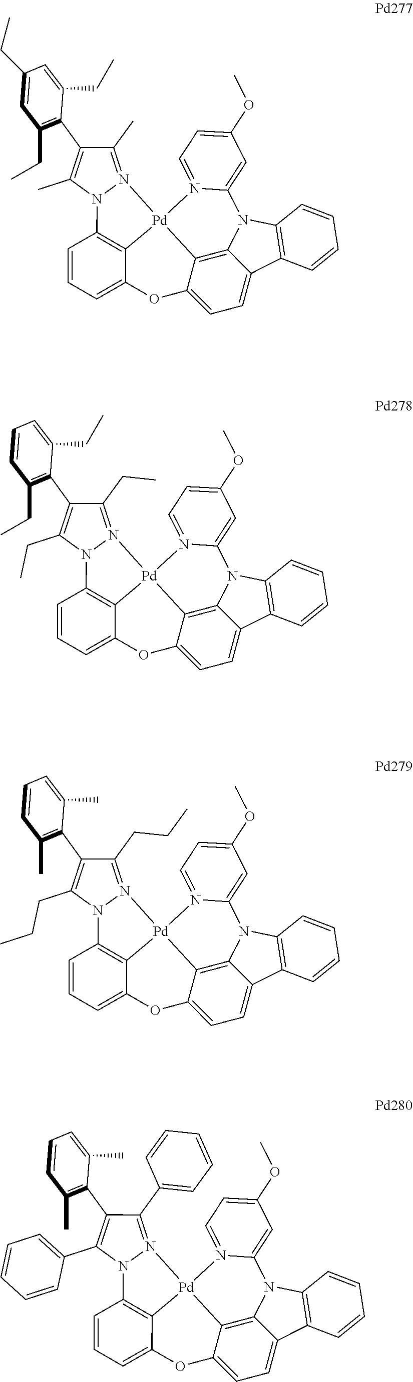

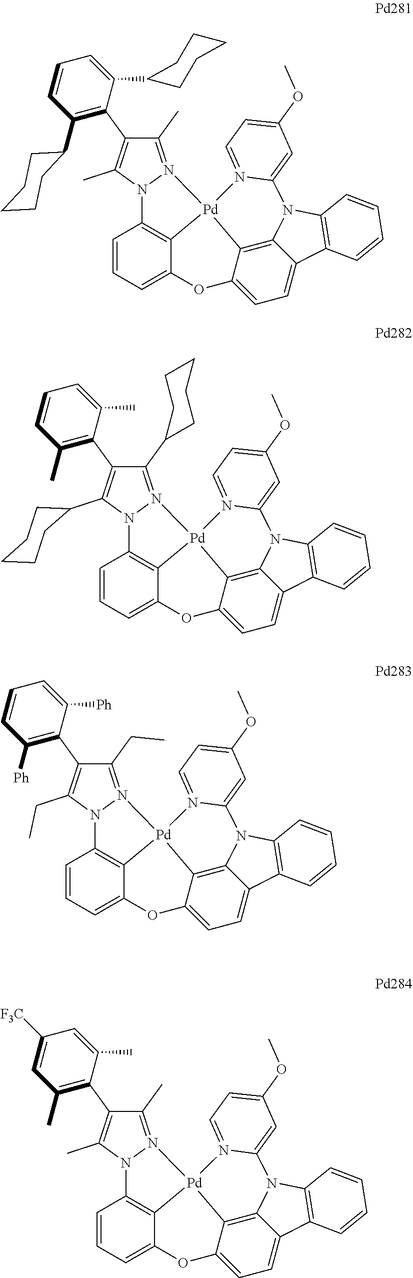

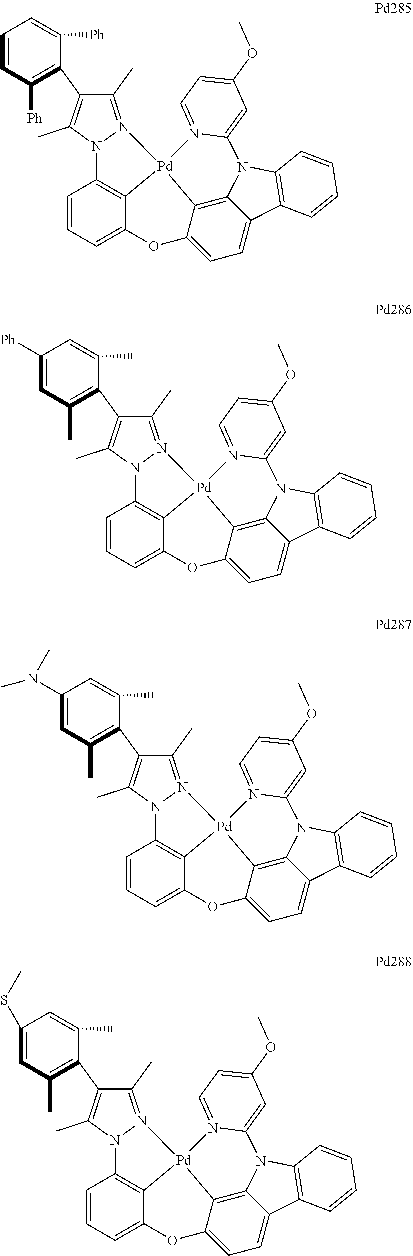

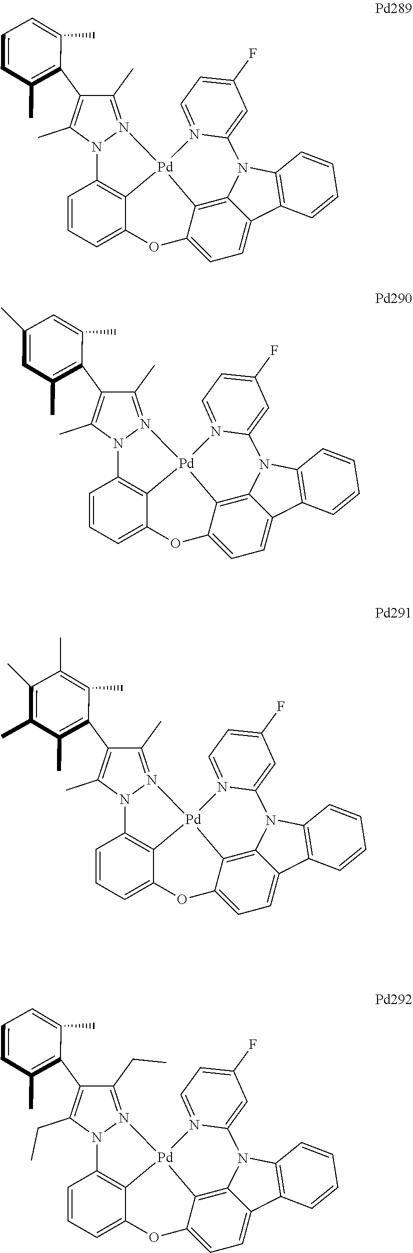

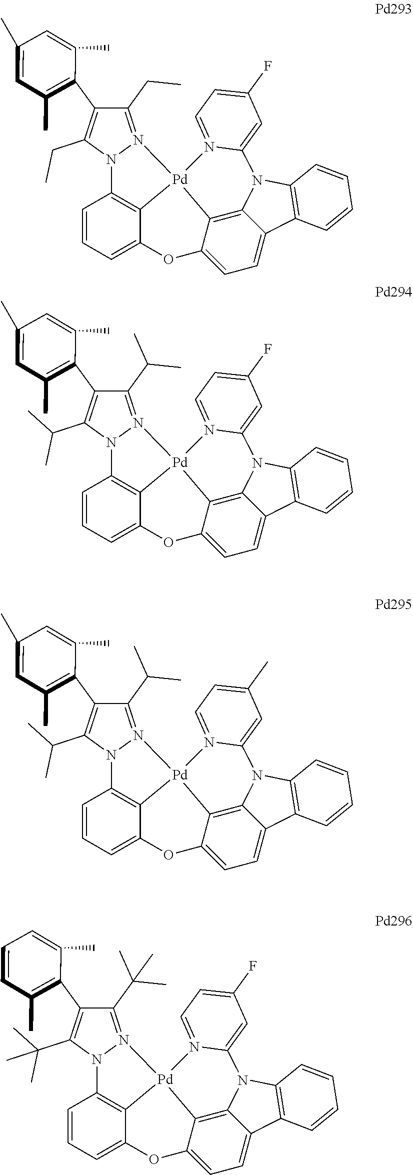

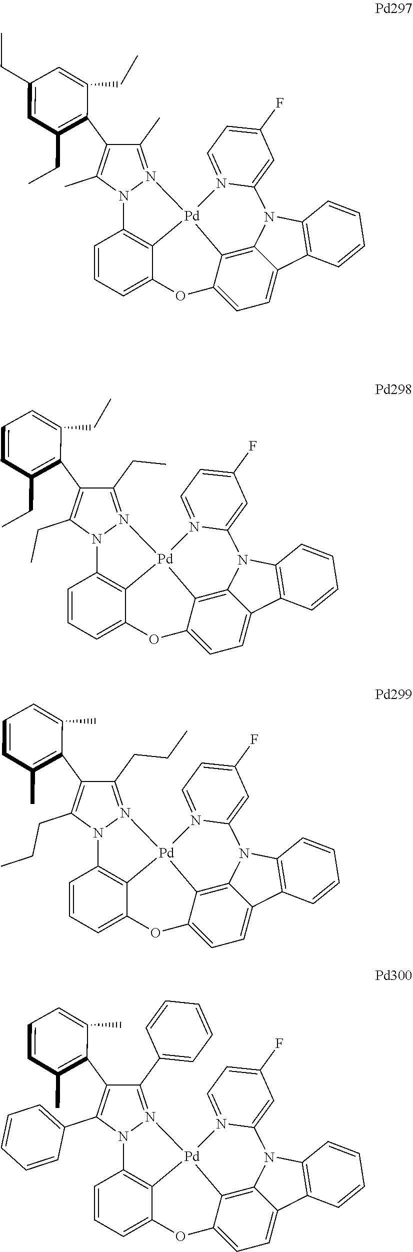

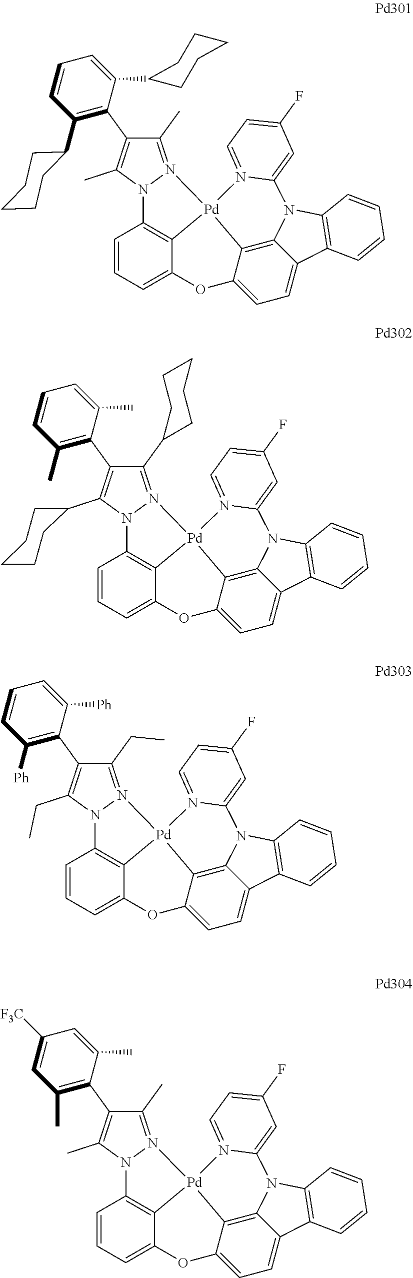

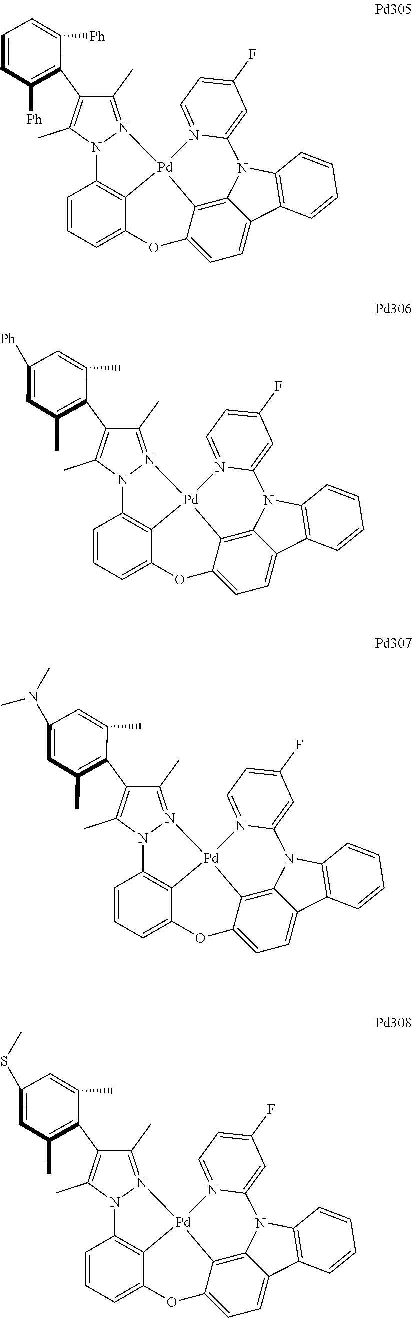

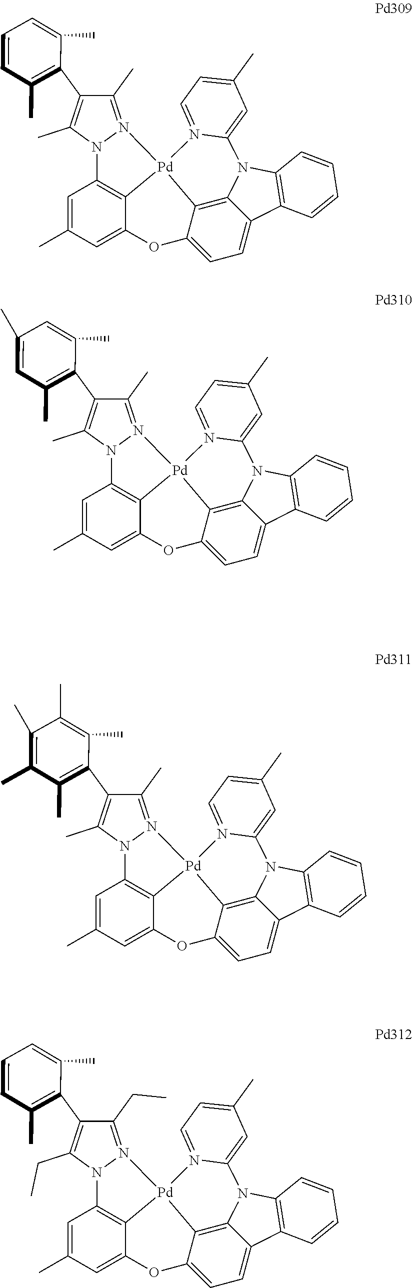

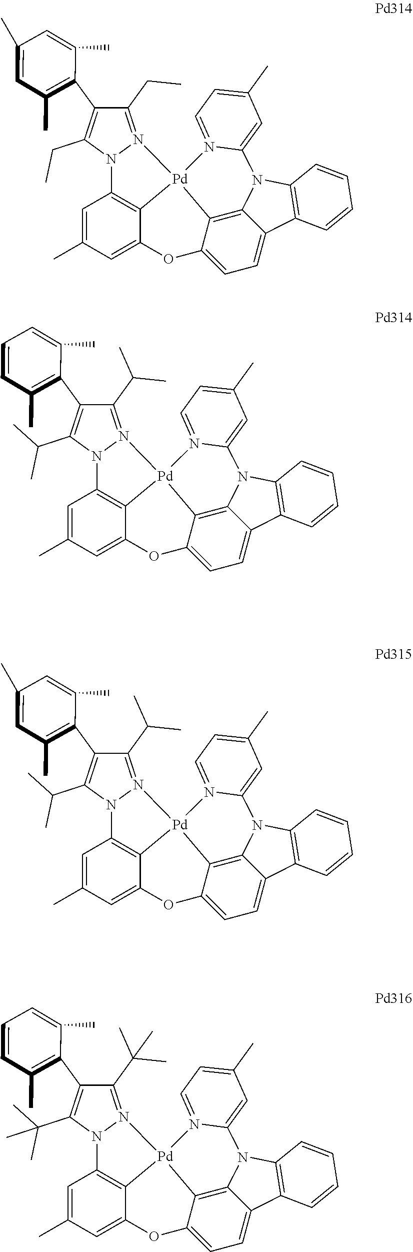

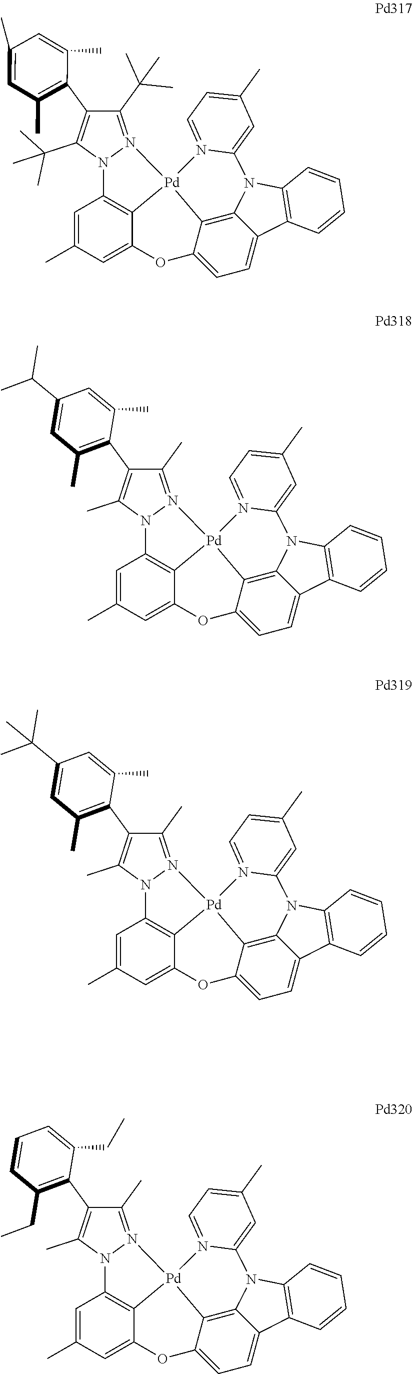

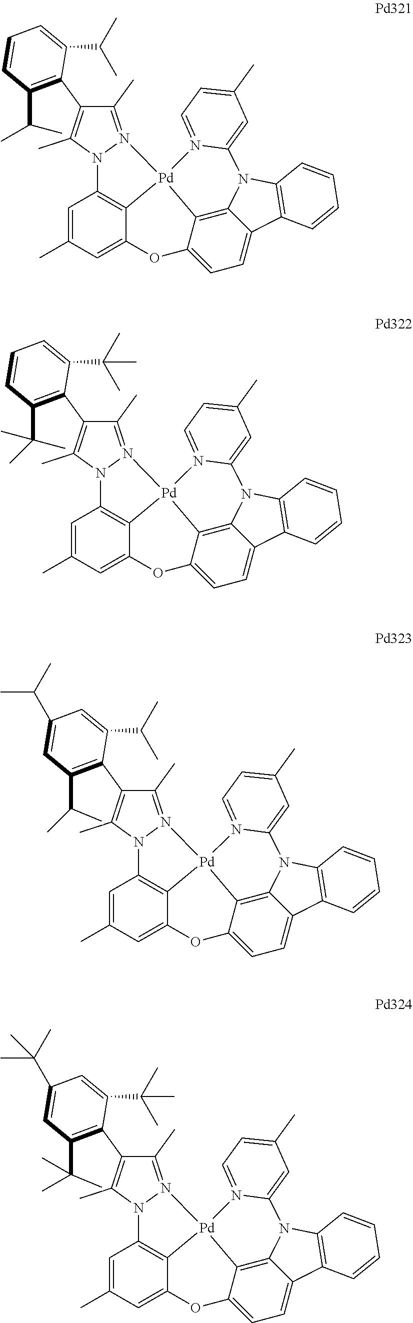

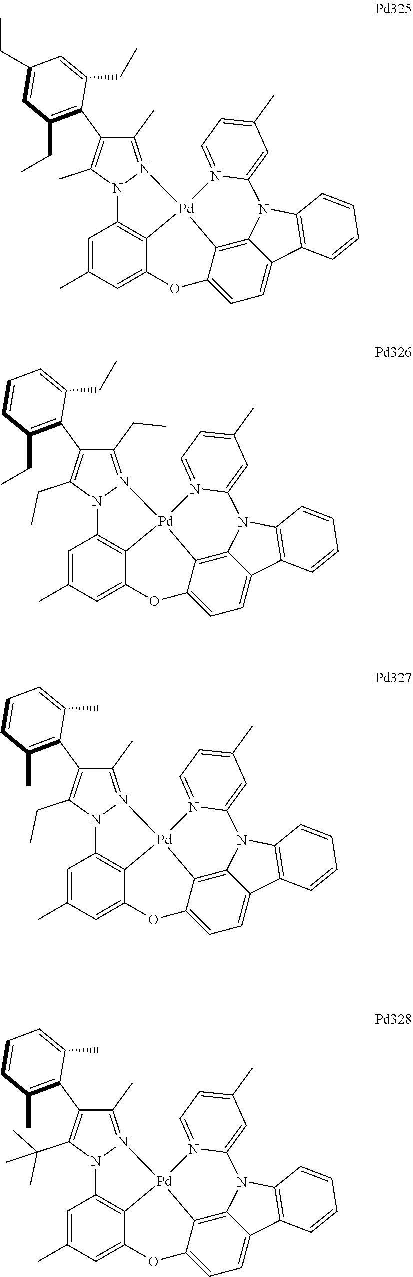

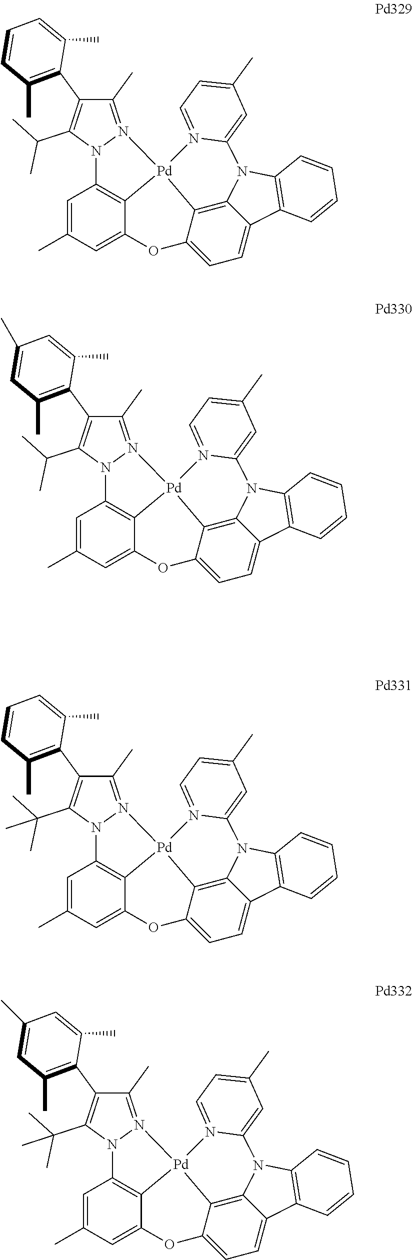

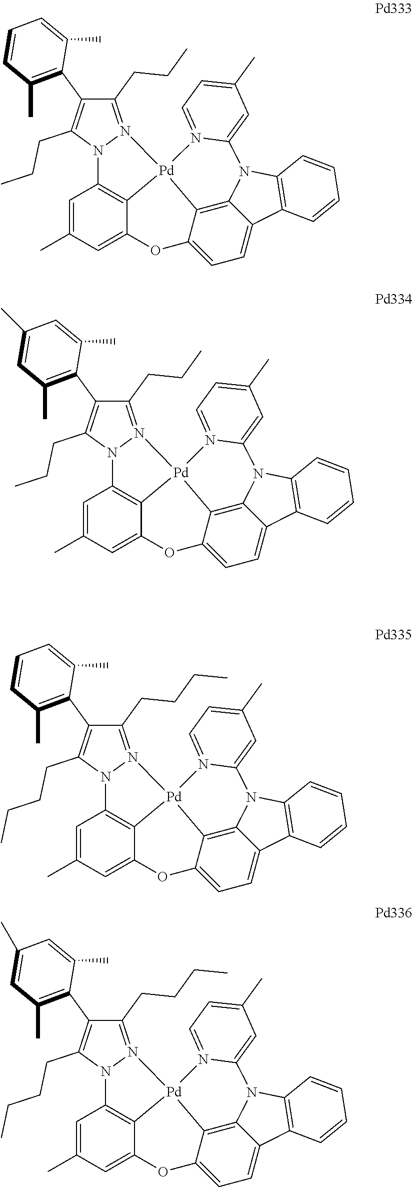

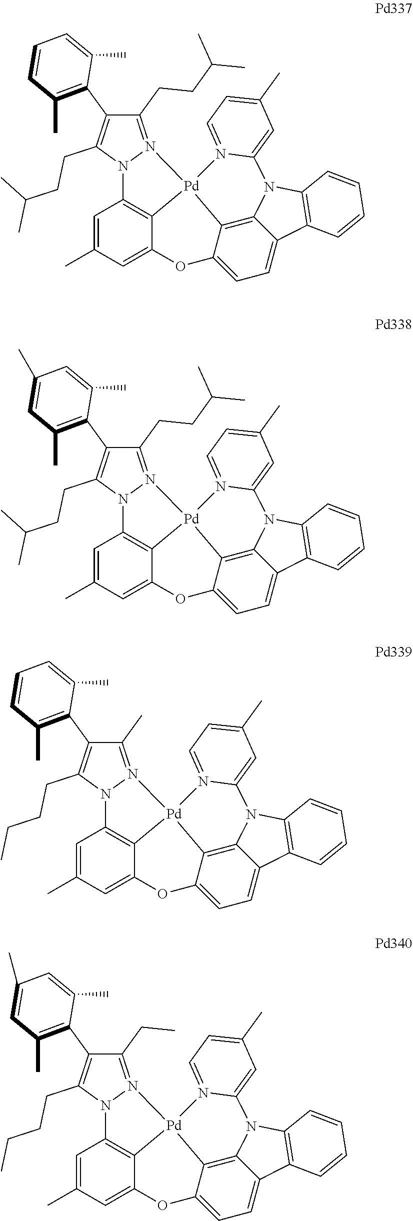

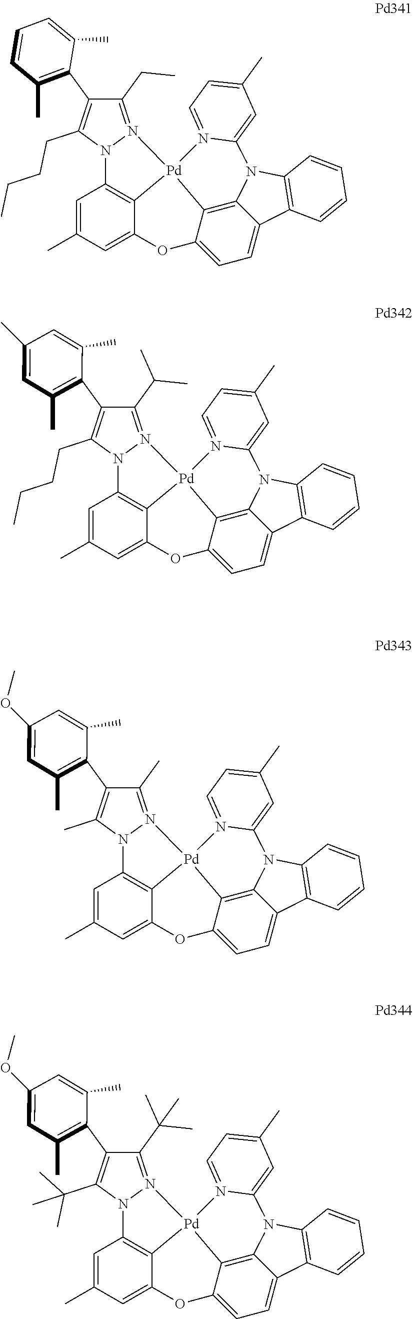

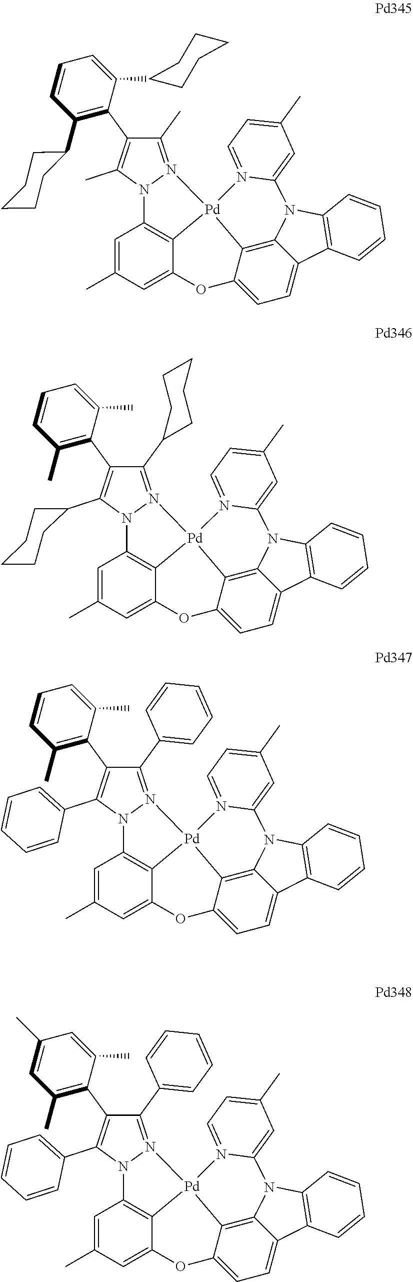

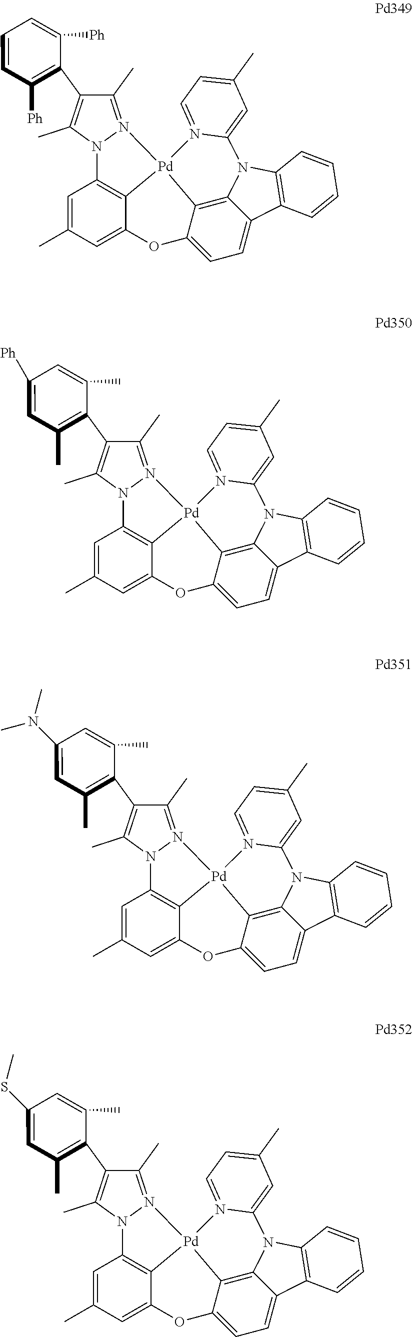

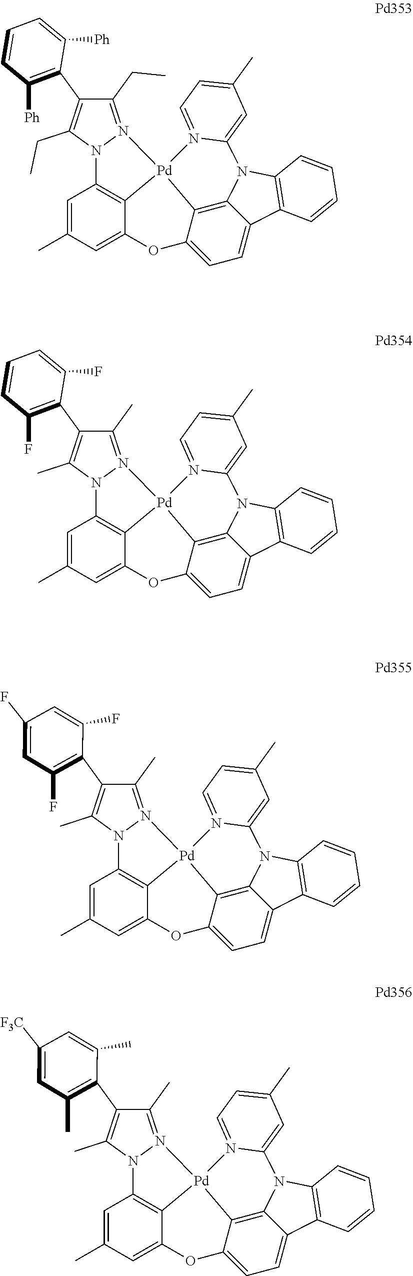

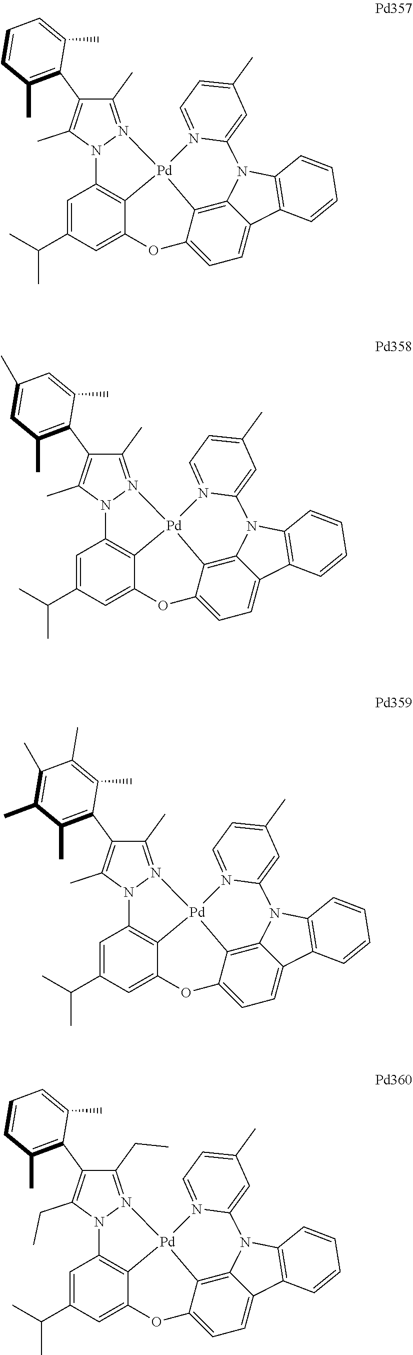

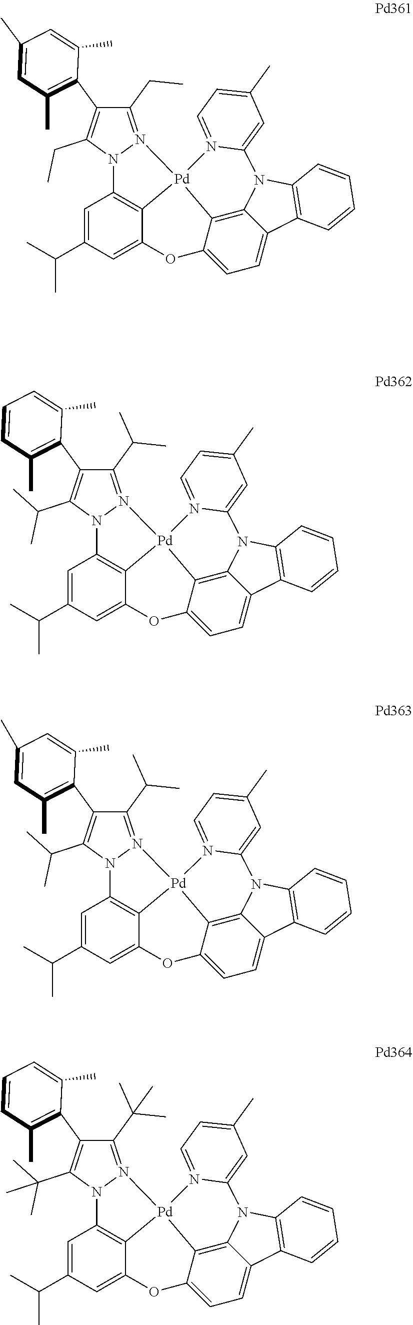

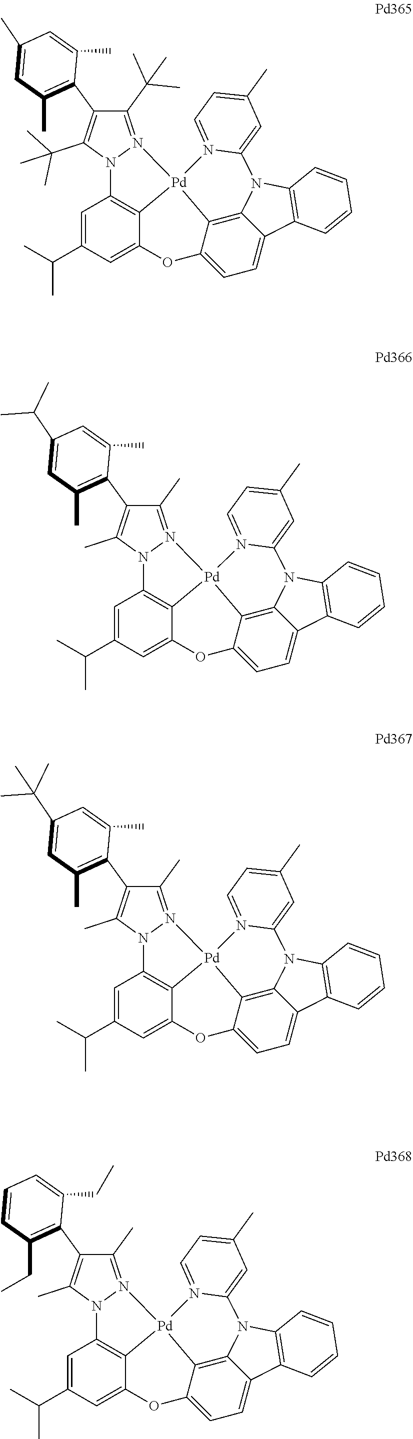

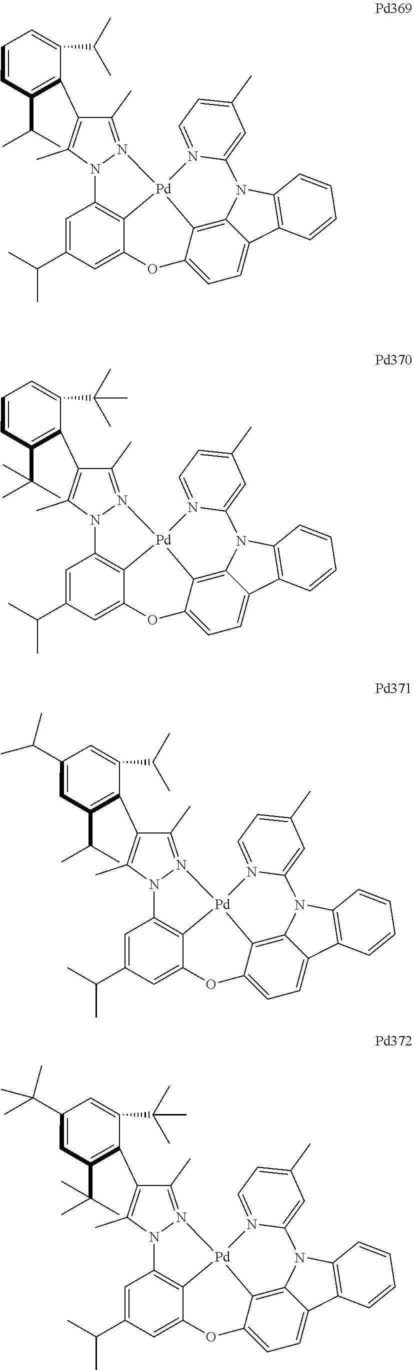

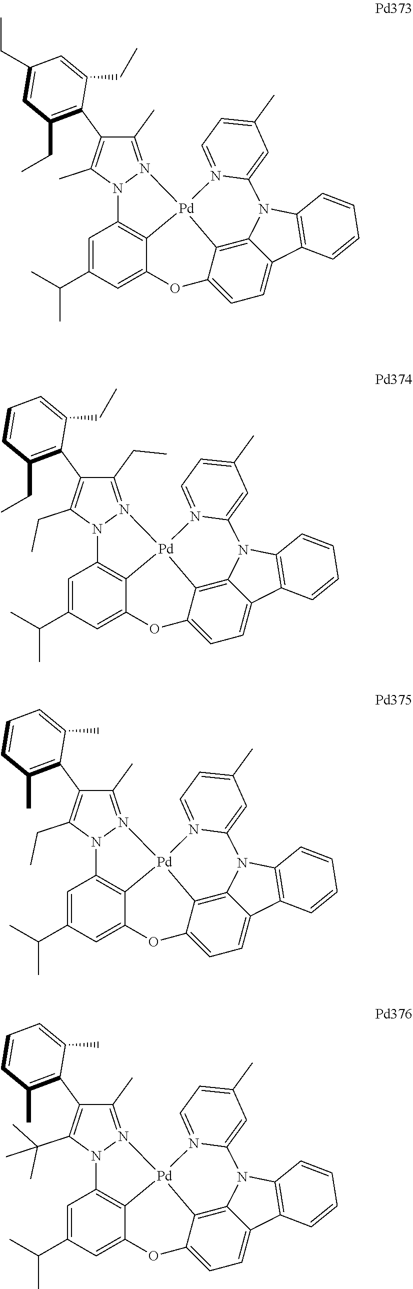

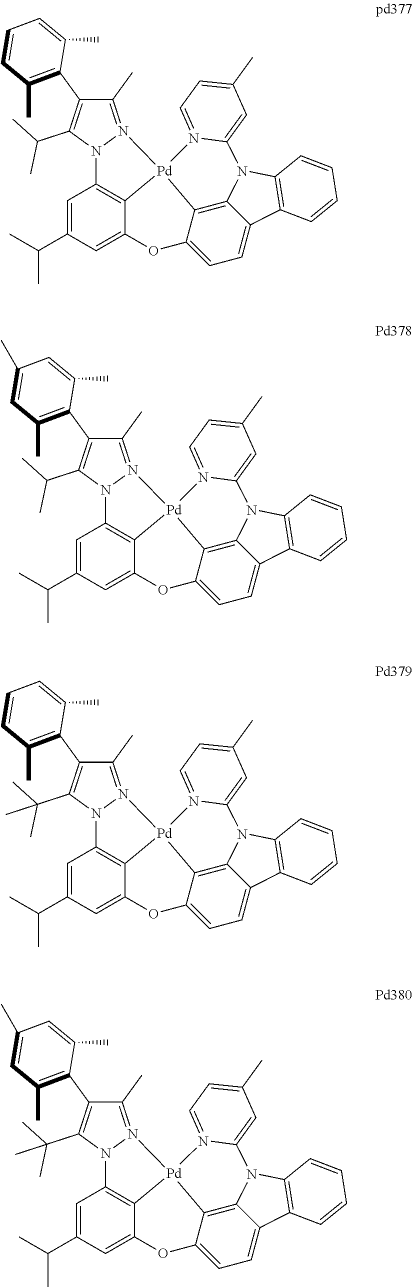

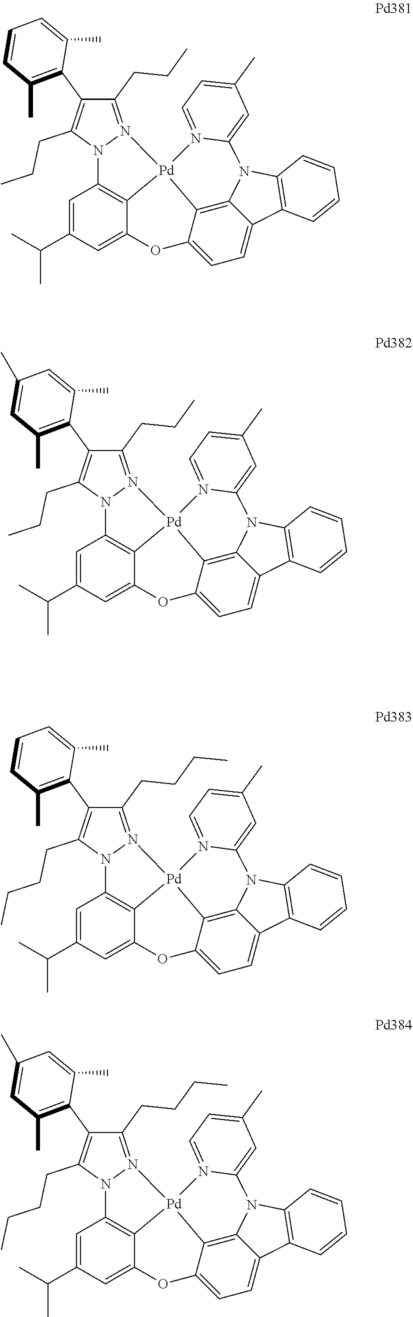

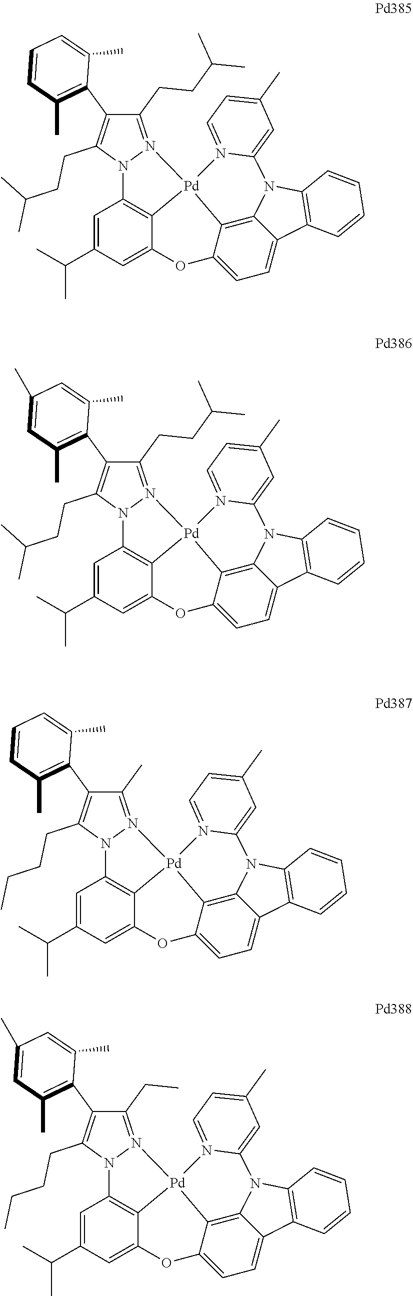

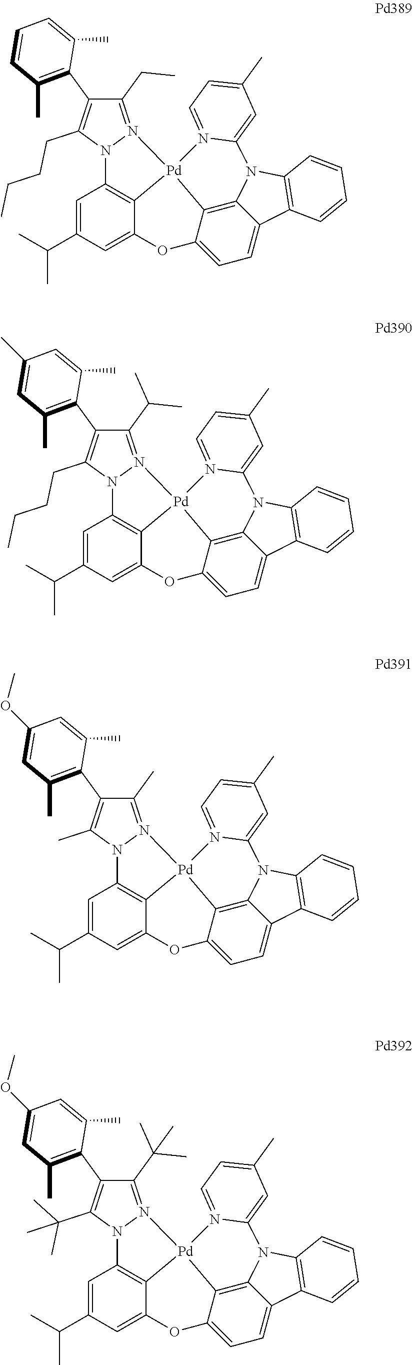

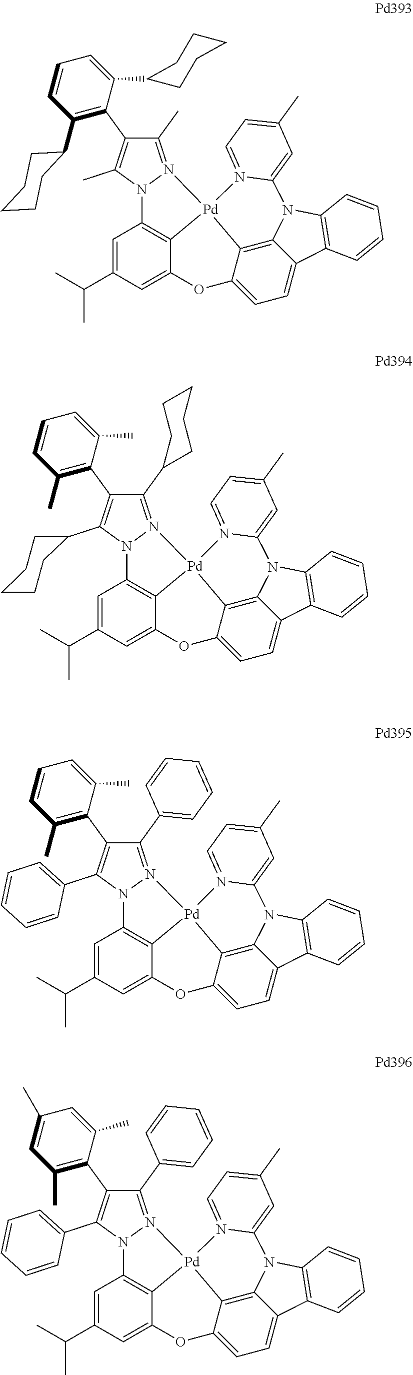

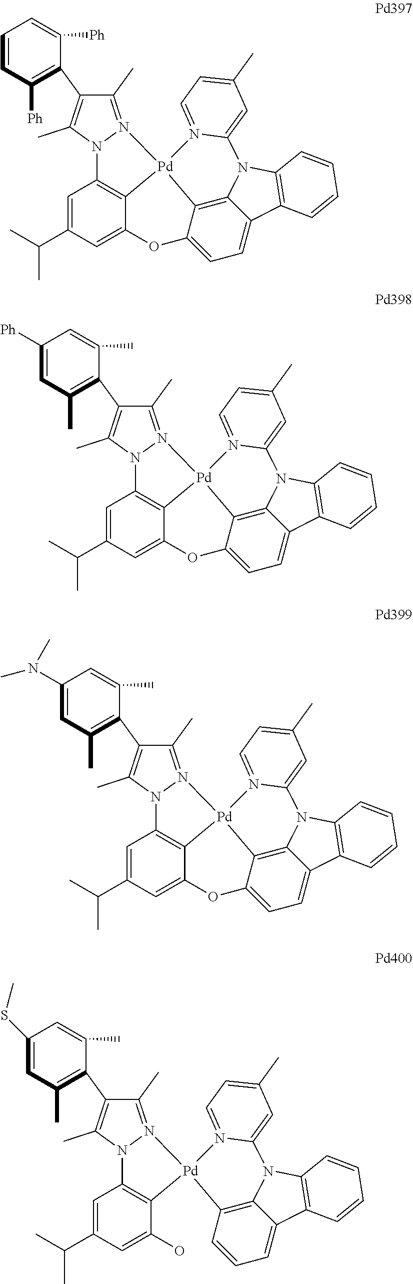

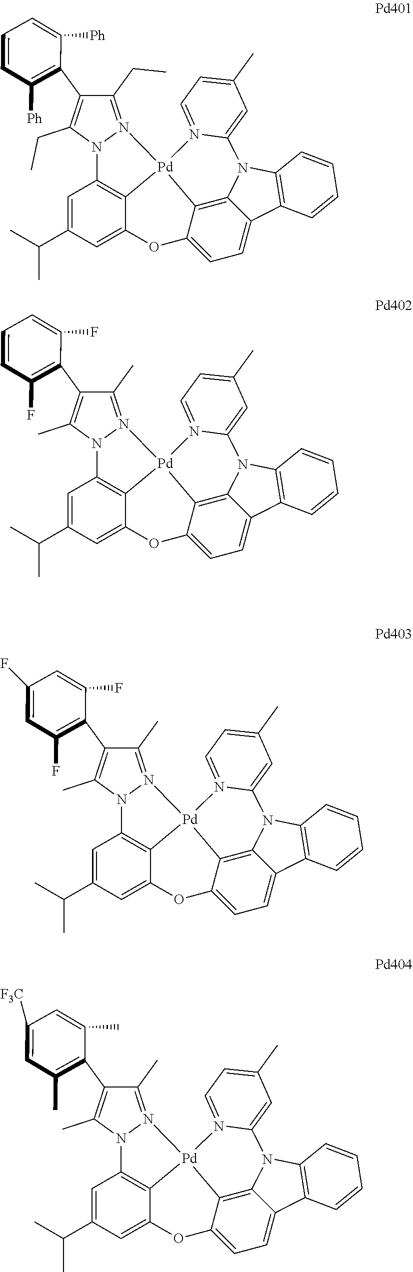

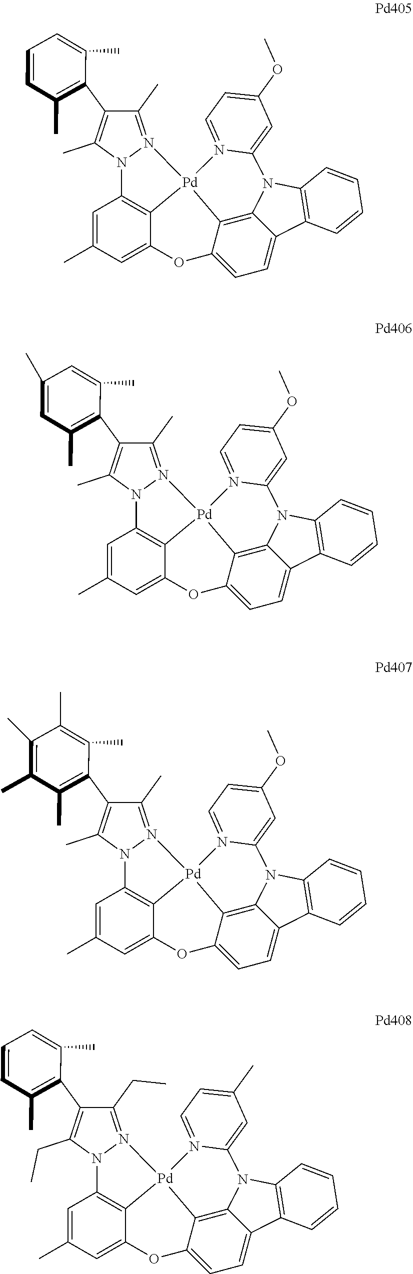

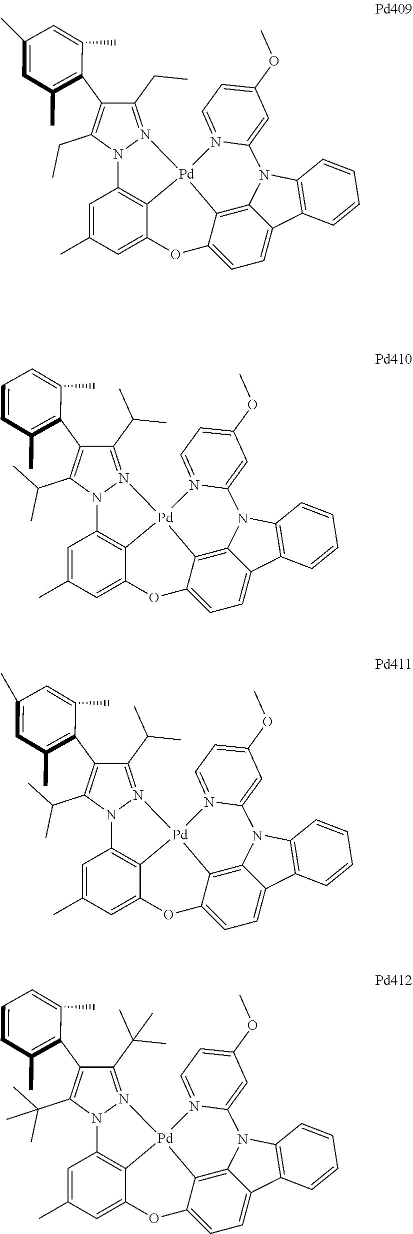

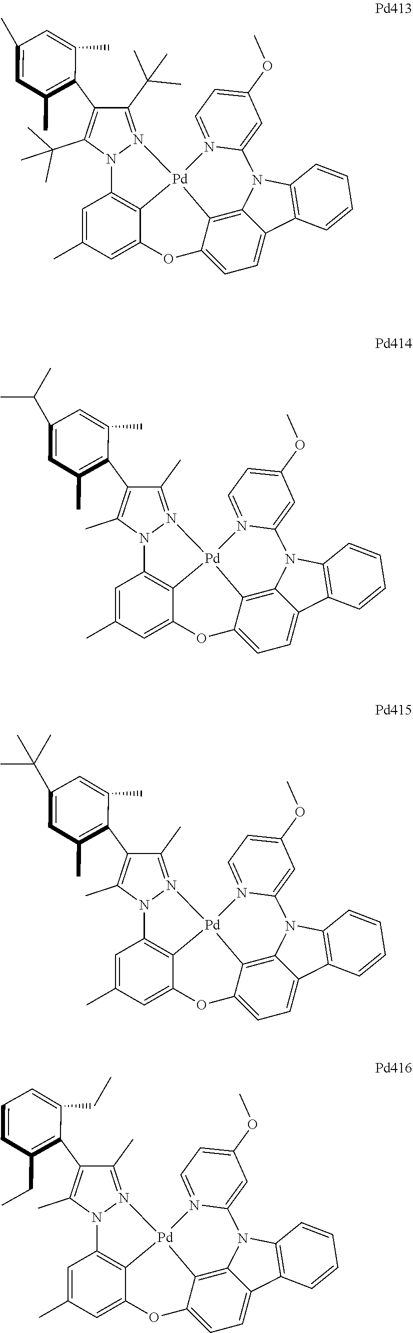

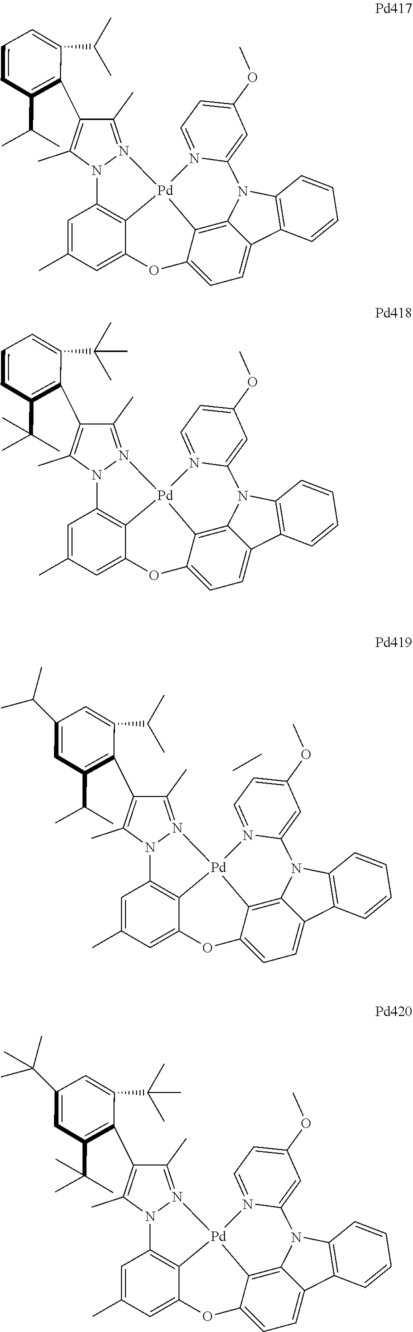

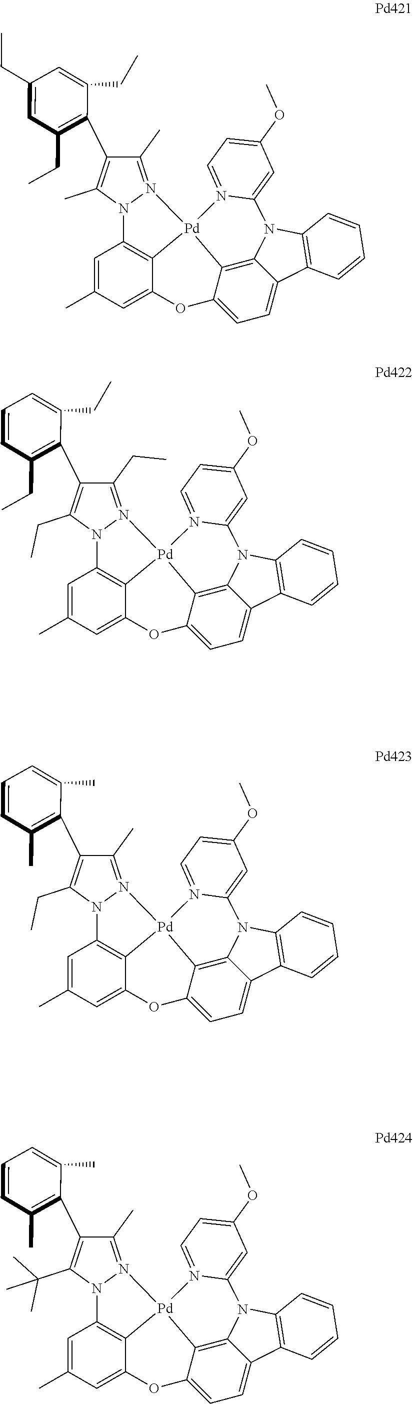

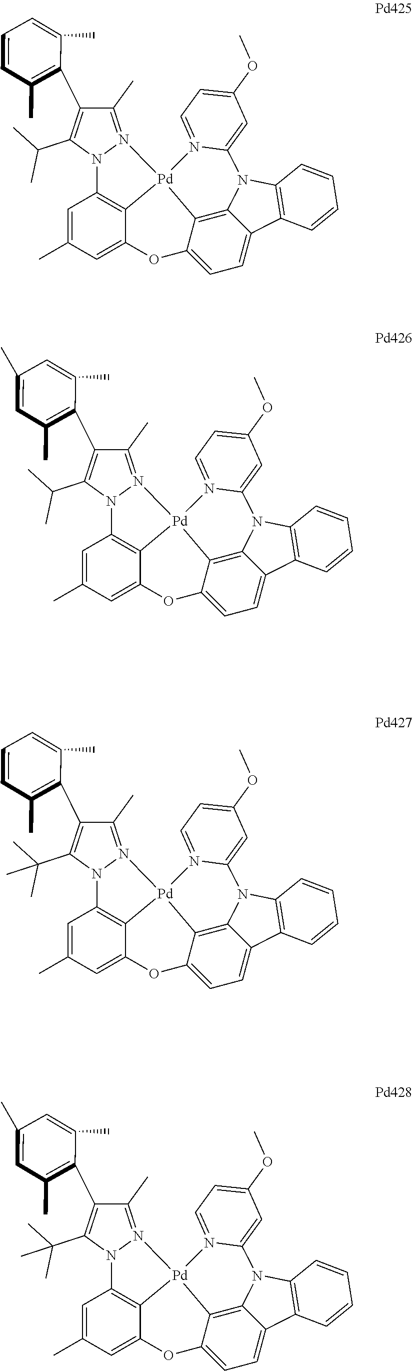

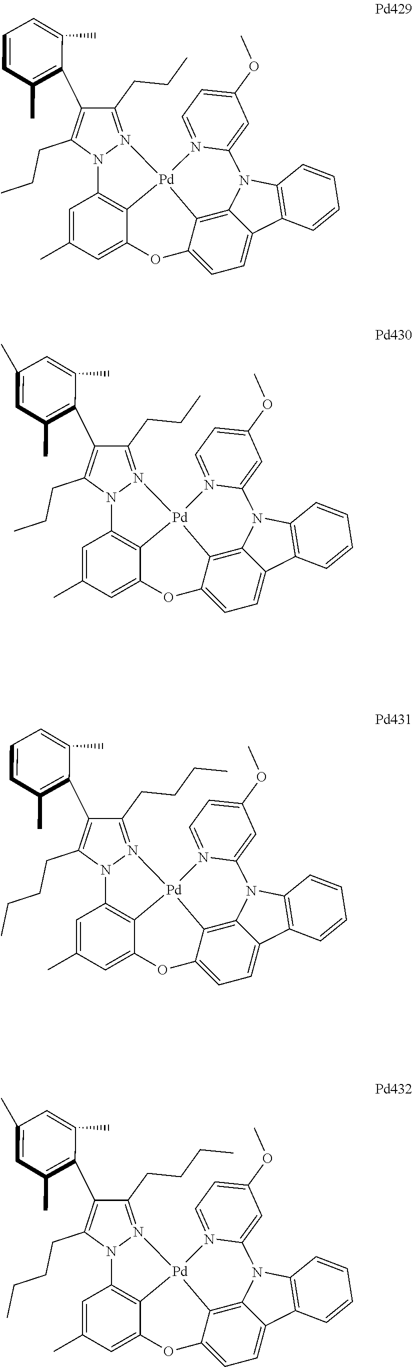

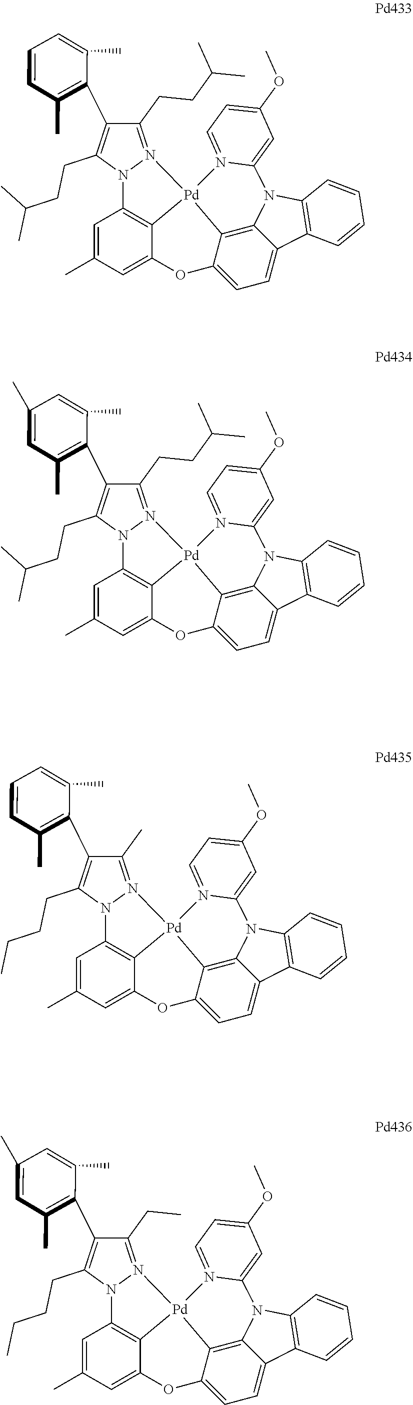

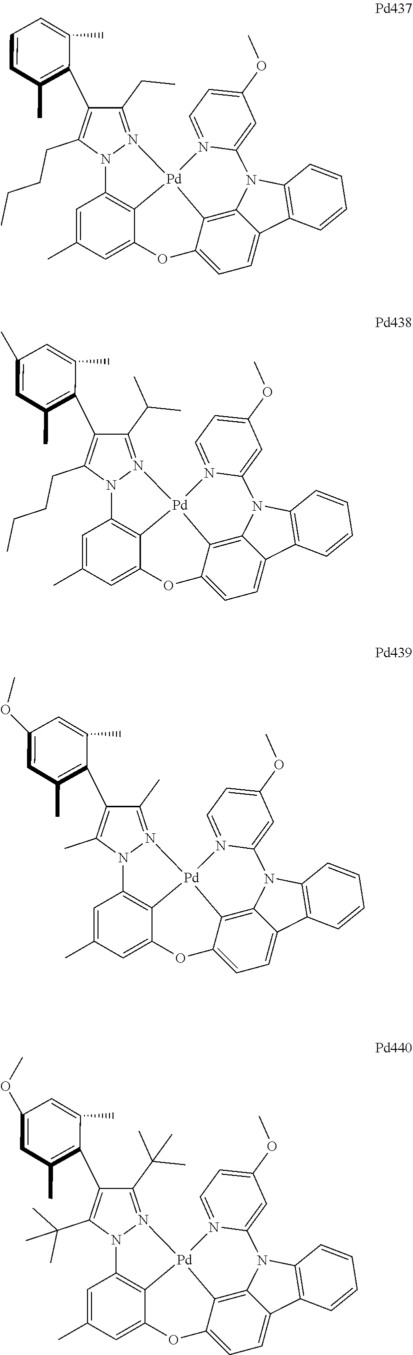

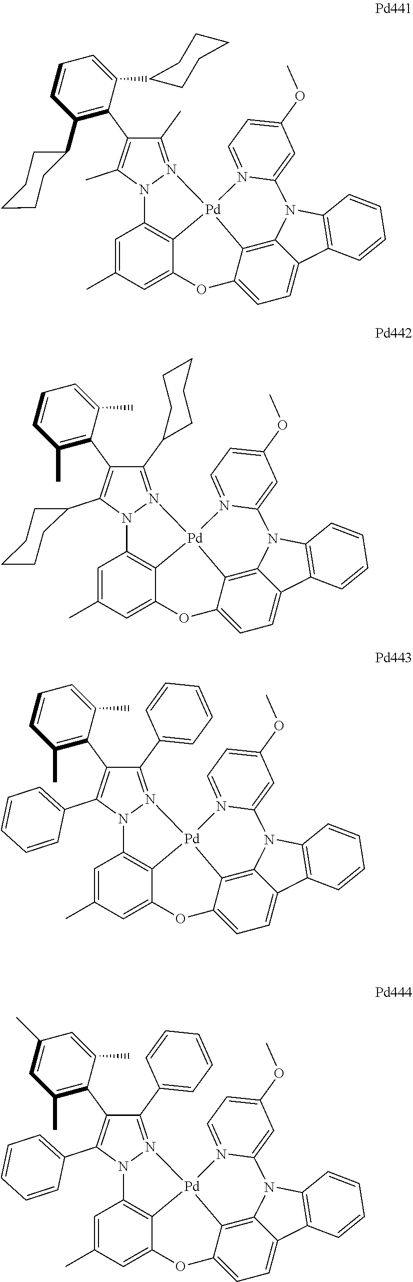

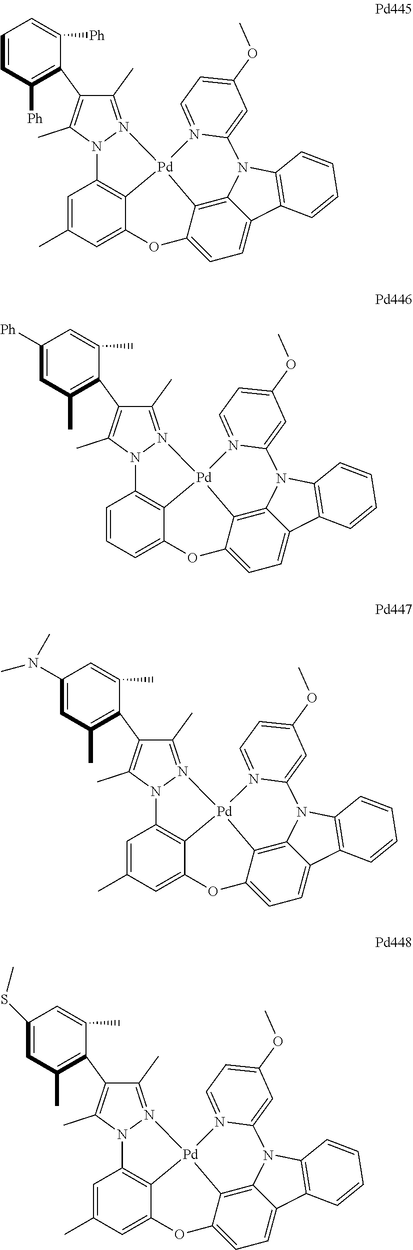

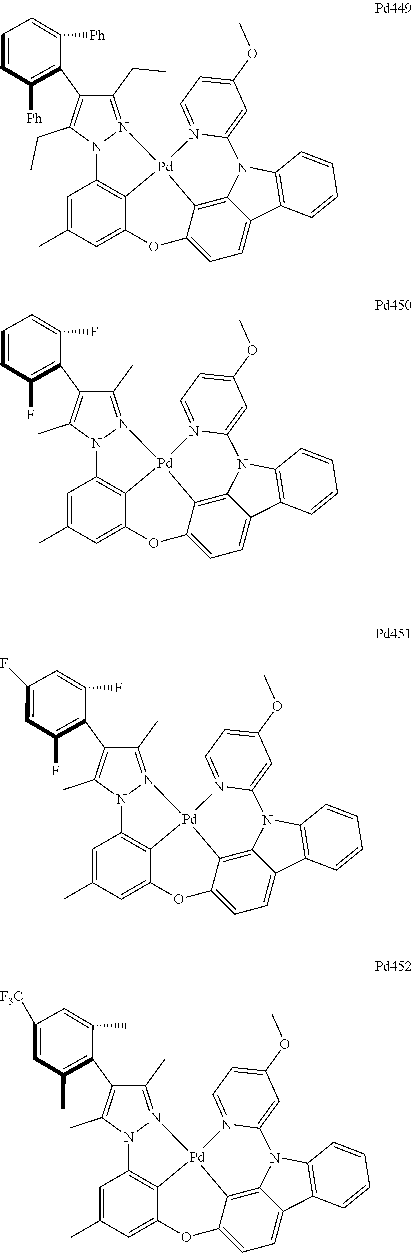

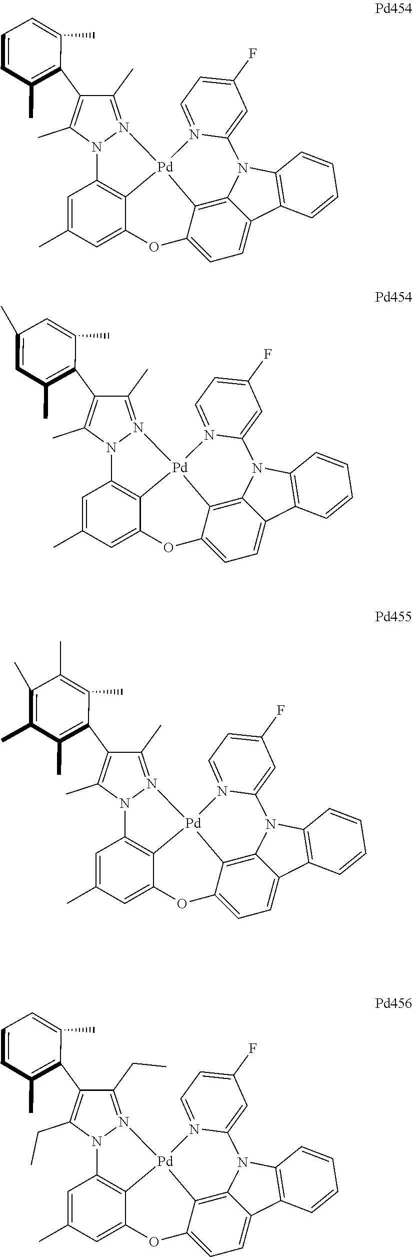

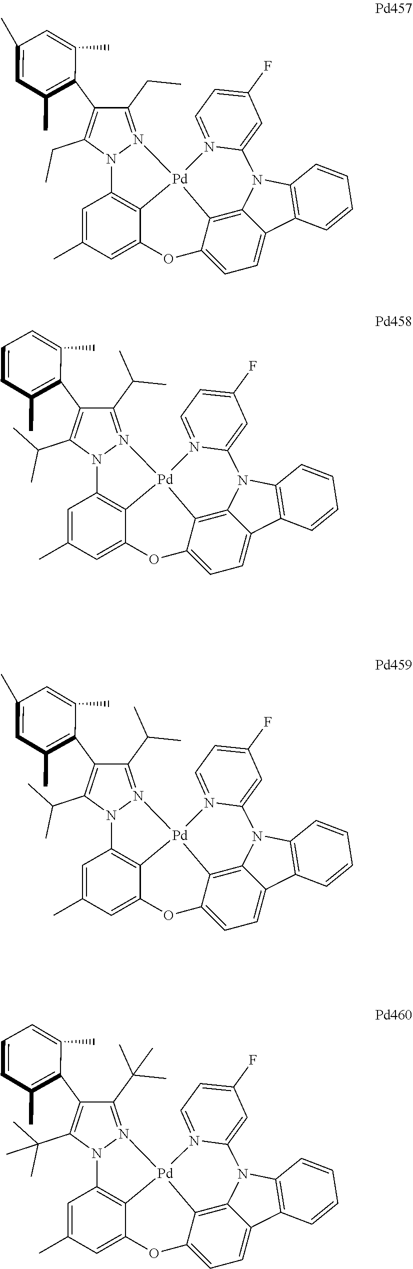

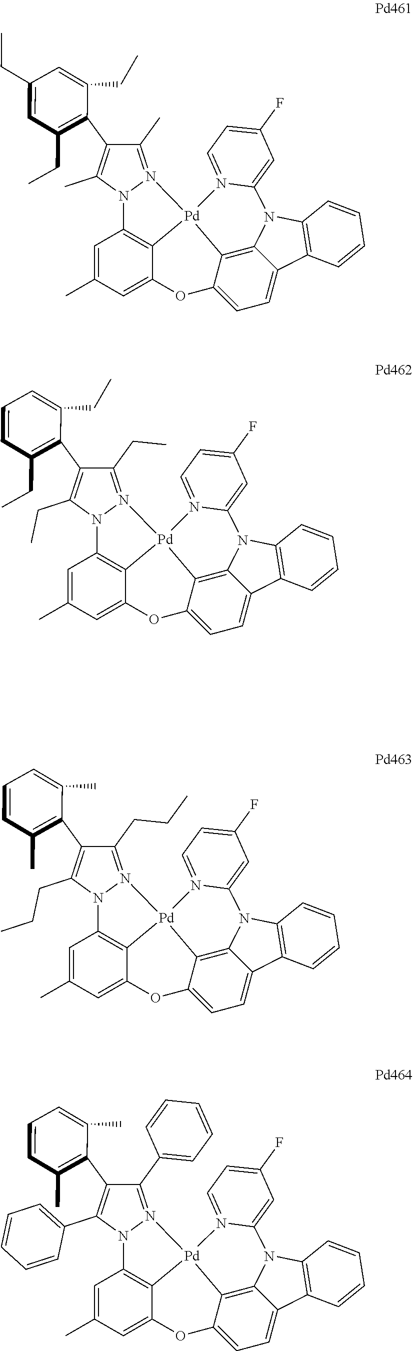

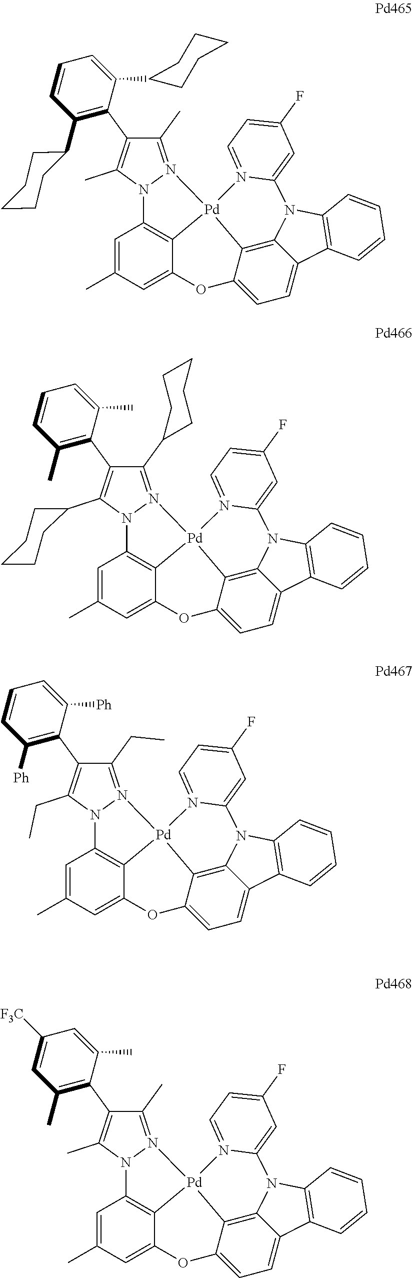

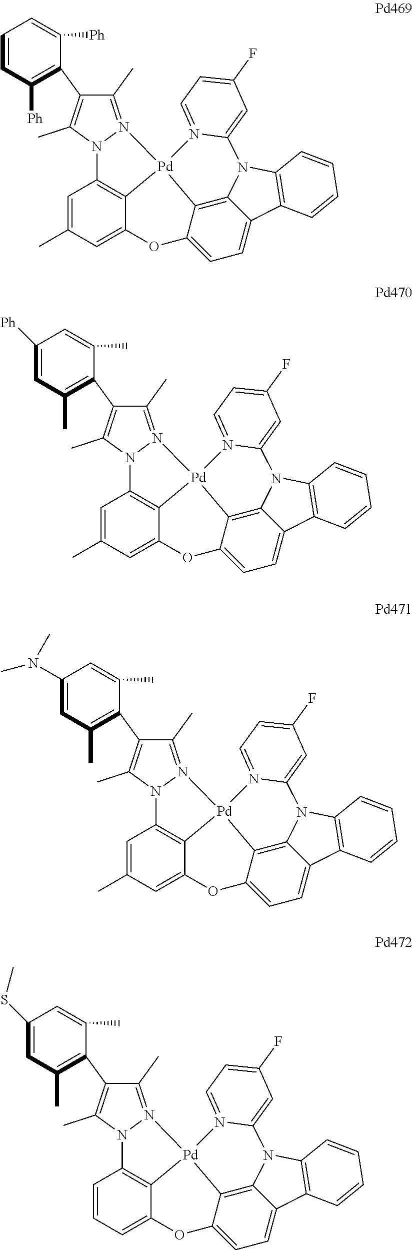

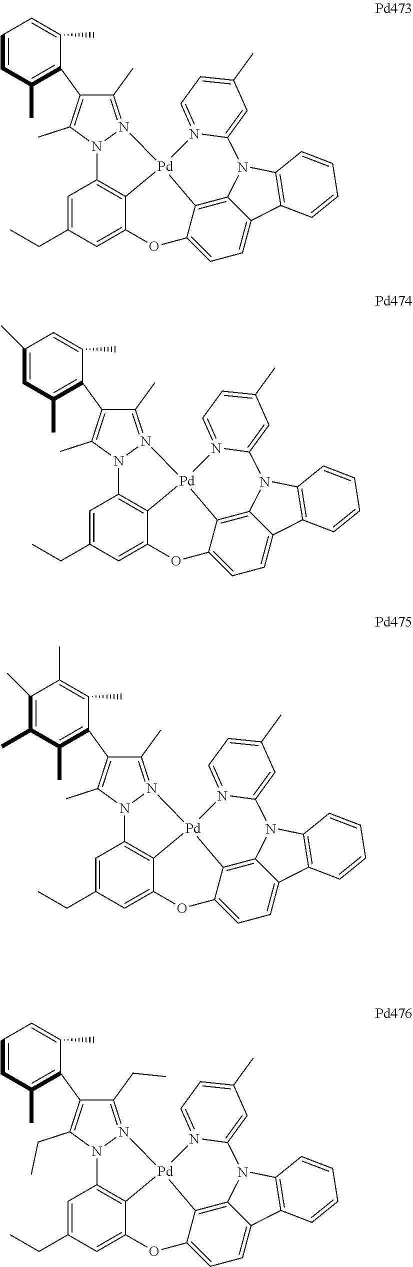

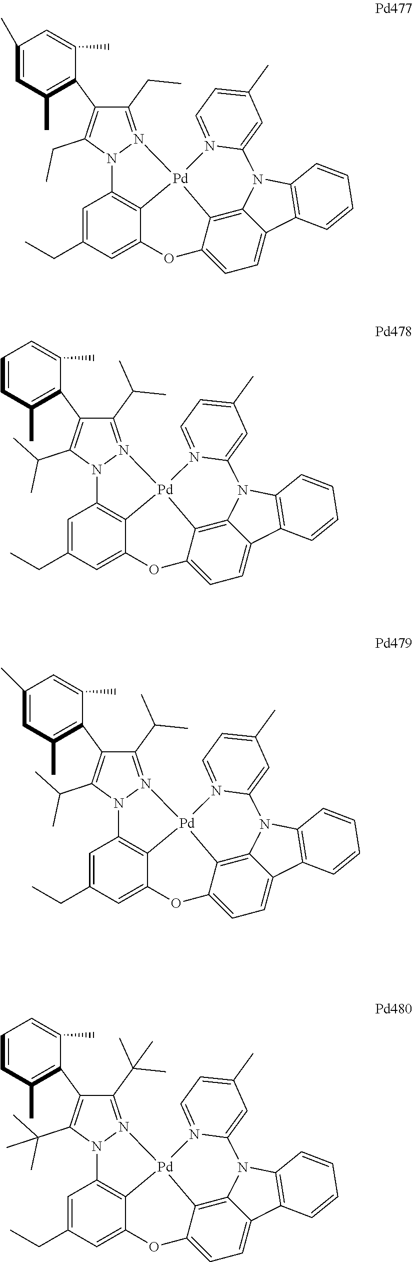

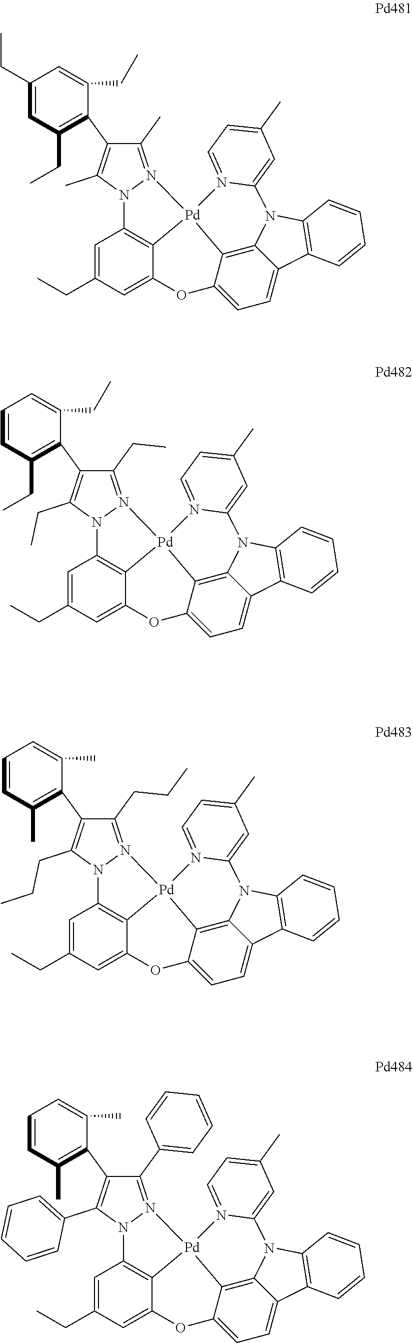

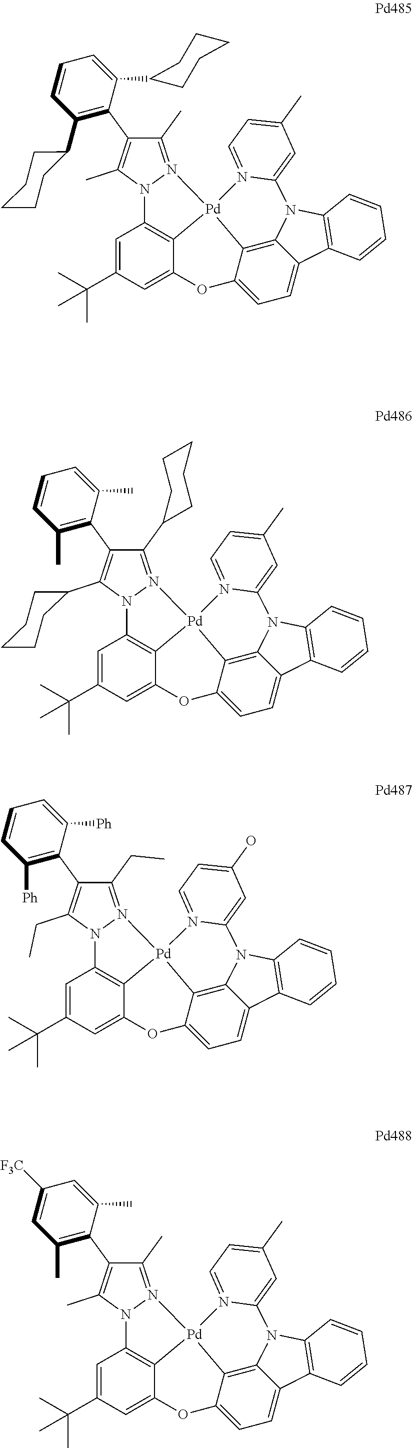

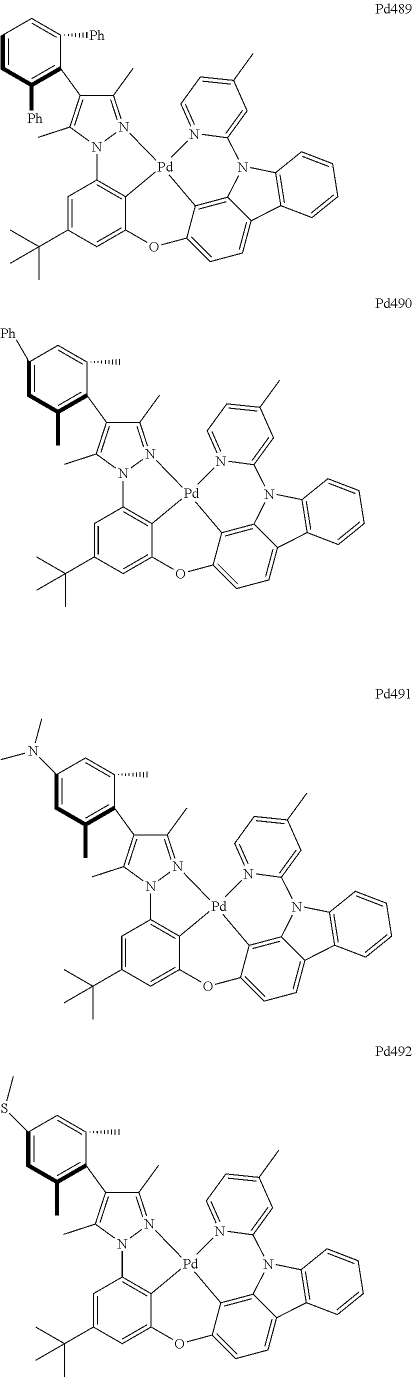

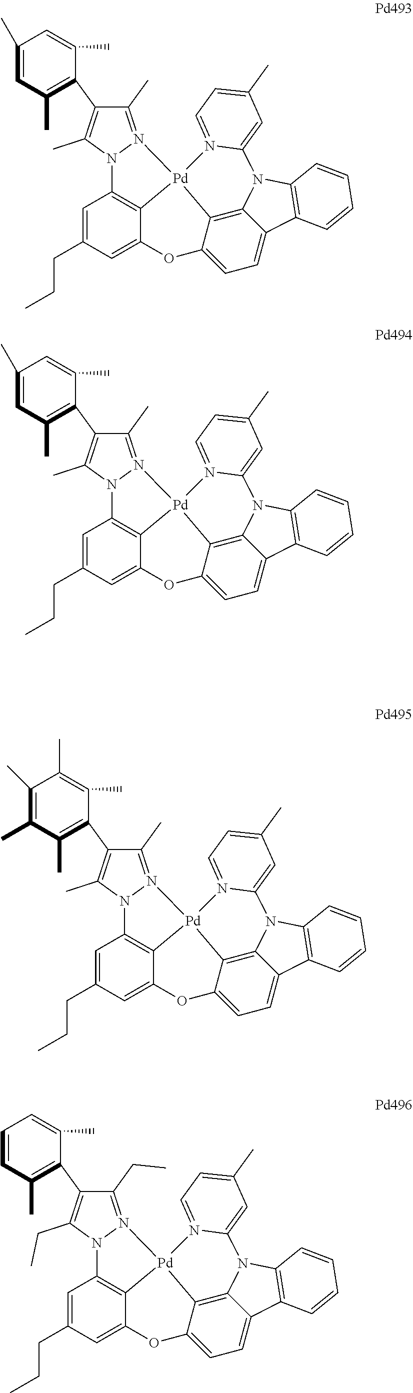

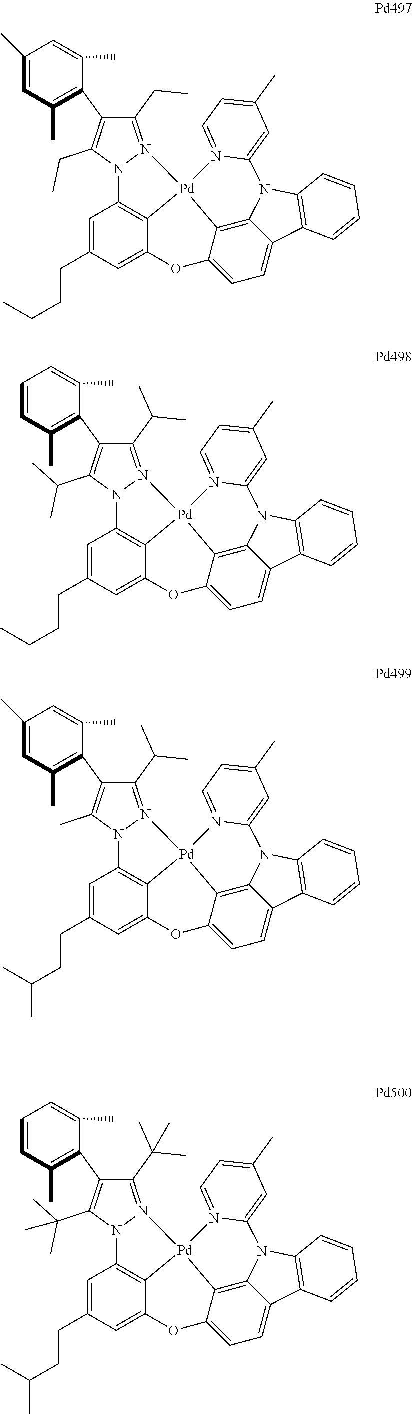

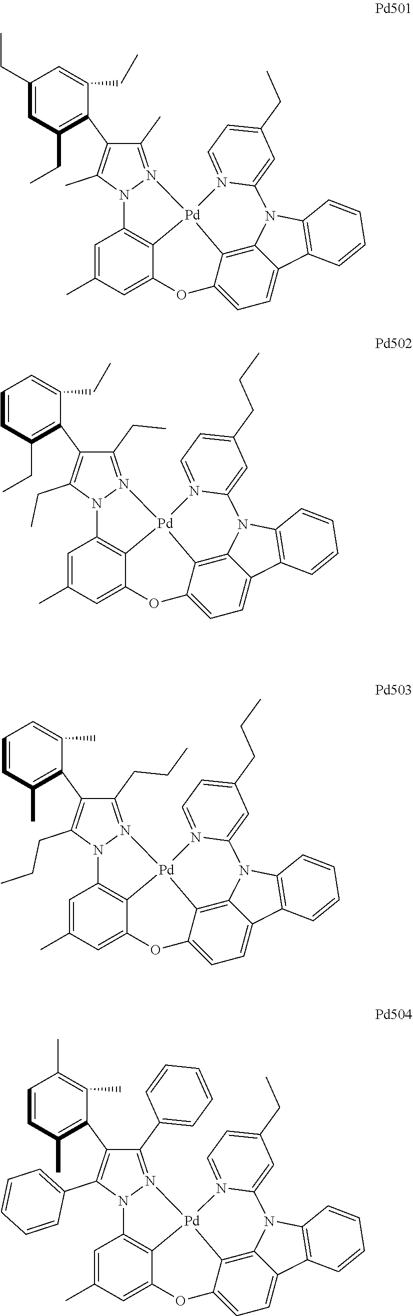

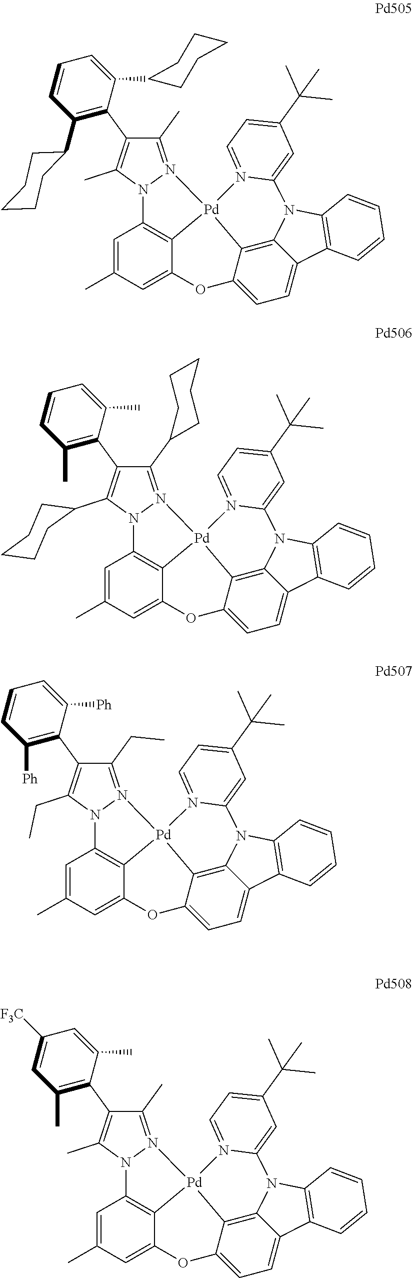

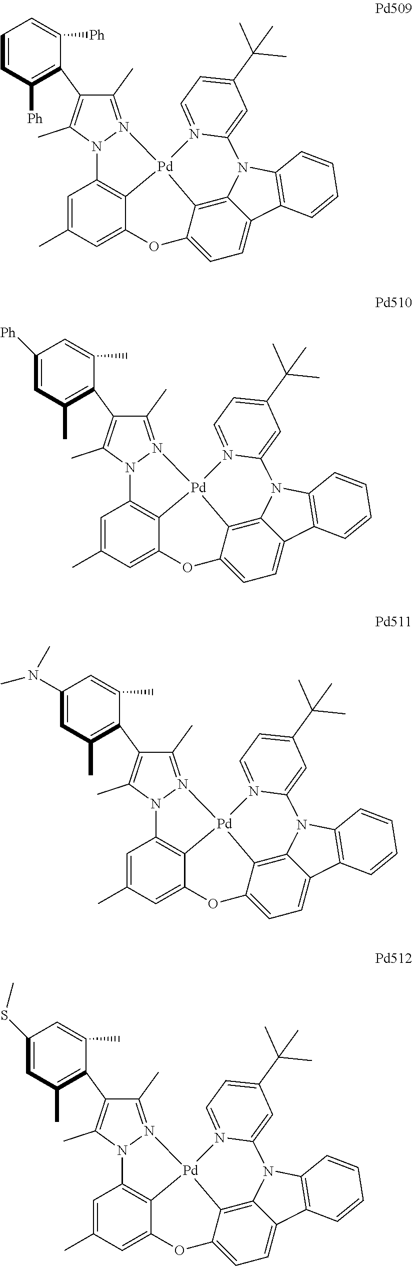

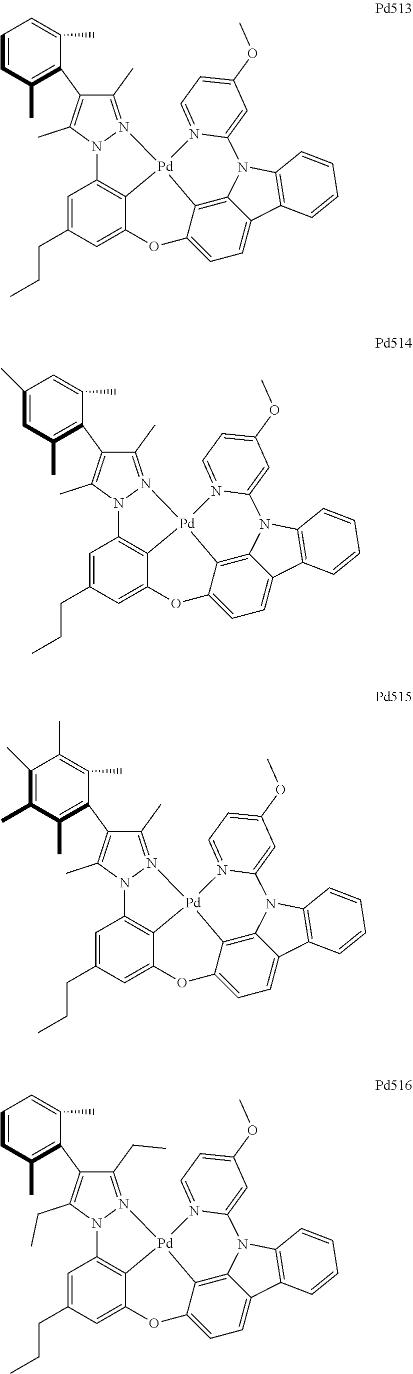

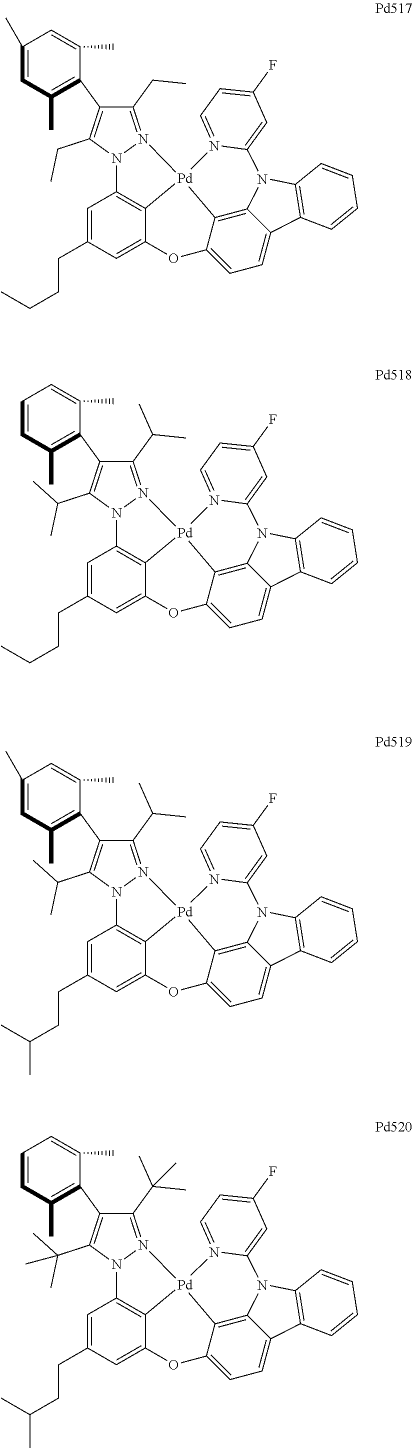

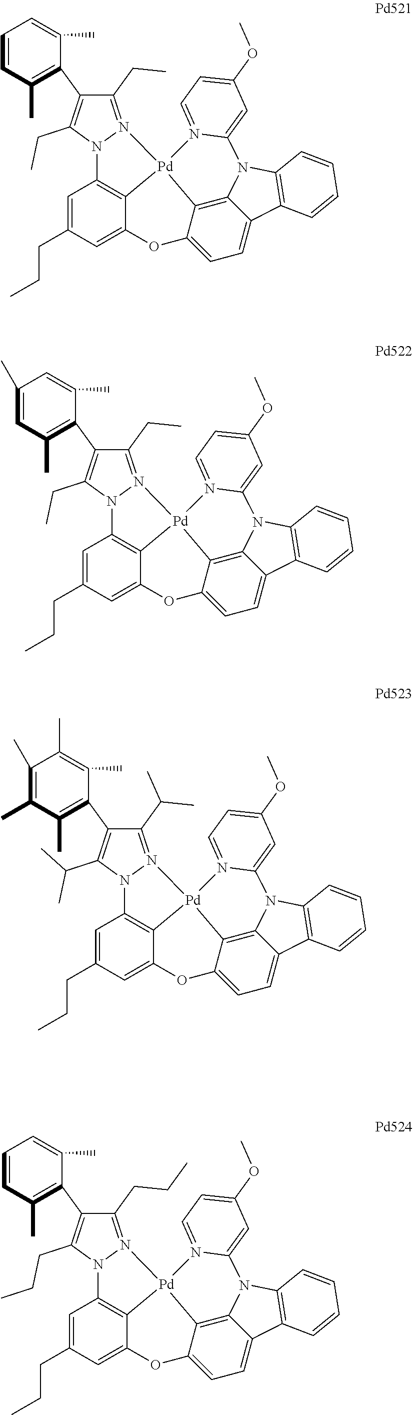

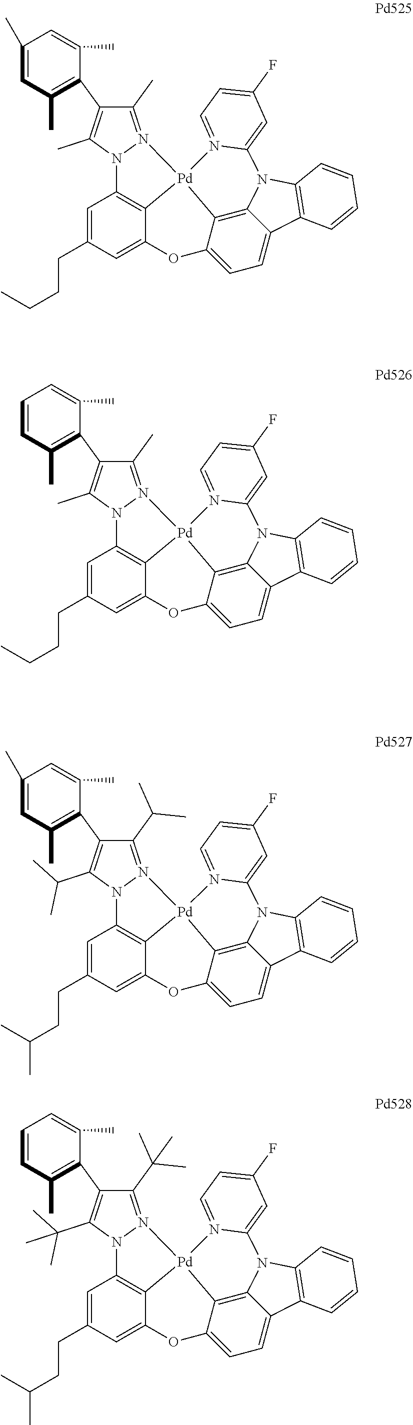

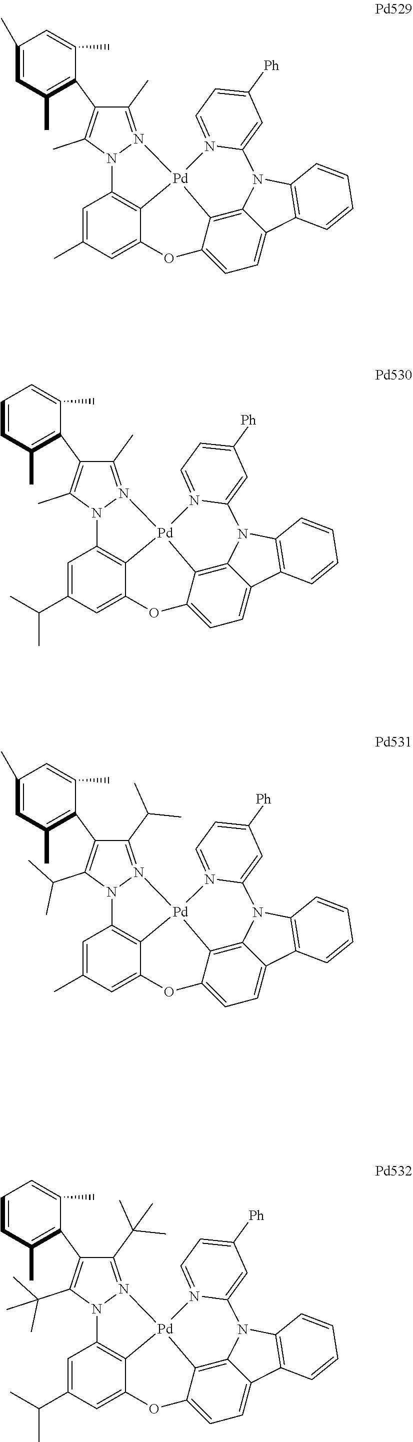

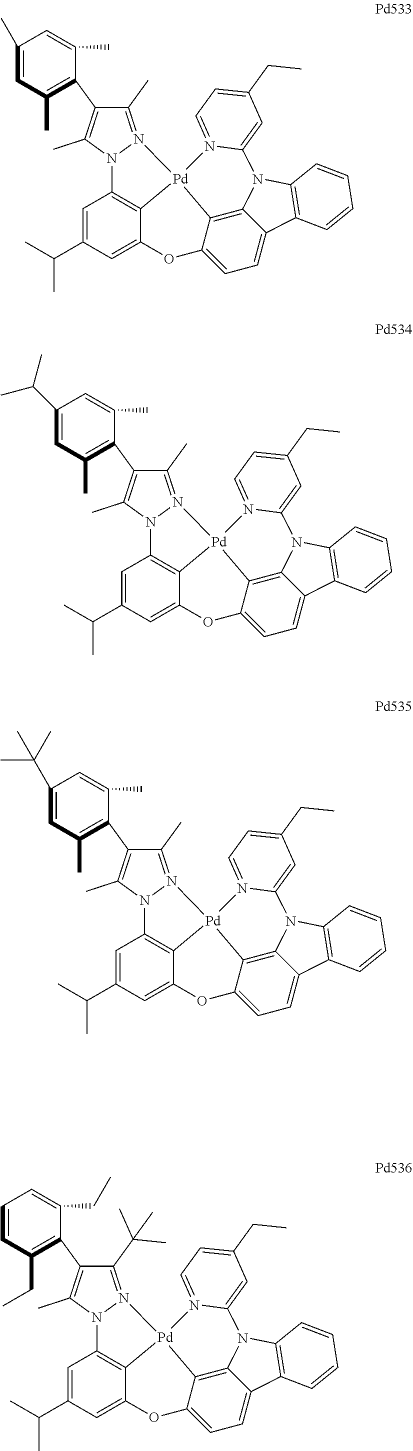

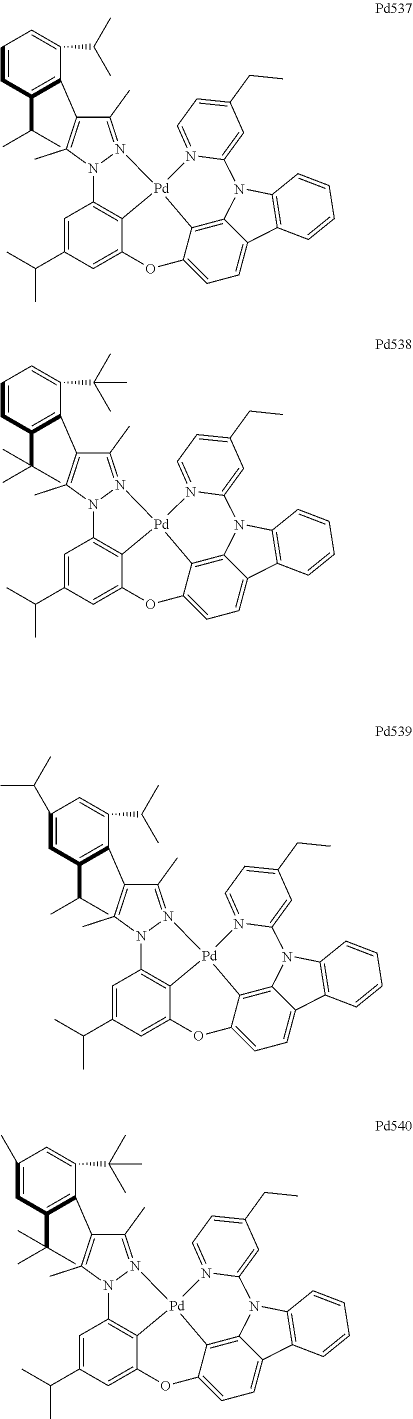

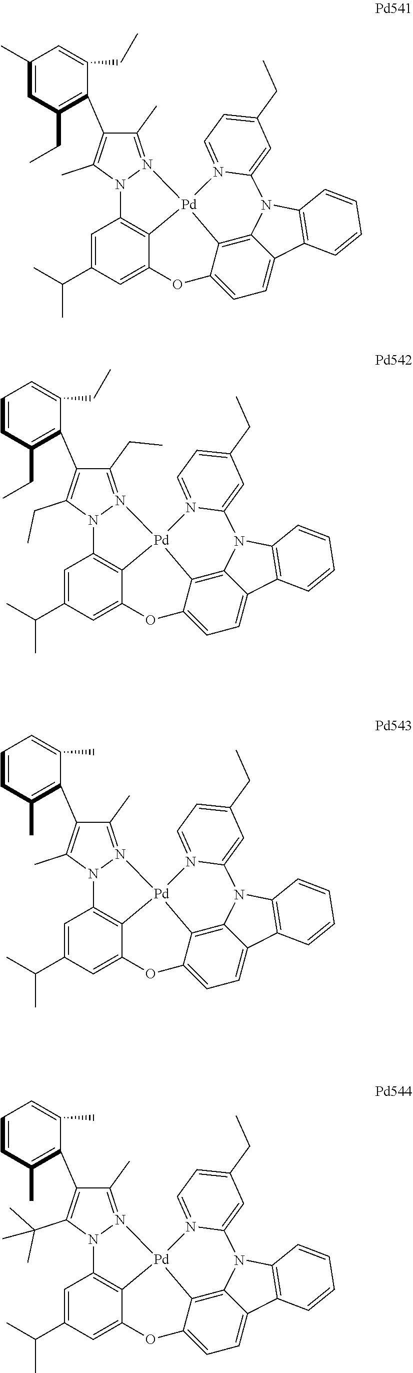

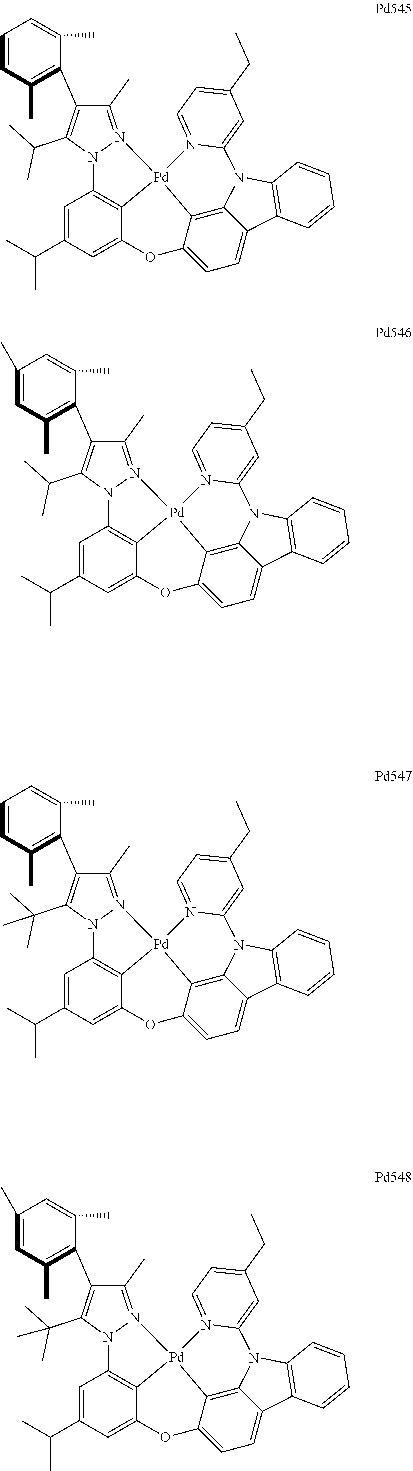

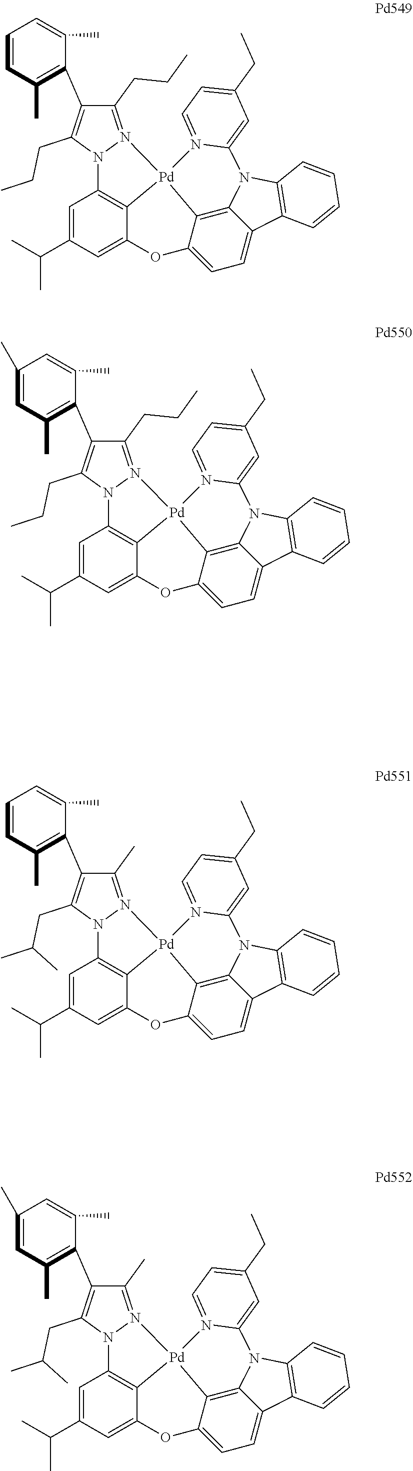

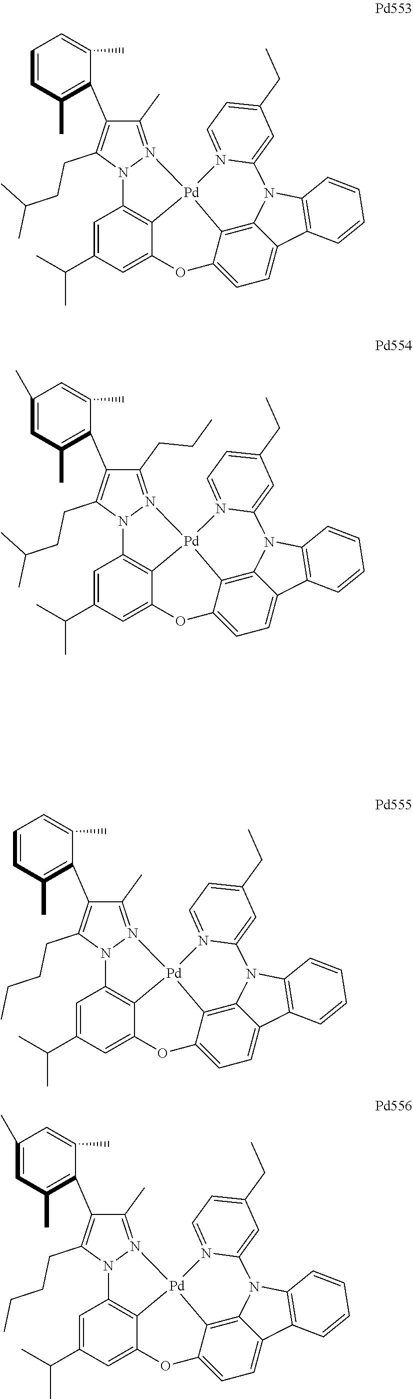

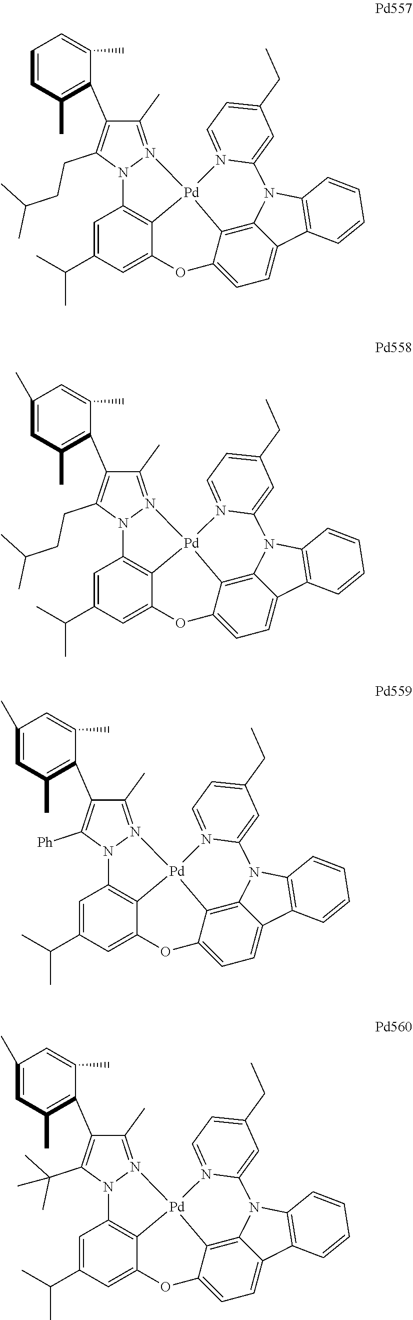

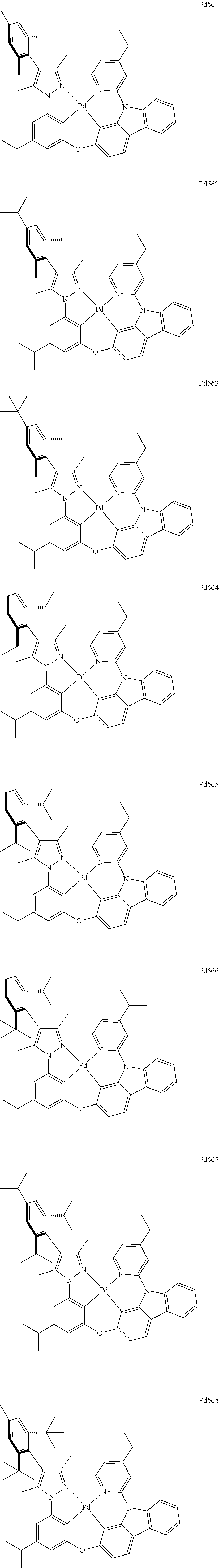

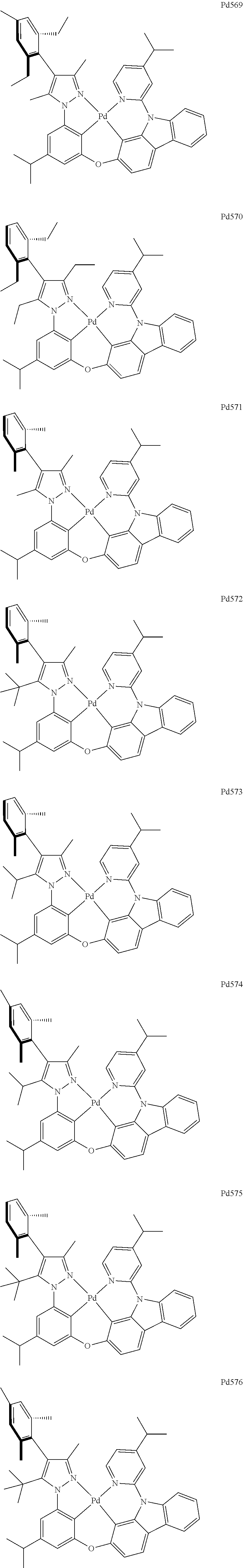

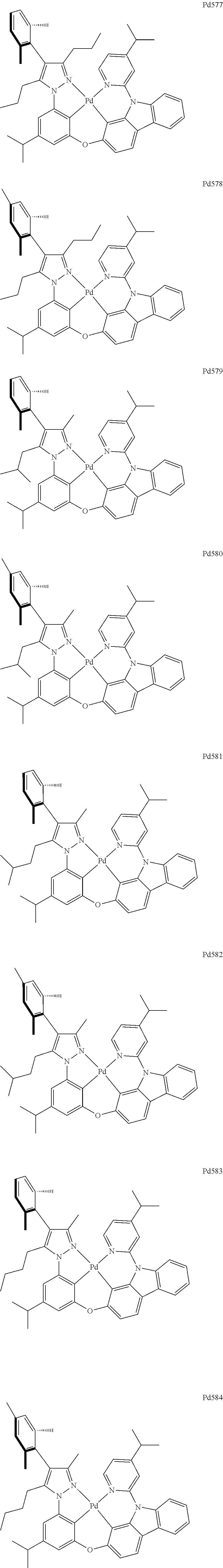

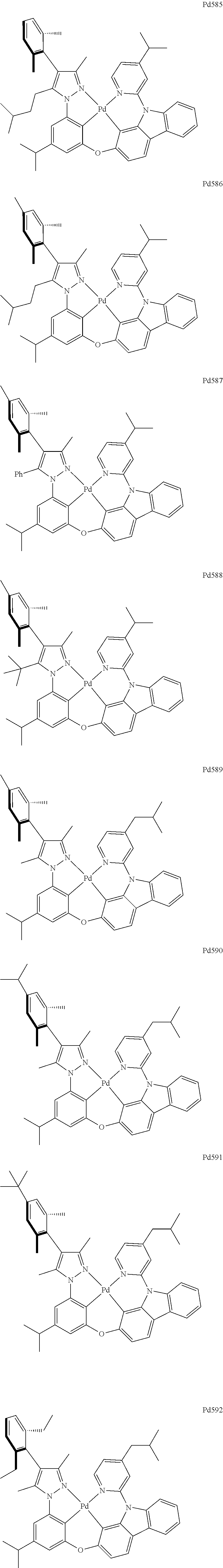

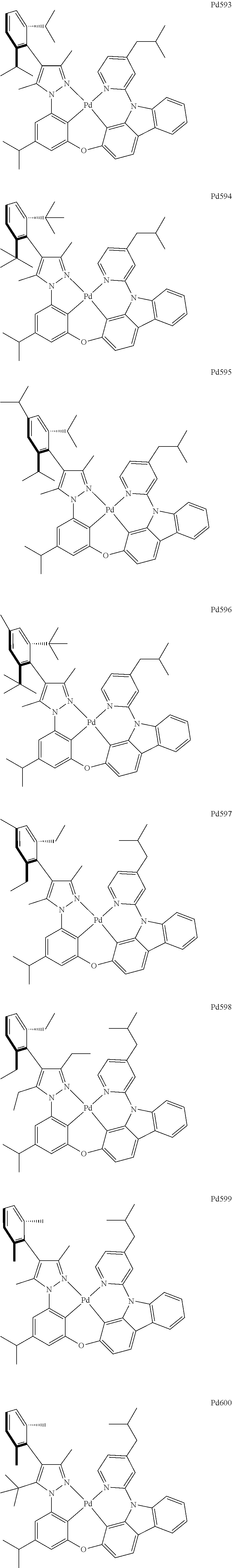

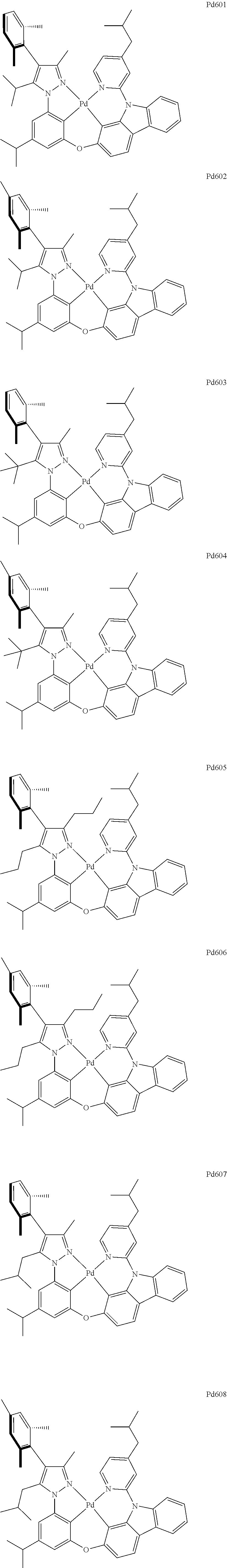

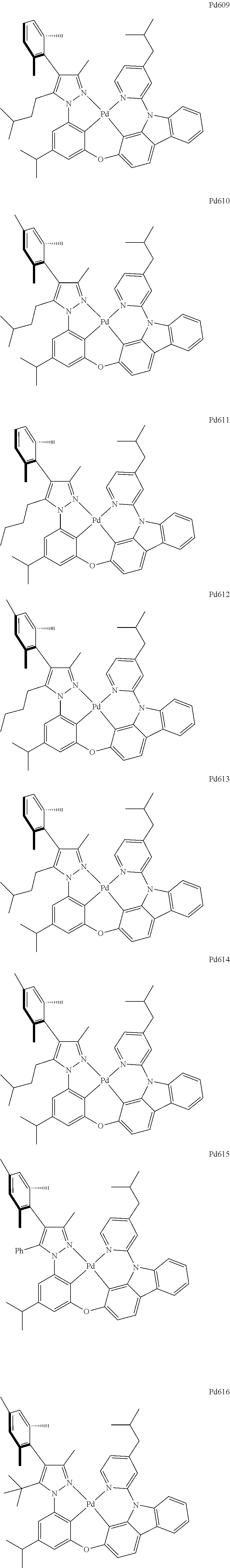

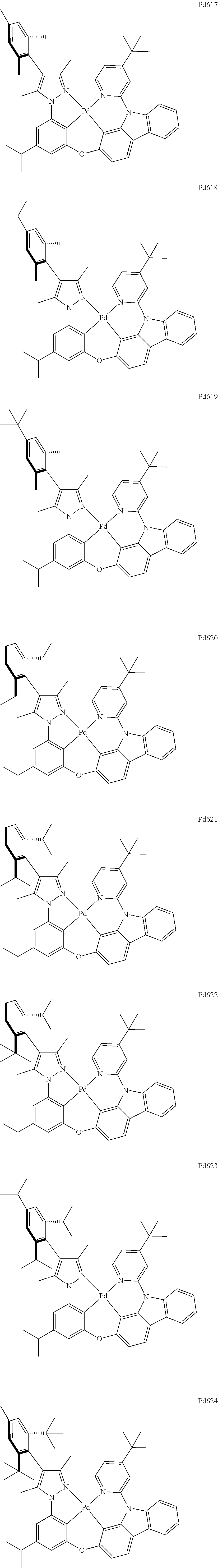

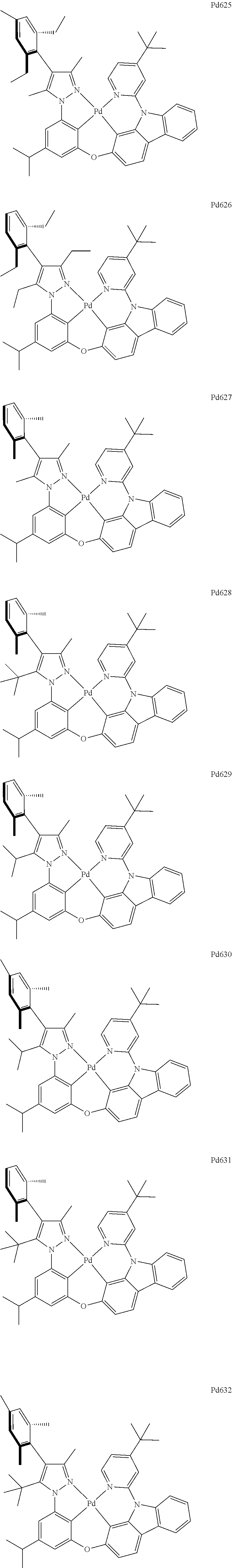

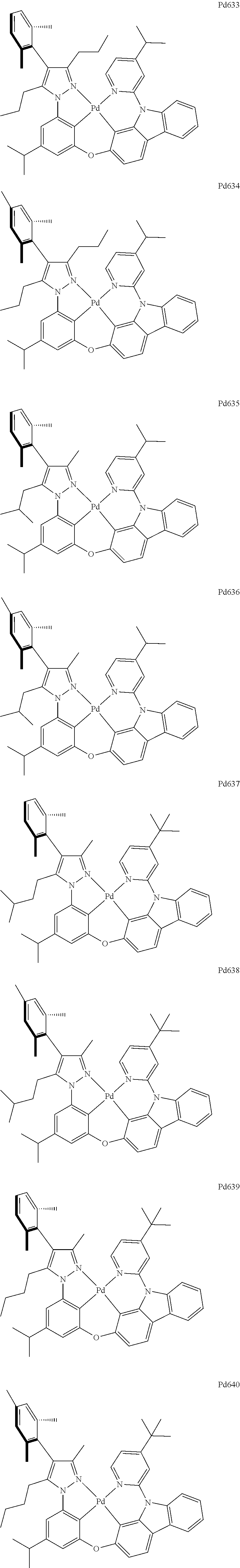

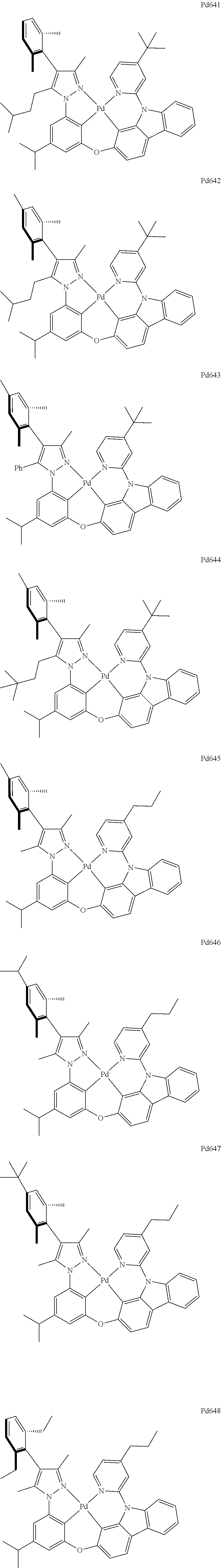

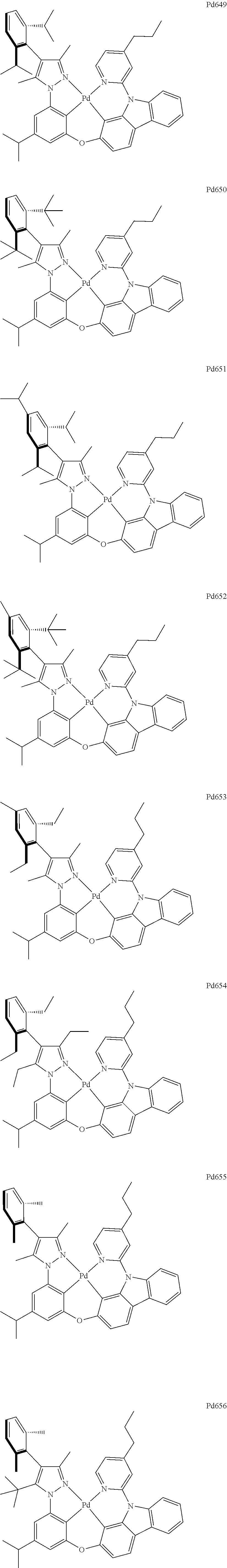

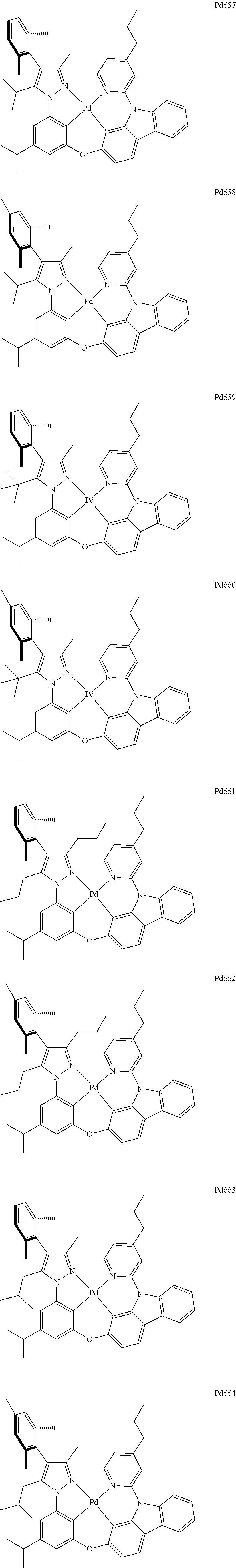

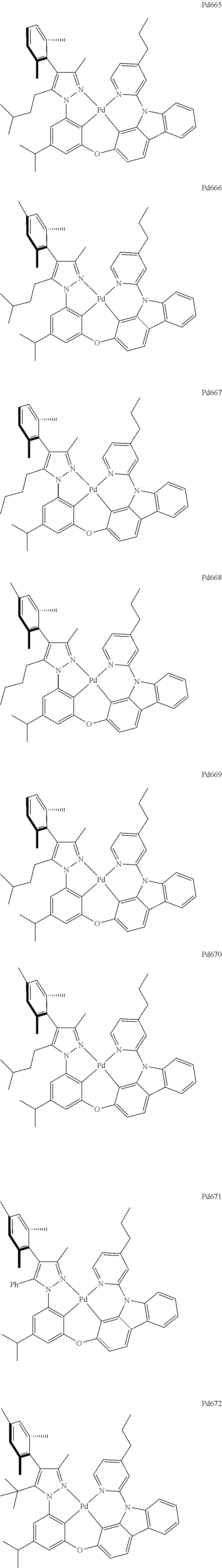

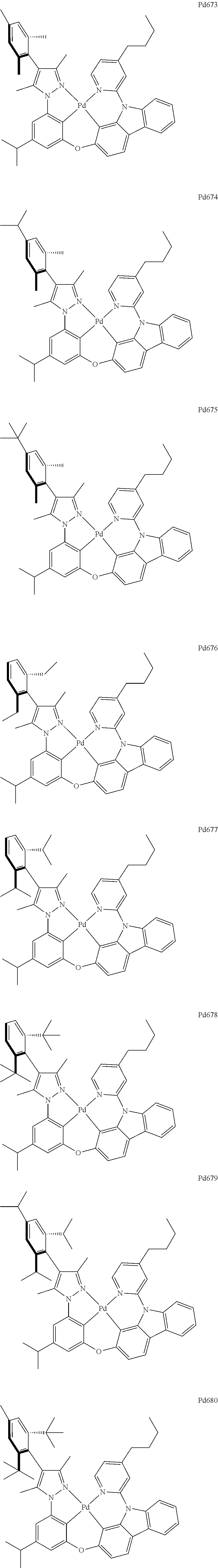

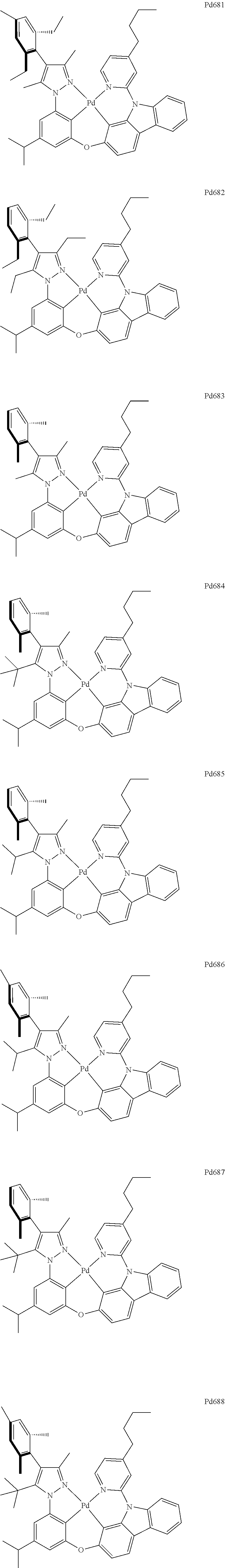

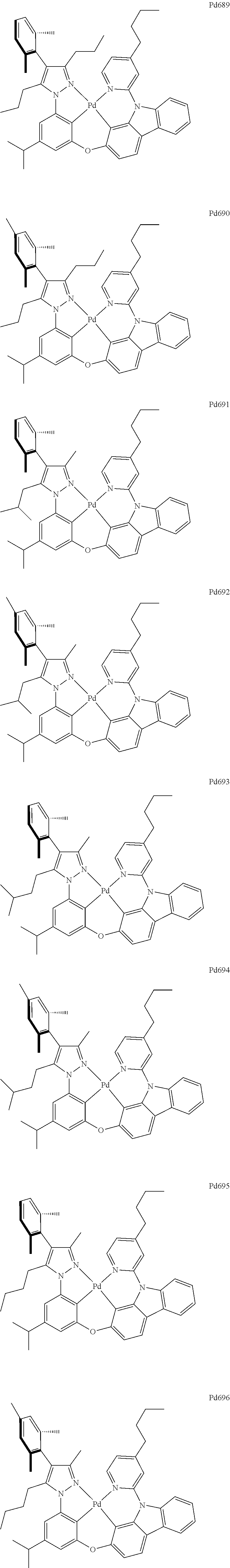

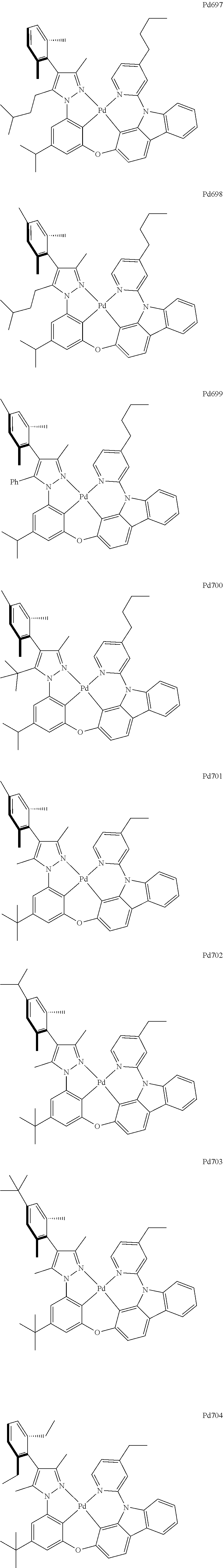

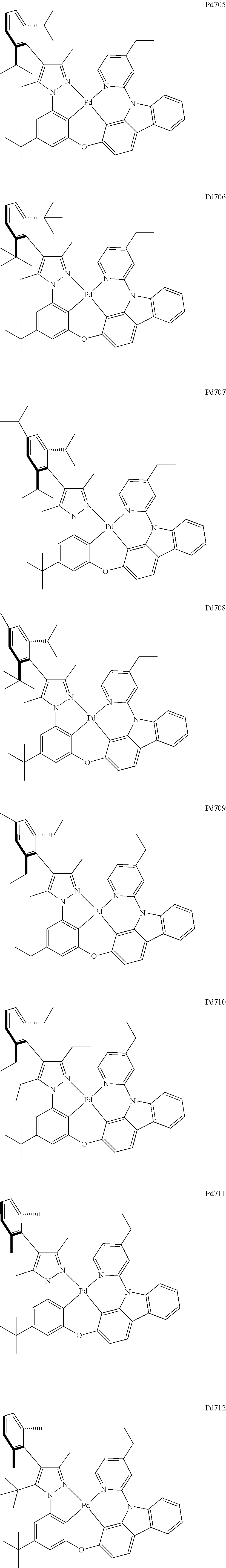

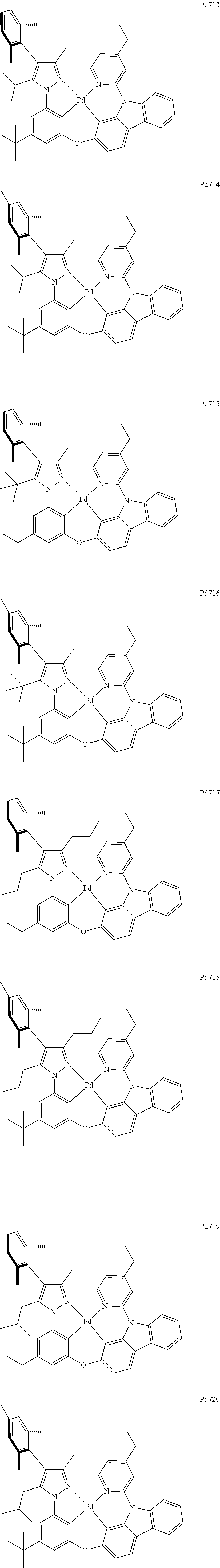

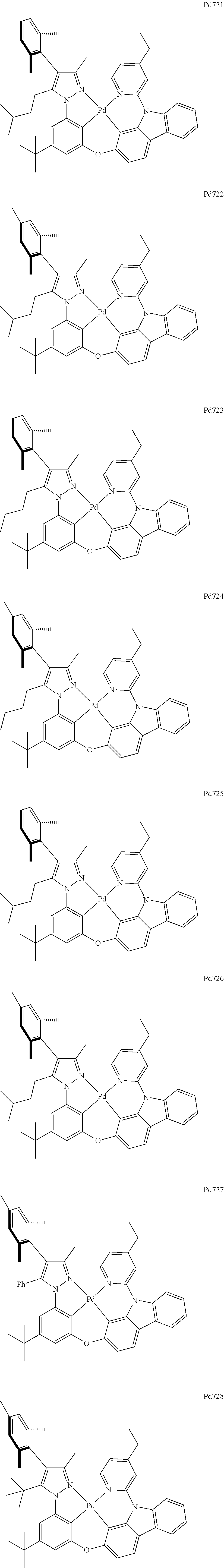

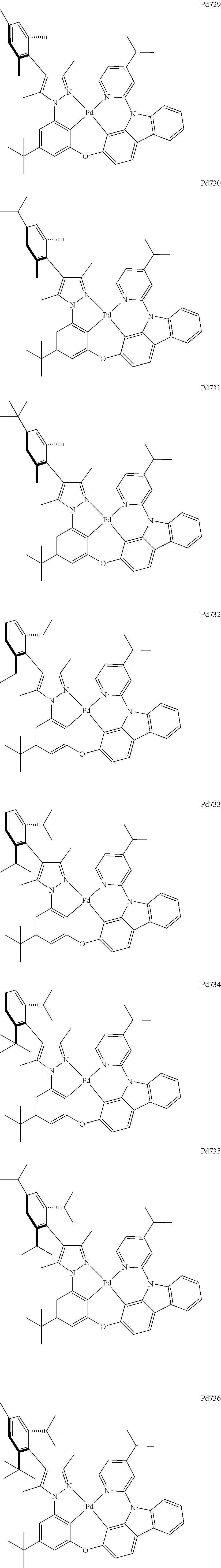

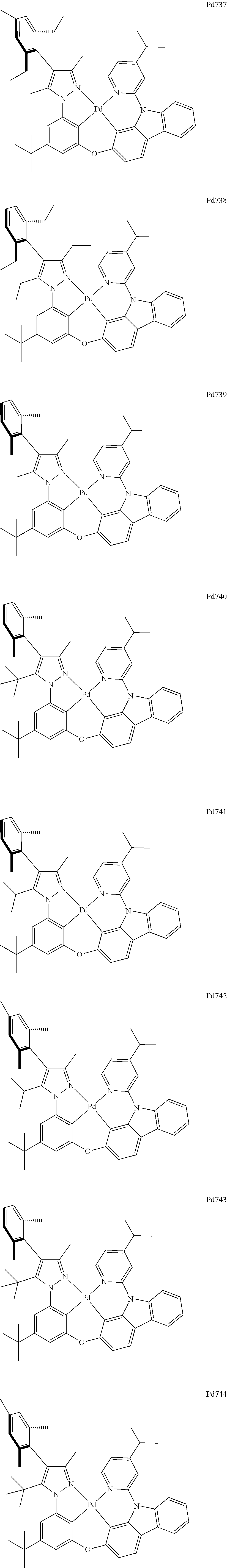

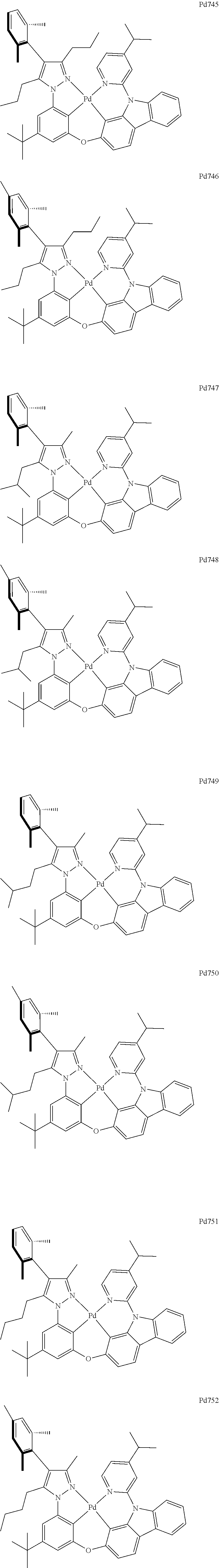

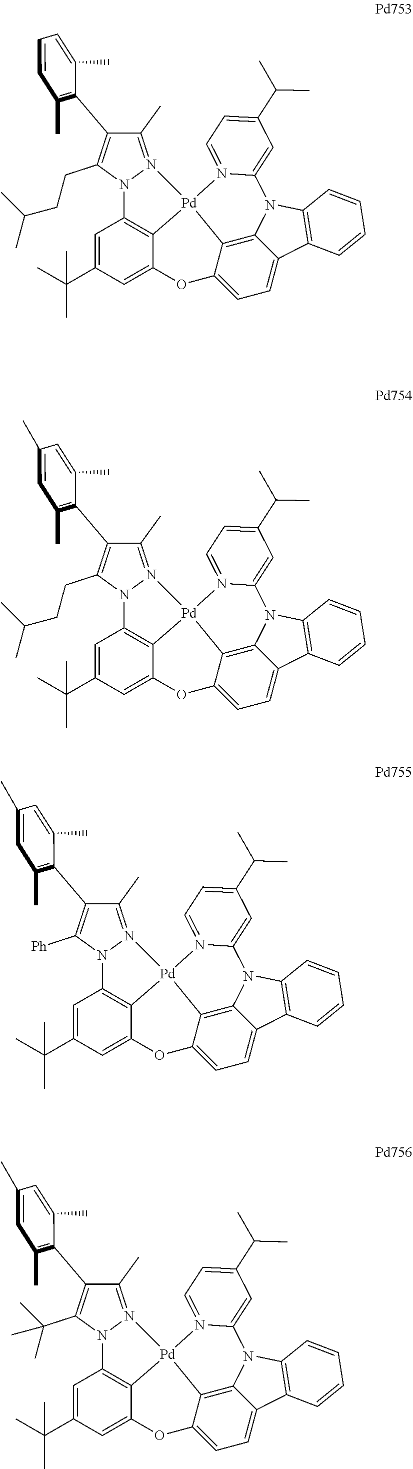

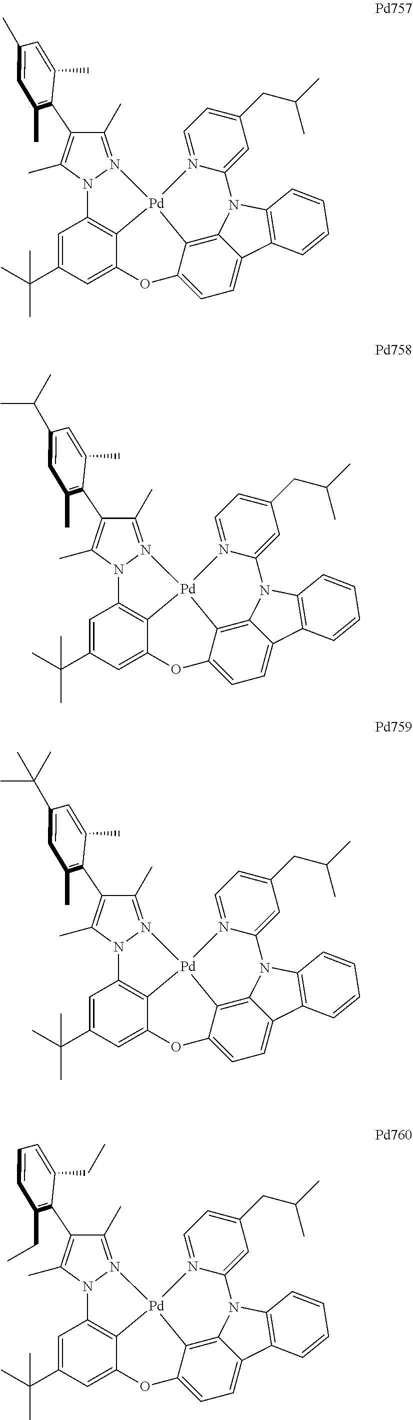

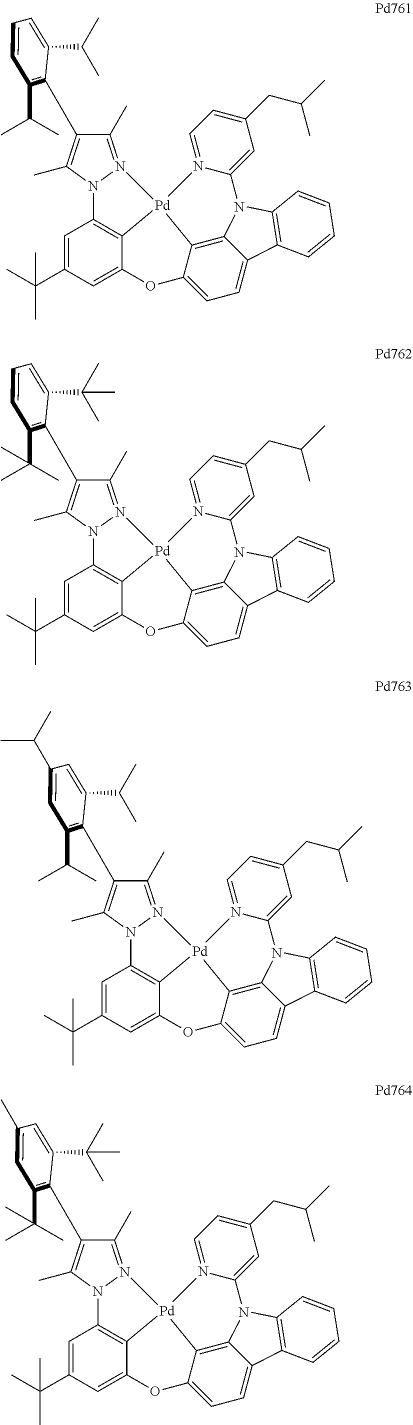

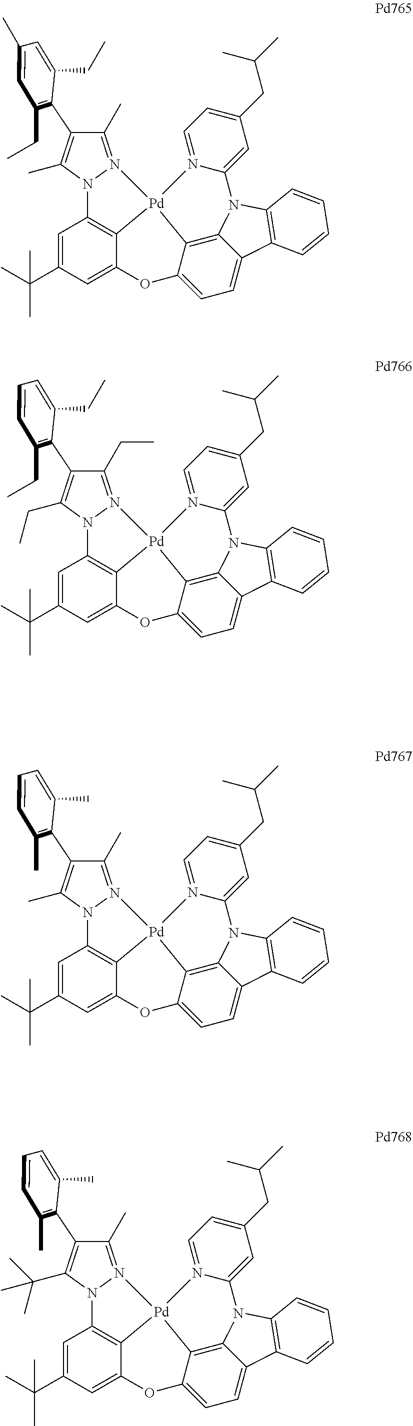

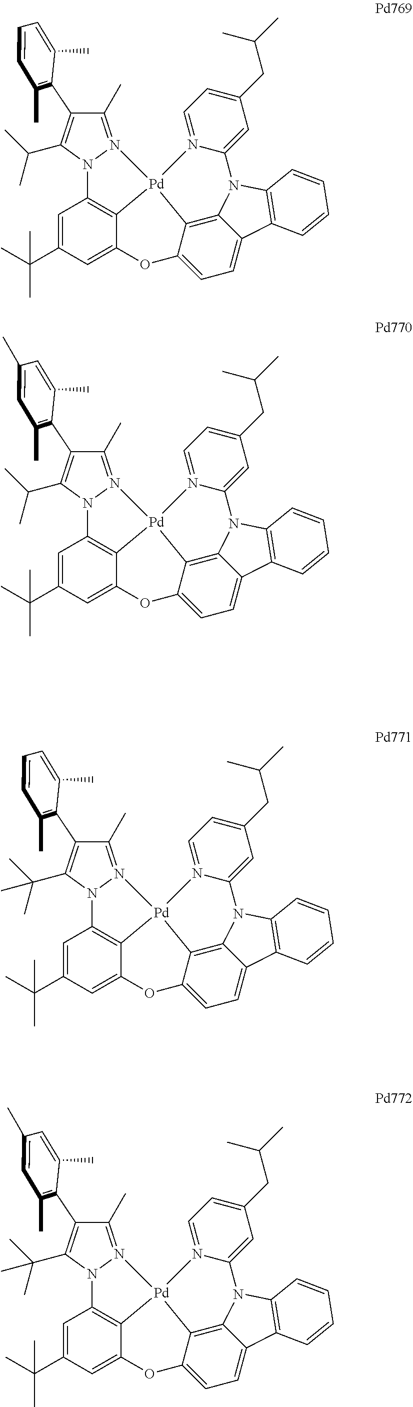

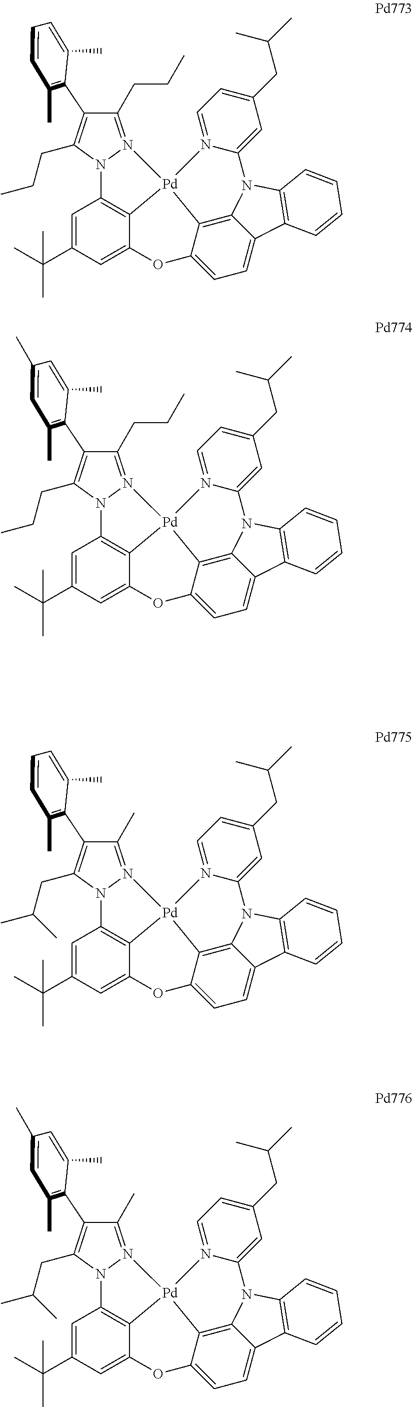

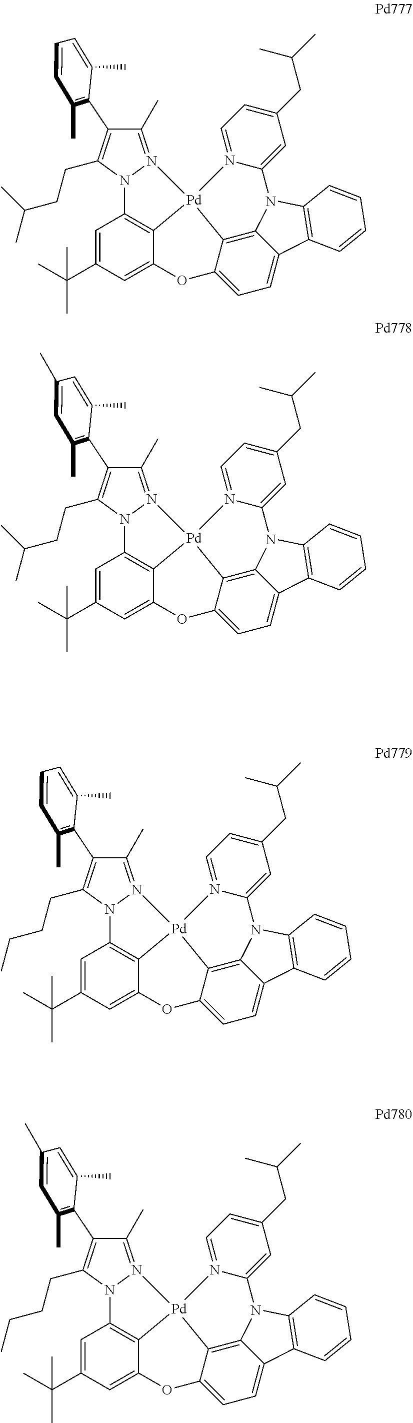

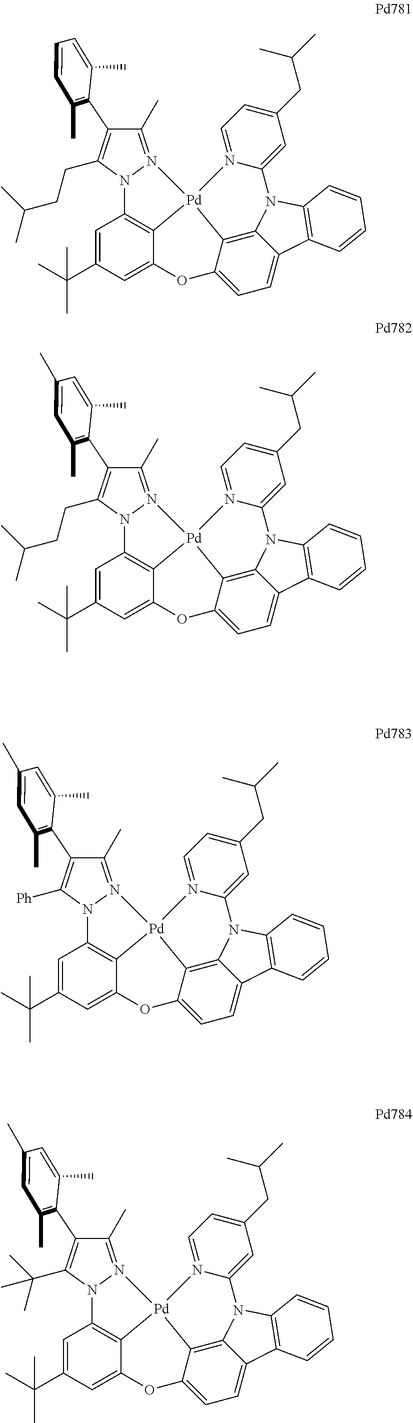

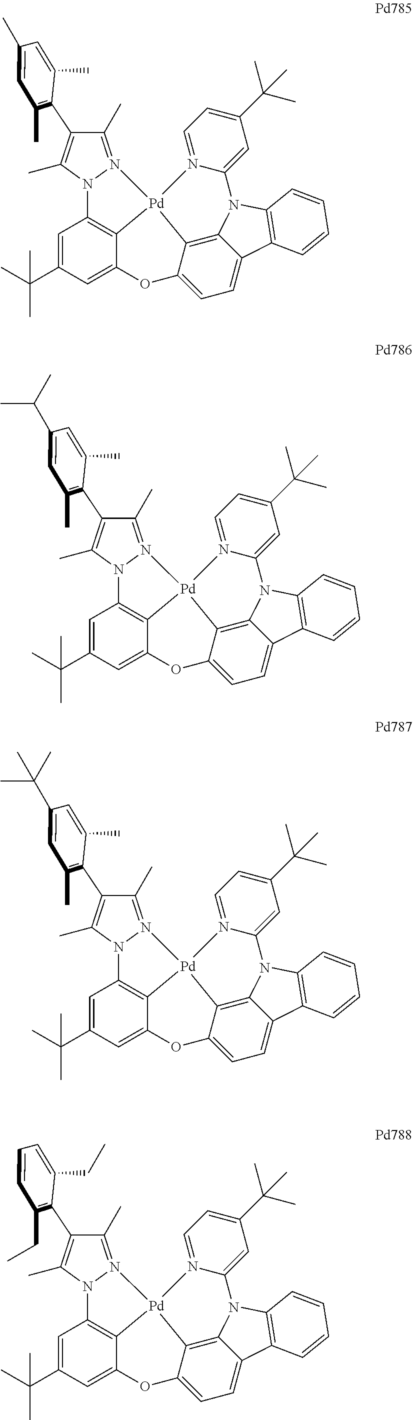

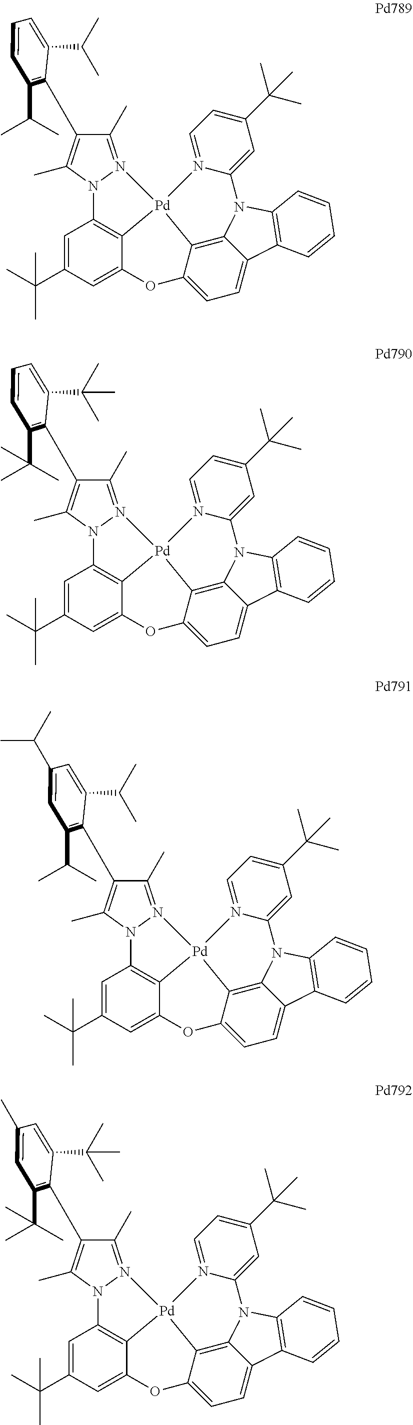

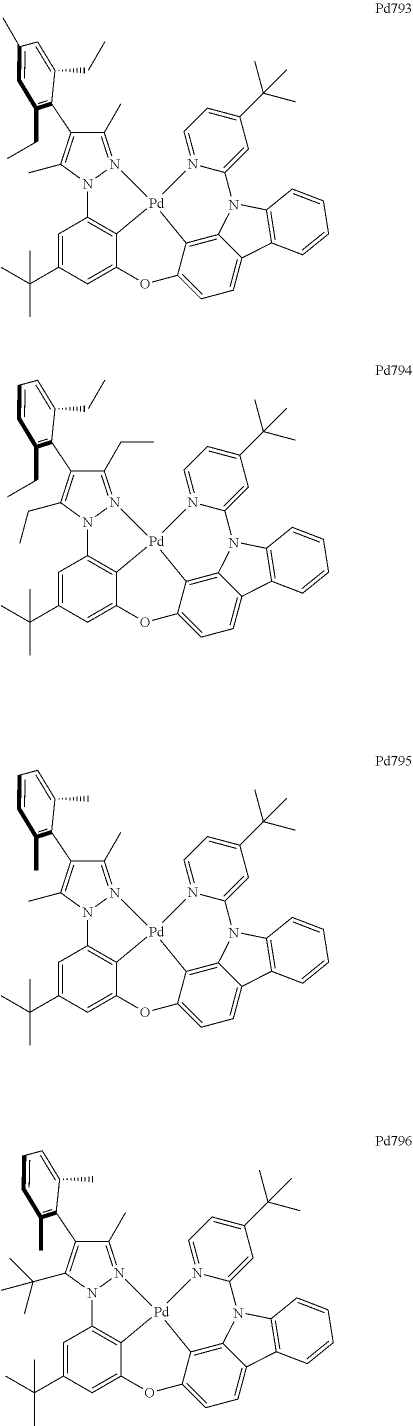

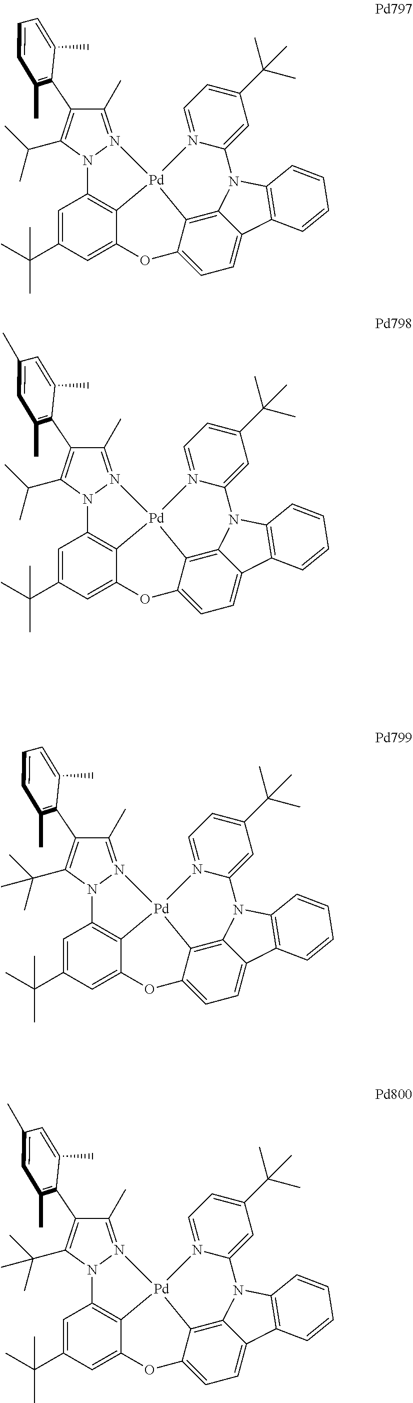

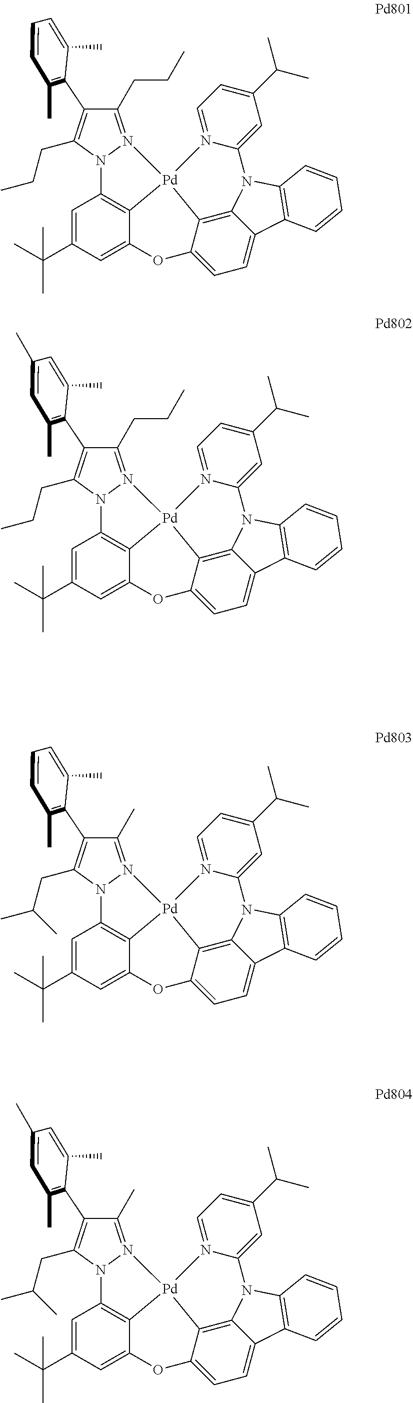

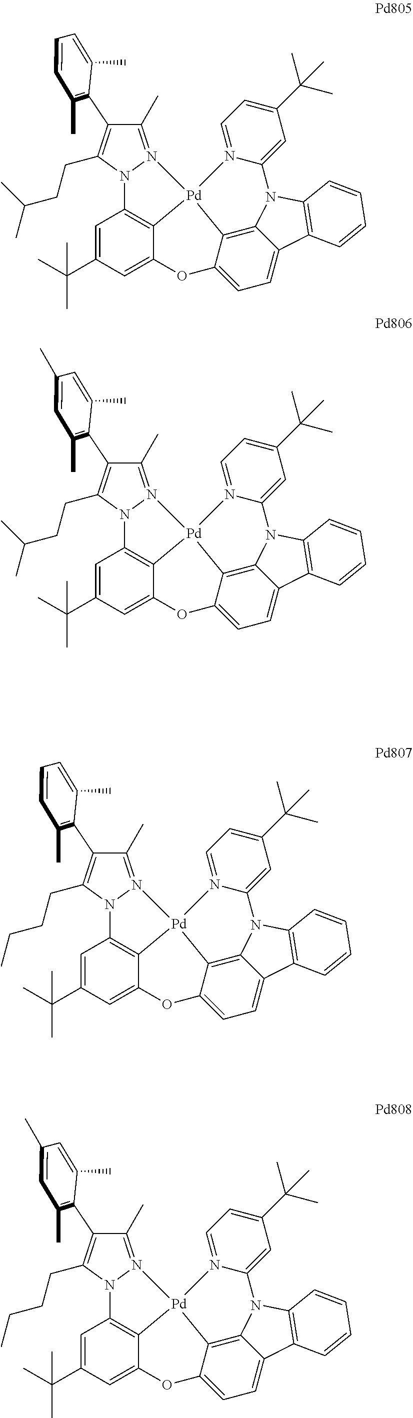

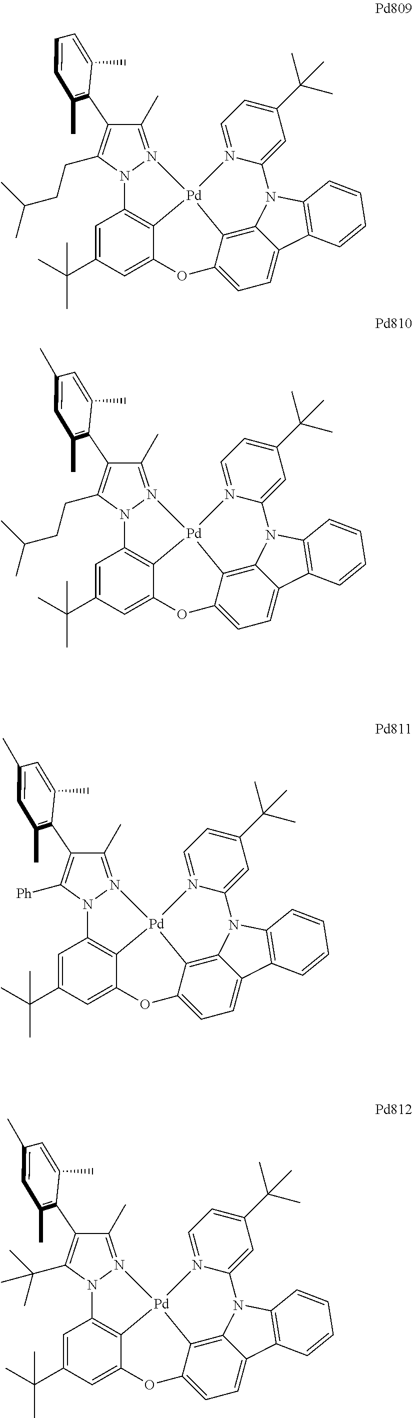

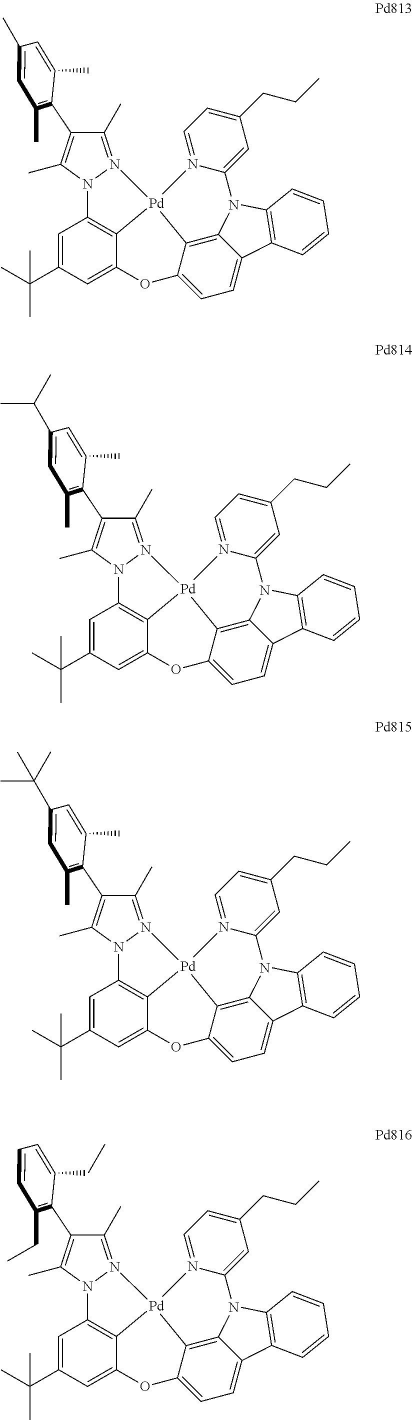

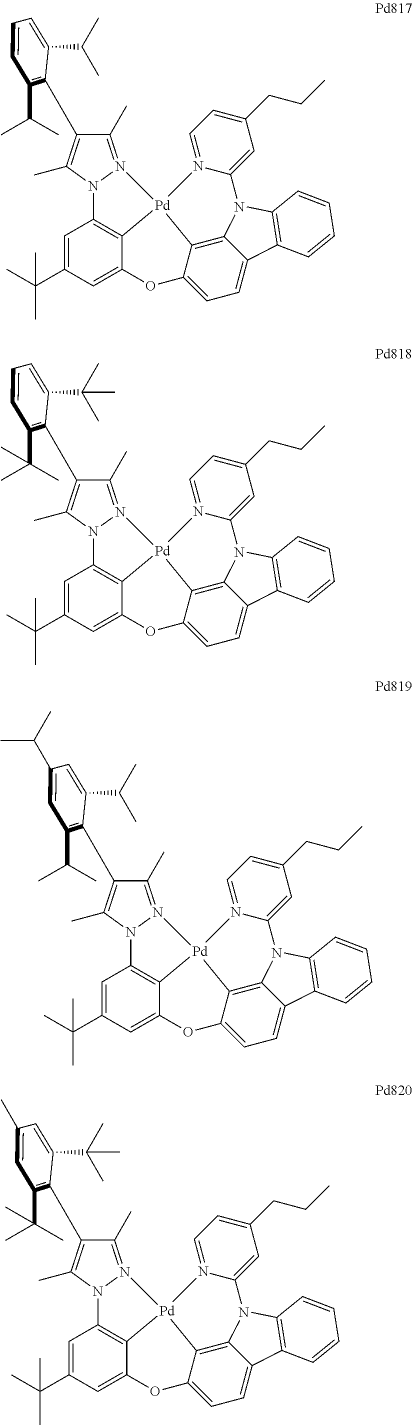

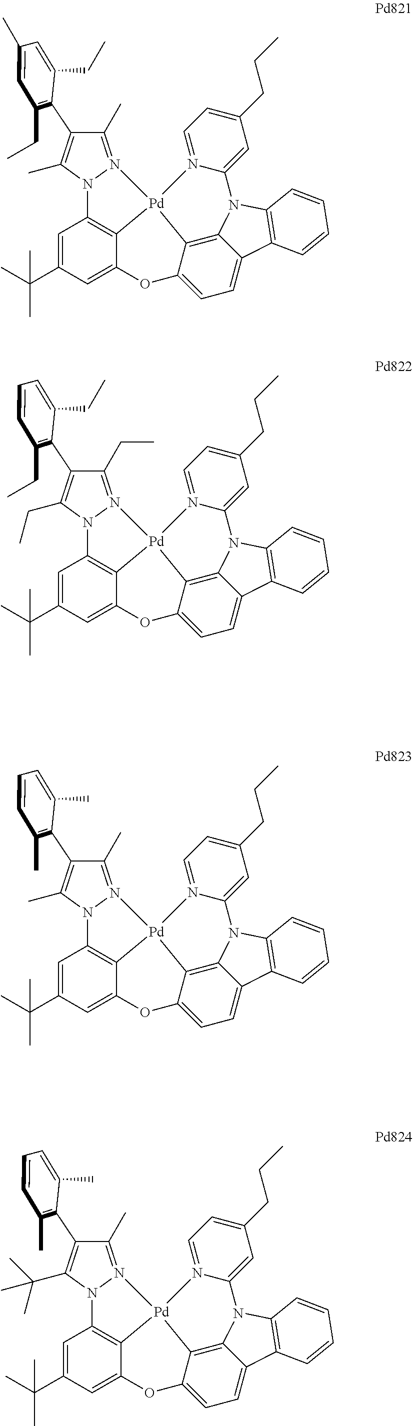

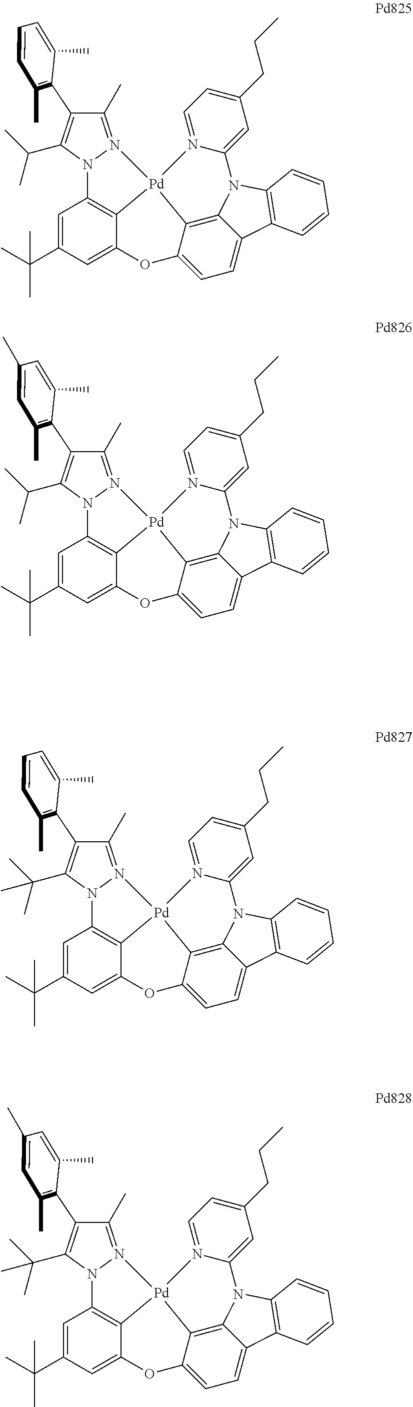

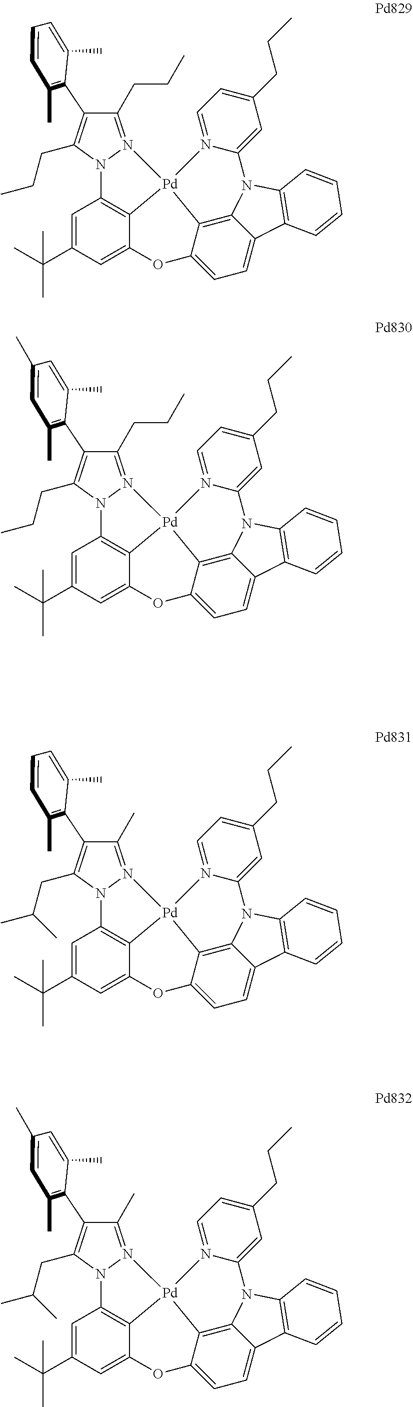

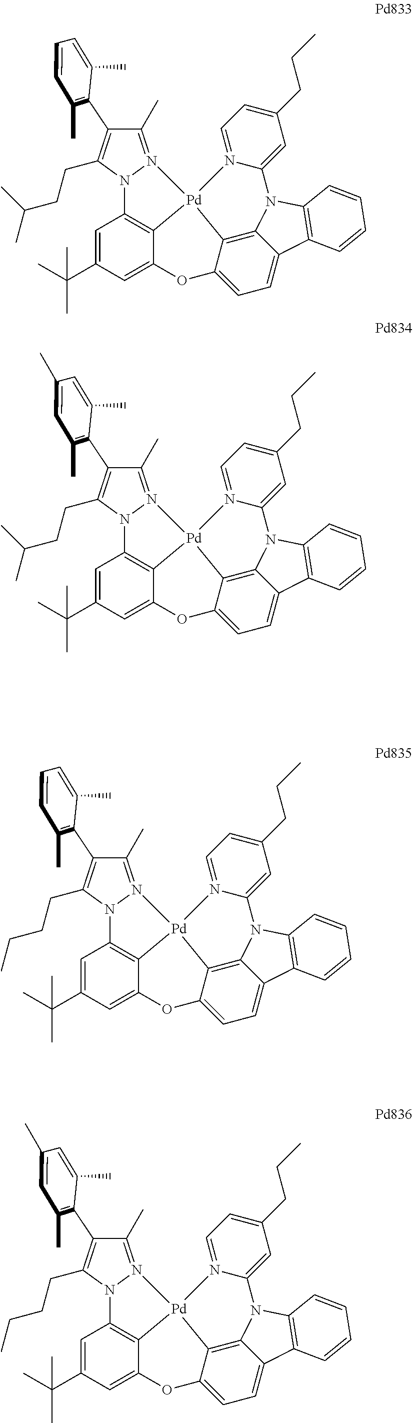

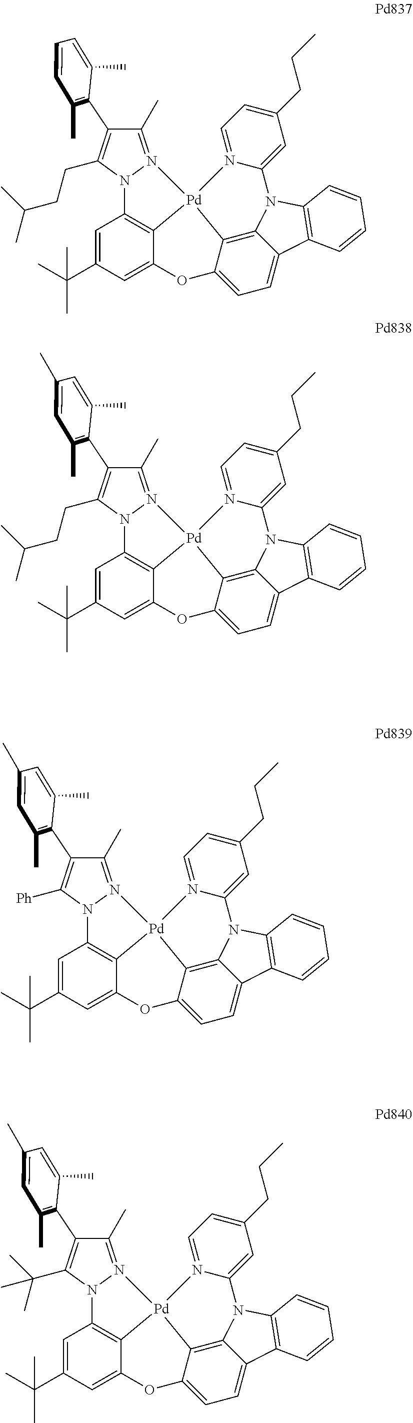

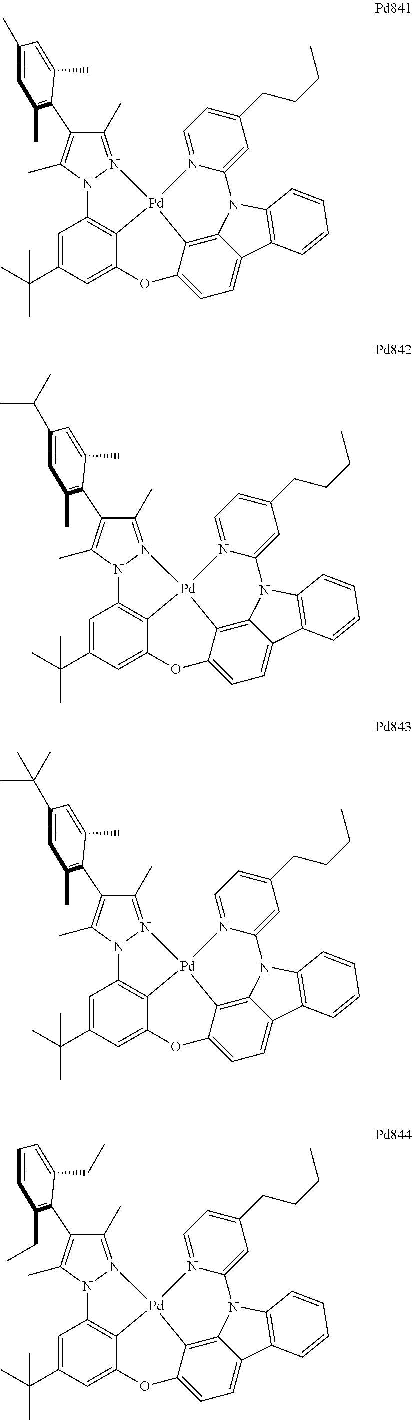

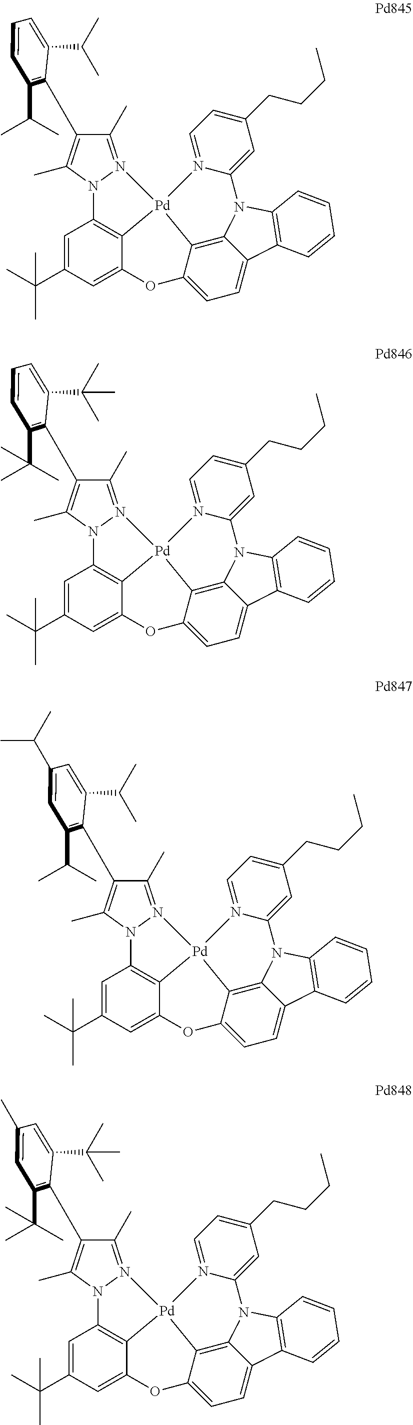

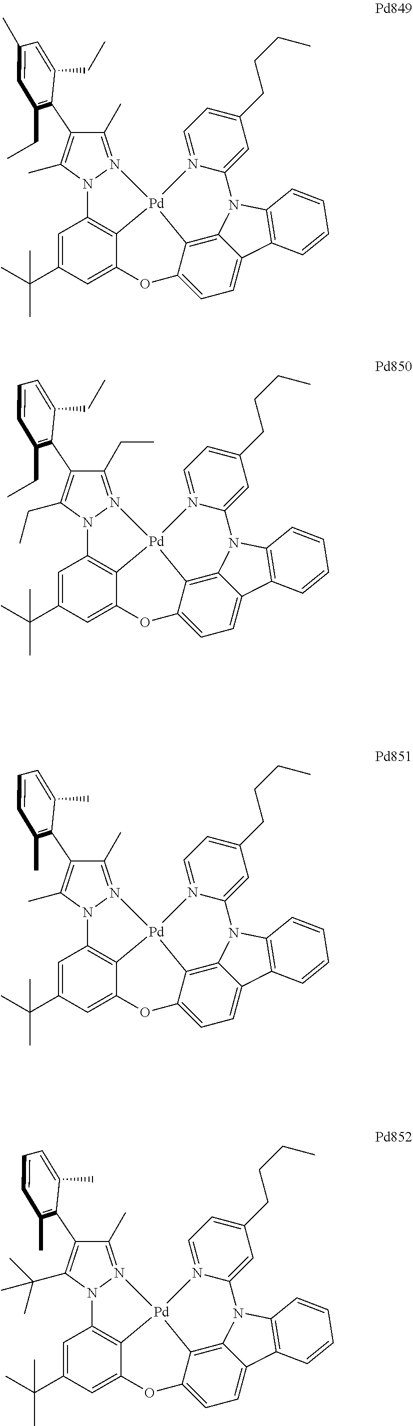

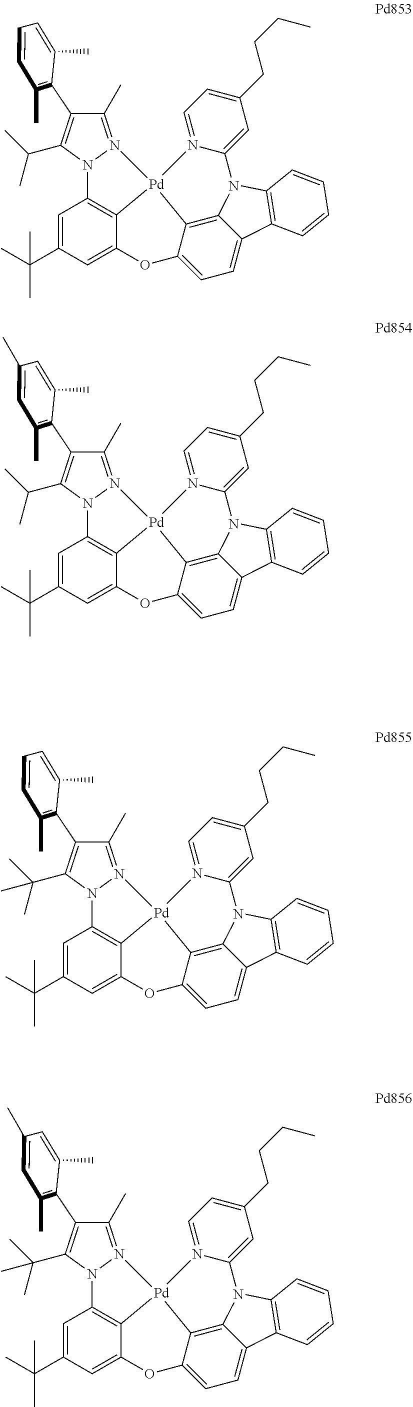

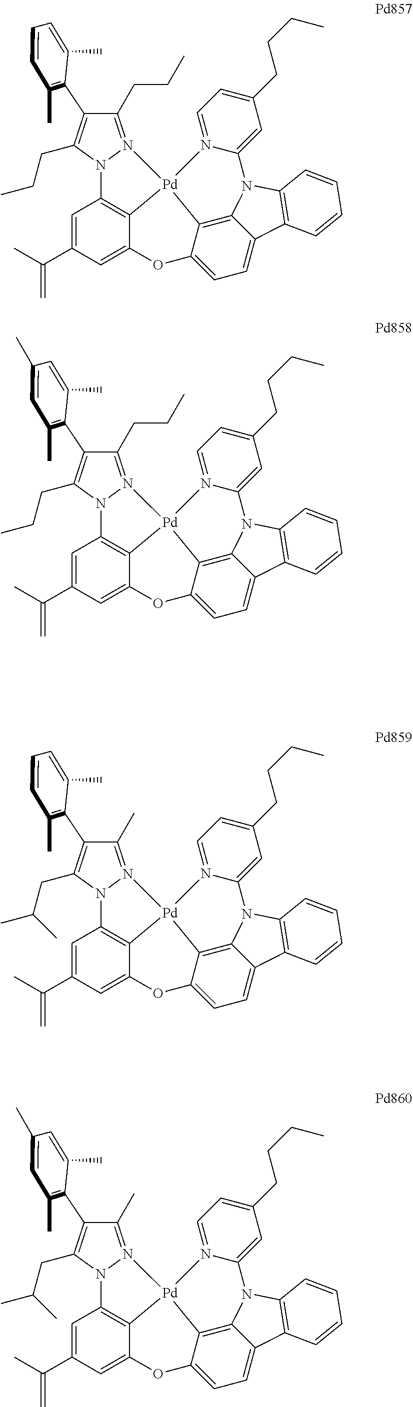

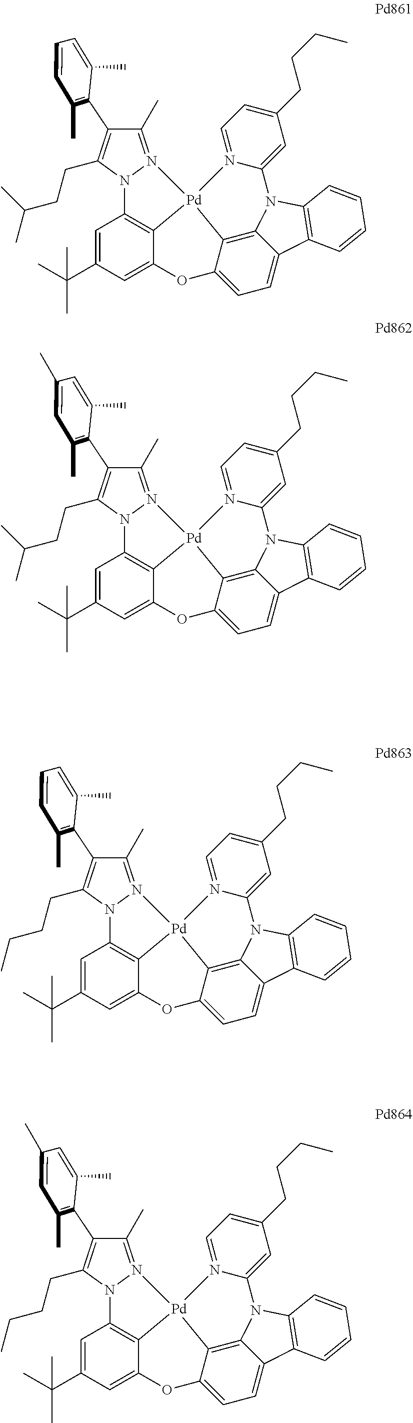

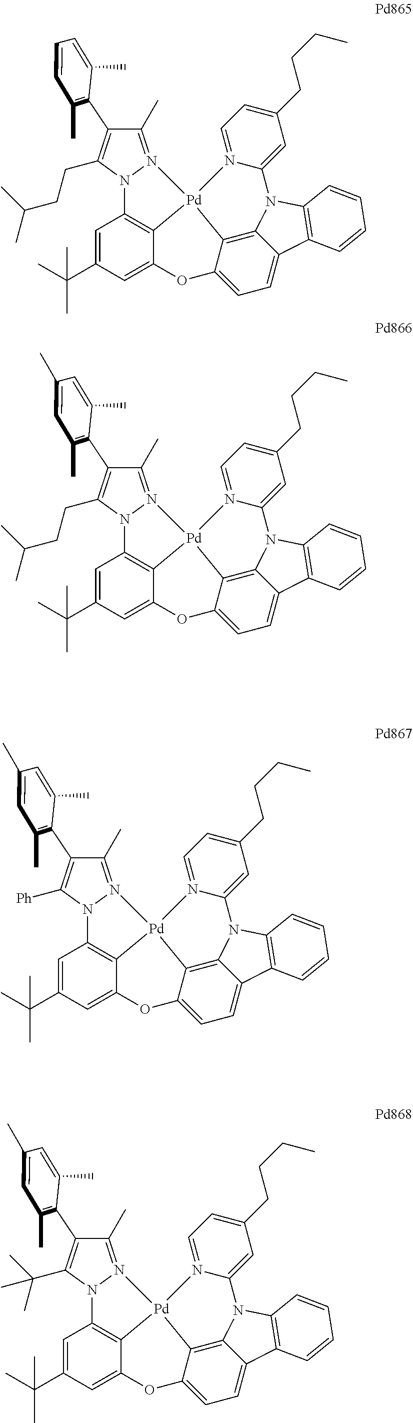

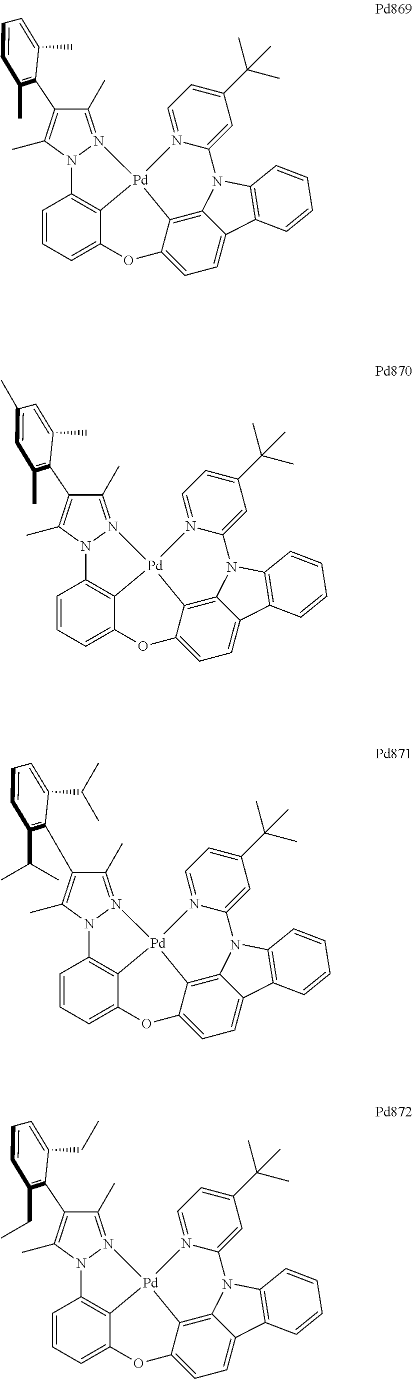

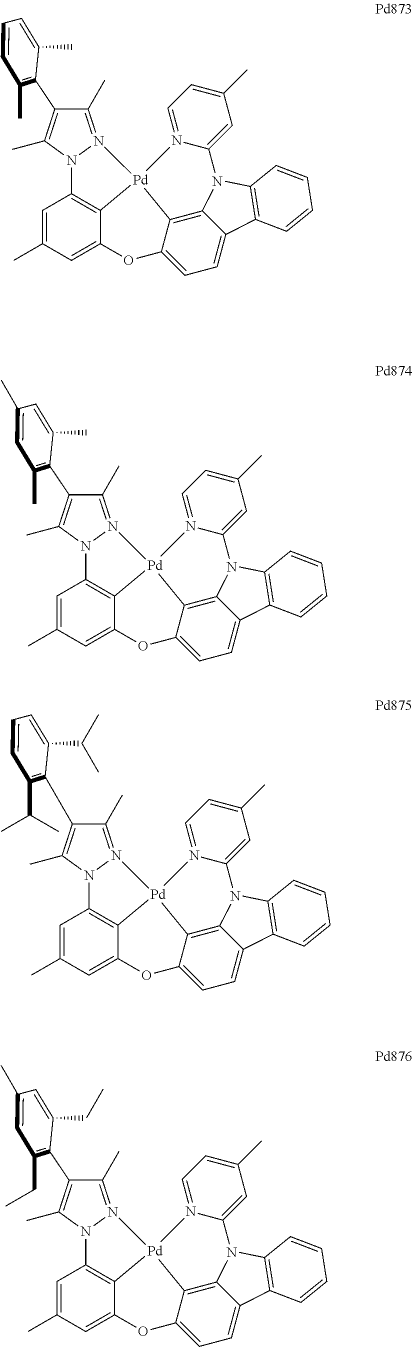

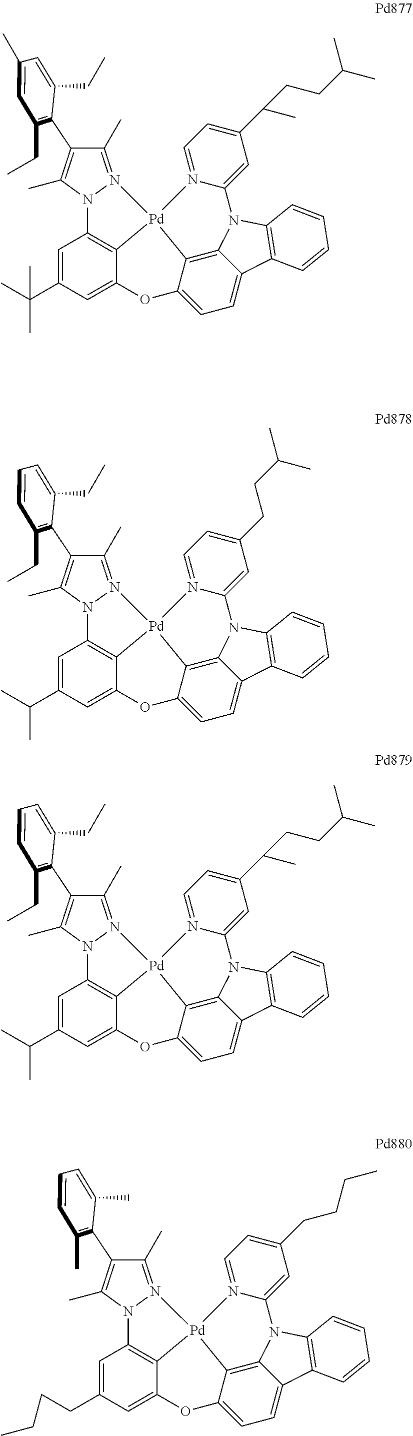

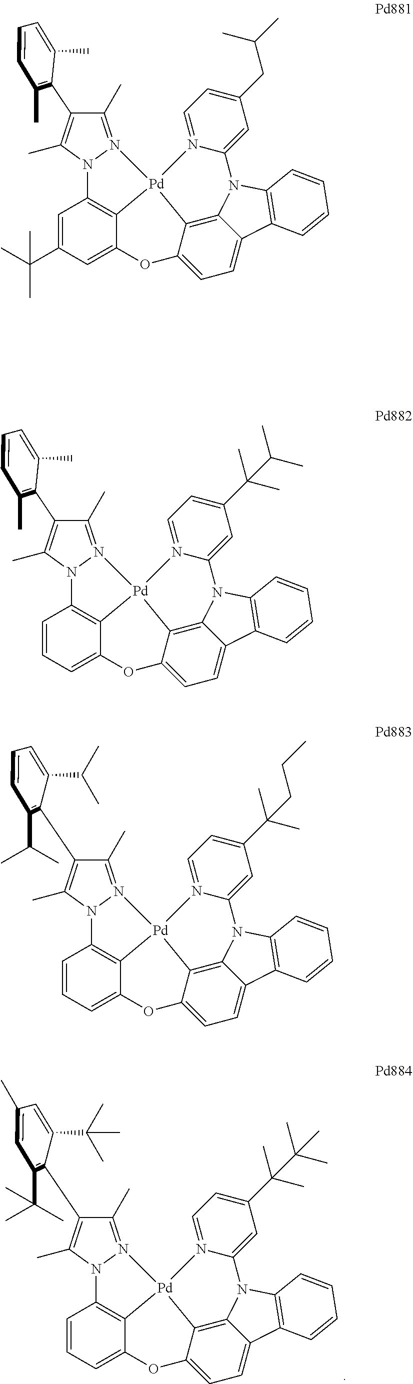

Preferably, the tetradentate cyclic-metal palladium complex comprising 4-aryl-3,5-disubstituted pyrazol provided by the embodiments of the present disclosure is electrically neutral.

An embodiment of present disclosure also provides a method for preparing a tetradentate cyclic-metal palladium complex comprising 4-aryl-3,5-disubstituted pyrazol, the complex is synthesized by using the following chemical reaction steps:

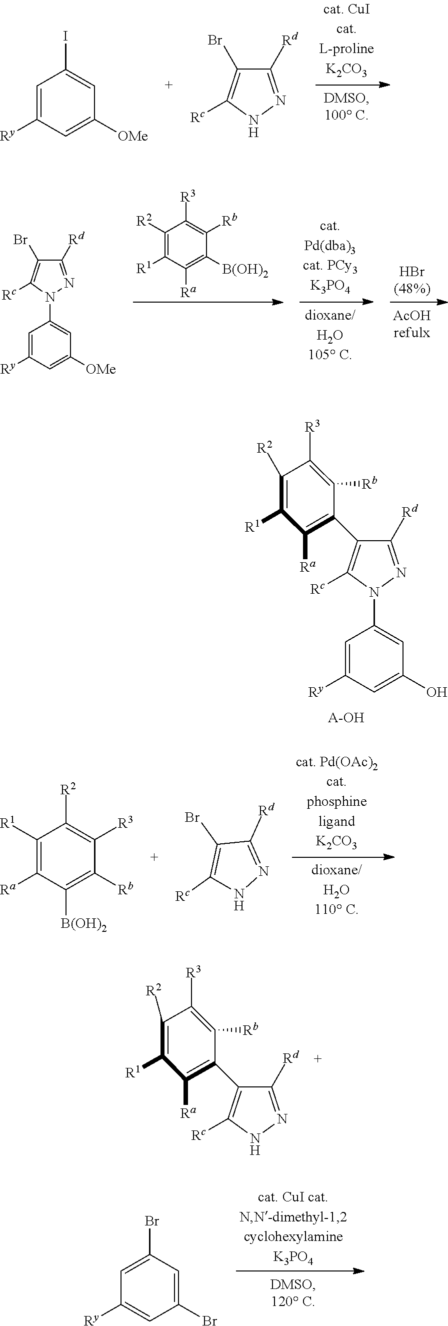

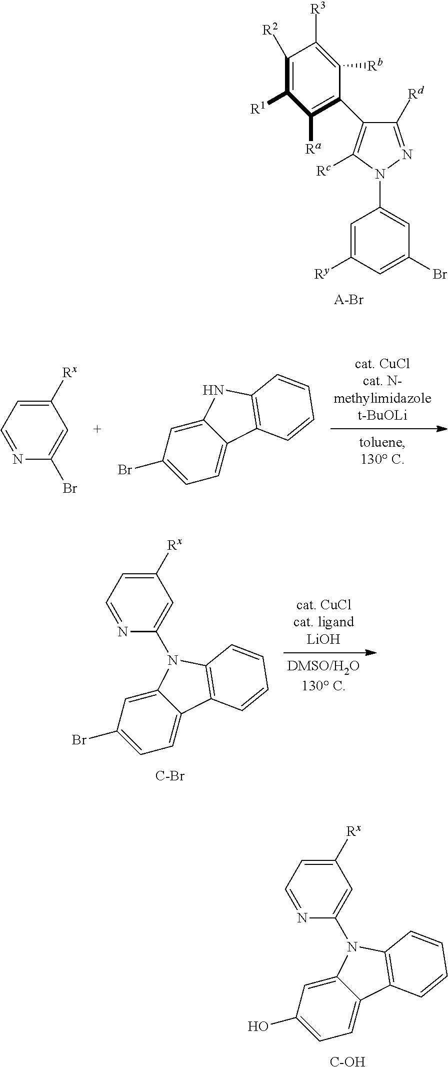

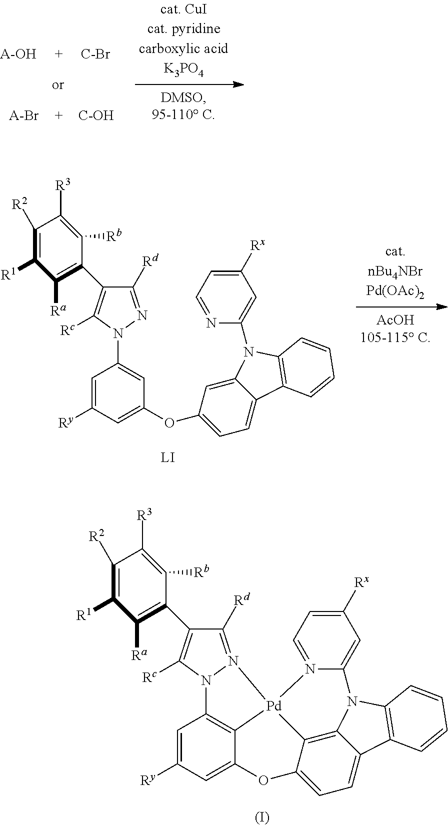

An embodiment of the present disclosure also provides use of the tetradentate cyclic-metal palladium complex comprising 4-aryl-3,5-disubstituted pyrazol in organic electroluminescent materials.

An embodiment of the present disclosure also provides an optical or electro-optical device, which comprises one or more of the tetradentate cyclic-metal palladium complex comprising 4-aryl-3,5-disubstituted pyrazol described above.

Preferably, the optical or electrical-optical device provided by some embodiments of the present disclosure comprises a light absorbing unit (such as solar device or photo-sensing device), an organic light emitting diodes (OLED), a light emitting device or a device that is capable of light-absorbing and light-emitting.

Preferably, the tetradentate cyclic-metal palladium complex comprising 4-aryl-3,5-disubstituted pyrazol provided by some embodiments of the present disclosure has 100% of internal quantum efficiency in the optical or electrical-optical device.

An embodiment of the present disclosure also provides an OLED device, wherein luminescent material or host material in the OLED device comprises one or more of the tetradentate cyclic-metal palladium complex comprising 4-aryl-3,5-disubstituted pyrazol. The complexes provided by some embodiments of the present disclosure can be used as either host materials for OLED devices, such as in panchromatic display etc.; or luminescent material for OLED devices, such as light emitting devices and display and so on.

With respect to the prior art, the present disclosure provides a blue phosphorescent material including tetradentate cyclic-metal palladium complex comprising 4-aryl-3,5-disubstituted pyrazol, which may be delayed fluorescence and/or phosphorescent emitter. The complex provided by some embodiments of the present disclosure has the following characteristics: 1) by introducing a 2,6-substituted phenyl at 4-position of pyrazole, the thermal stability of the molecule is greatly enhanced, and the thermal decomposition temperature is above 3400° C., which is much higher than that of the material when producing the device (generally no higher than 300° C.), and is beneficial to the commercial application of materials; 2) by introducing a large sterically hindered substituent other than a hydrogen atom at 3,5-position of the pyrazole, the conjugation between the pyrazole ring and its 4-position benzene ring is weakened, so that the whole light-emitting molecule has a higher minimum triplet energy level, make it emit blue light; At the same time, it can enhance molecular rigidity, effectively reduce the energy consumed by the molecular vibration, and improve the quantum efficiency of the luminescent material; 3) by controlling the position and type of substituent on the pyridine ring, the emitting light has a narrow emission spectrum, and the maximum wavelength of the emitting light is between 440-450 nm, which is a deep blue phosphorescent luminescent material. Therefore, such phosphorescent materials have great application prospects in the field of blue light, especially deep blue phosphorescent material, the design provides a new way for the development of blue and deep blue phosphorescent materials, and is of great significant for the development and application of deep blue phosphorescent materials.

### BRIEF DESCRIPTION OF THE DRAWINGS

FIG. 1 shows the emission spectrum of the complex Pd1 in dichloromethane solution at room temperature;

FIG. 2 shows the emission spectrum of the complex Pd2 in dichloromethane solution at room temperature;

FIG. 3 shows the original spectrum of thermogravimetric analysis of the complex Pd2;

FIG. 4 shows the emission spectrum of the complex Pd869 in dichloromethane solution at room temperature;

FIG. 5 shows the original spectrum of thermogravimetric analysis (TGA) of the complex Pd869;

FIG. 6 shows the emission spectrum of the complex Pd870 in dichloromethane solution at room temperature;

FIG. 7 shows the original spectrum of thermogravimetric analysis (TGA) of the complex Pd870.

### DETAILED DESCRIPTION OF THE EXEMPLARY EMBODIMENTS

The present disclosure can be more easily understood by reference to the following detailed description and examples contained therein. Before the complexes, devices, and/or methods of the present disclosure are disclosed and described, it should be understood that they are not limited to a specific synthesis method (unless otherwise stated), or a specific reagent (unless otherwise stated), as this of course can be changed. It should also to be understood that the terms used in the present disclosure is for the purpose of describing a particular aspect, and is not intended to be limiting. Although any methods and materials similar or equivalent to those described herein can be used in the practice or experiment, the exemplary methods and materials are described below.

As used in the specification and the appended claims, the singular forms of “a”, “an” and “the” include the plural referents, unless the context clearly indicated. Thus, for example, when referring to “components”, it means a mixture that may include two or more components.

As used herein, the terms “optional” or “optionally” means that the subsequently described event or circumstance may or may not occur, and that the description includes instances where the event or circumstance occurs and it does not occur.

The components that can be used to prepare the compositions of the present disclosure are disclosed, as well as the compositions themselves to be used in the methods disclosed in the present disclosure. These and other materials are disclosed in the present disclosure, and it should be understood that when the combination, subset, interaction, group and the like of these materials are disclosed, it is not specifically disclose each of the various individual and total combination and replacement of these complex, each is specifically intended and described in the present disclosure. For example, if specific complex are disclosed and discussed, and many modifications that can be made to many molecules comprising the complex are discussed, then various and every combinations and substitution of the complex are specifically contemplated and may be modified, and the modification may be performed, otherwise it will be specifically stated to the contrary. Thus, if an example of a class of molecules A, B, and C, and a class of molecules D, E, and F, and a combination molecule A-D are disclosed, then even if each is not recorded separately, it also considered to disclose each individual and total expected meaning combination, A-E, A-F, B-D, B-E, B-F, C-D, C-E, and C-F. Likewise, any subset or combination of these is also disclosed. Thus, for example, it should consider and disclosure of groups A-E, B-F, and C-E. These concepts apply to all aspects of the disclosure, including but not limited to the steps of the method of preparing and using the complex. Therefore, if there are various additional steps that can be performed, it should be understood that, each of these additional steps can be performed in a specific embodiment of the method or a combination of the embodiments.

The linking atoms used in the present disclosure, for example, N and C groups. The linking atoms can optionally have other (if the bond allows) attached chemical moieties. For example, on the one hand, oxygen does not have any other chemical group attached, because once bonded to two atoms (i.e., N or C) valences have been satisfied. On the other hand, when carbon is a connecting atom, two additional chemical moieties can be attached to the carbon atom. Suitable chemical moieties include, but are not limited to, hydrogen, hydroxy, alkyl, alkoxy, ═O, halogen, nitro, amine, amide, mercapto, aryl, heteroaryl, cycloalkyl, and heterocyclyl.

The term “cyclic structure” or similar terms used herein means that any cyclic chemical structure, including but not limited to aryl, heteroaryl, cycloalkyl, cycloalkenyl, heterocyclyl, carbene, and N-heterocyclic carbine.

The term “substituted” as used herein is intended to encompass all allowable substituents of organic compounds. In a broad aspect, the allowable substituents include non-cyclic and cyclic, branched and unbranched, carbocyclic and heterocyclic, and aromatic and non-aromatic substituents of organic compounds. Illustrative substituents include, for example, those described below. For a suitable organic compound, the allowable substituent may be one or more, the same or different. For the purpose of the present disclosure, a heteroatom (e.g., nitrogen) can have a hydrogen substituent and/or any allowable substituent of organic compound according to the present disclosure, which satisfies the valence bond of the heteroatom. The disclosure is not intended to impose any restrictions in any way on the use of substituents allowed by organic compounds. Likewise, the term “substitute” or “substituted” includes the implicit condition that such substitution is consistent with the atoms of the substituent and allowed valences of the substituent, and that the substitution results in a stable complex (e.g., the compound that will not be transformed spontaneously (such as by rearrangement, cyclization, elimination etc.)). It also contemplated that, in some aspects, individual substituent can be further optionally substituted (i.e., further substituted or unsubstituted), unless explicitly stated otherwise.

In defining various terms, “R¹” [symbol] “R²” [symbol] “R³” [symbol] “R⁴” are used as general symbols in the present disclosure to indicate various specific substituents. These symbols can be any substituent, not only limited to those disclosed herein, and they are limited to some substituents in one case, they may be limited to other substituents in other cases.

The term “alkyl” as used herein is a branched or unbranched 1 to 24 carbon atoms of saturated hydrocarbon, such as methyl, ethyl, n-propyl, isopropyl, n-butyl, isobutyl, sec-butyl, tert-butyl, n-pentyl, isopentyl, sec-amyl, neopentyl, hexyl, heptyl, hemiyl, nonyl, decyl, dodecyl, tetradecyl, ten hexadecyl, eicosyl, tetracosyl, etc. The alkyl can be cyclic or noncyclic. The alkyl may be branched or unbranched. The alkyl may be substituted or unsubstituted. For example, the alkyl may be substituted with one or more groups, including but not limited to, optionally substituted herein alkyl, cycloalkyl, alkoxy, amino, ether, halogen, hydroxy, nitro, silyl, sulfo-OXO, or thiol. “a lower alkyl” means an alkyl containing 1 to 6 (e.g., 1 to 4) carbon atoms.

Throughout the specification, “alkyl” is usually used to refer to both unsubstituted alkyl and substituted alkyl; however, substituted alkyl is also specifically mentioned in the present disclosure by determining the specific substituent on the alkyl. For example, the term “halogenated alkyl” or “haloalkyl” specifically refers to an alkyl substituted with one or more halogens (e.g., fluorine, chlorine, bromine, or iodine). The term “alkoxyalkyl” specifically refers to an alkyl substituted with one or more alkoxy, as described below. The term “alkylamino” specifically refers to an alkyl substituted with one or more amino, as described below, and the like. When “alkyl” is used in one instance and a specific term such as “alkyl alcohol” is used in another instance, it is not meant to imply that the term “alkyl” does not refer to specific term such as “alkyl alcohols” and the like.

This practice is also applied to other groups described in the present disclosure. That is, when a term such as “cycloalkyl” refers to both unsubstituted and substituted cycloalkyl moieties, the substituted moieties may be determined additionally in the present disclosure; for example, a specifically substituted cycloalkyl may be called “alkylcycloalkyl”. Similarly, substituted alkoxy may be specifically referred to as, for example, “halogenated alkoxy” and a specific substituted alkenyl may be “enol” etc. Likewise, the practice of using general terms such as “cycloalkyl” and specific terms such as “alkylcycloalkyl” is not intended to imply that the general term does not include the specific term at the same time.

The term “cycloalkyl” as used herein, is a non-aromatic carbon-based ring consisting of at least three carbon atoms. Examples of cycloalkyl include, but are not limited to, cyclopropyl, cyclobutyl, cyclopentyl, cyclohexyl, cyclononyl, and the like. The term “heterocycloalkyl” is a kind of cycloalkyl as defined above, and is included in the meaning of the term “cycloalkyl” wherein at least one ring carbon atom is a heteroatom such as, but not limited to, nitrogen, oxygen, sulfur, or phosphorus substitution. The cycloalkyl and heterocycloalkyl may be substituted or unsubstituted. The cycloalkyl and heterocycloalkyl may be substituted with one or more groups, including but not limited to, as described herein alkyl, cycloalkyl, alkoxy, amino, ether, halogen, hydroxy, nitro, silyl, sulfo-OXO, or thiol.

The term “alkoxy” and “alkoxy group” are used herein to refer to an alkyl or cycloalkyl bonded through an ether linkage; i.e., “alkoxy” may be defined as —OR¹, wherein R¹ is an alkyl or cycloalkyl as defined above. “alkoxy” also includes a polymer of the alkoxy just described; i.e., an alkoxy can be a polyether such as —OR¹—OR² or —OR¹—(OR²)ₐ—OR³, wherein “a” is an integer from 1 to 200, and R¹, R², and R³ each are alkyl, cycloalkyl, independently, or a combination thereof.

As used herein, the term “alkenyl” is a hydrocarbyl of 2 to 24 carbon atoms, whose structural formula contains at least one carbon-carbon double bond. Asymmetric structures such as (R¹R²)C═C(R³R⁴) are intended to contain the E and Z isomers. It can be presumed that in structural formula of the present disclosure, there is an asymmetric olefin, or it can be explicitly expressed by the bond symbol C═C. The alkenyl may be substituted with one or more groups, including but not limited to, as described herein alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azide, nitro, silyl, sulfo-OXO, or thiol.

The term “cycloalkenyl” as used herein, is a non-aromatic carbon-based ring that consists of at least 3 carbon atoms, and contains at least one carbon-carbon double bond, i.e., C══C. Examples of cycloalkenyl include, but not limited to, cyclopropenyl, cyclobutenyl, cyclopentenyl, cyclopentadienyl, cyclohexenyl, cyclohexadienyl, norbornenyl etc. The term “heterocycloalkenyl” is a cycloalkenyl as defined above, and included in the meaning of the term “cycloalkenyl”, wherein at least one of the carbon atoms of the ring is heteroatom such as but not limited to nitrogen, oxygen, sulfur, or phosphorus substitution. Cycloalkenyl and heterocycloalkenyl may be substituted or unsubstituted. The cycloalkenyl and heterocycloalkyl may be substituted with one or more groups, including but not limited to, alkyl, cycloalkyl, alkoxy, alkenyl, cycloalkenyl, alkyne, cycloalkynyl, aryl, heteroaryl, aldehyde, amino, carboxylic acid, ester, ether, halogen, hydroxy, ketone, azide, nitro, silyl, sulfo-OXO, or thiol as described herein.

As used herein, the term “alkynyl” is a hydrocarbon radical having 2 to 24 carbon atoms, which has a structure containing at least one carbon-carbon triple bond. An alkynyl can be unsubstituted or substituted with one or more groups, including but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxy, ketone, azide, nitro, silyl, sulfo-OXO, or thiol as described herein.

The term “cycloalkynyl” as used herein, is a non-aromatic carbon-based ring that contains at least seven carbon atoms and contains at least one carbon-carbon triple bond. Examples of cycloalkynyl include but not limited to, cycloheptynyl, cyclooctynyl, cyclodecynyl, and the like. The term “heterocycloalkynyl” is a cycloalkenyl as defined above, and included in the meaning of the term “cycloalkynyl” wherein at least one of the carbon atoms of the ring is replaced by heteroatom, the heteroatom such as but not limited to nitrogen, oxygen, sulfur, or phosphorus. Cycloalkenyl and heterocycloalkenyl may be substituted or unsubstituted. The cycloalkenyl and heterocycloalkyl may be substituted with one or more groups, including but not limited to, alkyl, cycloalkyl, alkoxy, alkenyl, cycloalkenyl, alkyne, cycloalkynyl, aryl, heteroaryl, aldehyde, amino, carboxylic acid, ester, ether, halogen, hydroxy, ketone, azide, nitro, silyl, sulfo-OXO, or thiol as described herein.

The term “aryl” as used herein, is a group that contains any carbon-based aromatic group, including but not limited to, benzene, naphthalene, phenyl, biphenyl, phenoxy benzene, and so on. The term “aryl” also includes “heteroaryl”, which is defined as a group containing an aromatic group having at least one heteroatom introduced into the ring of an aromatic group. Examples of heteroatoms include but are not limited to, nitrogen, oxygen, sulfur and phosphorous. The term “non-heteroaryl” (which is also included in the term “aryl”) defines an aromatic group, which does not contain a heteroatom. The aryl may be substituted or unsubstituted. An aryl may be substituted with one or more groups including but not limited to, alkyl, cycloalkyl, alkoxy, alkenyl, cycloalkenyl, alkynyl, cycloalkynyl, aryl, heteroaryl, aldehyde, amino, carboxyl acid groups, ester groups, ether groups, halogen, hydroxy, ketone groups, azide, nitro, silyl, thio-oxo, or sulfydryl as described herein. The term “biaryl” is a specific type of aryl and included in the definition of “aryl”. Biaryl refers to two aryl bonded together via a fused ring structure, as in naphthalene, or two aryl linked via one or more carbon-carbon bonds, as in biphenyl in the same way.

The term “amine” or “amino” as used herein is represented by the formula —NR¹R², wherein R¹ and R² can be independently selected from hydrogen, alkyl, cycloalkyl, alkenyl, cycloalkenyl, alkynyl, cycloalkyne, aryl or heteroaryl.

The term “alkylamino” as used herein is represented by the formula —NH(-alkyl), wherein alkyl is as described herein. Representative examples include but not limited to, methylamino, ethylamino, propylamino, isopropylamino, butylamino, isobutylamino, (sec-butyl)amino, (tert-butyl)amino, amylamino, isoamylamino, (tert-armyl)amino, hexylamino, and the like.

The term “dialkylamino” as used herein is represented by the formula —NH(-alkyl)₂, wherein alkyl is as described herein. Representative examples include but not limited to, dimethylamino, diethylamino, dipropylamino, diisopropylamino, dibutylamino, diisobutylamino, di(sec-butyl)amino, di(tert-butyl)amino, dipentylamino, diisoamylamino, di(tert-amyl)amino, dihexylamino, N-ethyl-N-methylamino, N-methyl-N-propylamino, N-ethyl-N-propylamino, and the like.

The term “ether” as used herein is represented by the formula R¹OR², wherein R¹ and R² can be independently alkyl, cycloalkyl, alkenyl, cycloalkenyl, alkynyl, cycloalkynyl, aryl, or heteroaryl, as described herein. The term “polyether” as used herein is represented by the formula —(R¹O—R²O)ₐ—, wherein R¹ and R² can be independently alkyl, cycloalkyl, alkenyl, cycloalkenyl, alkynyl, cycloalkynyl, aryl, or heteroaryl, and “a” is an integer from 1 to 500. Examples of polyether groups include polyoxyethylene, polyoxypropylene, and polyoxybutylene.

The term “halogen” as used herein refers to halogen, for example fluoride, chlorine, bromine, and iodine.

The term “heterocyclyl” as used herein refers to both monocyclic and polycyclic non-aromatic ring systems, and “heteroaryl” as used herein refers to monocyclic and polycyclic aromatic ring system: wherein at least one of the ring members is not carbon. The term includes azetidinyl, dioxanyl, furyl, imidazolyl, isothiazolyl, isoxazolyl, morpholinyl, oxazolyl, oxazolyl including 1,2,3-oxazolyl, 1,2,5-oxadiazolyl and 1,3,4-oxadiazolyl, piperazinyl, piperidinyl, pyrazinyl, pyrazolyl, pyrazolyl, pyridazinyl, pyrindine, pyridinyl, pyrrolyl, pyrrolidinyl, tetrahydrofuranyl, tetrahydropyranyl, tetrazine including 1,2,4,5-tetrazinyl, tetrazolyl including 1,2,3,4-tetrazolyl and 1,2,4,5-tetrazolyl, thiadiazolyl including 1,2,3-thiadiazolyl, 1,2,5-thiadiazolyl and 1,2,5-thiadiazolyl, thiadiazolyl, thiazolyl, triazinyl including 1,3,5-triazinyl and 1,2,4-triazinyl, triazolyl including 1,2,3-triazolyl and 1,3,4-triazolyl, and so on.

The term “hydroxy” as used herein, is represented by the formula —OH.

The term “ketone” as used herein is represented by the formula R¹C(O)R², wherein R¹ and R² can be independently alkyl, cycloalkyl, alkenyl, cycloalkenyl, alkynyl, cycloalkynyl, aryl, or heteroaryl, as described herein.

The term “azido” as used herein is represented by the formula —N₃.

The term “nitro” as used herein is represented by the formula —NO₂.

The term “nitrile” as used herein is represented by the formula —CN.

The term “silyl” as used herein is represented by the formula —SiR¹R²R³, wherein R¹, R² and R³ can be independently hydrogen, or alkyl, cycloalkyl, alkoxy, alkenyl, cycloalkenyl, alkynyl, cycloalkynyl, aryl, or heteroaryl, as described herein.

The term “sulfur-oxo group” as used herein is represented by the formula —S(O)R¹, —S(O)₂R¹, —OS(O)₂R¹ or —OS(O)₂OR¹, wherein R¹ can be hydrogen, or alkyl, cycloalkyl, alkenyl, cycloalkenyl, alkynyl, cycloalkynyl, aryl, or heteroaryl, as described herein. Throughout this specification, “S(O)” is shorthand for S═O. The term “sulfonyl” as used herein refers to a sulfur-oxygen group represented by the formula —S(O)₂R¹, wherein R¹ may be alkyl, cycloalkyl, alkenyl, cycloalkenyl, alkyne, alkynyl, cycloalkynyl, aryl, or heteroaryl. The term “sulphone” as used herein is represented by the formula R¹S(O)₂R², wherein R¹ and R² can be independently alkyl, cycloalkyl, alkenyl, cycloalkenyl, alkynyl, cycloalkynyl, aryl, or heteroaryl, as described herein. The term “sulfoxide” as used herein is represented by the formula R'S(O)R², wherein R¹ and R² can be independently alkyl, cycloalkyl, alkenyl, cycloalkenyl, alkynyl, cycloalkynyl, aryl, or heteroaryl, as described herein.

The term “sulfydryl” used herein is represented by the formula —SH.

As used herein, “R¹,” “R²,” “R³,” “Rⁿ” (wherein n is an integer) may independently have one or more of radicals listed above. For example, if R¹ is a linear alkyl, one of the hydrogen atoms of the alkyl may be optionally substituted with hydroxy, alkoxy, alkyl, halogen, and the like. Depending on the selected group, the first group can be bound to the second group, or alternatively the first group can be pendant (i.e., attached) to the second group. For example. For the phrase “alkyl containing amino”, the amino may be incorporated within the backbone of the alkyl. Alternatively, amino can be connected to the backbone of the alkyl. The nature of the selected group will determine whether the first group is embedded or attached to the second group.

The complex described herein may contain “optionally substituted” moieties. In general, the term “substituted” (whether or not the term “optionally” precedes) means that the indicated portion of one or more hydrogens is replaced by a suitable substituent. Unless otherwise specified, an “optionally substituted” group may have a suitable substituent at each substitutable position of the group, and more than one may be substituted when there is more than one position in any given structure, when selected from the group of substituents, the substituents at each position may be the same or different. Combinations of substituents envisioned by the present disclosure are preferably those that form stable or chemically feasible complex. In certain aspects, unless clearly indicated to the contrary, it is also encompassed that each substituent may be further optionally substituted (i.e., further substituted or unsubstituted).

The structure of the complex can be represented by the following formula:

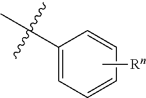

It should be understood to be equivalent to the following formula:

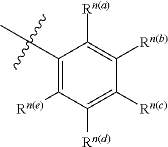

Wherein n is usually an integer. That is, WI is understood to represent five individual substituents R^{n(a)}, R^{n(b)}, R^{n(c)}, R^{n(d)}, R^{n(e)}. “Individual substituent” means each R may be independently defined. For example, if R^{n(a)} is halogen in one case, R^{n(b)} is not necessarily halogen in this case.

R¹, R², R³, R⁴, R⁵, R⁶ etc. are mentioned several times in the chemical structures and moieties disclosed and described herein. Any description of R¹, R², R³, R⁴, R⁵, R⁶ etc. in the specification is applicable to any structure or moieties cited R¹, R², R³, R⁴, R⁵, R⁶ etc, respectively, unless otherwise specified.

For many reasons, the use of organic materials of optoelectronic devices has become more and more urgent. Many of the materials used to make such devices are relatively inexpensive, so organic optoelectronic devices have the potential for cost advantages over inorganic devices. In addition, the inherent properties of organic materials, such as their flexibility, can make them very suitable for special applications such as manufacturing on flexible substrates. Examples of organic optoelectronic devices include organic light emitting devices (OLED), organic phototransistors, organic photovoltaic cells and organic photodetectors. For OLED, organic materials may have performance advantages over conventional materials. For example, the wavelength of light emitted by an organic light emitting layer can usually be easily tuned with a suitable dopant.

Excitons decay from a singlet excited state to a ground state to produce instant luminescence, which is fluorescence. If the exciton decays from the triplet excited state to the ground state to generate light emission, this is phosphorescent. Because of the spin-orbit coupling of heavy metal atoms between the singlet state and the triplet excited state, which effectively enhances intersystem crossing (ISC), phosphorescent metal complexes (e.g., platinum complexes) have shown their simultaneous using the potential of singlet and triplet excitons, 100% of internal quantum efficiency is achieved. Therefore, phosphorescent metal complexes are a good candidates for dopants in the emission layer of organic light emitting devices (OLED), and have received great attention in academic and industrial fields. In the past decade, it have made many achievements, resulting in a profitable commercialization of the technology, for example, OLED has been used for advanced displays of smart phones, a senior display of television and digital camera.

However, blue electroluminescent devices are still the most challenging areas of the technology by far, and the stability of blue devices is a big problem. It has been demonstrated that the choice of host material is very important for the stability of blue devices. However, the lowest energy of the triplet excited state (Ti) of the blue luminescent material is very high, which means that the lowest energy of the triplet excited state (Ti) of the host material of the blue device should be higher. This has led to an increased difficulty in the development of the host material of the blue device.

The metal complexes of the present disclosure can be customized or tuned to specific application that are expected to have specific emission or absorption characteristics. The optical properties of the metal complex in the disclosure can be adjusted by changing the structure of the ligand surrounding the metal center or changing the structure of the fluorescent light emitter on the ligand. For example, in emission and absorption spectra, metal complexes or electron withdrawing substituents having ligands that donate electrons can generally exhibit different optical properties. The color of the metal complex can be adjusted by modifying the conjugated group on the fluorescent emitter and the ligand.

The emission of such complex according to the present disclosure can be adjusted, for example, by changing the structure of the ligand or the fluorescence emitter, for example from ultraviolet to near infrared. Fluorescent light emitters are a group of atoms in organic molecules that can absorb energy to produce singlet excited state, and singlet excitons decay rapidly to produce immediate luminescence. On the one hand, the complexes of the present disclosure can provide emission of most visible spectrum. On the other hand, the complexes of the present disclosure have improved stability and efficiency compared with the traditional emission complexes. In another aspect, the complexes of the present disclosure may be used in light emitting devices, such as compact fluorescent lamps (CFL), light emitting diodes (LED), incandescent lamps and combinations thereof.

The disclosure discloses a palladium-containing compounds or complexes. The term compound or complex may be used interchangeably herein.

The complexes disclosed herein may exhibit desired properties and have emission and/or absorption spectra that can be modulated by selecting suitable ligands. In another aspect, the present disclosure may exclude any one or more of complexes, structures or moieties thereof specifically described herein.

The complexes of the present disclosure may be prepared by a variety of methods, including but not limited to those described in the examples provided herein.

The complexes disclosed herein may be delayed fluorescence and/or phosphorescent emitters. On the one hand, the complexes disclosed herein may be a delayed fluorescence emitter. On the other hand, the complexes disclosed herein may be a phosphorescent emitter. On the other hand, the complexes disclosed herein may be a fluorescence emitter and a phosphorescent emitter.

One embodiment of the present disclosure relates to a tetradentate cyclic-metal platinum complex comprising 4-aryl-3,5-disubstituted pyrazole, its structure is shown in formula (I):

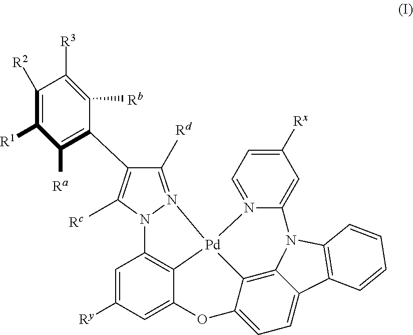

wherein

R^{a}, R^{b}, R^{c} and R^{d} are each independently alkyl, alkoxy, cycloalkyl, ether, heterocyclyl, hydroxy, aryl, heteroaryl, aryloxy, mono- or di-alkylamino, mono- or di-arylamino, halogen, sulfydryl, cyano, or combinations thereof;

R^{x} is alkyl, alkoxy, cycloalkyl, heterocyclyl, ether, mono- or di-alkylamino, mono- or di-arylamino, halogen, or combination thereof;

R^{y} is H, deuterium, alkyl, alkoxy, cycloalkyl, heterocyclyl, ether, mono- or di-alkylamino, mono- or di-arylamino, halogen, or combination thereof;

R¹, R², and R³ are each independently H, deuterium, alkyl, alkoxy, ether, cycloalkyl, heterocyclyl, hydroxy, aryl, heteroaryl, aryloxy, mono- or di-alkylamino, mono- or di-arylamino, halogen, sulfydryl, cyano, haloalkyl, or combinations thereof.

In one embodiment of the present disclosure, for any structure disclosed herein, wherein the structure unit

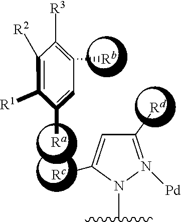

may independently represent the following structures, but are not limited to the following structures:

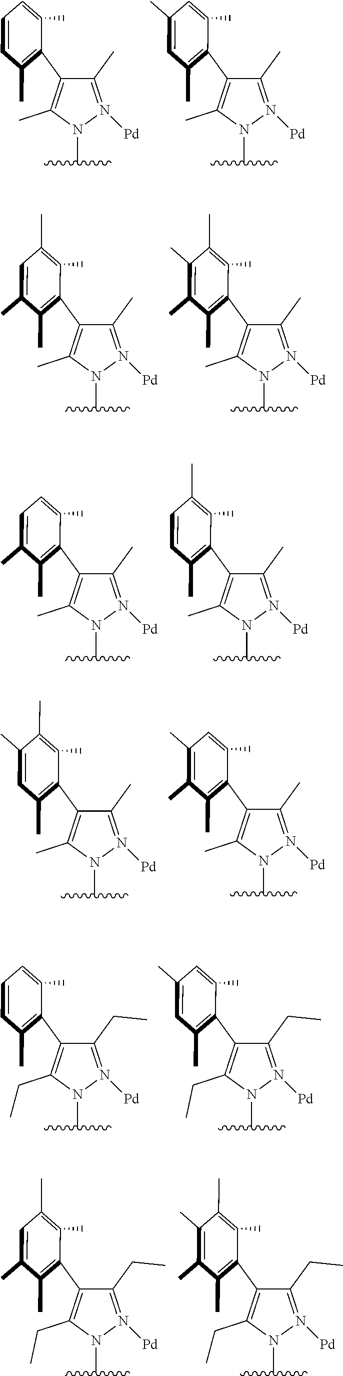

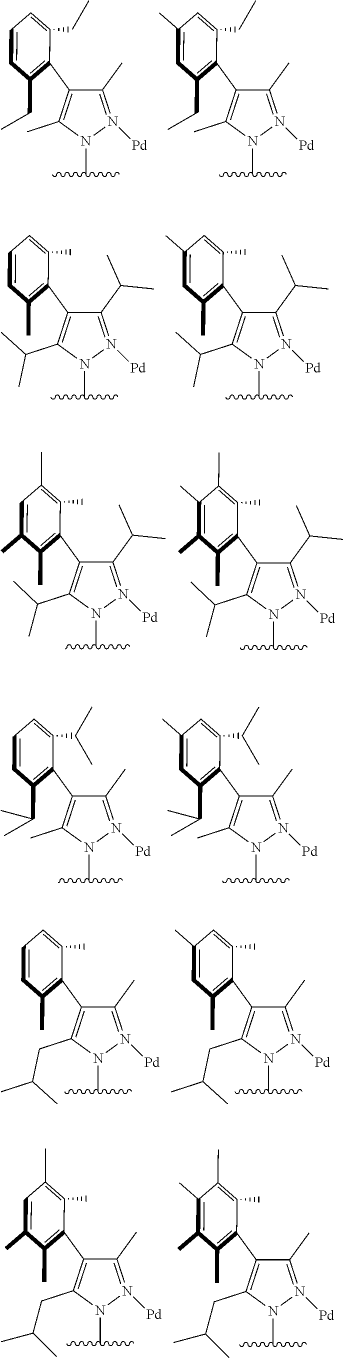

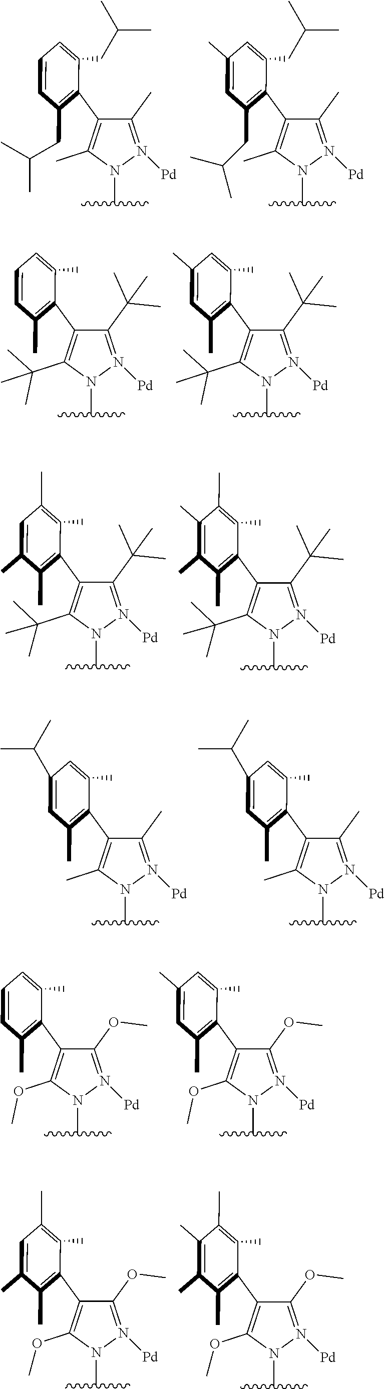

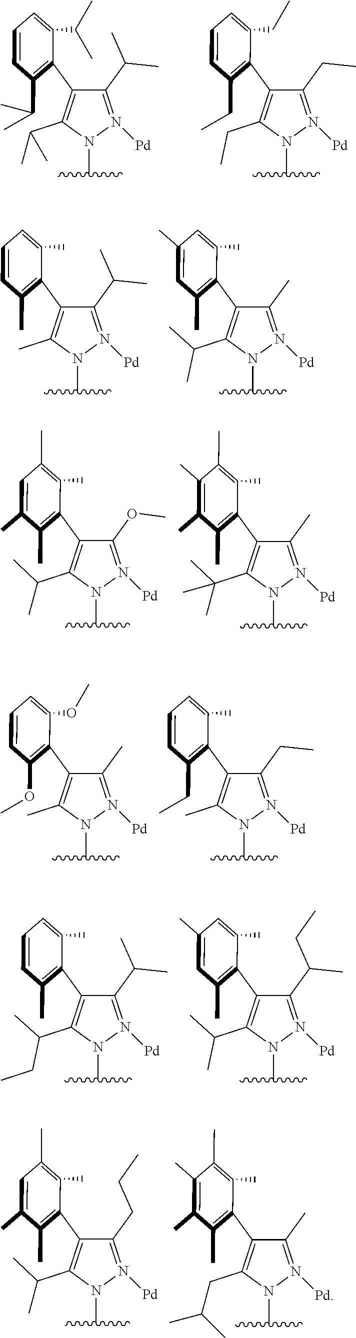

In some embodiments of the present disclosure, the tetradentate cyclic-metal palladium complex comprising 4-aryl-3,5-disubstituted pyrazol has a structure selected from one of the following Pt1-Pt884:

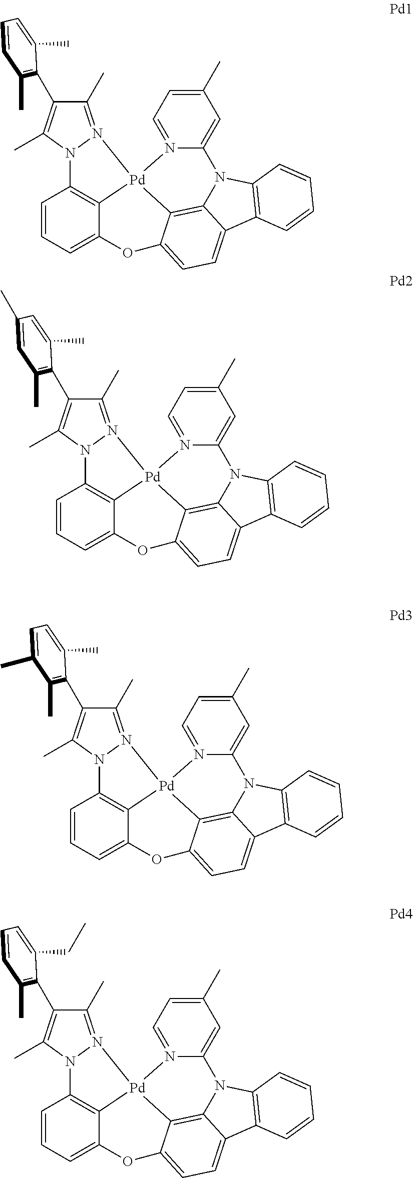

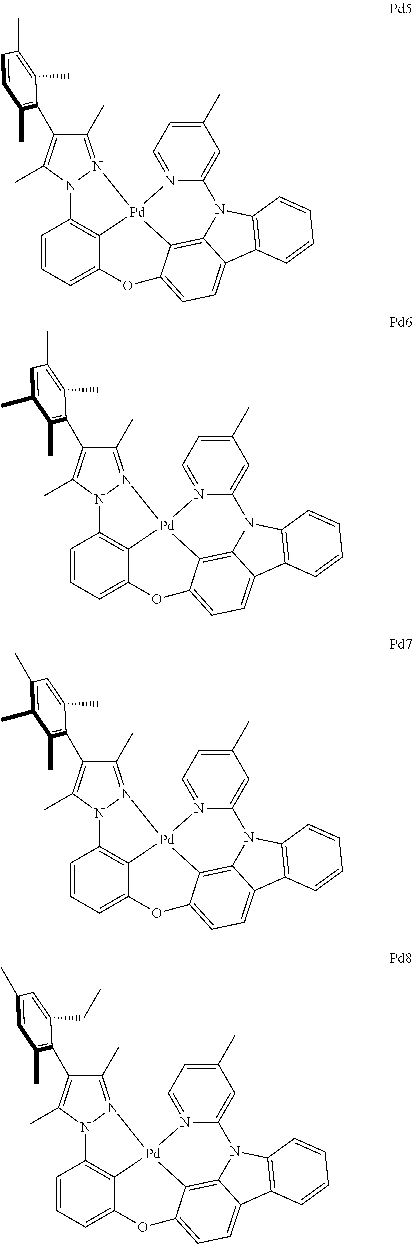

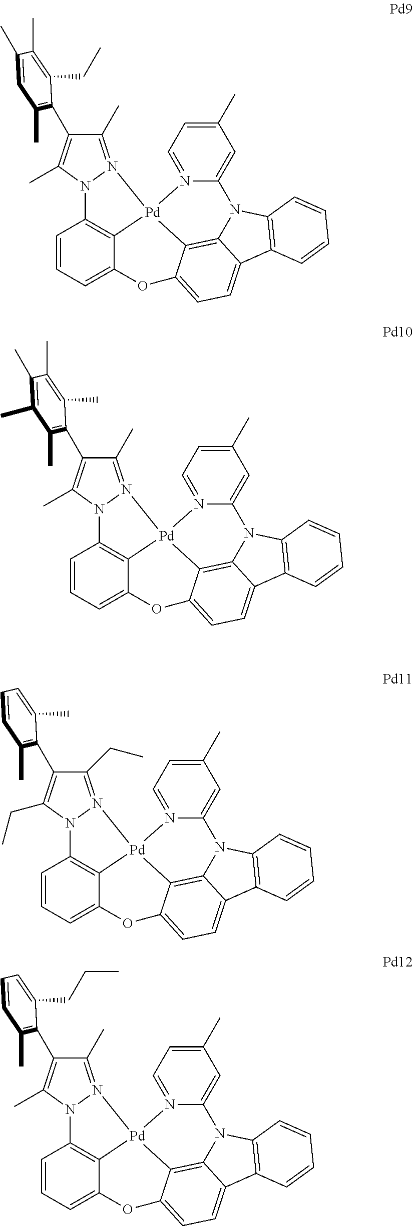

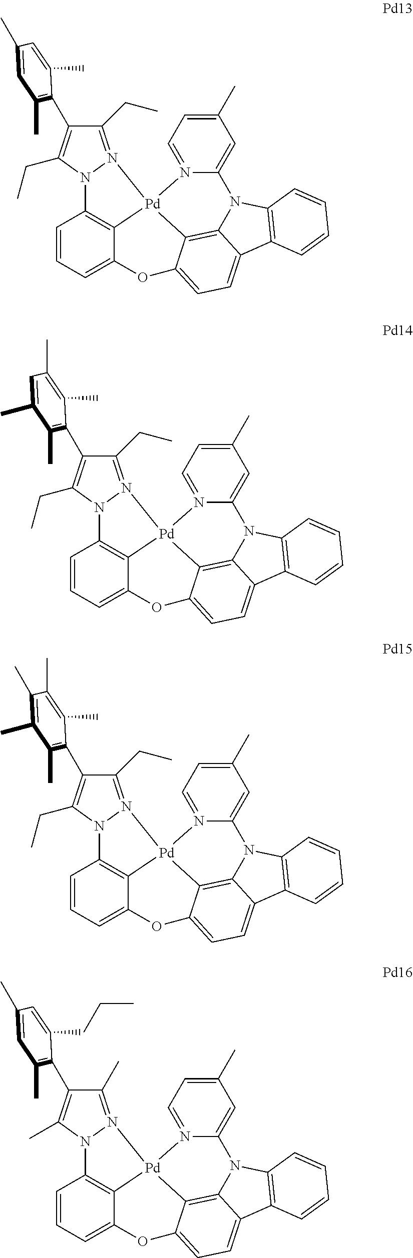

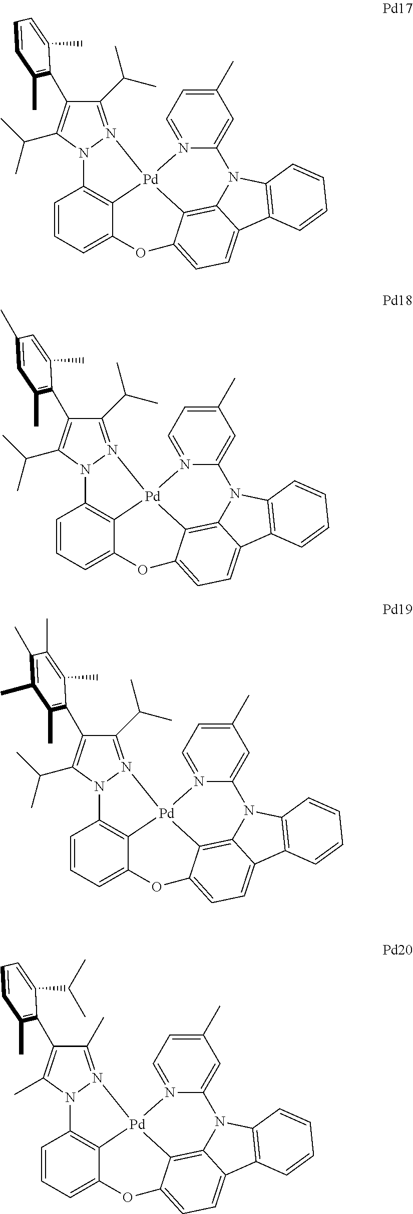

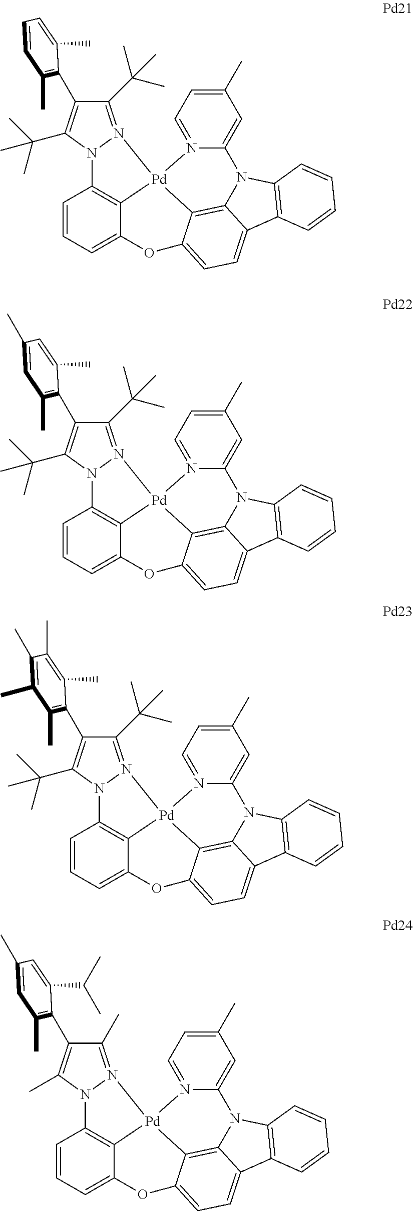

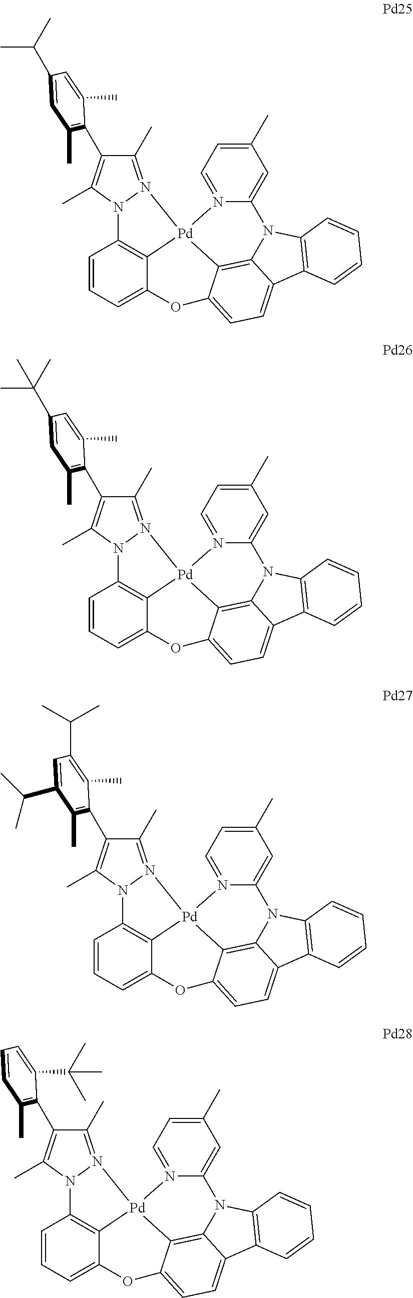

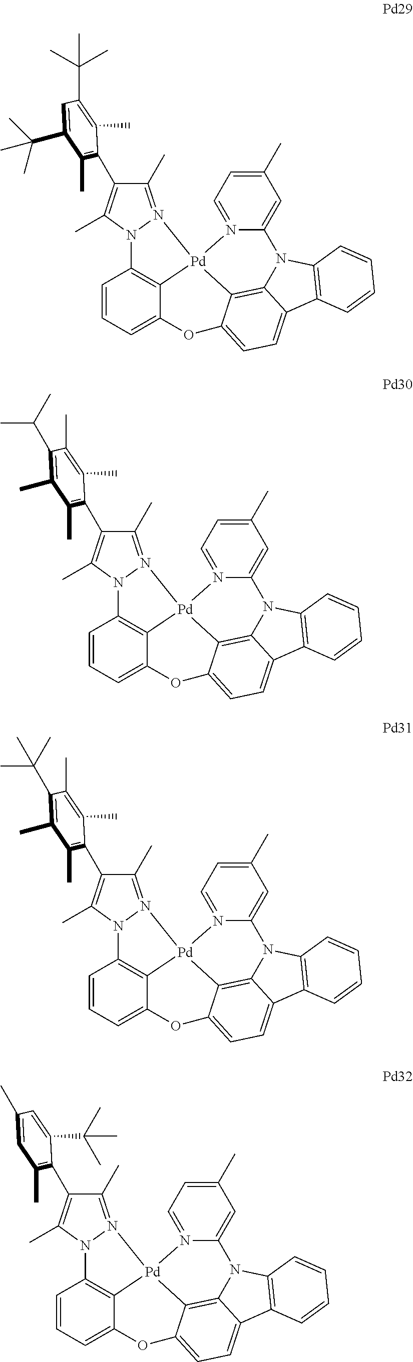

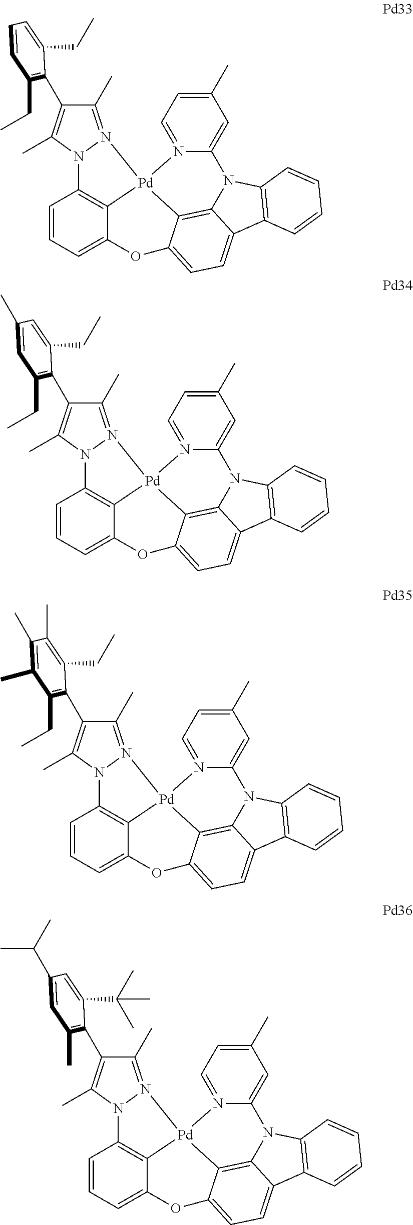

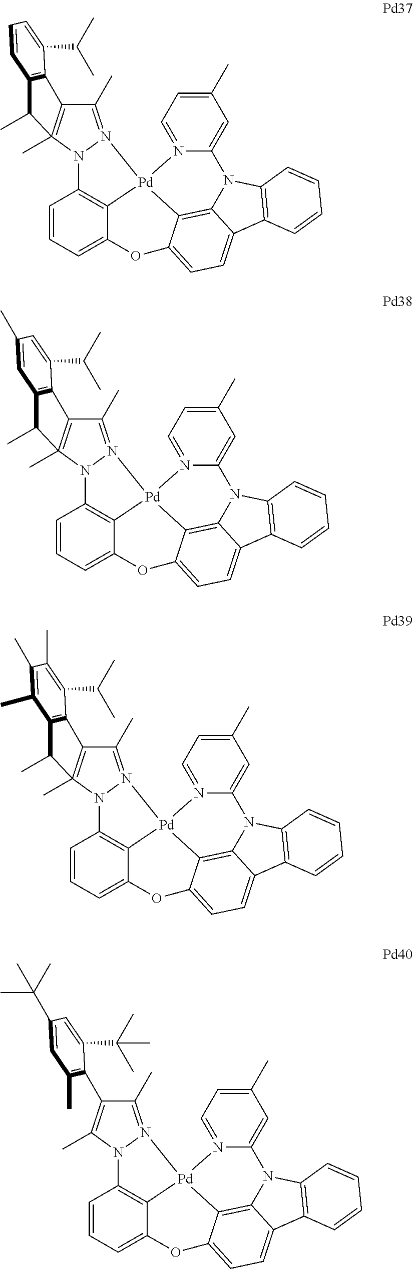

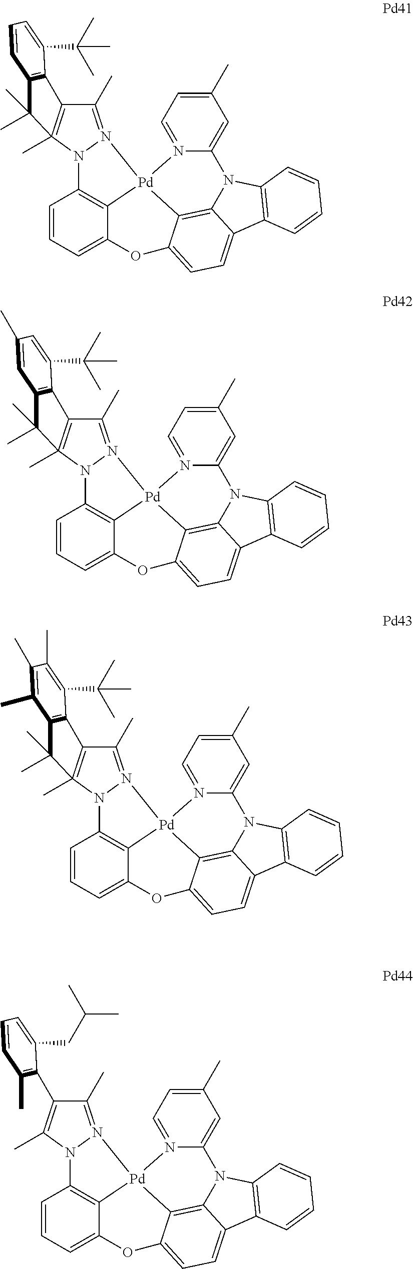

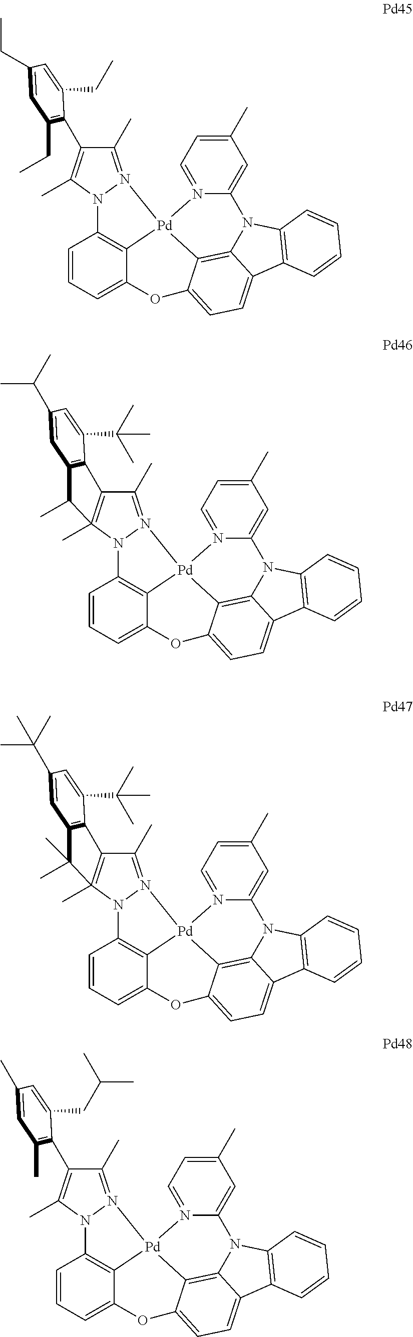

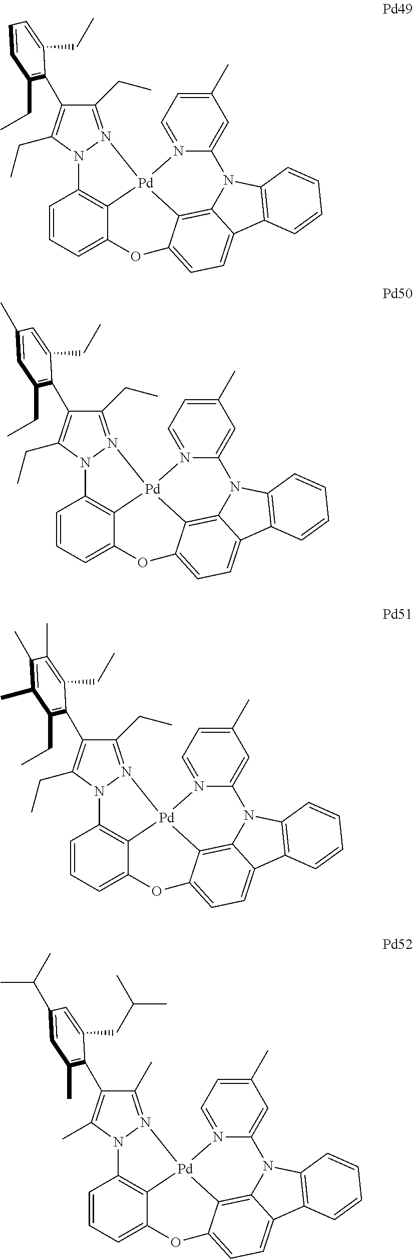

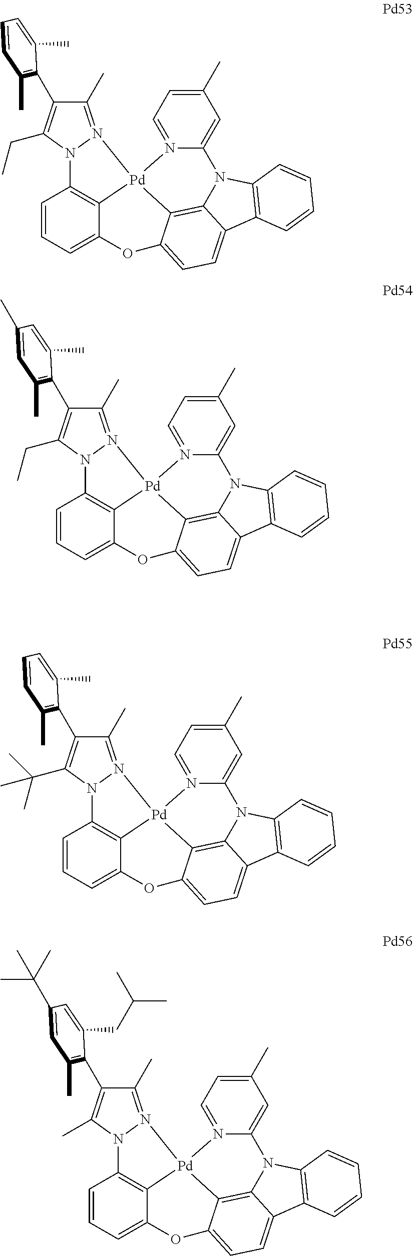

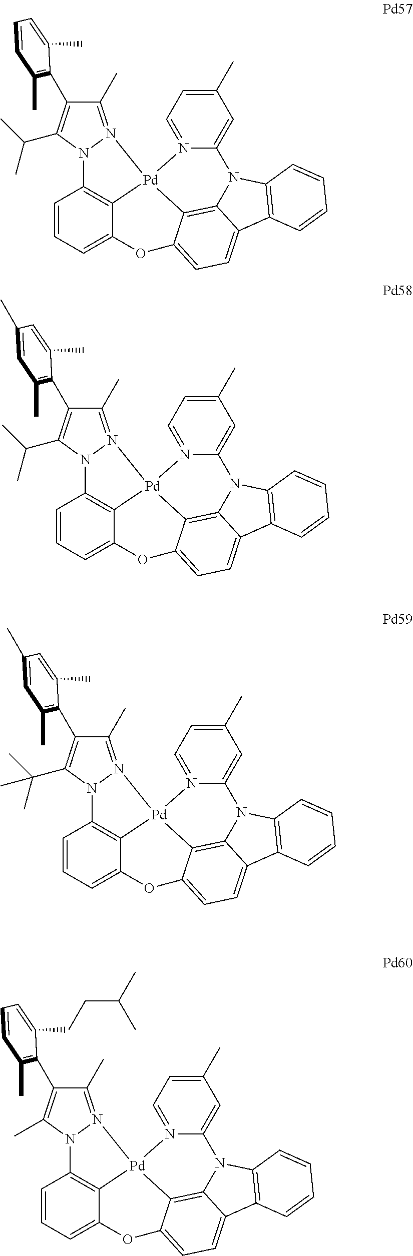

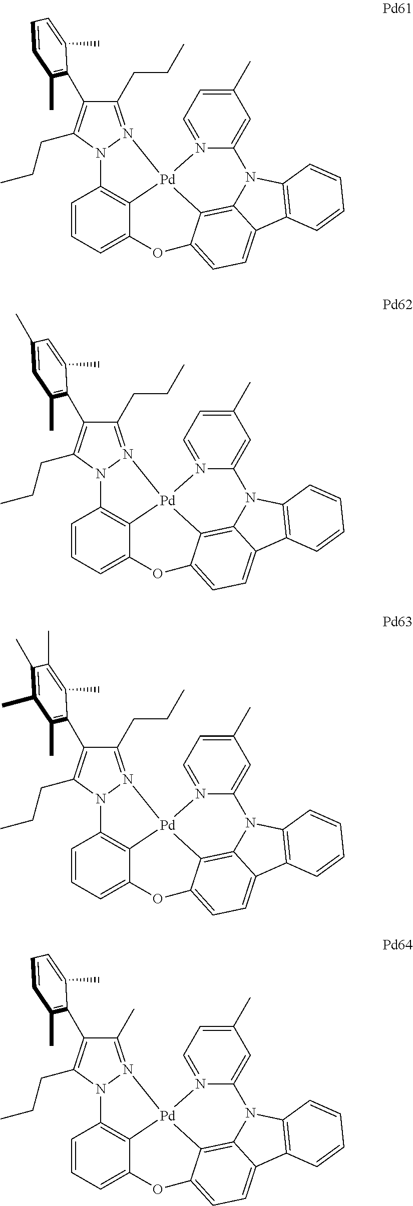

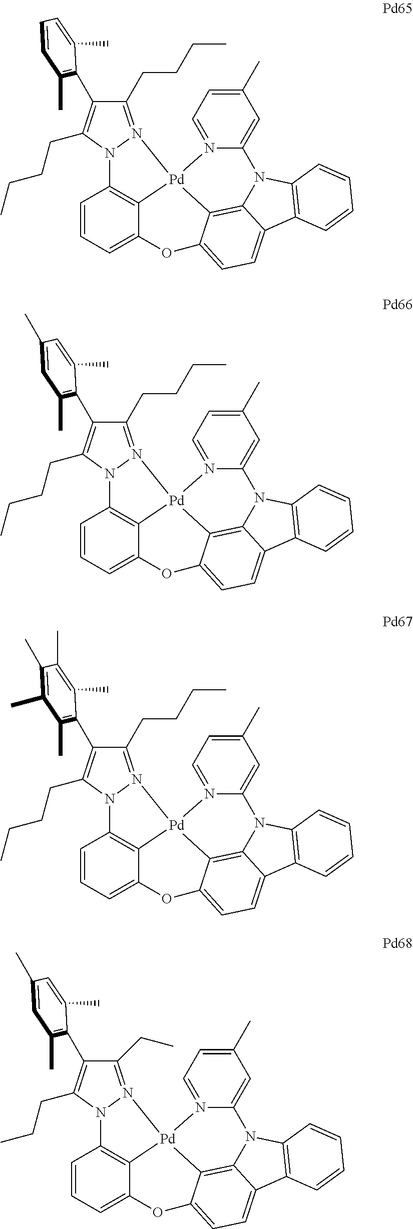

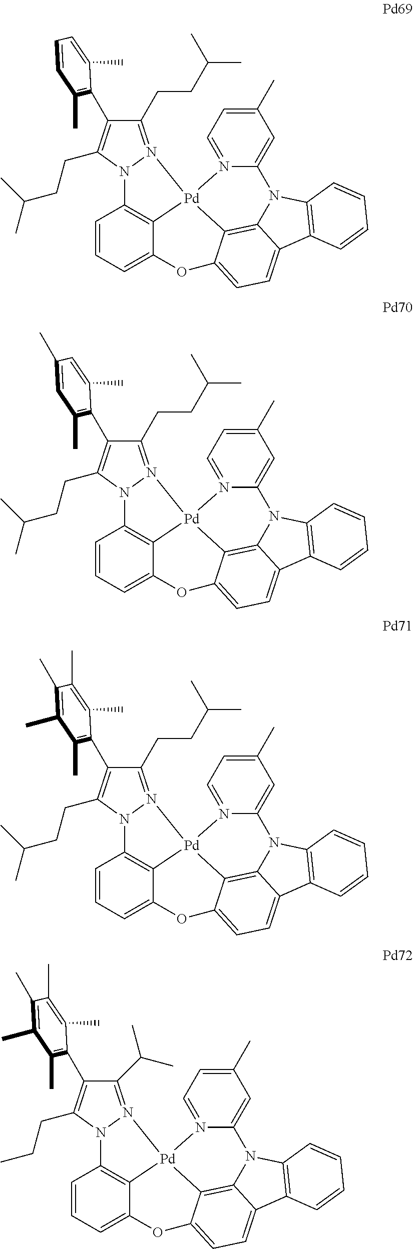

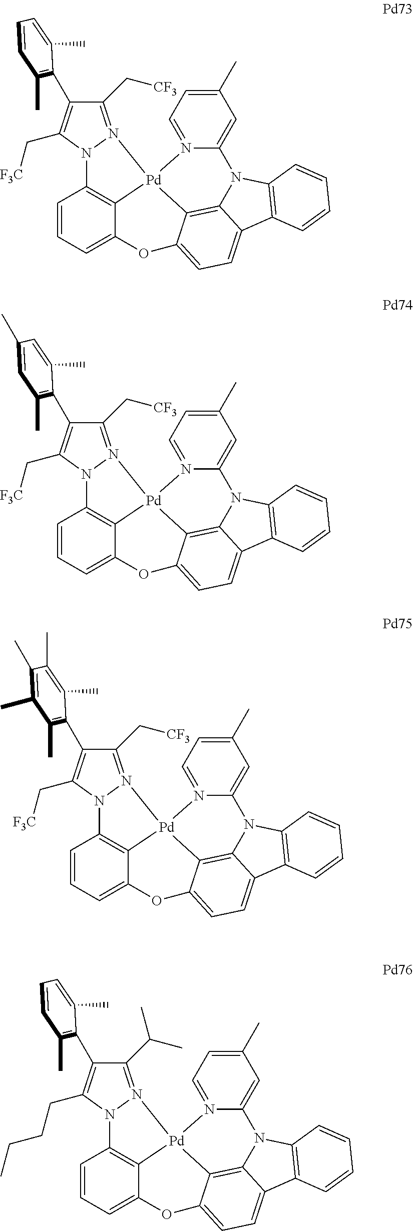

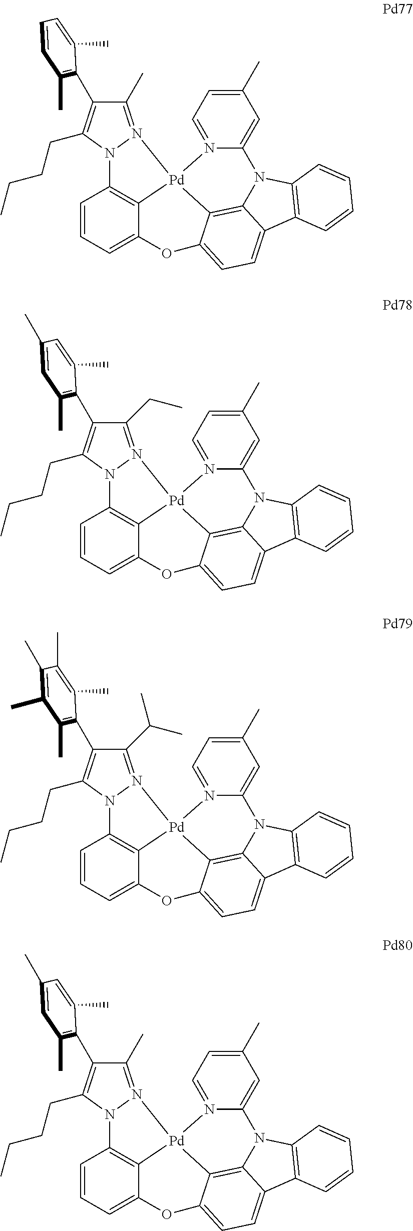

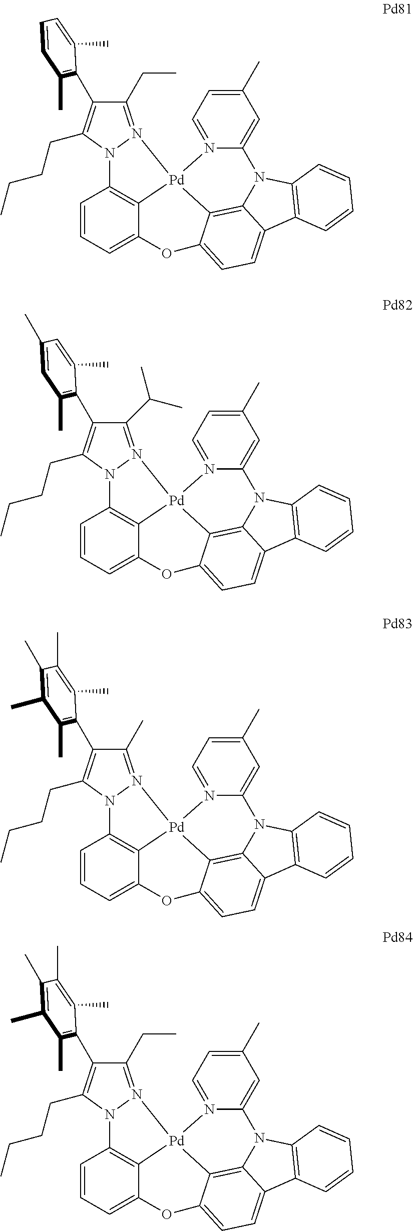

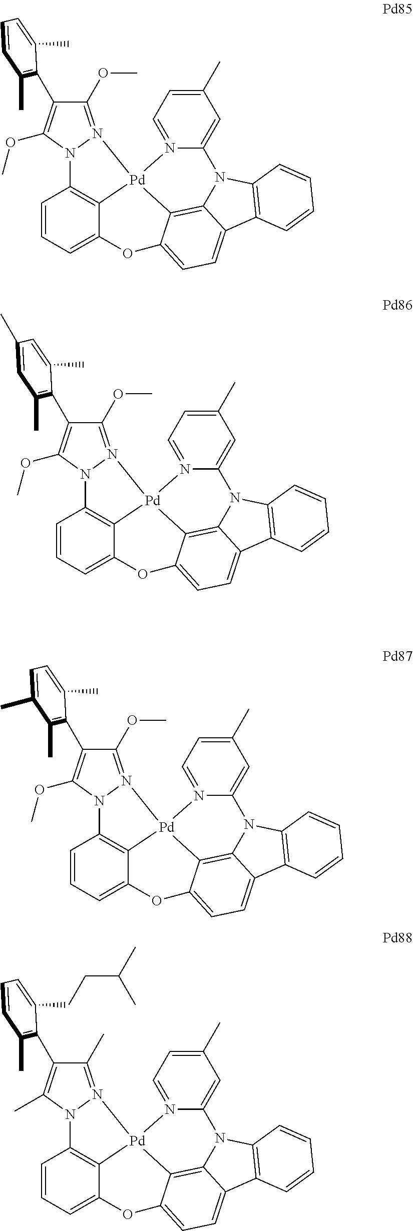

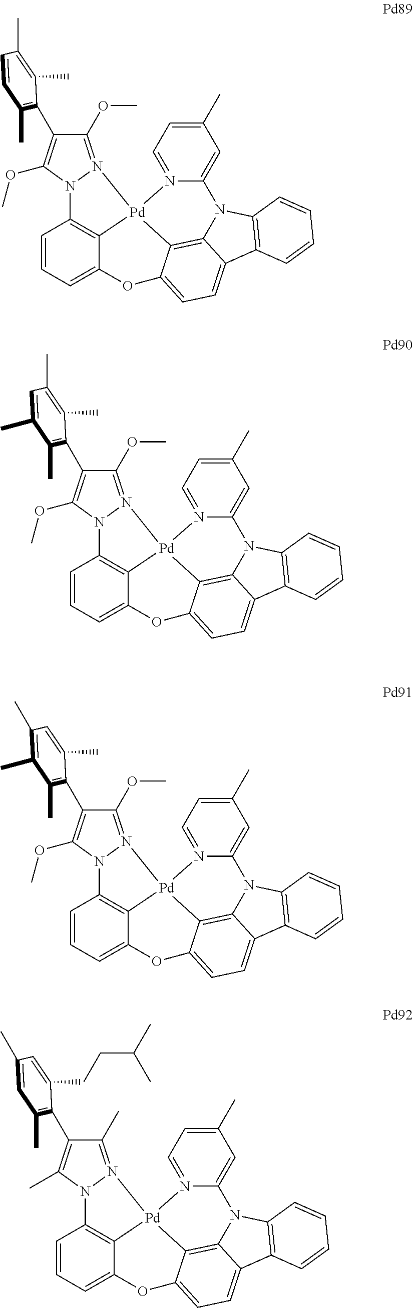

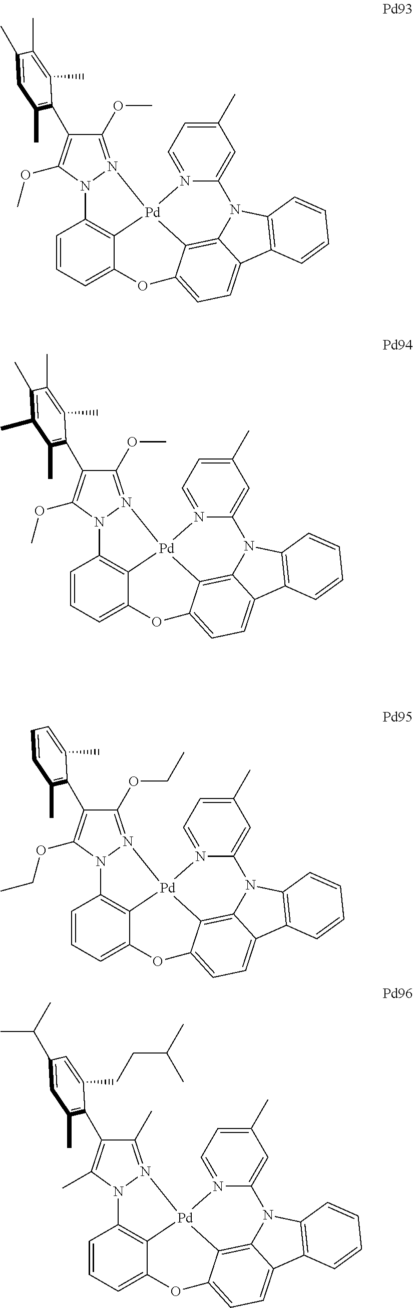

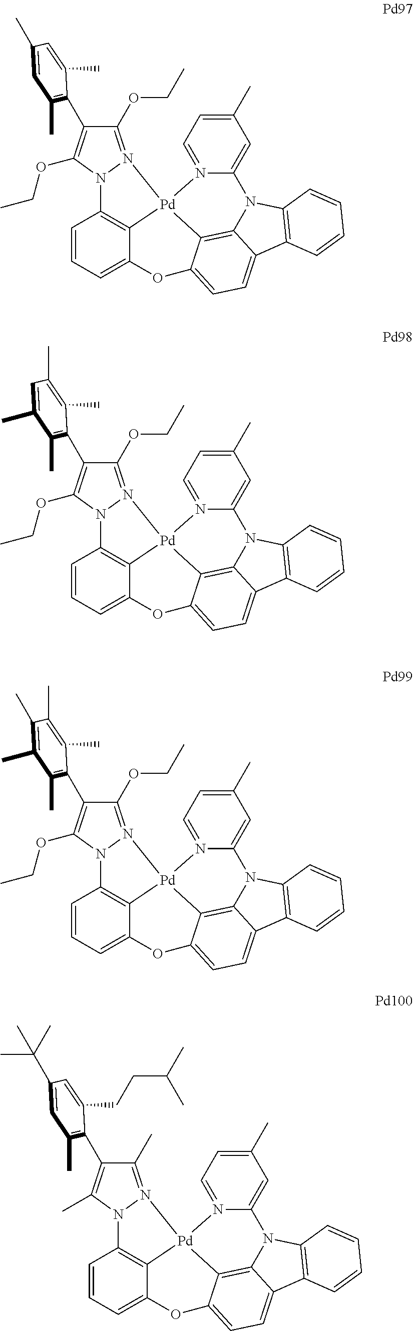

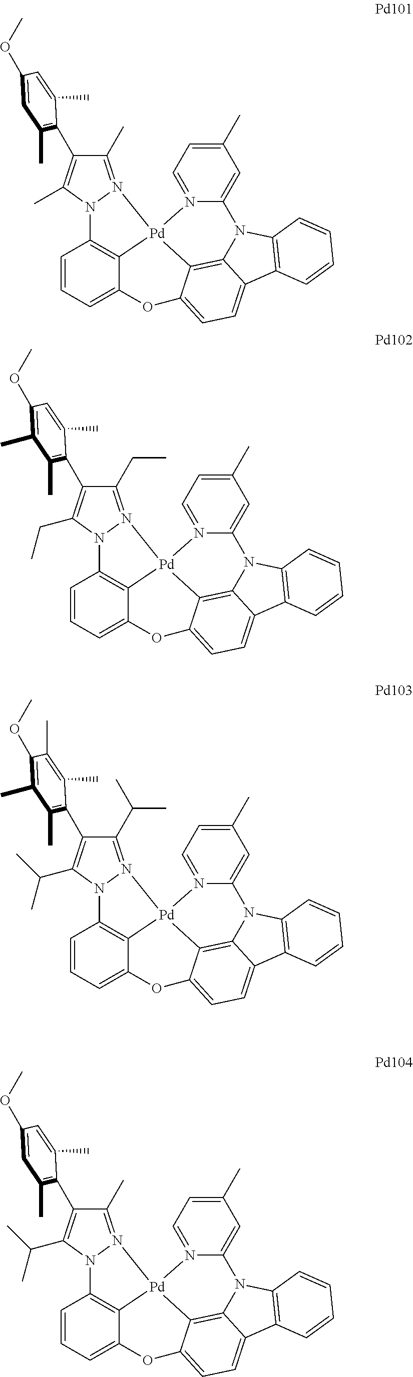

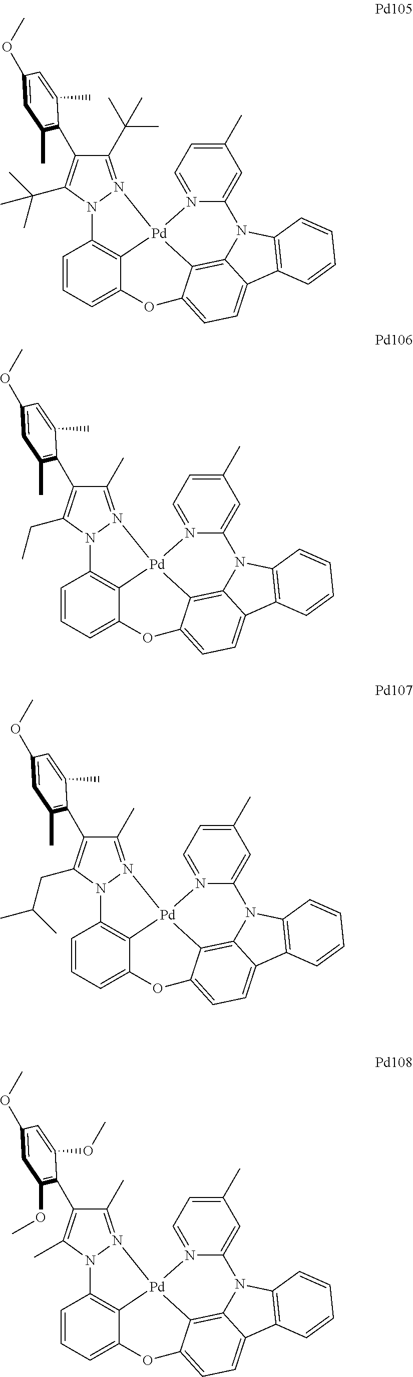

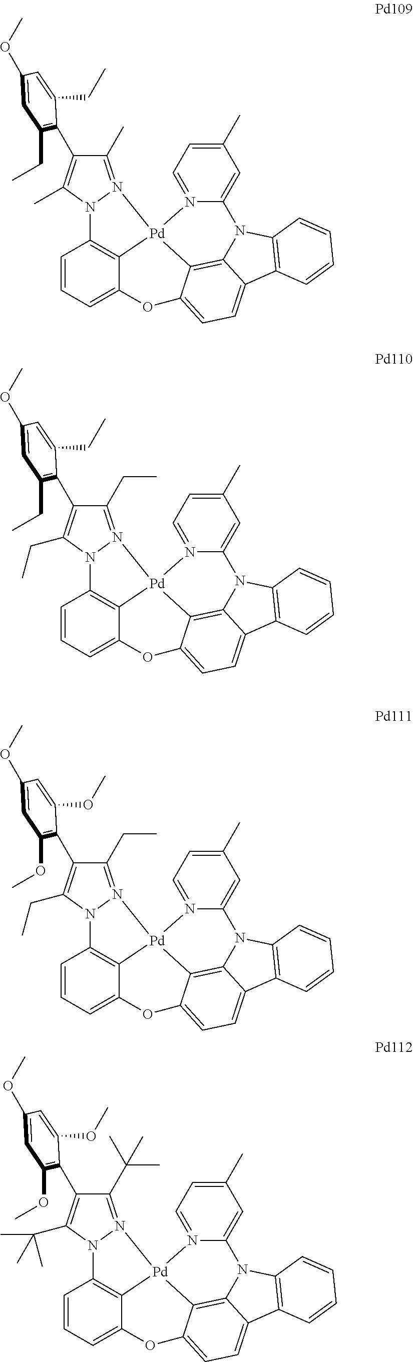

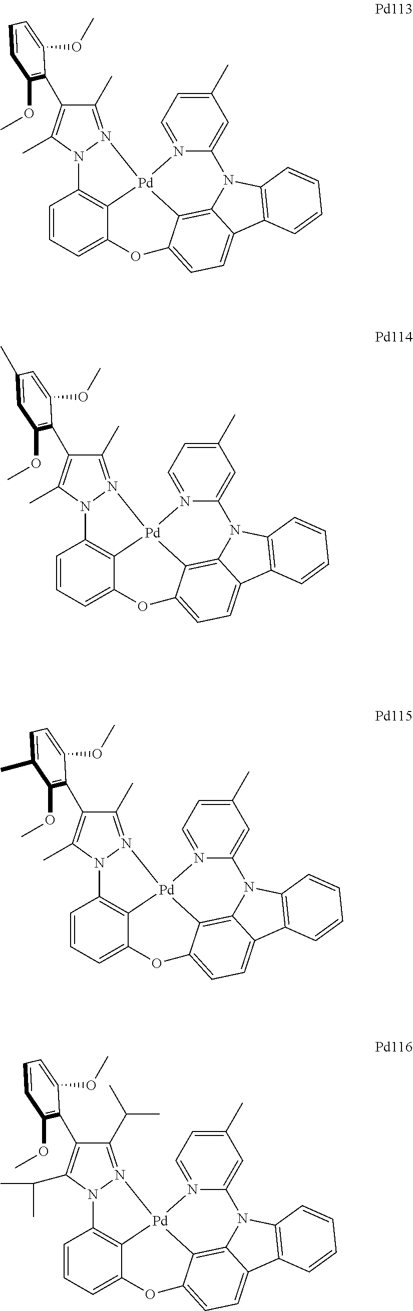

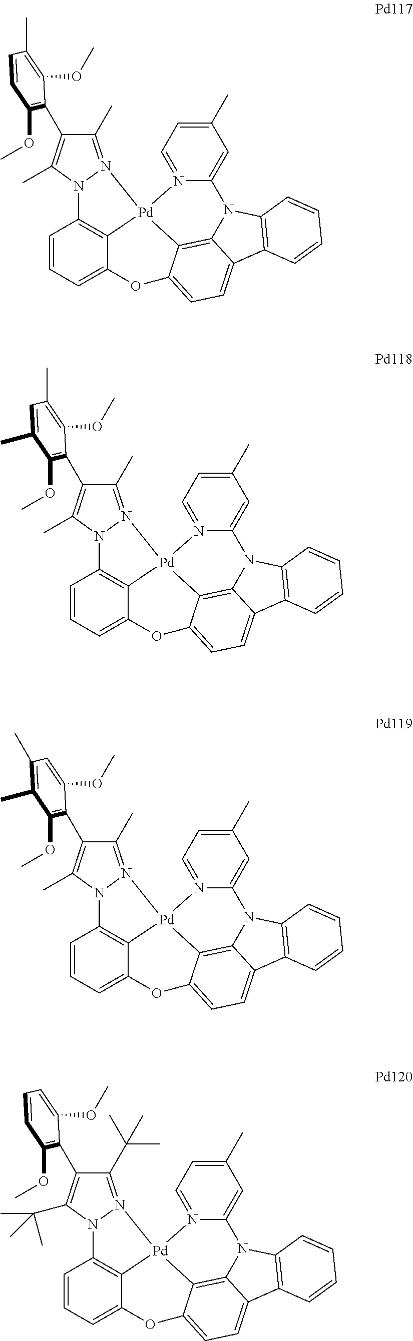

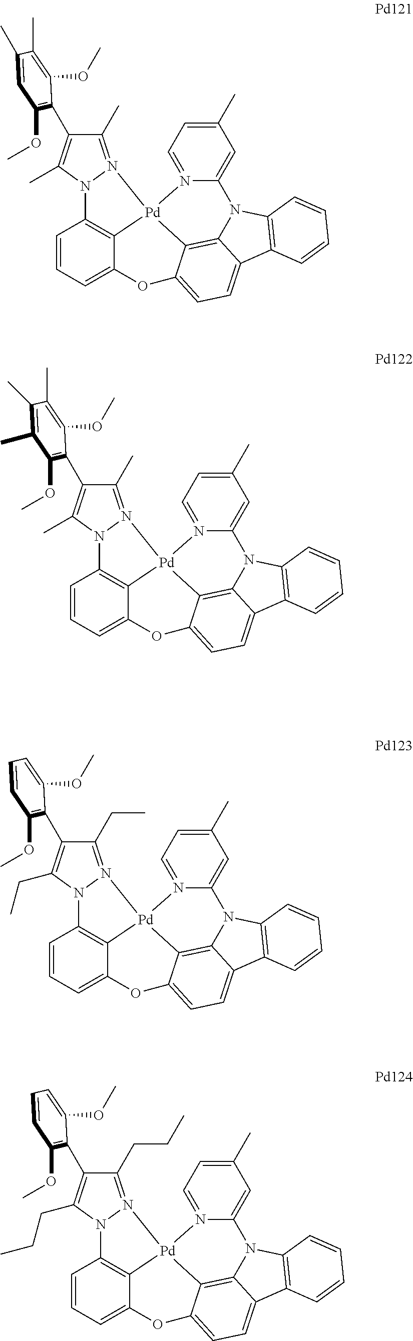

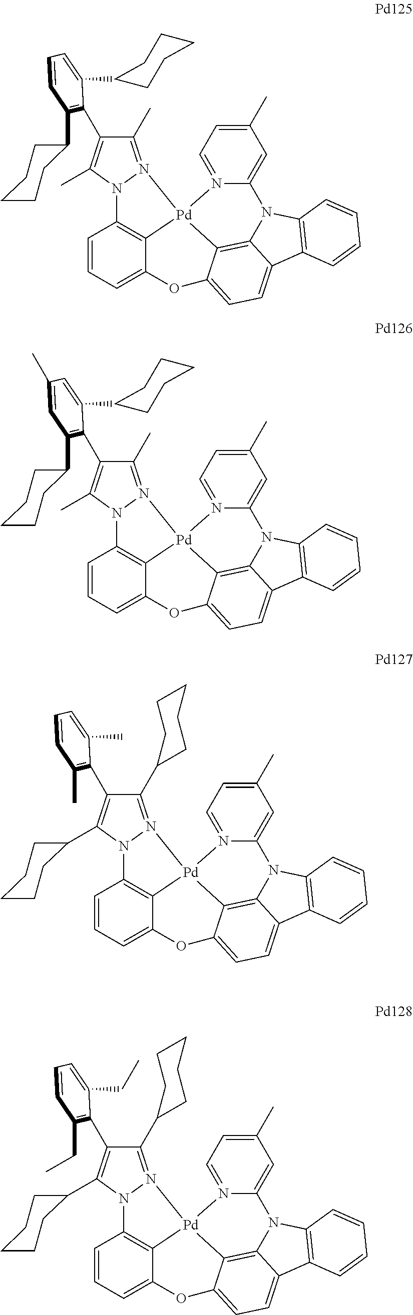

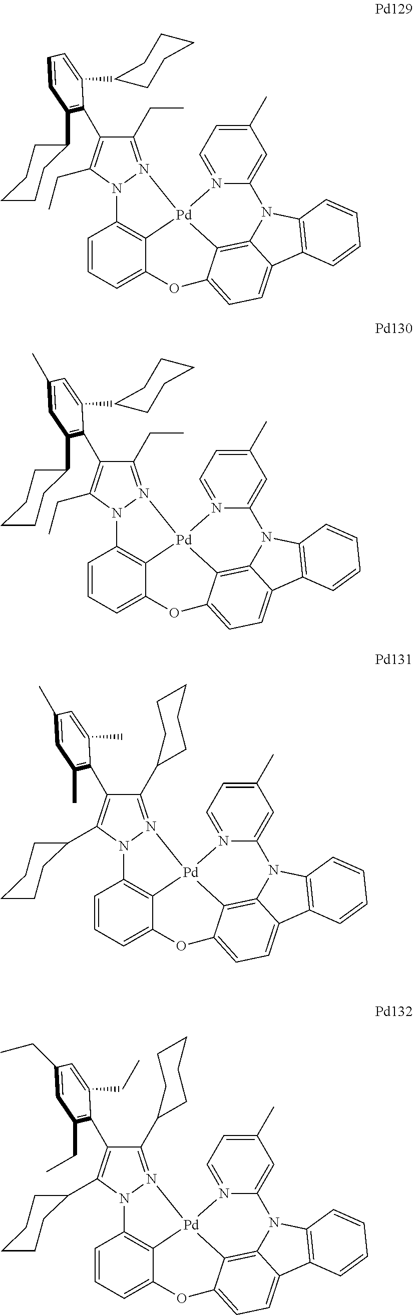

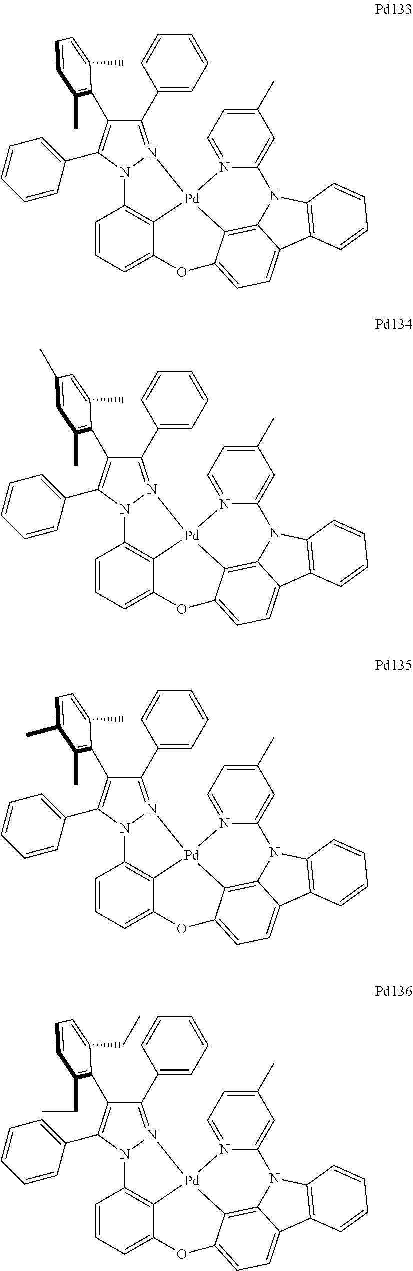

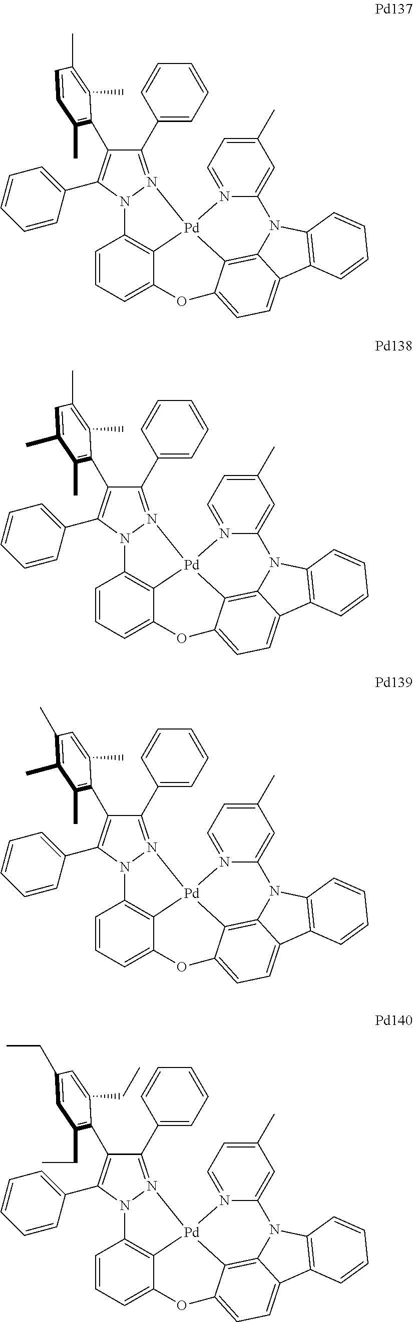

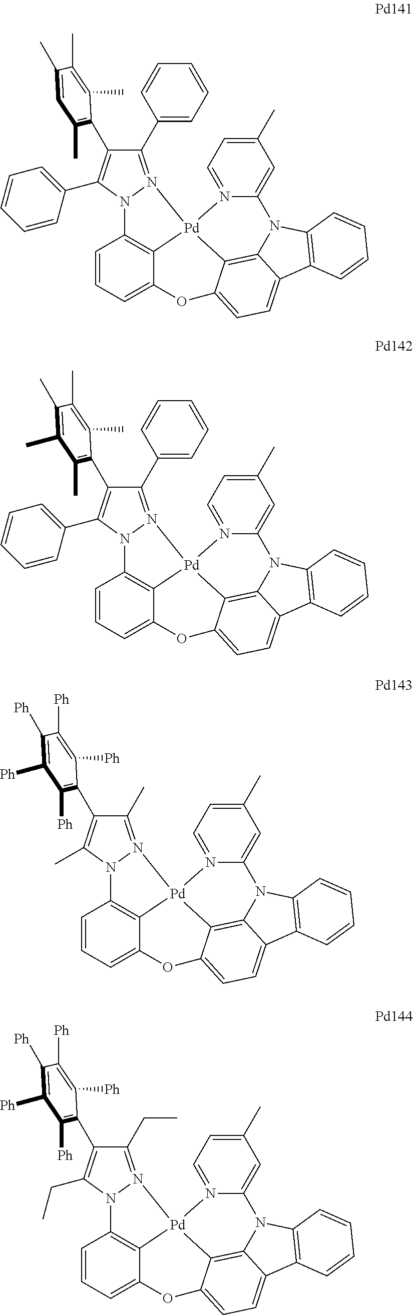

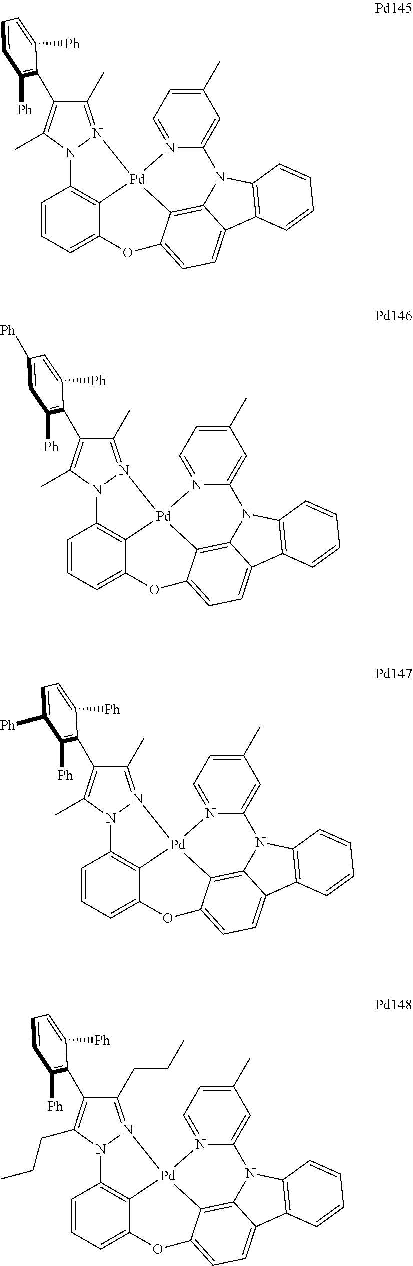

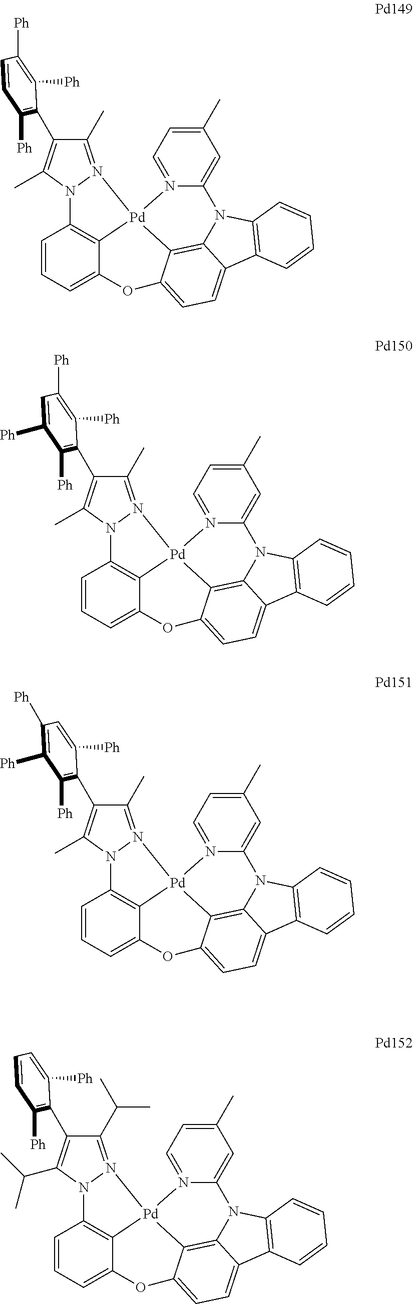

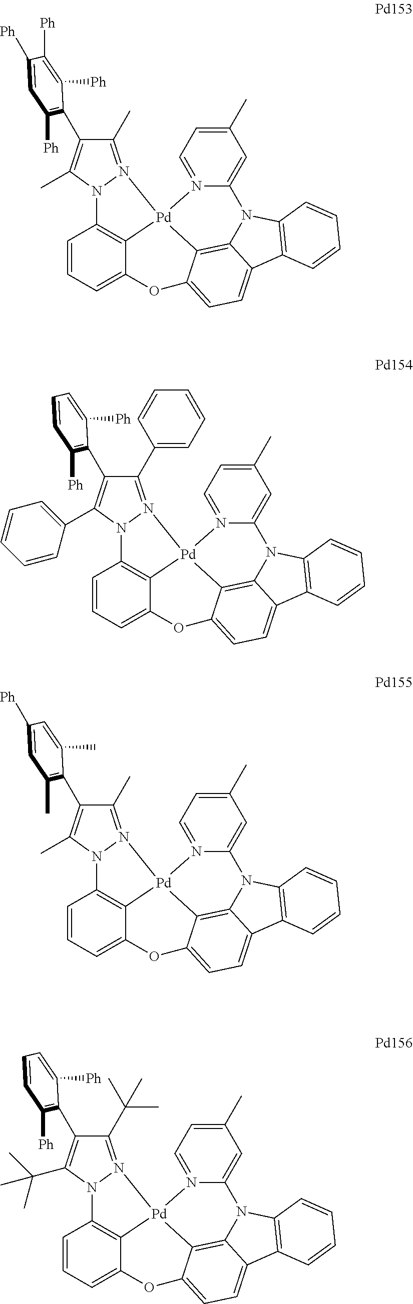

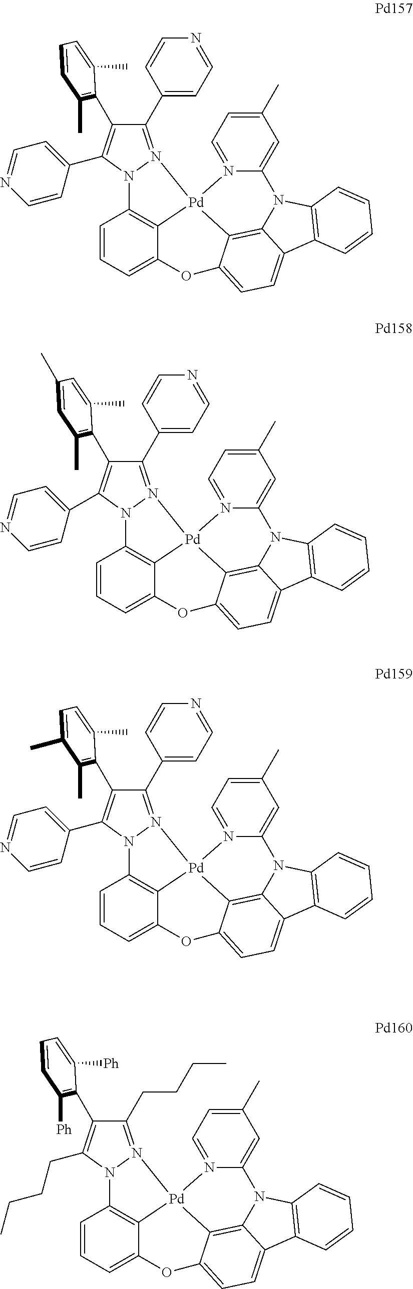

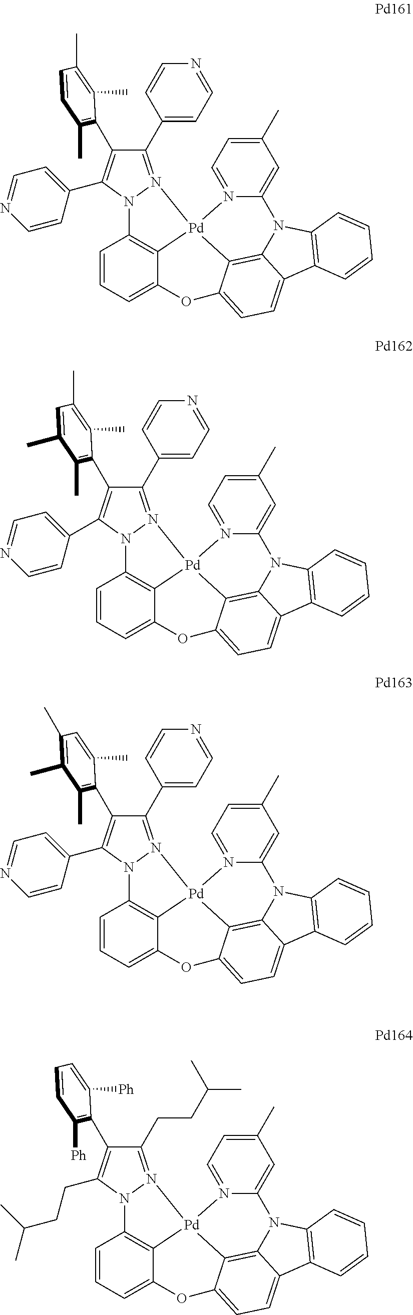

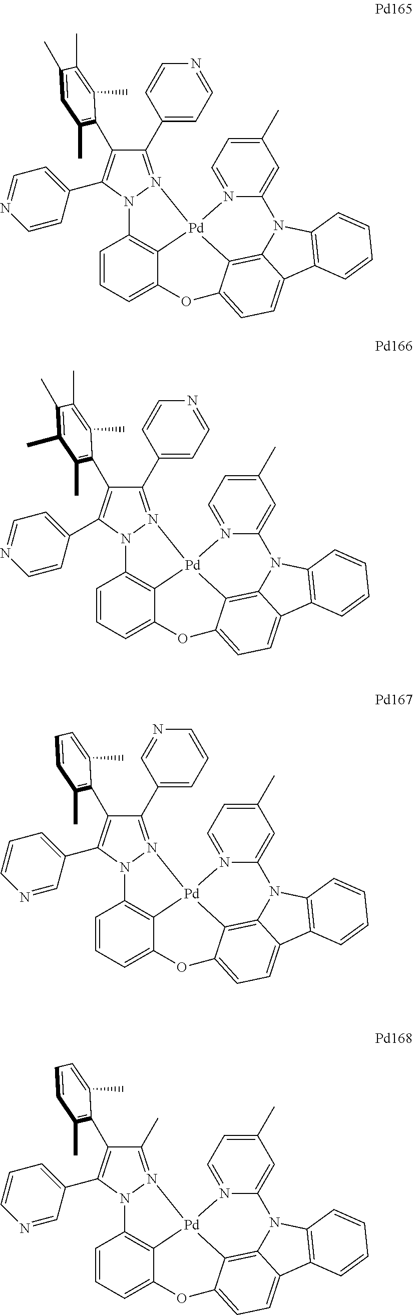

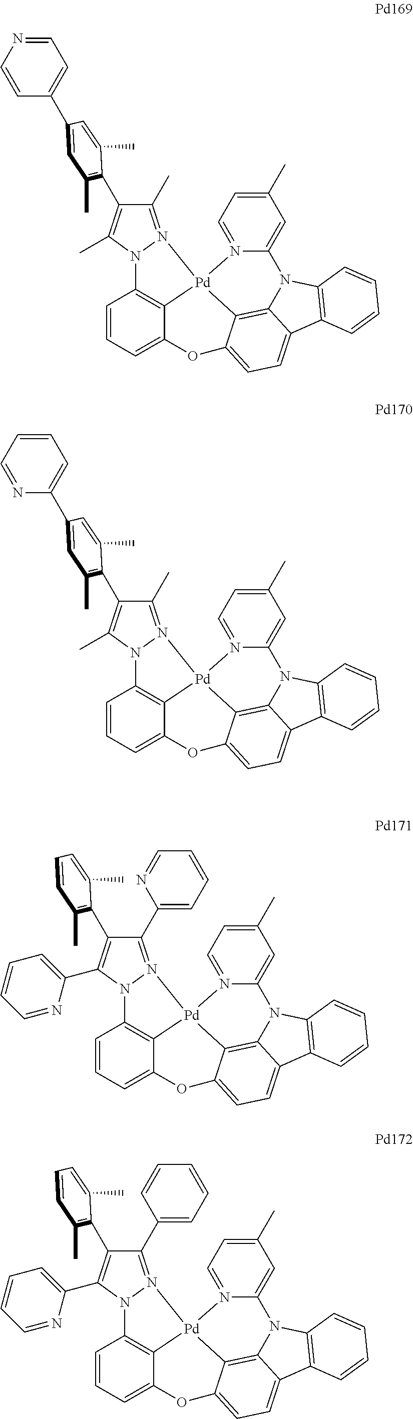

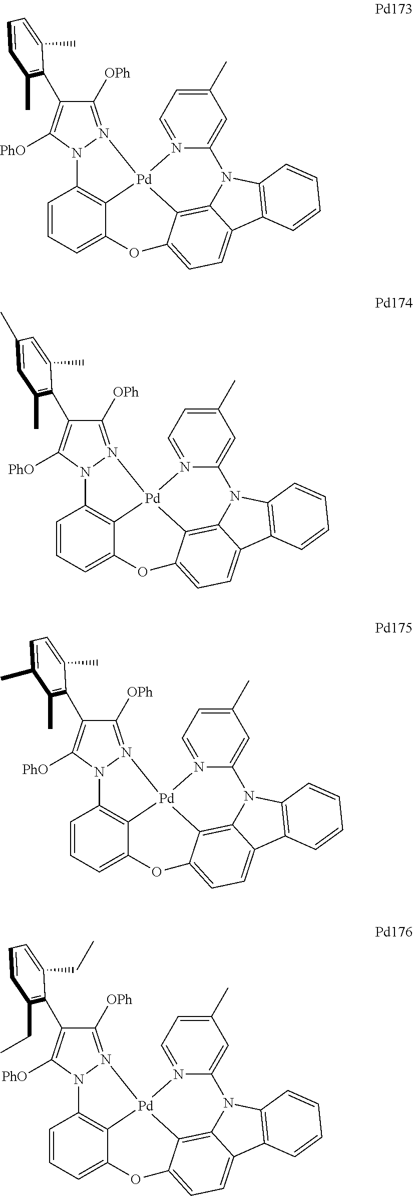

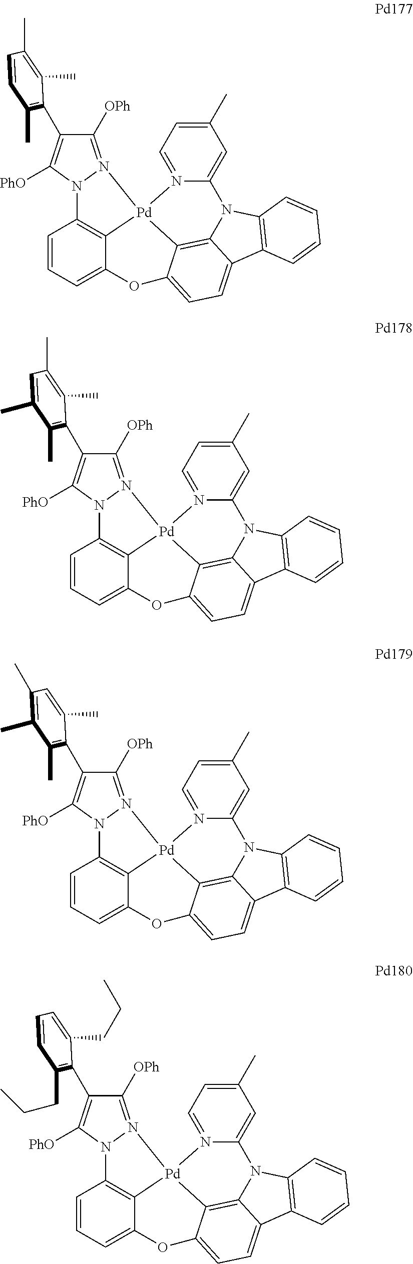

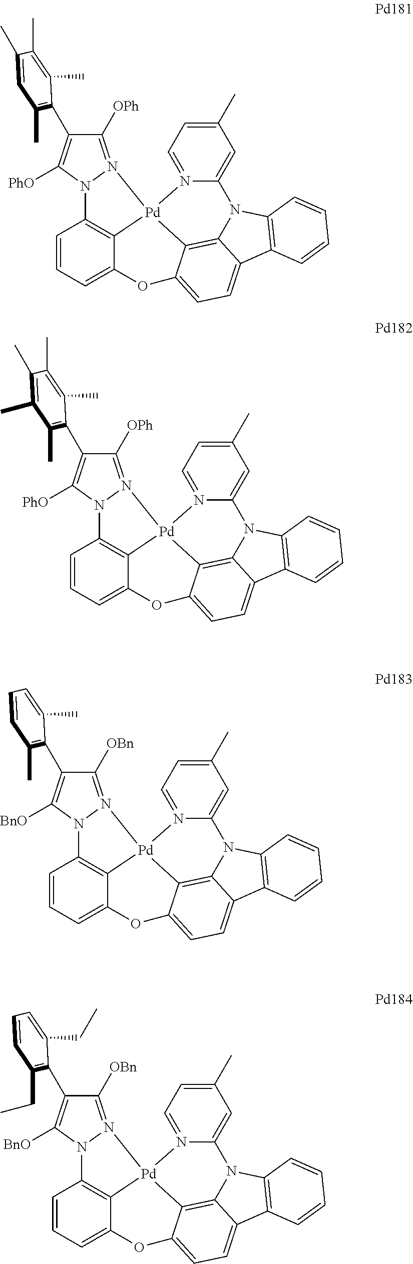

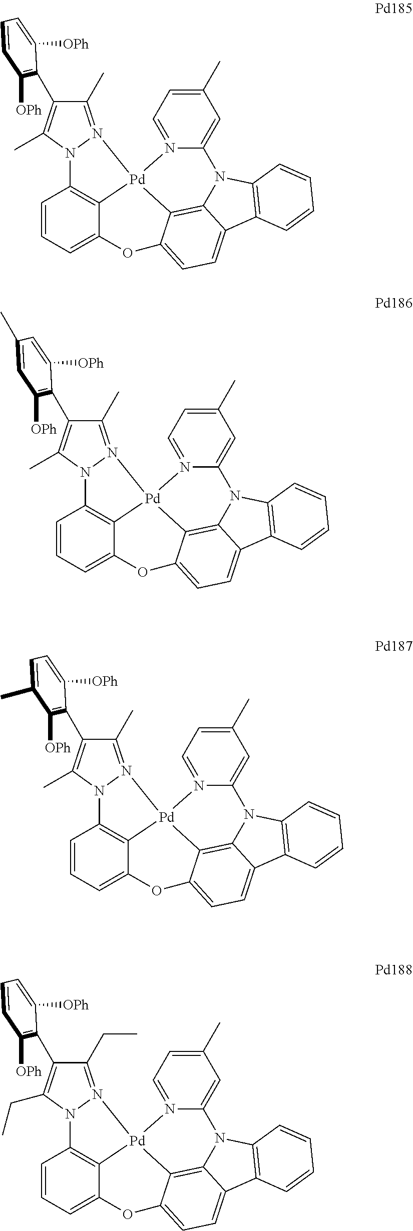

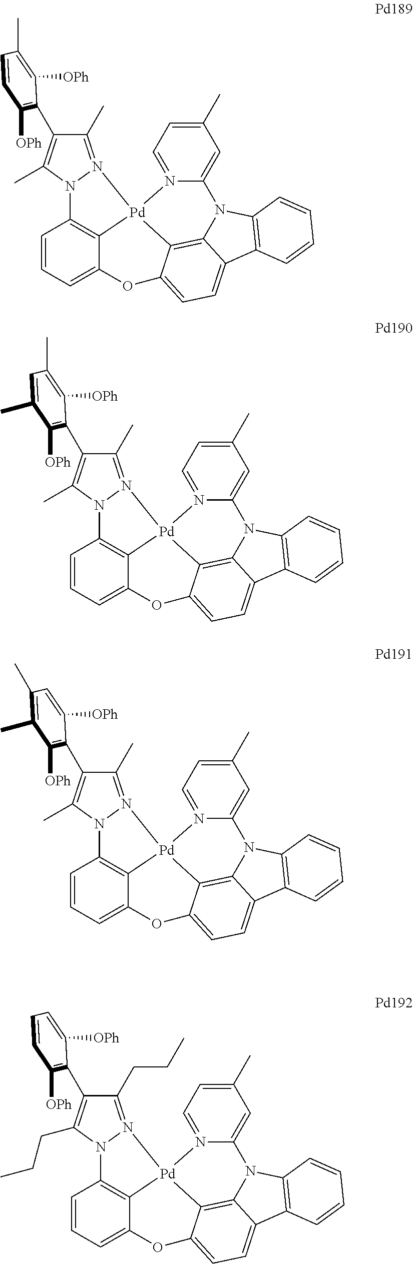

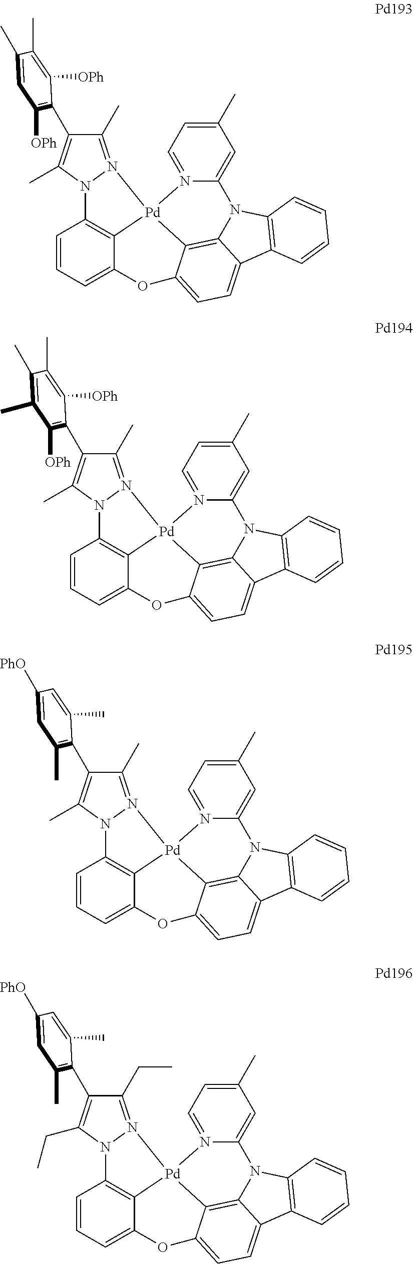

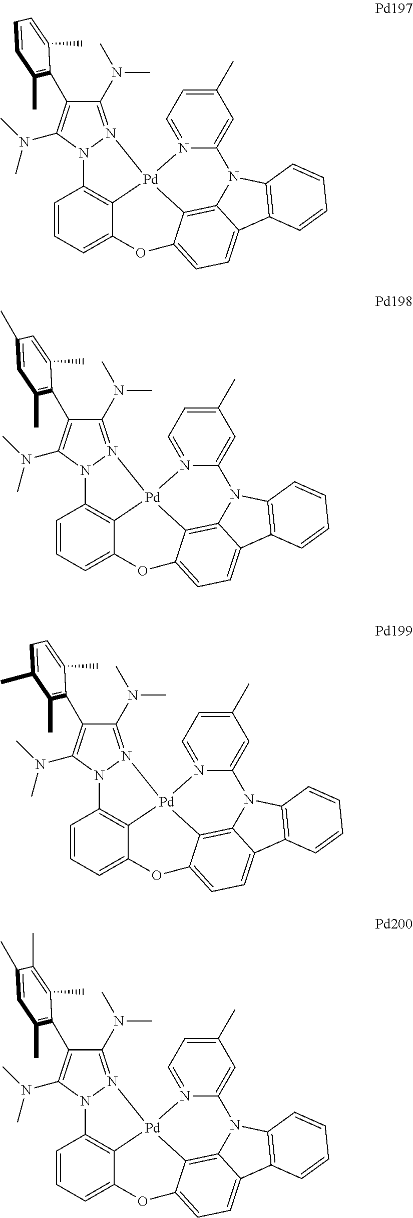

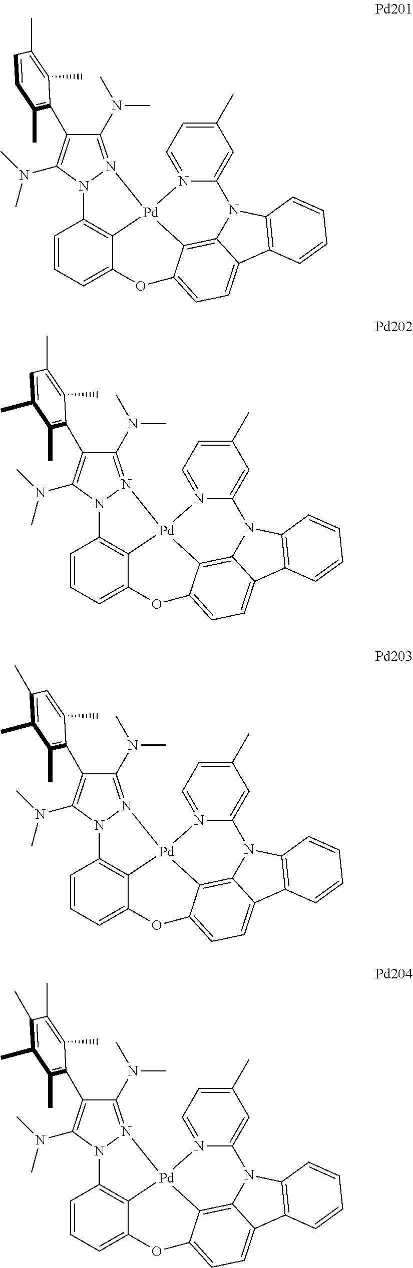

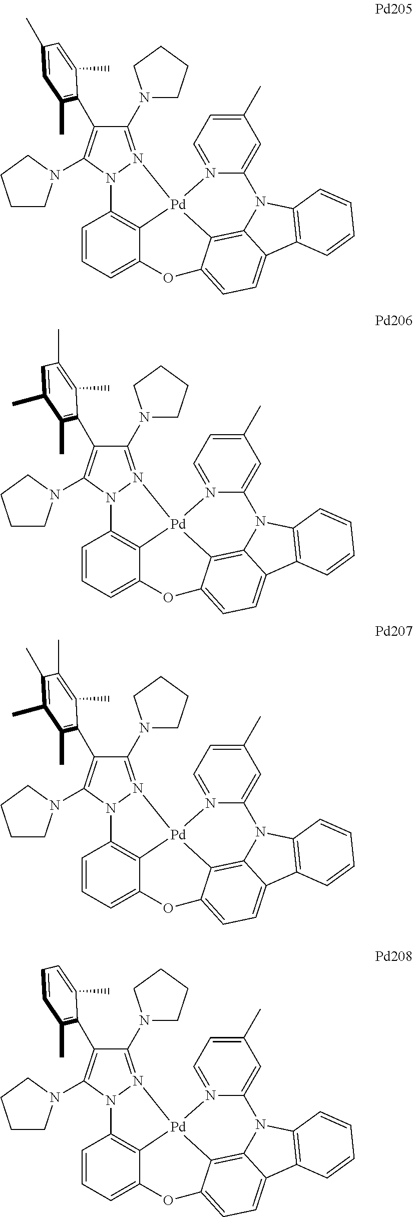

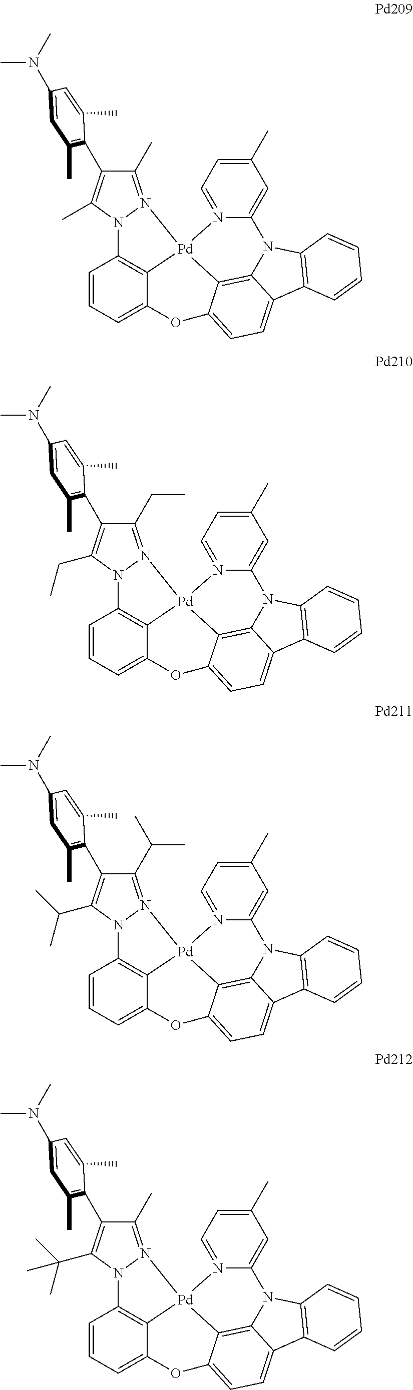

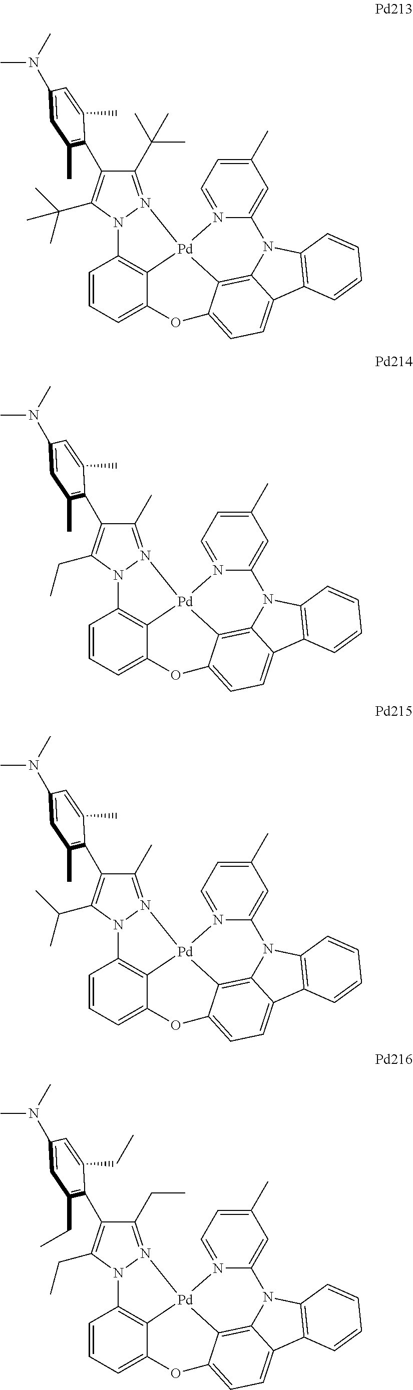

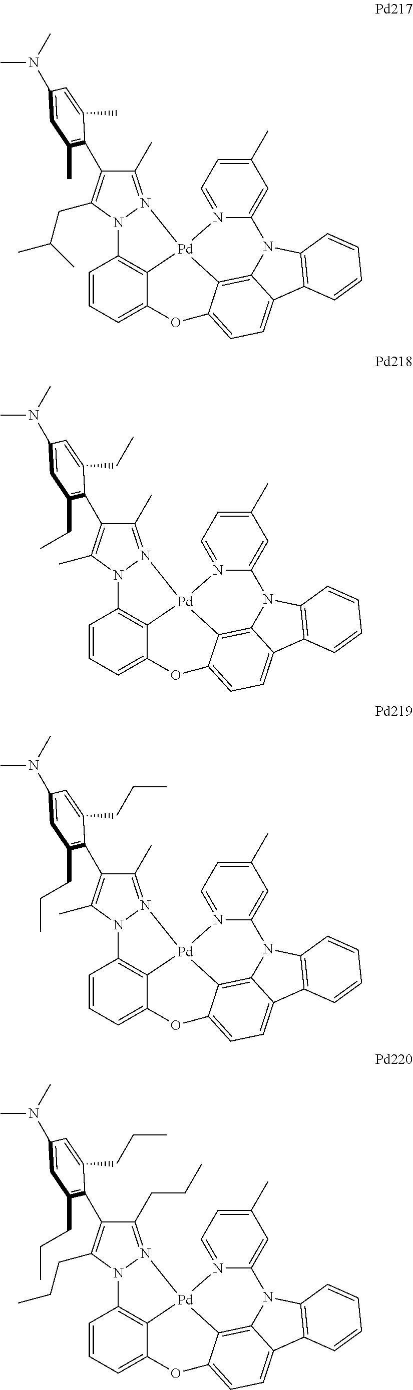

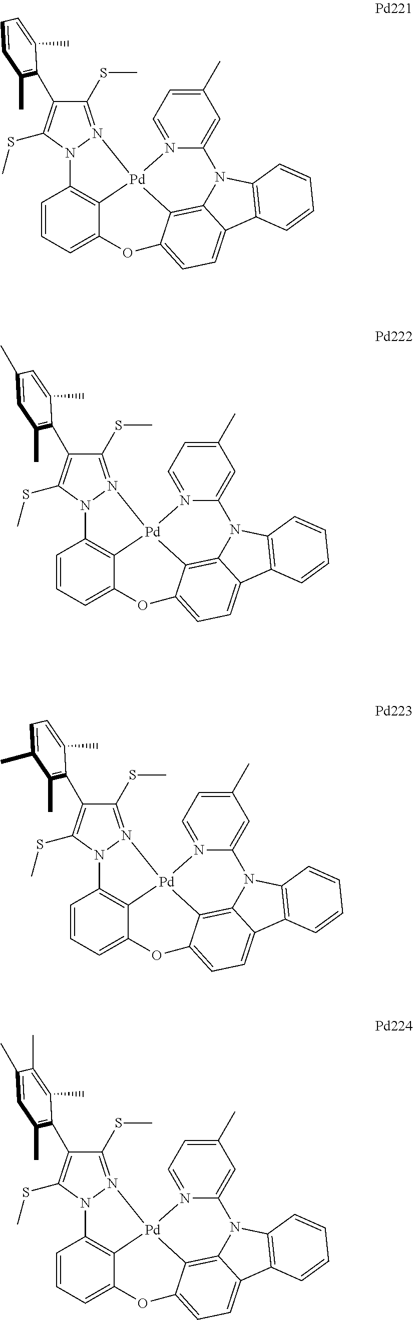

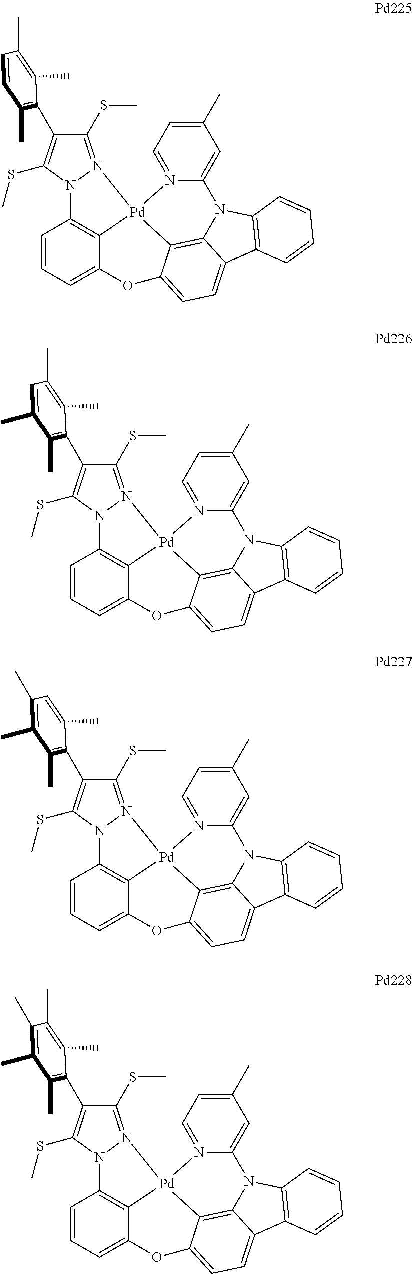

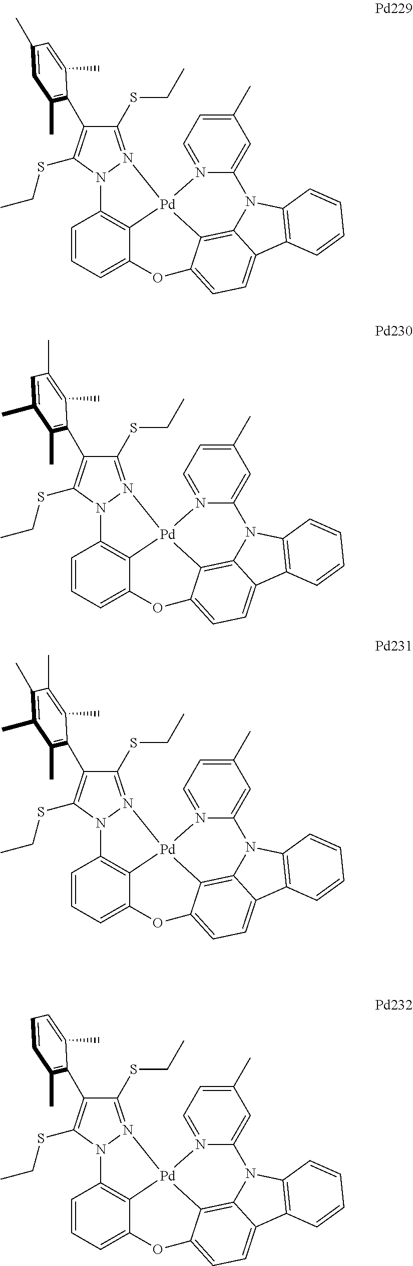

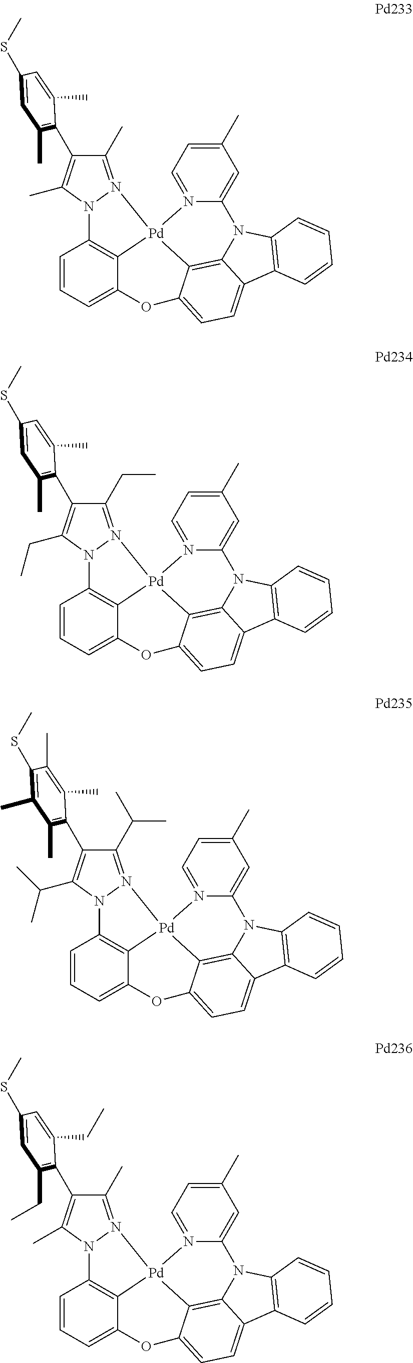

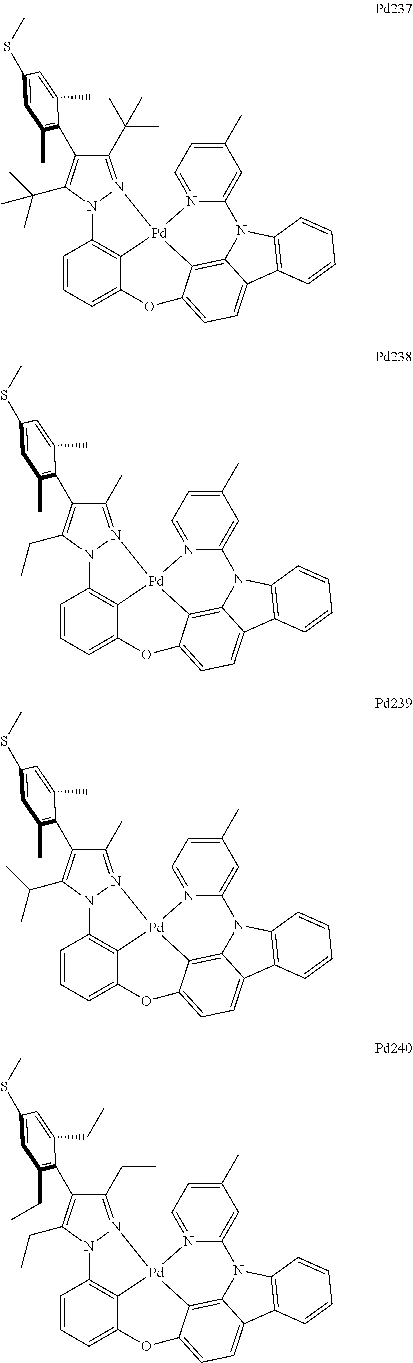

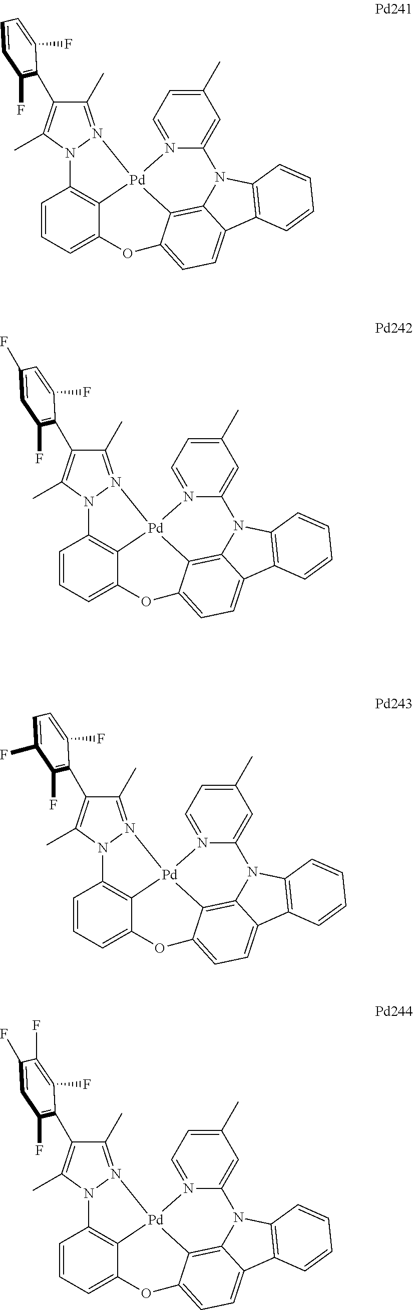

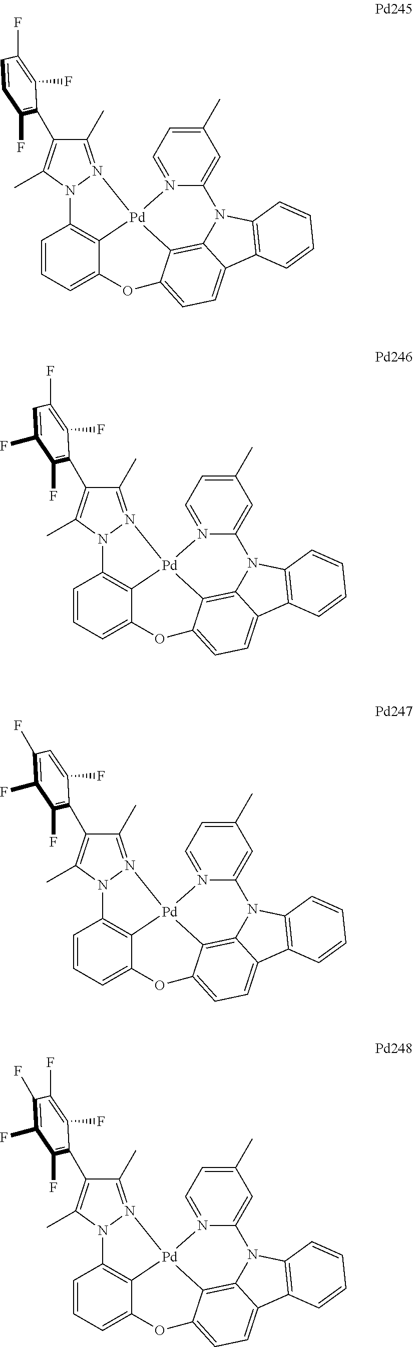

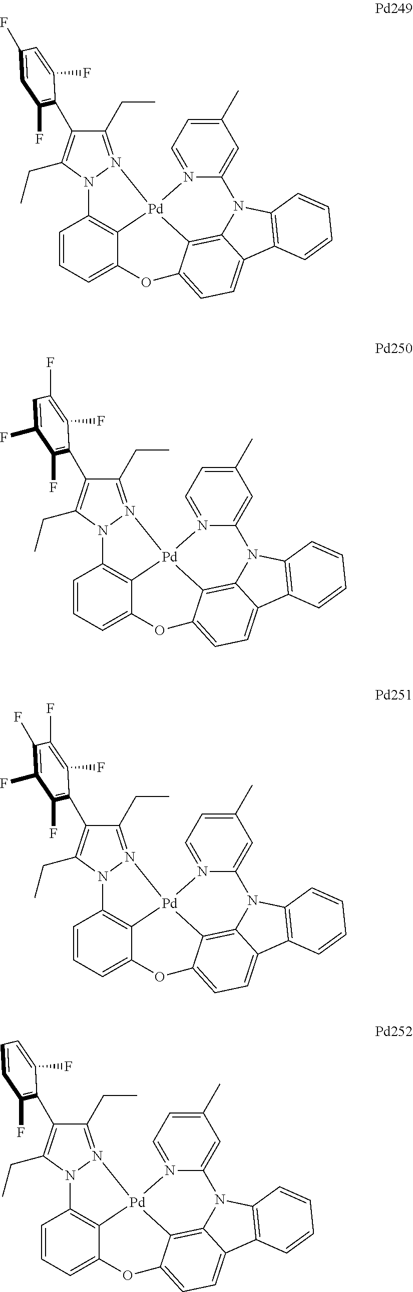

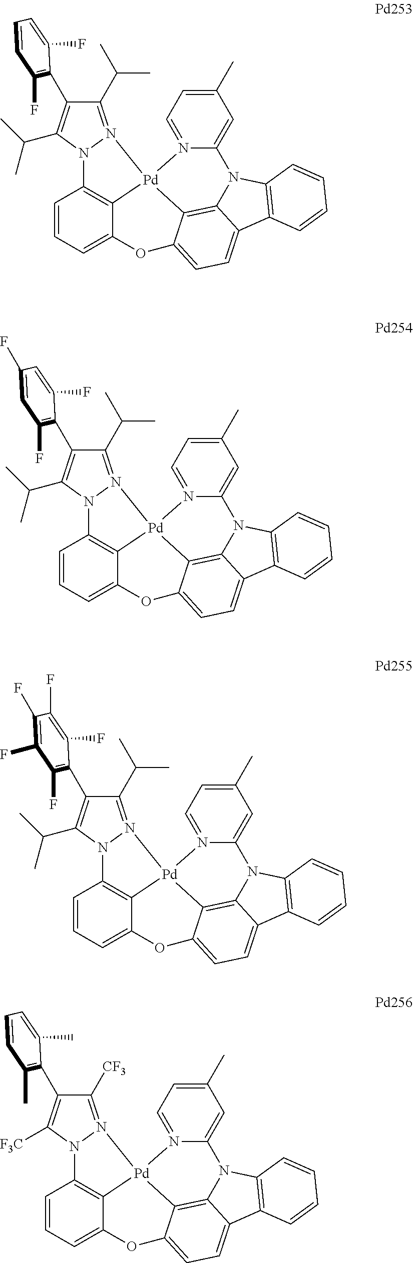

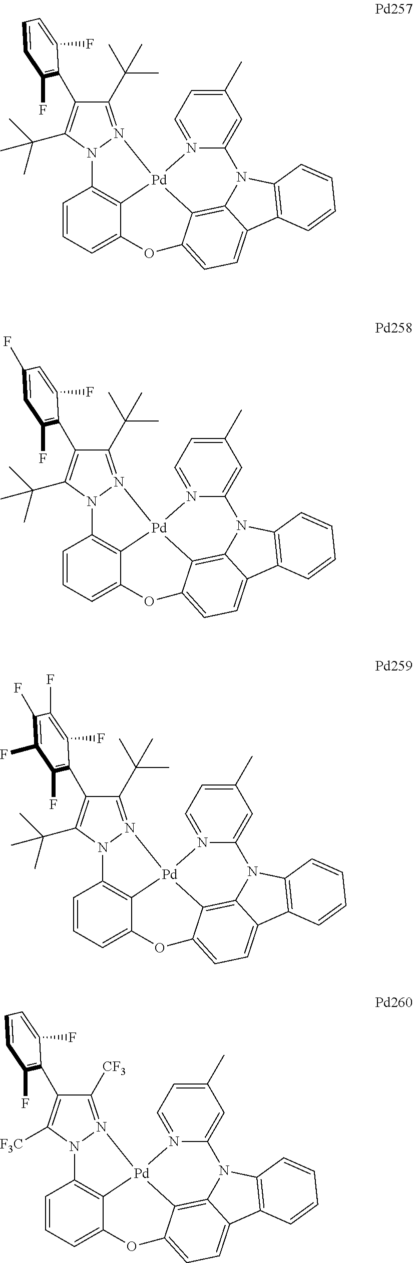

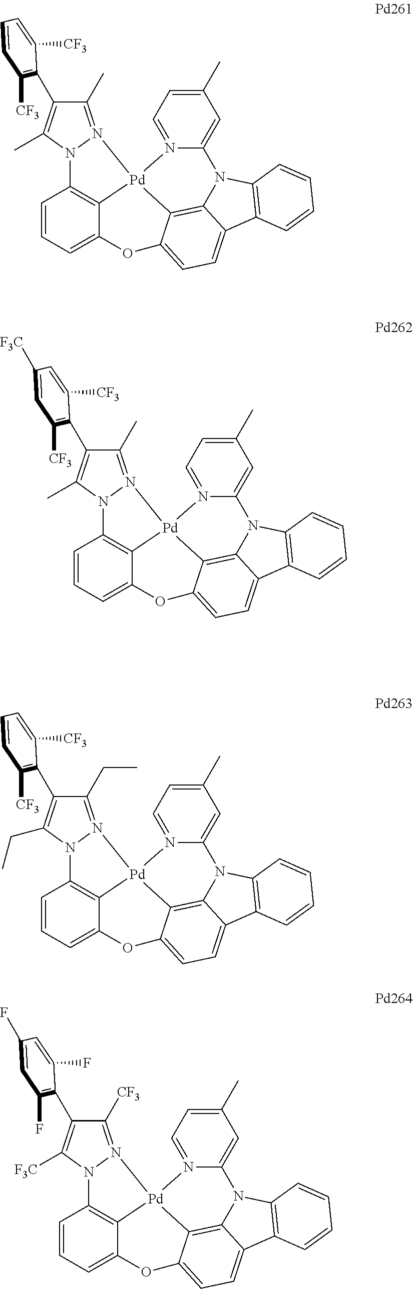

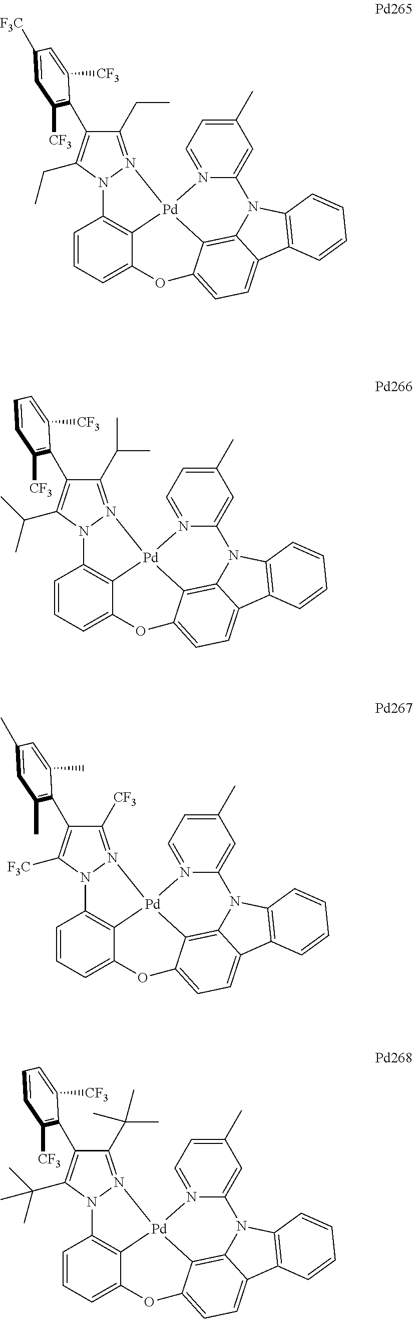

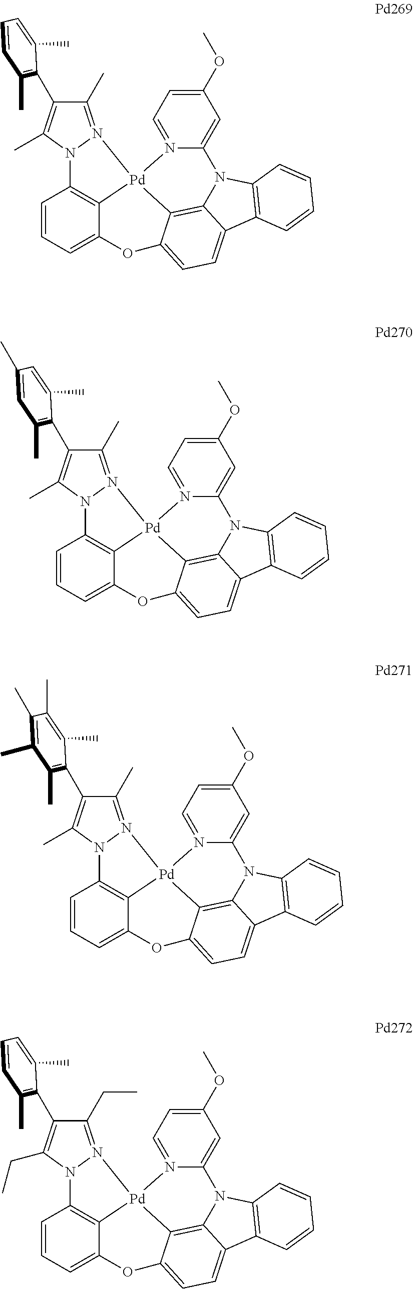

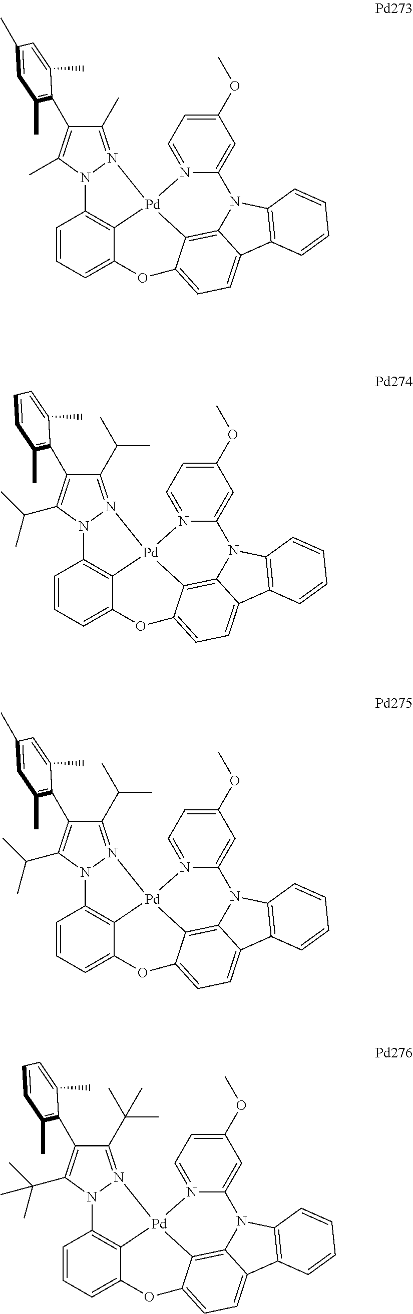

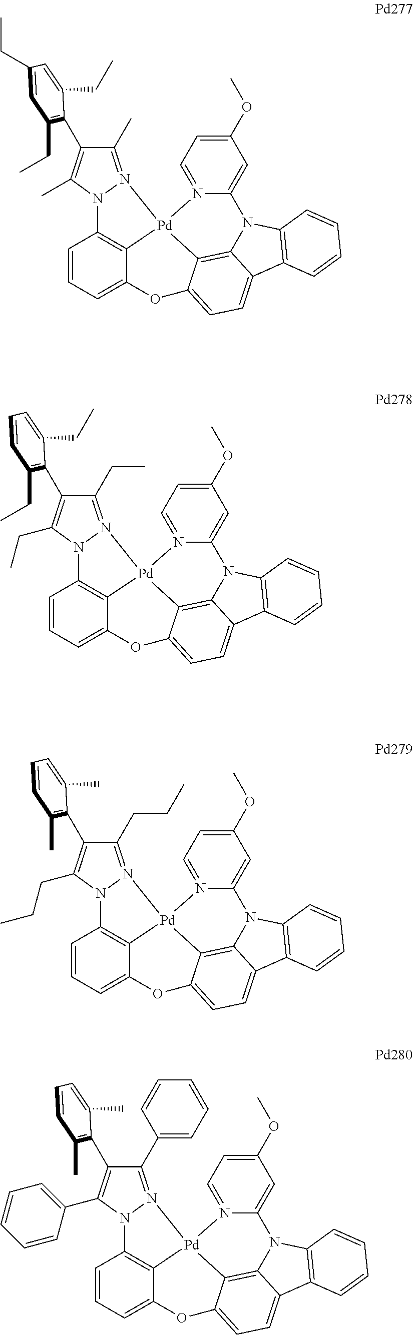

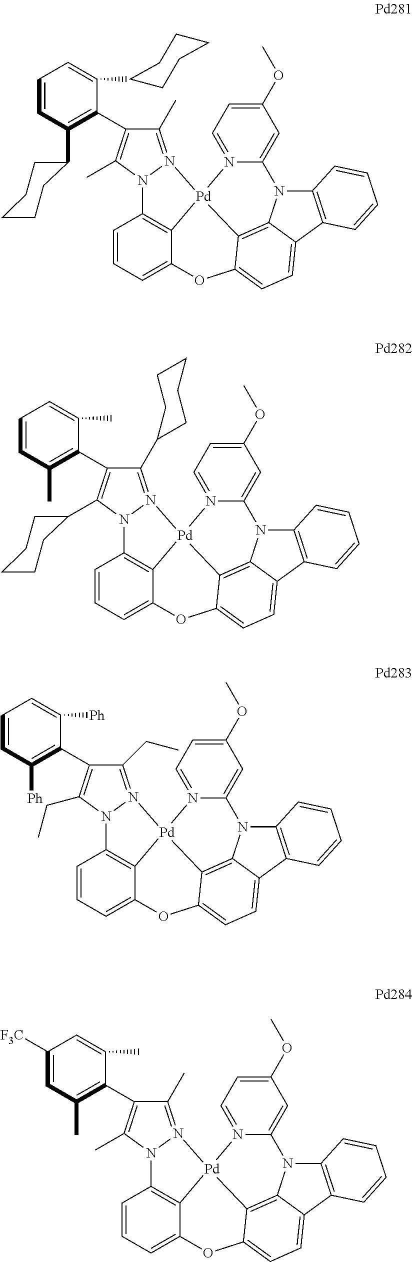

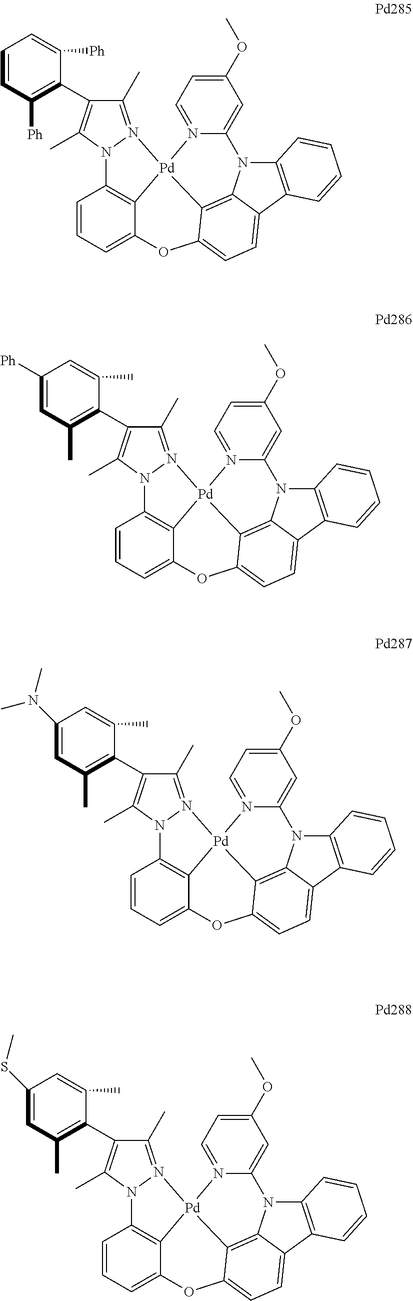

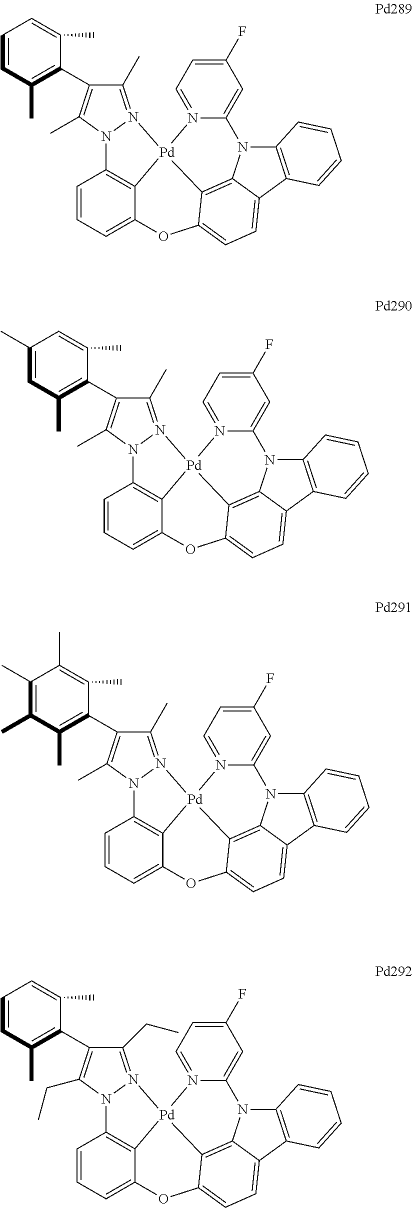

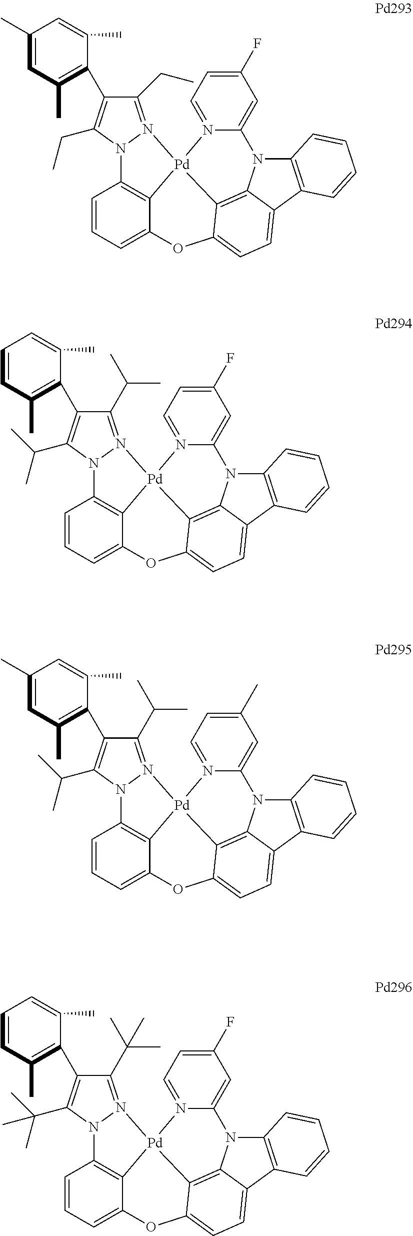

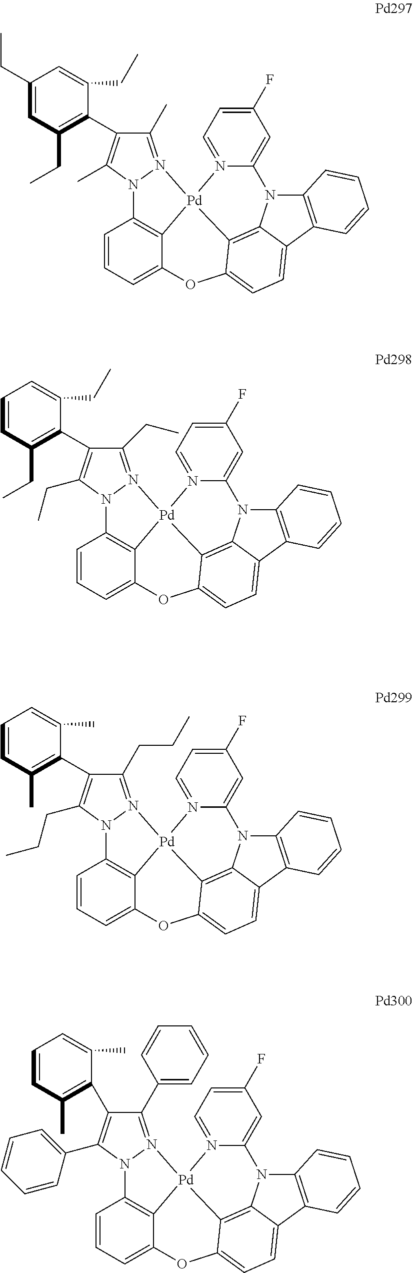

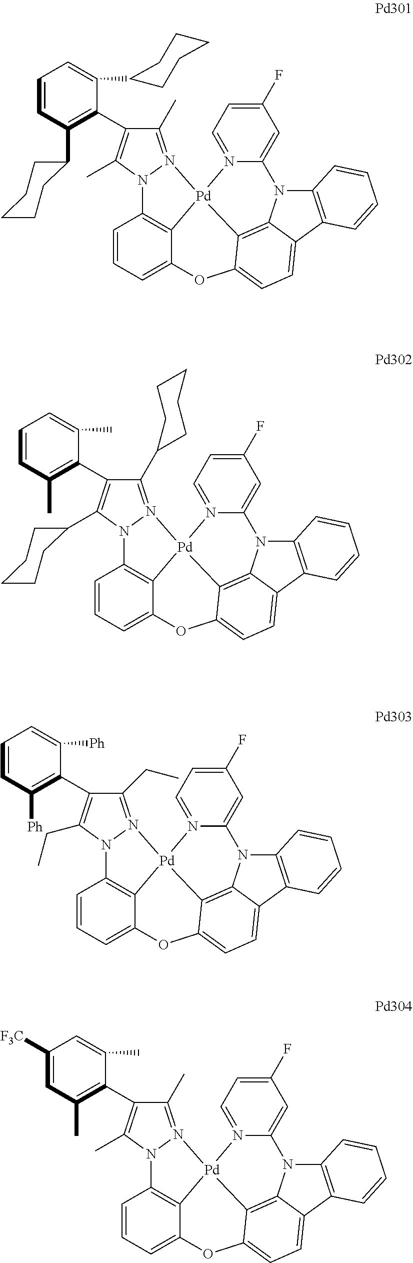

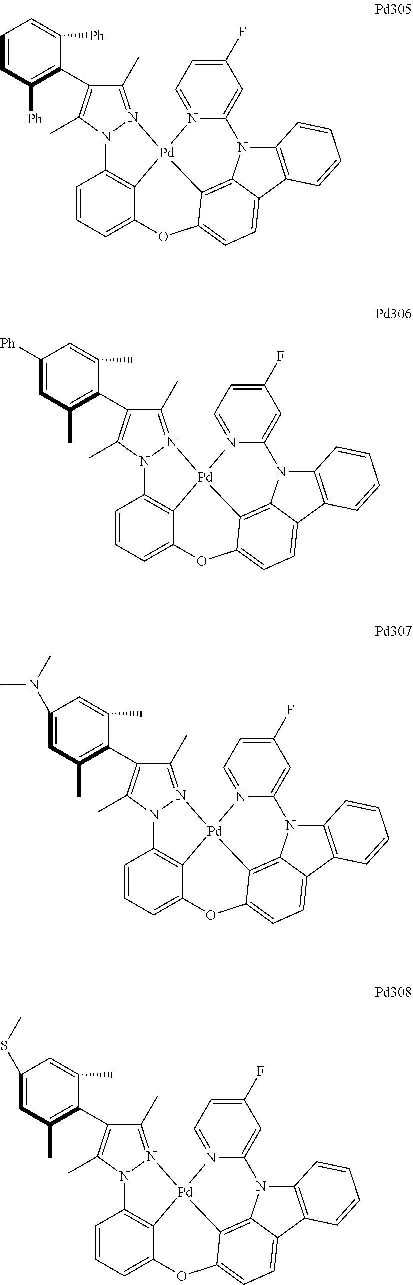

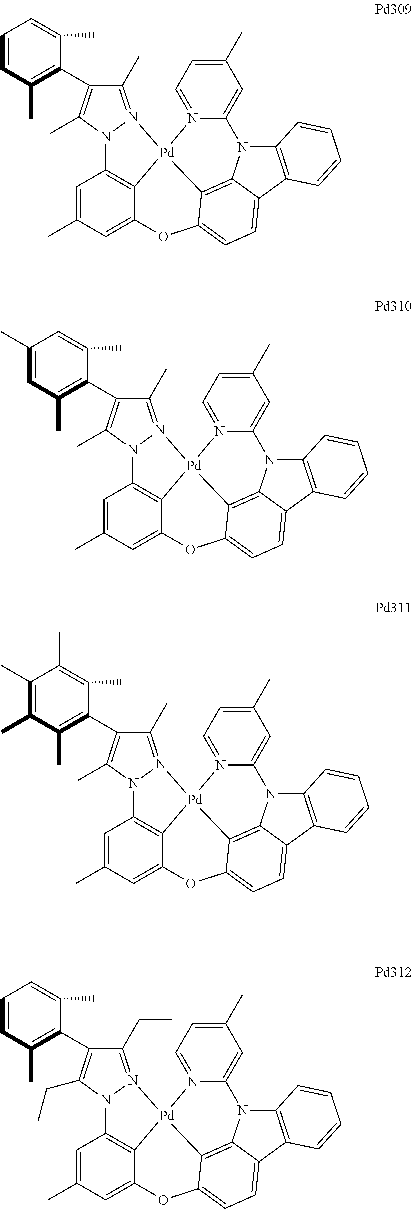

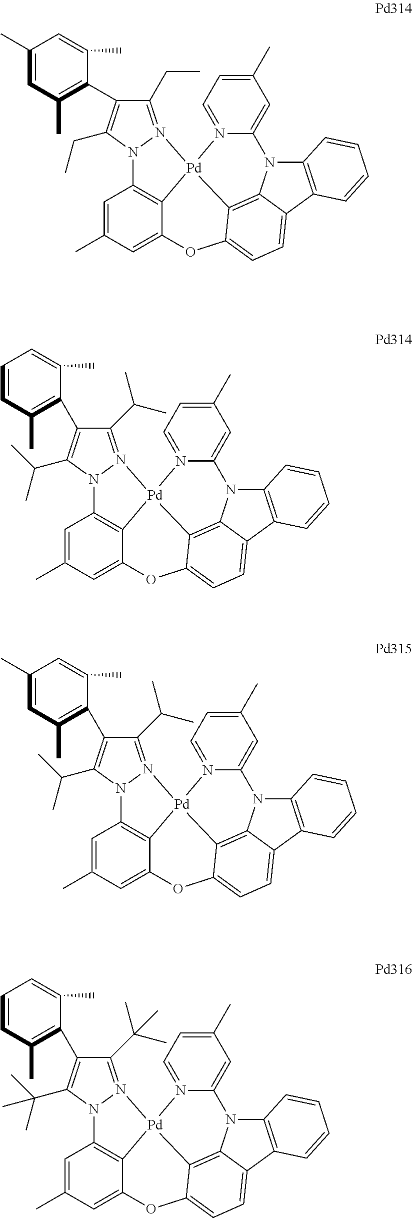

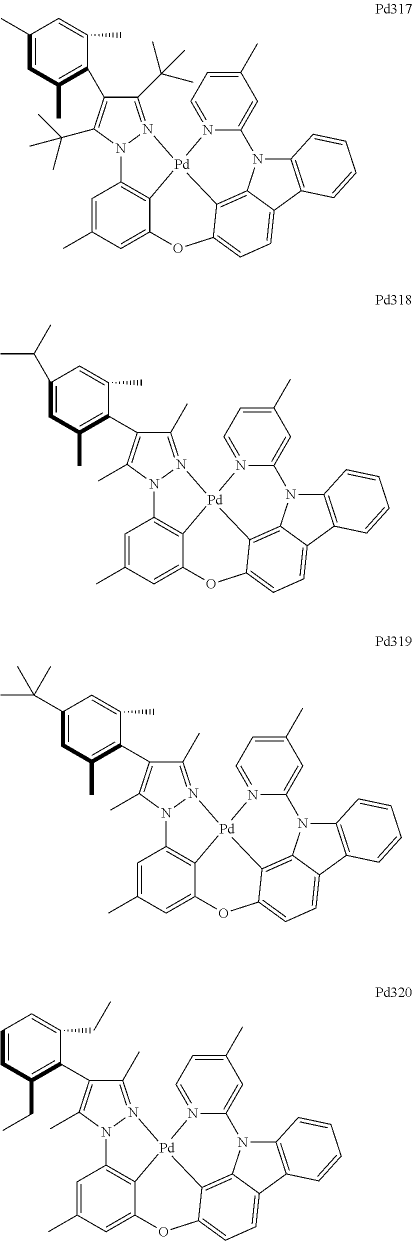

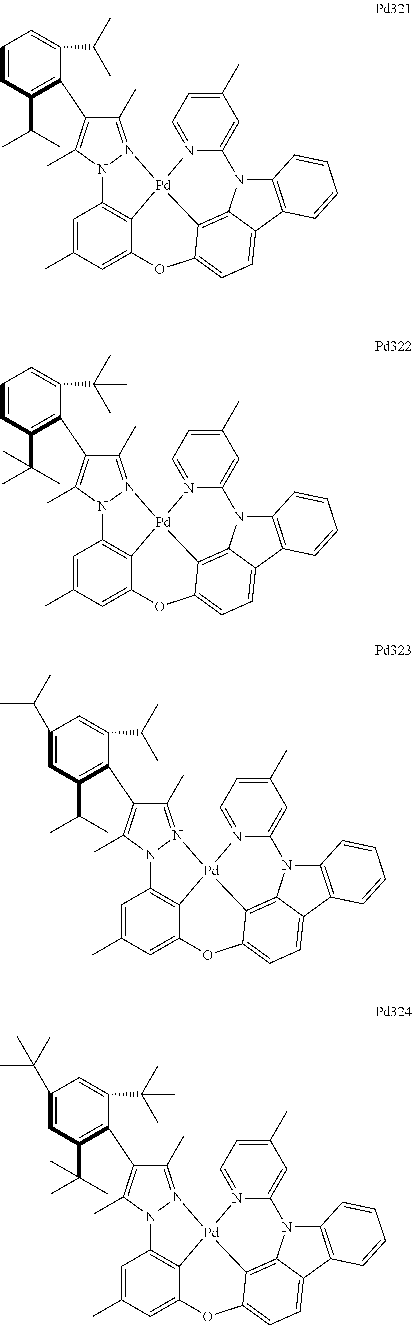

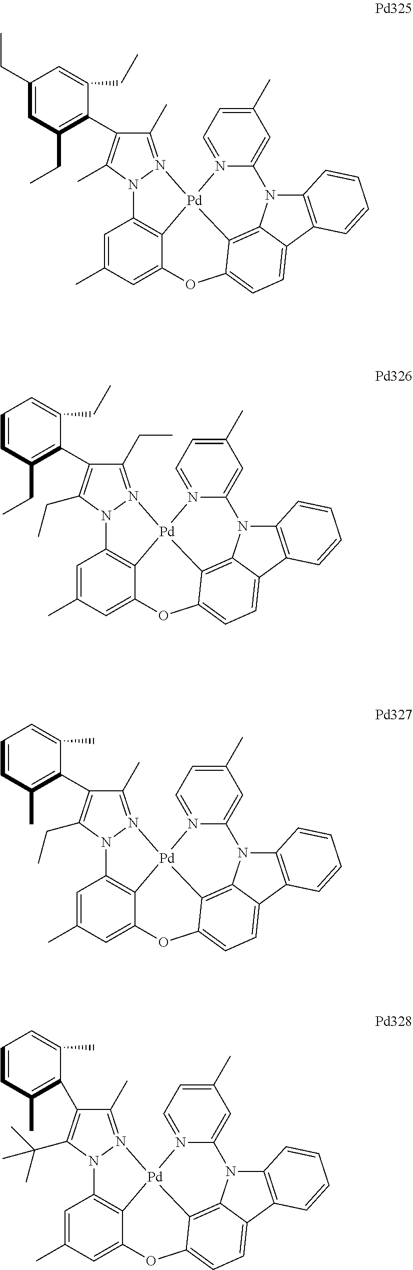

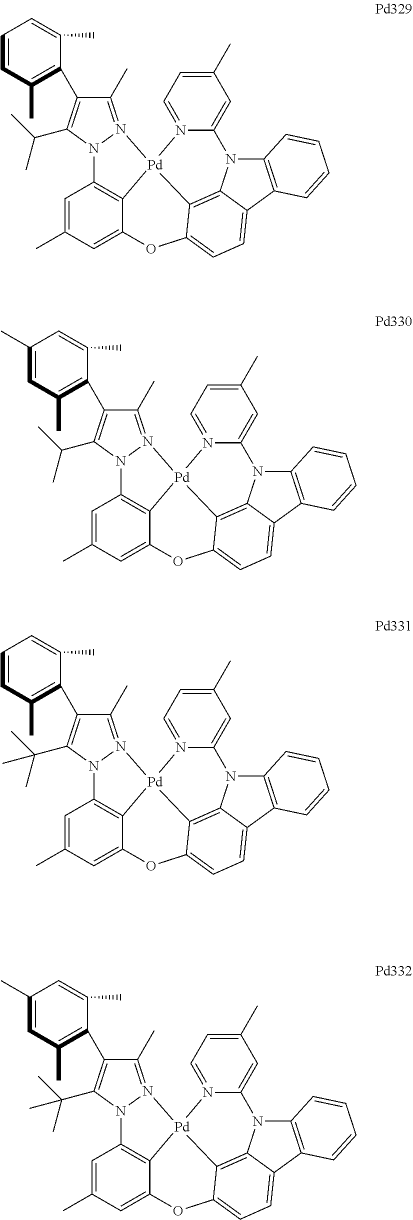

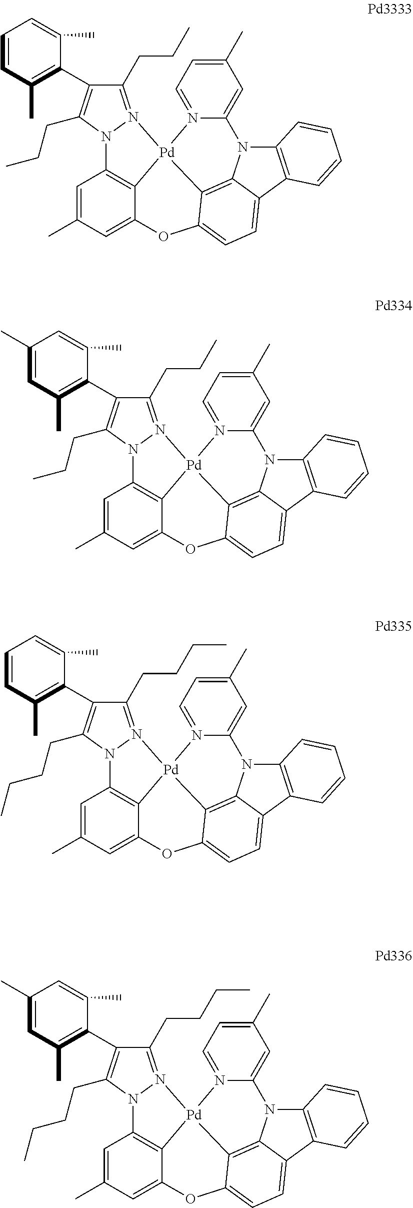

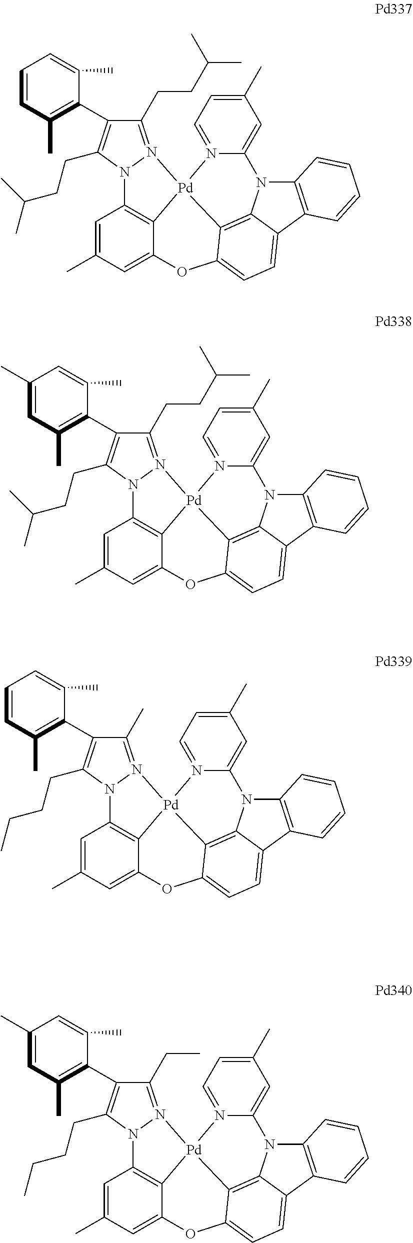

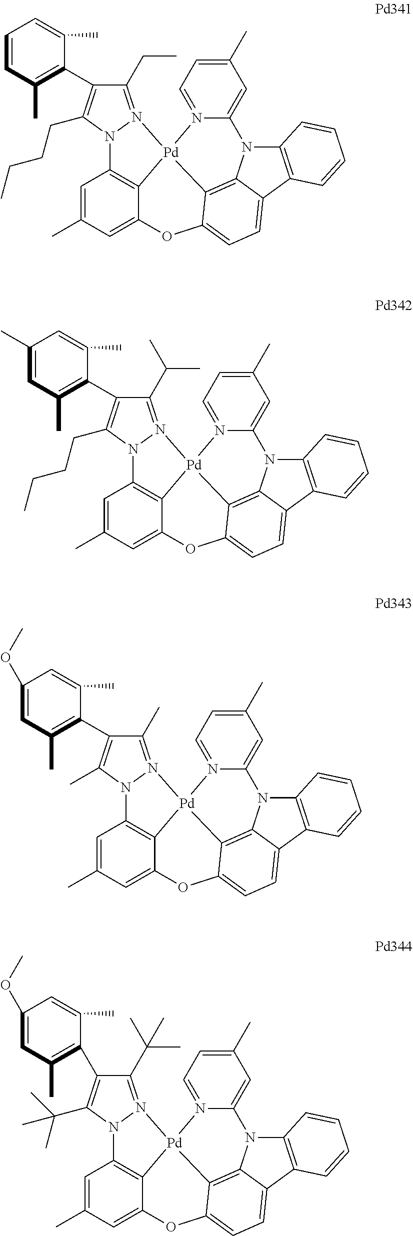

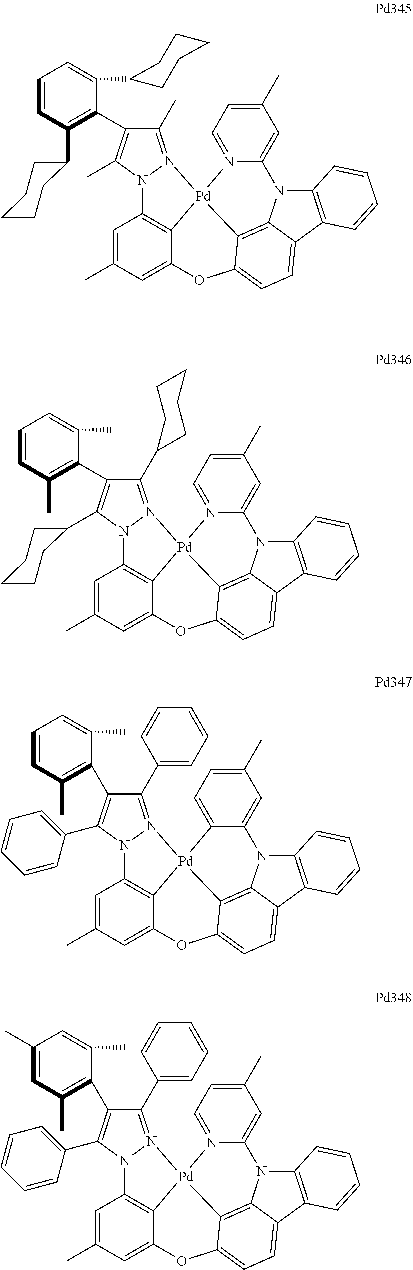

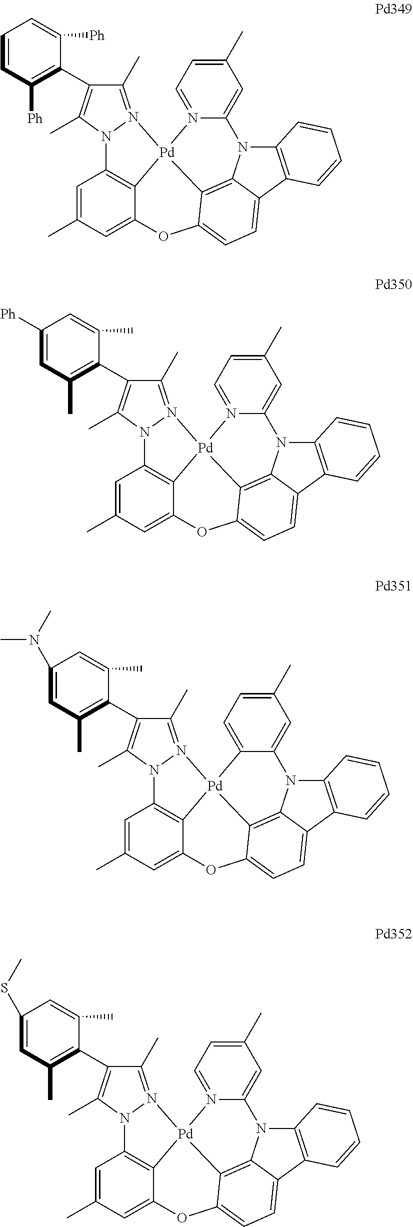

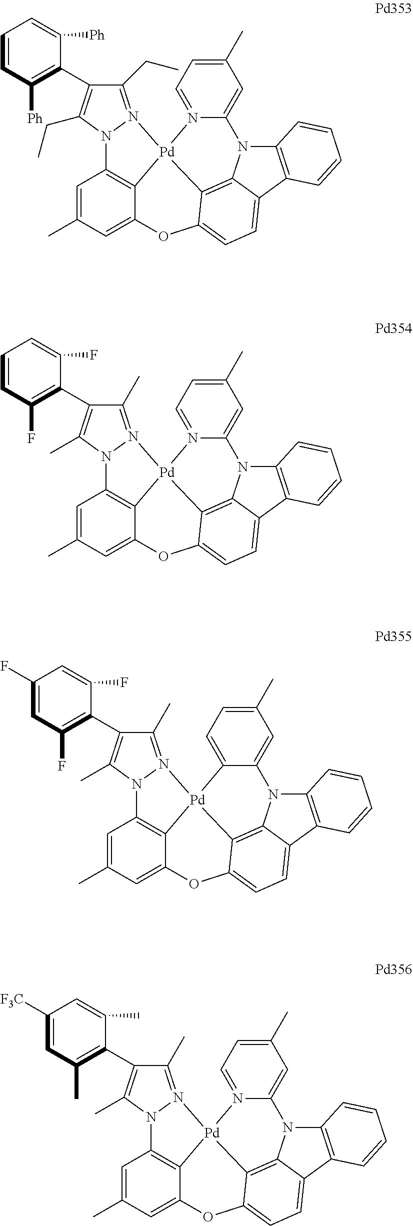

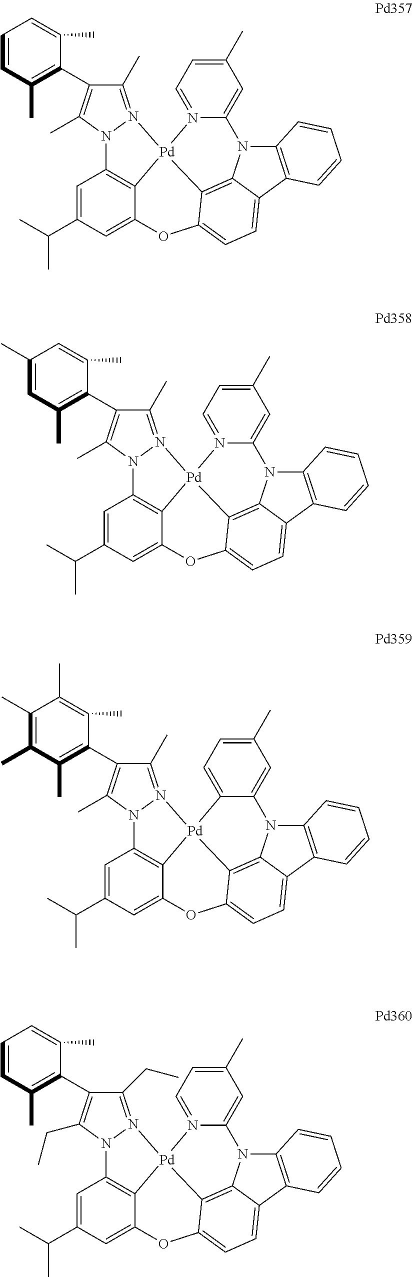

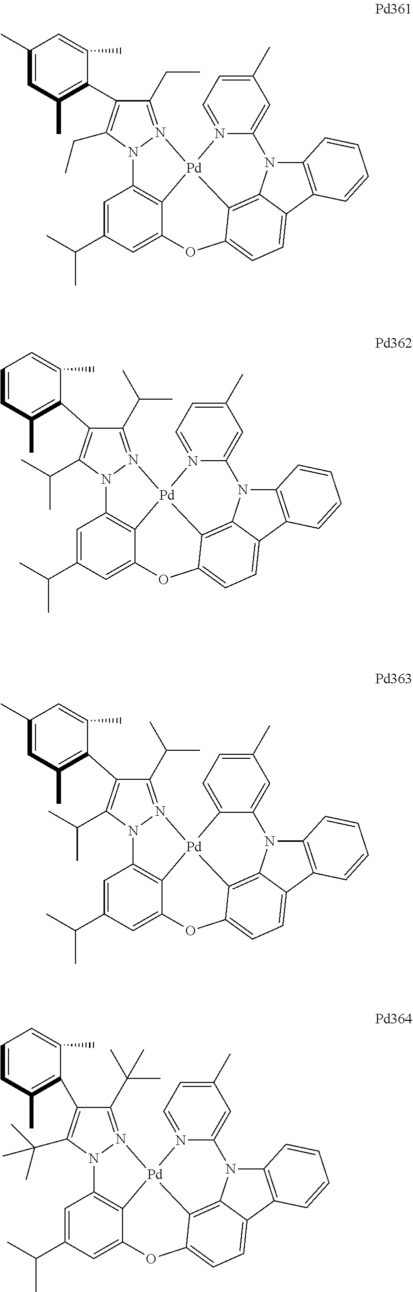

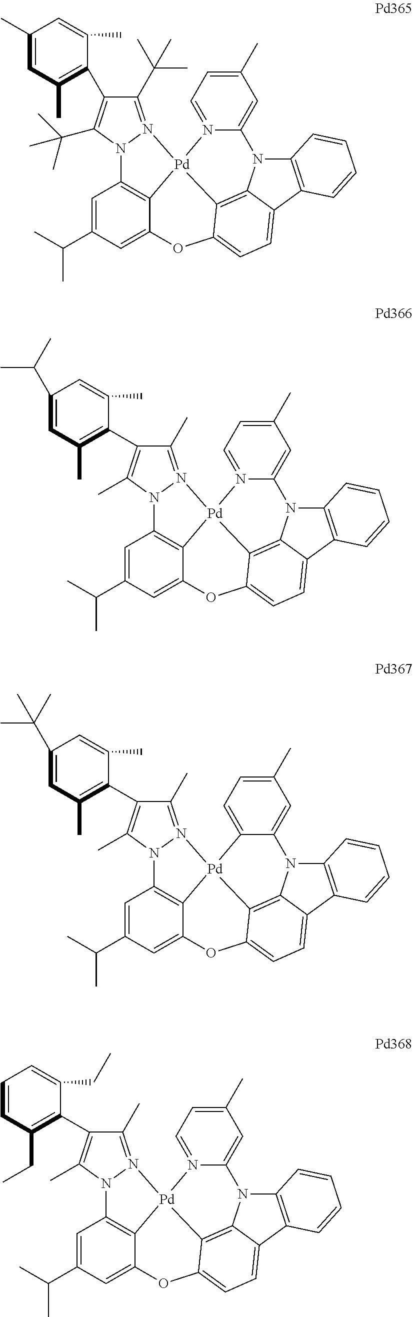

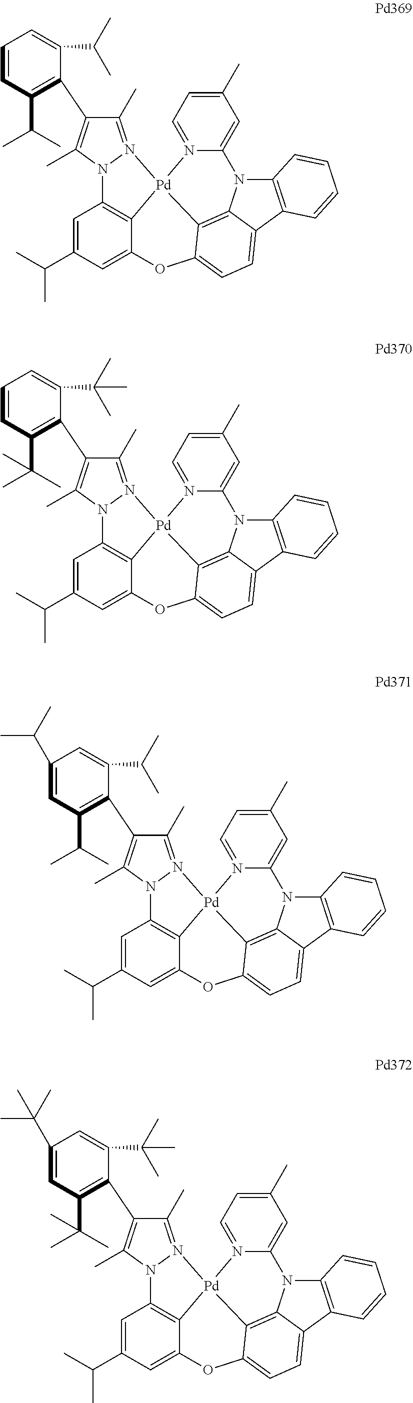

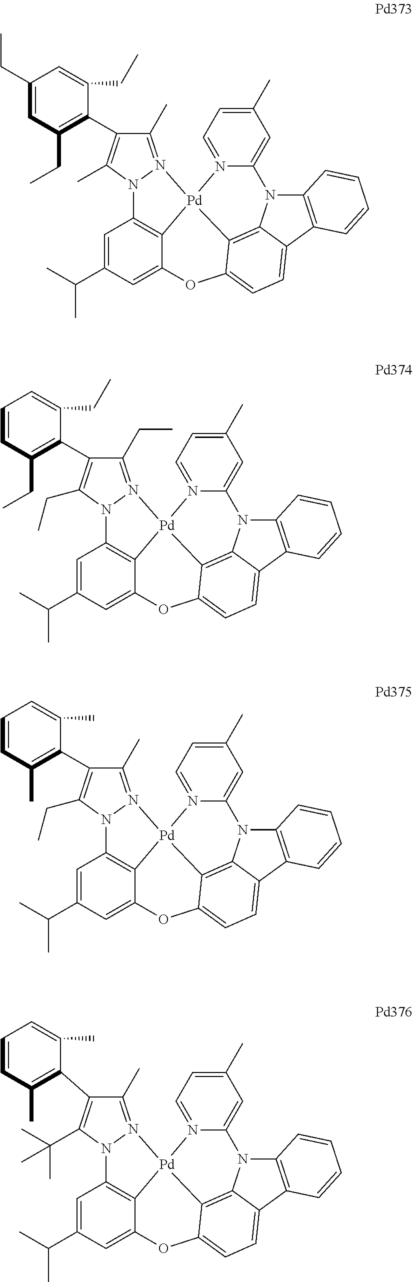

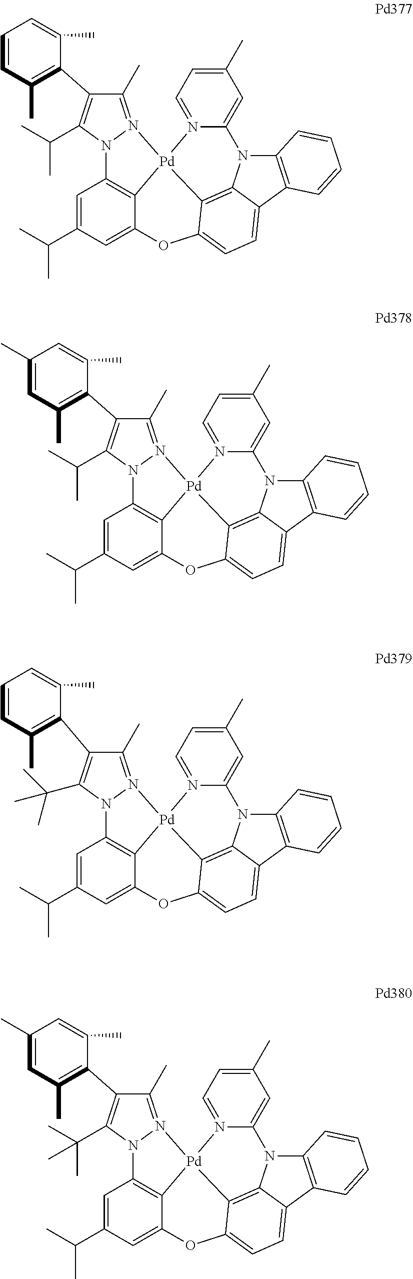

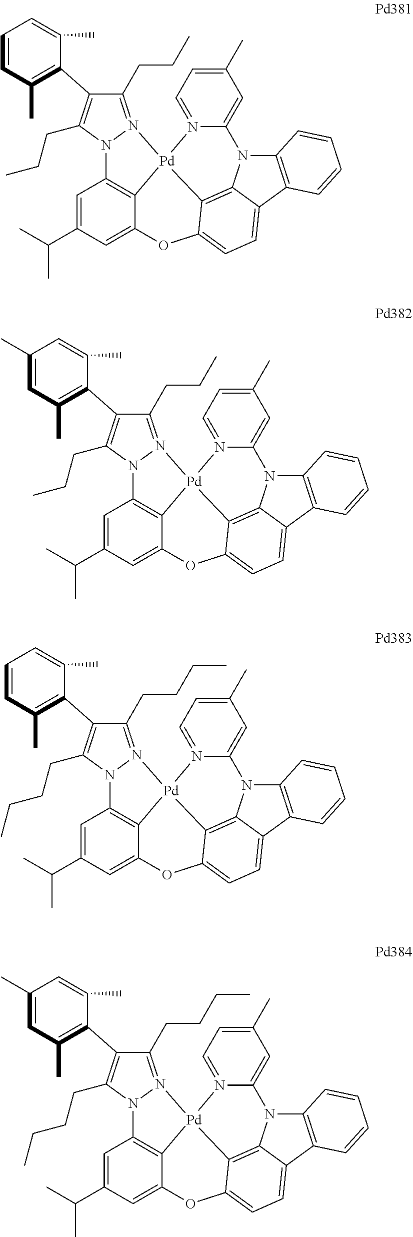

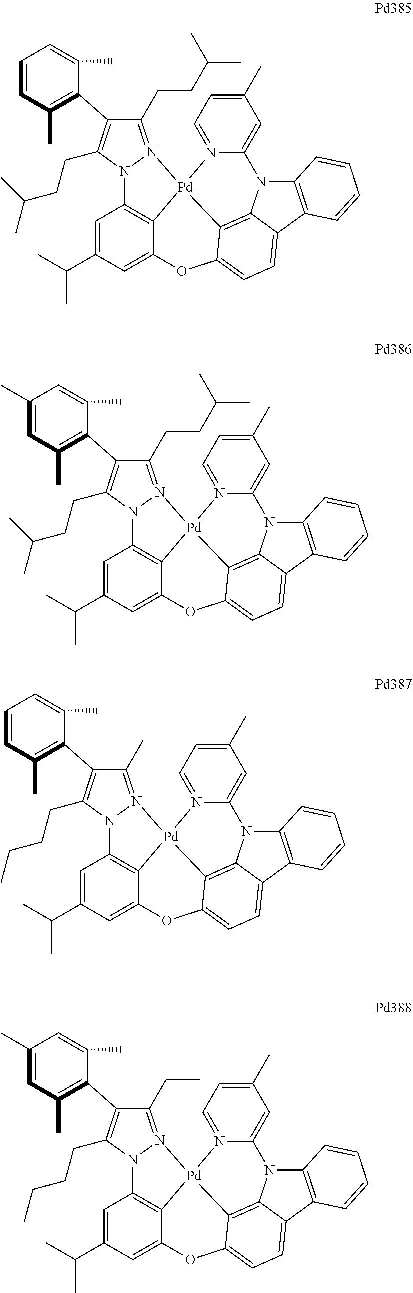

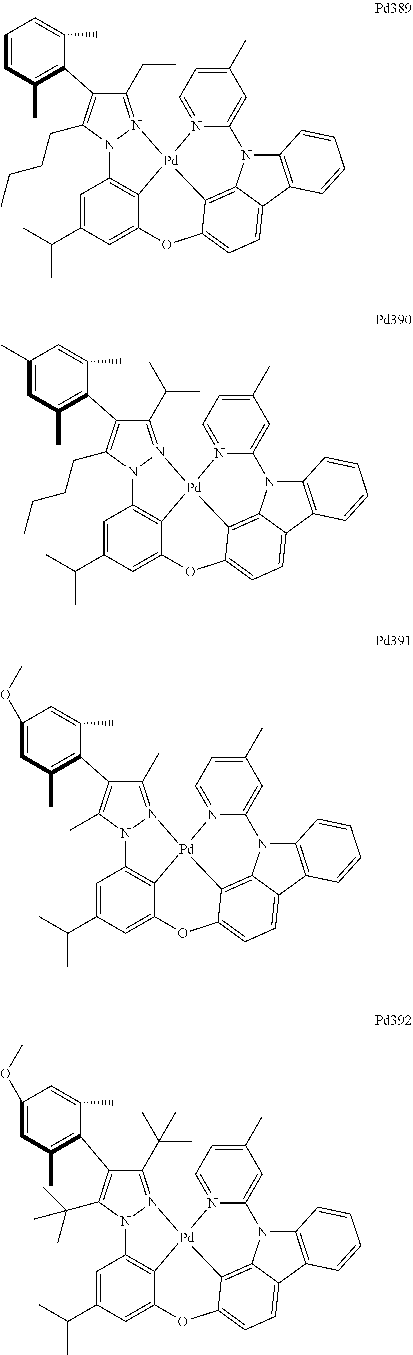

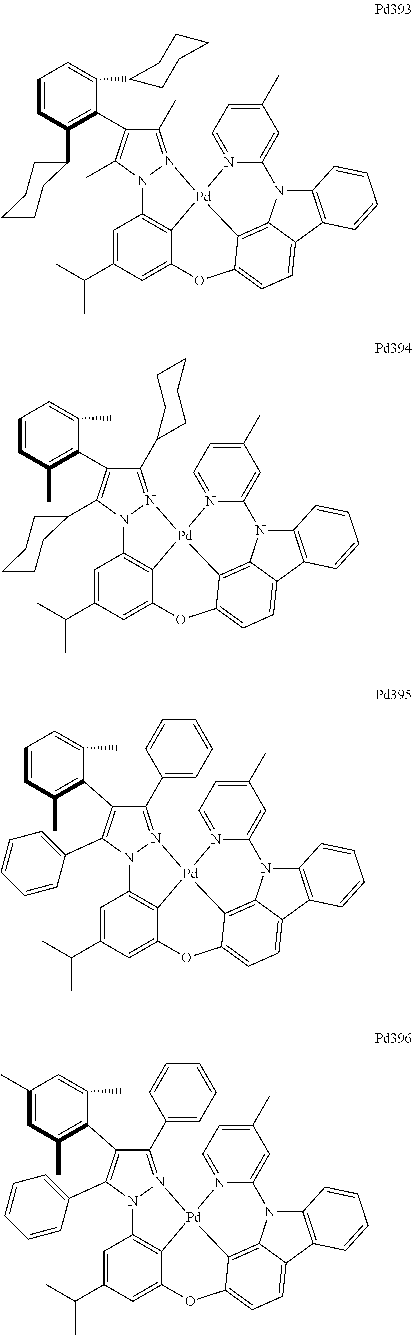

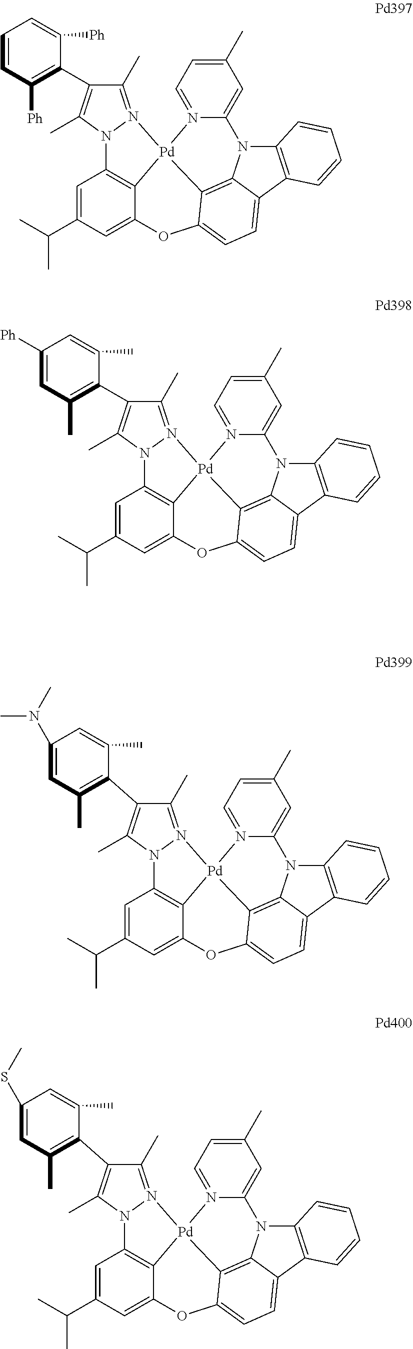

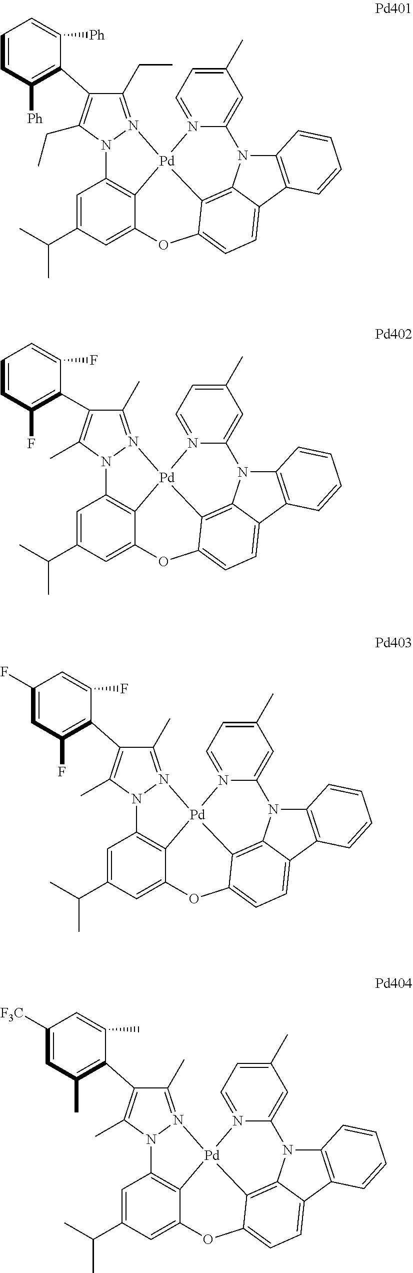

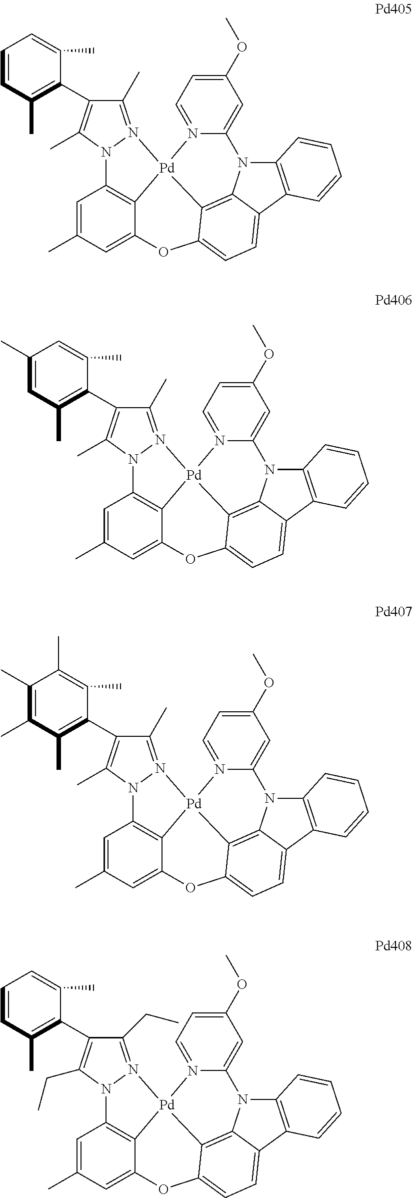

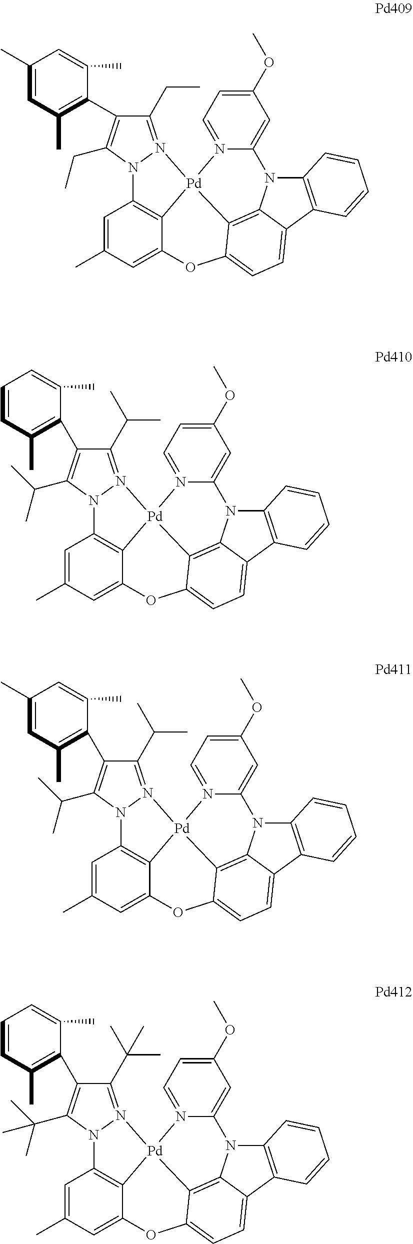

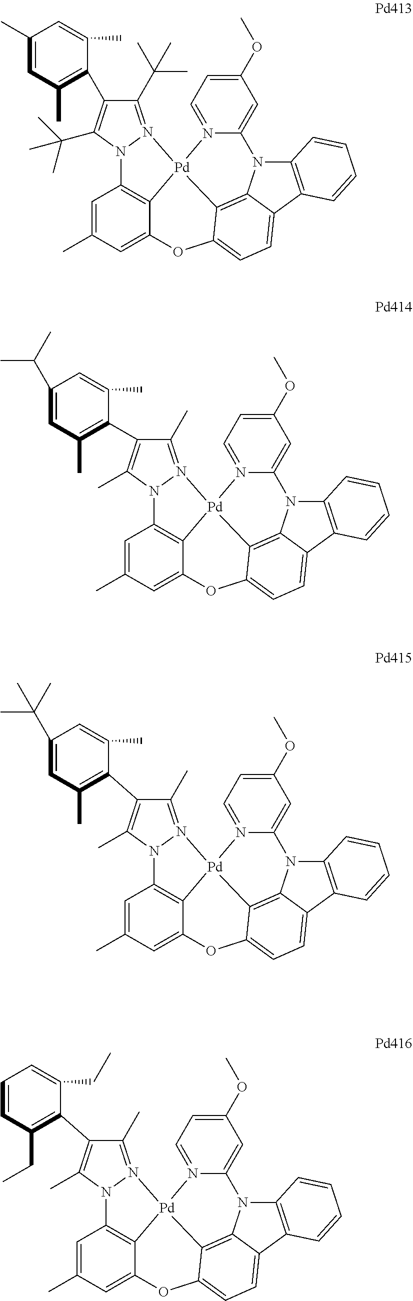

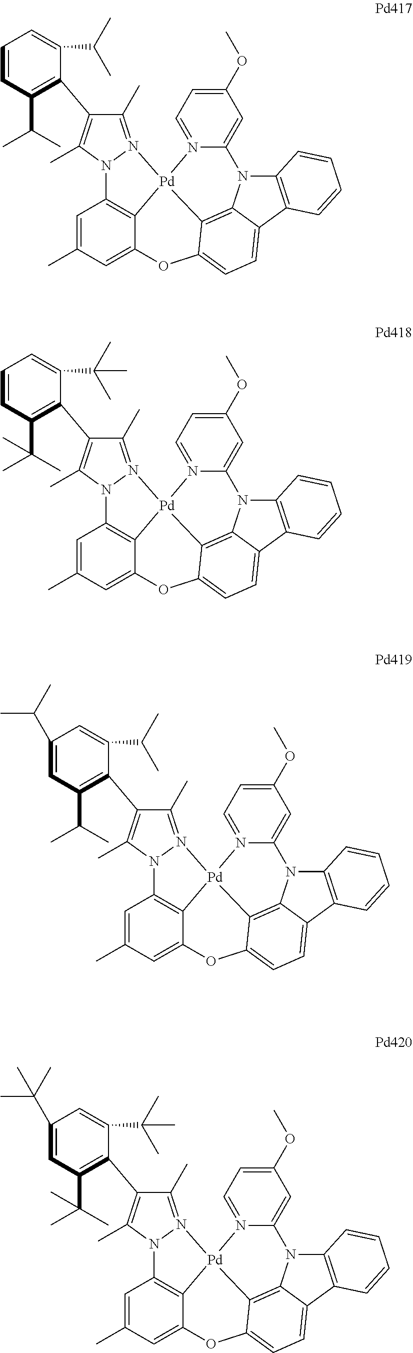

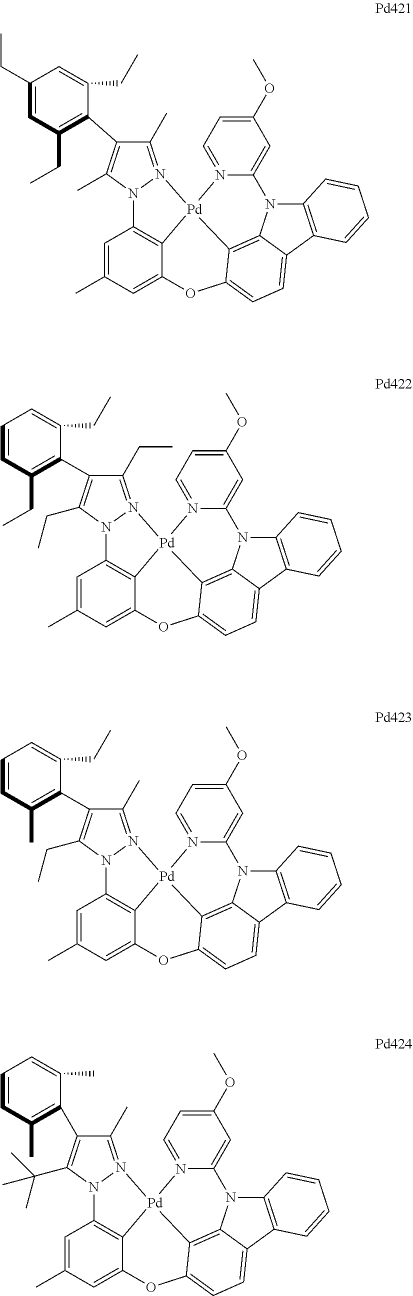

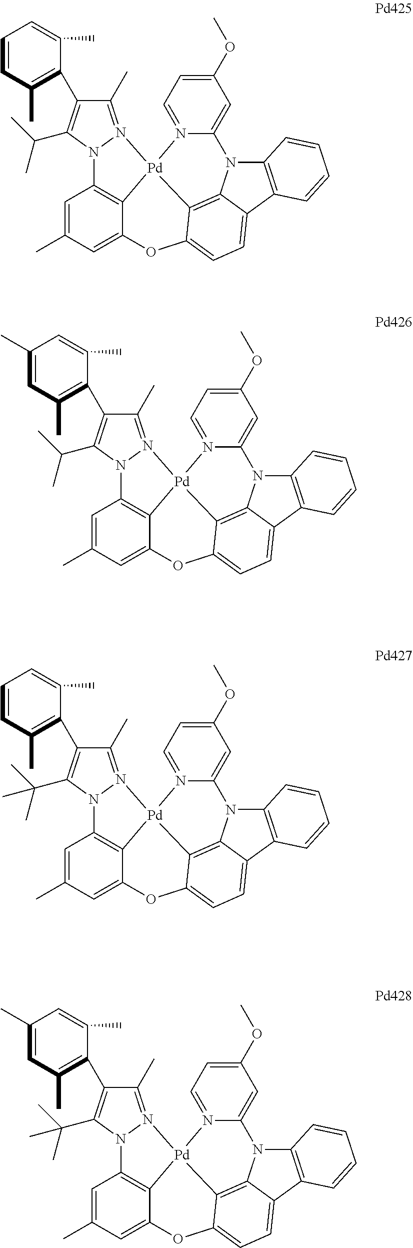

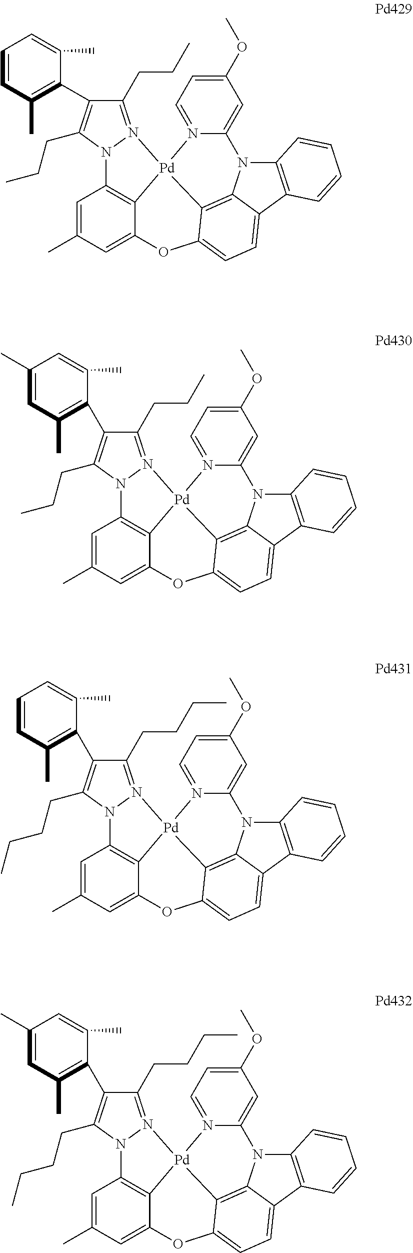

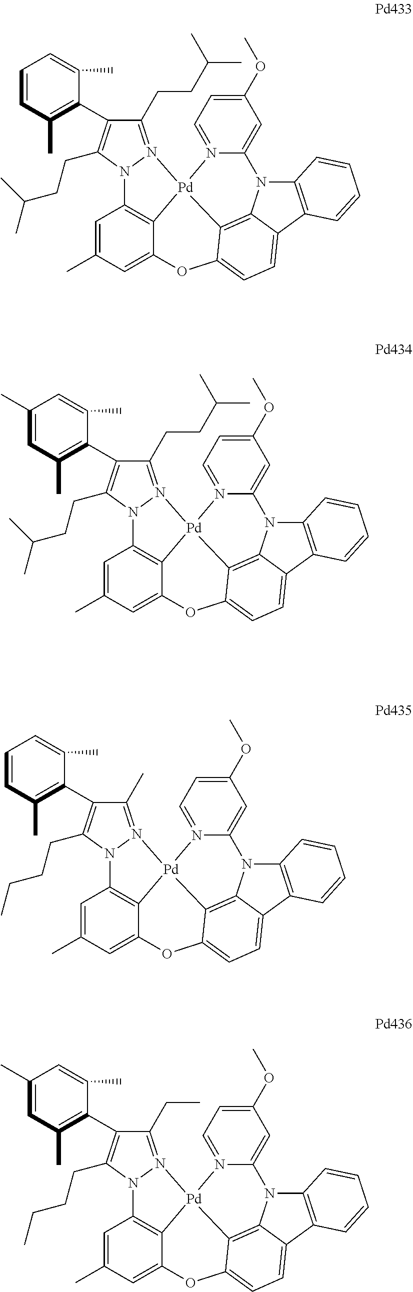

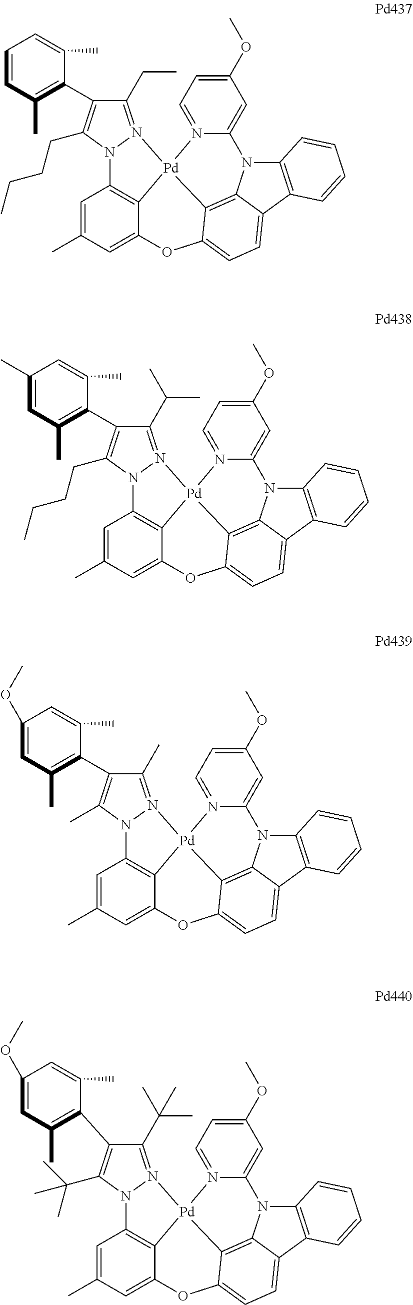

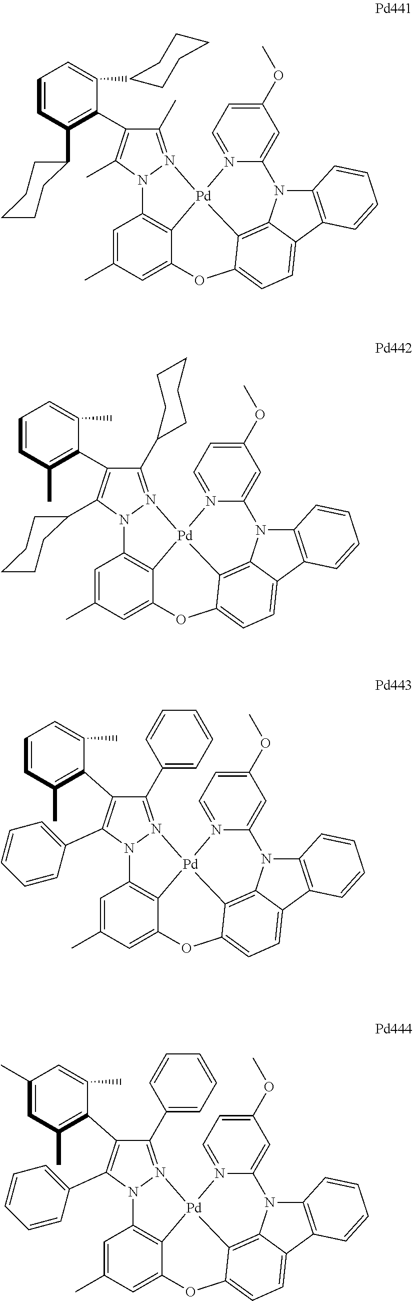

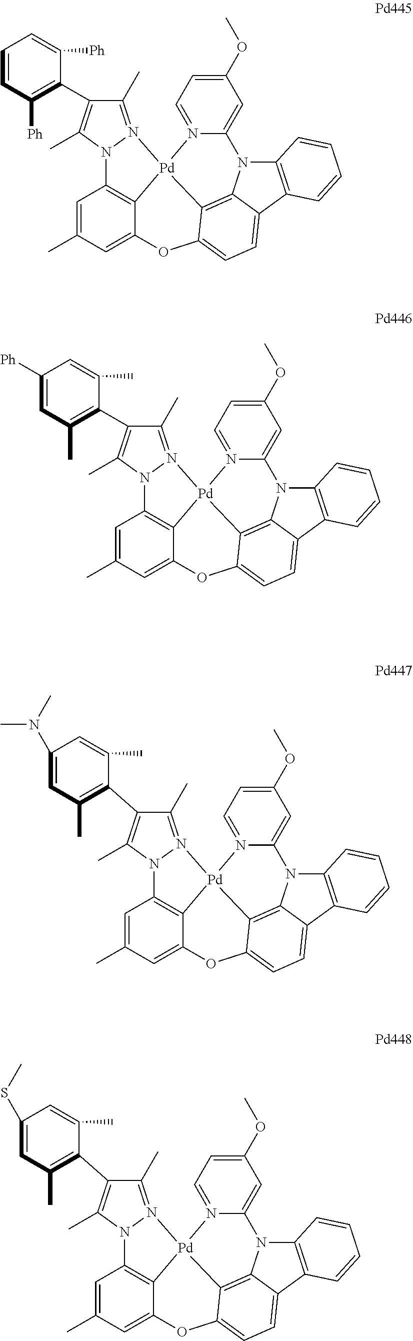

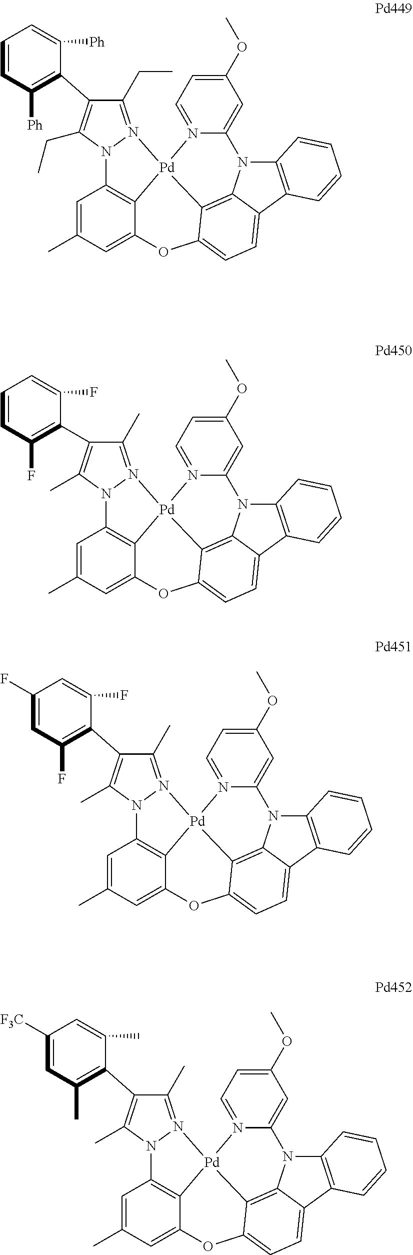

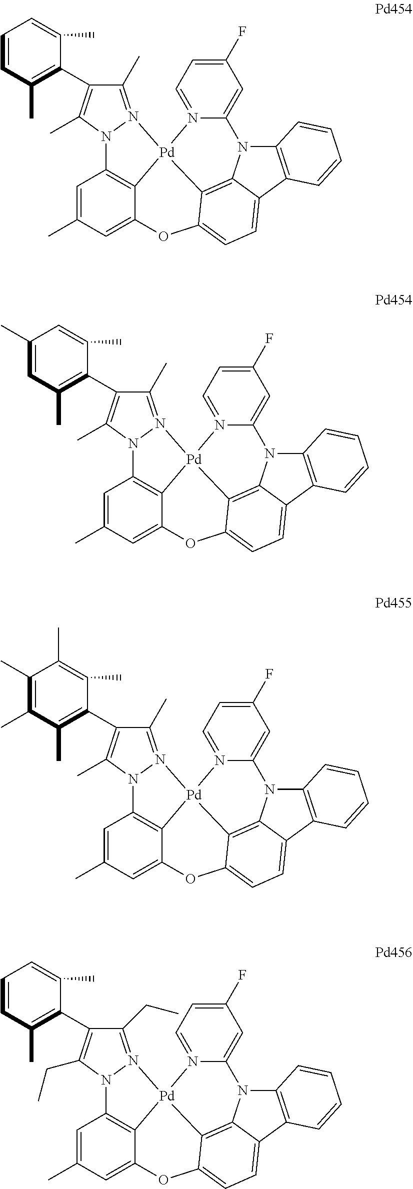

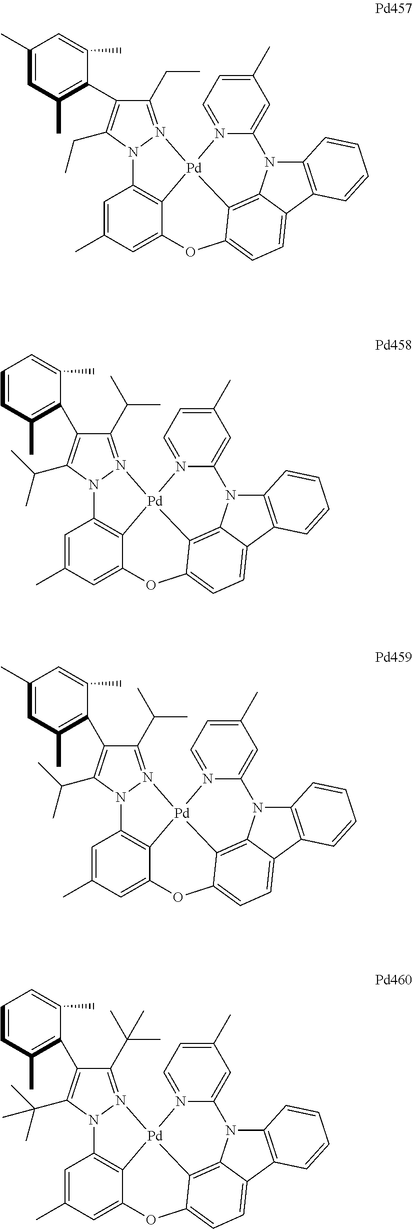

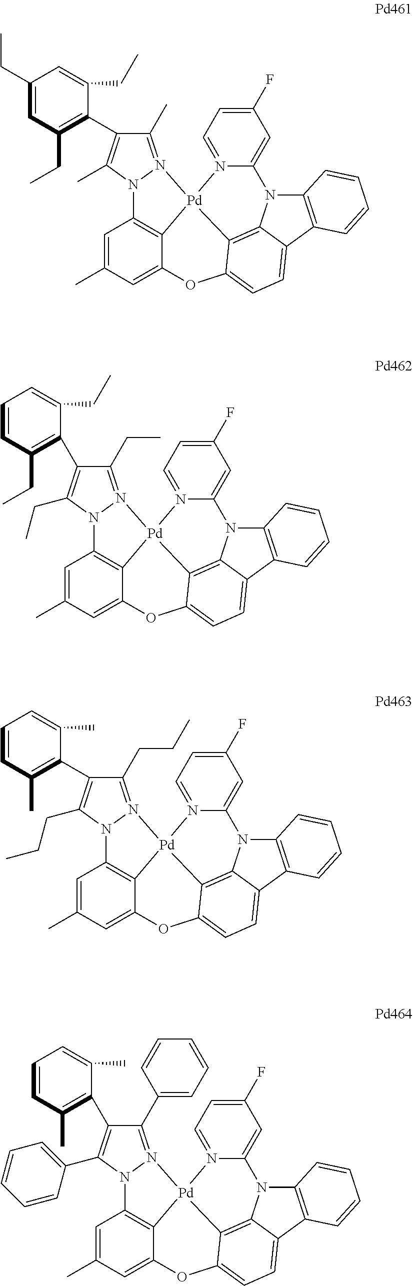

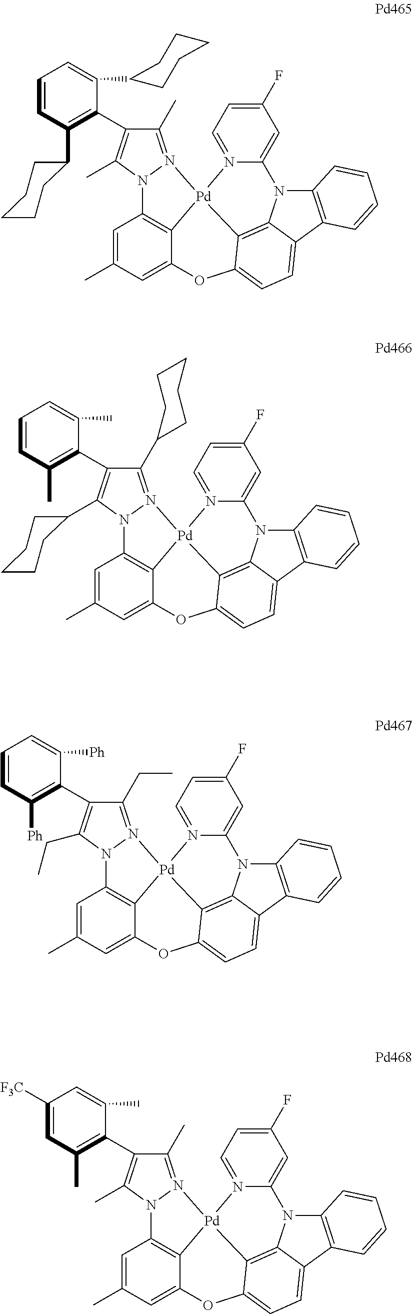

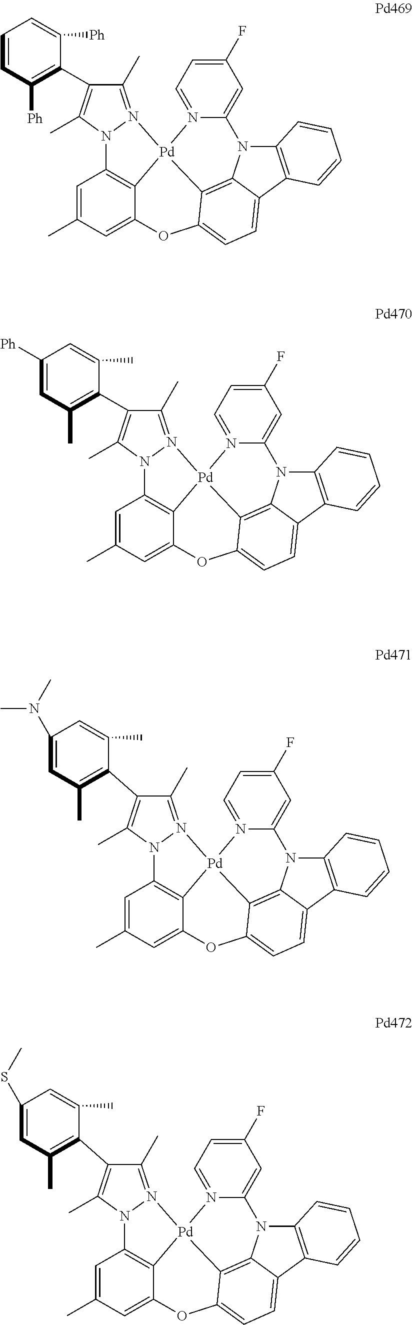

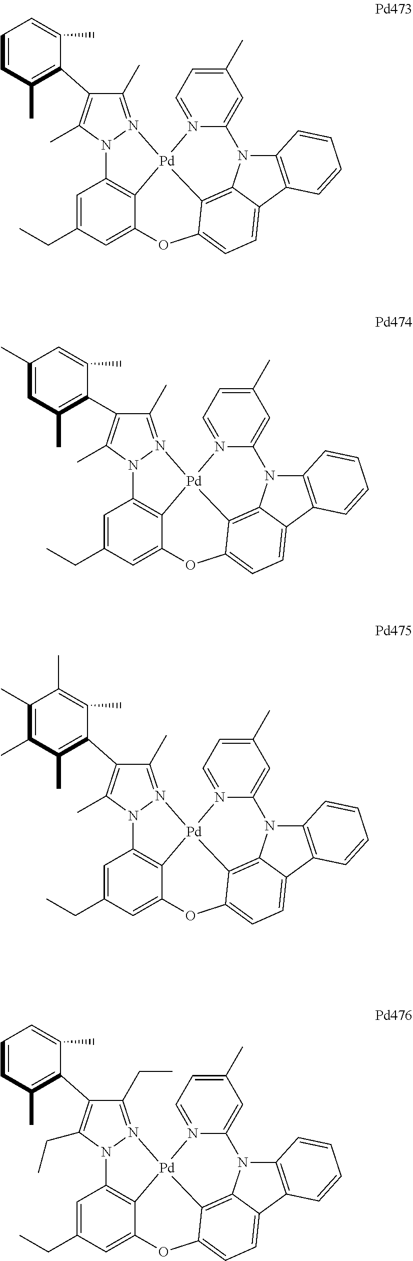

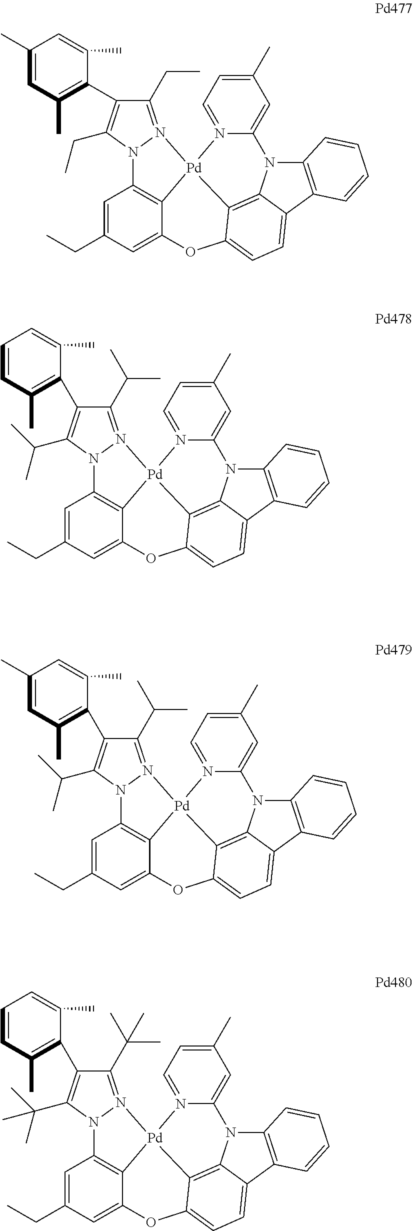

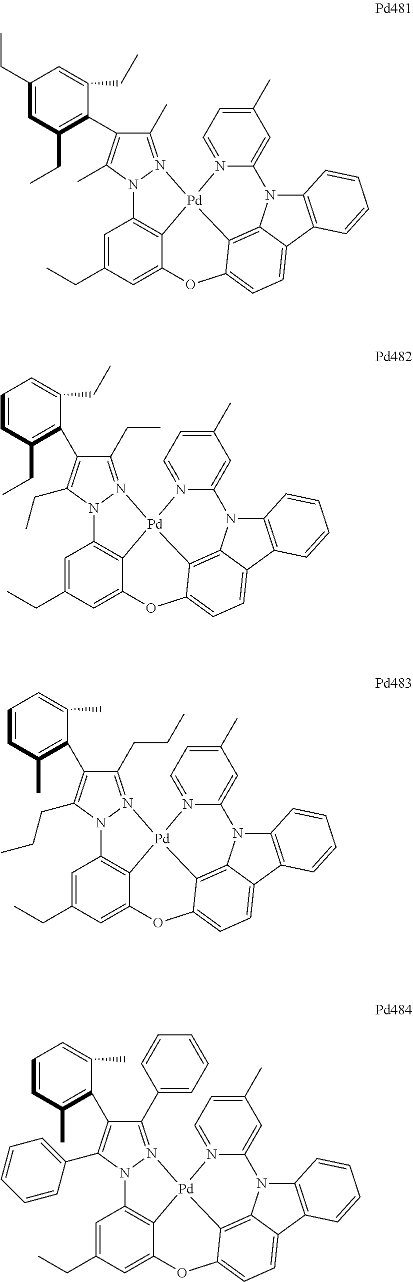

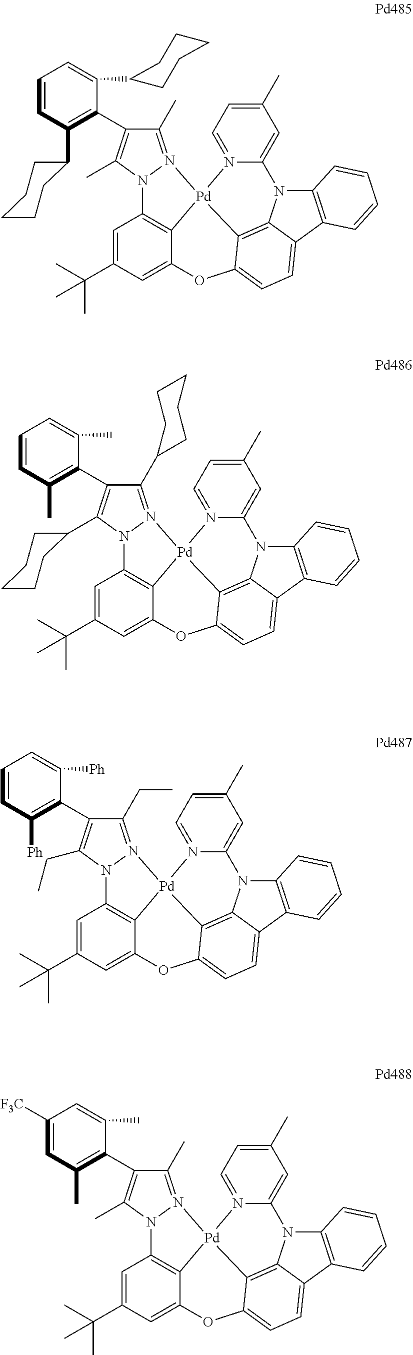

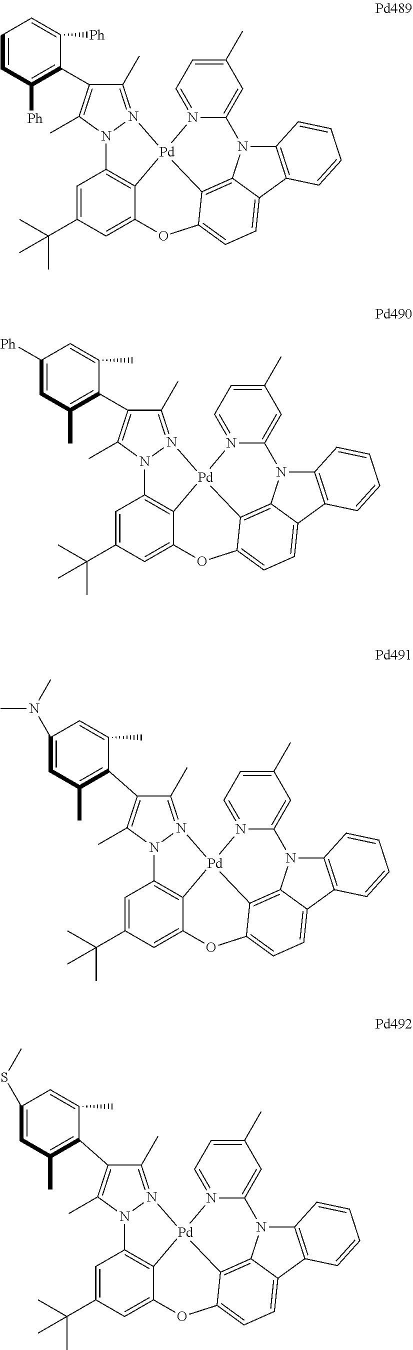

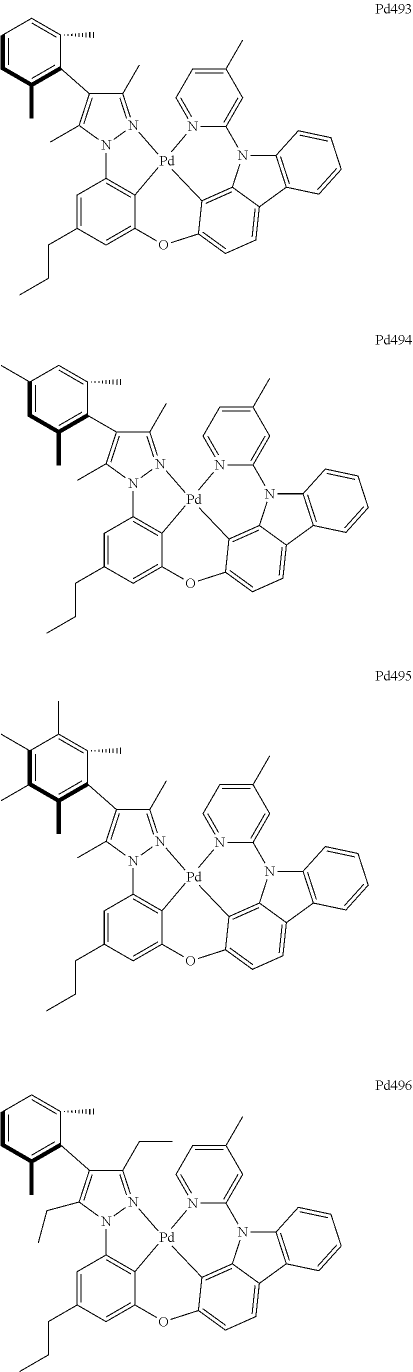

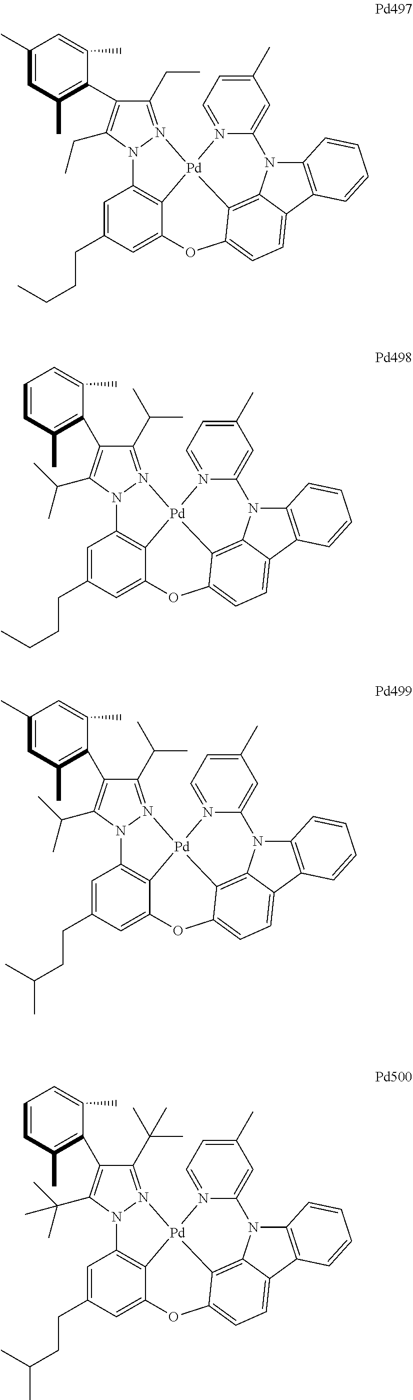

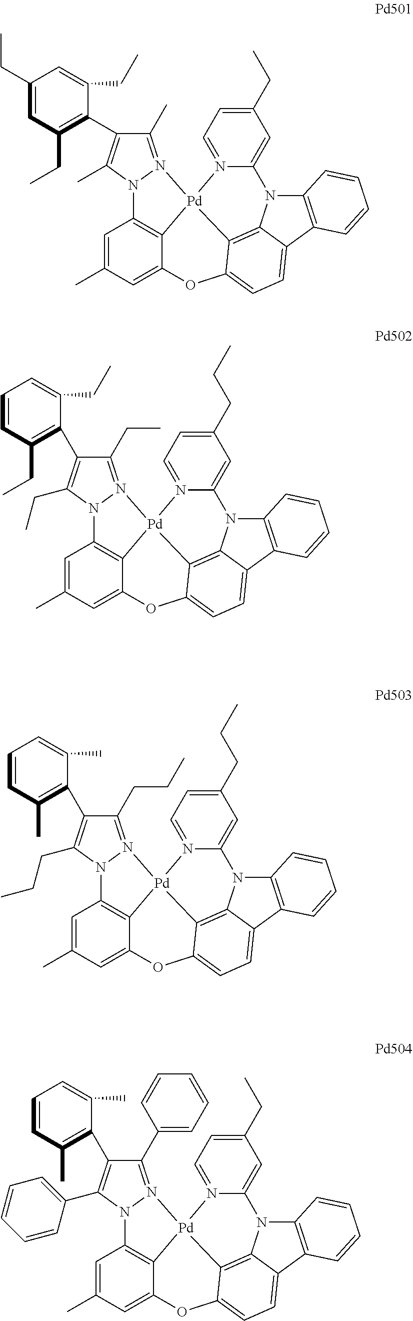

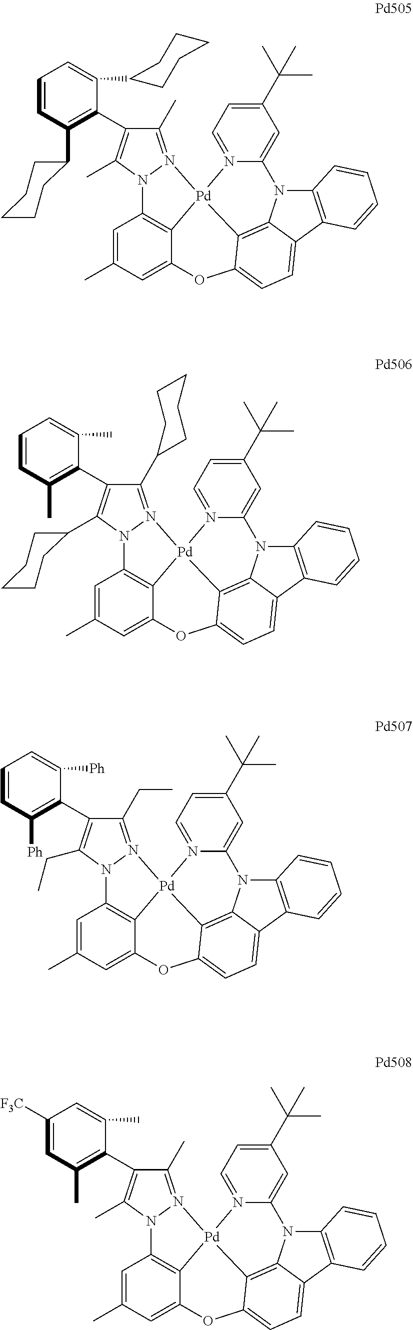

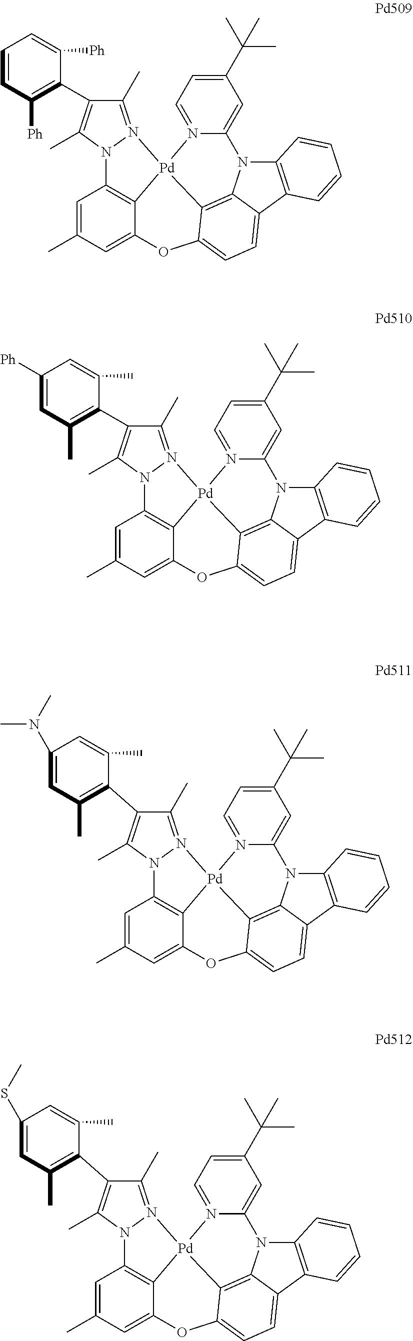

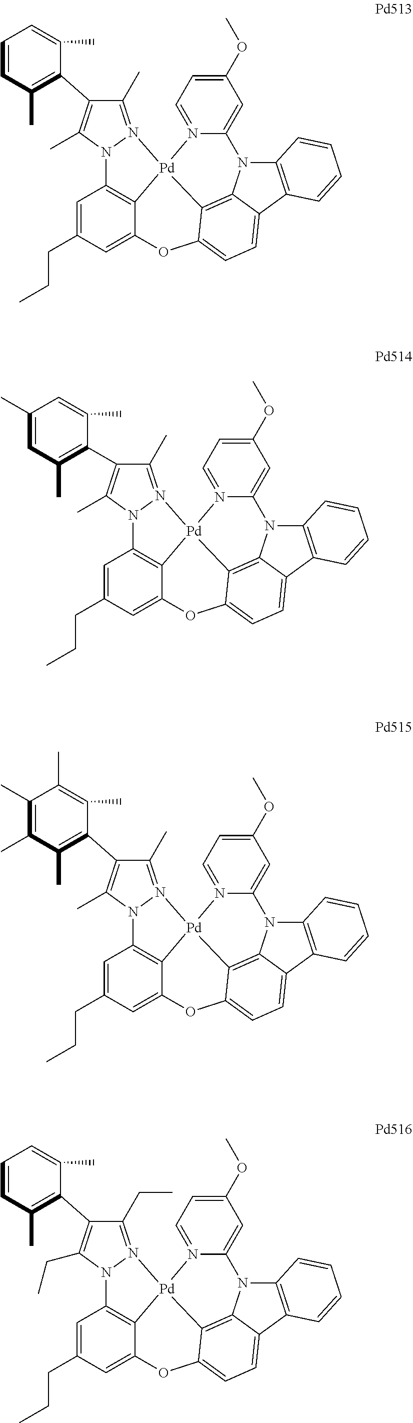

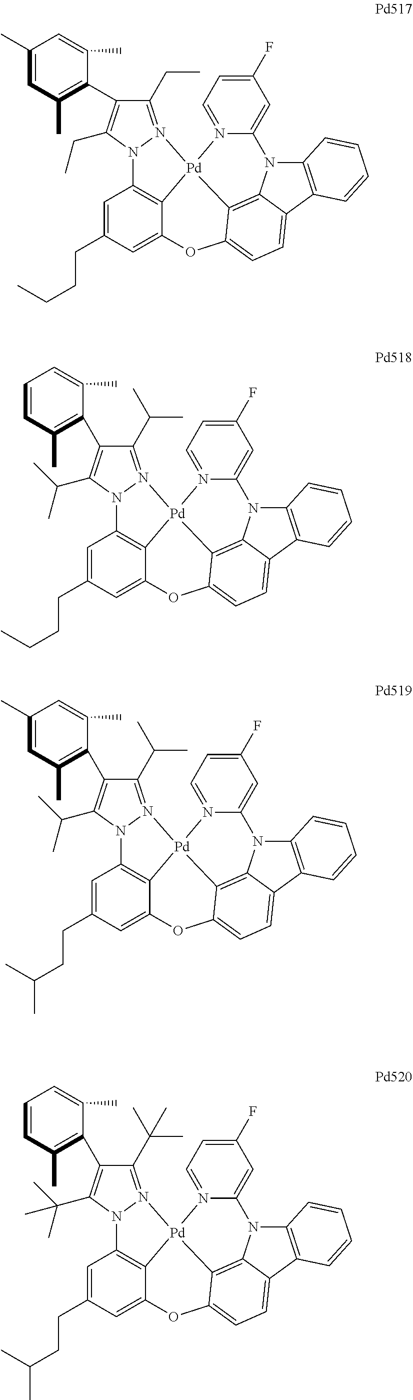

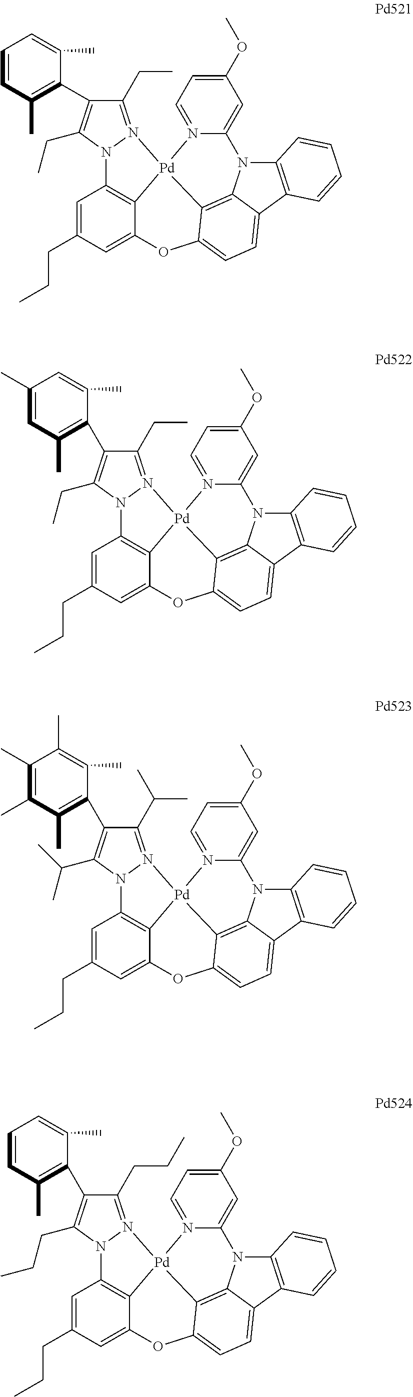

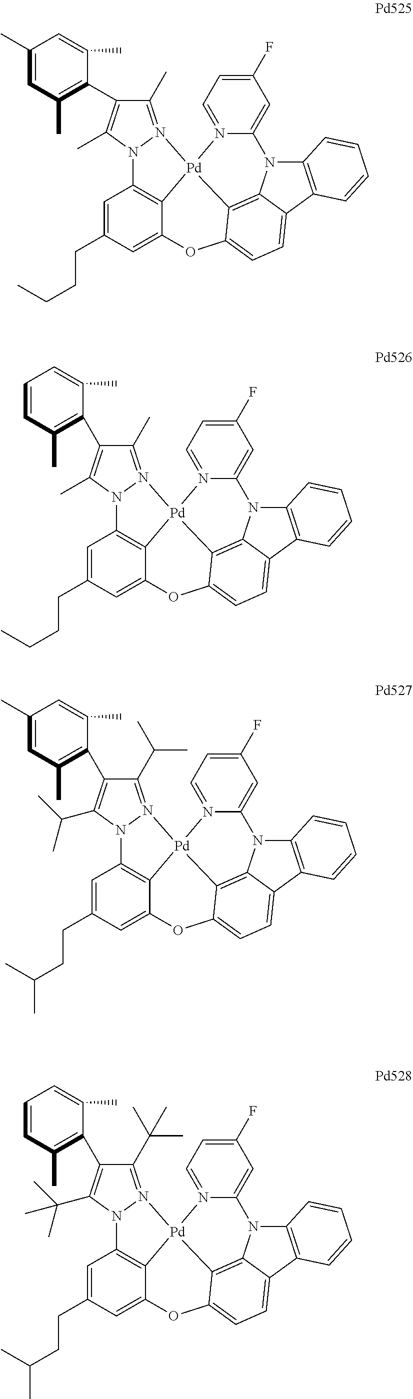

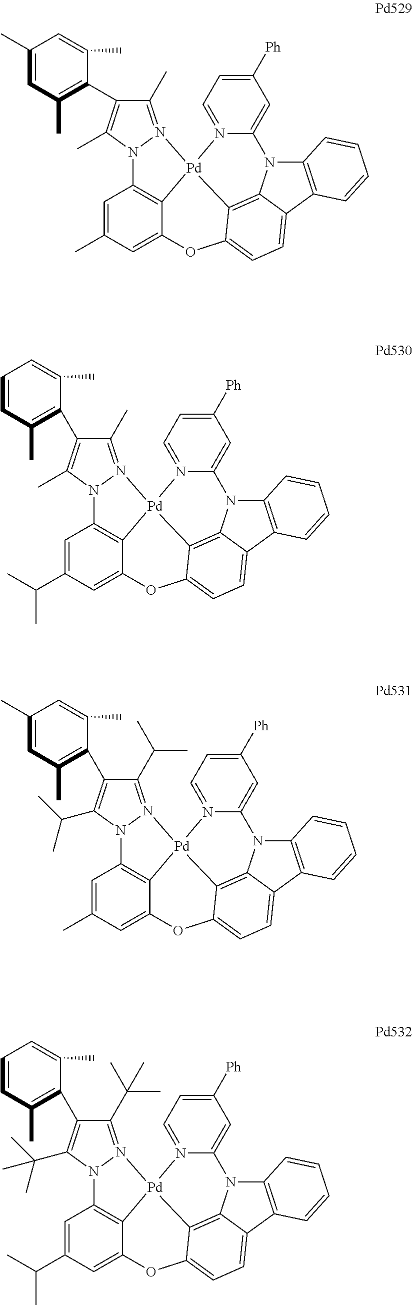

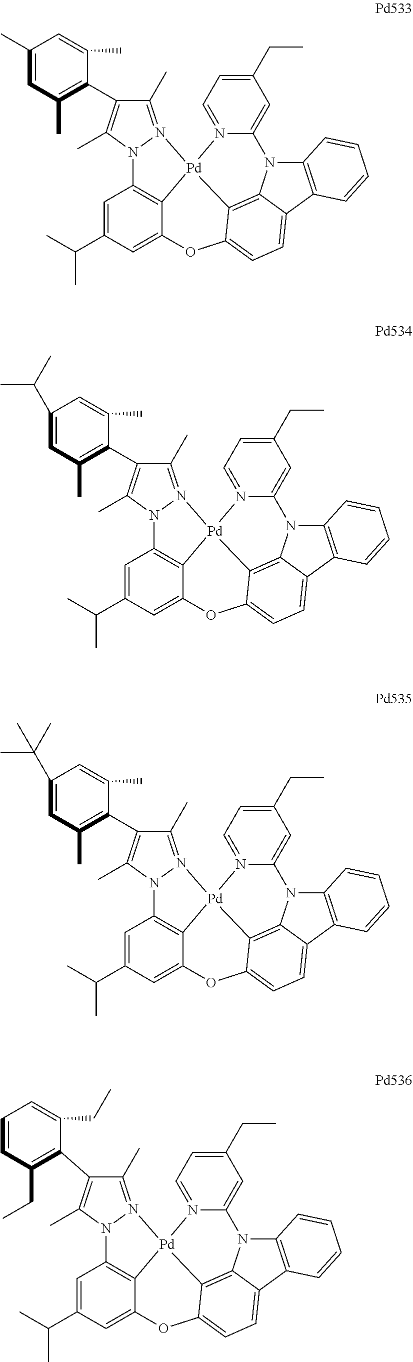

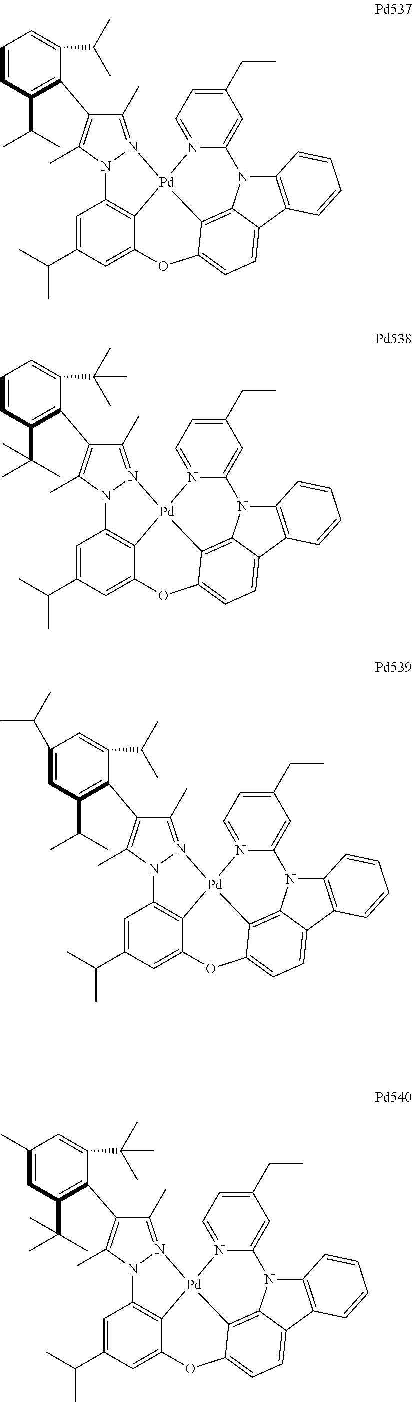

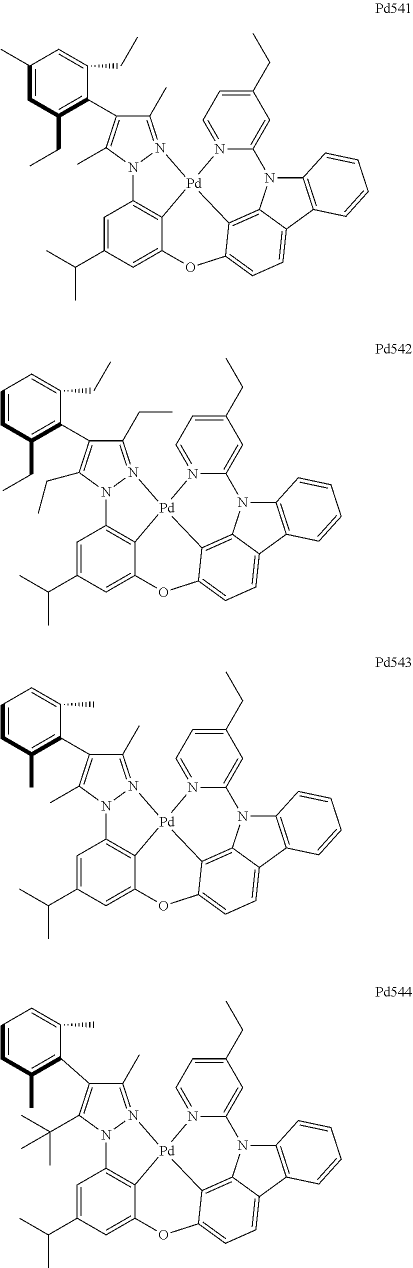

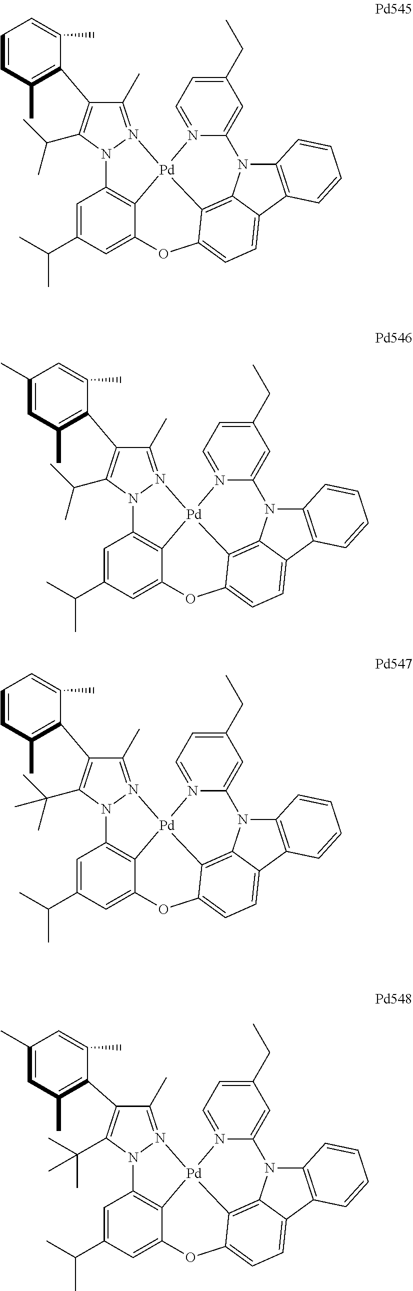

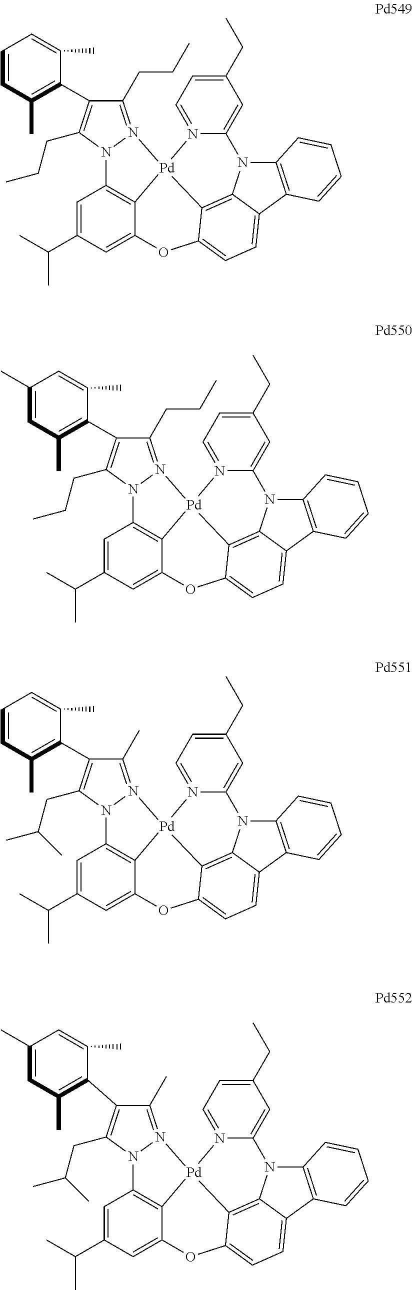

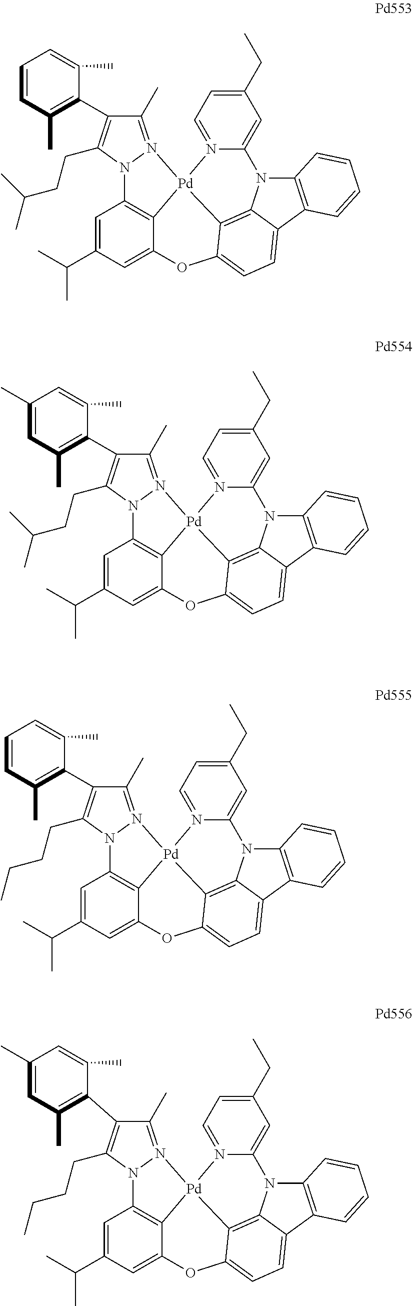

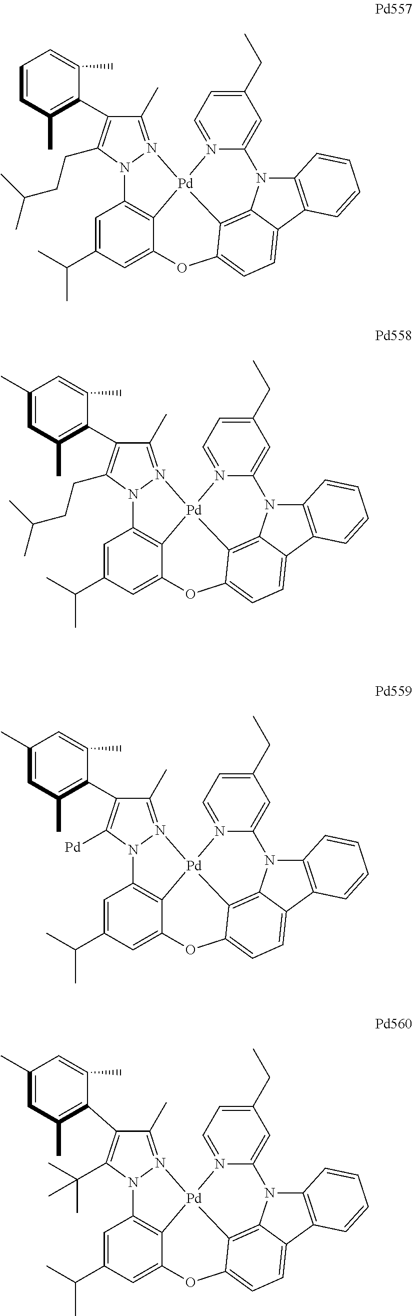

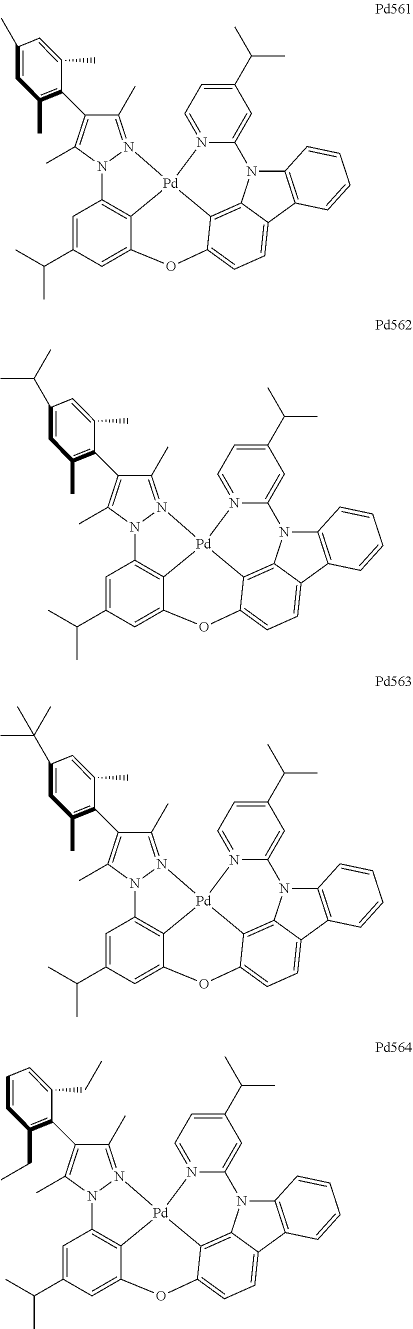

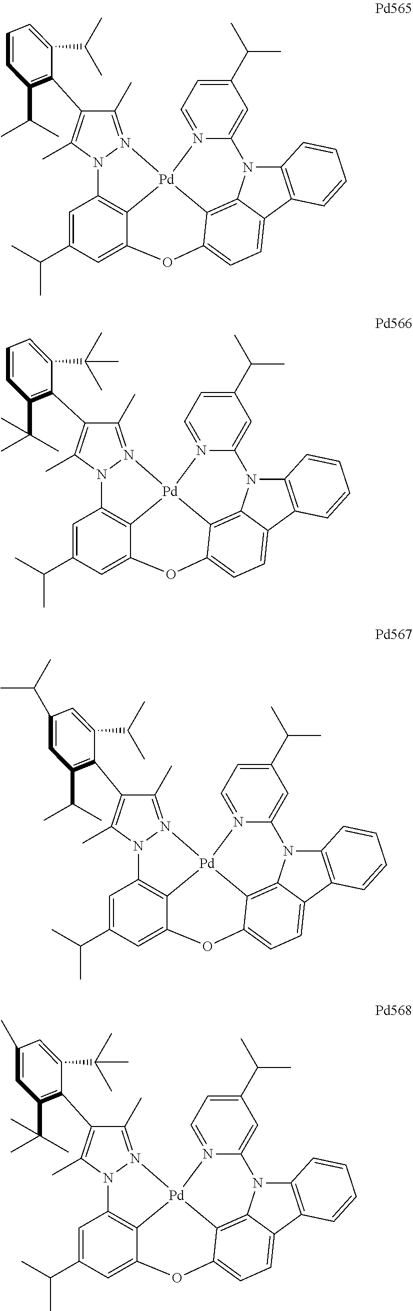

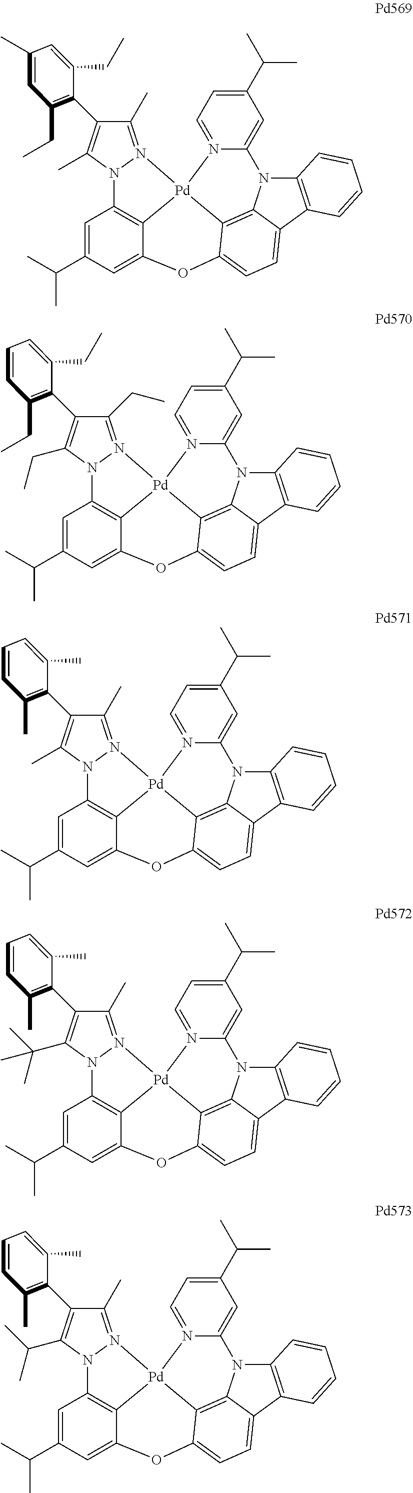

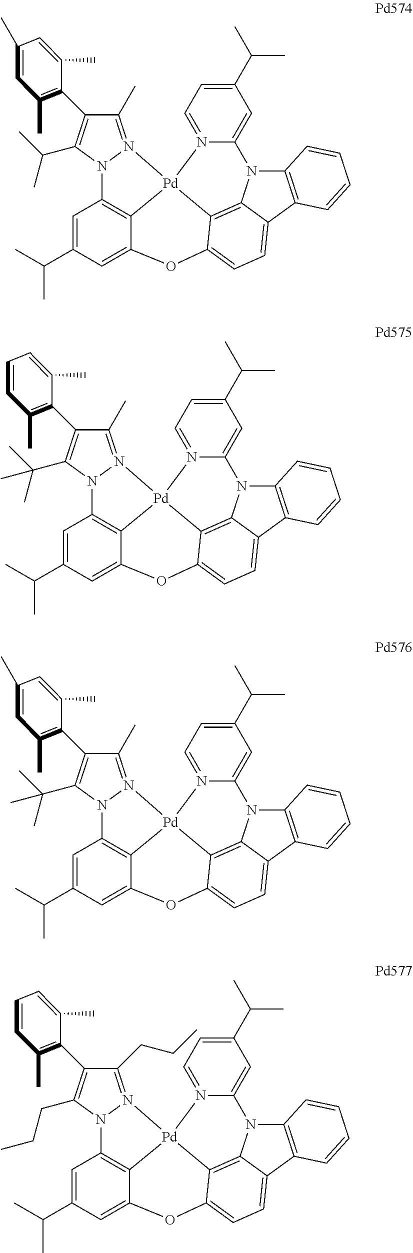

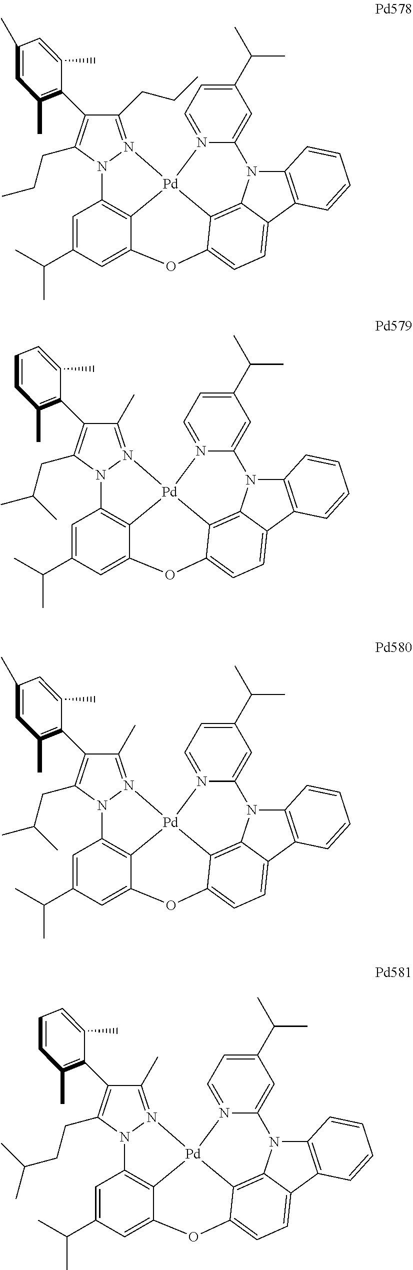

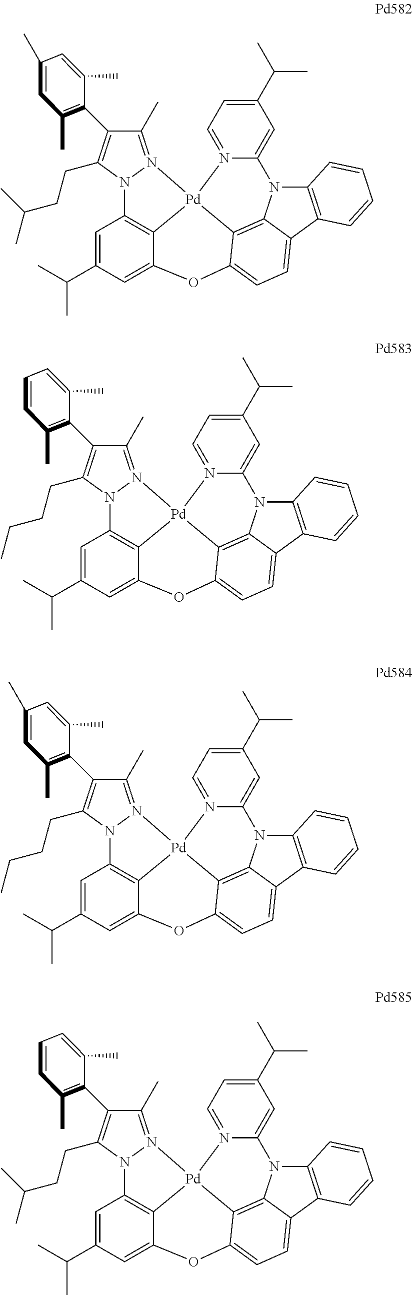

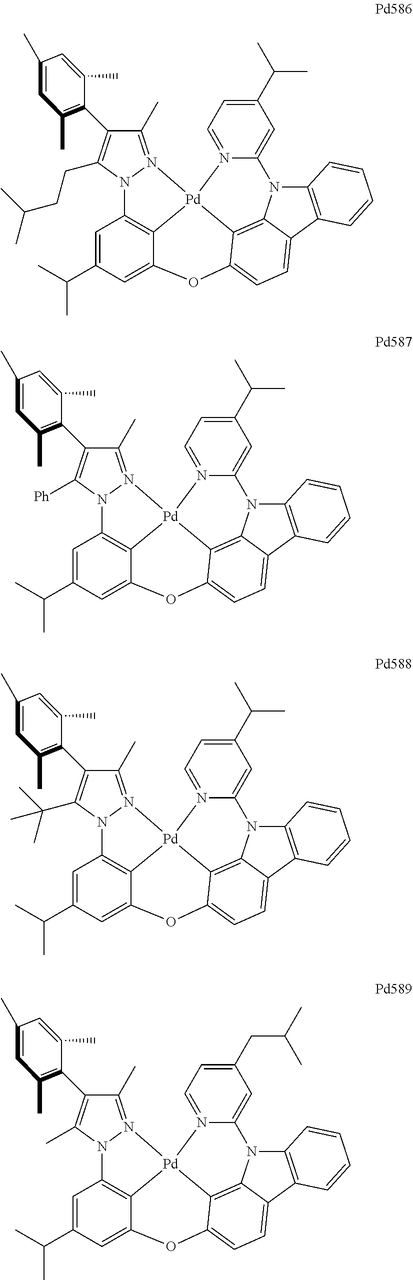

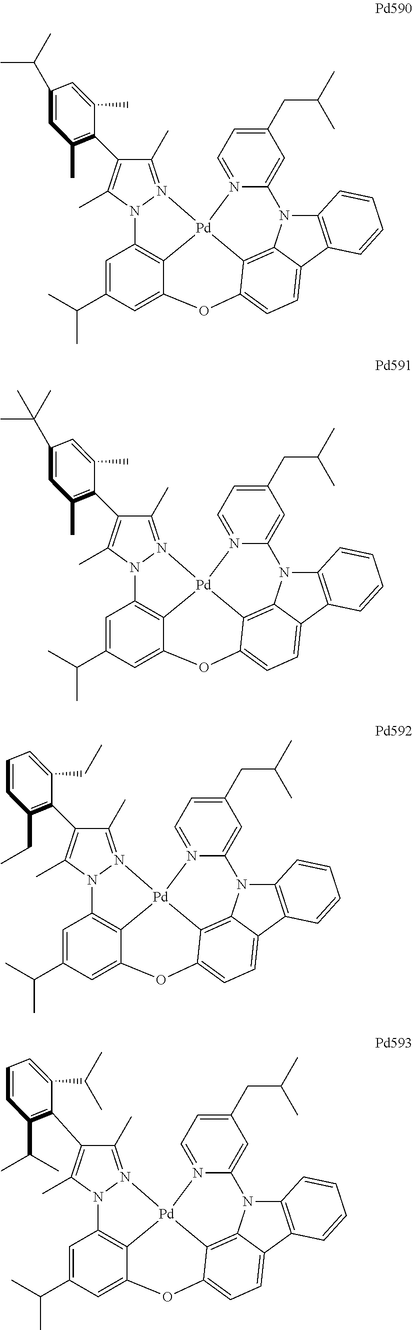

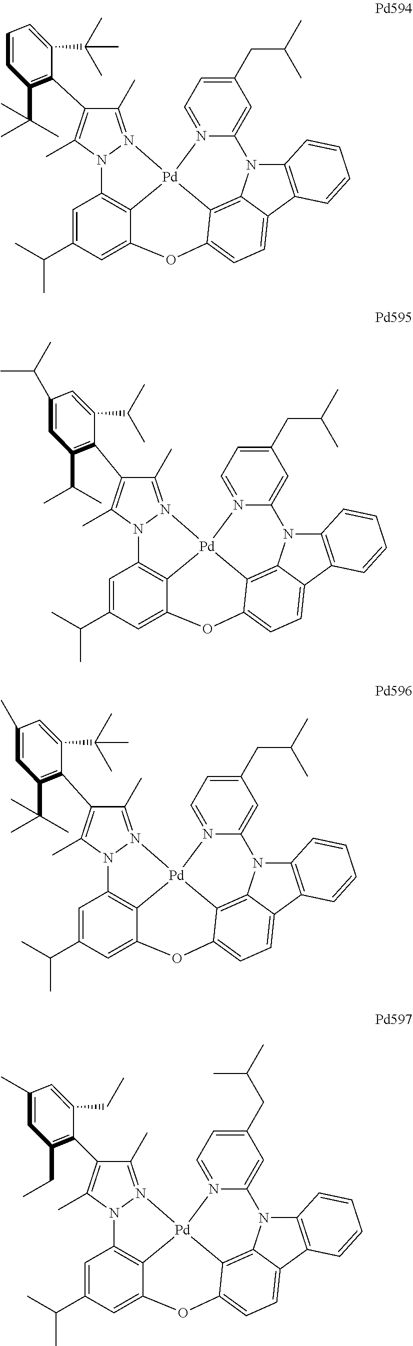

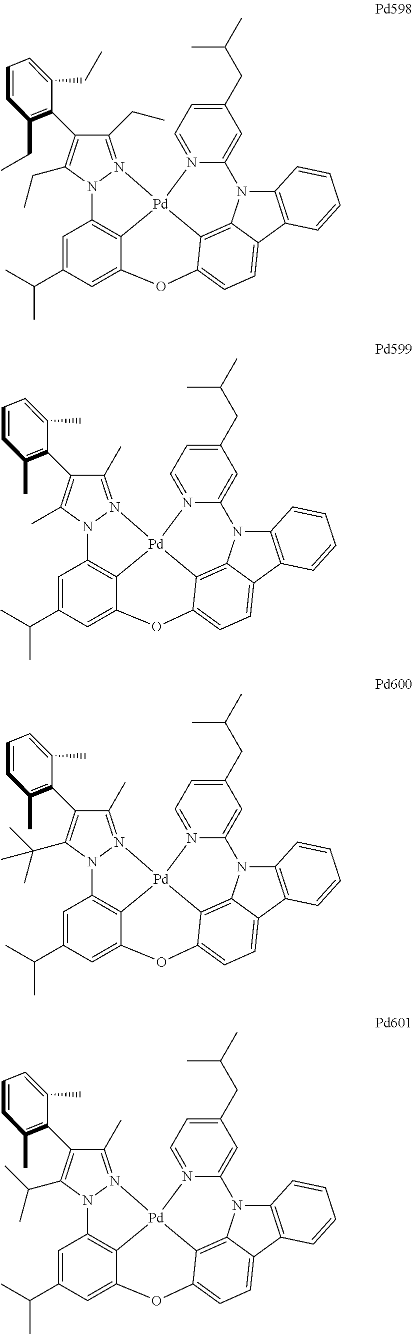

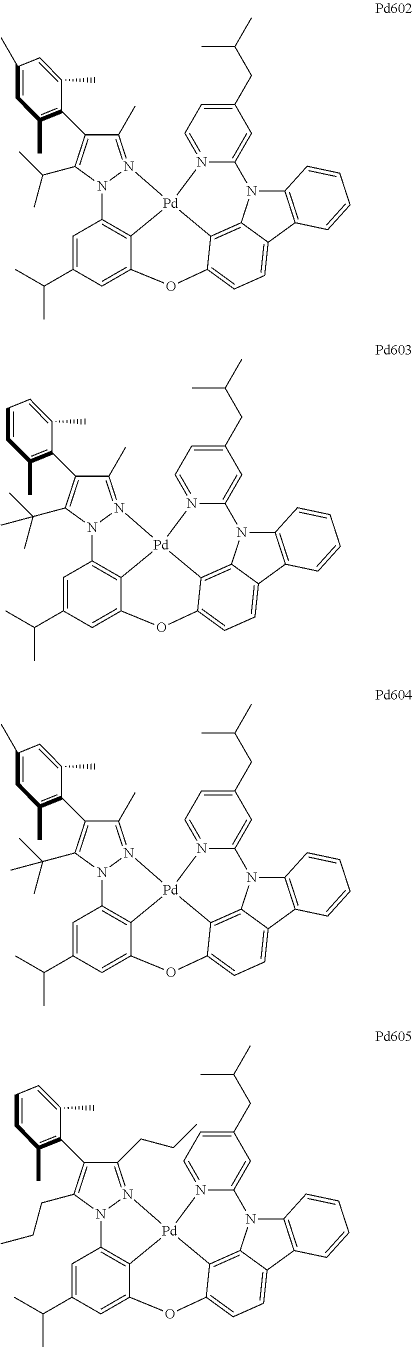

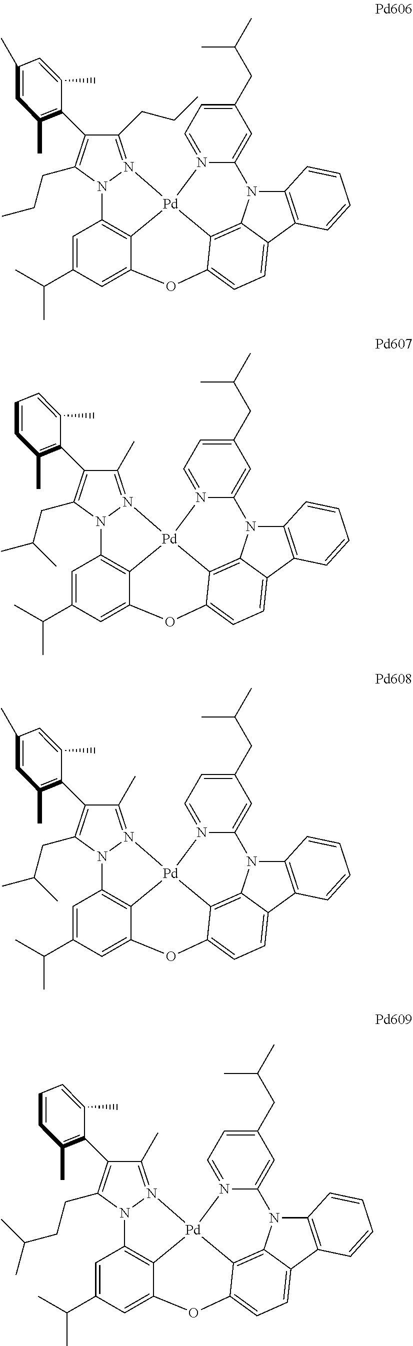

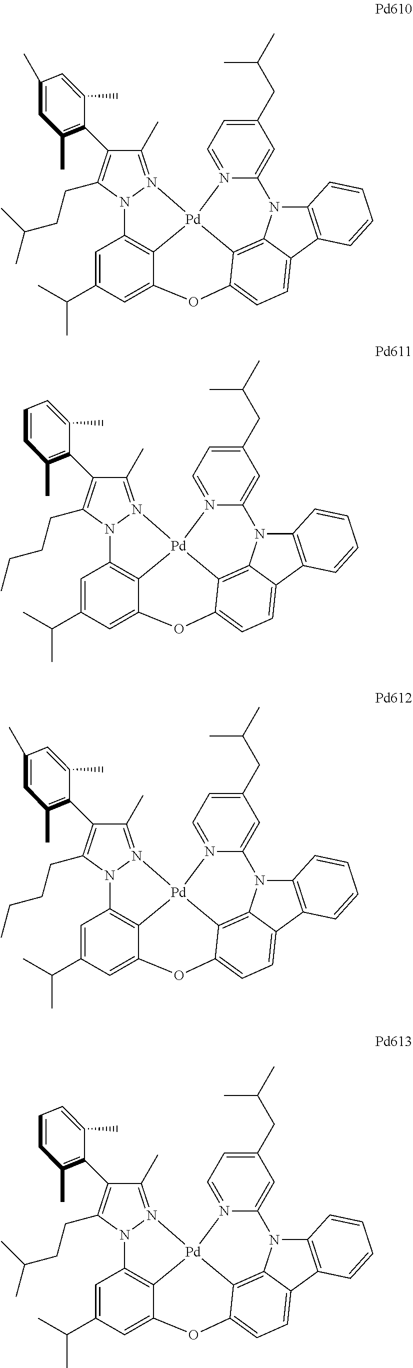

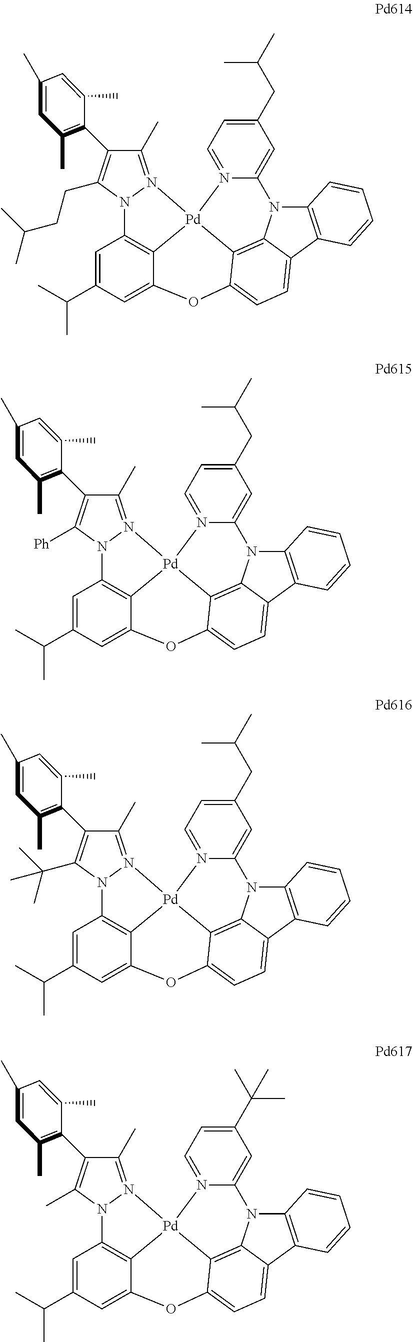

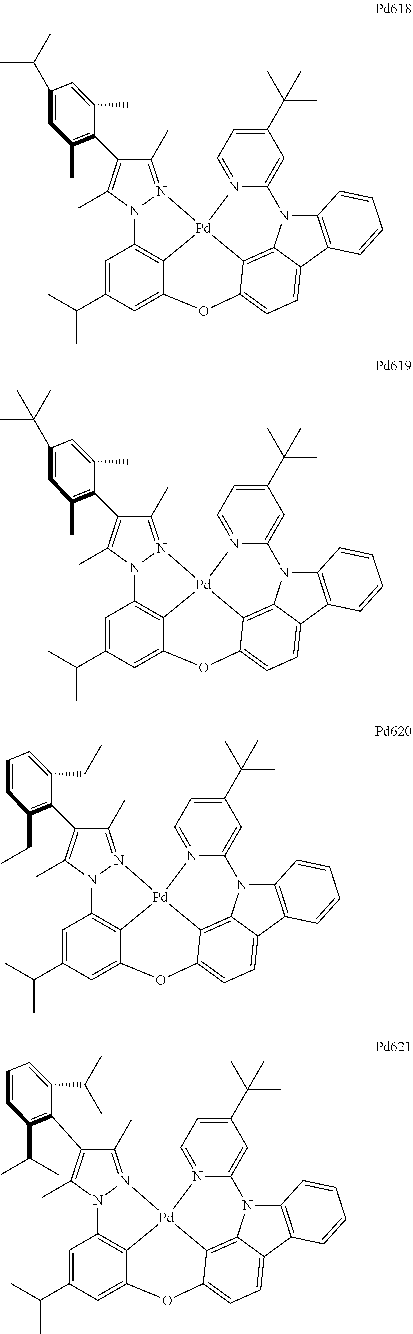

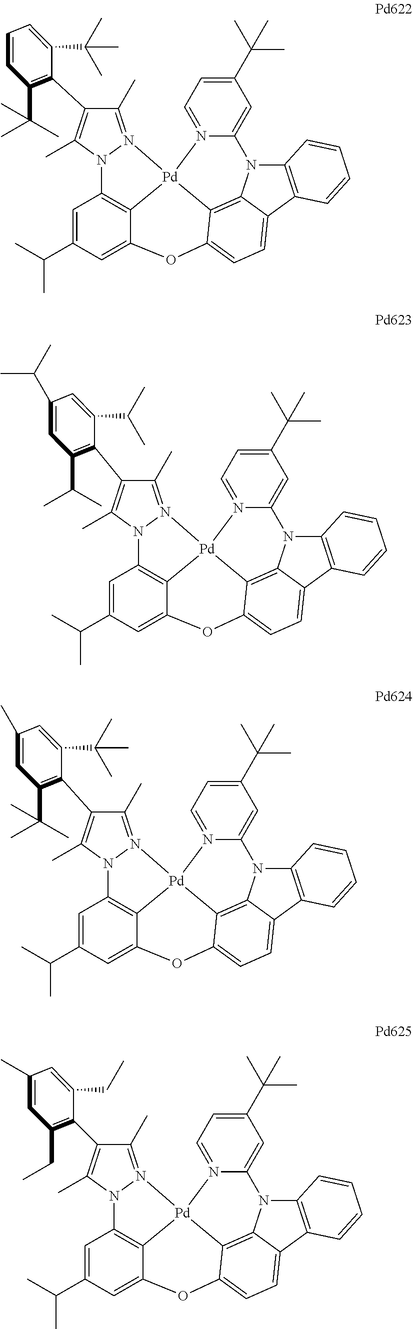

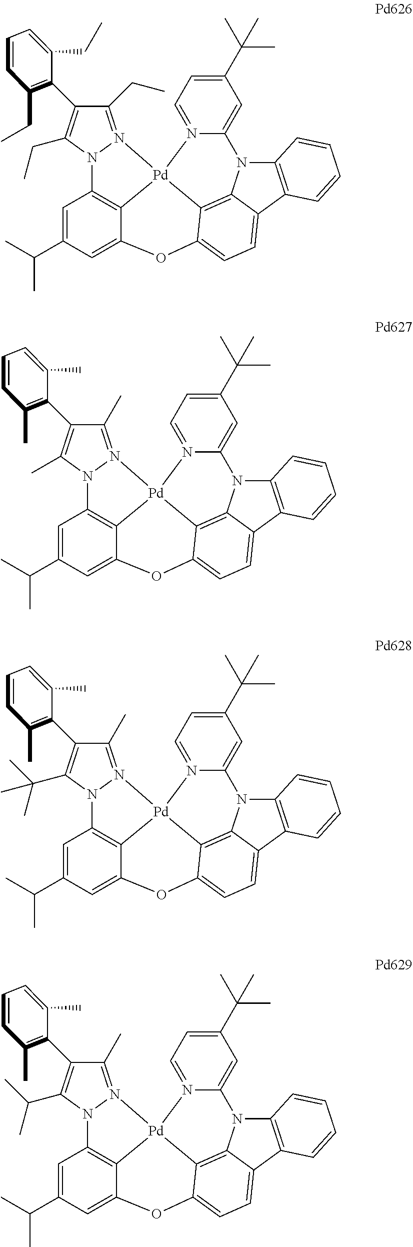

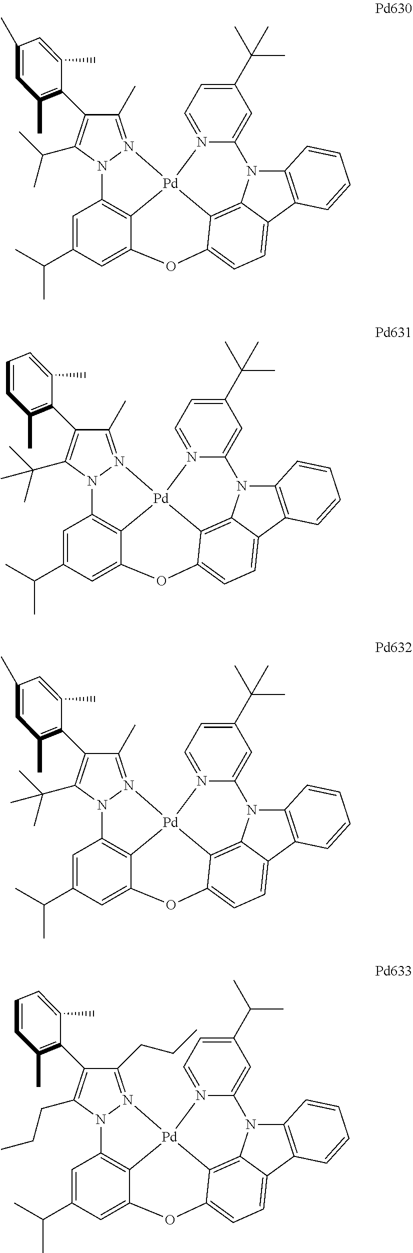

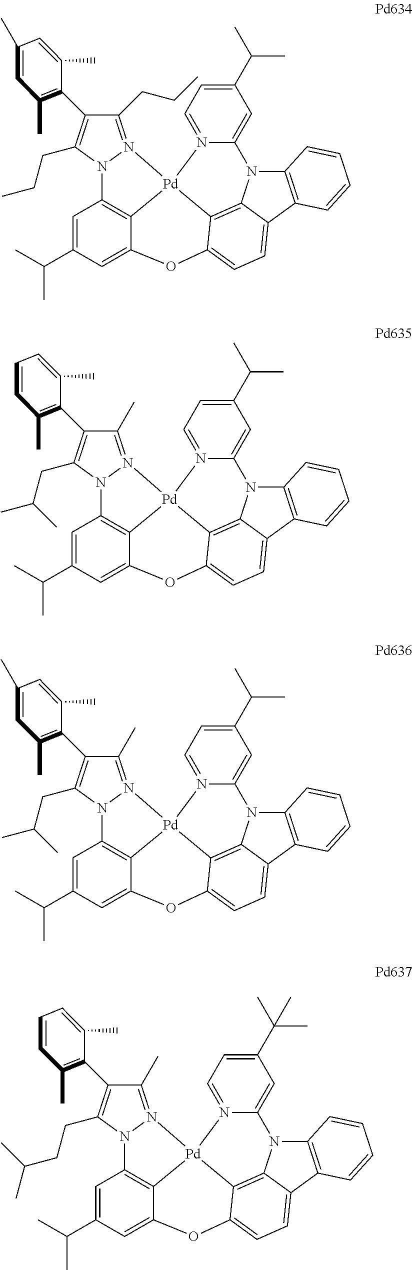

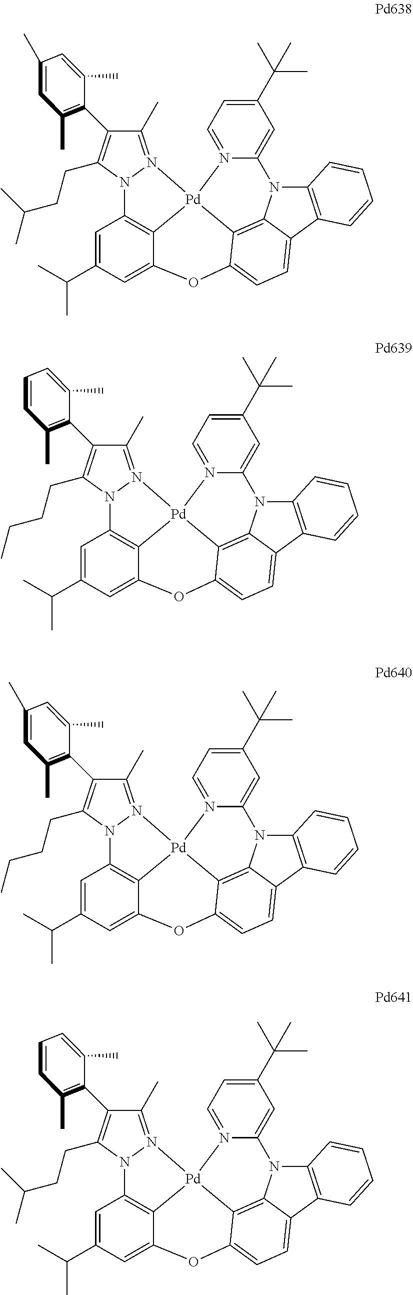

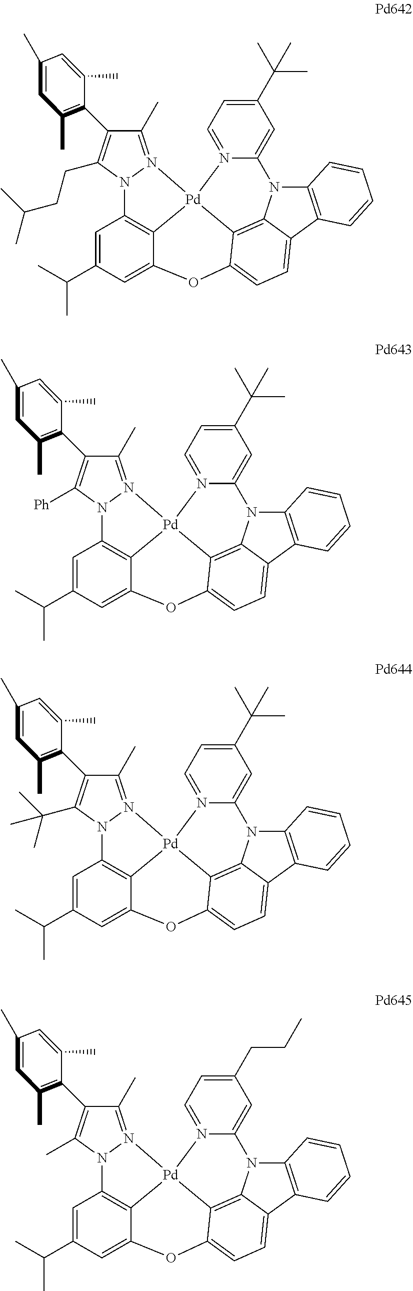

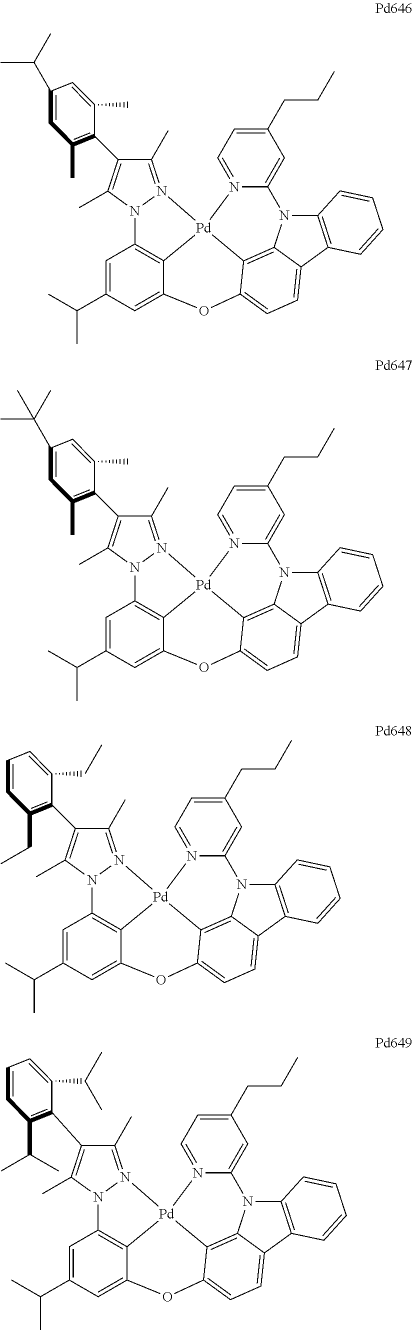

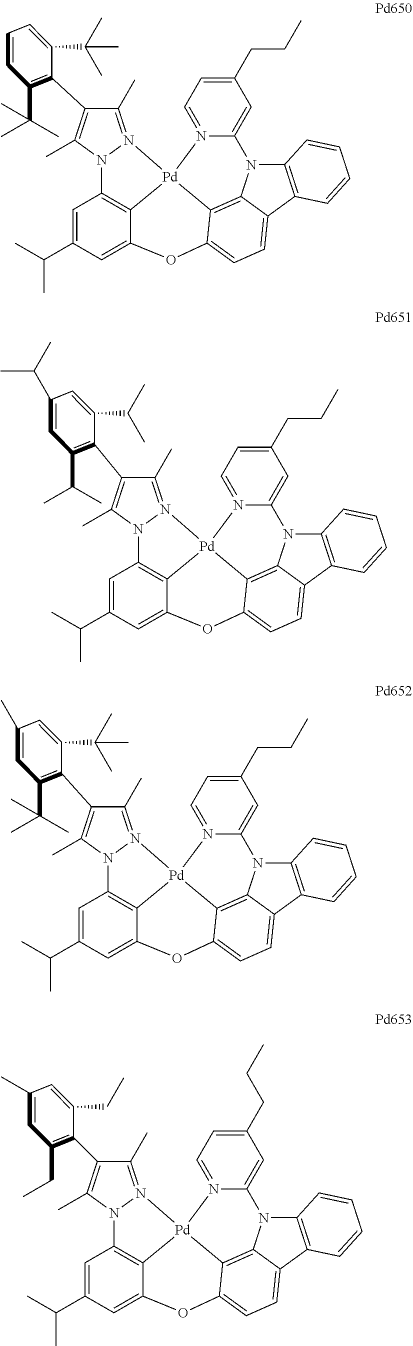

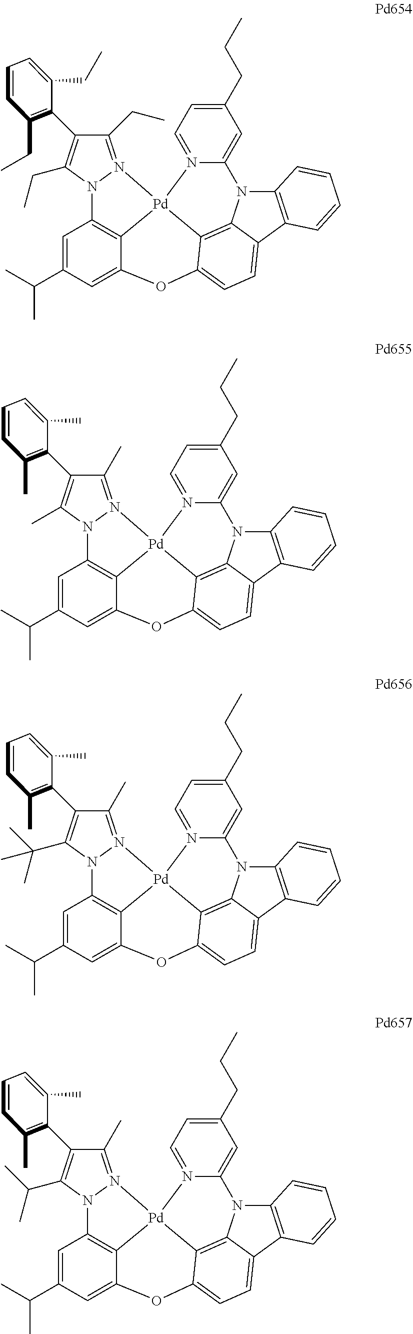

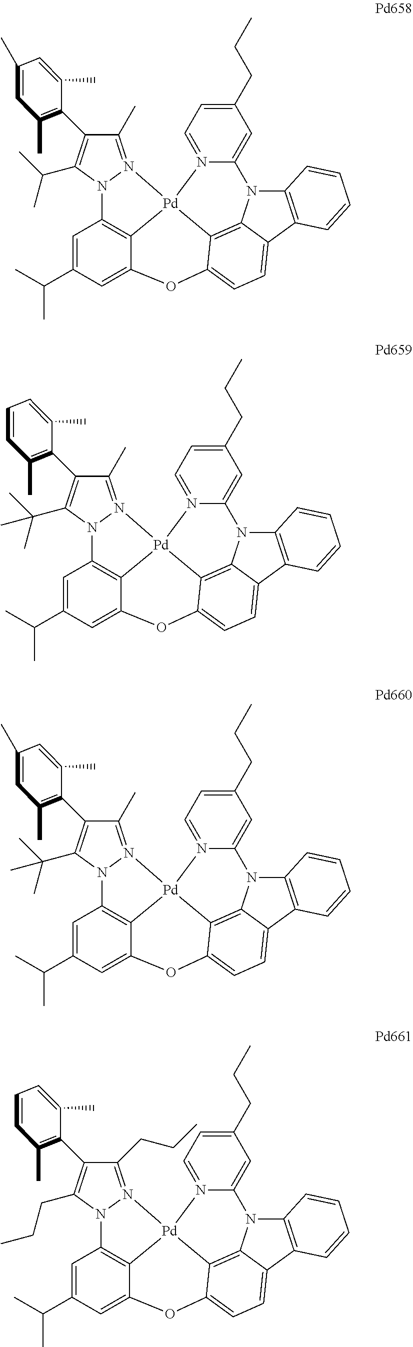

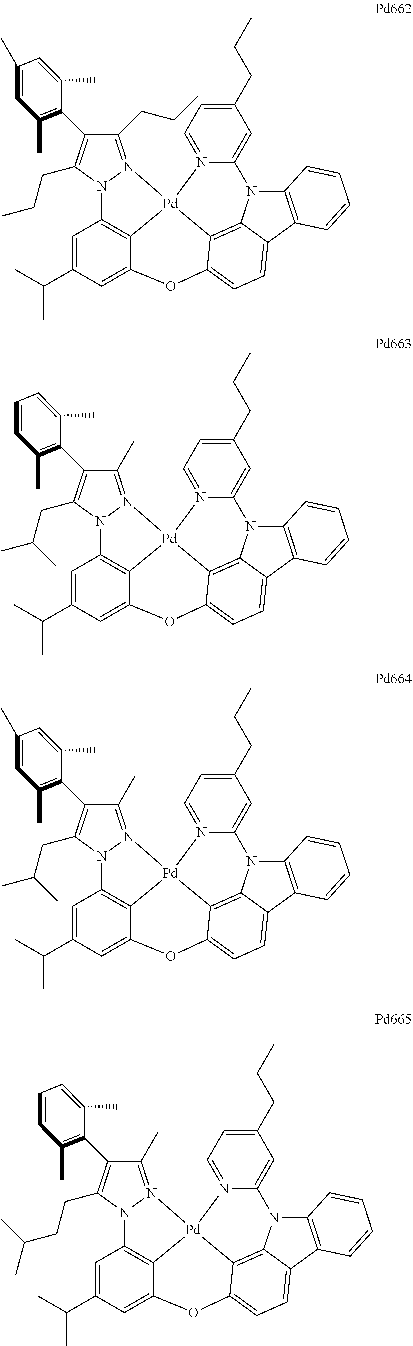

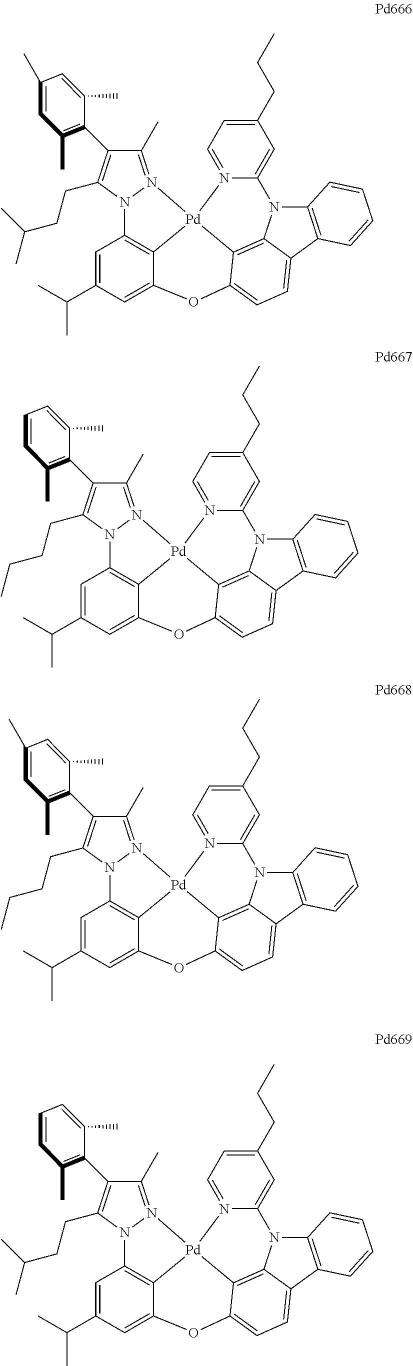

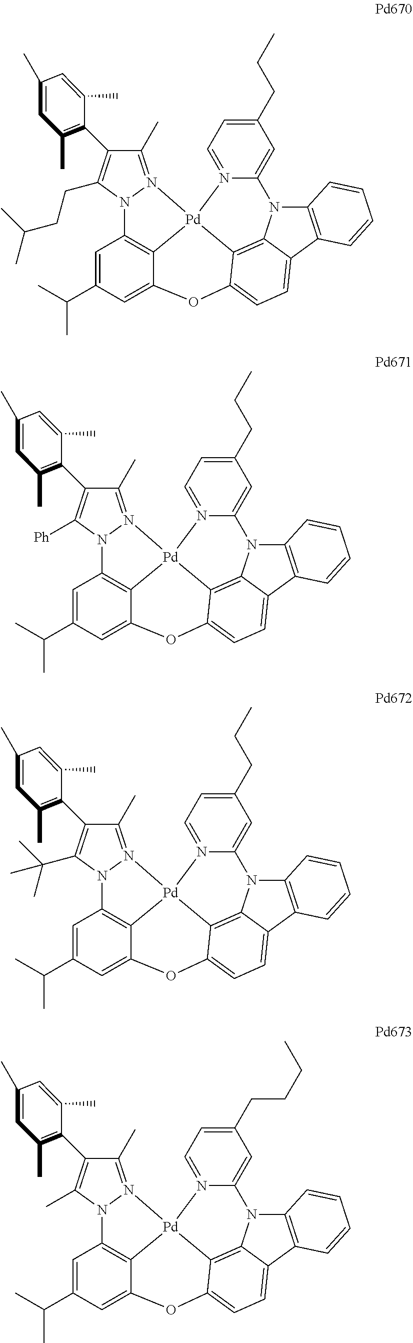

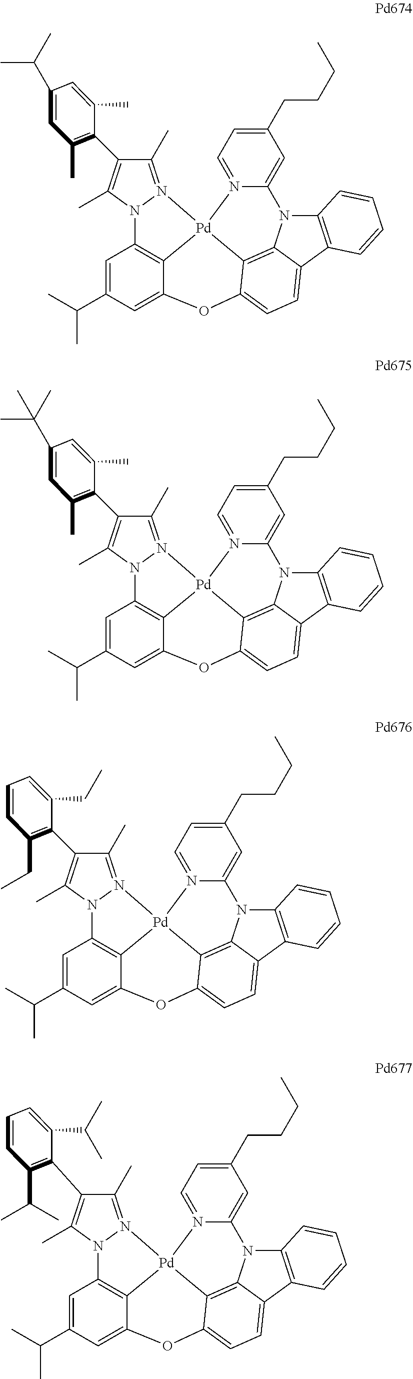

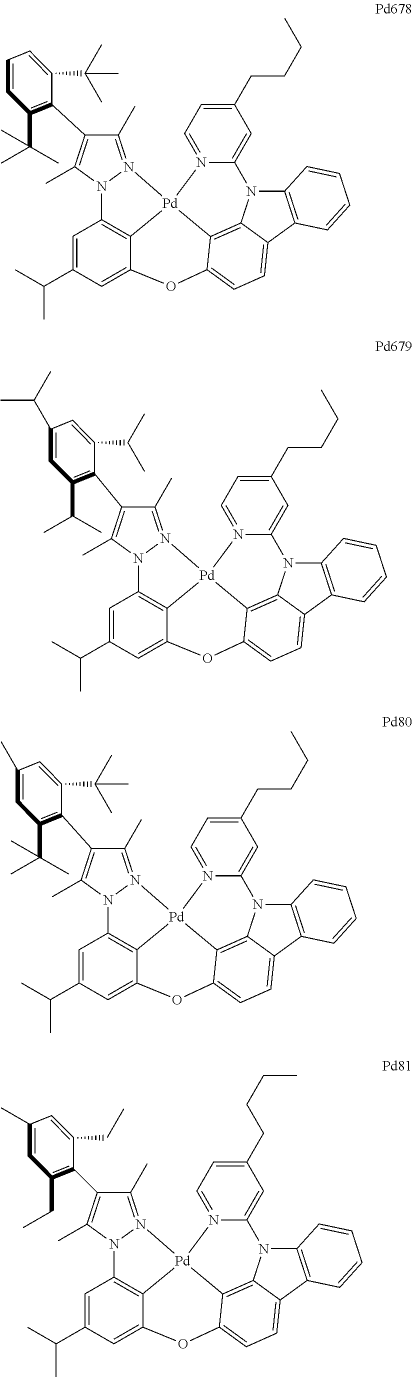

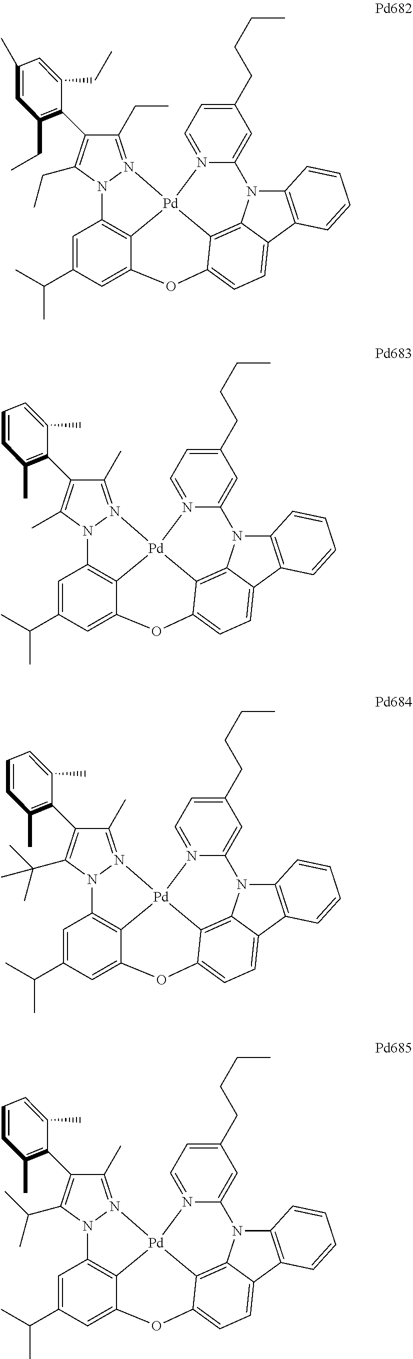

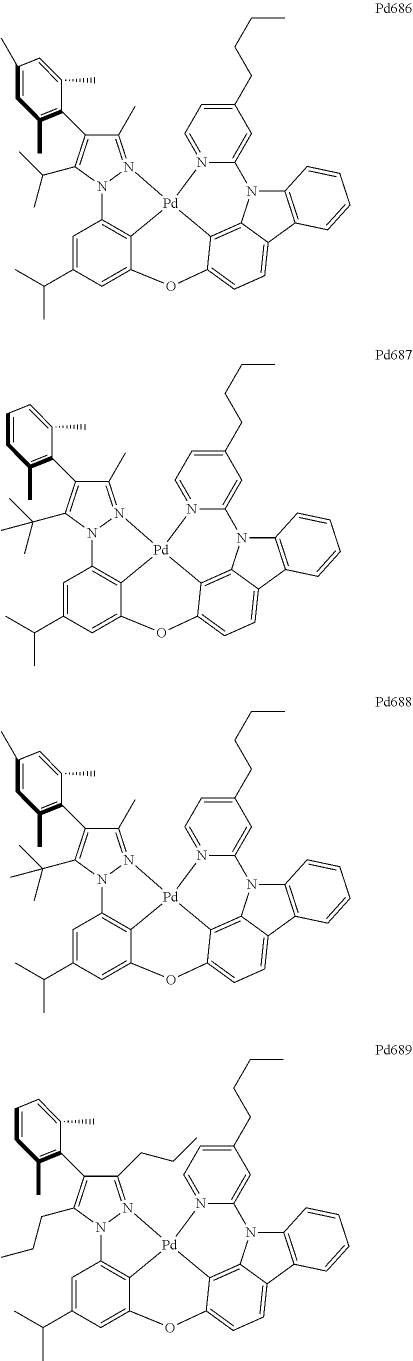

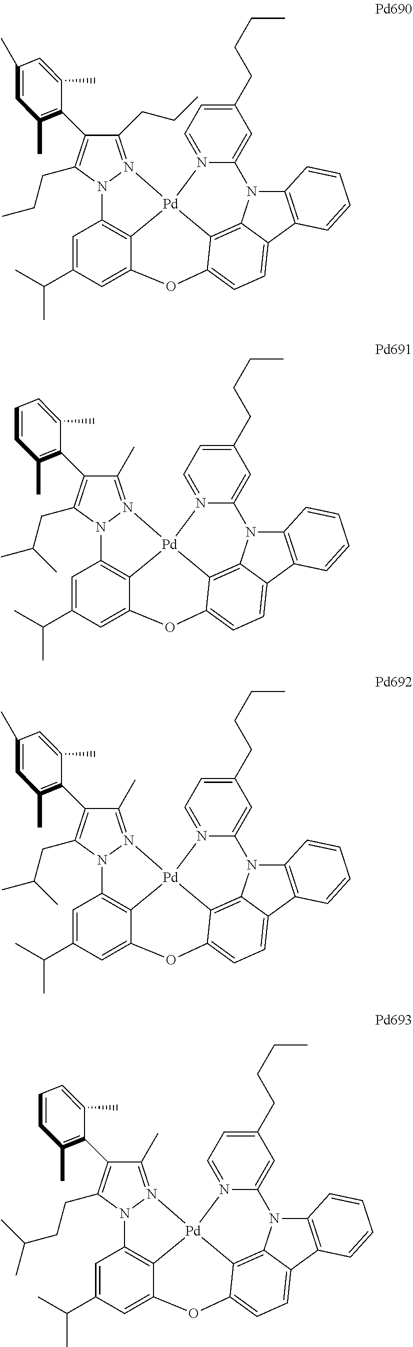

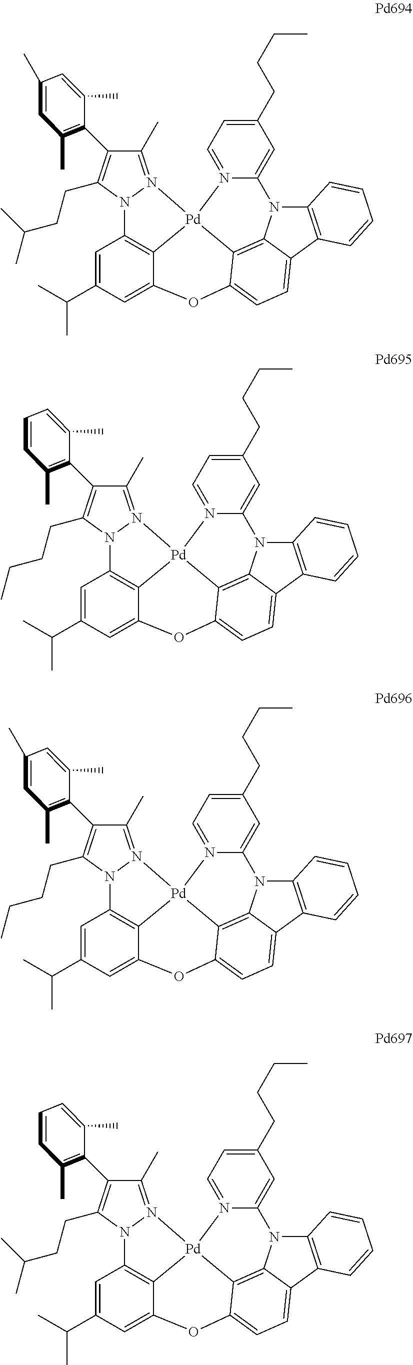

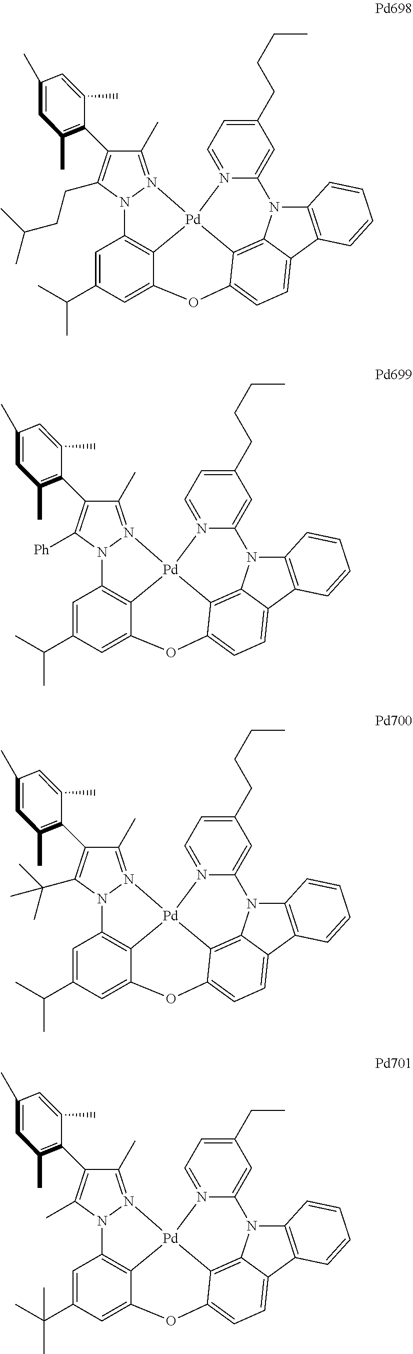

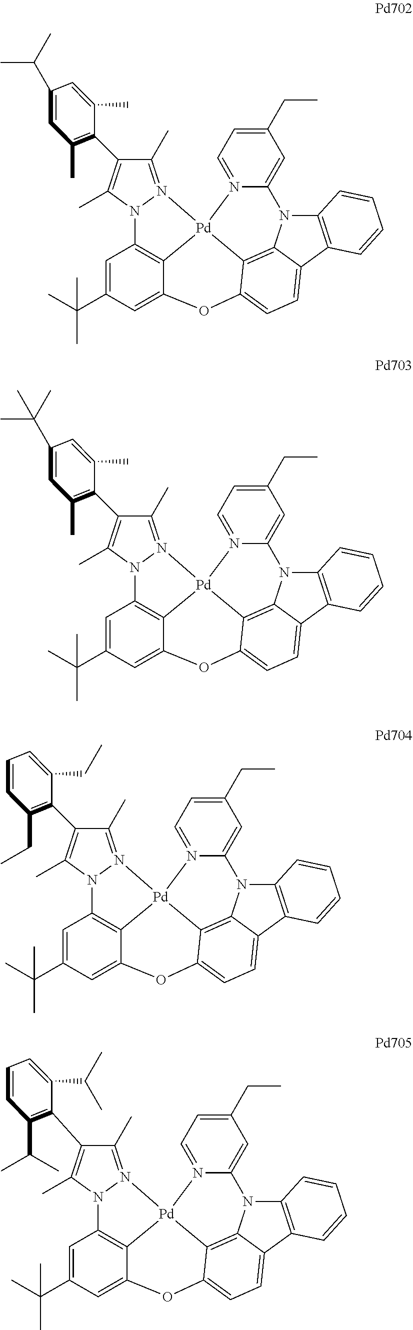

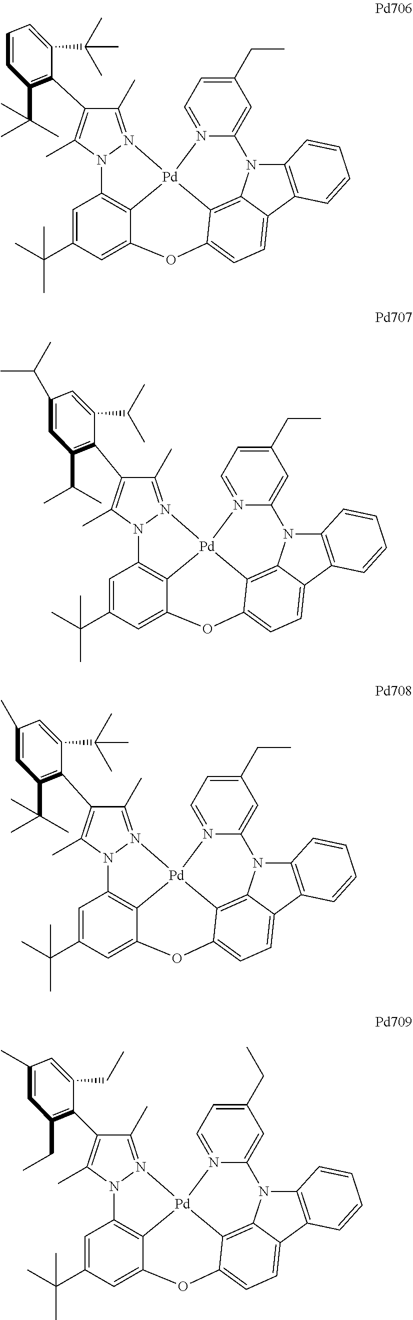

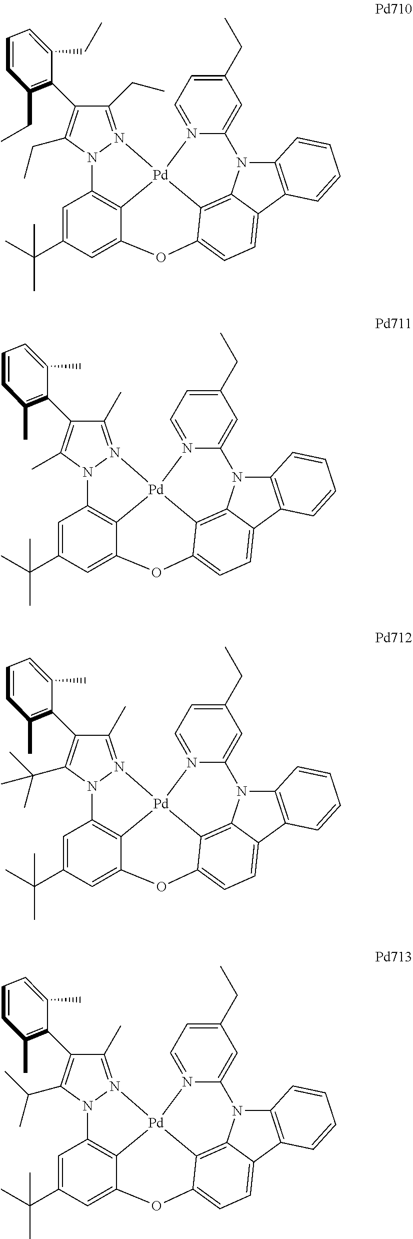

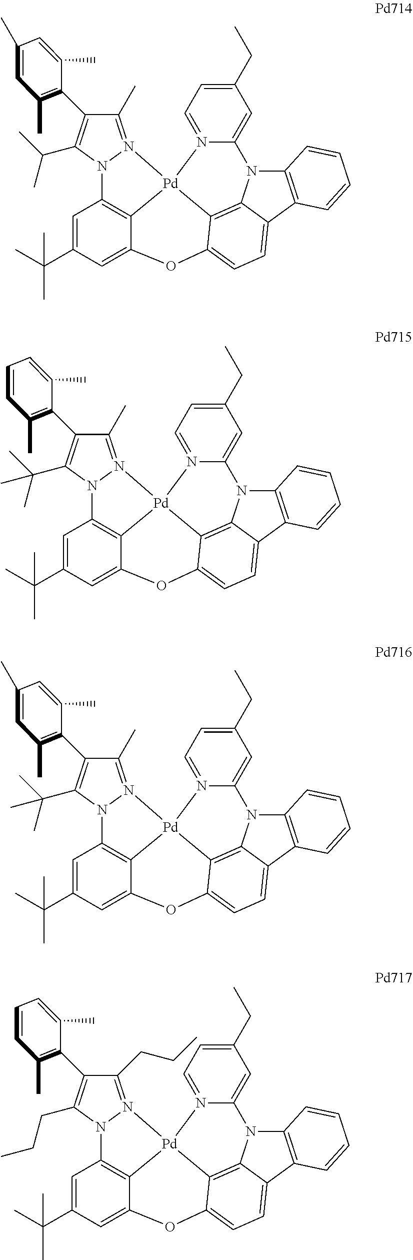

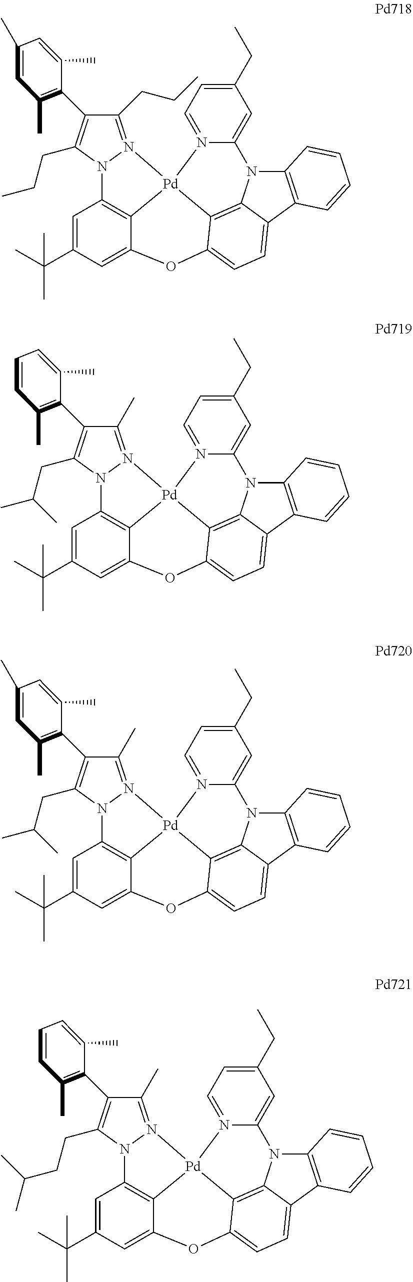

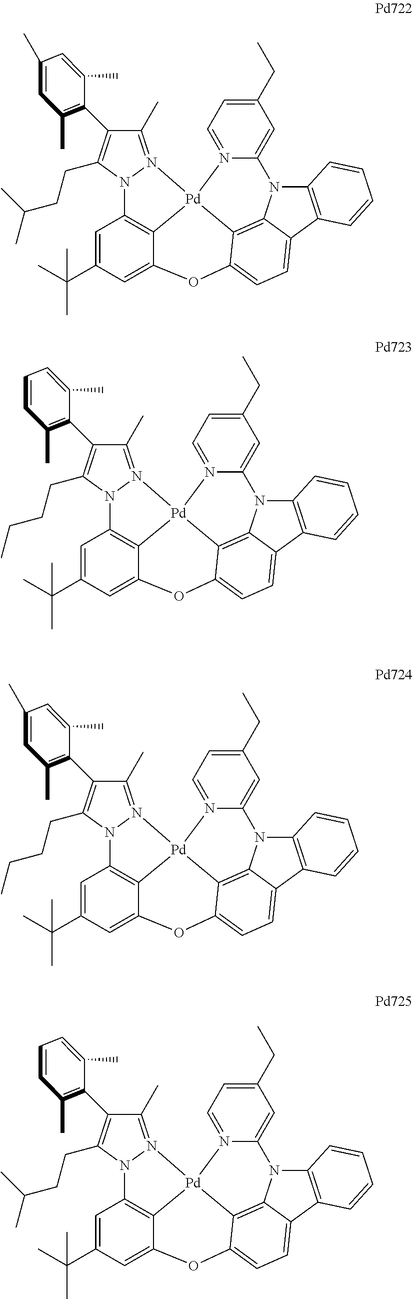

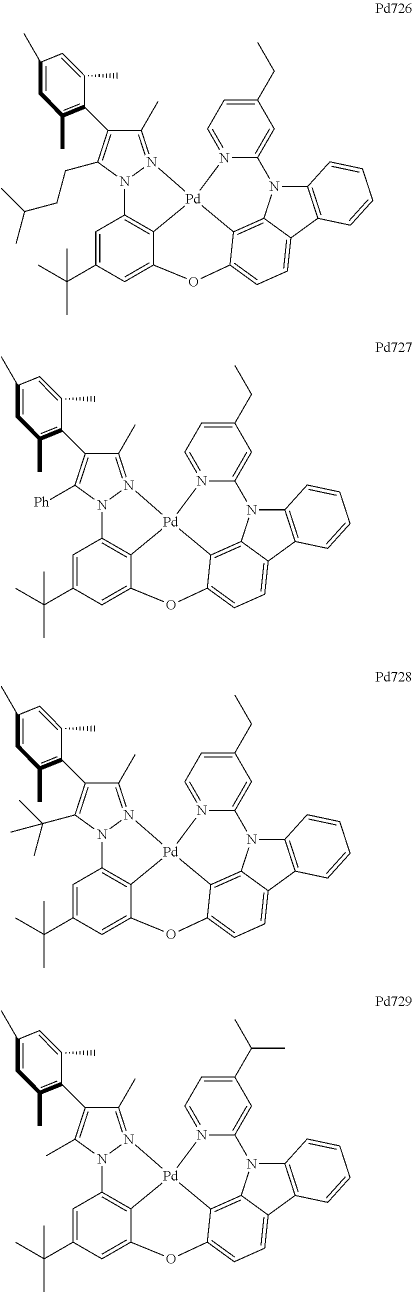

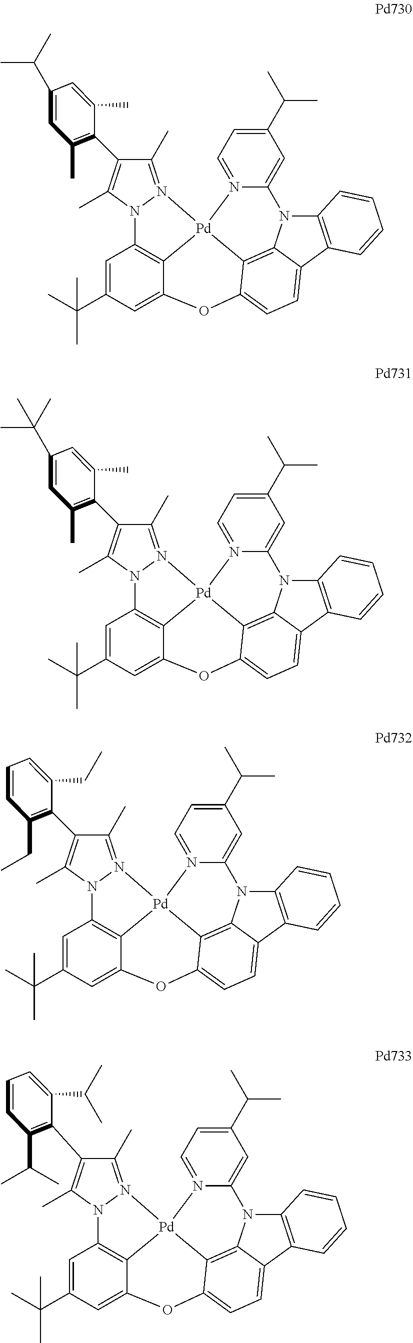

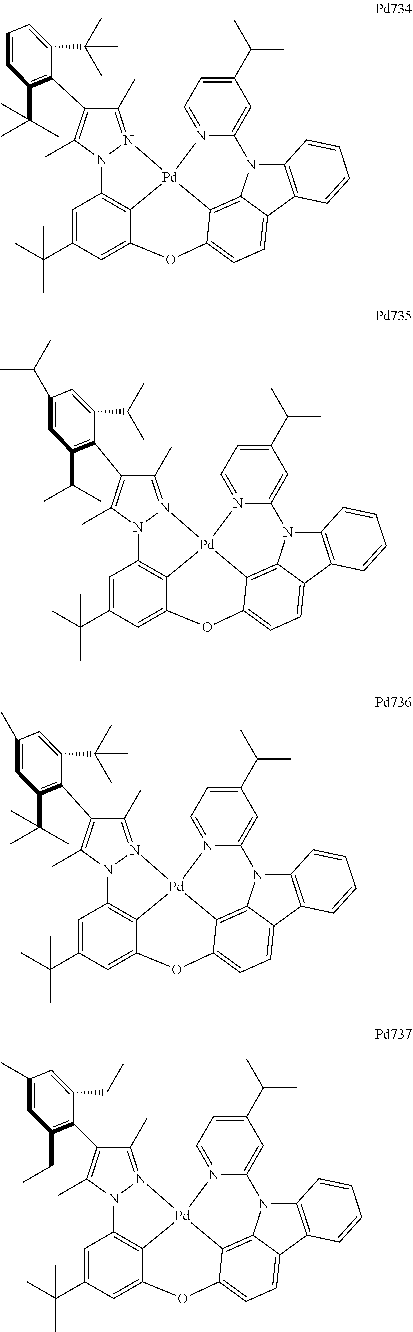

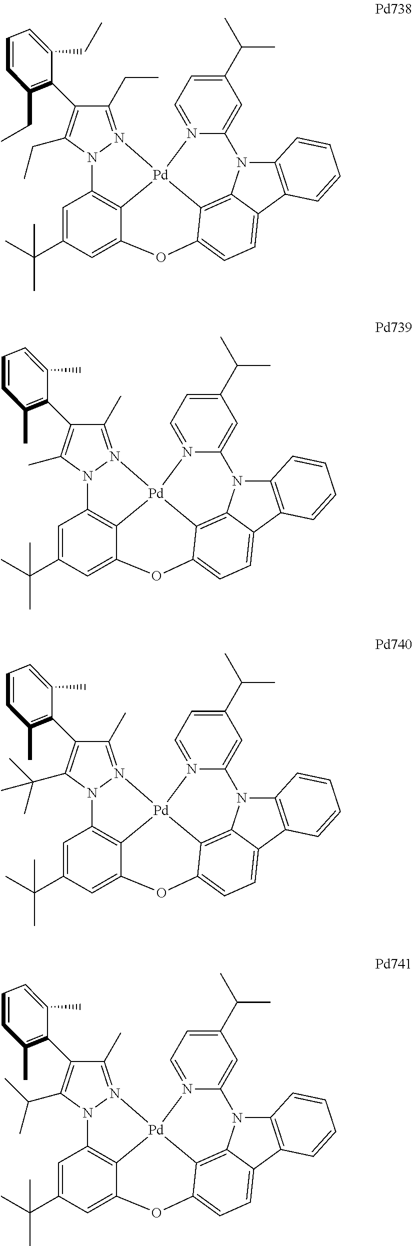

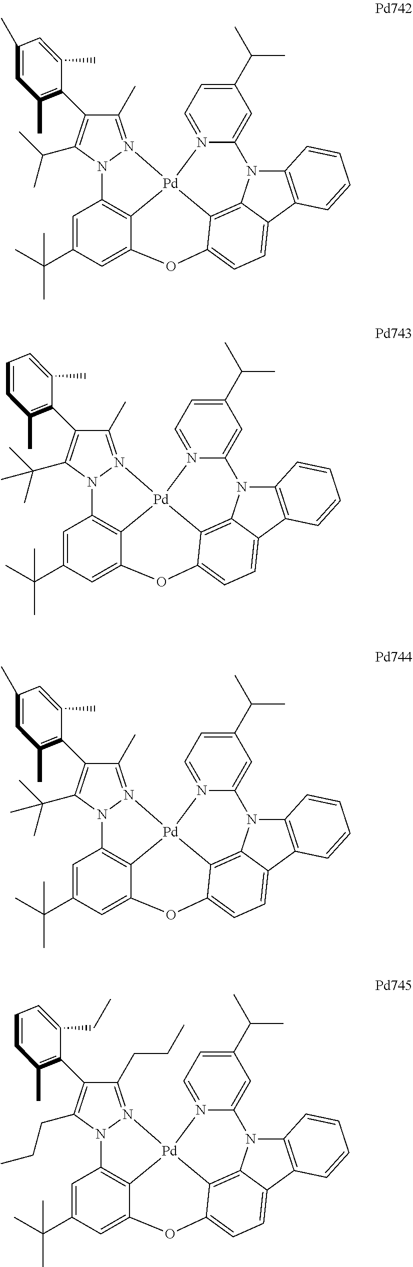

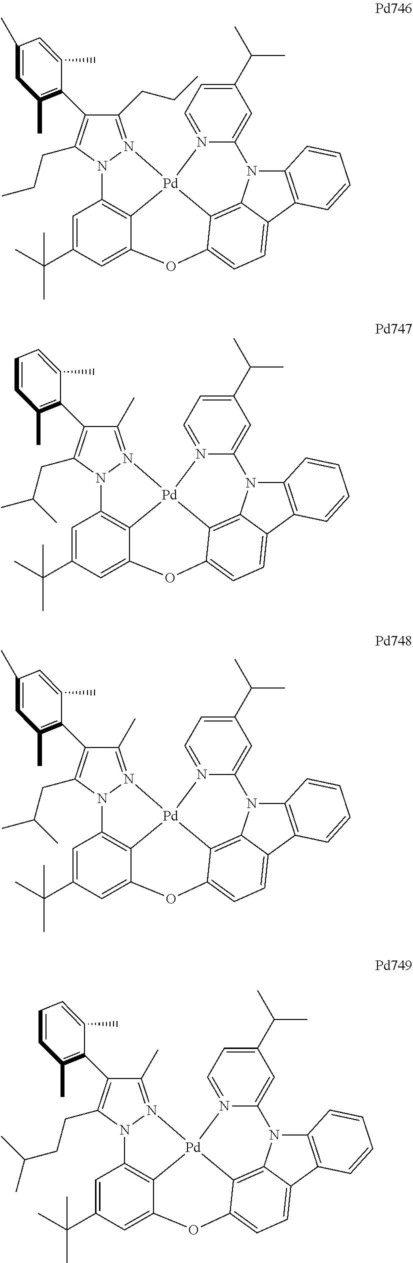

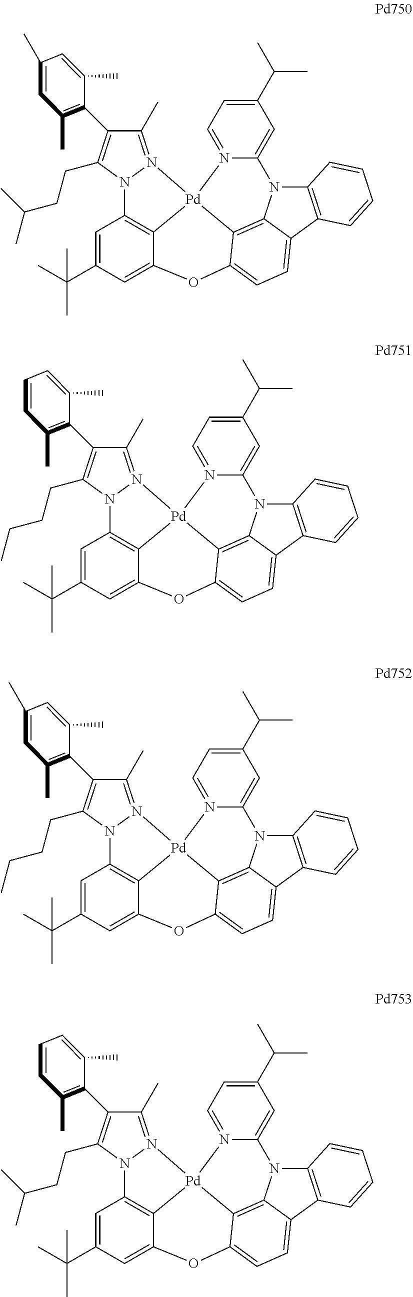

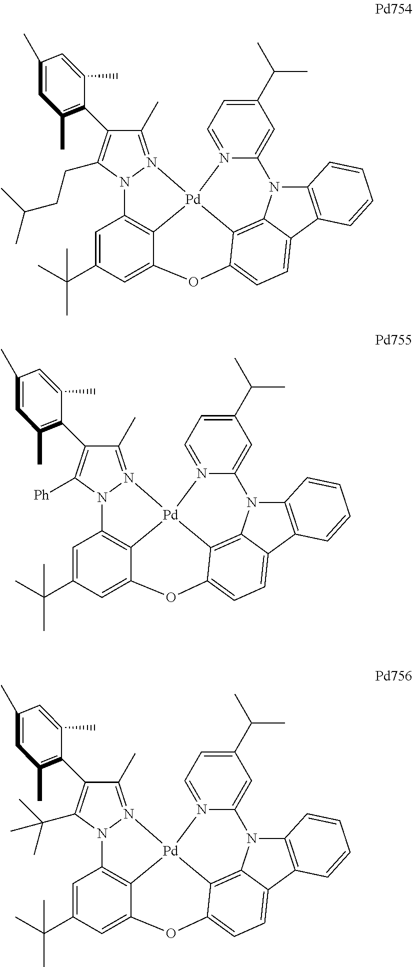

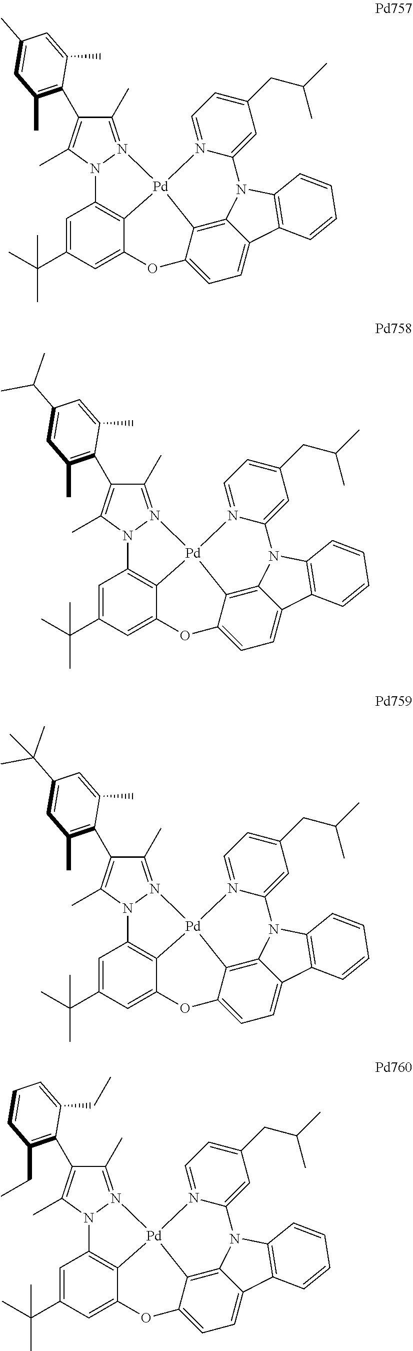

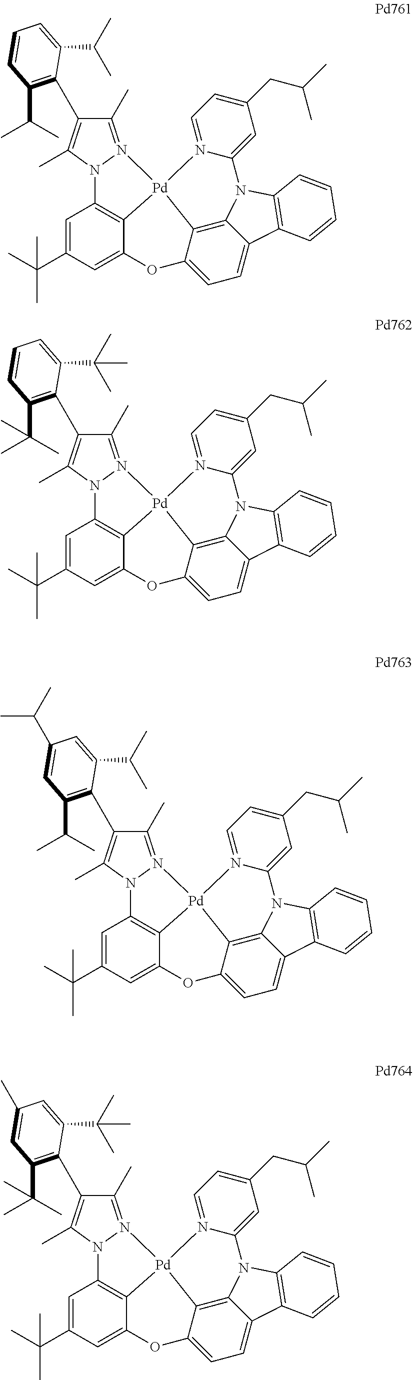

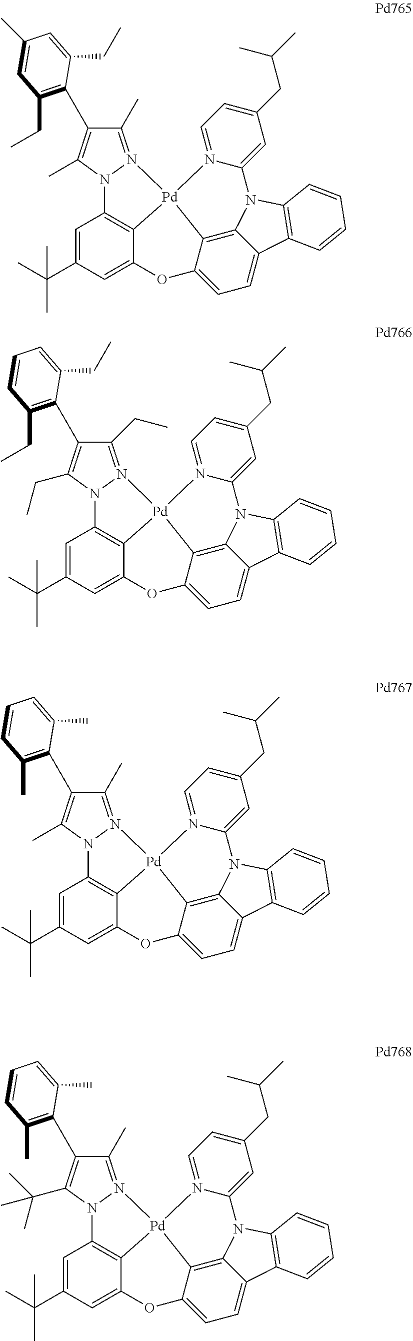

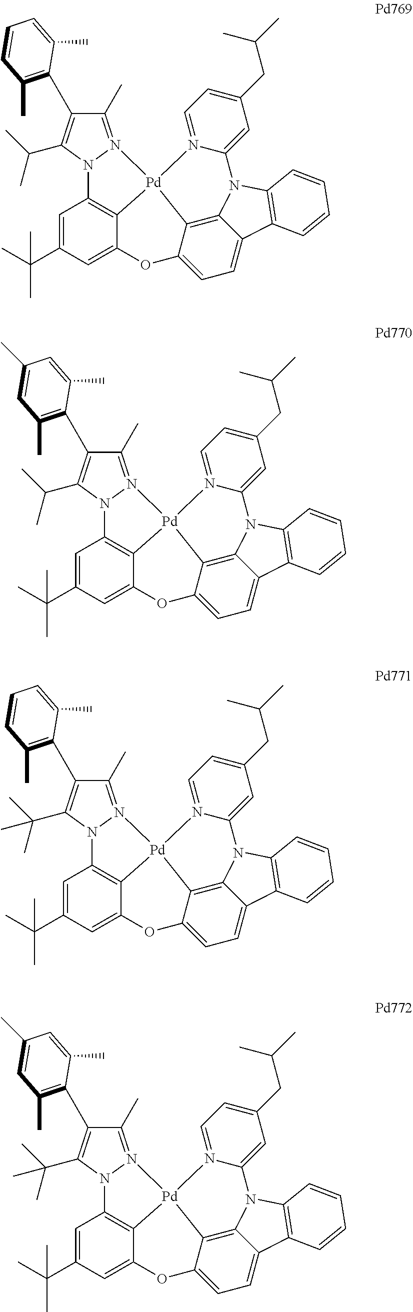

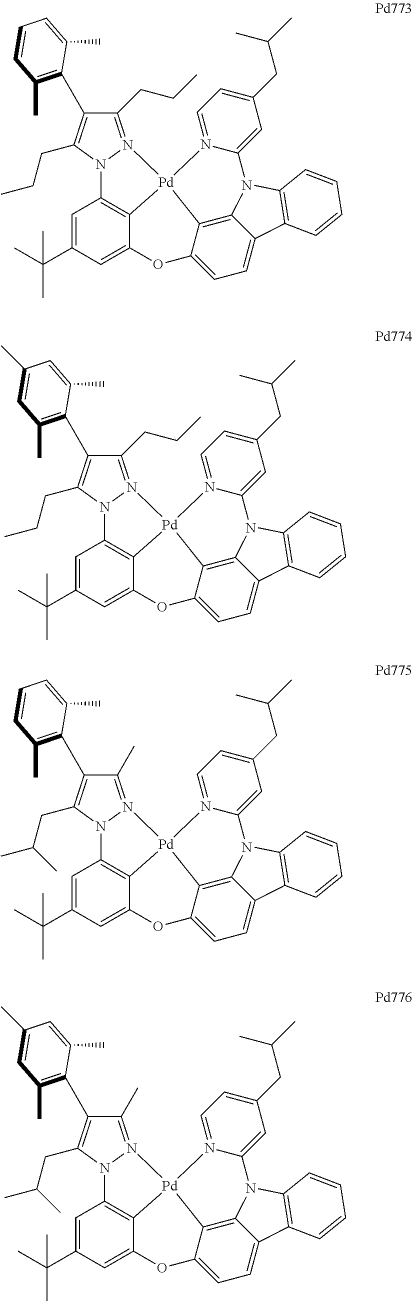

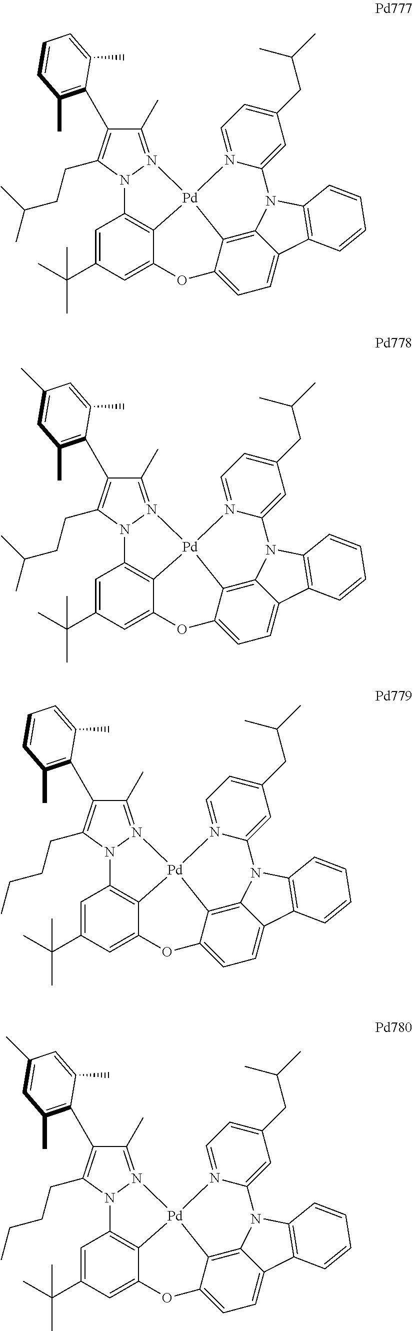

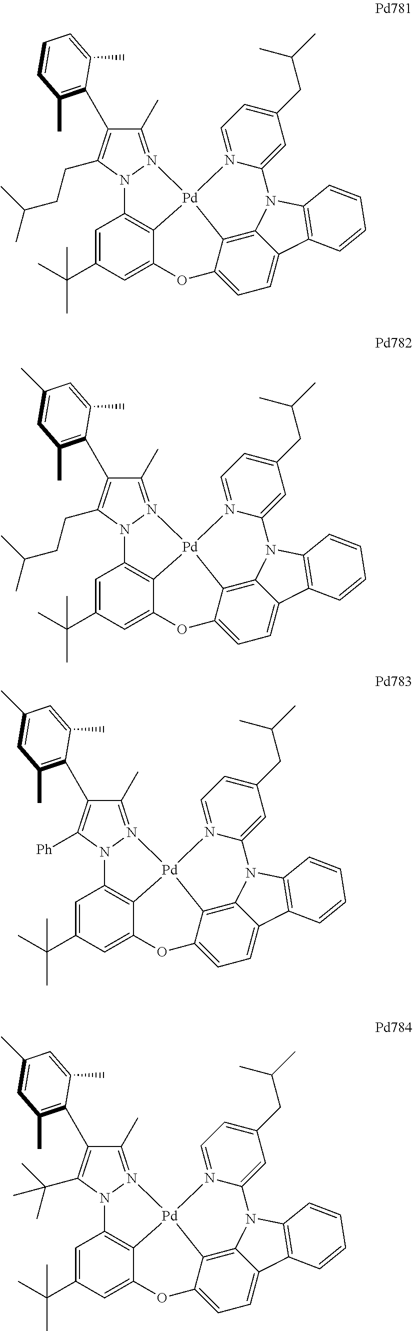

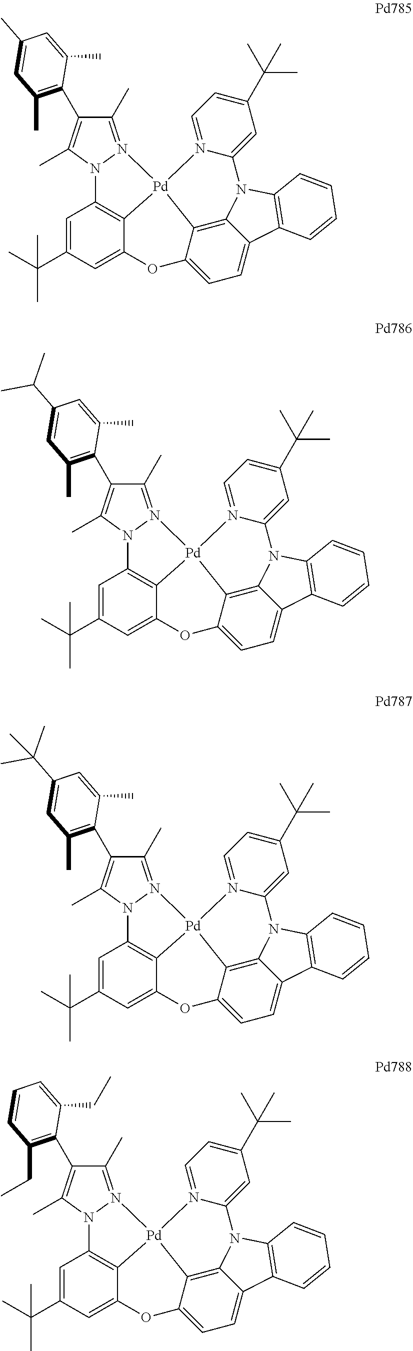

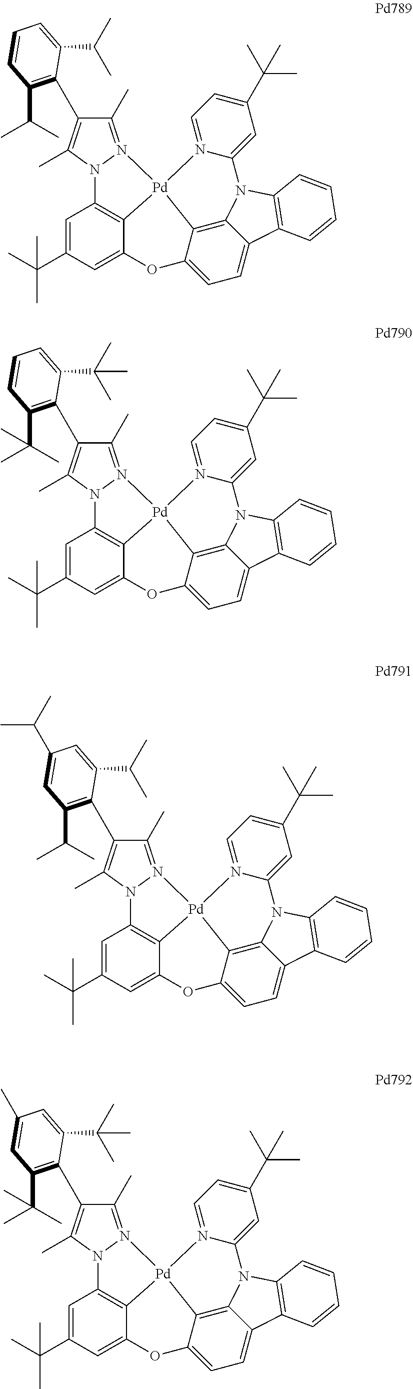

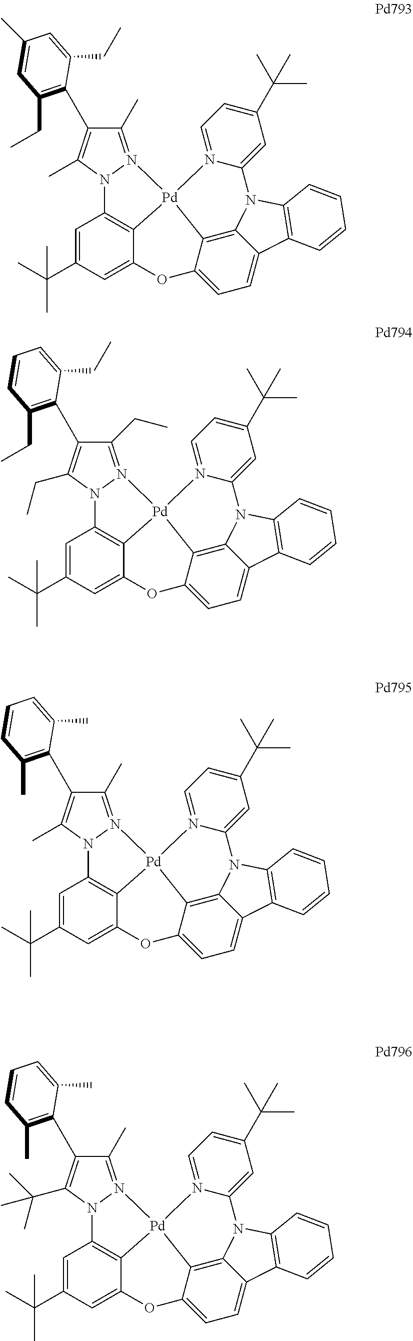

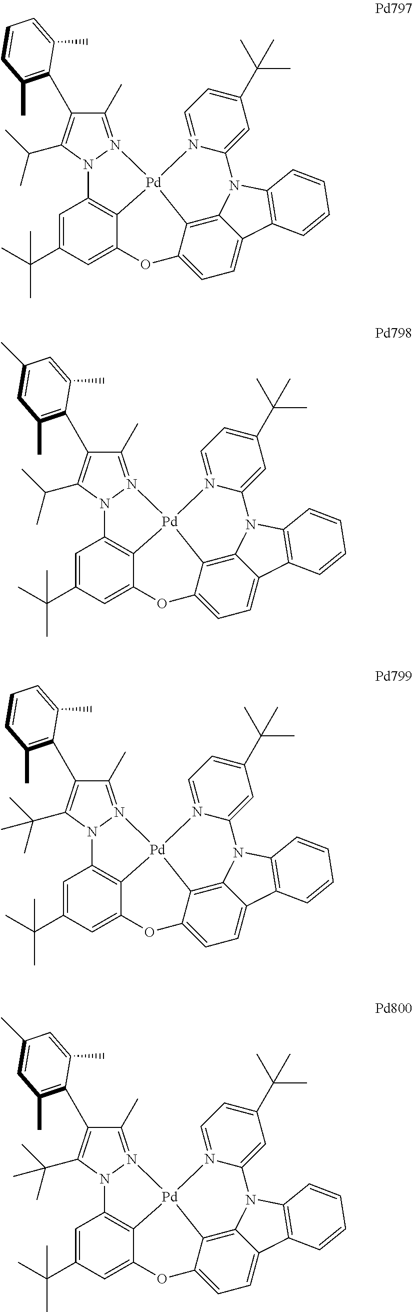

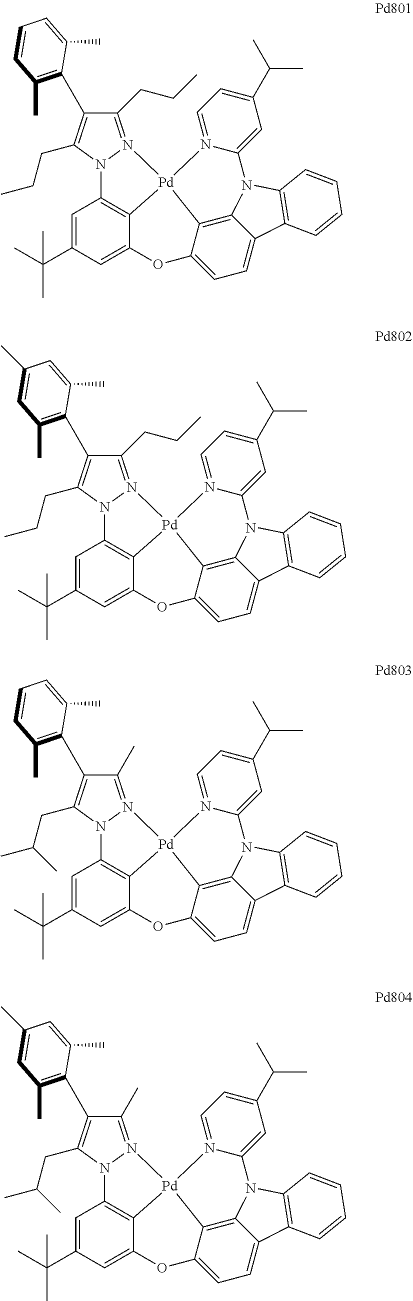

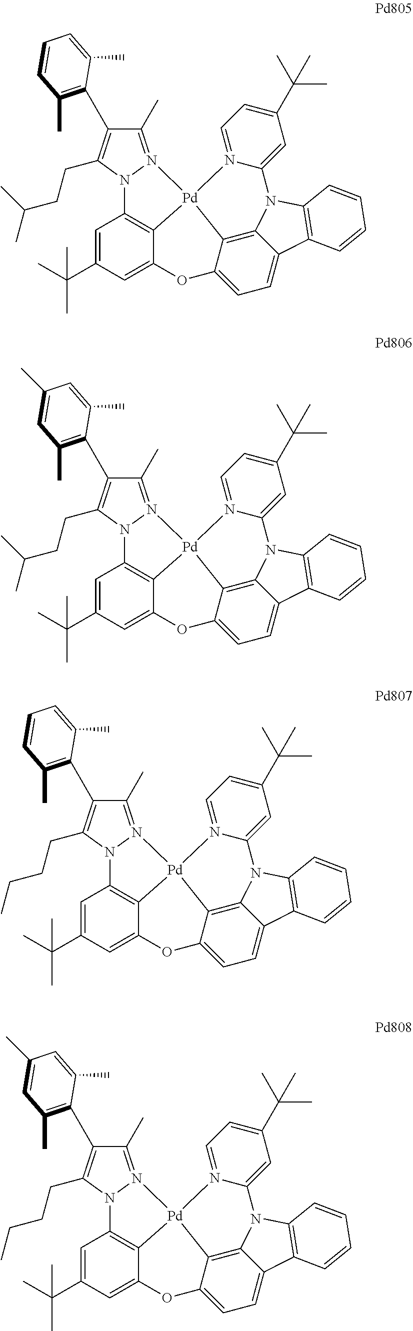

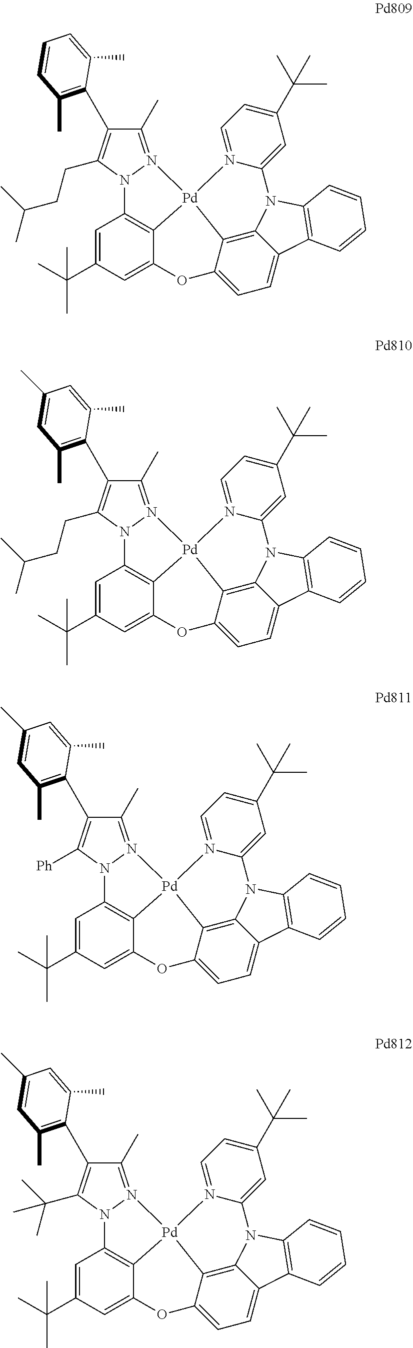

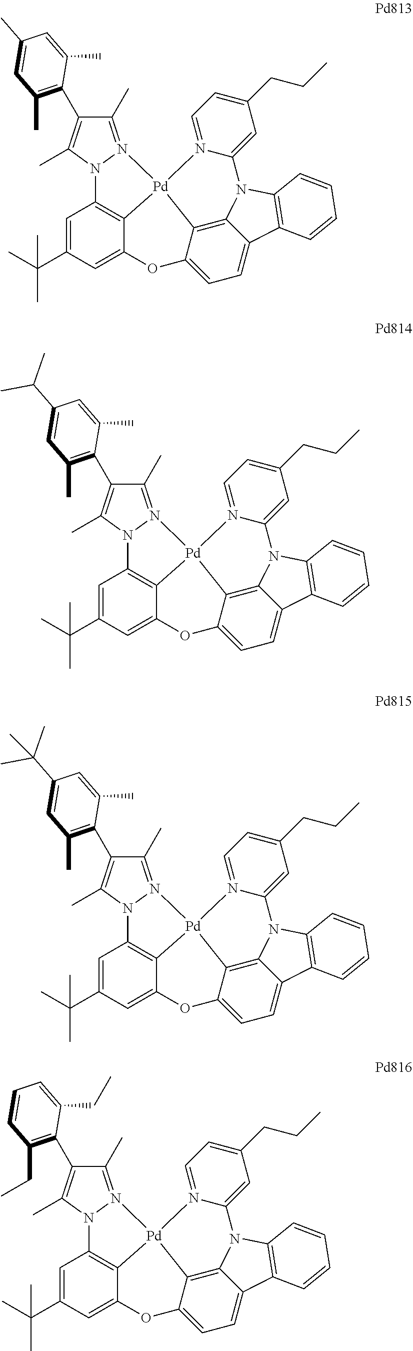

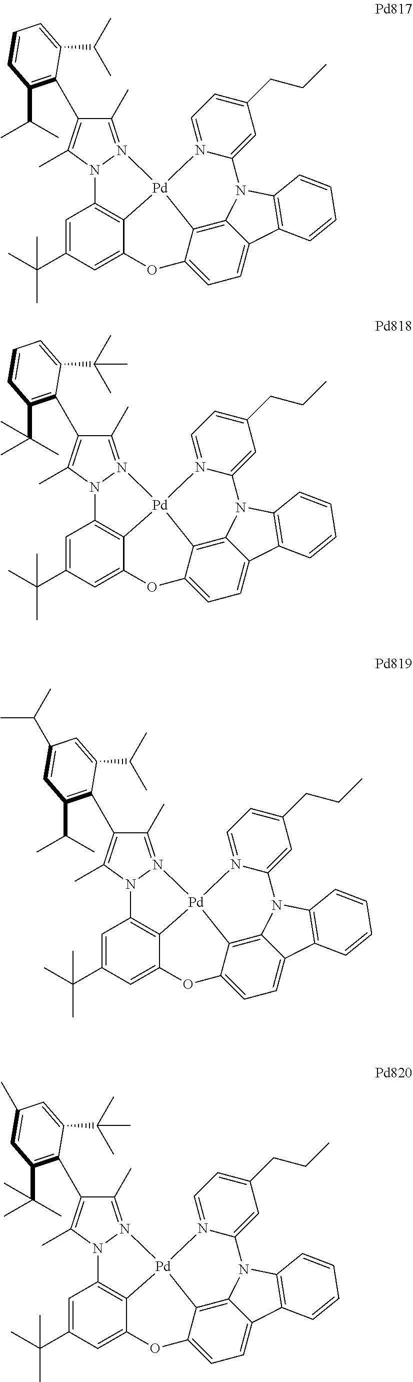

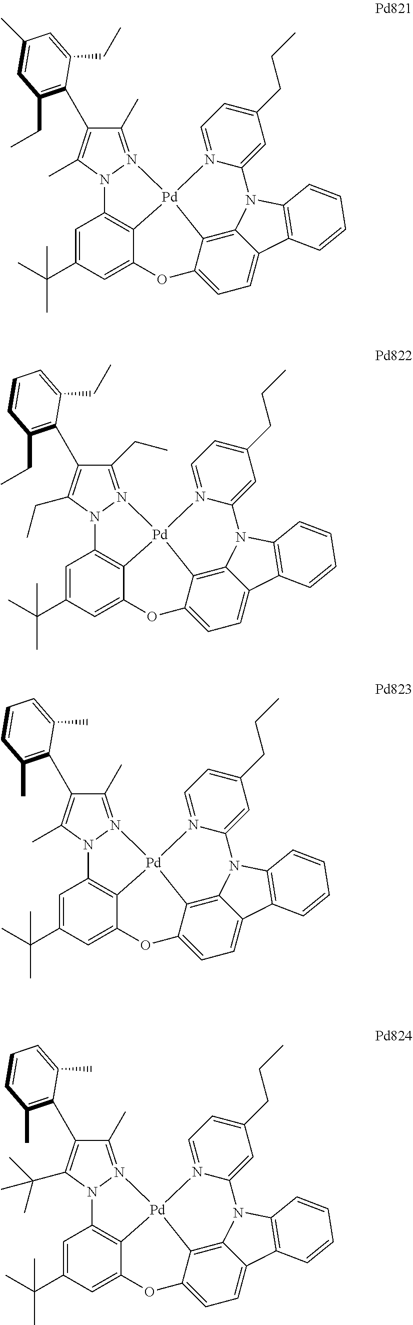

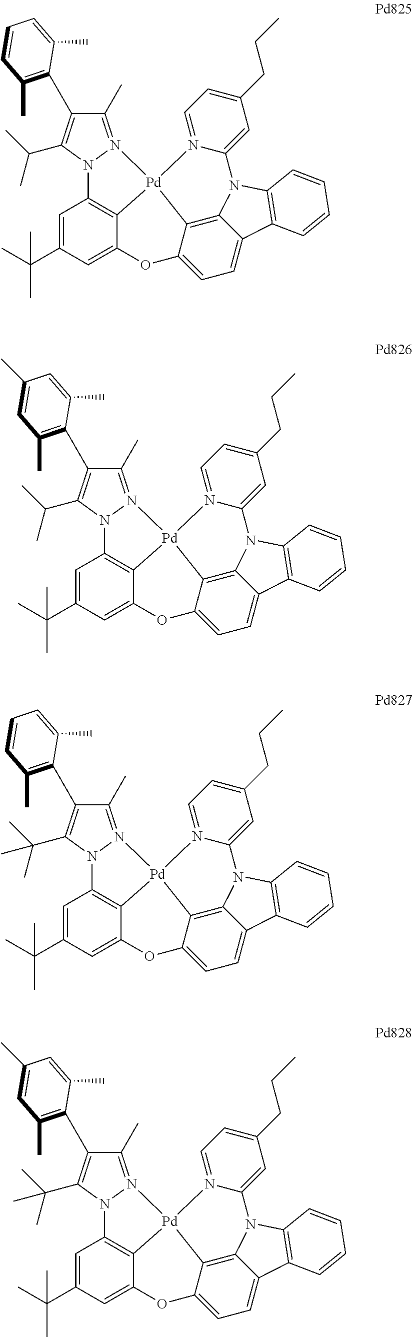

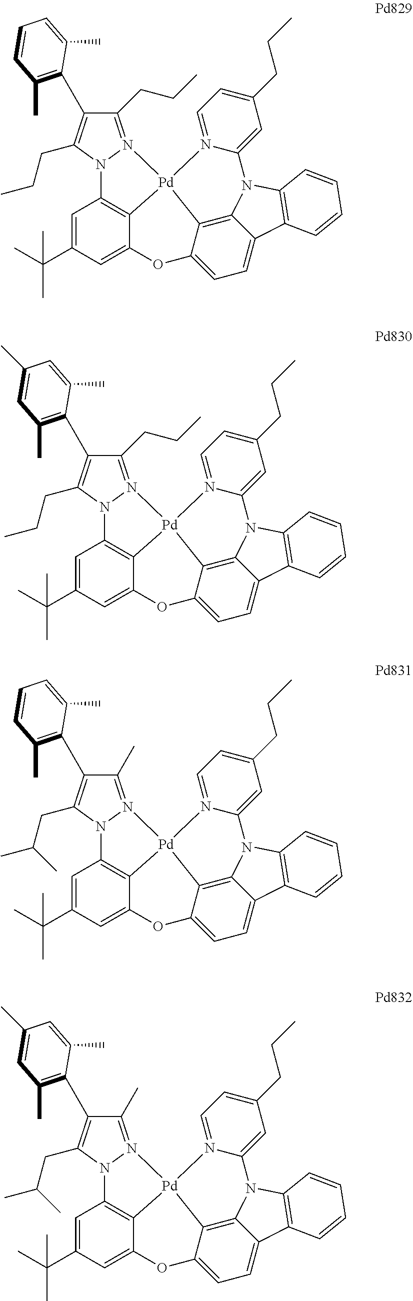

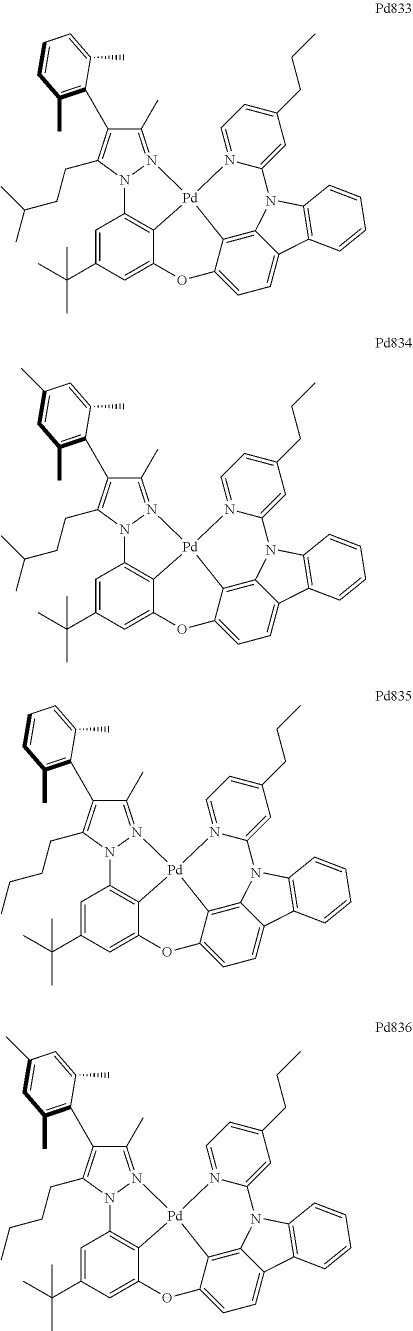

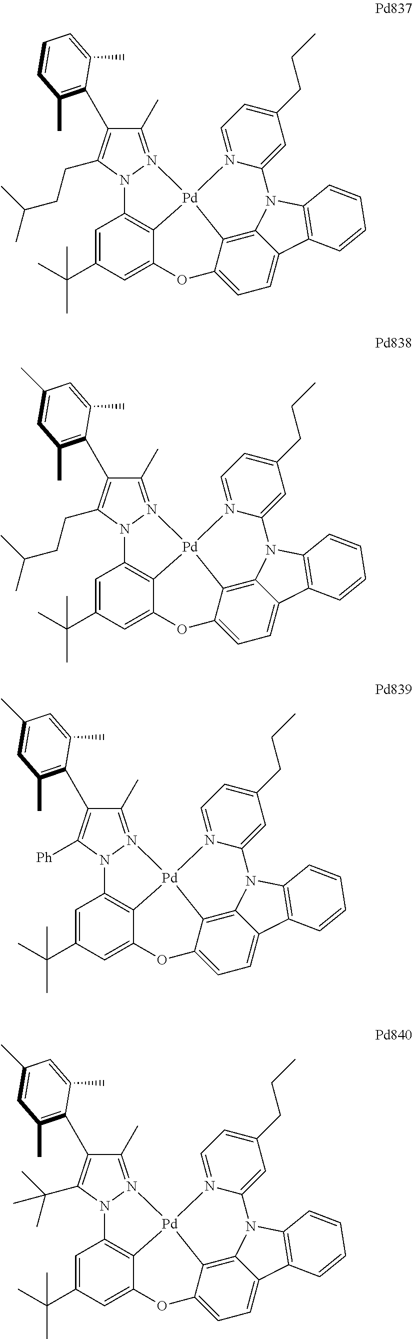

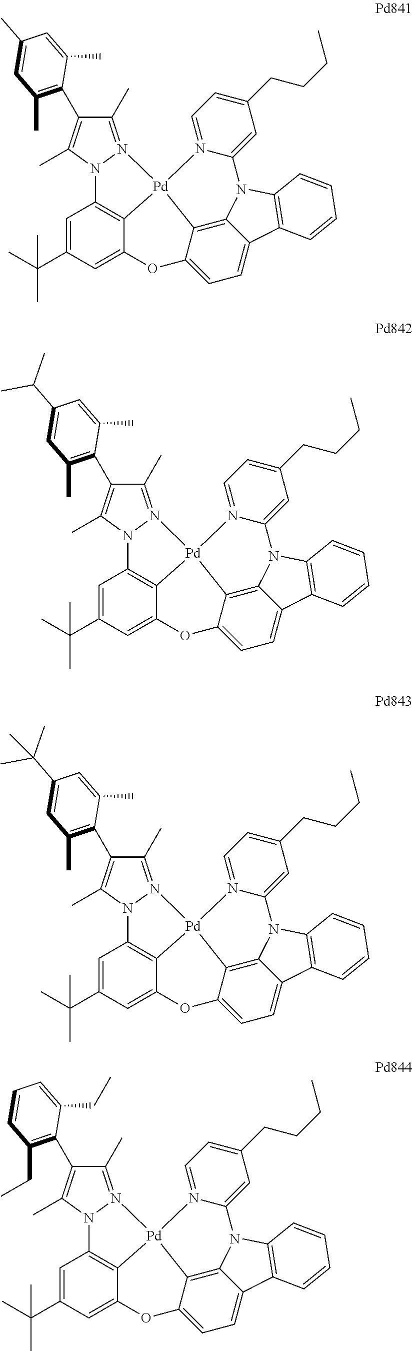

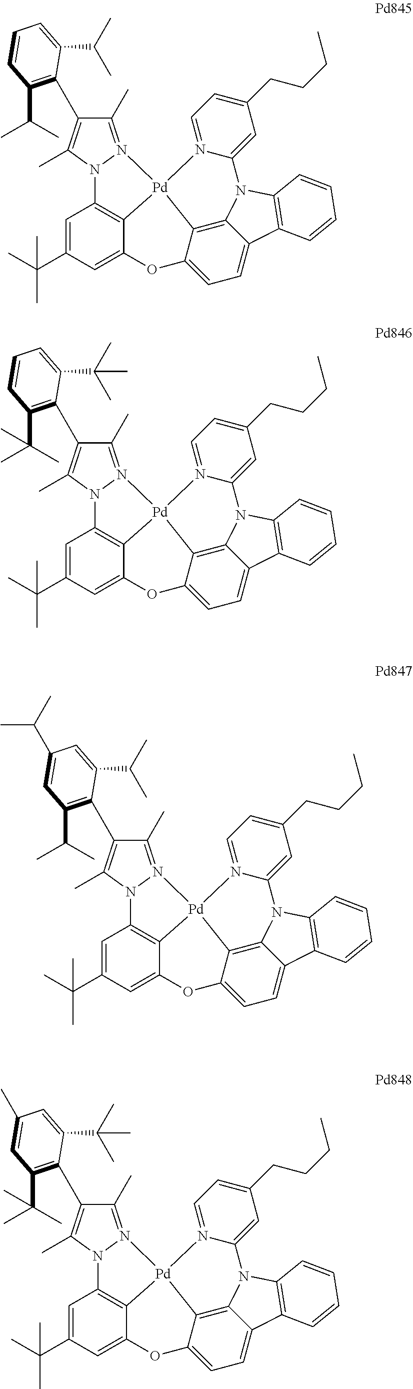

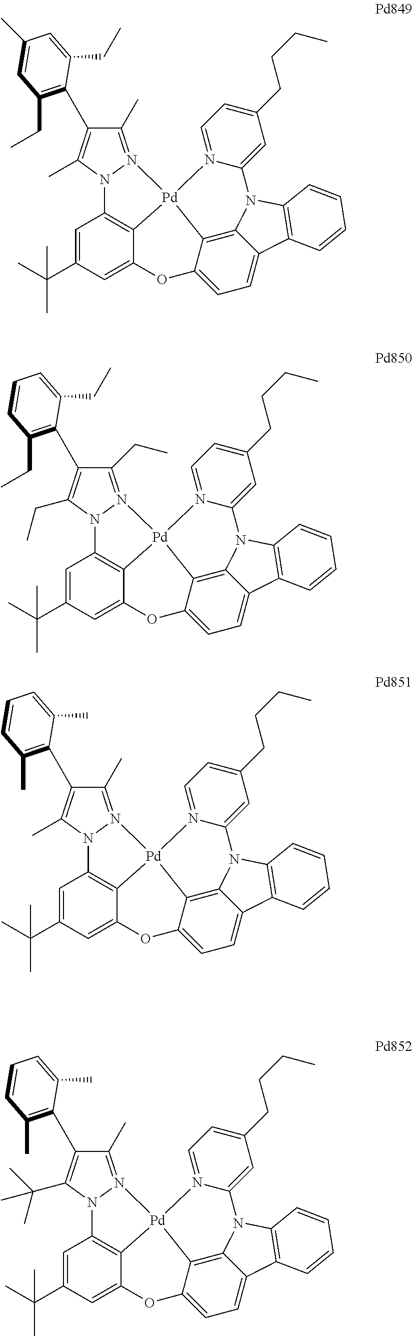

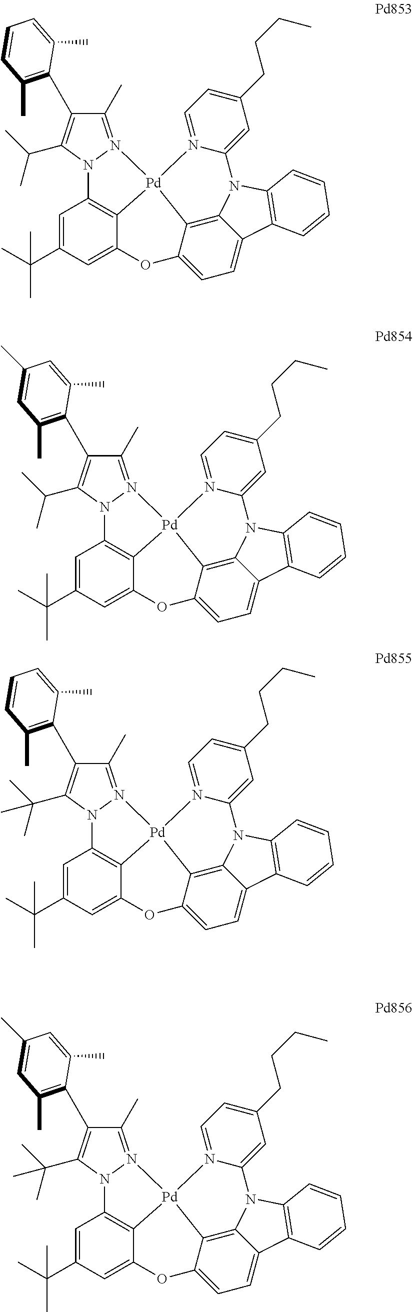

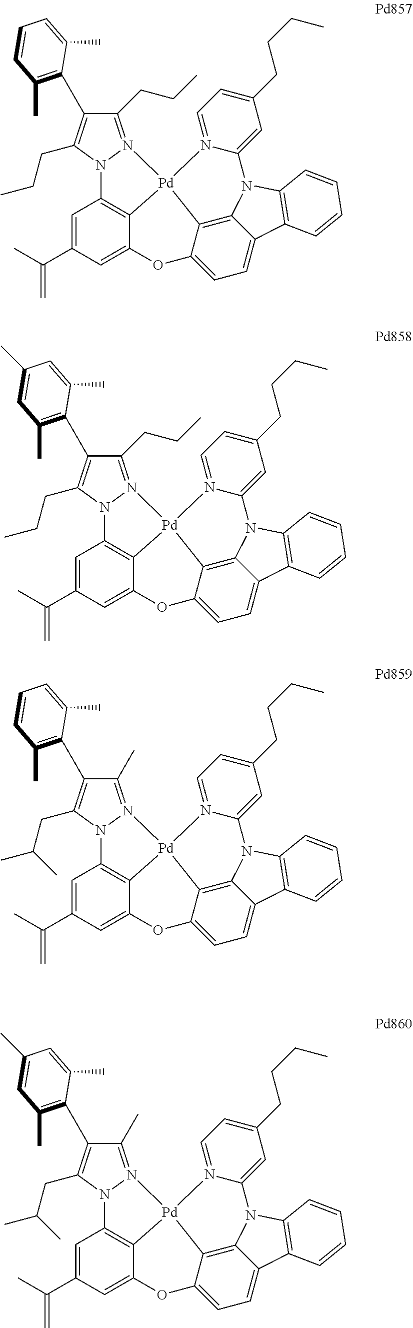

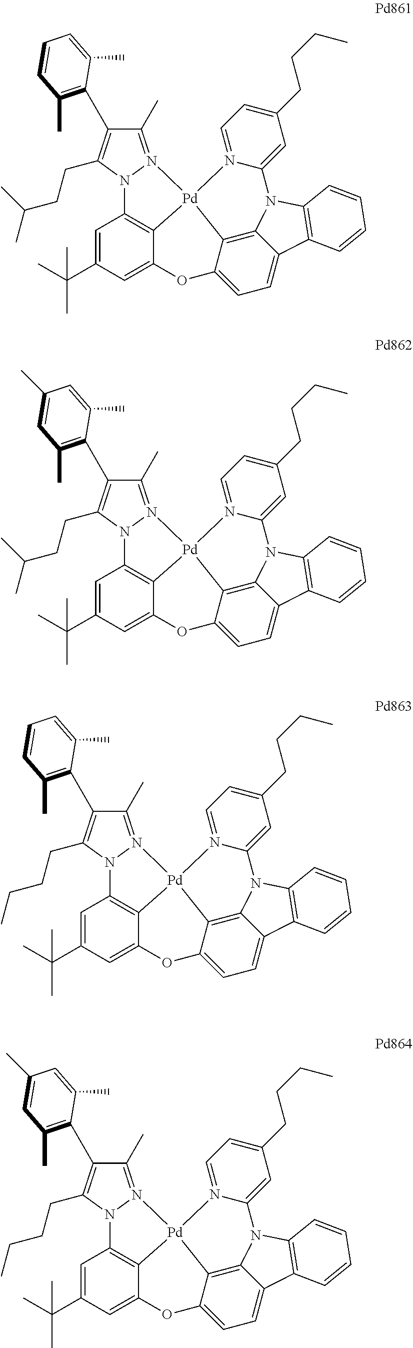

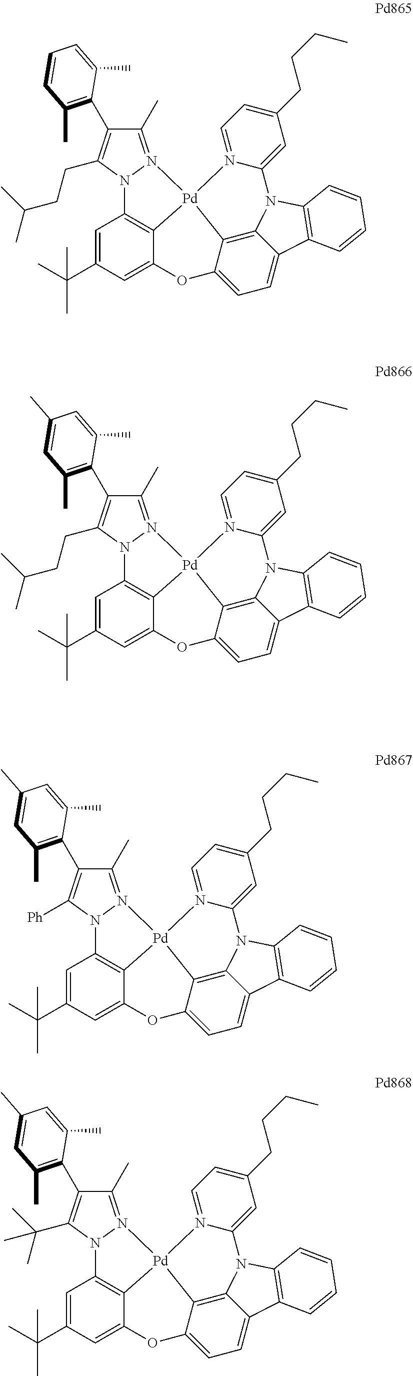

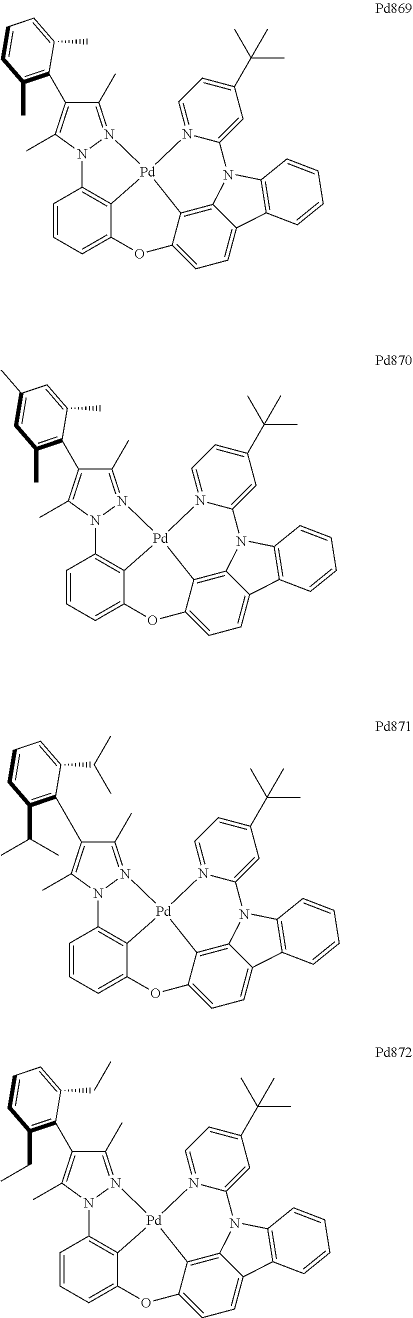

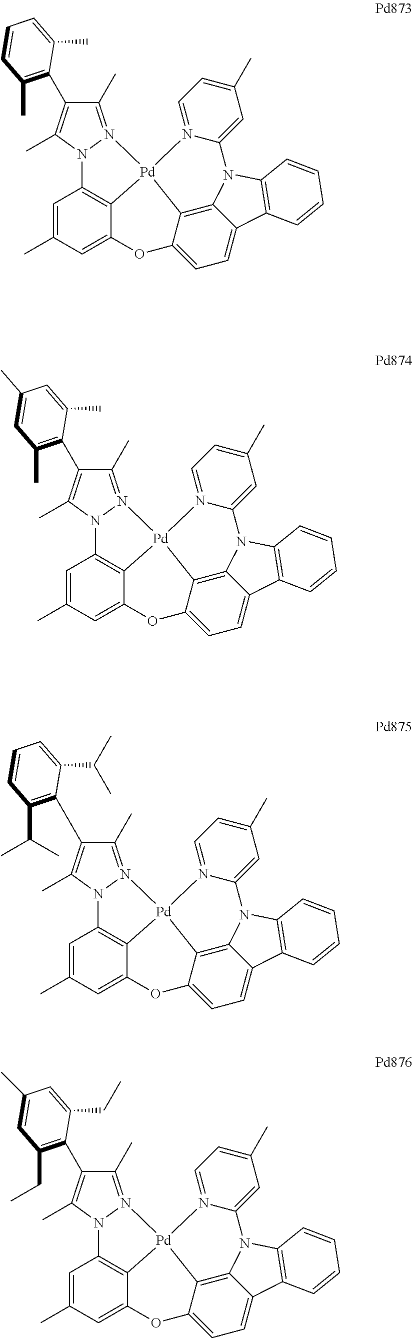

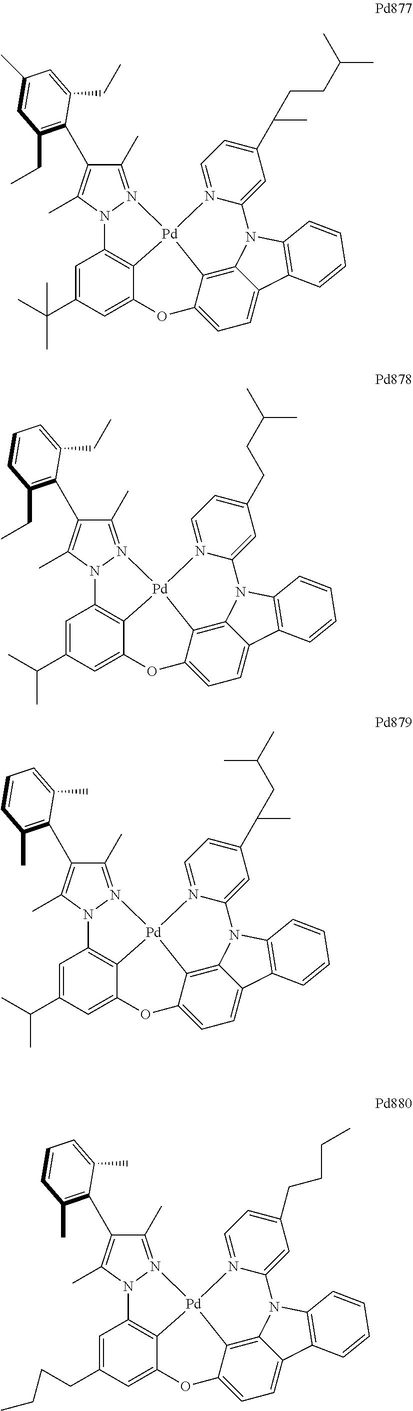

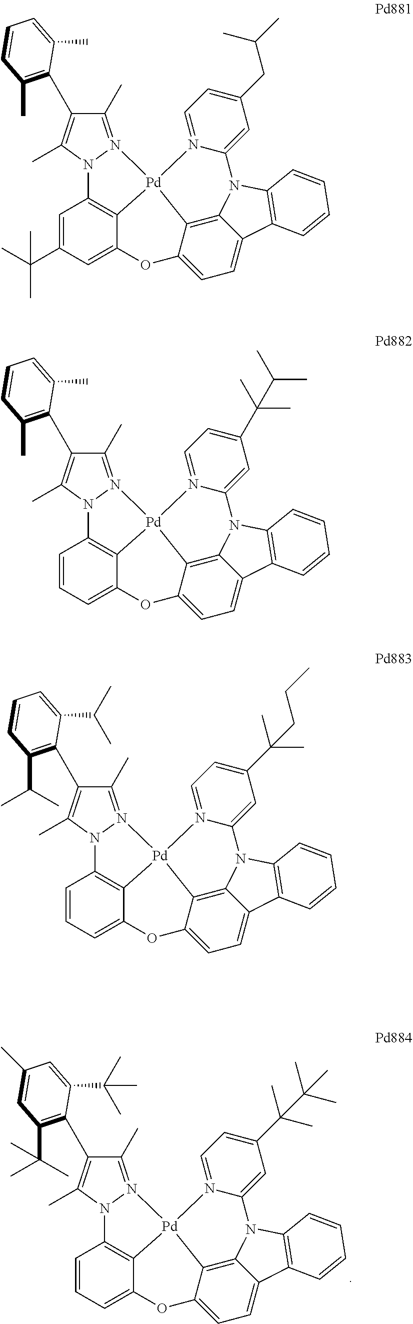

In some embodiments of the present disclosure, the tetradentate cyclic-metal palladium complex comprising 4-aryl-3,5-disubstituted pyrazol is electrically neutral.

Some embodiments of the present disclosure also provide use of the tetradentate cyclic-metal palladium complex comprising 4-aryl-3,5-disubstituted pyrazol in organic electroluminescent materials.

Some embodiments of the present disclosure also provide an optical or electro-optical device, which comprises one or more of the tetradentate cyclic-metal palladium complex comprising 4-aryl-3,5-disubstituted pyrazol described above.

In some embodiments of the present disclosure, the optical or electrical-optical device provided includes a light absorbing device (such as solar device or photosensing device), an organic light emitting diodes (OLED), a light emitting device or a device that is capable of light-absorbing and light-emitting.

In some embodiments of the present disclosure, the tetradentate cyclic-metal palladium complex comprising 4-aryl-3,5-disubstituted pyrazol provided by some embodiments of the present disclosure has 100% of internal quantum efficiency in the optical or electrical-optical device.

One embodiment of the present disclosure also provides a OLED device, wherein the luminescent material or host material in the OLED device comprises one or more of the tetradentate cyclic-metal palladium complex comprising 4-aryl-3,5-disubstituted pyrazol. The complexes provided by some embodiments of the present disclosure can be used as either host materials for OLED devices, such as in panchromatic display etc.; or luminescent material for OLED devices, such as light emitting devices and display and so on.

### Preparation and Performance Evaluation Examples

The examples are set forth below to provide those of ordinary skill in the art with complete disclosure and description of how to make and evaluate the complexes, compositions, articles, devices and/or methods described herein, and are intended to be only illustrative of the disclosure and not intended to limit the scope. Although efforts have been made to ensure accuracy with respect to numerical values (e.g., amounts, temperature, etc.), some errors and deviations should be taken into account. Unless otherwise indicated, parts are parts by weight, temperature is in ° C. or at ambient temperature, and pressure is at or near atmospheric pressure.

Various methods for preparing the complexes disclose herein are described in the examples. These methods are provided to illustrate various preparation methods, but the disclosure is not intended to be limited to any of the methods described herein. Accordingly, the person skilled in the art to which the disclosure pertains can easily modify the described methods or utilize different methods to prepare one or more of the disclosed complexes. The following aspects are only exemplary and are not intended to limit the scope of the disclosure. Temperatures, catalysts, concentrations, reactant compositions, and other process conditions may vary, and for the desired complexes, one skilled in the art of the disclosure can readily select suitable reactants and conditions.

The ¹H spectrum was recorded at 400 MHz in a CDCl₃ or DMSO-d₆ solution on a Varian Liquid State NMR instrument, and ¹³C NMR spectrum was recorded at 100 MHz with the chemical shifts referenced to the residual protiated solvent. If CDCl₃ is used as a solvent, ¹H NMR spectrum is recorded using tetramethylsilane (δ=0.00 ppm) as an internal standard; ¹³C NMR spectrum is recorded using DMSO-d₆ (δ=77.00 ppm) as an internal standard. If H₂O (δ=3.33 ppm) is used as a solvent, ¹H NMR spectrum is recorded using residual H₂O (δ=3.33 ppm) as an internal standard; ¹³C NMR spectrum is recorded using DMSO-d₆ (δ=39.52 ppm) as an internal standard. The following abbreviations (or combinations thereof) are used to explain the multiplicity of ¹H NMR: s=singlet, d=double, t=triplet, q=fourfold, P=fivefold, m=multiplex, br=broad.

### General Synthetic Route

The general synthesis route for the complexes disclosed in the present disclosure is as follows:

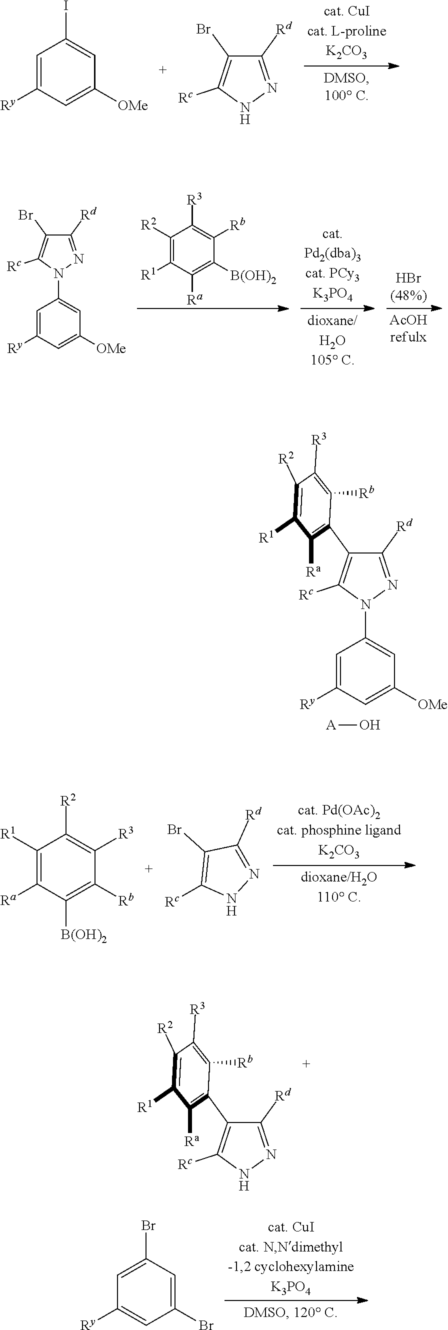

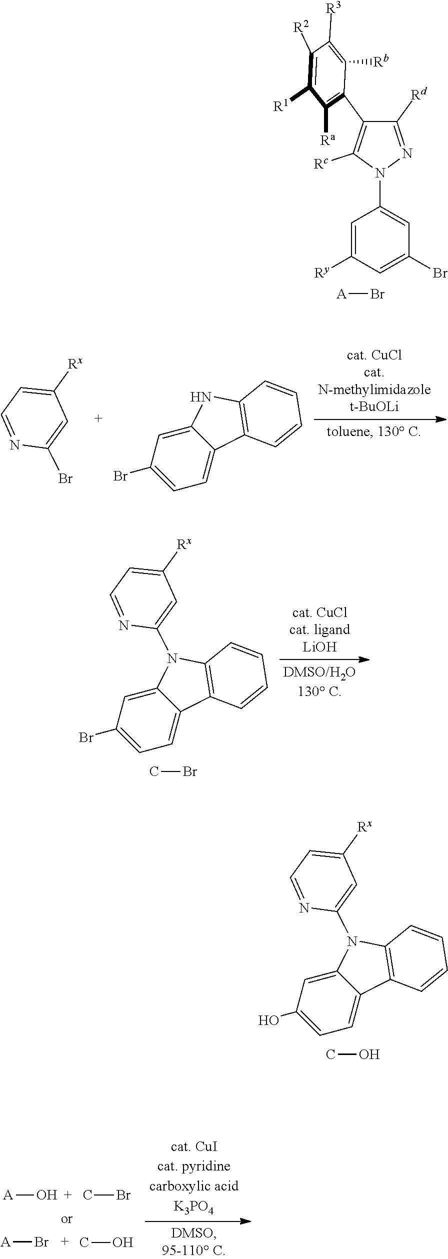

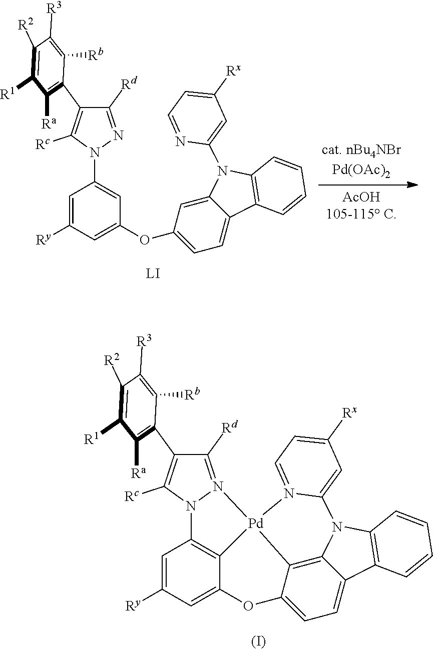

### PREPARATION EXAMPLES

### Example 1: Synthesis of the Complex Pd1 in the Following Route

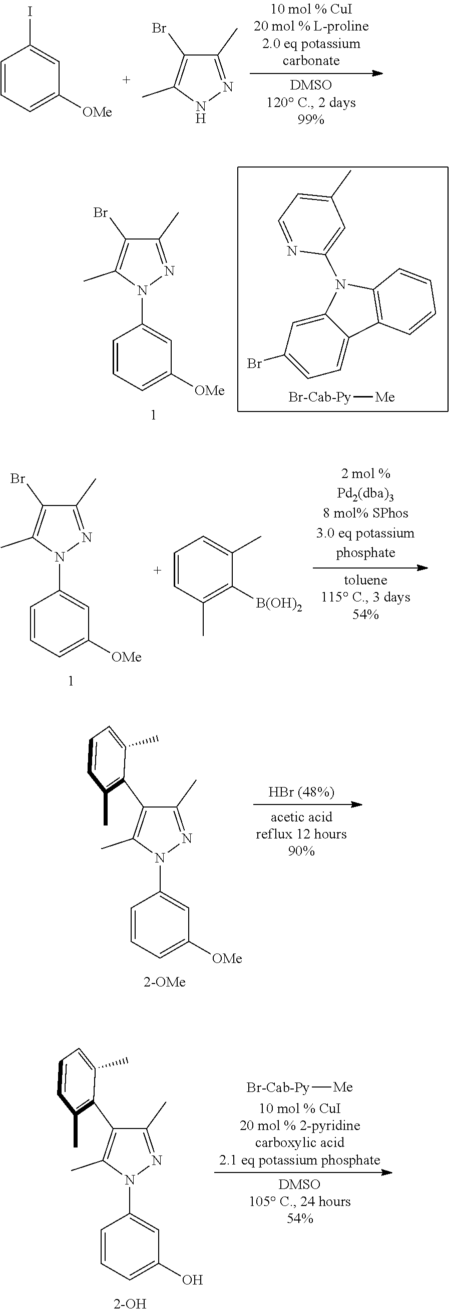

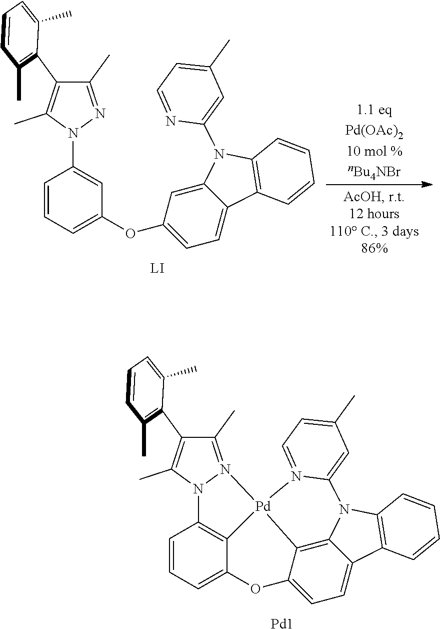

Synthesis of intermediate compound 1: To a dry three-necked flask with reflux condenser tube and a magnetic rotor, 3,5-dimethyl-4-bromo pyrazole (5250 mg, 30.00 mmol, 1.00 eq), cuprous iodide (572 mg, 3.00 mmol, 0.10 eq), L-proline (690 mg, 6.00 mmol, 0.20 eq), potassium carbonate (8280 mg, 60.00 mmol, 2.00 eq) were added in order. Nitrogen was purged three times, then added m-idoanisole (10500 mg, 45.00 mmol, 1.50 eq) and re-distilled dimethylsulfoxide (10 mL). The reaction mixture was stirred at 120° C. for 2 days, and monitored by TLC until the reaction of the raw material 4-bromopyrazole was completed. Water (100 mL) was added to quench the reaction, filtered, and 50 mL of ethyl acetate was thoroughly washed for insolubles, the organic phase in the liquor was separated, dried over anhydrous sodium sulfate, filtered and the solvent was distilled off under reduced pressure. Purification of the obtained crude product by flash silica gel column chromatography (eluent: petroleum ether/ethyl acetate=20:1˜10:1), get compound 1, colorless viscous liquid, 99% yield.

¹H NMR (500 MHz, DMSO-d₆): δ 2.20 (s, 3H), 2.30 (s, 3H), 3.81 (s, 3H), 7.01 (ddd, J=8.1, 2.4, 0.6 Hz, 1H), 7.05-7.08 (m, 2H), 7.42 (t, J=8.1 Hz, 1H).

Synthesis of Intermediate 2-OMe:

To a dry three-necked flask with a magnetic rotor, 4-bromo-1-(3-methoxyphenyl)-3,5-dimethyl-1-hydropyrazole (2100 mg, 7.47 mmol, 1.00 eq), 2,6-dimethylphenylboronic acid (2240 mg, 14.94 mmol, 2.00 eq), Pd₂(dba)₃ (137 mg, 0.15 mmol, 0.02 eq), tripotassium phosphate (4760 mg, 22.41 mol, 3.00 eq), S-Phos (245 mg, 0.60 mmol, 0.08 eq) were added in order. Nitrogen was purged three times and then toluene (40 mL) was added. Nitrogen was then bubbled for 20 minutes and the reaction mixture was left at 110° C. for 3 day with stirring. After cooling, 100 mL of water was added and the mixture was extracted with ethyl acetate (50 mL×3), the organic phases were combined, dried over anhydrous sodium sulfate, filtered, and the solvent was distilled off under reduced pressure. Purification of the obtained crude product by flash silica gel column chromatography (eluent: petroleum ether/ethyl acetate=20:1˜10:1), get compound 2-OMe, orange viscous liquid, 54% yield.

¹H NMR (500 MHz, DMSO-d₆): δ 1.94 (s, 3H), 2.02 (s, 6H), 2.05 (s, 3H), 3.83 (s, 3H), 6.96 (d, J=8.3 Hz, 1H), 7.14-7.18 (m, 5H), 7.42 (t, J=8.0 Hz, 1H).

Synthesis of Intermediate 2-OH:

4-(2,6-dimethylbenzene)-1-(3-methoxyphenyl)-3,5-dimethyl-1H-pyrazol 2-OMe (600 mg, 1.95 mmol, 1.00 eq) was dissolved in 25 mL acetic acid, hydrobromic acid (strength 48%, 10 mL) was added, and the reaction mixture was stirred at 120° C. for 12 hours. After cooling, spin out the acetic acid, add a small amount of water, then add sodium carbonate solution, titration so that no bubbles are generated, extract the aqueous phase with ethyl acetate (20 mL×2), combine the organic phase, dry over anhydrous sodium sulfate, filter, and remove the solvent by distillation under reduced pressure. Purification of the obtained crude product by flash silica gel column chromatography (eluent: petroleum ether/ethyl acetate=5:1˜10:1), get compound 2-OH, brown solid, 90% yield.

¹H NMR (500 MHz, DMSO-d₆): δ 1.93 (s, 3H), 2.01 (s, 6H), 2.03 (s, 3H), 6.78 (ddd, J=7.8, 2.6, 0.6 Hz, 1H), 6.97-7.00 (m, 2H), 7.14-7.20 (m, 3H), 7.29 (t, J=8.0 Hz, 1H), 9.75 (s, 1H).

Synthesis of Ligand L1:

To a dry three-necked flask with a magnetic rotor, Phenol derivative 2-OH (500 mg, 1.71 mmol, 1.00 eq), 2-bromo-9-(4-methylpyridine-2-)-9H-carbazole Br-Cab-Py-Me (691 mg, 2.05 mmol, 1.20 eq, see synthetic method: The Journal of Organic Chemistry, 2017, 82, 1024-1033), Cuprous iodide (65 mg, 0.34 mmol, 0.20 eq), 2-picolinic acid (84 mg, 0.68 mmol, 0.40 eq), potassium phosphate (762 mg, 3.59 mmol, 2.10 eq) were added in order. Nitrogen was purged three times and then DMSO (5 mL) was added. The reaction mixture was stirred at 105° C. for 24 hours, and the reaction was monitored by TLC. After cooling, add ethyl acetate (40 mL) and water (40 mL), dilute, separate, separate the organic phase, extract the aqueous phase with ethyl acetate (20 mL×2), and combine the organic phase, dry over anhydrous sodium sulfate, filter, and remove the solvent by distillation under reduced pressure. Purification of the obtained crude product by flash silica gel column chromatography (eluent: petroleum ether/ethyl acetate=15:1˜10:1), get ligand L1, white solid, 76% yield.

¹H NMR (500 MHz, DMSO-d₆): δ 1.89 (s, 3H), 1.98 (s, 6H), 2.02 (s, 3H), 2.45 (s, 3H), 7.06-7.08 (m, 1H), 7.12-7.19 (m, 4H), 7.26 (t, J=2.2 Hz, 1H), 7.30 (d, J=5.0 Hz, 1H), 7.33-7.37 (m, 2H), 7.44-7.47 (m, 1H), 7.50-7.53 (m, 2H), 7.61 (s, 1H), 7.77 (d, J=8.3 Hz, 1H), 8.23 (d, J=7.6 Hz, 1H), 8.29 (d, J=8.4 Hz, 1H), 8.53 (d, J=5.0 Hz, 1H).

Synthesis of Pd1:

To a 100 mL of three-necked bottle with a magnetic rotor and condenser tube, Ligand L1 (164.6 mg, 0.30 mmol, 1.0 eq), Pd(OAc)₂ (74.1 mg, 0.33 mmol, 1.1 eq) and “Bu₄NBr (10.6 mg, 0.03 mmol, 0.1 eq) were added in order. Nitrogen was purged three times, then acetic acid (20 mL) was added, followed by nitrogen bubbling for 10 minutes, stirring at room temperature for 12 hours, and then stirring at 110° C. in oil bath for 3 days. The reaction mixture was cooled to room temperature, and the solvent was distilled off under reduced pressure, the crude product was purified by silica gel column chromatography eluting solvent (petroleum ether:dichloromethane=3:1-1:1), get Pd1, white solid 168.0 mg, 86% yield. ¹H NMR (500 MHz, DMSO-d₆): δ 2.06 (s, 6H), 2.08 (s, 3H), 2.40 (s, 3H), 2.43 (s, 3H), 7.02 (dd, J=7.5, 1.0 Hz, 1H), 7.18-7.29 (m, 6H), 7.32 (dd, J=8.0, 1.0 Hz, 1H), 7.37-7.40 (m, 1H), 7.46-7.49 (m, 1H), 7.90 (d, J=8.0 Hz, 1H), 7.91 (s, 1H), 8.09 (d, J=8.0 Hz, 1H), 8.15 (dd, J=7.5, 0.5 Hz, 1H), 8.95 (d, J=6.0 Hz, 1H). ¹³C NMR (100 MHz, DMSO-d₆): δ 12.87, 13.01, 20.22, 20.97, 108.11, 111.32, 111.99, 112.45, 115.06, 115.54, 116.49, 116.61, 119.86, 120.42, 120.50, 122.70, 124.64, 125.91, 127.45, 127.88, 128.17, 130.29, 137.82, 137.95, 137.99, 143.18, 147.28, 147.92, 148.64, 151.23, 151.58, 151.89, 152.24. HRMS (DART POSTIVE Ion Mode) for C₃₇H₃₁N₄O¹⁰²Pd [M+H]⁺: calcd 649.1548, found 649.1542.

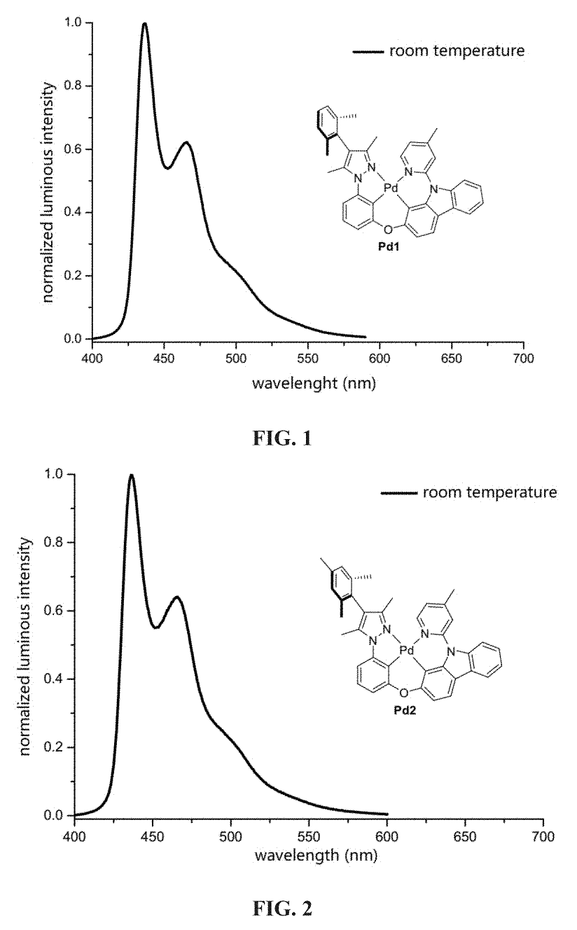

FIG. 1 shows the emission spectrum of the complex Pd1 in dichloromethane solution at room temperature.

### Example 2: Synthesis of the Complex Pd2 in the Following Route

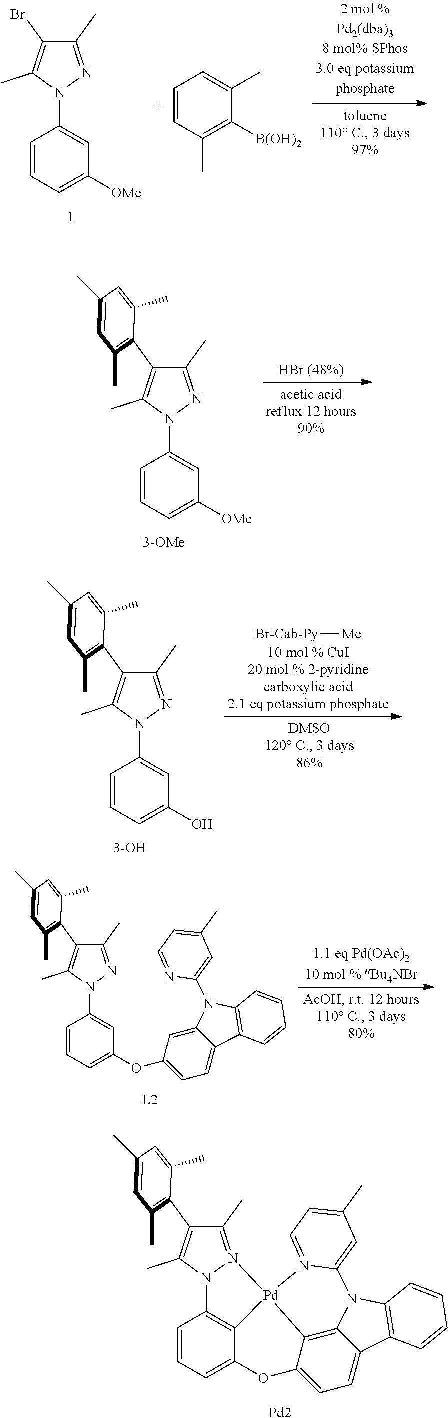

Synthesis of Intermediate 3-OMe:

To a dry three-necked flask with a magnetic rotor, 4-bromo-1-(3-methoxyphenyl)-3,5-dimethyl-1H-pyrazole (4.50 g, 16.01 mmol, 1.00 eq), 2,4,6-trimethylphenylboronic acid (5.25 g, 32.02 mmol, 2.00 eq), Pd2(dba)₃ (0.29 g, 0.32 mmol, 0.02 eq), tripotassium phosphate (10.20 g, 48.03 mol, 3.00 eq), S-Phos (0.53 g, 0.60 mmol, 0.08 eq) were added in order. Nitrogen was purged three times and then toluene (100 mL) was added under nitrogen protection. Nitrogen was then bubbled for 20 minutes and the reaction mixture was left at 110° C. for 3 days with stirring. After cooling, add water (100 mL) and extract with ethyl acetate (50 mL×3), combine the organic phases, dry over anhydrous sodium sulfate, filter and evaporate the solvent under reduced pressure. Purification of the obtained crude product by flash silica gel column chromatography (eluent: petroleum ether/ethyl acetate=20:1˜10:1), get compound 3-OMe, pale yellow viscous liquid, 97% yield.

¹H NMR (500 MHz, DMSO-d₆): δ 1.93 (s, 3H), 1.98 (s, 6H), 2.04 (s, 3H), 2.28 (s, 3H), 3.83 (s, 3H), 6.94-6.97 (m, 3H), 7.12-7.15 (m, 2H), 7.41 (t, J=8.1 Hz, 1H).

Synthesis of Intermediate 3-OH:

Anisole derivative 3-OMe (600 mg, 1.95 mmol, 1.00 eq) was dissolved in 25 mL acetic acid, hydrobromic acid (48% strength, 10.0 mL) was added, and the reaction mixture was placed at 120° C. for stirring 12 hours. After cooling, spin out acetic acid, add a small amount of water, then add sodium carbonate solution, titrate it so that there is no bubble generated, extract the aqueous phase with ethyl acetate (20 mL×2), combine the organic phase, dry over anhydrous sodium sulfate, filter and remove the solvent by distillation under reduced pressure. Purification of the obtained crude product by flash silica gel column chromatography (eluent: petroleum ether/ethyl acetate=5:1˜3:1), get compound 3-OH, brown solid 511 mg, 90% yield.

¹H NMR (500 MHz, DMSO-d₆): (δ 1.92 (s, 3H), 1.97 (s, 6H), 2.02 (s, 3H), 2.28 (s, 3H), 6.77 (ddd, J=8.2, 2.2, 0.8 Hz, 1H), 6.96-6.99 (m, 4H), 7.28 (t, J=8.0 Hz, 1H), 9.74 (s, 1H).

Synthesis of Ligand L2:

To a dry three-necked flask with a magnetic rotor, Phenol derivative 3-OH (1000 mg, 3.42 mmol, 1.00 eq), 2-bromo-9-(4-methylpyrinde-2-)-9H-carbazole Br-Cab-Py-Me (1382 mg, 4.10 mmol, 1.20 eq, see synthetic method: The Journal of Organic Chemistry, 2017, 82, 1024-1033), cuprous iodide (65 mg, 0.34 mmol, 0.10 eq), 2-picolinic acid (84 mg, 0.68 mmol, 0.20 eq), potassium phosphate (1524 mg, 7.18 mmol, 2.10 eq) were added in order. Nitrogen was purged three times and then DMSO (8 mL) was added. The reaction mixture was stirred at 120° C. for 3 days, and the reaction was monitored by TLC. After cooling, add ethyl acetate (40 mL) and water (40 mL) to dilute and separate, separate the organic phase, extract the aqueous phase with ethyl acetate (20 mL×2), and combine the organic phase, dry over anhydrous sodium sulfate, filter and remove the solvent by distillation under reduced pressure. Purification of the obtained crude product by flash silica gel column chromatography (eluent: petroleum ether/ethyl acetate=15:1˜10:1), get ligand L2, white solid 1663 mg, 86% yield.

¹H NMR (500 MHz, DMSO-d₆): (δ 1.88 (s, 3H), 1.93 (s, 6H), 2.01 (s, 3H), 2.26 (s, 3H), 2.45 (s, 3H), 6.94 (s, 2H), 7.06 (ddd, J=8.2, 2.3, 0.6 Hz, 1H), 7.11 (dd, J=8.4, 2.1 Hz, 1H), 7.24 (t, J=2.2 Hz, 1H), 7.30 (d, J=4.7 Hz, 1H), 7.33-7.36 (m, 2H), 7.44-7.47 (m, 1H), 7.49-7.52 (m, 2H), 7.61 (s, 1H), 7.77 (d, J=8.3 Hz, 1H), 8.23 (d, J=7.6 Hz, 1H), 8.29 (d, J=8.4 Hz, 1H), 8.53 (d, J=5.0 Hz, 1H).

Synthesis of the Complex Pd2:

To a 100 mL of three-necked bottle with a magnetic rotor and condenser tube, Ligand L2 (197.0 mg, 0.35 mmol, 1.0 eq), Pd(OAc)₂ (86.5 mg, 0.39 mmol, 1.1 eq) and ⁿBu₄NBr (12.9 mg, 0.04 mmol, 0.1 eq) were added in order. Nitrogen was purged three times, then solvent acetic acid (25 mL) was added, followed by nitrogen bubbling for 10 minutes, stirring at room temperature for 12 hours, and then stirring at 110° C. in oil bath for 3 days. The reaction mixture was cooled to room temperature and distilled off the solvent under reduced pressure, the crude product was purified by silica gel column chromatography eluting solvent (petroleum ether:dichloromethane=3:1˜1:1), get Pd2, white solid 186.4 mg, 80% yield. ¹H NMR (500 MHz, DMSO-d₆): (δ 2.02 (s, 6H), 2.06 (s, 3H), 2.30 (s, 3H), 2.39 (s, 3H), 2.43 (s, 3H), 7.00-7.02 (m, 3H), 7.18 (d, J=8.5 Hz, 1H), 7.22 (dd, J=6.0, 1.0 Hz, 1H), 7.27 (t, J=8.0 Hz, 1H), 7.31 (dd, J=8.0, 1.0 Hz, 1H), 7.37-7.40 (m, 1H), 7.46-7.49 (m, 1H), 7.90 (d, J=8.0 Hz, 1H), 7.91 (s, 1H), 8.09 (d, J=8.0 Hz, 1H), 8.14 (dd, J=7.5, 0.5 Hz, 1H), 8.94 (d, J=5.5 Hz, 1H). ¹³C NMR (100 MHz, DMSO-d₆): δ 12.80, 12.94, 20.07, 20.69, 20.92, 108.03, 111.33, 111.95, 112.37, 115.01, 115.47, 116.45, 119.80, 120.36, 120.43, 122.59, 122.67, 124.57, 125.83, 127.22, 127.87, 128.15, 137.15, 137.67, 137.88, 137.97, 143.17, 147.43, 147.91, 148.64, 151.23, 151.51, 151.88, 152.17. HRMS (DART POSTIVE Ion Mode) for C₃₈H₃₃N₄O¹⁰²Pd [M+H]⁺: calcd 663.1705, found 663.1699.

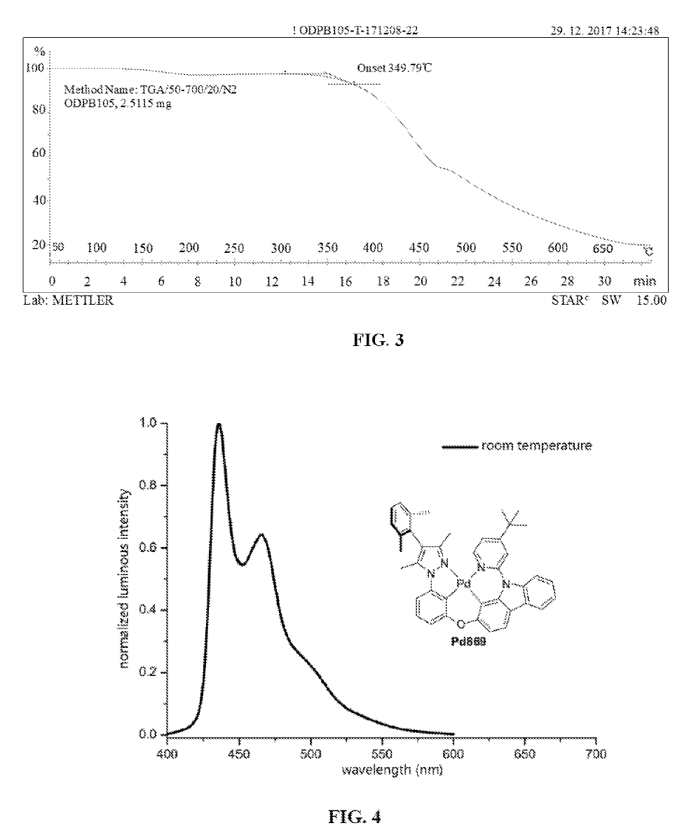

FIG. 2 shows the emission spectrum of the complex Pd2 in dichloromethane solution at room temperature; FIG. 3 shows the original spectrum of thermogravimetric analysis (TGA) of the complex Pd2.

### Example 3: Synthesis of the Complex Pd869 in the Following Route

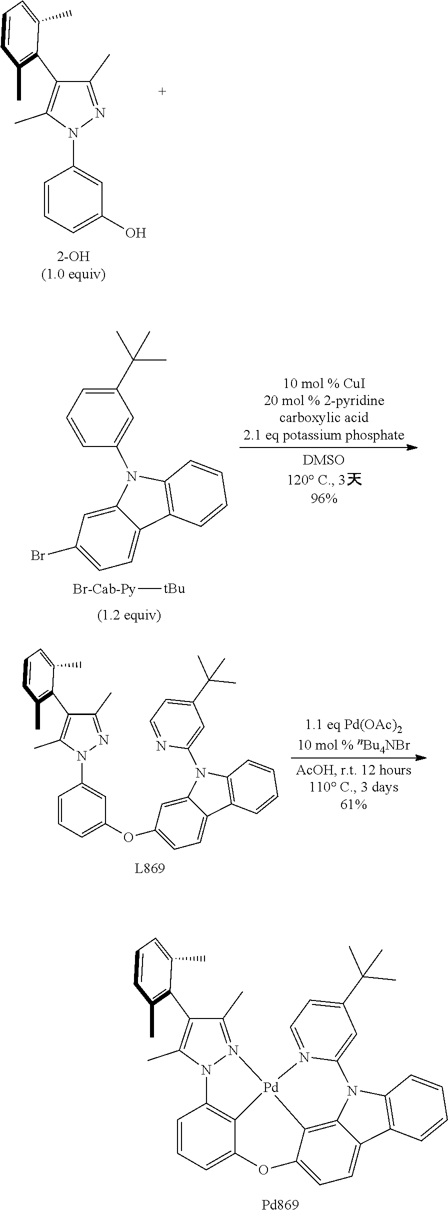

Synthesis of Ligand L869:

To a dry sealed tube with a magnetic rotor, 1-(3-hydroxyphenyl)-3,5-dimethyl-4-(2,6-dimethylphenyl)-pyrazole 2-OH (877.1 mg, 3.00 mmol, 1.0 eq), 2-bromo-9-(2-(4-tert-butylpyridyl))carbazole Br-Cab-Py-tBu (1.37 g, 3.60 mmol, 1.2 eq, see synthesis method: The Journal of Organic Chemistry, 2017, 82, 1024-1033), cuprous iodide (57.1 mg, 0.30 mmol, 0.1 eq), ligand 2-picolinic acid (73.9 mg, 0.60 mmol, 0.2 eq), potassium phosphate (1.34 g, 6.30 mmol, 2.1 eq). Nitrogen was purged three times and then added solvent dimethylsulfoxide (8 mL). The reaction mixture was then stirred at 120° C. for 3 days, cooled to room temperature, diluted with a large of ethyl acetate, filtered and washed with ethyl acetate. The resulting filtrate was washed twice with water and extracted with the aqueous phase twice, the organic phases were combined and dried over anhydrous sodium sulfate. Filtration, the filtrate was distilled under reduced pressure to remove the solvent, the crude product was purified by silica gel column chromatography, eluent (petroleum ether/ethyl acetate=10:1), get the target product, white solid 1.47 g, 96% yield.

¹H NMR (400 MHz, DMSO-d₆): δ 1.28 (s, 9H), 1.89 (s, 3H), 1.966 (s, 3H), 1.969 (s, 6H), 7.10-7.18 (m, 5H), 7.29 (t, J=2.0 Hz, 1H), 7.31-7.39 (m, 3H), 7.42-7.46 (m, 2H), 7.52 (t, J=8.0 Hz, 1H), 7.63 (d, J=0.8 Hz, 1H), 7.74 (d, J=8.0 Hz, 1H), 8.22 (d, J=7.6 Hz, 1H), 8.29 (d, J=8.4 Hz, 1H), 8.56 (d, J=5.2 Hz, 1H).

Synthesis of the Complex Pd869:

To a 100 mL of three-necked flask with a magnetic rotor and condenser tube, Ligand L869 (295.4 mg, 0.50 mmol, 1.0 eq), Pd(OAc)₂ (123.5 mg, 0.55 mmol, 1.1 eq) and ⁿBu₄NBr (16.1 mg, 0.05 mmol, 0.1 eq) were added in order. Nitrogen was purged three times, then solvent acetic acid (30 mL) was added, followed by nitrogen bubbling for 10 minutes, stirring at room temperature for 12 hours, and then stirring at 110° C. in oil bath for 3 days. The reaction mixture was cooled to room temperature, and the solvent was distilled off under reduced pressure, the crude product was purified by silica gel column chromatography, eluent (petroleum ether:dichloromethane=2:1˜1:1), get Pd869, brown solid 212.1 mg, 61% yield. ¹H NMR (500 MHz, DMSO-d₆): δ 1.32 (s, 9H), 2.07 (s, 6H), 2.10 (s, 3H), 2.41 (s, 3H), 7.02 (dd, J=8.0, 0.5 Hz, 1H), 7.19-7.21 (m, 3H), 7.24-7.29 (m, 2H), 7.33 (dd, J=8.0, 1.0 Hz, 1H), 7.37-7.40 (m, 1H), 7.46-7.51 (m, 2H), 7.92 (d, J=8.0 Hz, 1H), 7.99 (d, J=2.0 Hz, 1H), 8.09 (d, J=8.0 Hz, 1H), 8.17 (dd, J=7.5, 0.5 Hz, 1H), 8.98 (d, J=6.0 Hz, 1H). ¹³C NMR (100 MHz, DMSO-d₆): δ 12.89, 13.14, 20.23, 29.73, 35.34, 108.05, 111.18, 111.99, 112.47, 114.56, 116.45, 116.67, 117.12, 120.04, 120.45, 122.50, 122.69, 124.69, 125.93, 127.45, 127.92, 128.18, 130.27, 137.88, 137.94, 138.09, 143.24, 147.23, 147.96, 148.89, 151.26, 151.70, 151.81, 164.06. HRMS (DART POSTIVE Ion Mode) for C₄₀H₃₇N₄O¹⁰²Pd [M+H]⁺: calcd 691.2018, found 691.2025.

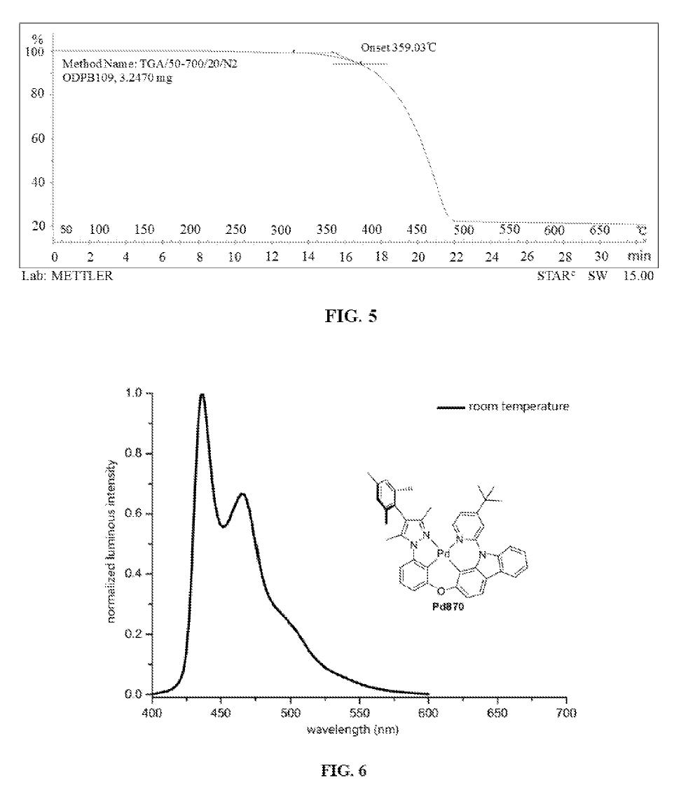

FIG. 4 shows a emission spectrum of the complex Pt869 in dichloromethane solution at room temperature; FIG. 5 shows the original spectrum of thermogravimetric analysis (TGA) of the complex Pd869.

### Example 4: Synthesis of the Complex Pd870 in the Following Route

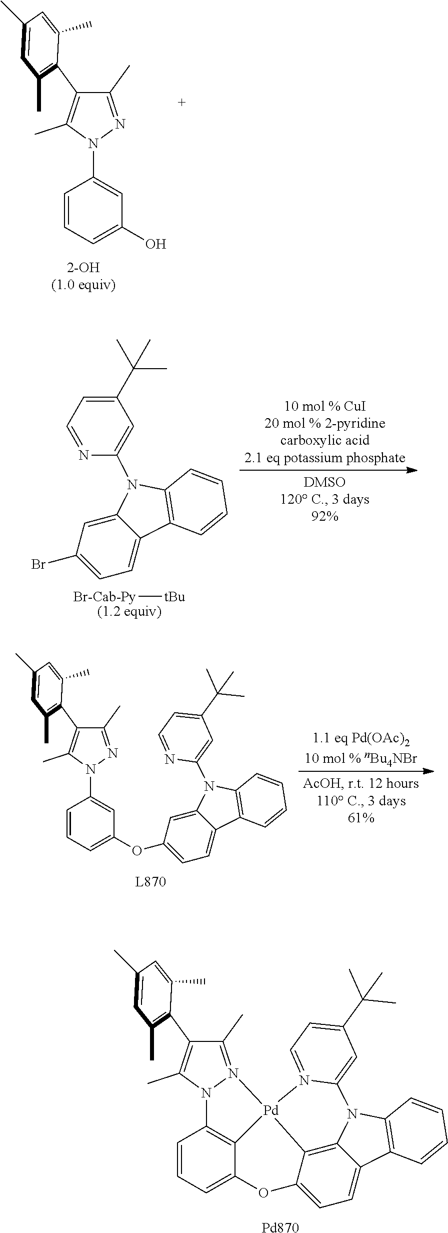

Synthesis of Ligand L870:

To a dry sealed tube with a magnetic rotor, 1-(3-hydroxyphenyl)-2,5-dimethyl-4-(2,6-dimethylphenyl)-pyrazole 3-OH (1.46 g, 5.00 mmol, 1.0 eq), 2-bromo-9-(2-(4-tert-butylpyridyl))carbazole Br-Cab-Py-tBu (2.27 g, 6.00 mmol, 1.2 eq, see synthesis method: The Journal of Organic Chemistry, 2017, 82, 1024-1033), cuprous iodide (95.2 mg, 0.50 mmol, 0.1 eq), ligand 2-picolinic acid (123.1 mg, 1.00 mmol, 0.2 eq), potassium phosphate (2.23 g, 10.50 mmol, 2.1 eq) were added in order. Nitrogen was purged three times and then added solvent dimethylsulfoxide (10 mL). The reaction mixture was then stirred at 120° C. for 3 days, cooled to room temperature, diluted with a large of ethyl acetate, filtered and washed with ethyl acetate. The resulting filtrate was washed twice with water and extracted the aqueous phase twice, then combined the organic phases and dried over anhydrous sodium sulfate. Filtration, the filtrate was distilled under reduced pressure to remove the solvent, the crude product was purified by silica gel column chromatography, eluent (petroleum ether/ethyl acetate=20:1-10:1), get the target product, white solid 2.78 g, 92% yield.

¹H NMR (500 MHz, DMSO-d₆): δ 1.27 (s, 9H), 1.87 (s, 3H), 1.92 (s, 6H), 1.95 (s, 3H), 2.25 (s, 3H), 6.93 (s, 2H), 7.10 (dd, J=8.5, 2.0 Hz, 1H), 7.14 (dd, J=8.5, 2.5 Hz, 1H), 7.28 (t, J=2.0 Hz, 1H), 7.33 (t, J=7.5 Hz, 1H), 7.37 (dd, J=8.5, 1.5 Hz, 1H), 7.38 (d, J=2.0 Hz, 1H), 7.42-7.45 (m, 2H), 7.51 (t, J=8.0 Hz, 1H), 7.62 (d, J=1.5 Hz, 1H), 7.74 (d, J=8.0 Hz, 1H), 8.22 (d, J=8.0 Hz, 1H), 8.29 (d, J=8.5 Hz, 1H), 8.56 (d, J=5.0 Hz, 1H).

Synthesis of the Complex Pd870:

To a 100 mL of three-necked flask with a magnetic rotor and condenser tube, Ligand L870 (302.4 mg, 0.50 mmol, 1.0 eq), Pd(OAc)₂ (123.5 mg, 0.55 mmol, 1.1 eq) and ⁿBu₄NBr (16.1 mg, 0.05 mmol, 0.1 eq) were added in order. Nitrogen was purged three times, then solvent acetic acid (30 mL) was added, followed by nitrogen bubbling for 10 minutes, stirring at room temperature for 12 hours, and then stirring at 110° C. in oil bath for 3 days. The reaction mixture was cooled to room temperature, and the solvent was distilled off under reduced pressure, the crude product was purified by silica gel column chromatography, eluent (petroleum ether:dichloromethane=3:1˜1:1), get Pd870, brown solid 205.9 mg, 58% yield. ¹H NMR (500 MHz, DMSO-d₆): (δ 1.31 (s, 9H), 2.02 (s, 6H), 2.09 (s, 3H), 2.30 (s, 3H), 2.40 (s, 3H), 7.00-7.02 (m, 3H), 7.19 (d, J=8.0 Hz, 1H), 7.27 (t, J=7.5 Hz, 1H), 7.31-7.33 (m, 1H), 7.29 (t, J=8.0 Hz, 1H), 7.45-7.50 (m, 2H), 7.91 (d, J=8.5 Hz, 1H), 7.98 (d, J=2.0 Hz, 1H), 8.08 (d, J=8.5 Hz, 1H), 8.16 (d, J=7.5 Hz, 1H), 8.97 (d, J=6.0 Hz, 1H). ¹³C NMR (100 MHz, DMSO-d₆): δ 12.82, 13.07, 20.09, 20.70, 29.71, 35.31, 107.98, 111.16, 111.95, 112.39, 114.51, 116.41, 116.60, 117.05, 119.99, 120.39, 122.45, 122.65, 124.63, 125.87, 127.21, 127.90, 128.14, 137.16, 137.68, 137.96, 138.06, 143.23, 147.40, 147.95, 148.89, 151.25, 151.64, 151.80, 164.05. HRMS (DART POSTIVE Ion Mode) for C₄₁H₃₉N₄O¹⁰²Pd [M+H]⁺: calcd 705.2174, found 705.2175.

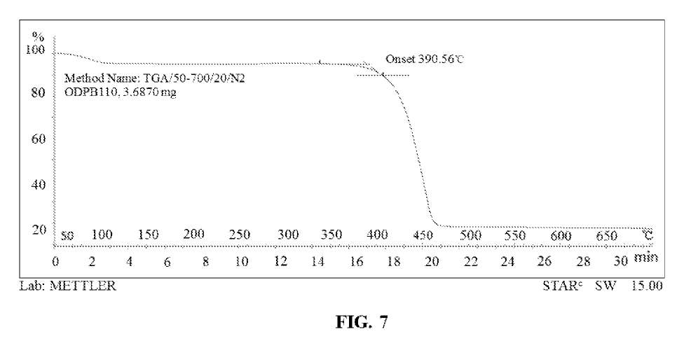

FIG. 6 shows the emission spectrum of the complex Pd870 in dichloromethane solution at room temperature; FIG. 7 shows the original spectrum of thermogravimetric analysis (TGA) of the complex Pd870.

### Performance Evaluation Examples

Photophysical, electrochemical and thermogravimetric analysis of the complexes prepared in the above examples of the present disclosure are described below:

Photophysical analysis: phosphorescence emission spectra and triplet lifetimes were all tested on a HORIBA FL3-11 spectrometer. Test conditions: in a emission spectra at room temperature, all of samples were dilute solutions of dichloromethane (chromatographic grade) (10⁻⁵-10⁻⁶ M), and the samples were all prepared in glove box, and were purged with nitrogen for 5 minutes; the triplet lifetime detection is measured at the strongest peak of the sample emission spectrum. Quantum efficiency is the absolute quantum efficiency measured in an integrating sphere with a dilute solution of dichloromethane (chromatographic grade) of the sample (10⁻⁵-10⁻⁶ M).

Electrochemical analysis: cyclic voltammetry was used to test on CH670E electrochemical workstation. 0.1 M solution of tetra-n-butyl ammonium hexafluorophosphate (ⁿBu₄NPF₆) in N,N-dimethyl acetamide (DMF) serves as the electrolyte solution; Metal palladiu electrode serves as a positive electrode; graphite is a negative electrode; metal silver is used as a reference electrode; ferrocene is a reference internal standard, and its redox potential is set to zero.

Thermogravimetric analysis: the thermogravimetric analysis curves were all performed on a TGA2(SF) thermogravimetric analysis. The TGA test conditions: the test temperature is 50-700° C.; the heating rate is 20 K/min; the tantalum material is aluminum trioxide; and the testing is completed under the nitrogen atmosphere; the sample quality is generally 2-5 mg.

TABLE 1
Photophysical, electrochemical and thermogravimetric
analysis of the metal complexes luminescent materials

| Pd | peak/ | τ/ | PLQE/ | | Eₒₓ | E_{red} | Td/ |
|---|---|---|---|---|---|---|---|
| complex | nm | μs | % | CIE | (V) | (V) | ° C. |
| Pd1 | 436.4 | 50 | 7 | (0.144, 0.070) | 0.54 | −2.73 | — |
| Pd2 | 436.4 | 38 | 12 | (0.144, 0.071) | 0.56 | −2.73 | 349 |
| Pd869 | 436.0 | 54 | 10 | (0.145, 0.079) | 0.61 | −2.73 | 359 |
| Pd870 | 436.4 | 43 | 13 | (0.145, 0.077) | 0.60 | −2.74 | 390 |

As can be seen from the table 1, the palladium complexes provided by the embodiments of the present disclosure are all deep blue phosphorescent luminescent material, its maximum emission peak is 436.0-436.4 nm; the triplet lifetime of the solution is microseconds (10⁻⁵ seconds) level; all have strong phosphorescence emission; more importantly, the thermal decomposition temperature is above 340° C., which is much higher than the thermal evaporation temperature of the material during producing the device (usually not higher than 300° C.); CIE_{y}<0.1. Therefore, such phosphorescent materials have great application prospects in the field of blue light, especially deep blue phosphorescent material, and are of great significant for the development and application of deep blue phosphorescent materials.

The ordinary skilled in the art can understand that the above examples are specific embodiments for implementing the present disclosure, and in practical applications, various changes in form and detail can be made without departing from the spirit and the scope of the present disclosure.

What is claimed is:

1. A tetradentate cyclic-metal platinum complex comprising 4-aryl-3,5-disubstituted pyrazole, wherein structure of the complex is shown in formula (I): 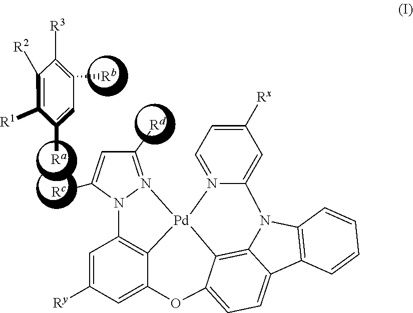
wherein R^{a}, R^{b}, R^{c} and R^{d} each are alkyl, alkoxy, cycloalkyl, ether, heterocyclyl, hydroxy, aryl, heteroaryl, aryloxy, mono- or di-alkylamino, mono- or di-arylamino, halogen, sulfydryl, cyano, independently, or combinations thereof,
R^{x} is alkyl, alkoxy, cycloalkyl, heterocyclyl, ether, mono- or di-alkylamino, mono- or di-arylamino, halogen, or combination thereof,
R^{y} is H, deuterium, alkyl, alkoxy, cycloalkyl, heterocyclyl, ether, mono- or di-alkylamino, mono- or di-arylamino, halogen, or combination thereof;
R¹, R², and R³ are each independently H, deuterium, alkyl, alkoxy, ether, cycloalkyl, heterocyclyl, hydroxy, aryl, heteroaryl, aryloxy, mono- or di-alkylamino, mono- or di-arylamino, halogen, sulfydryl, cyano, haloalkyl, or combinations thereof.

2. The complex according to claim 1, wherein 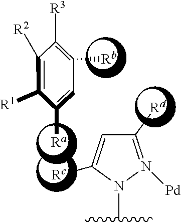
has a structure selected from one of the following structures:

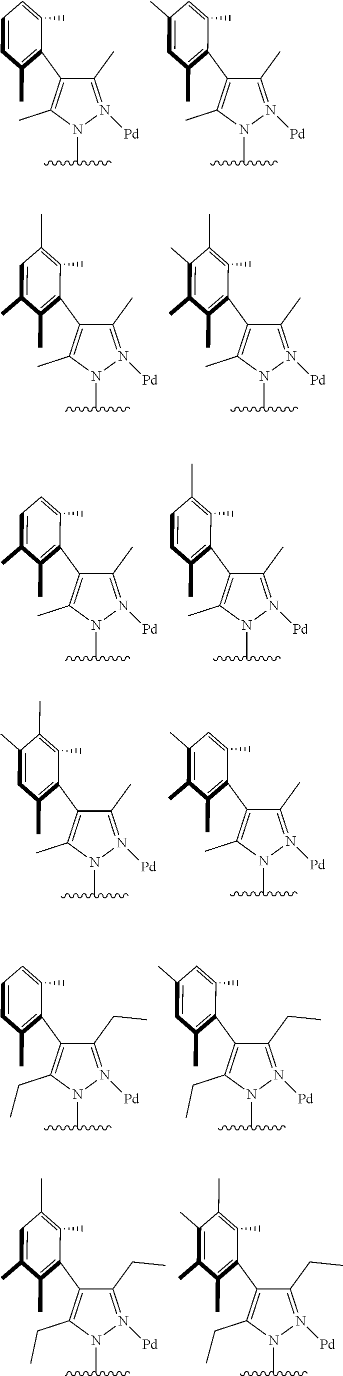

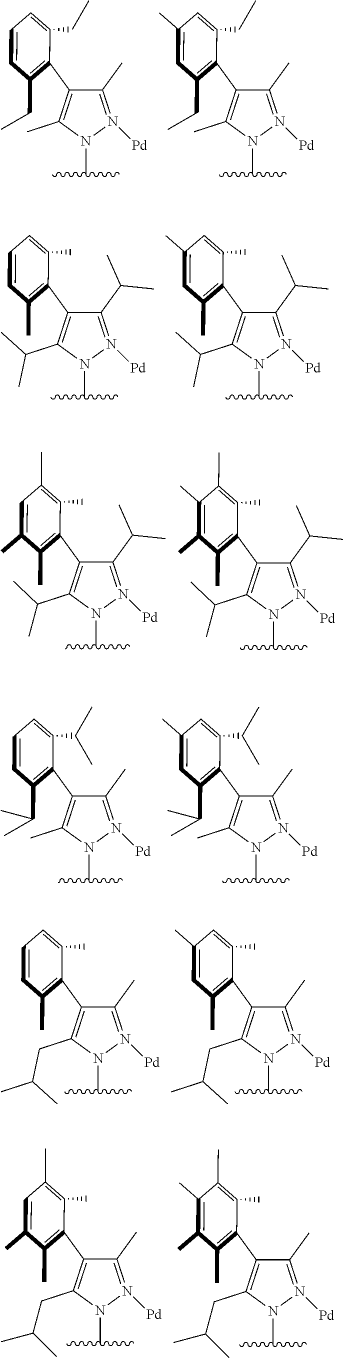

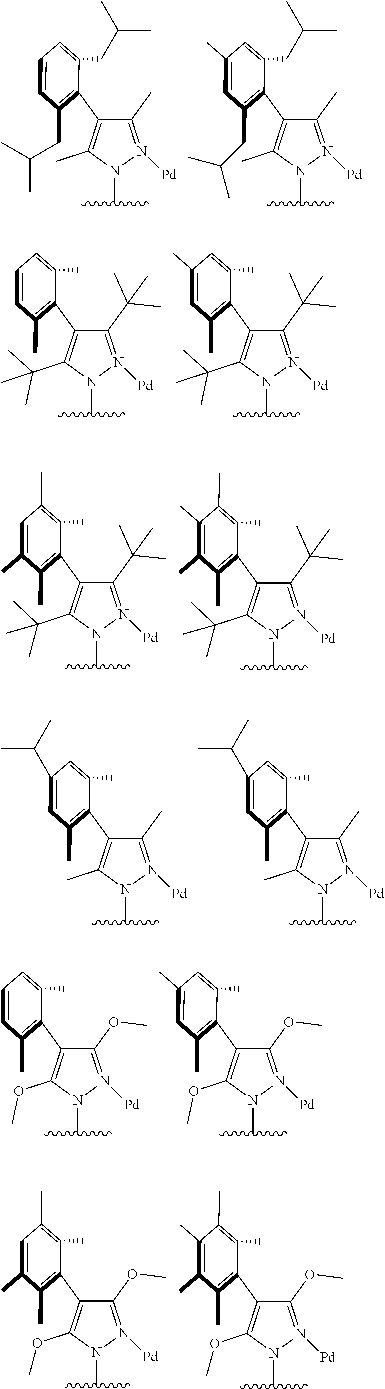

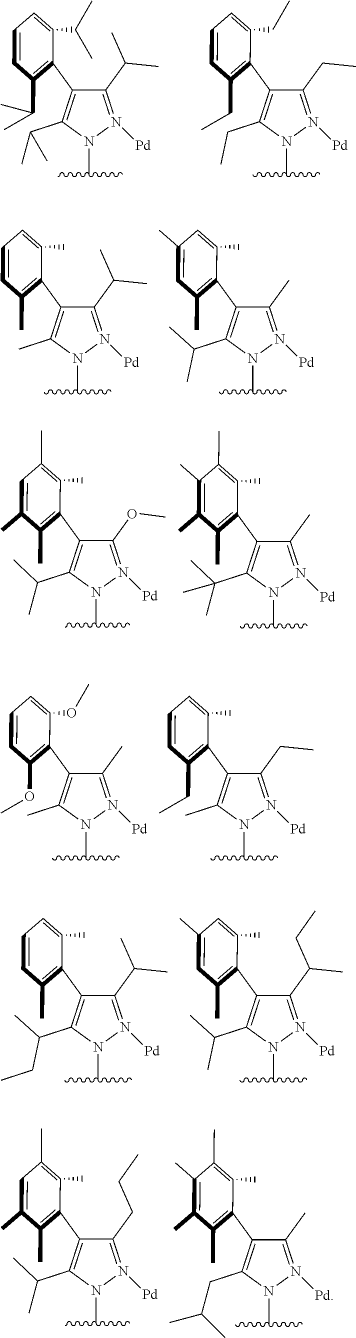

3. The complex according to claim 1, wherein the complex has a structure selected from structures of Pd1˜Pd884:

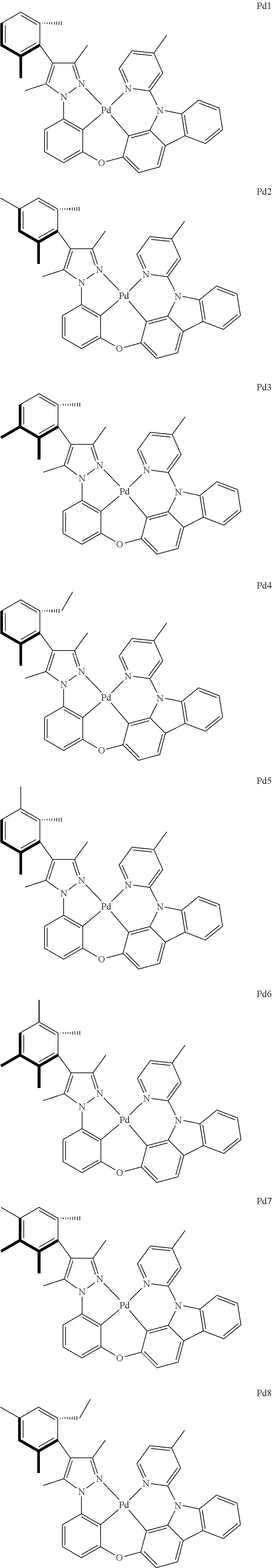

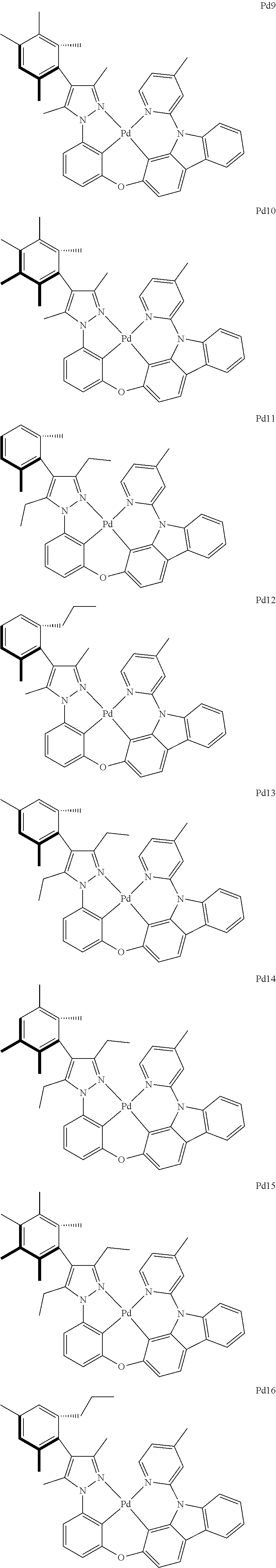

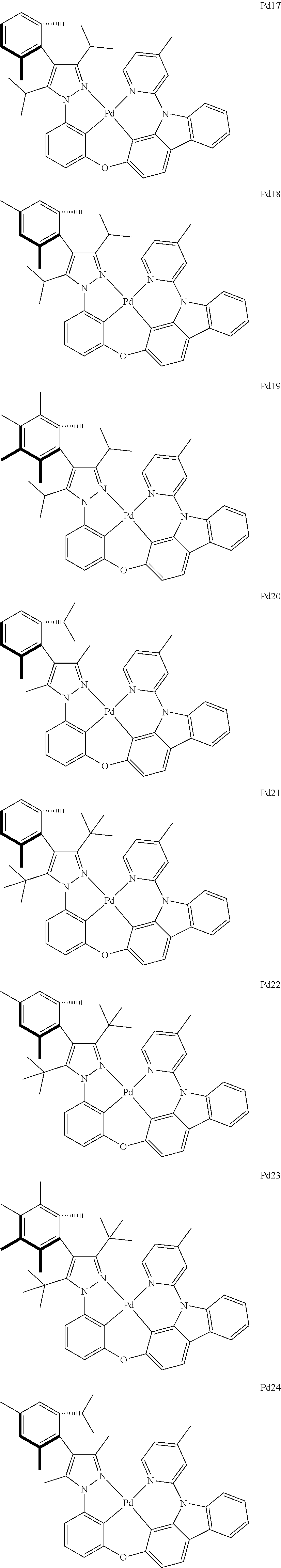

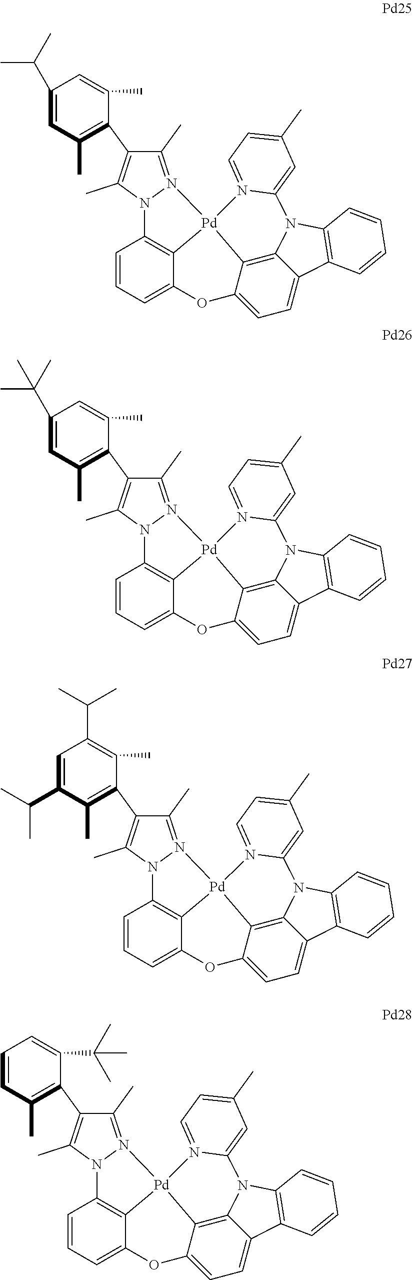

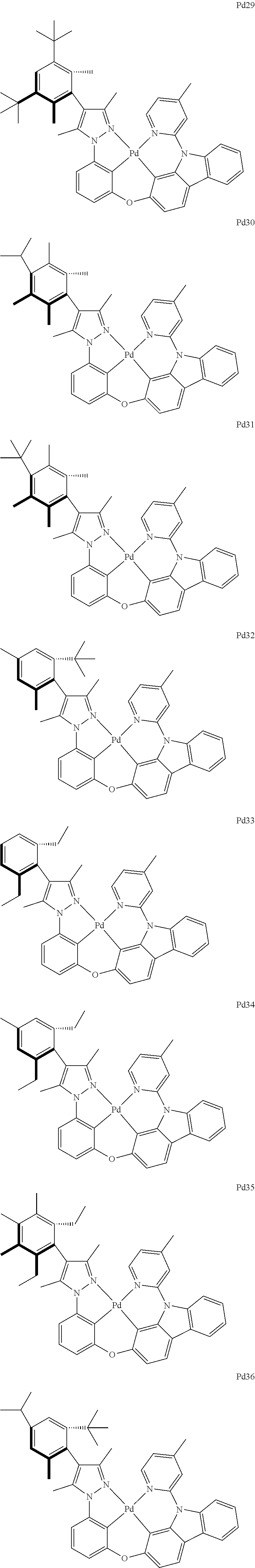

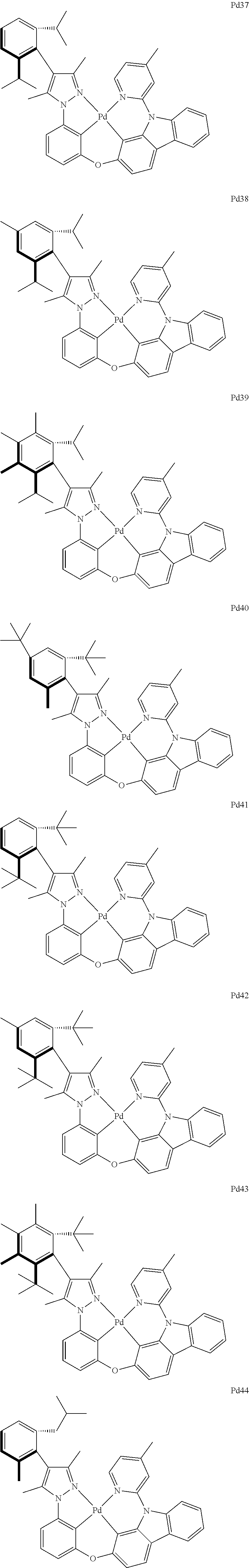

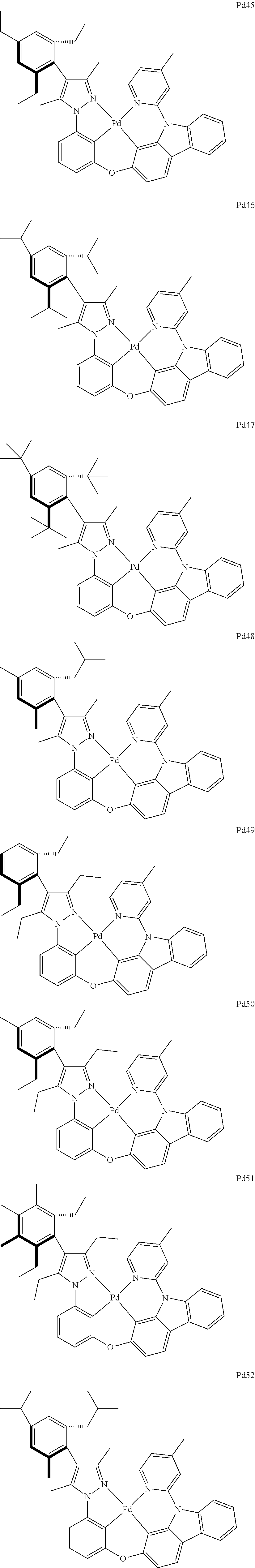

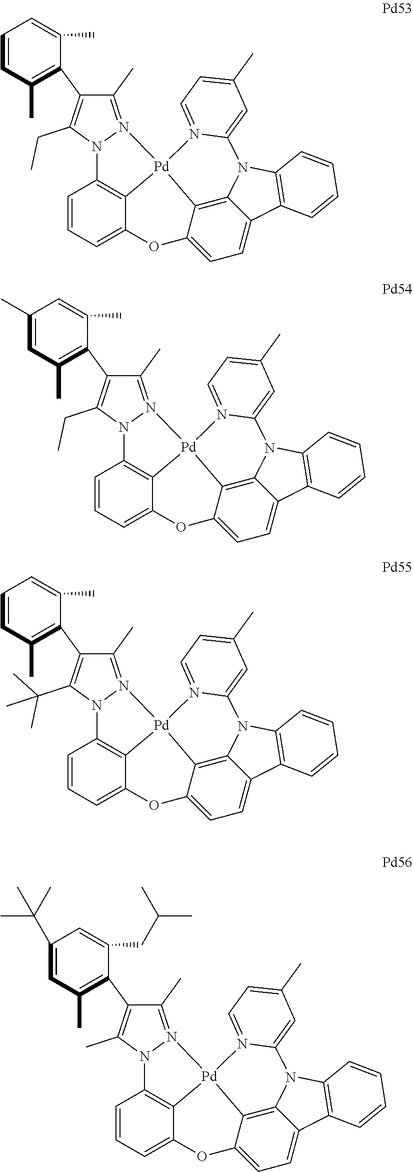

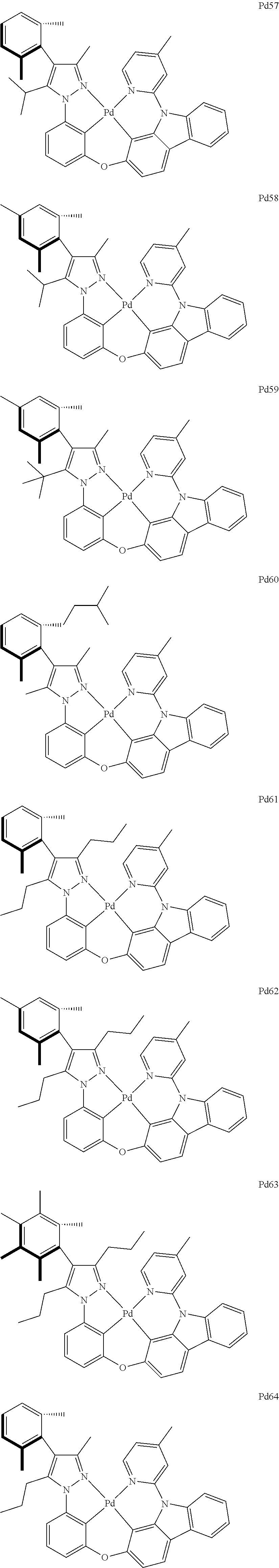

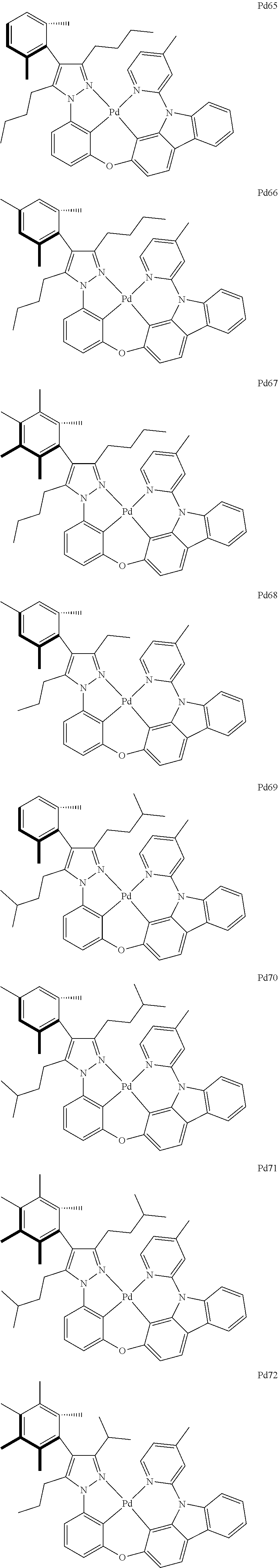

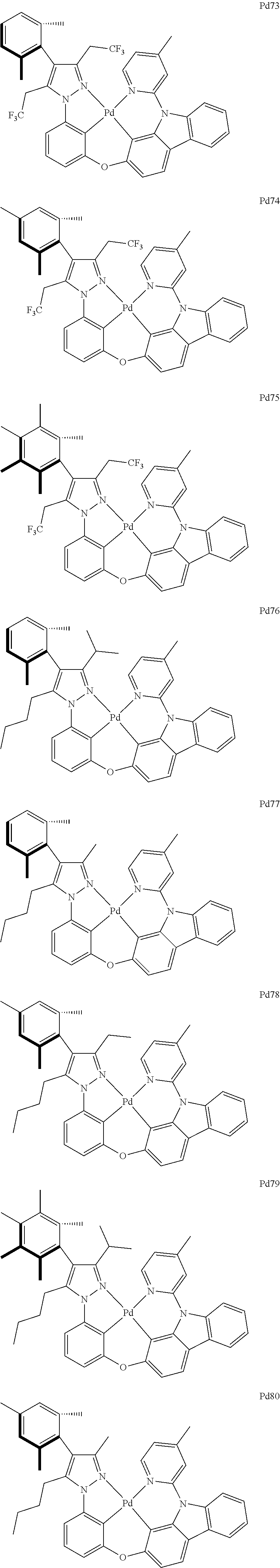

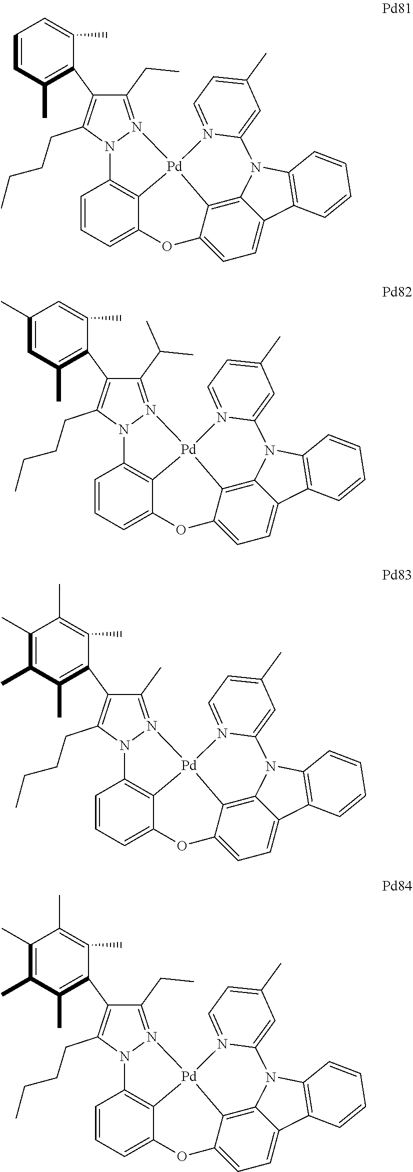

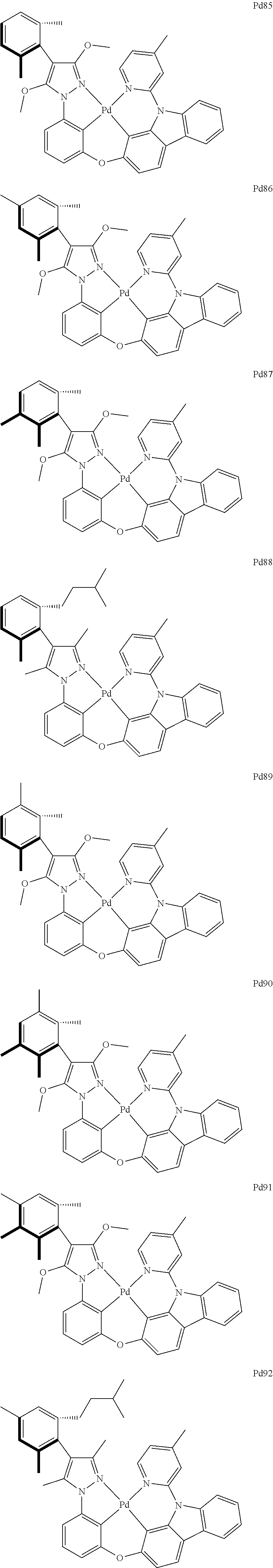

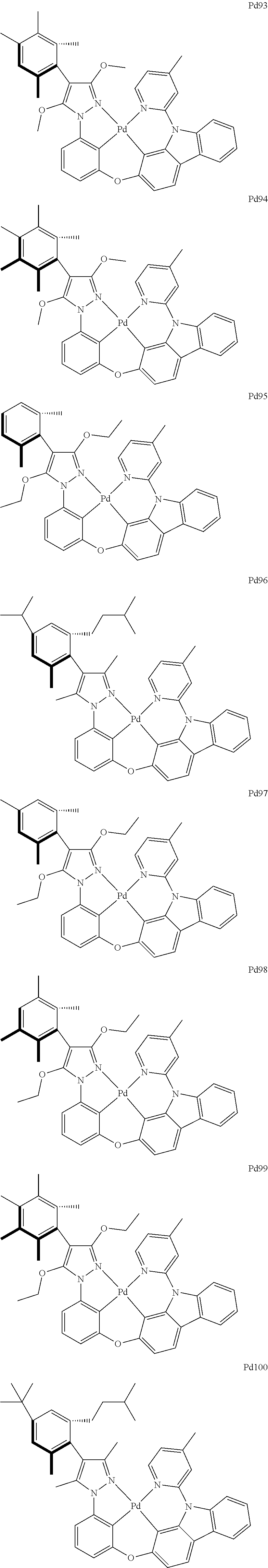

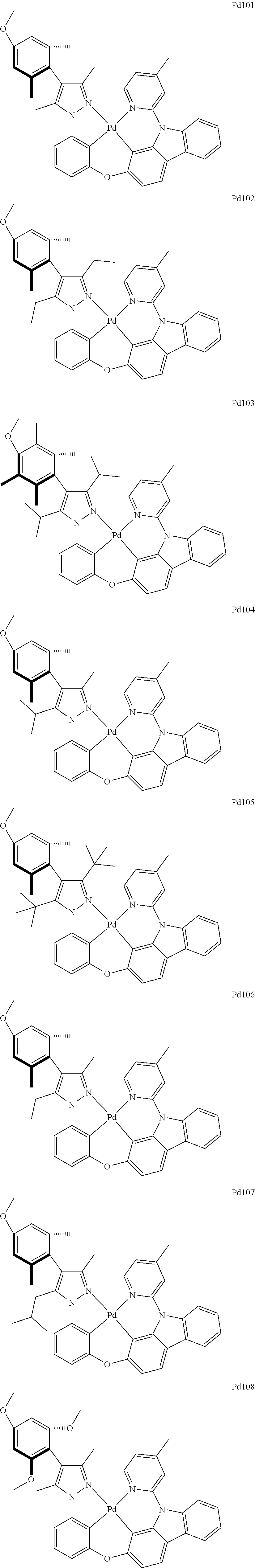

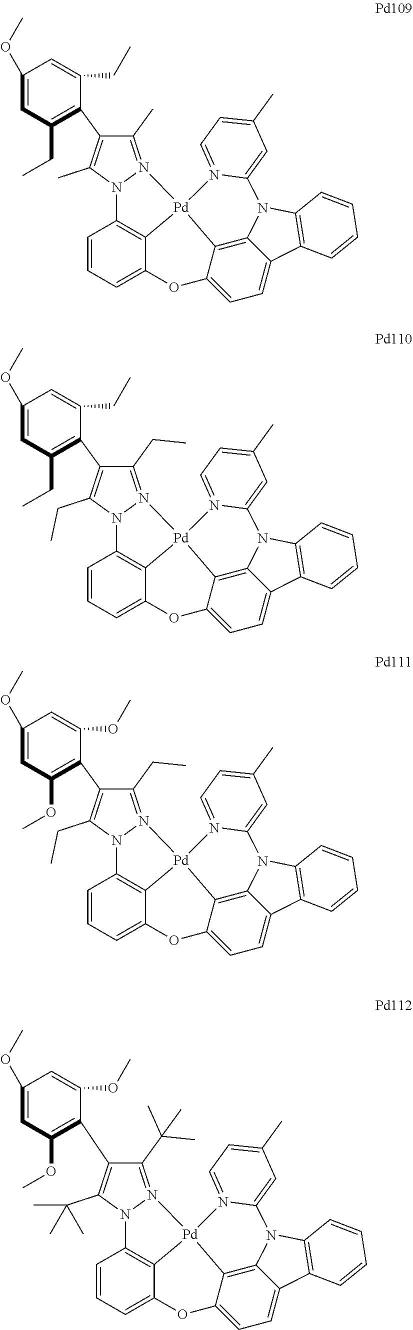

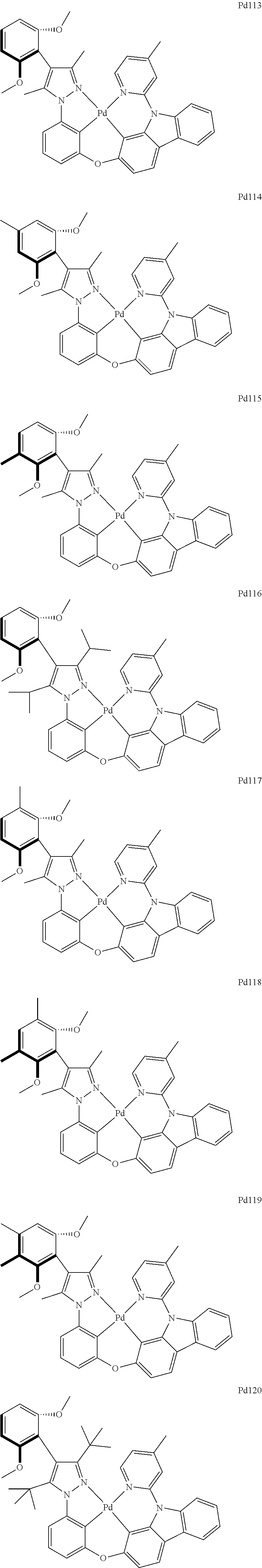

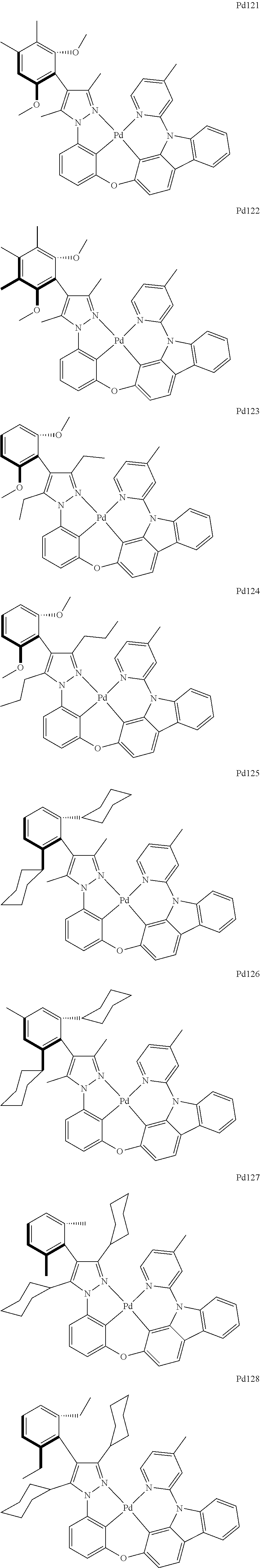

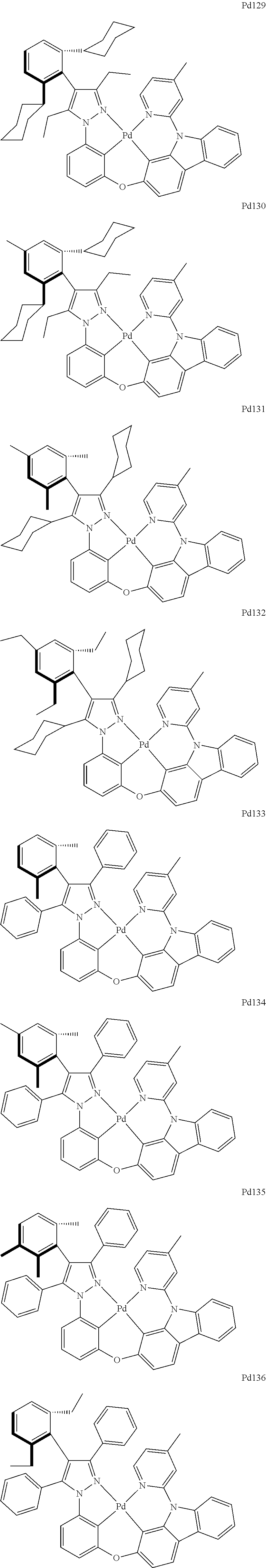

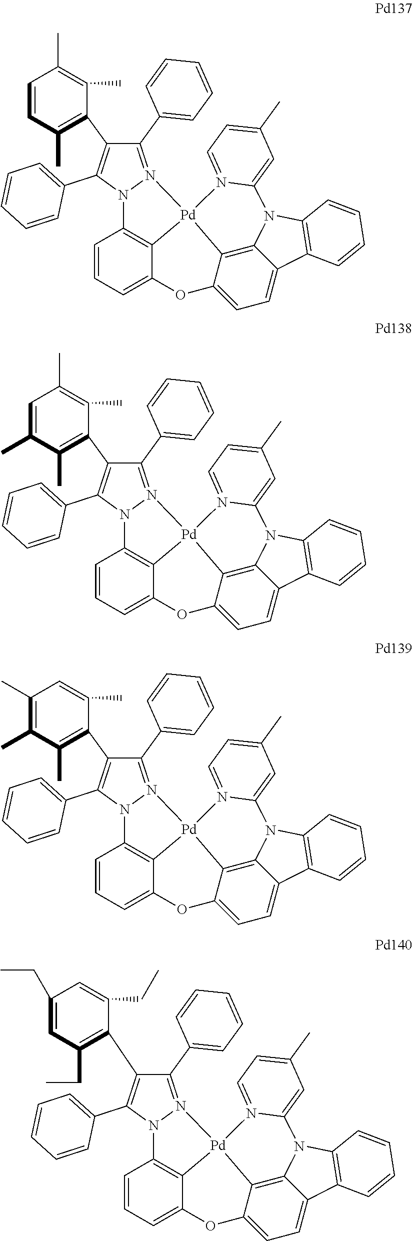

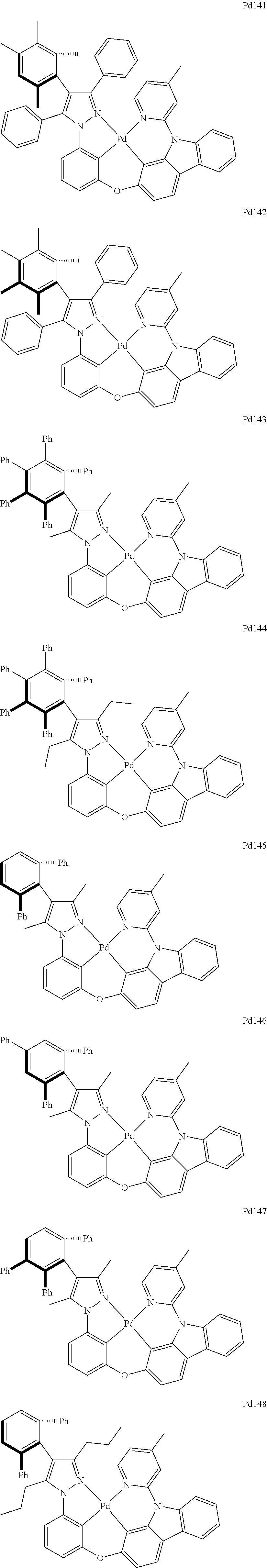

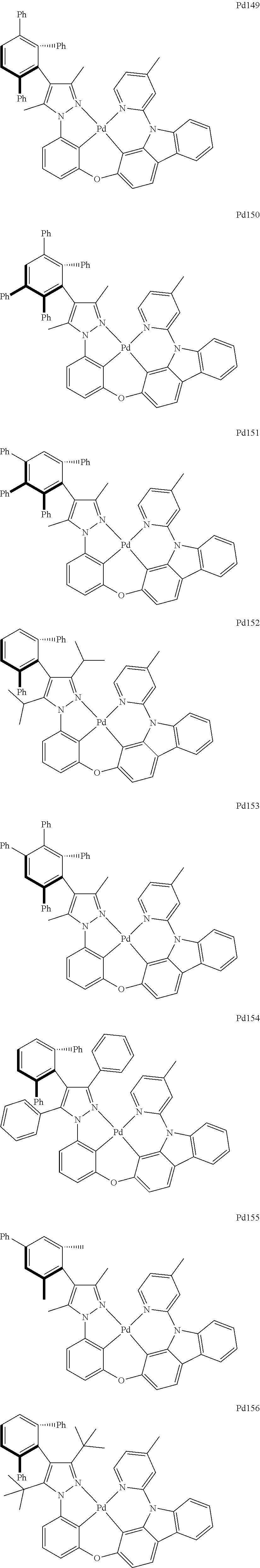

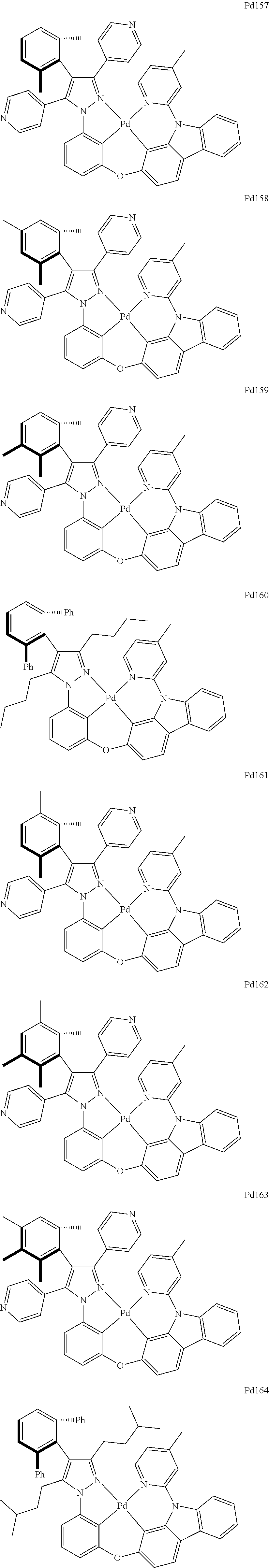

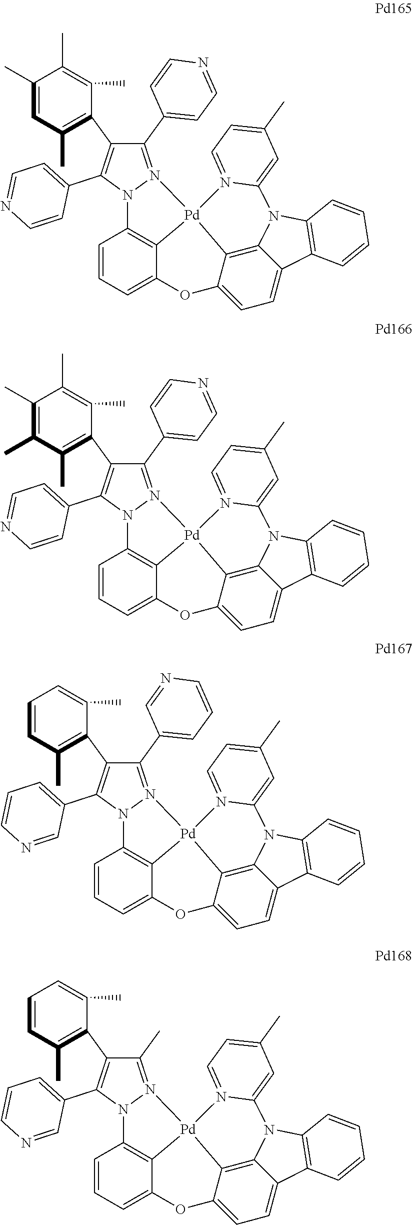

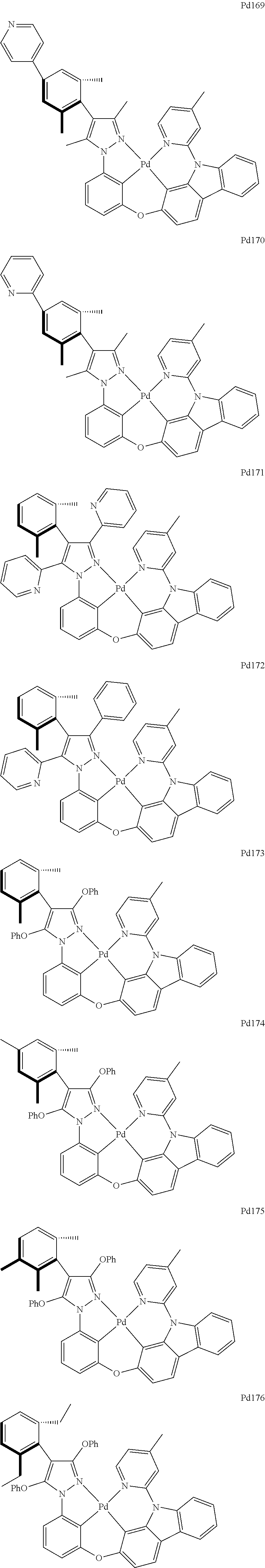

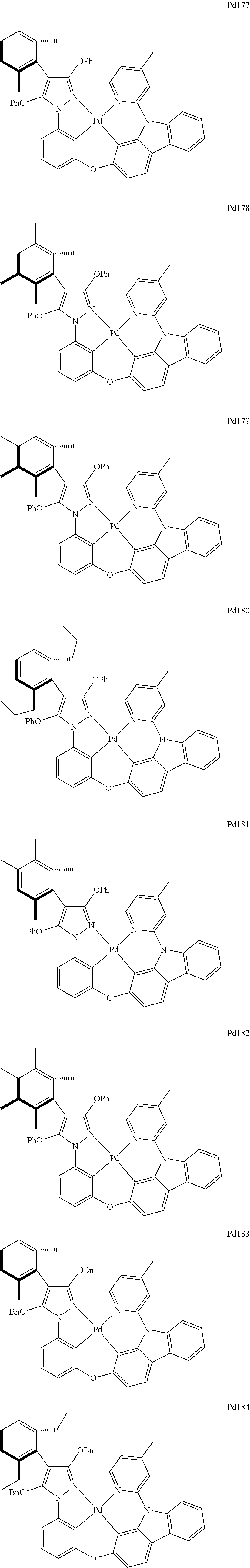

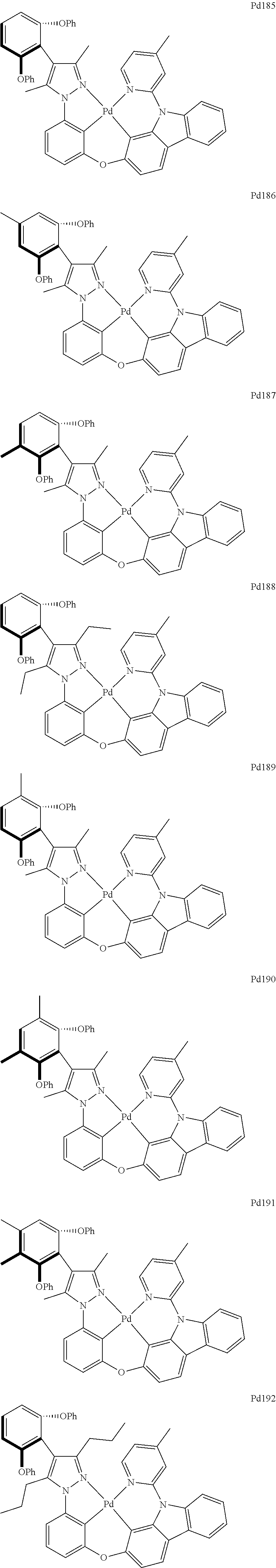

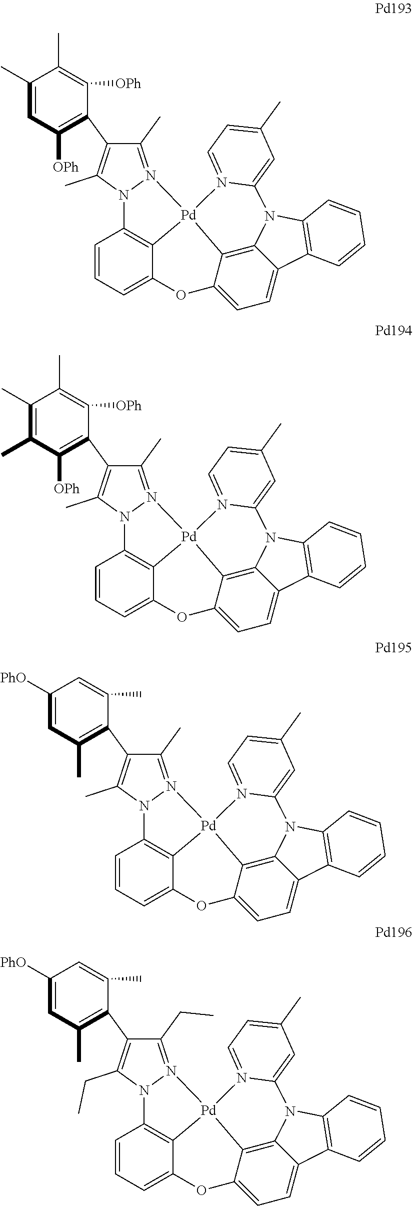

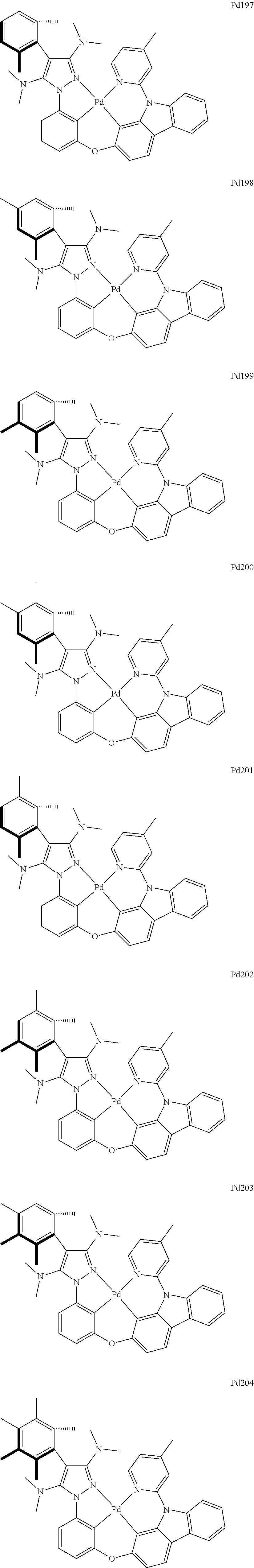

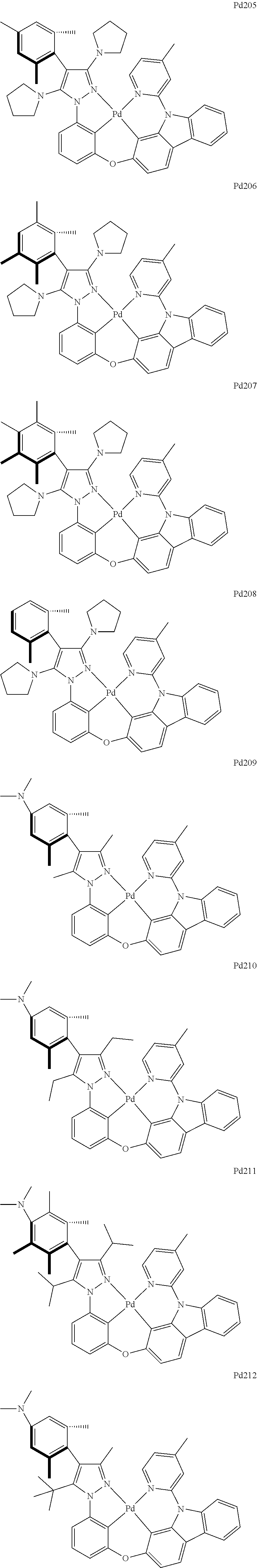

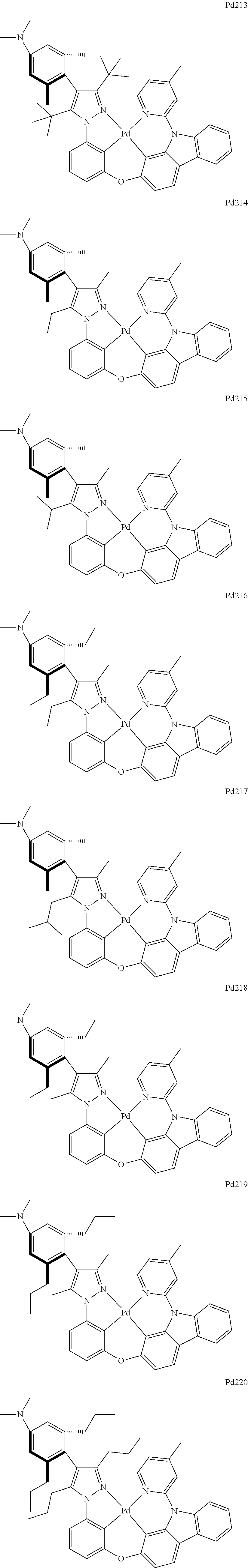

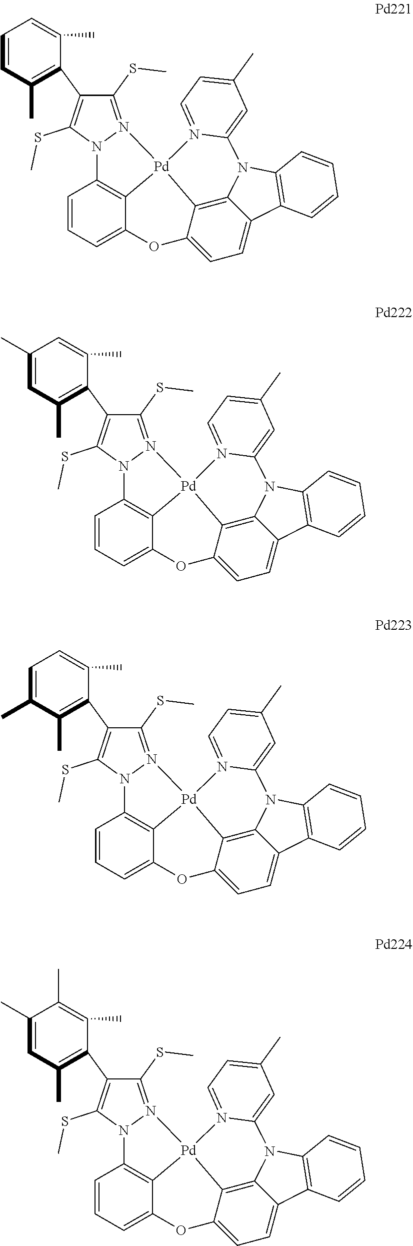

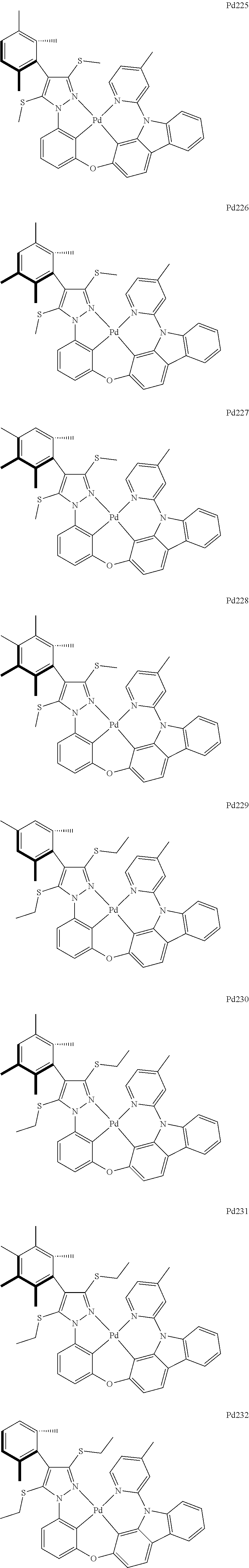

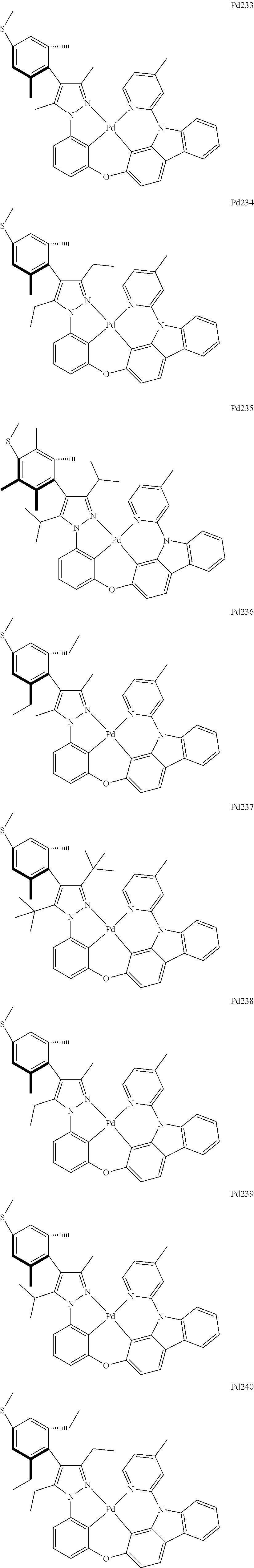

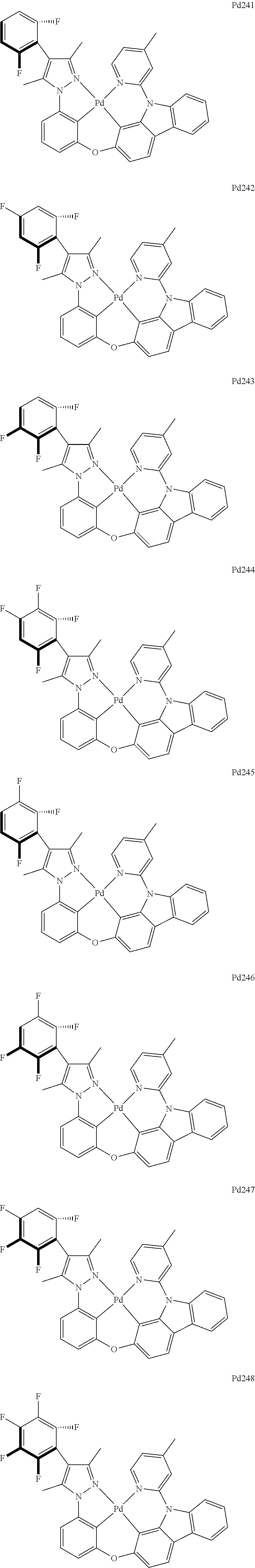

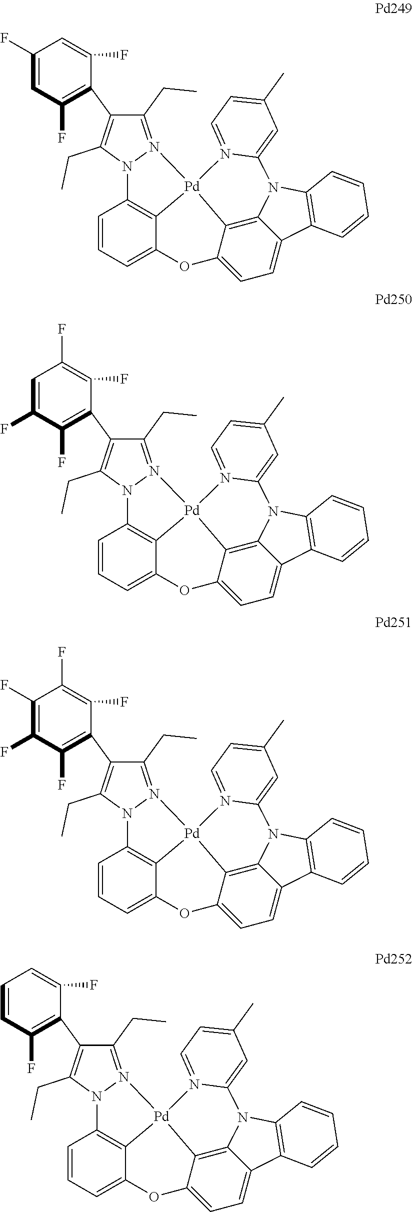

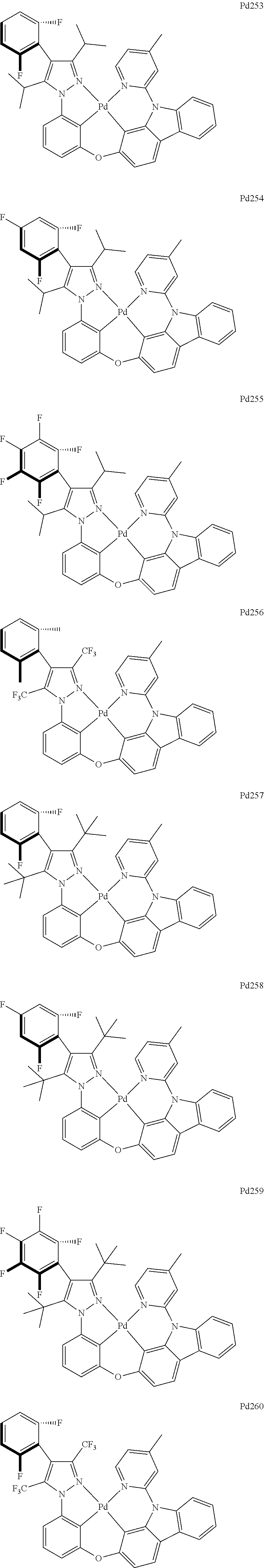

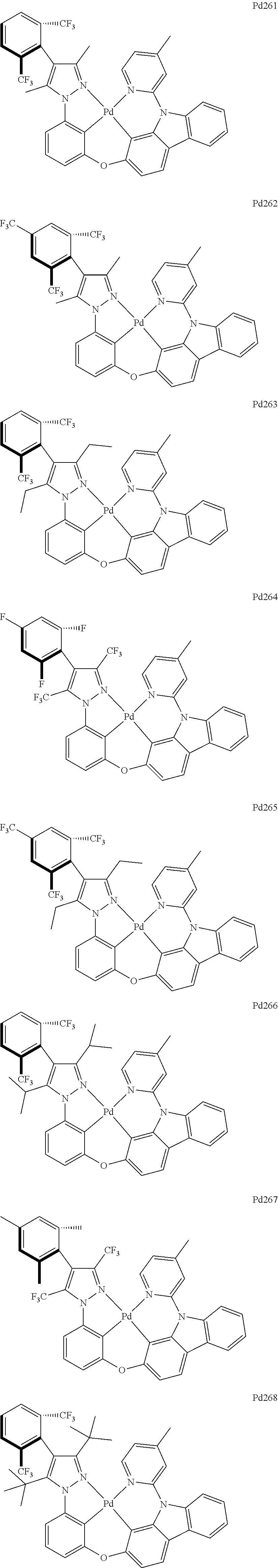

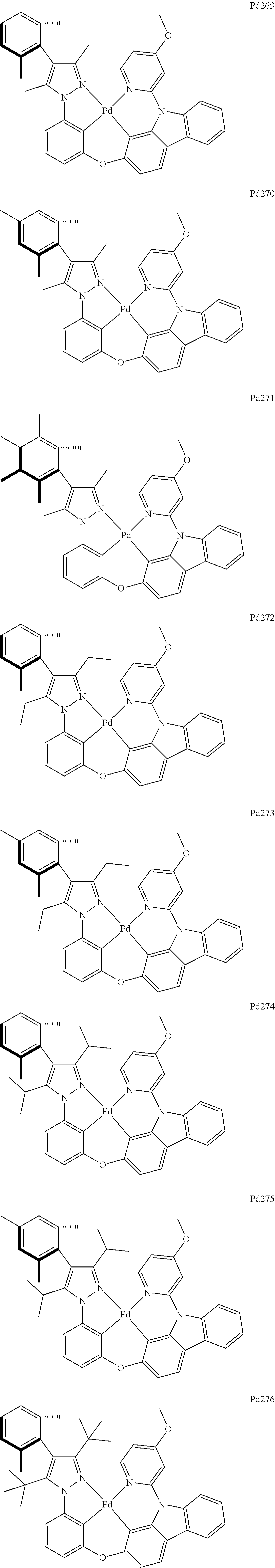

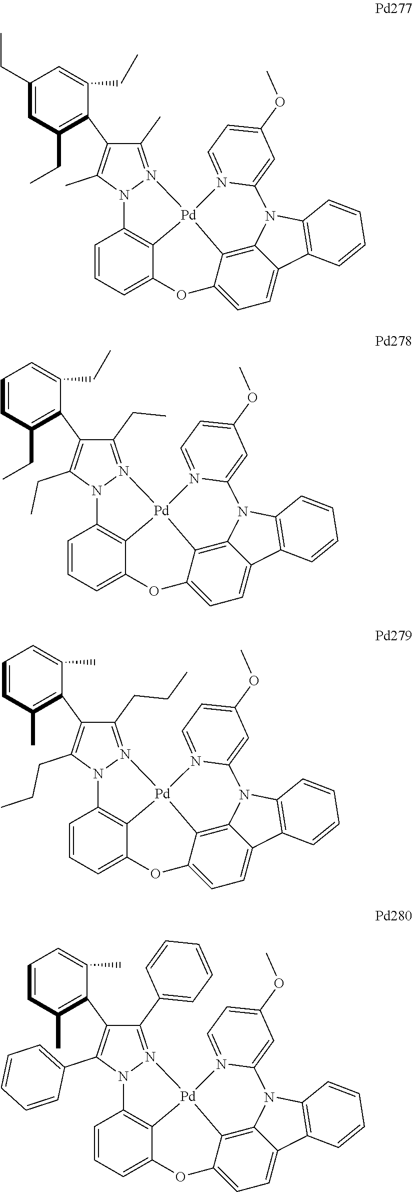

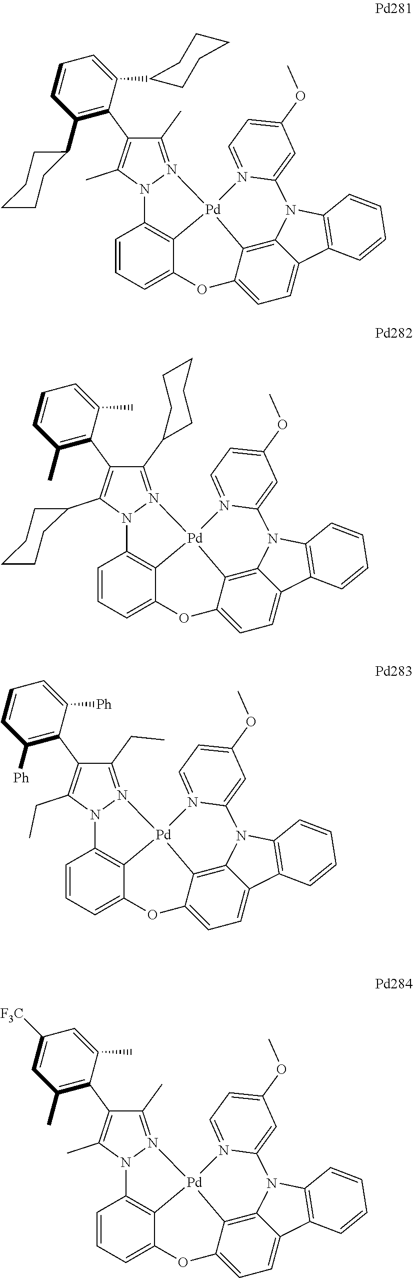

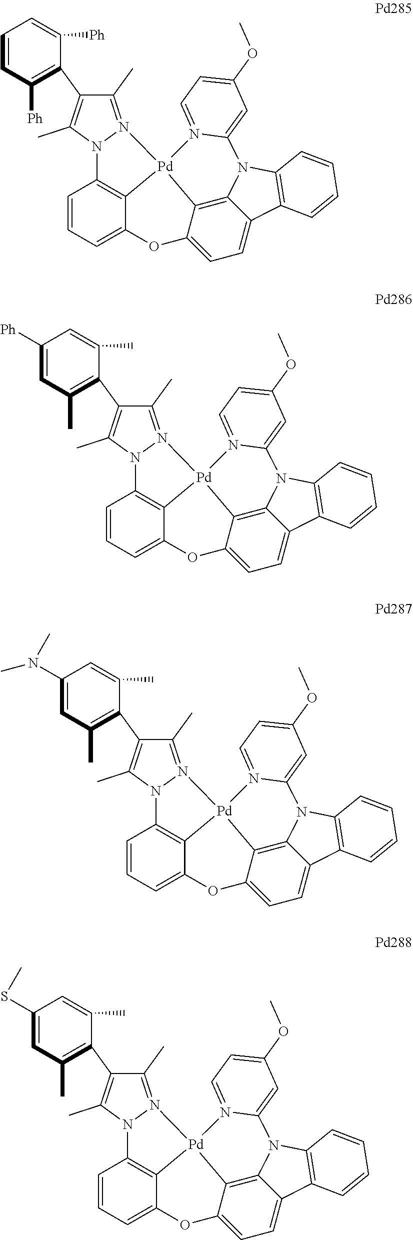

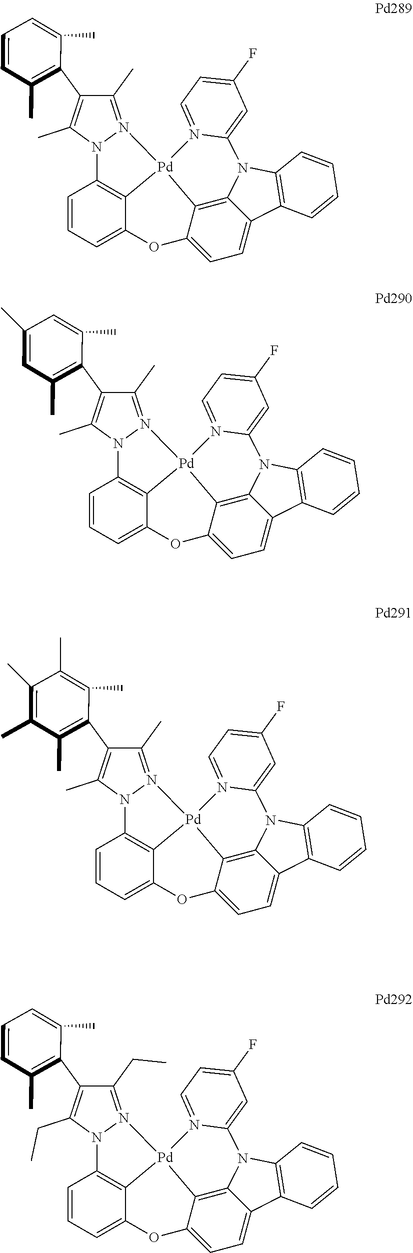

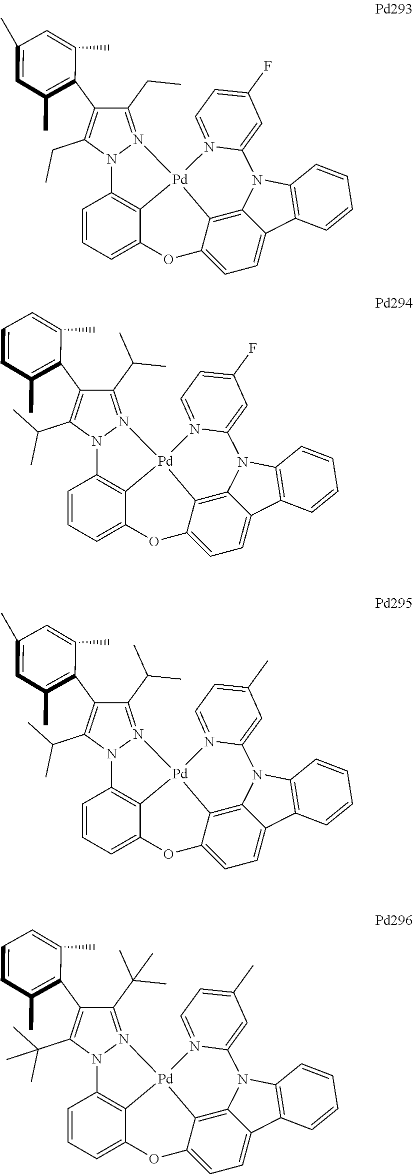

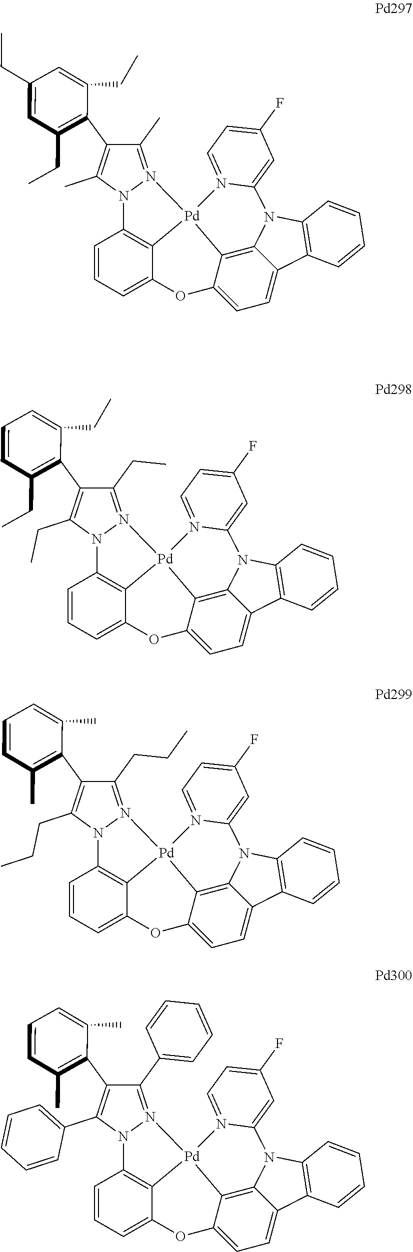

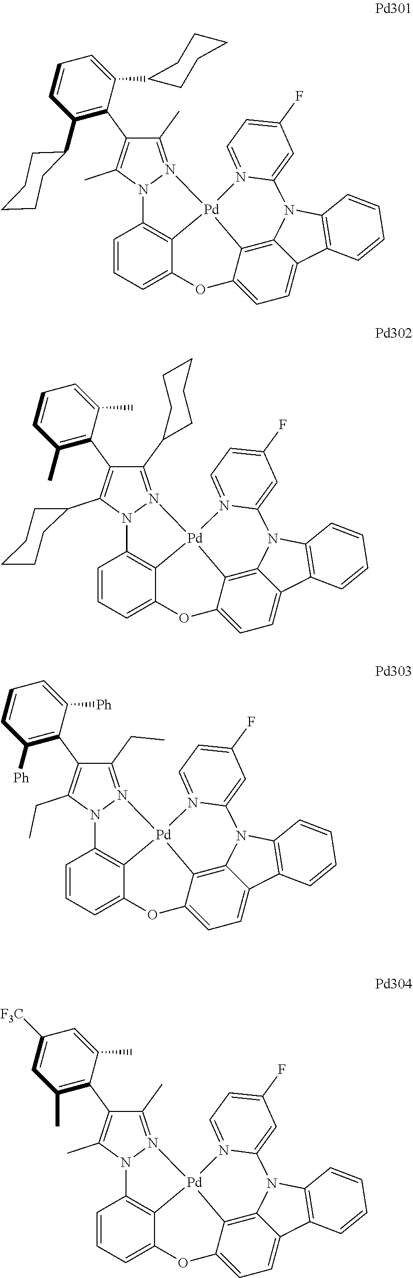

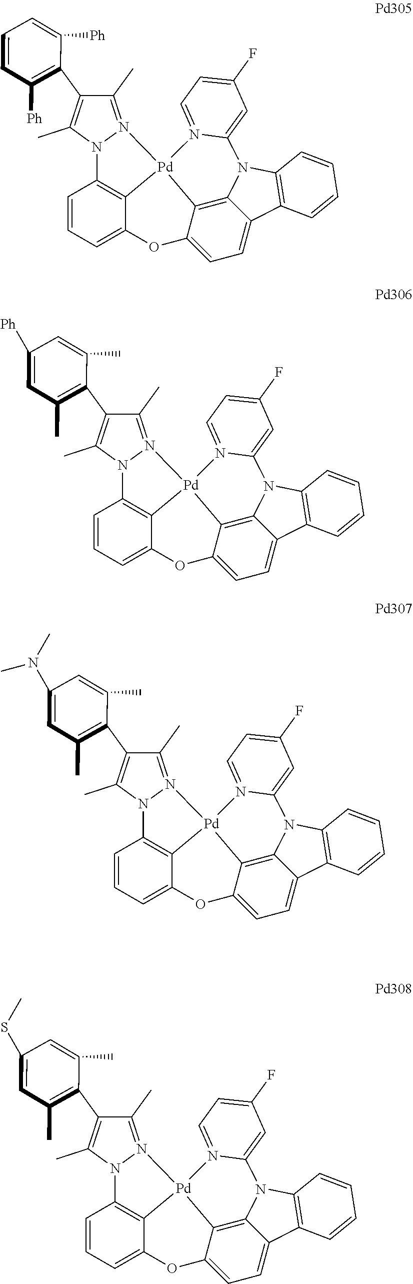

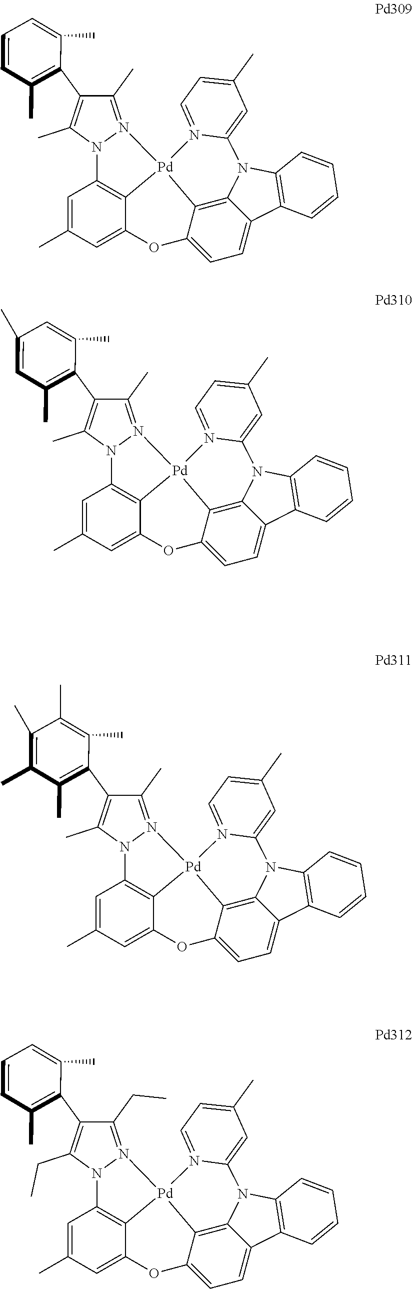

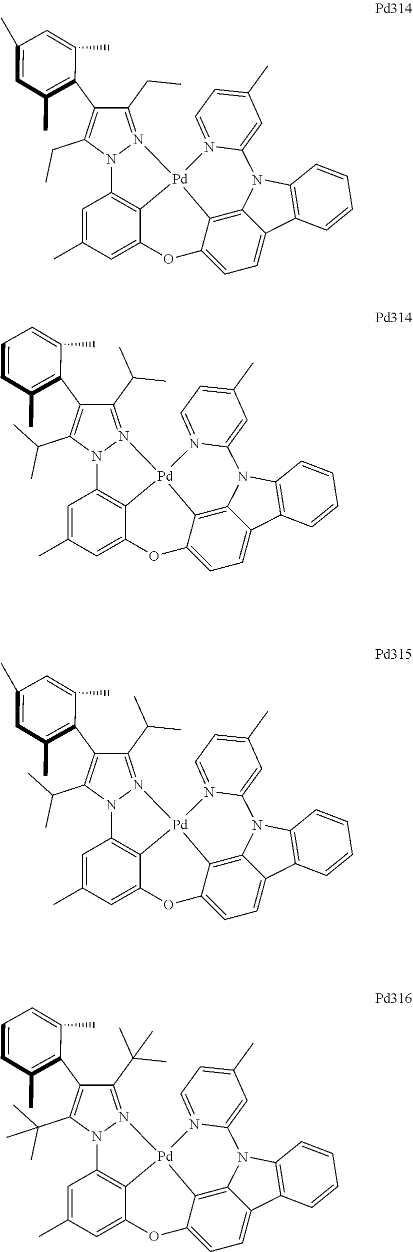

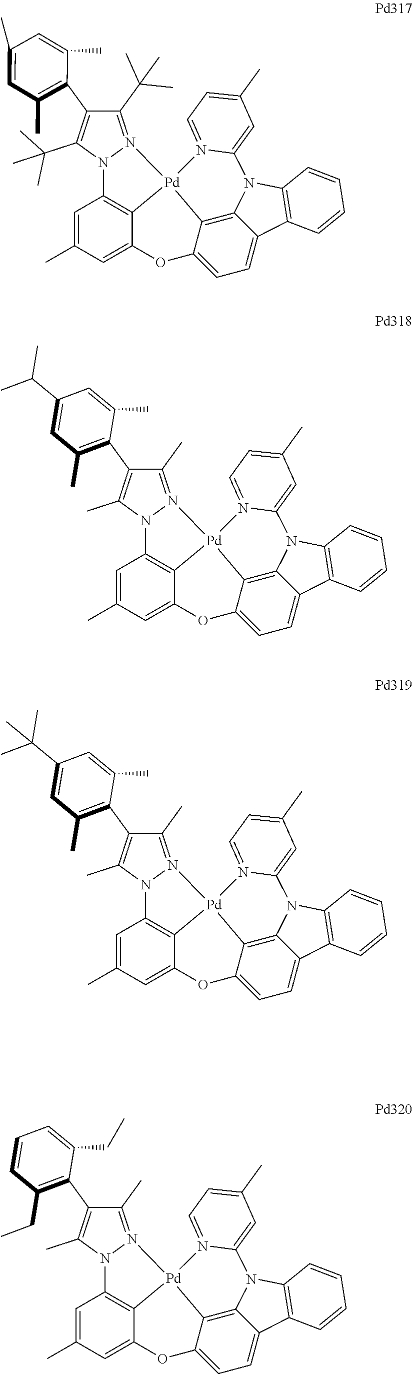

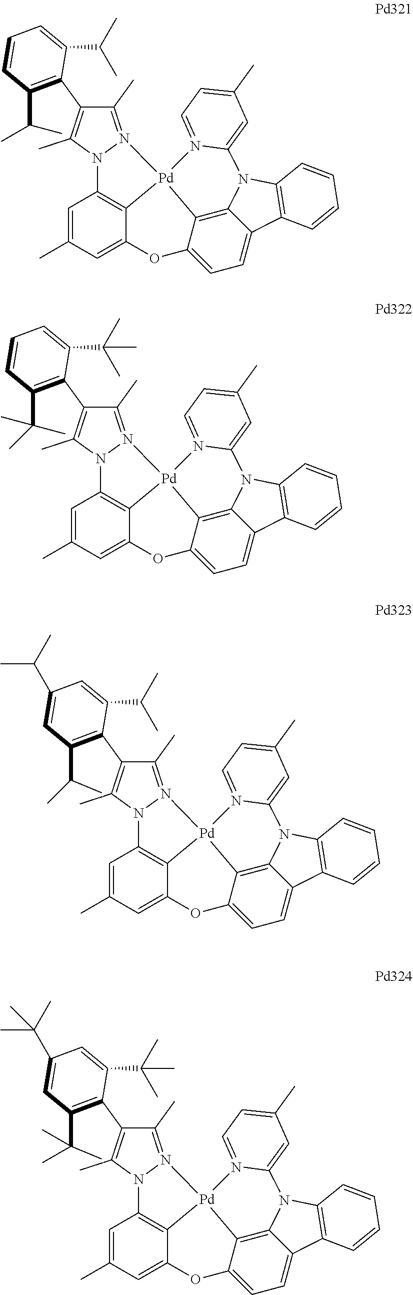

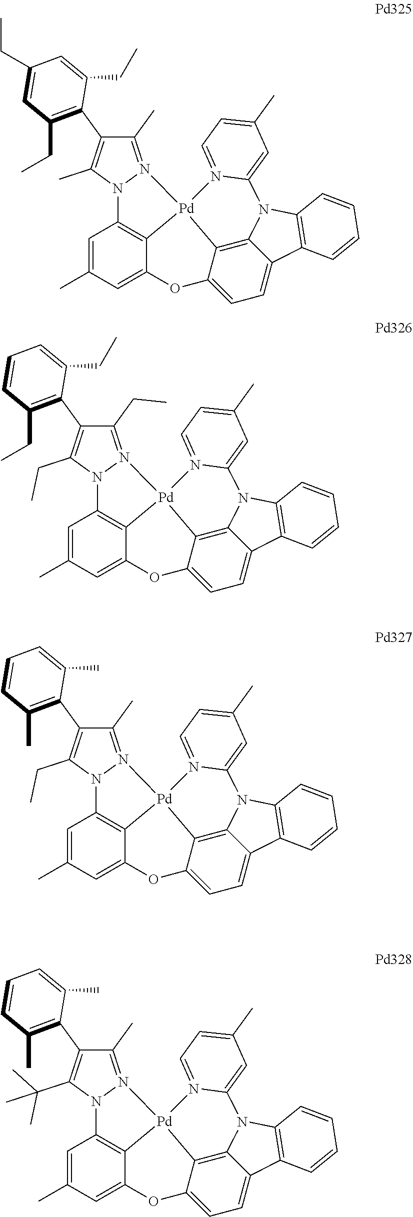

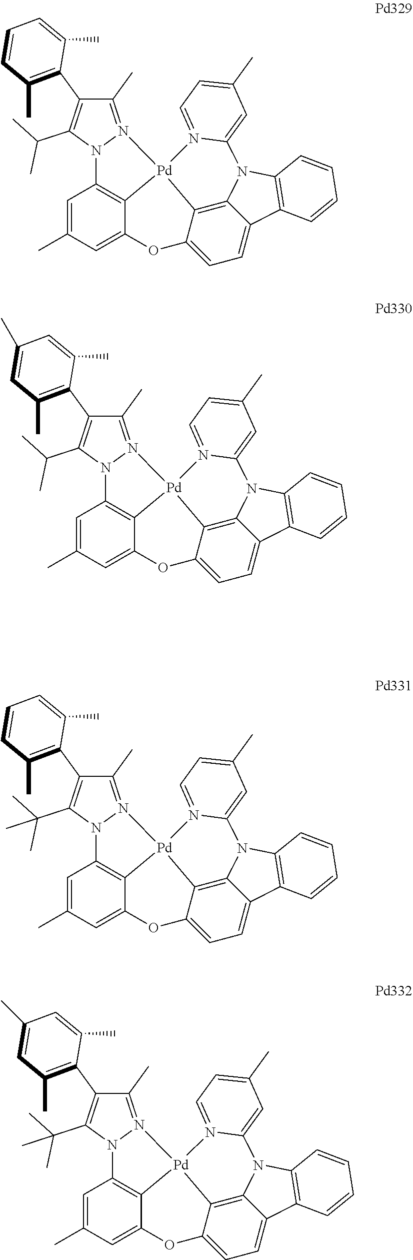

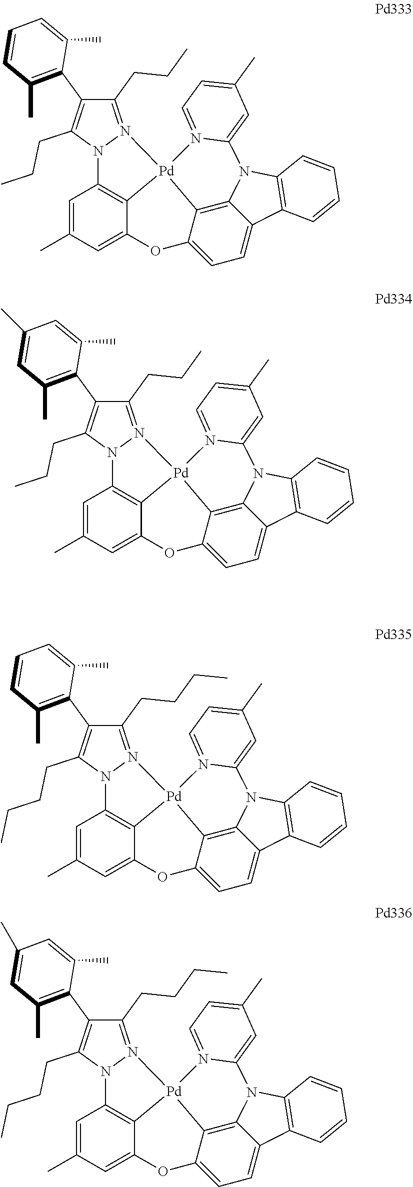

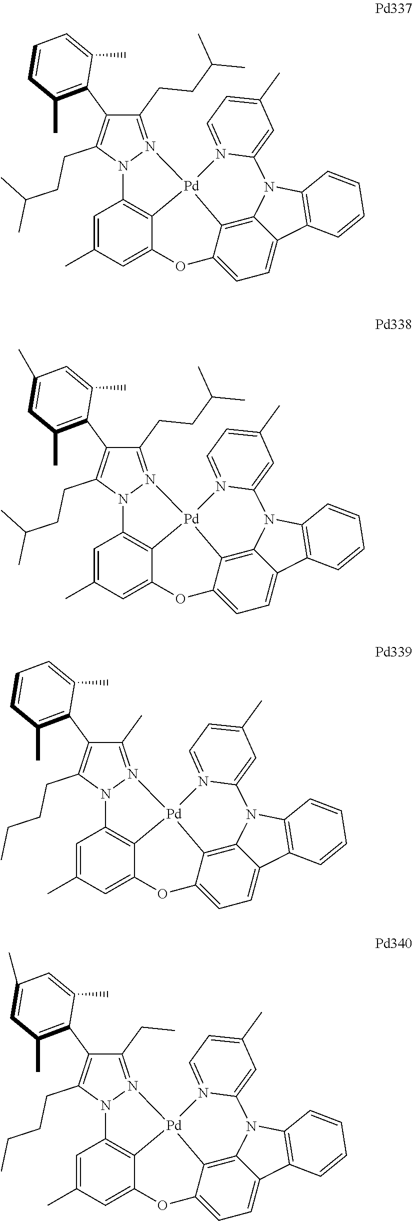

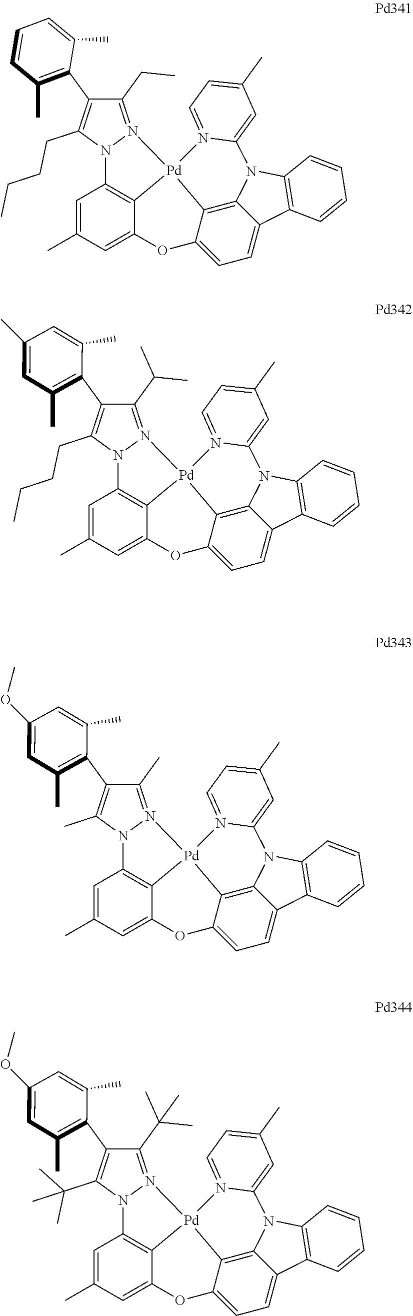

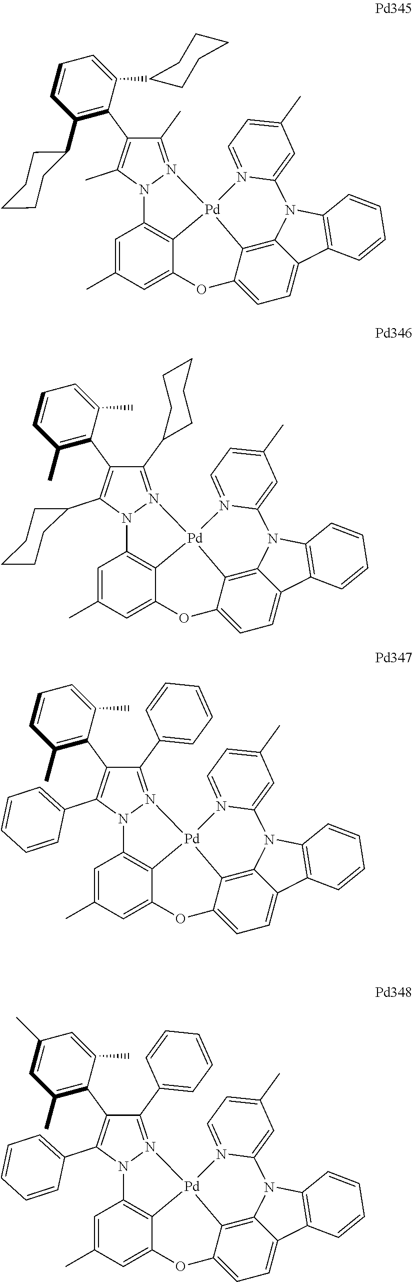

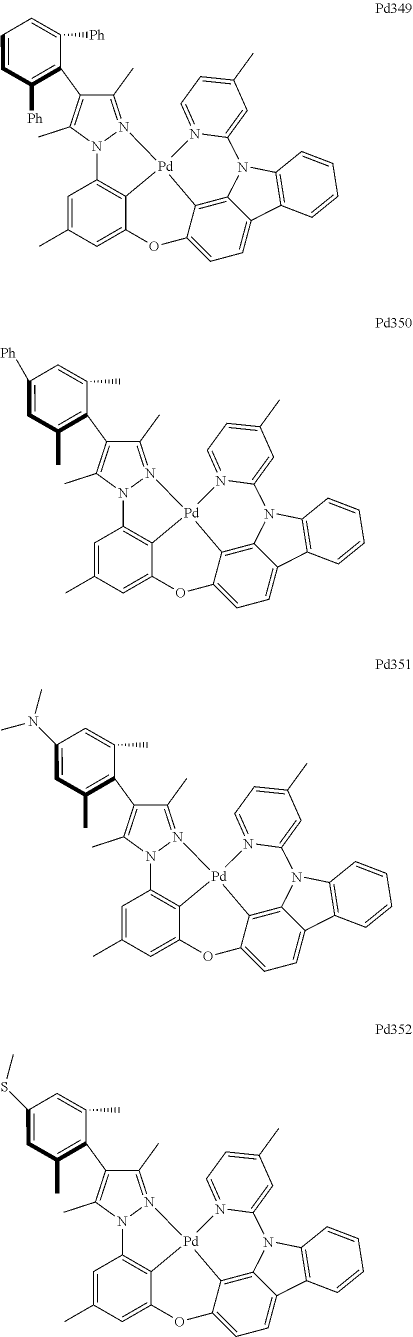

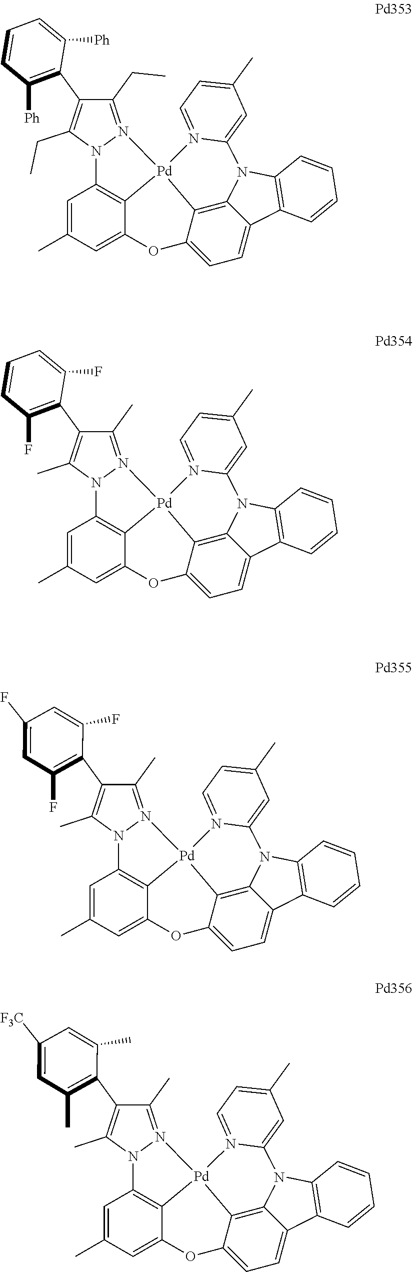

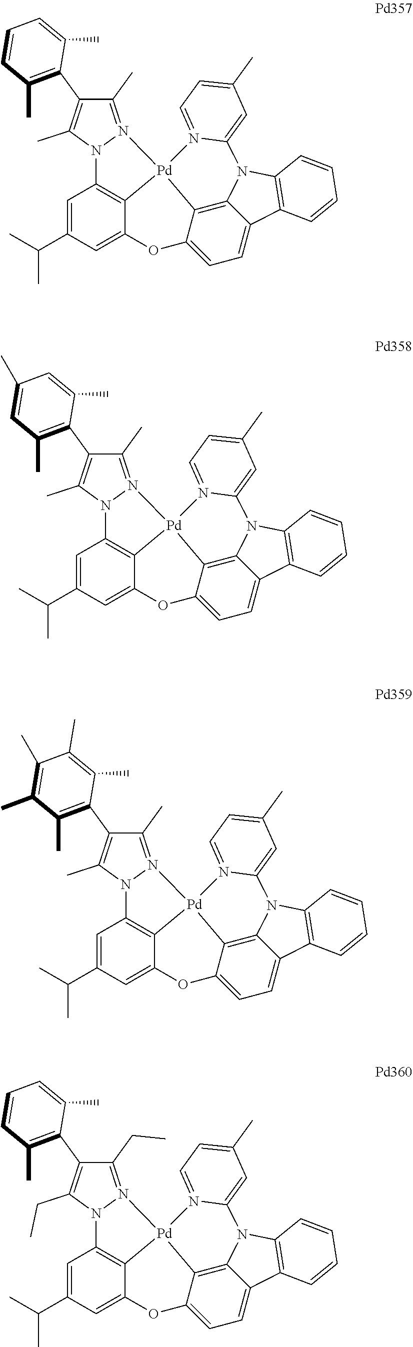

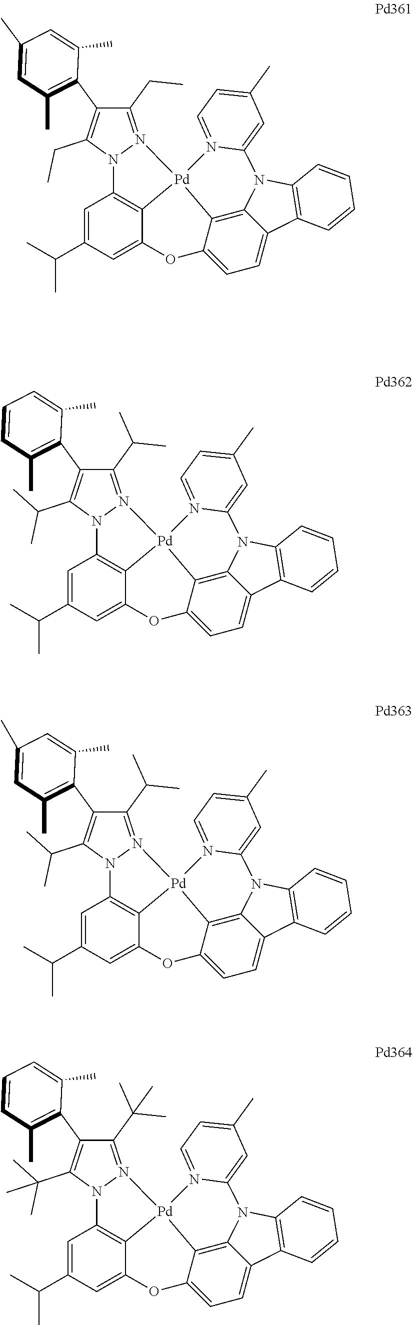

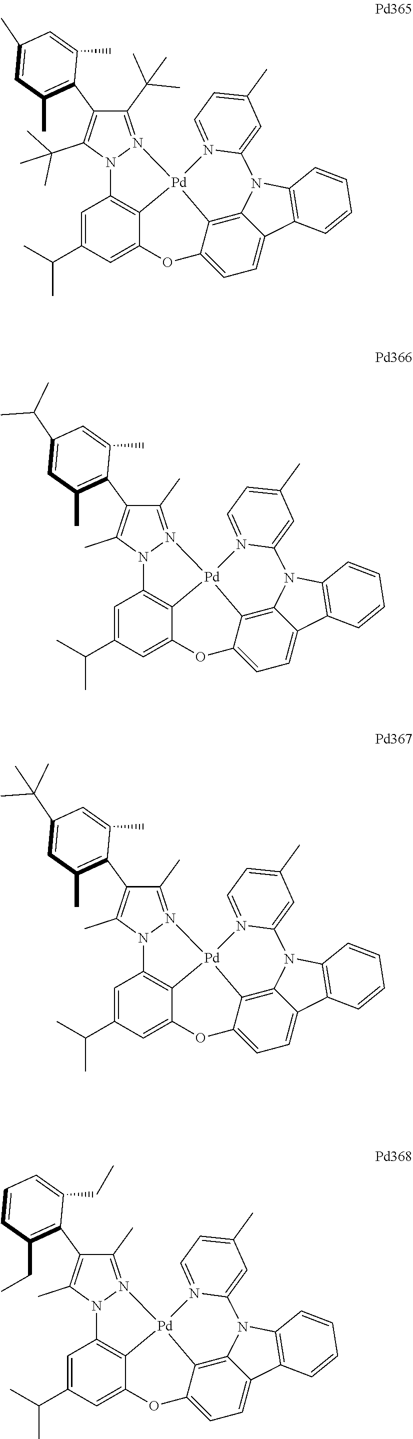

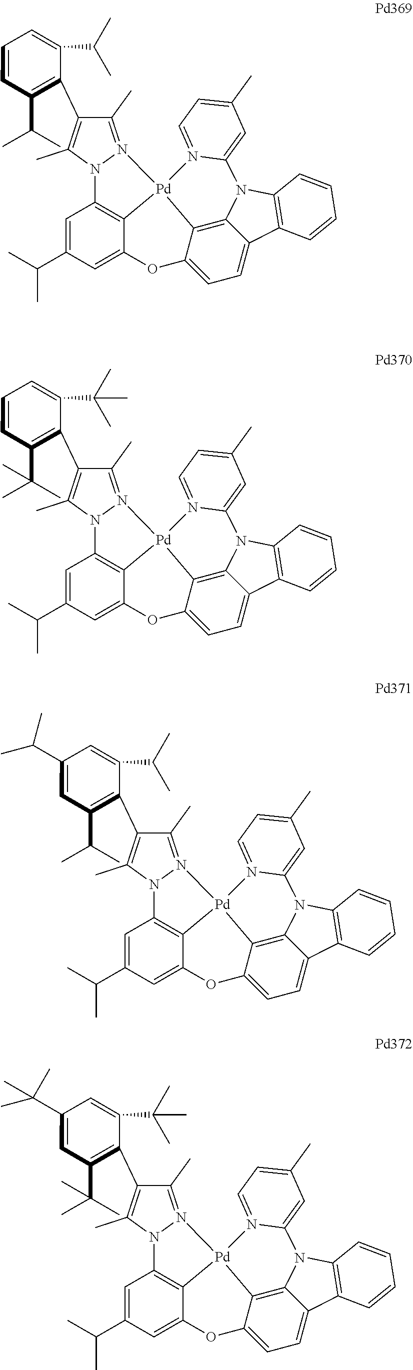

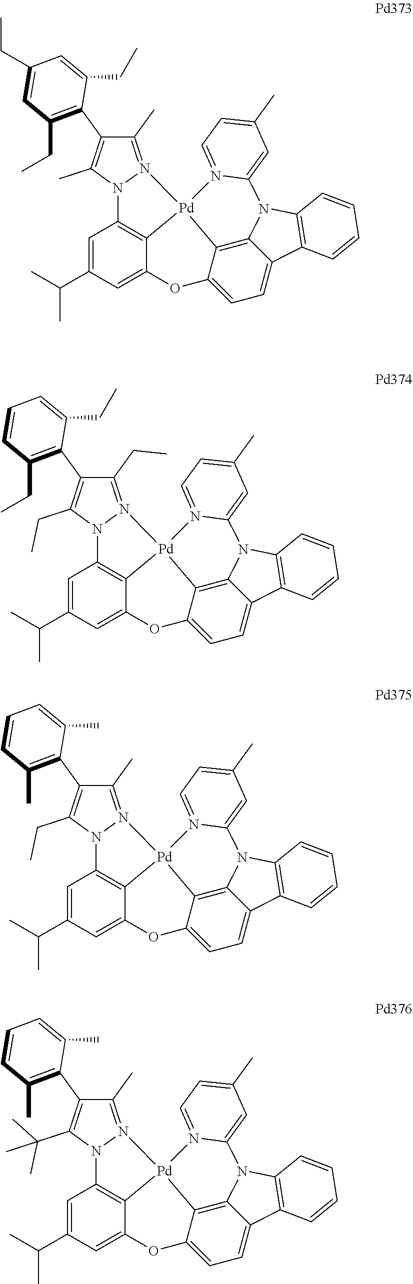

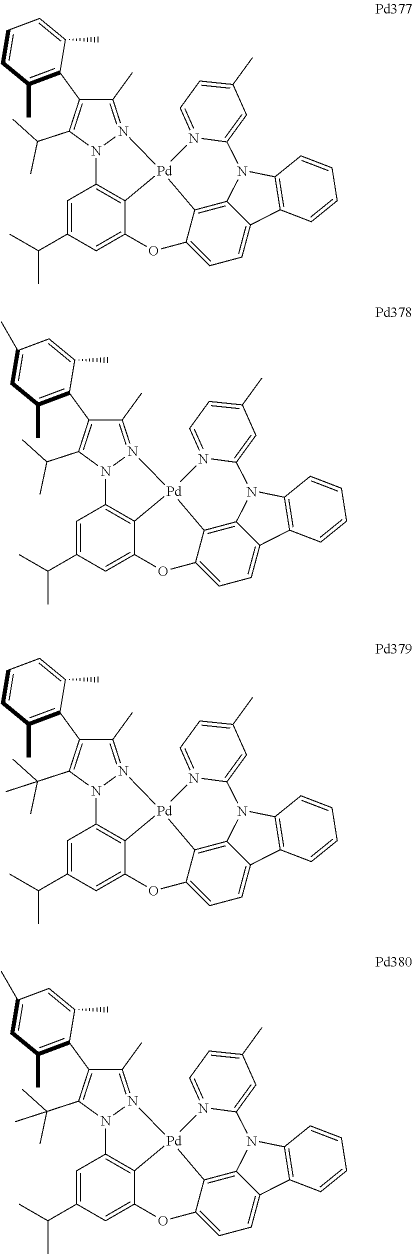

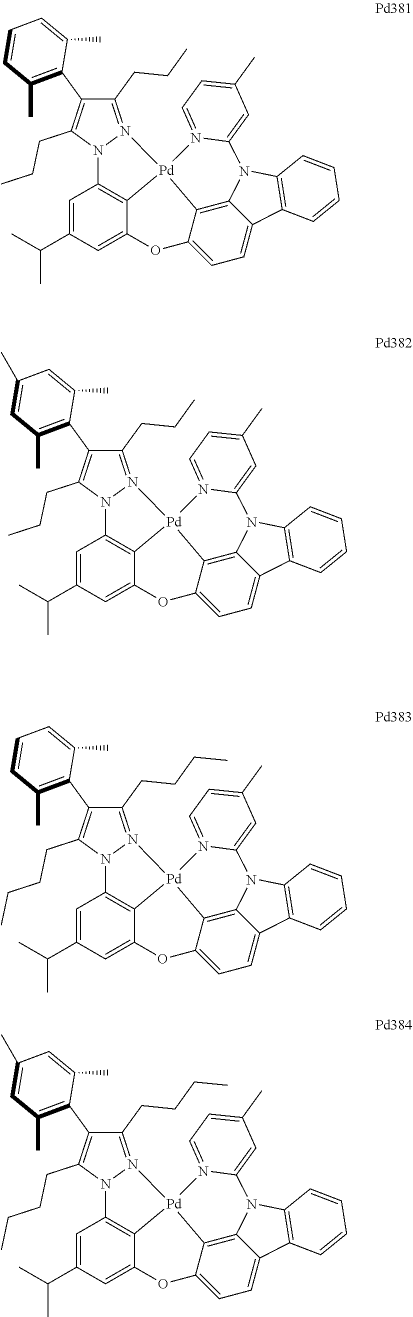

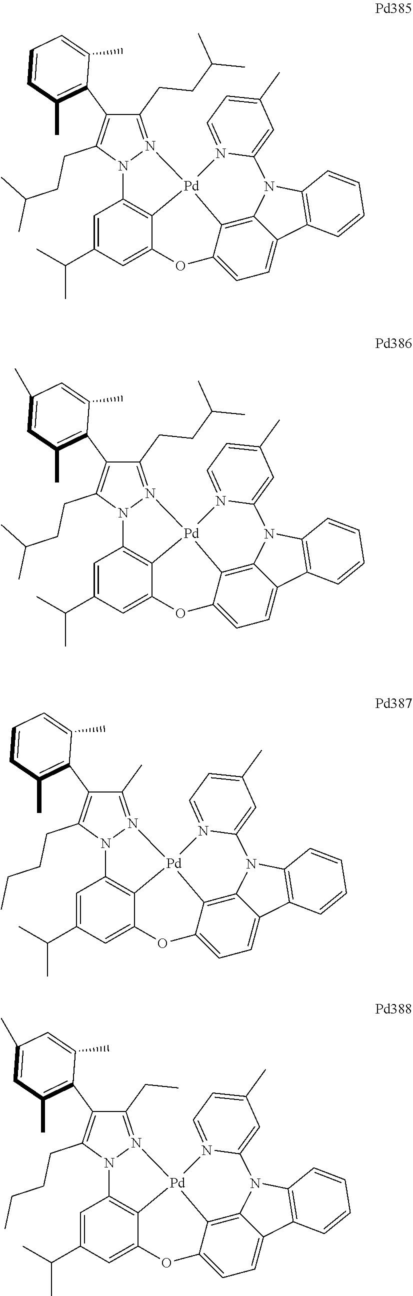

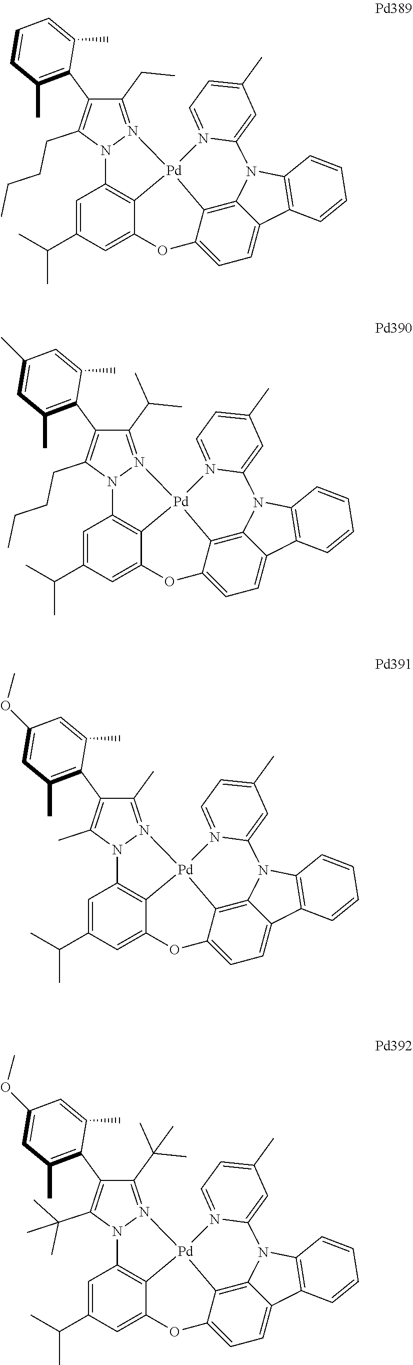

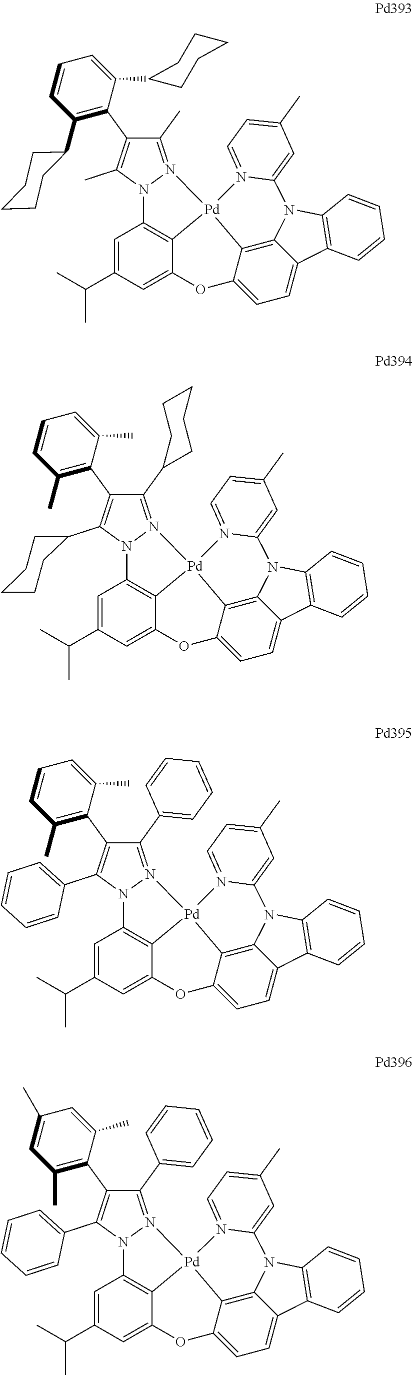

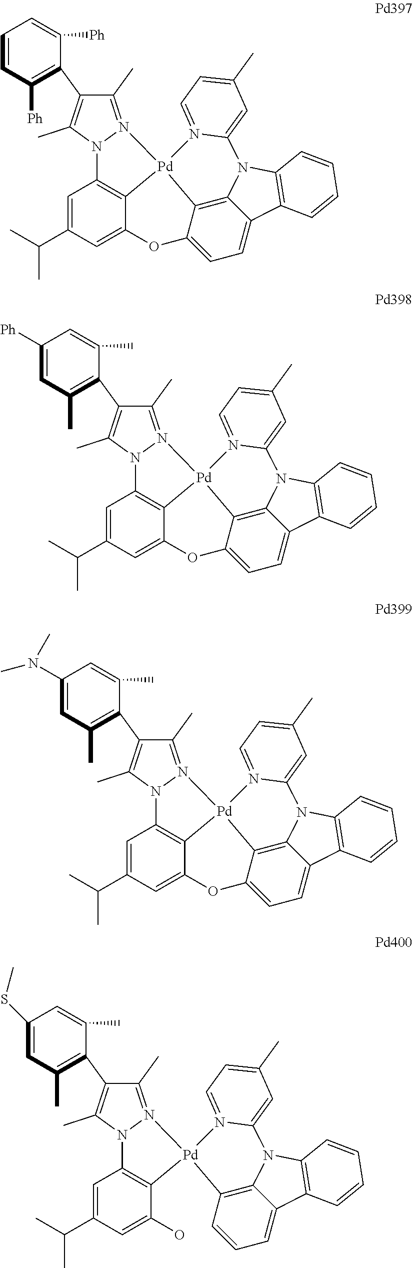

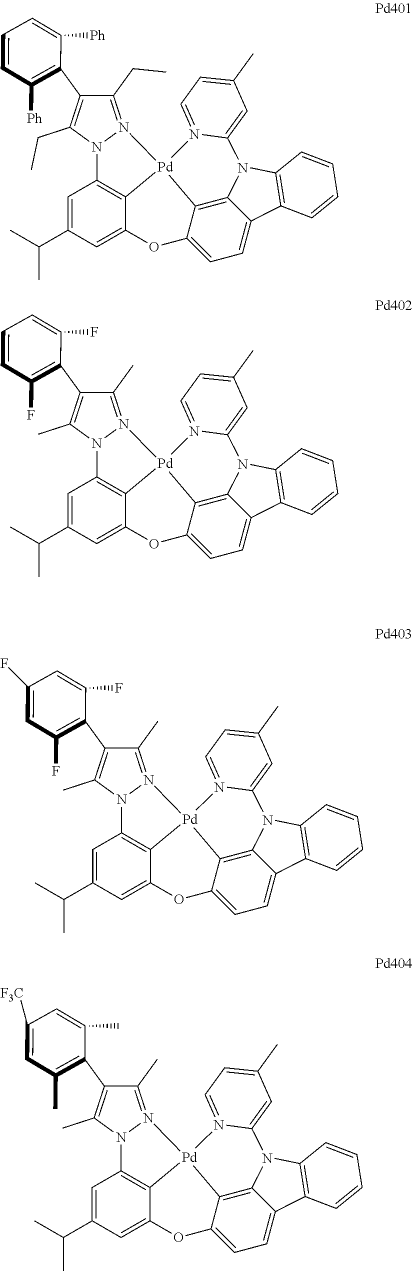

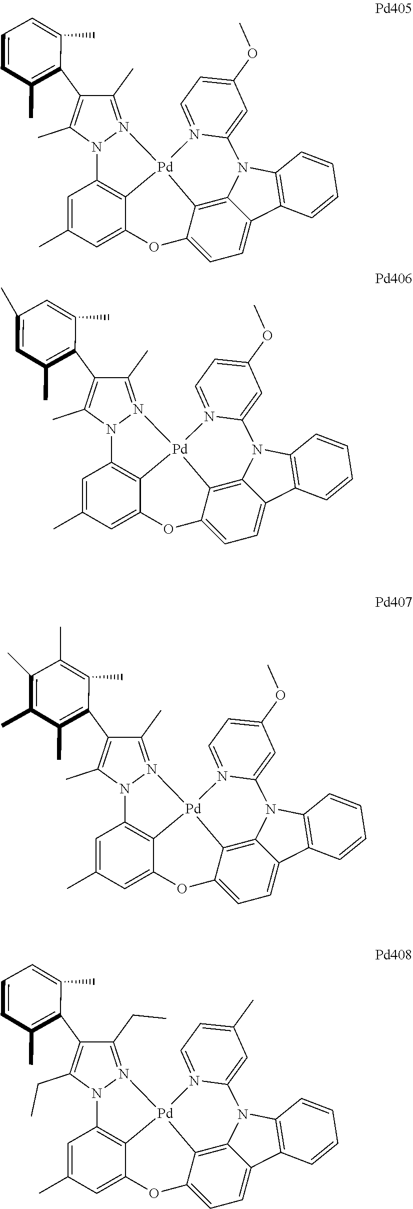

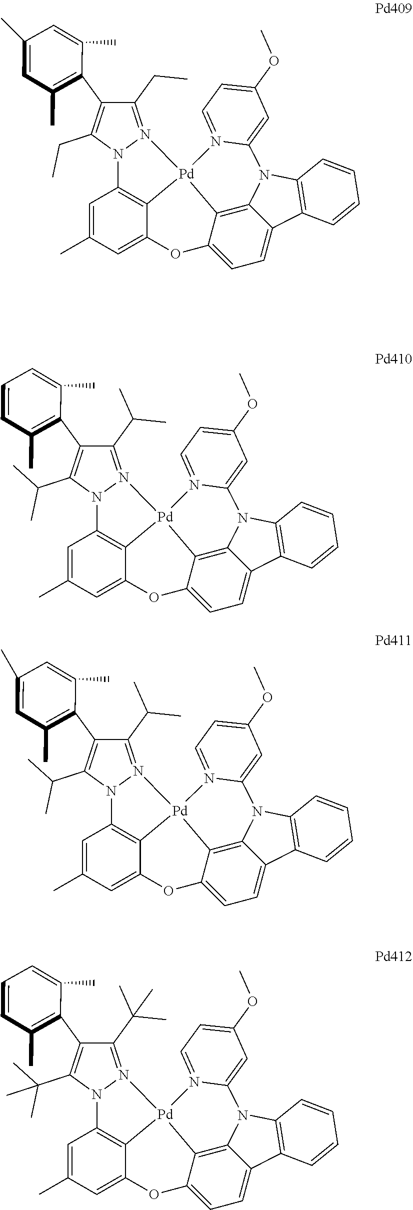

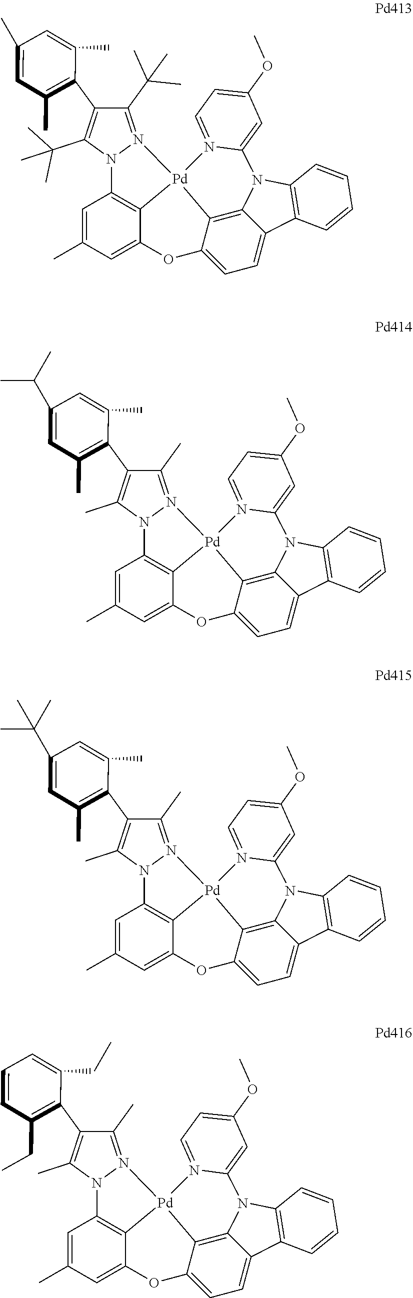

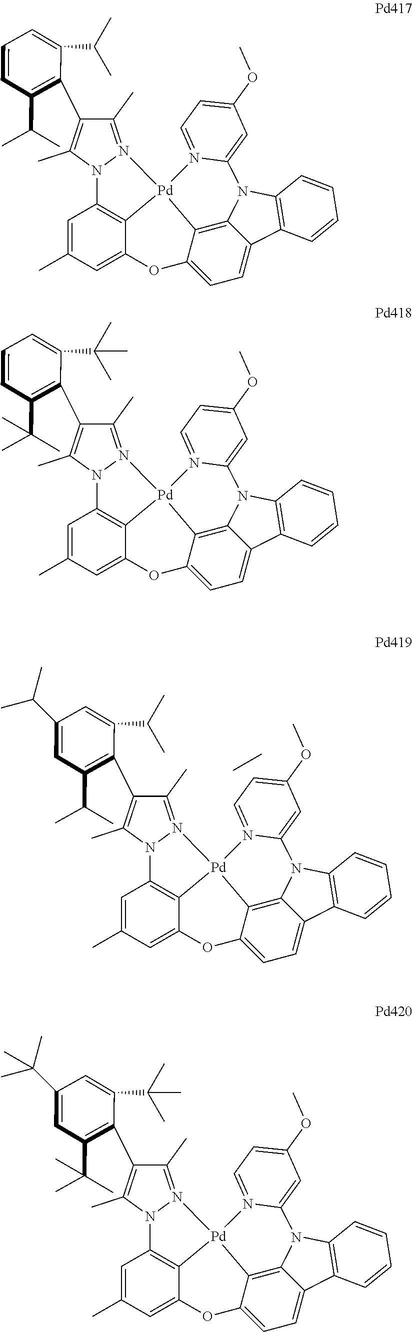

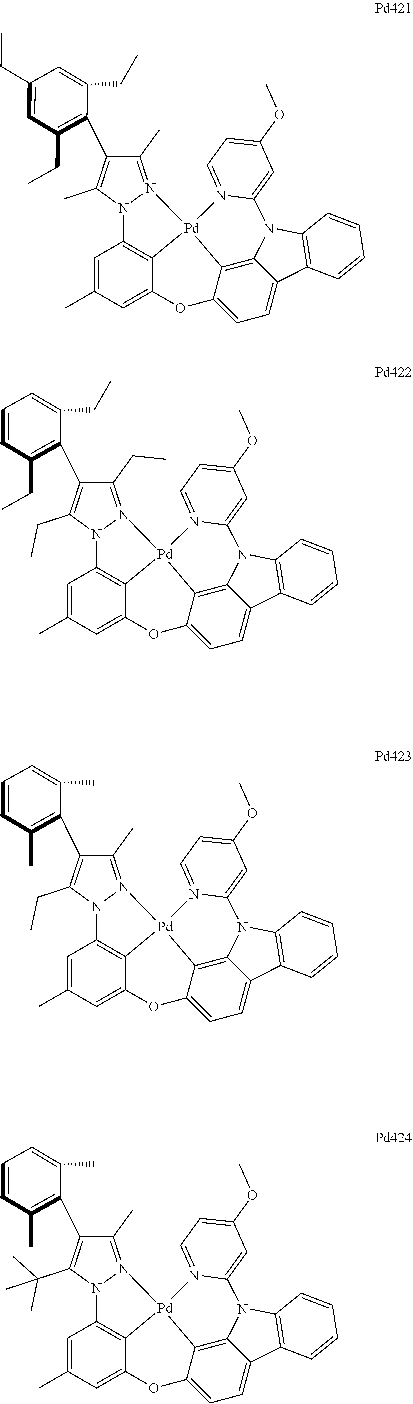

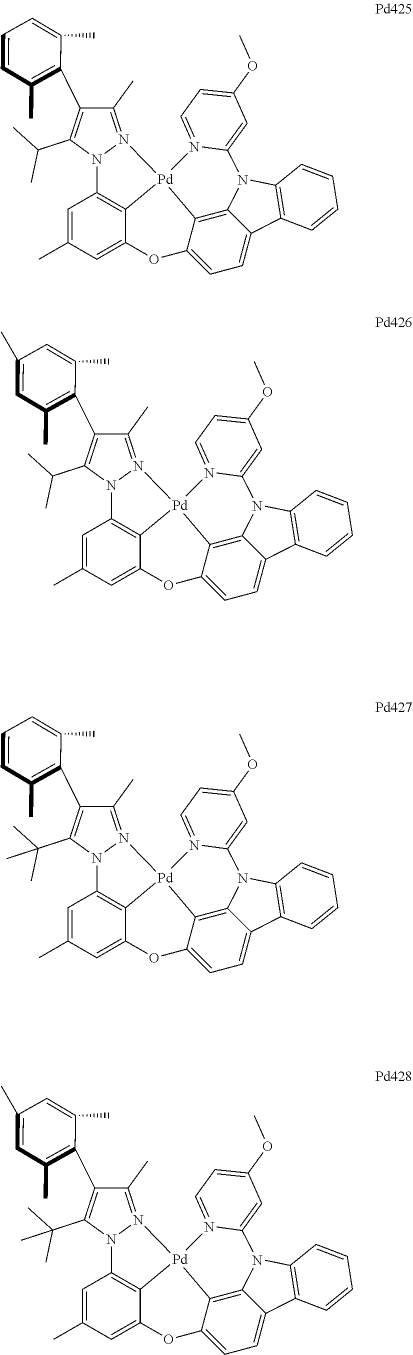

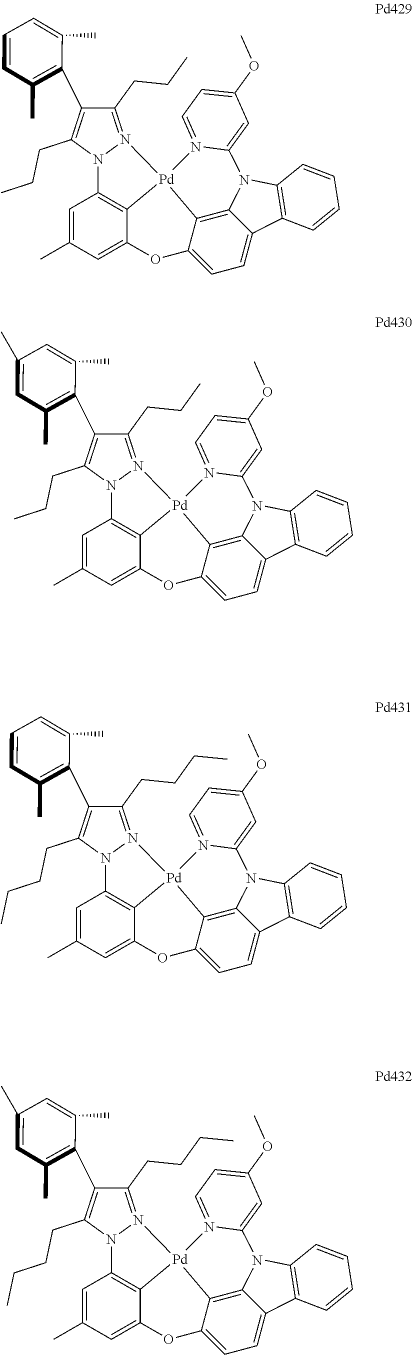

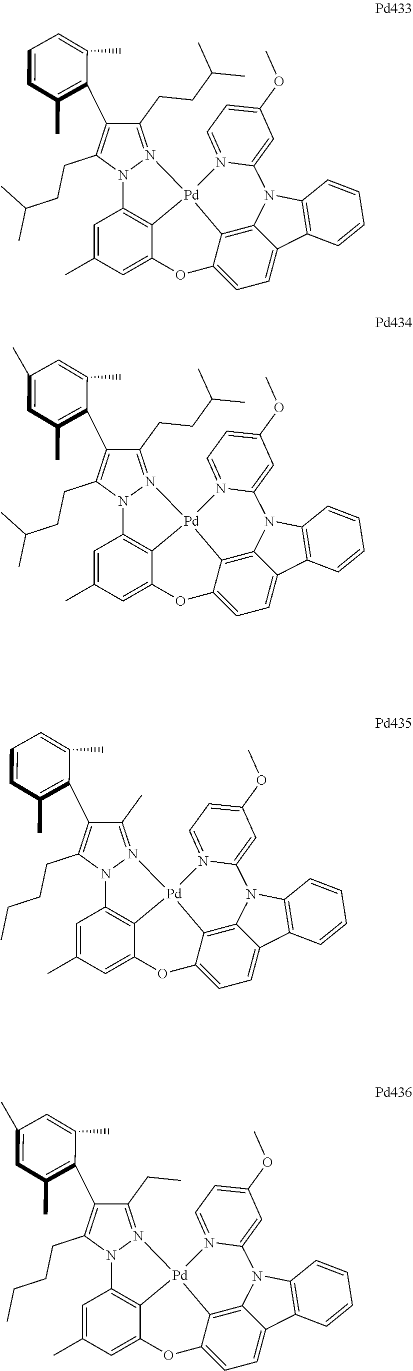

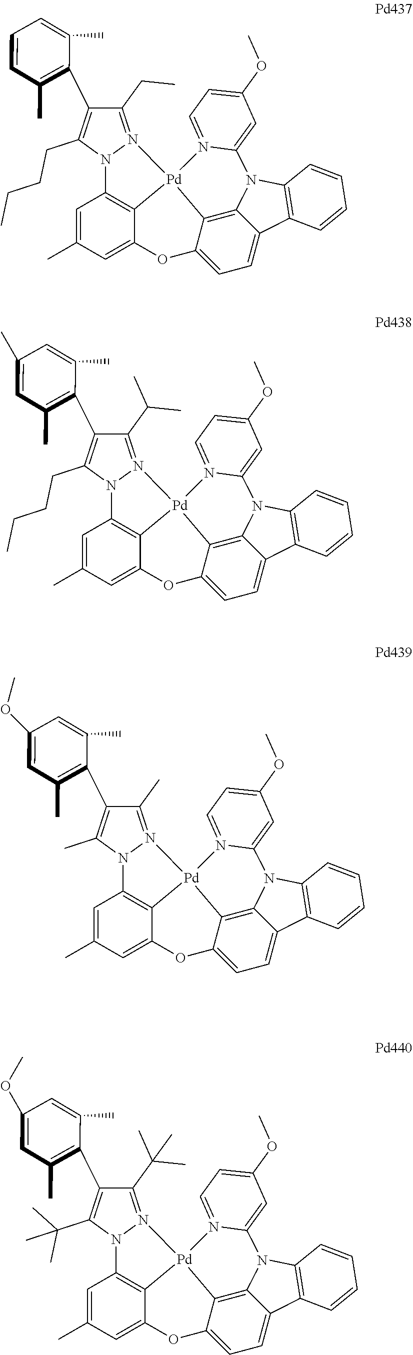

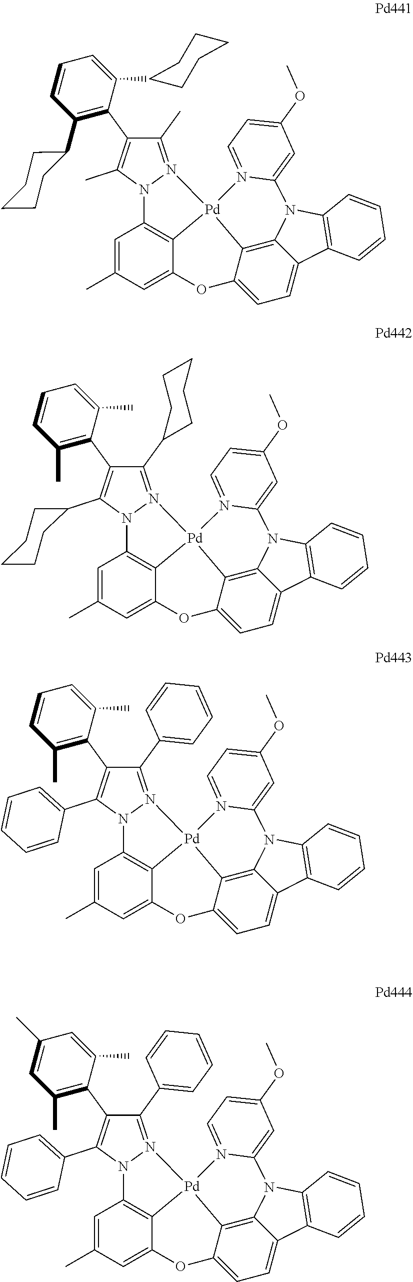

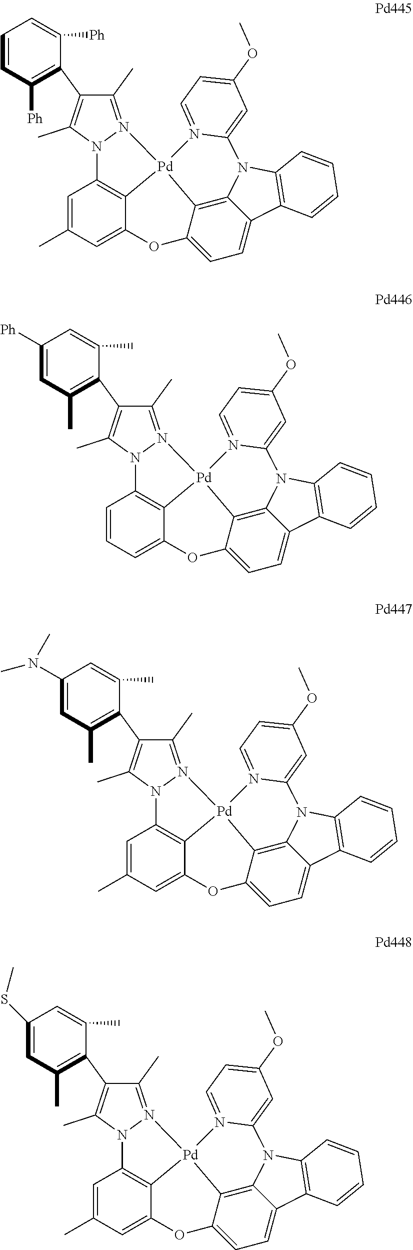

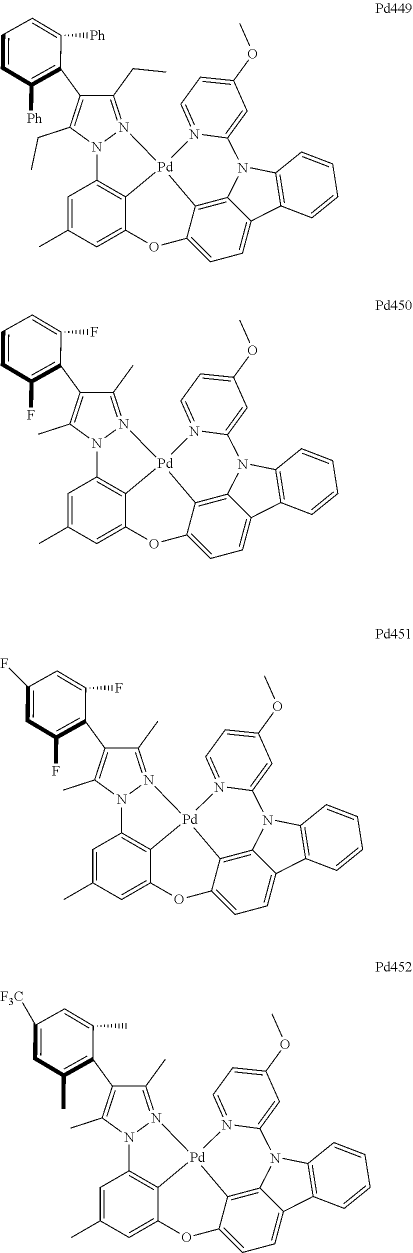

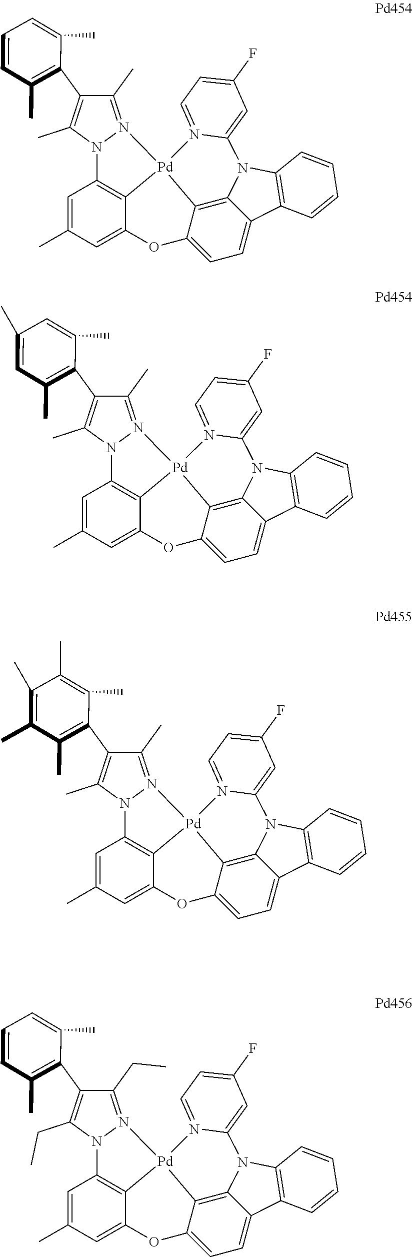

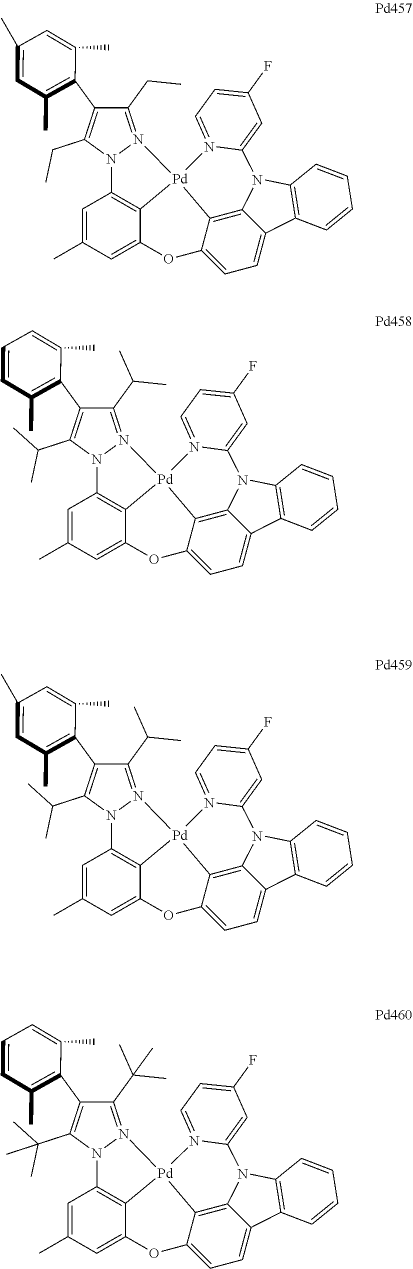

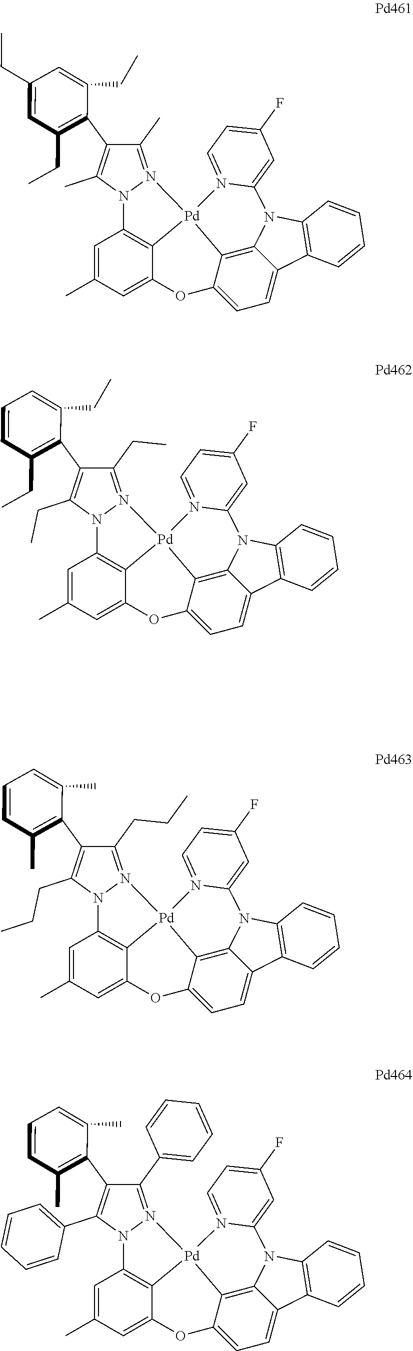

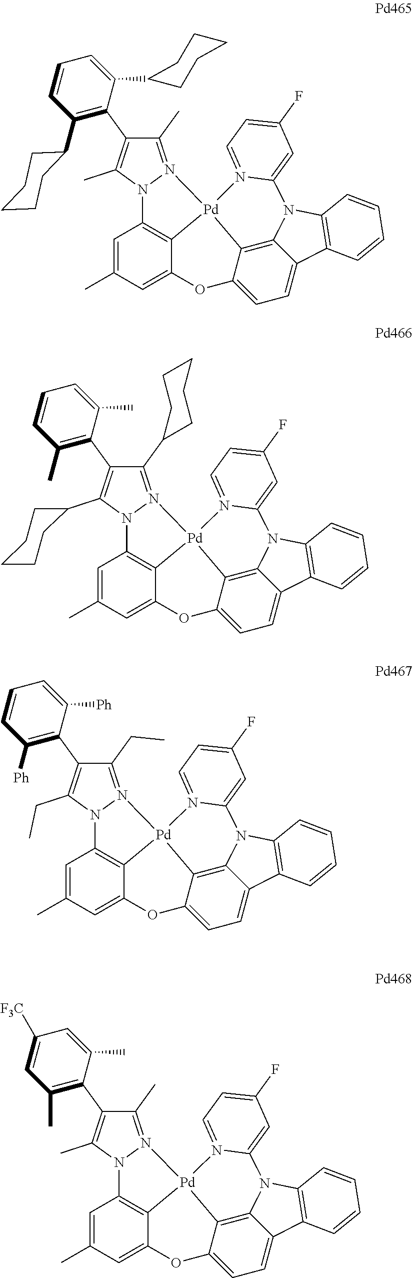

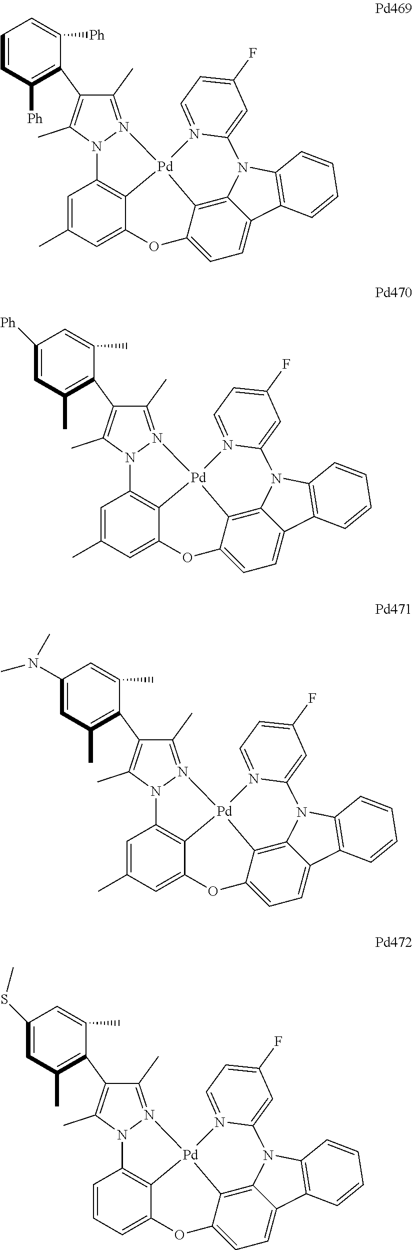

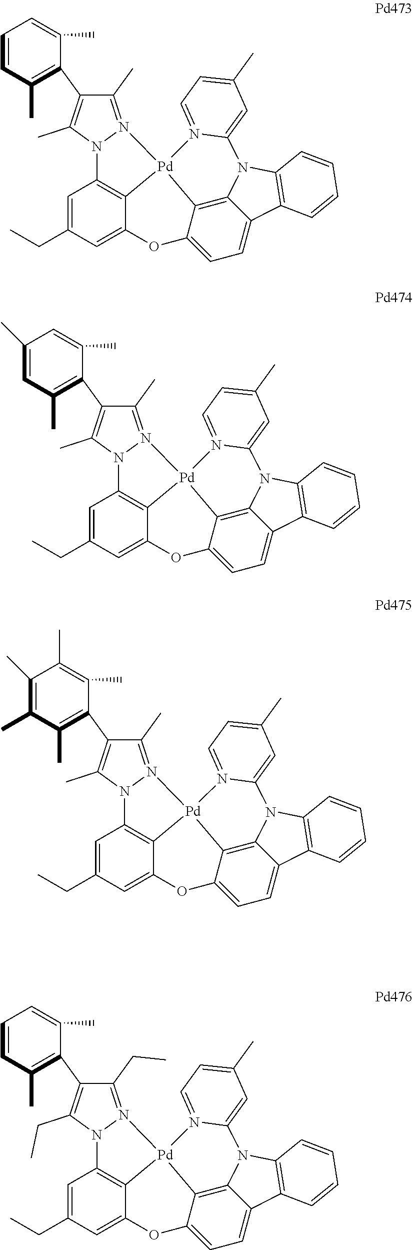

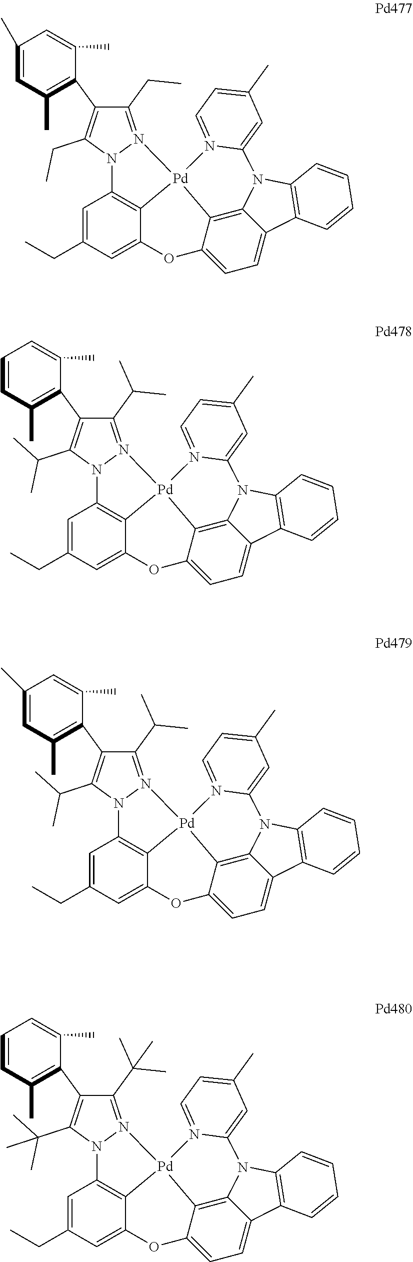

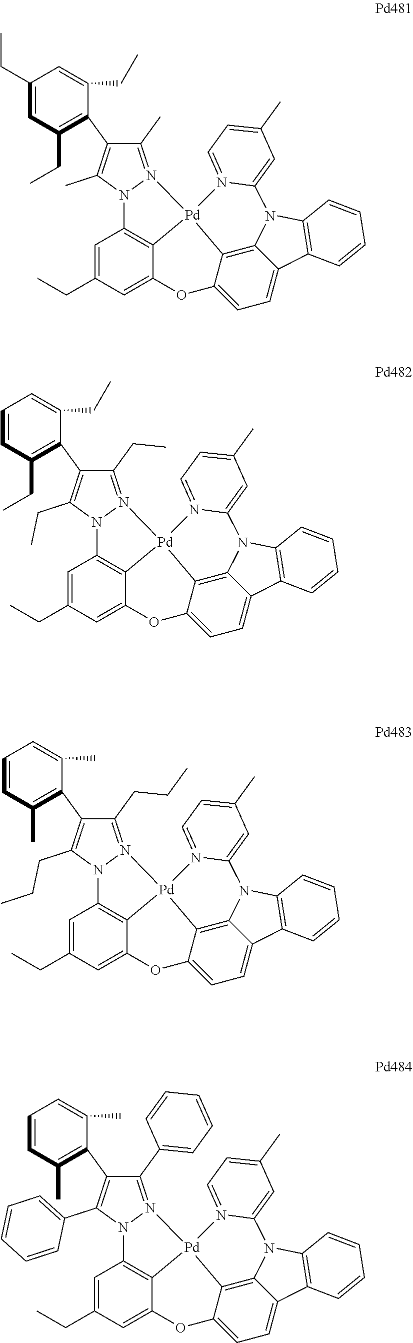

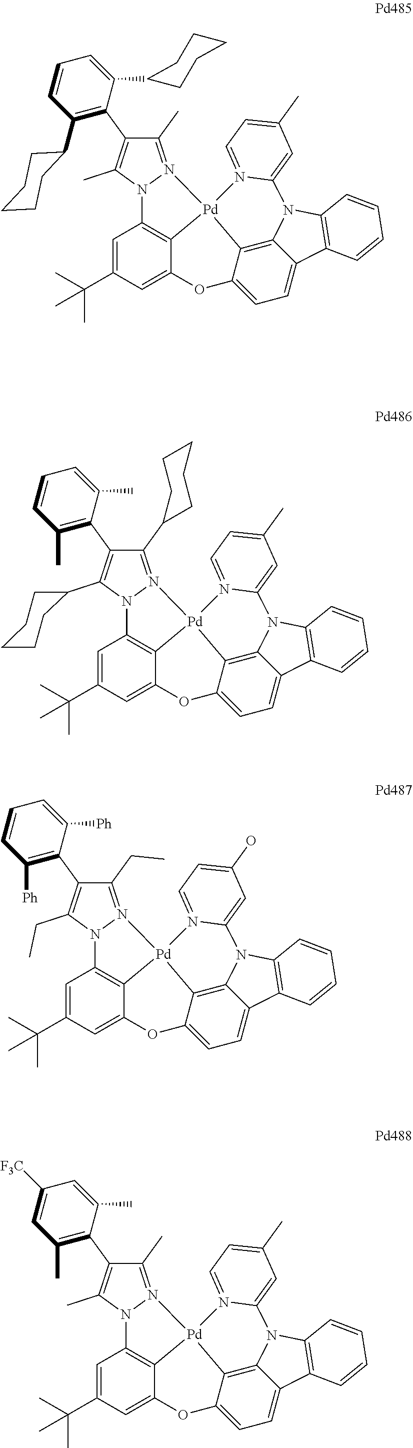

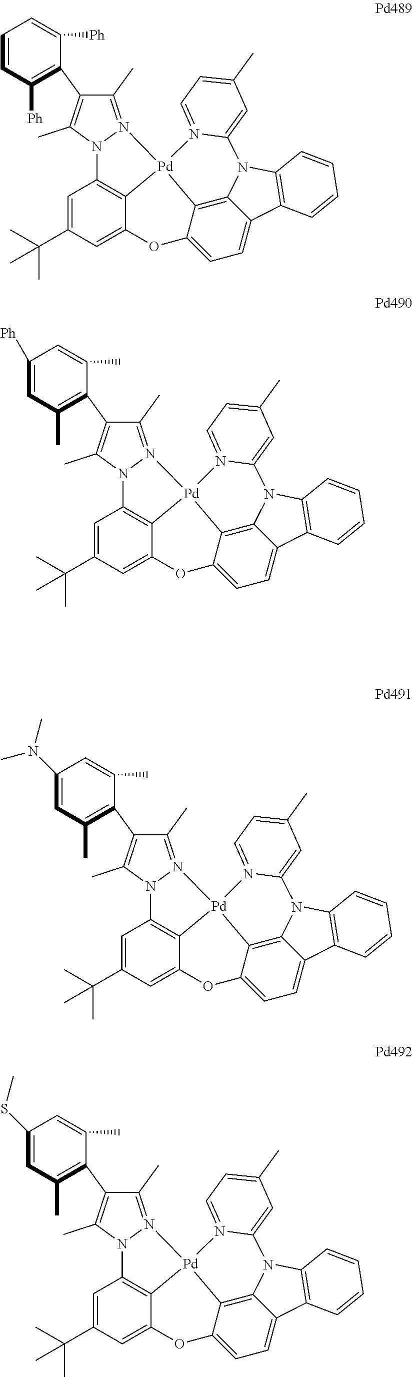

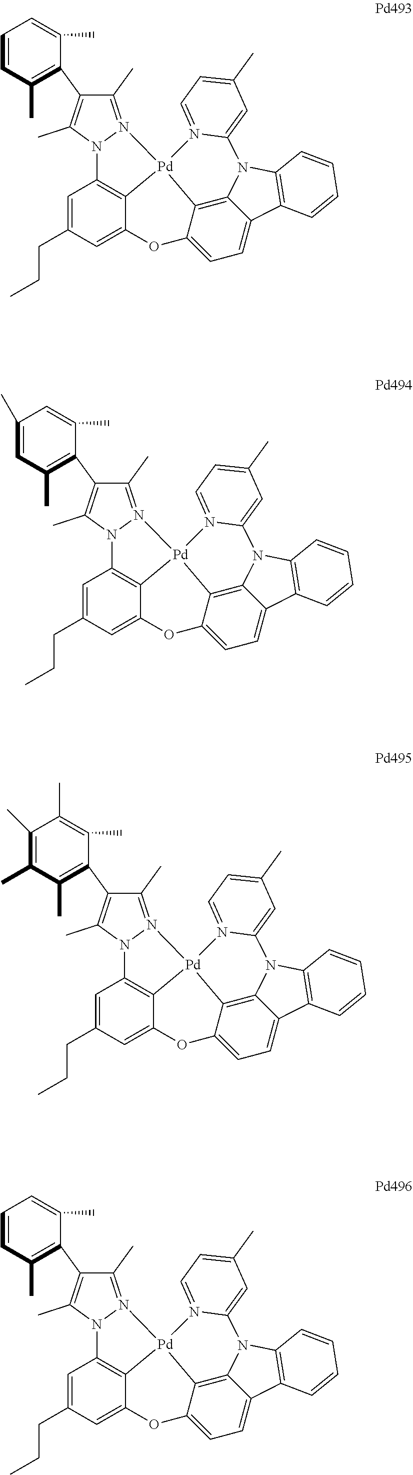

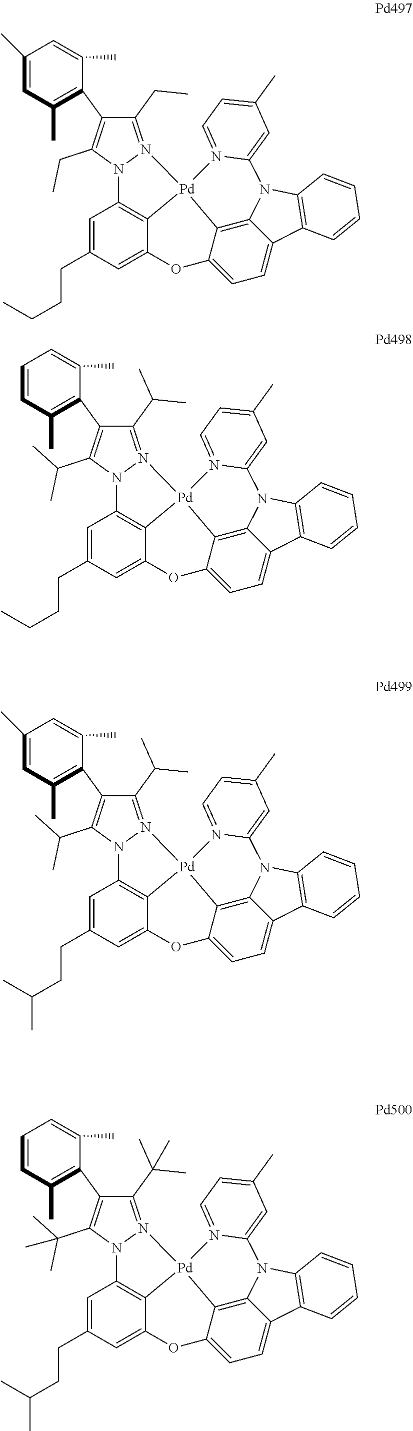

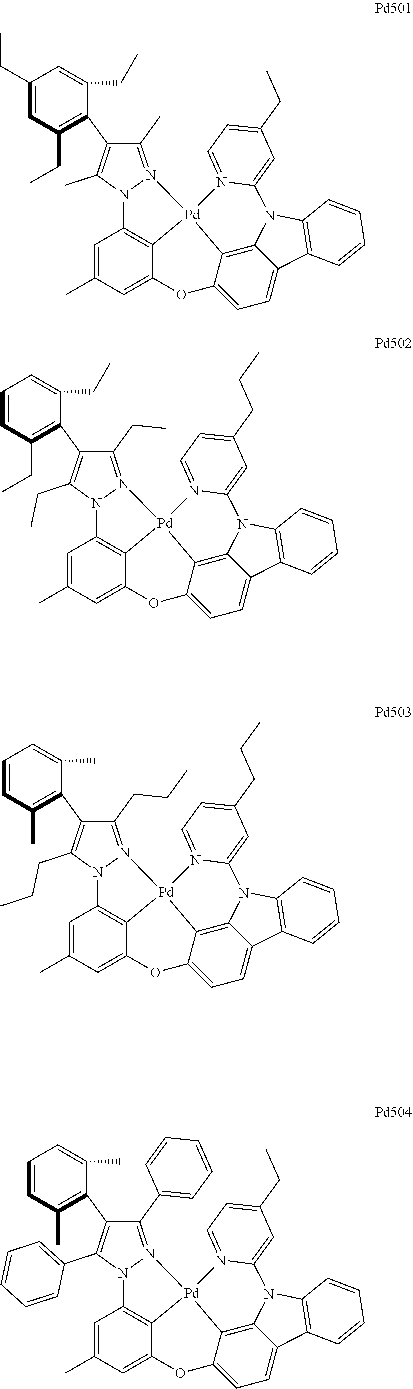

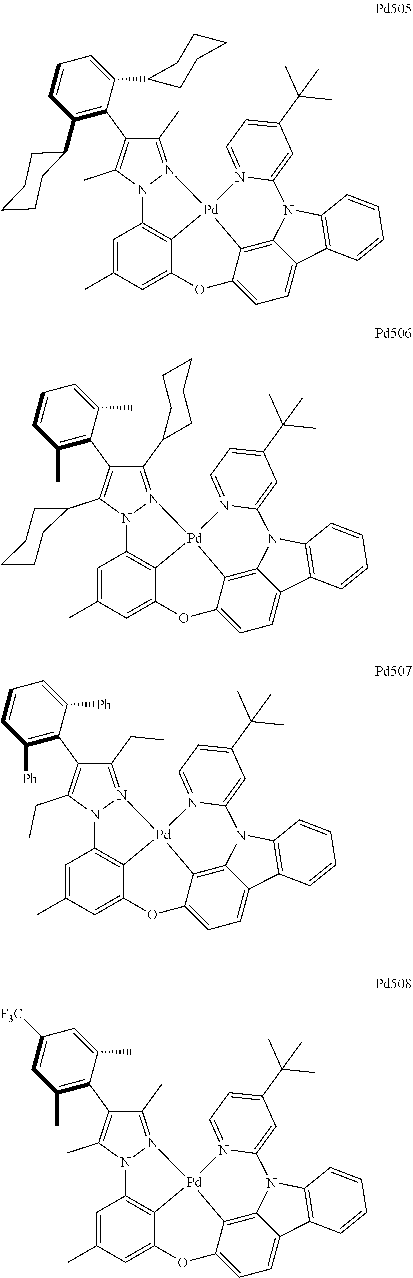

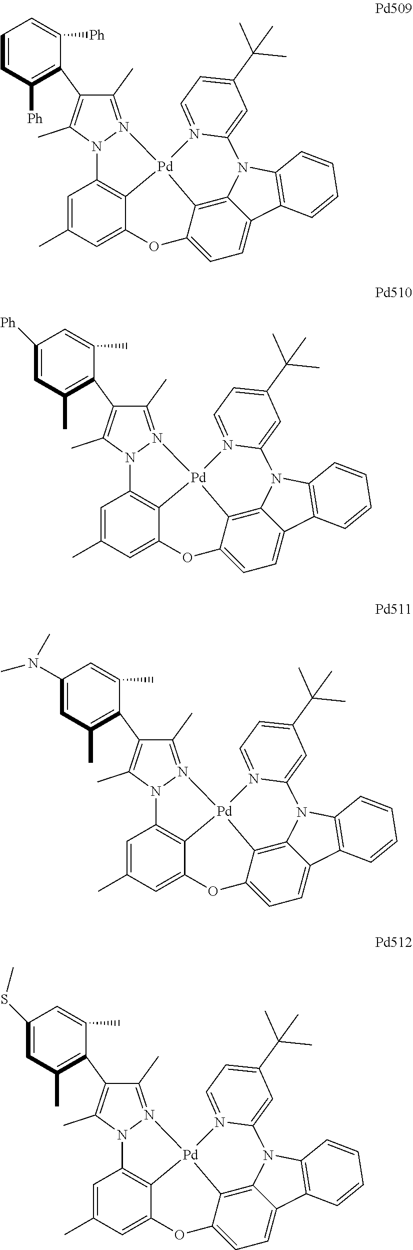

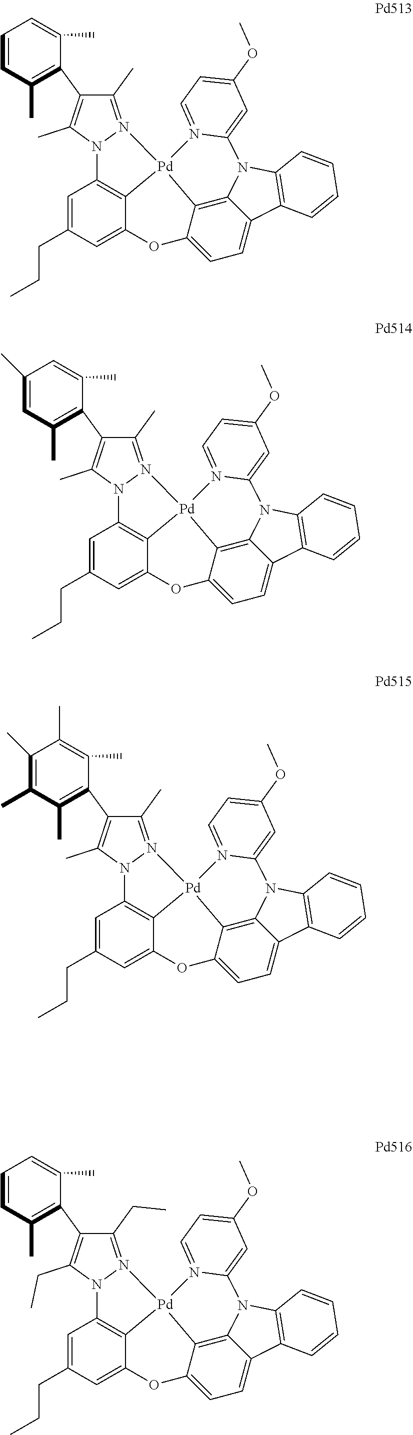

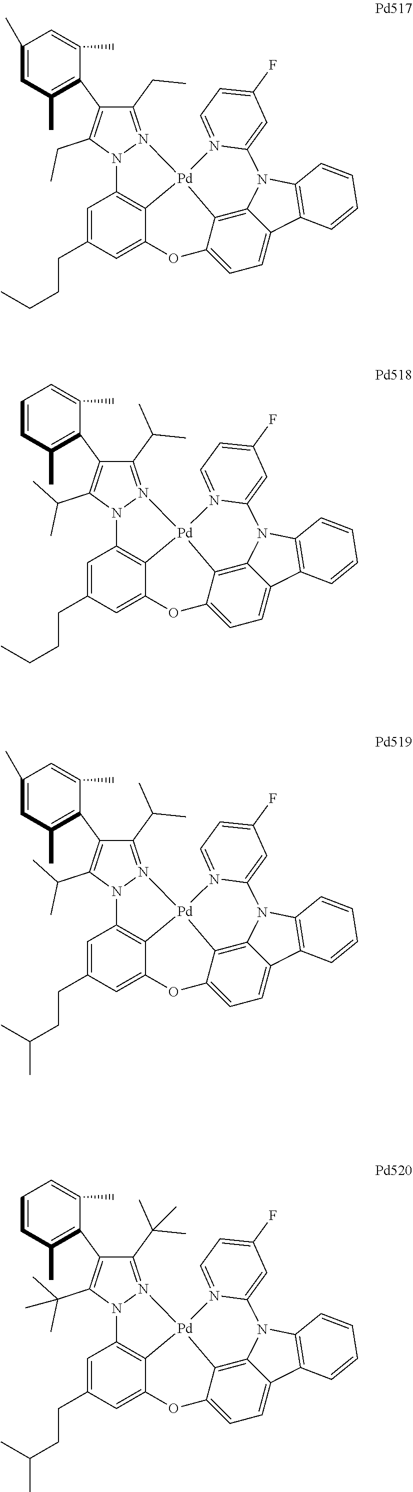

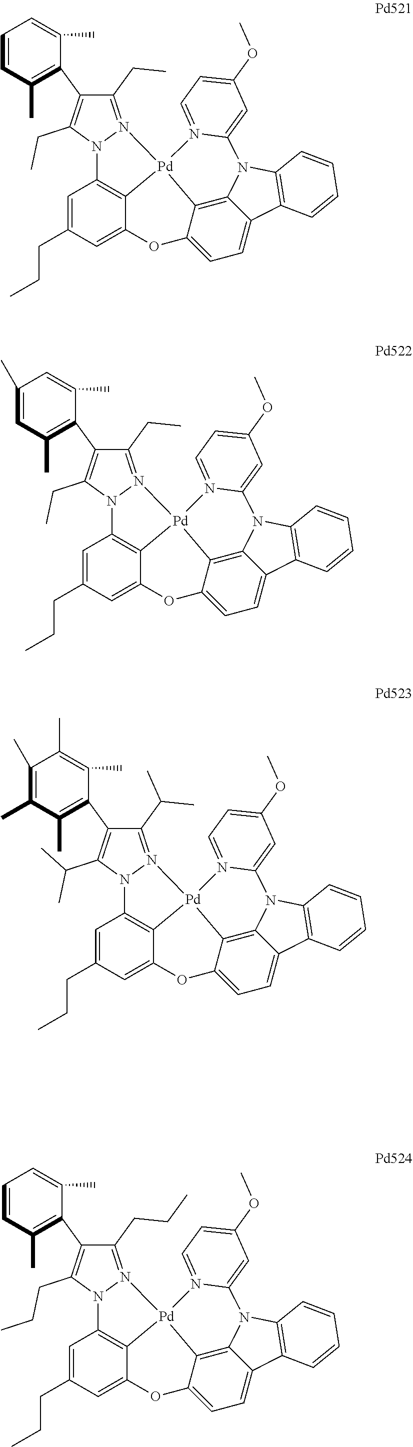

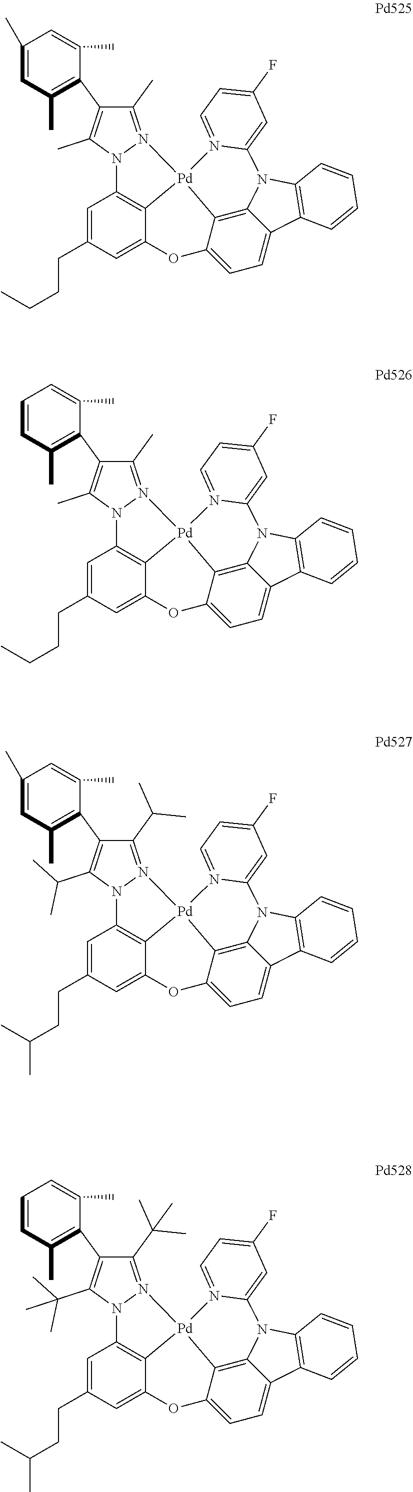

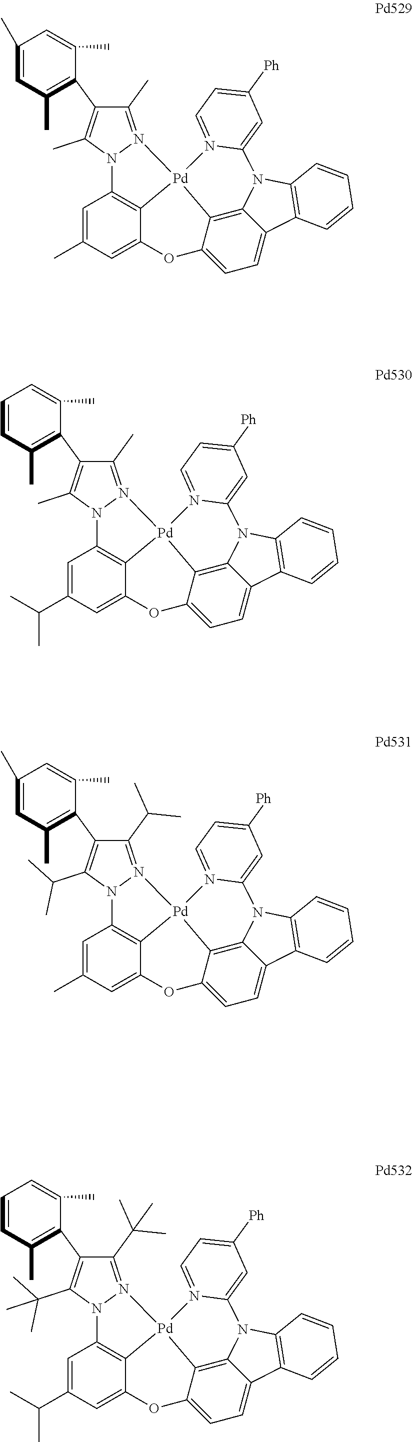

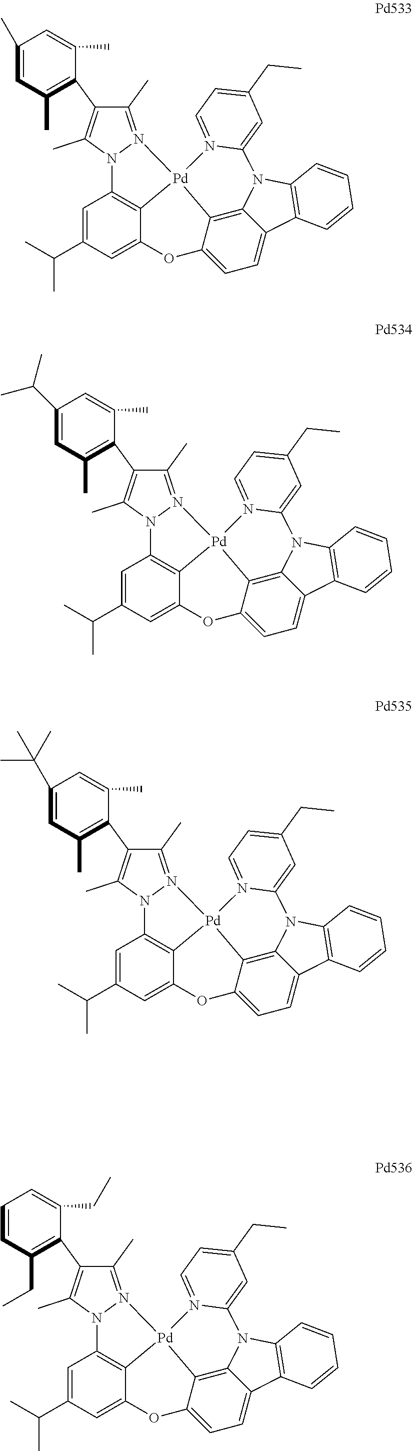

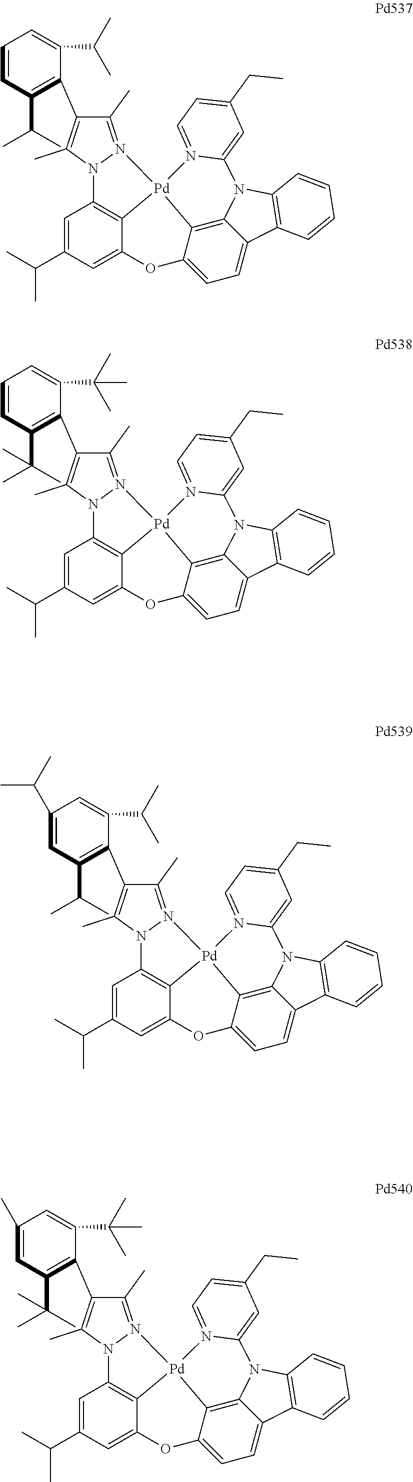

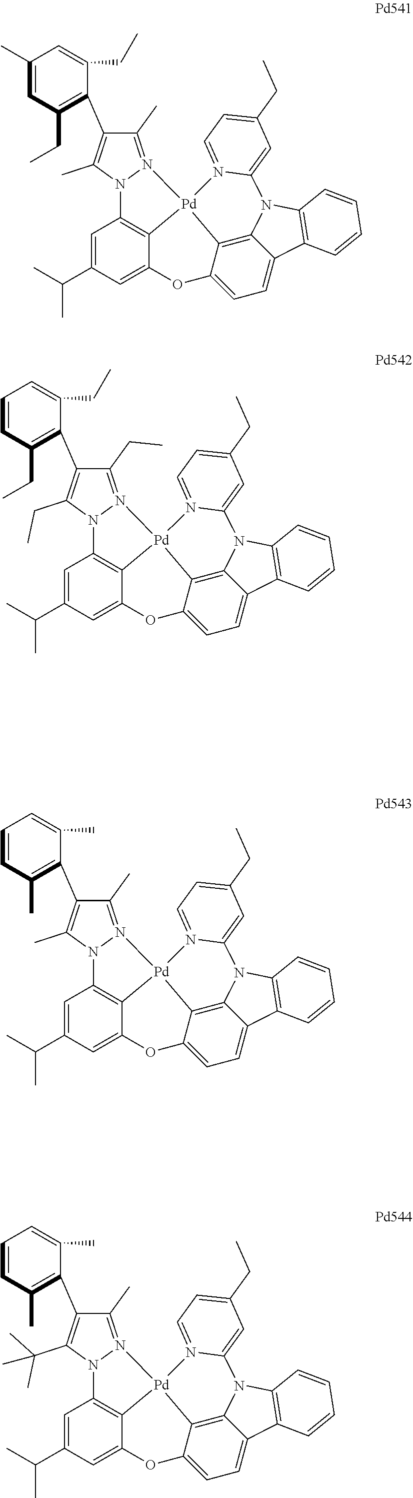

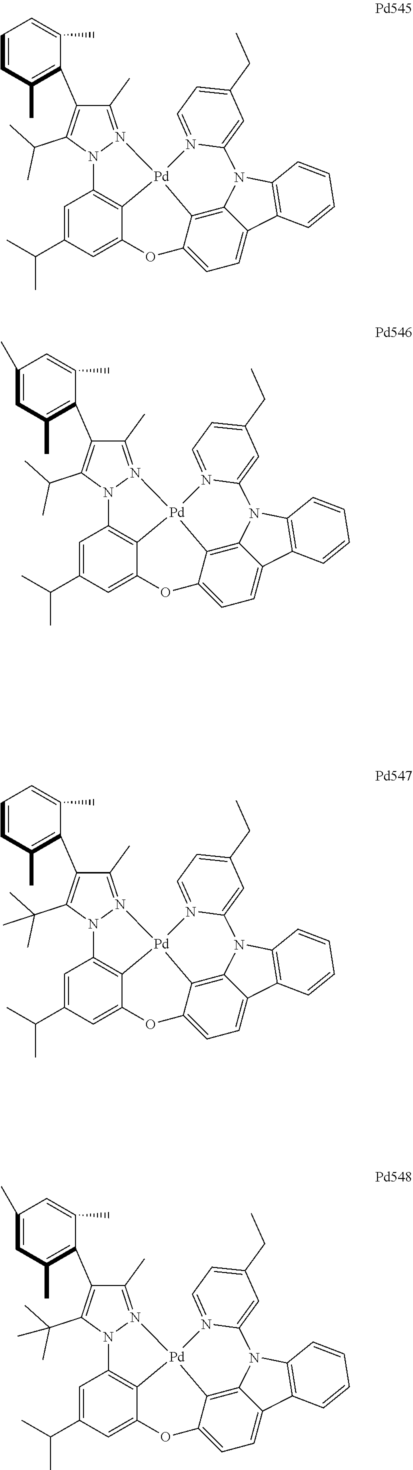

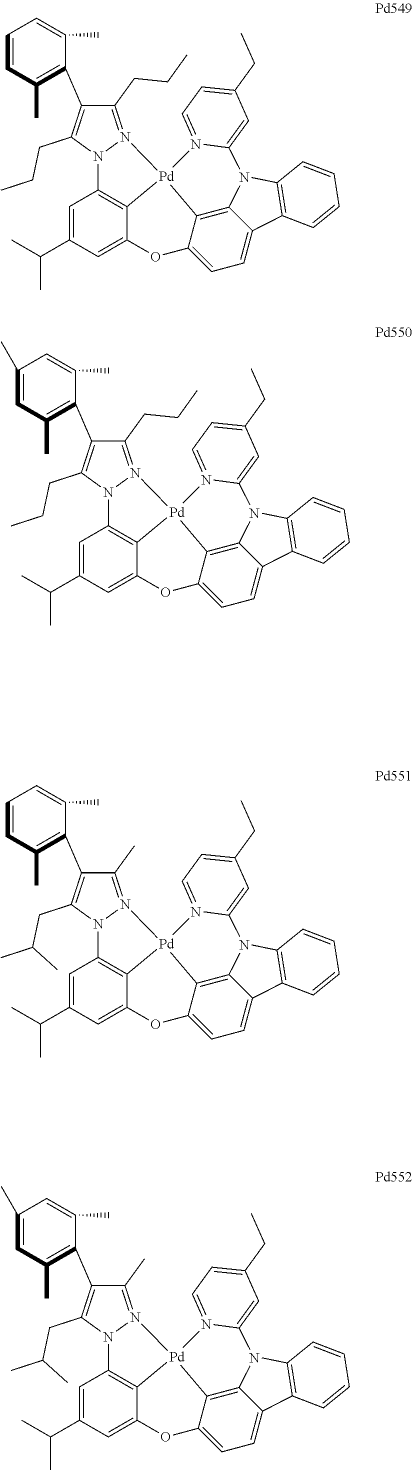

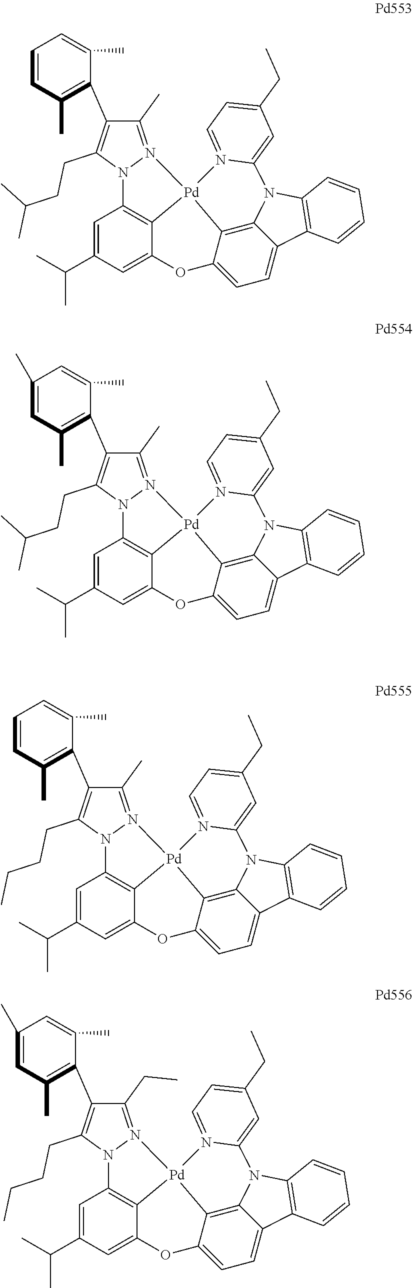

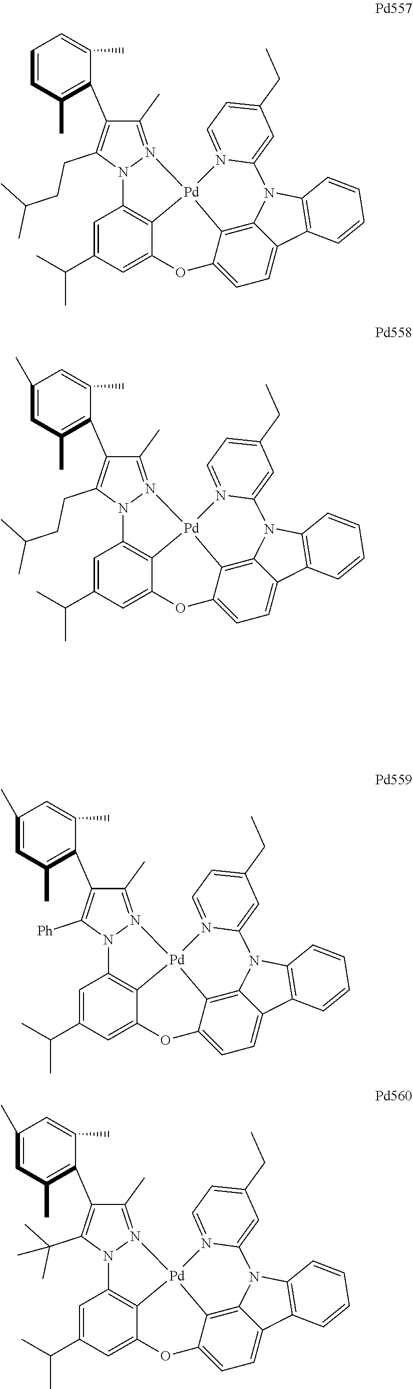

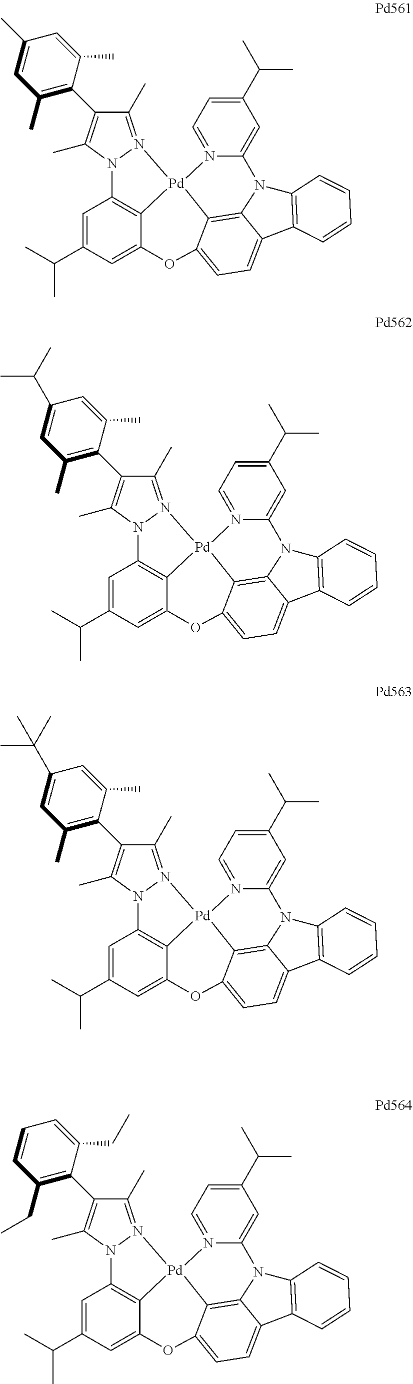

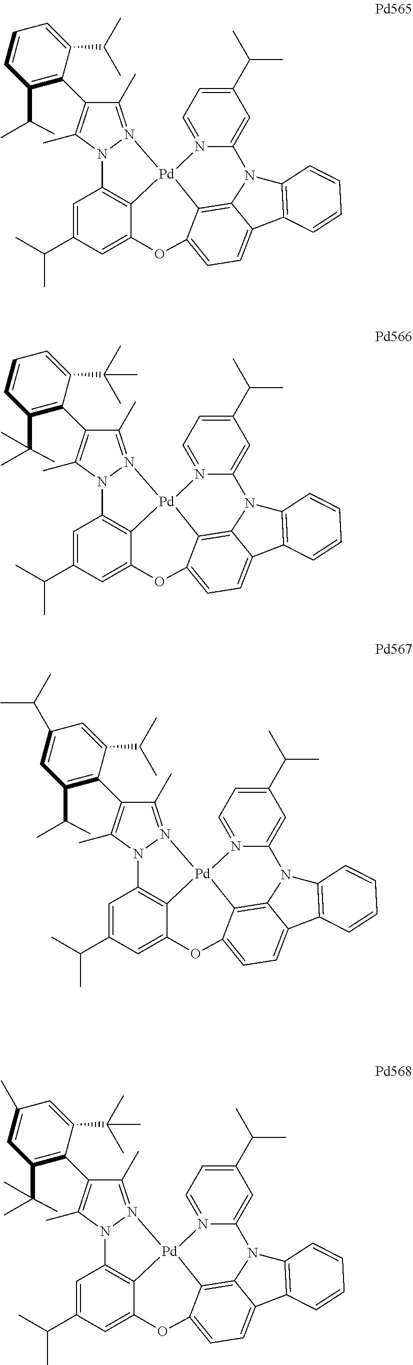

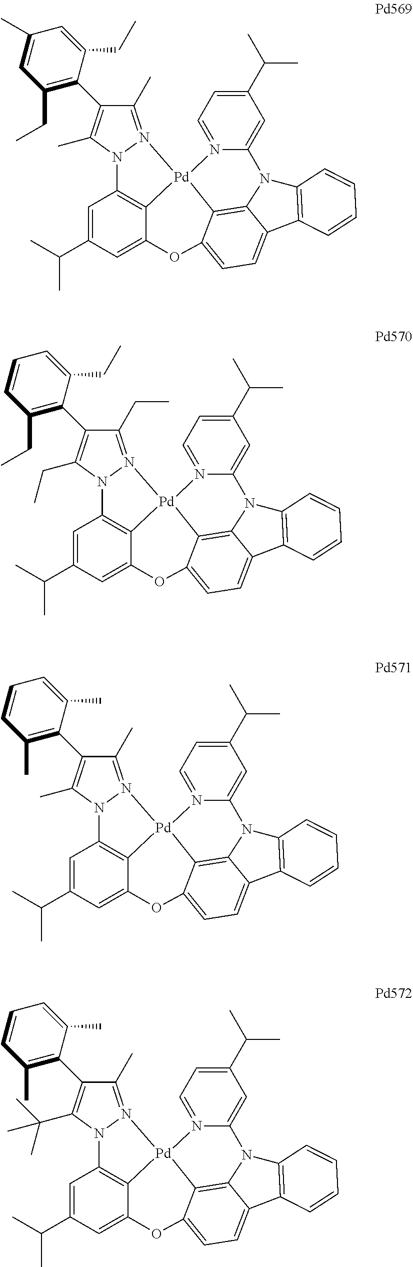

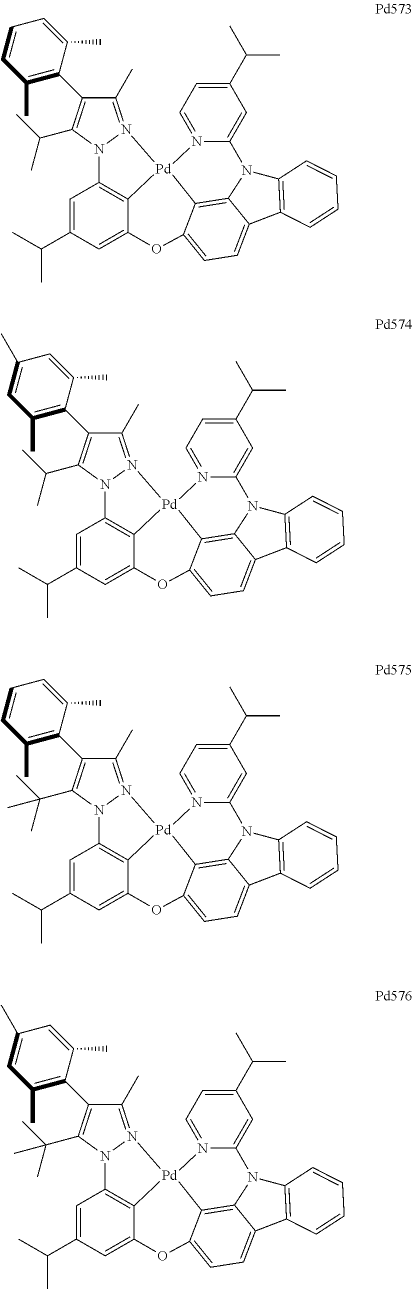

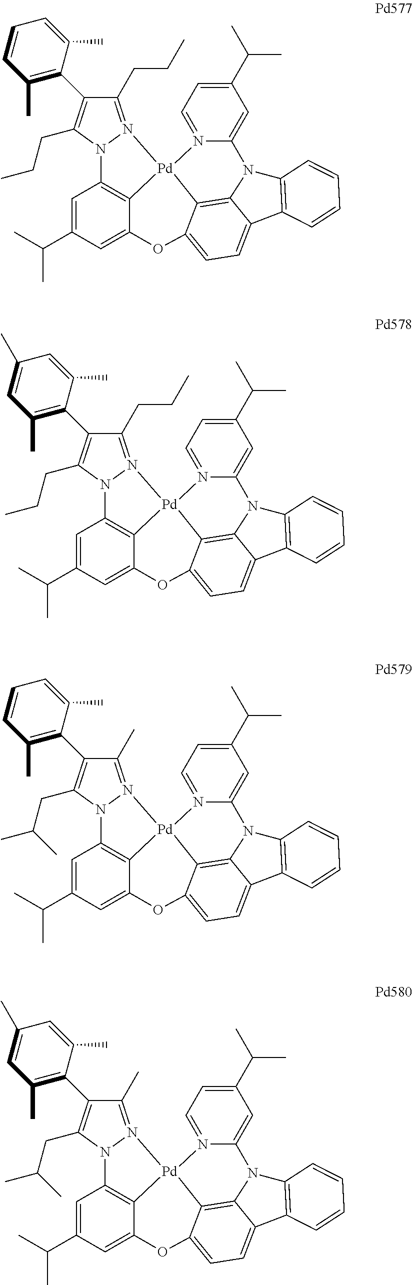

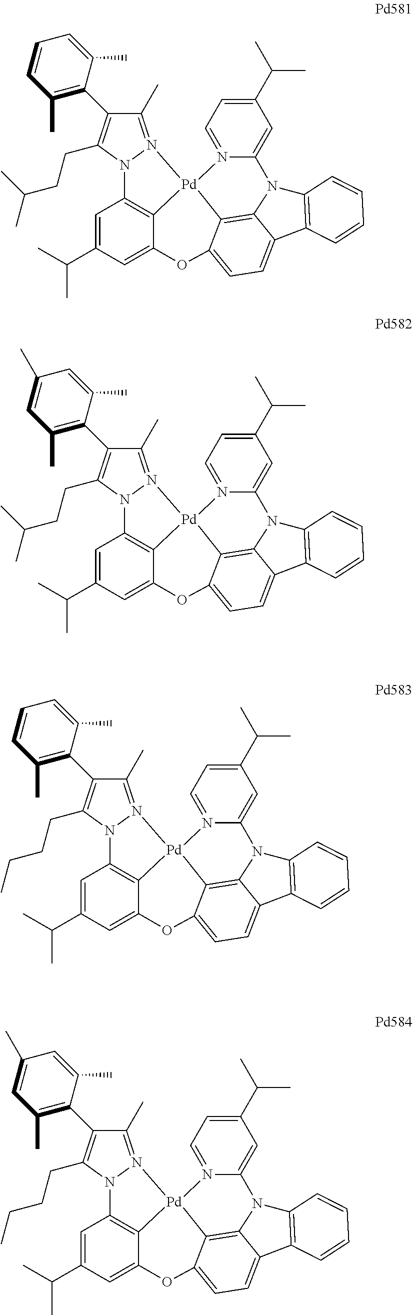

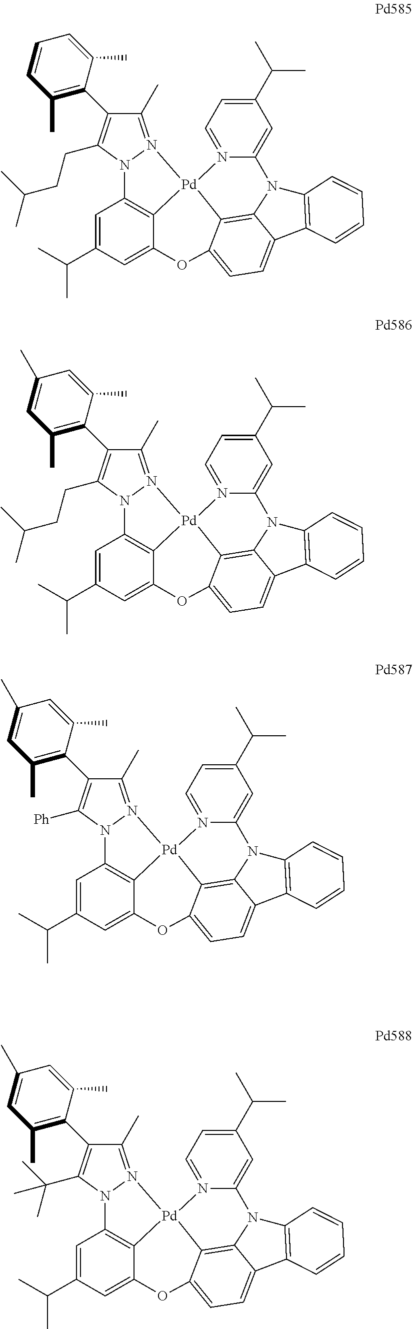

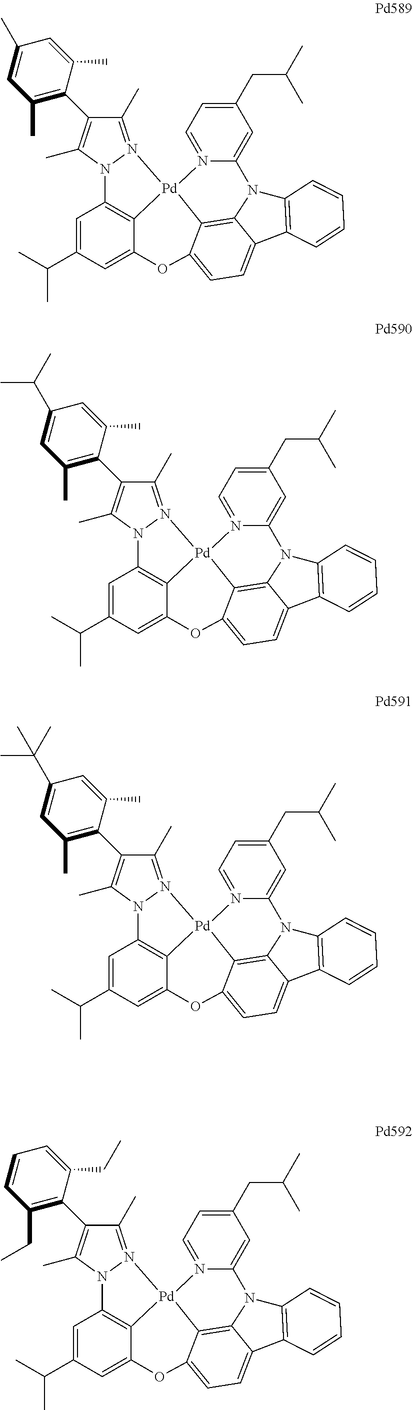

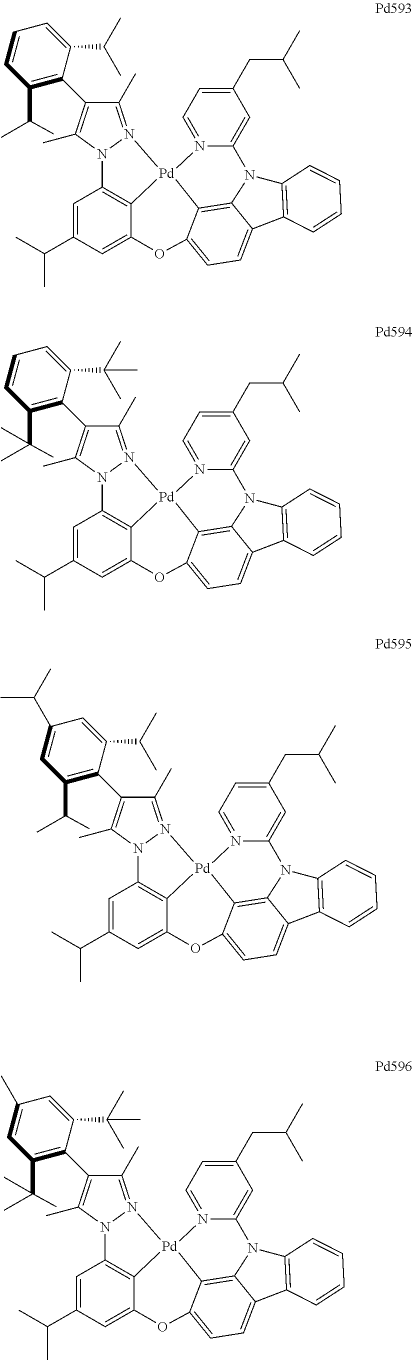

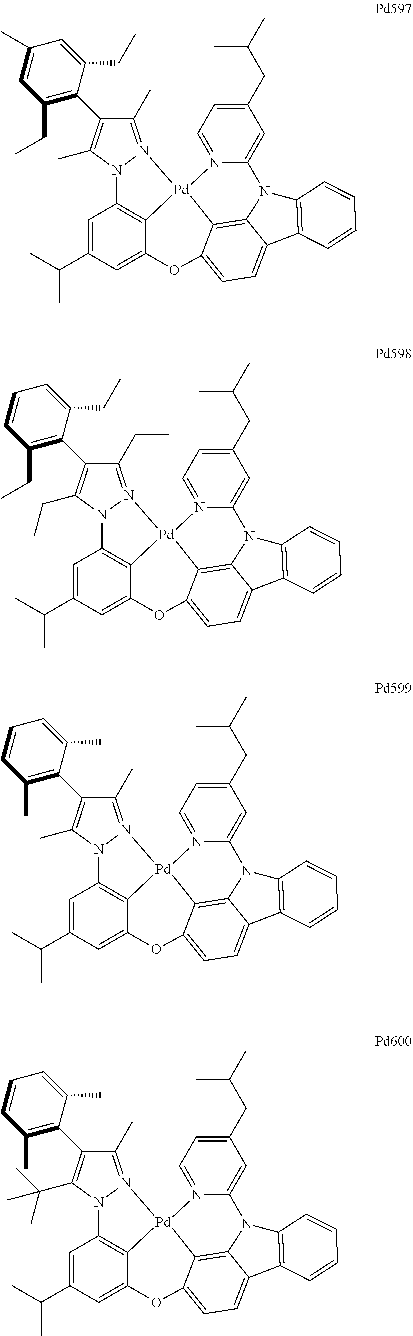

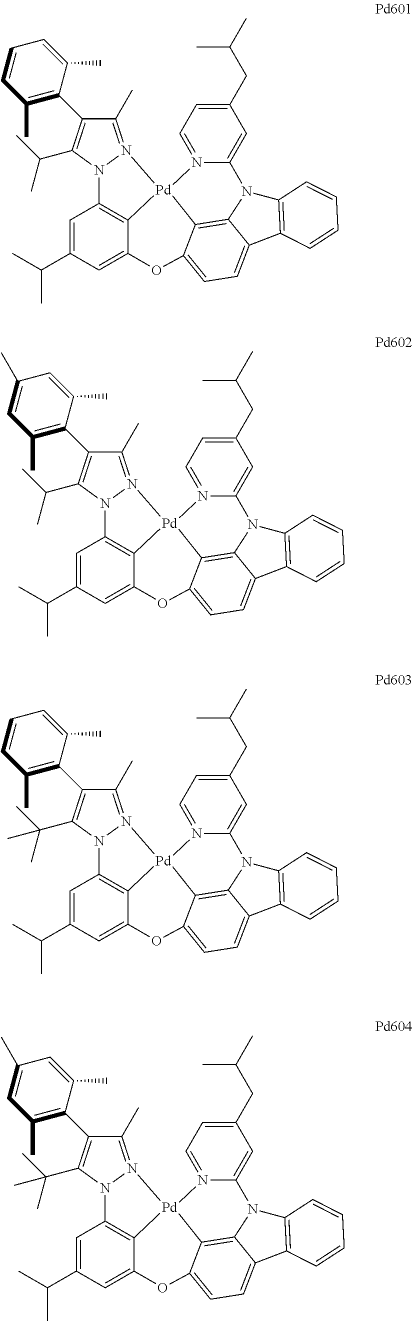

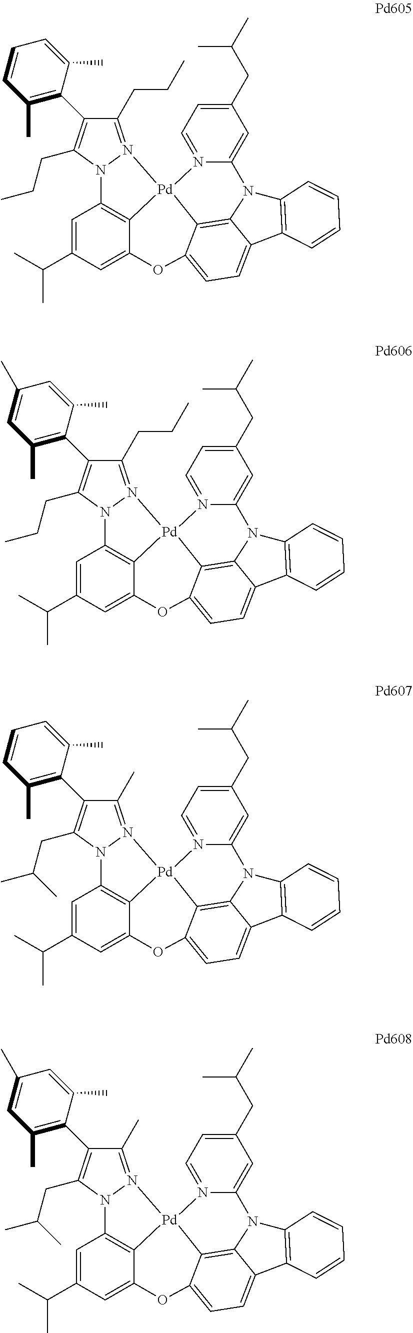

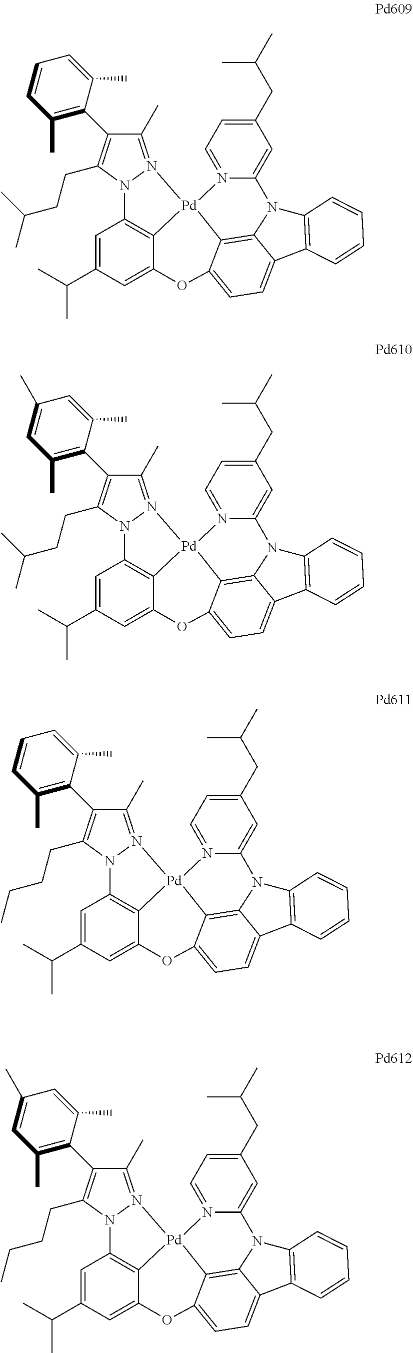

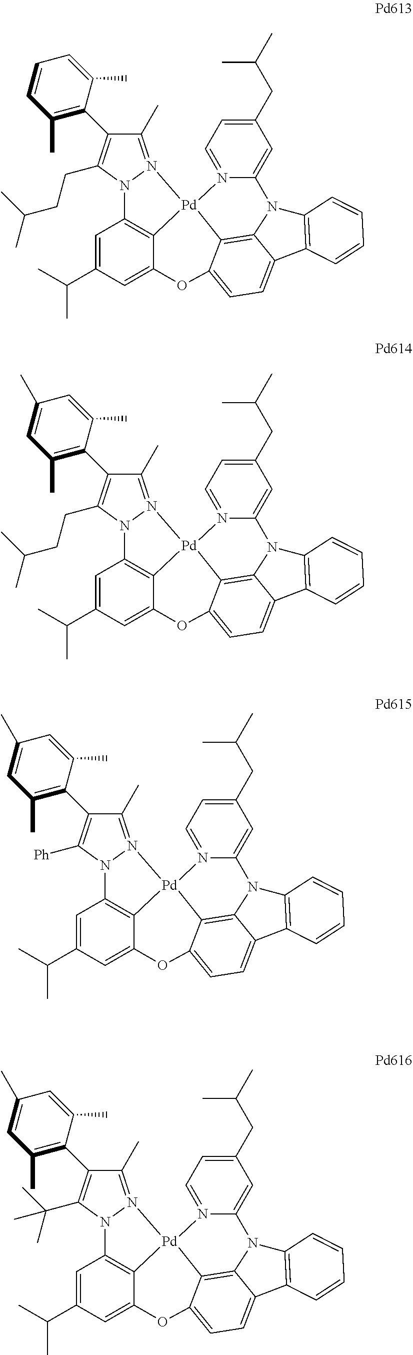

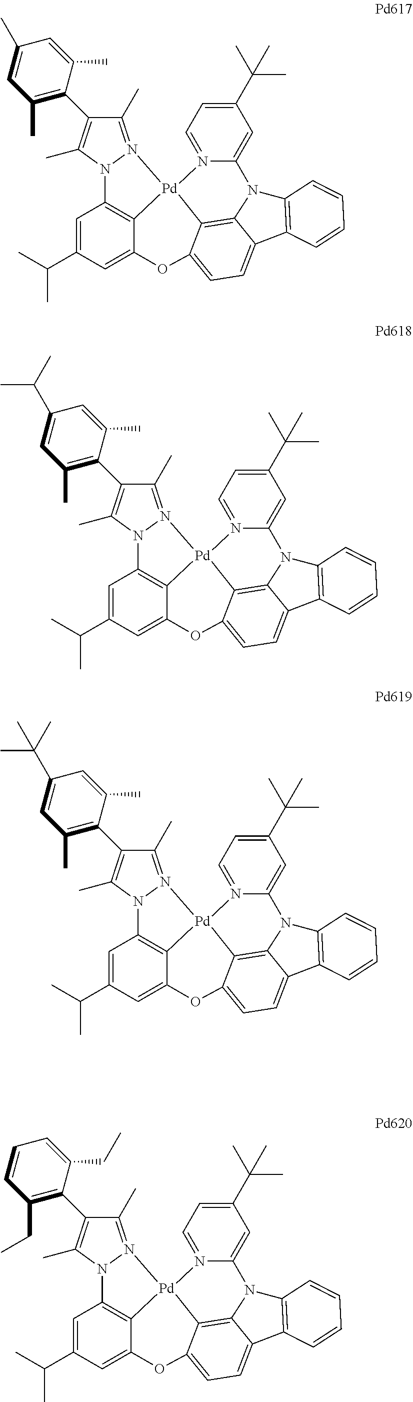

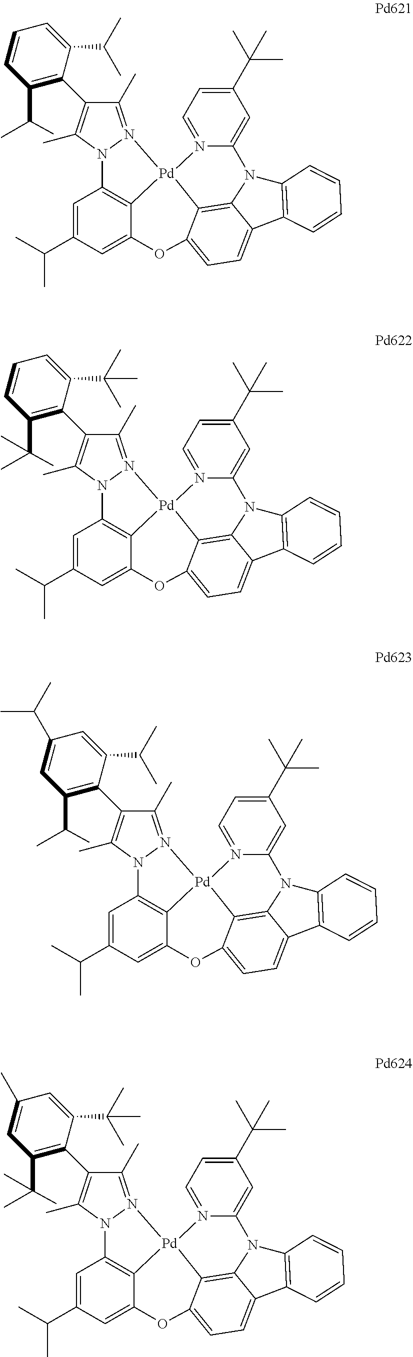

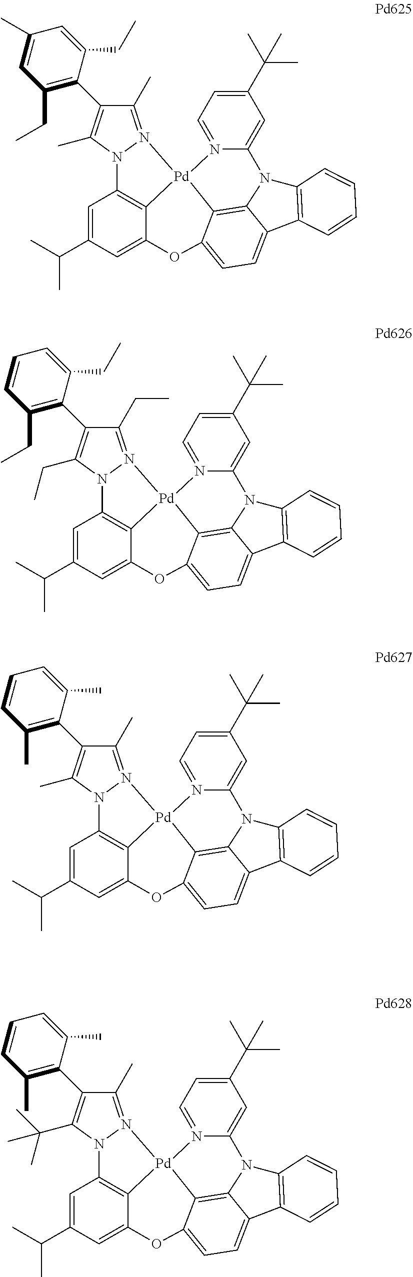

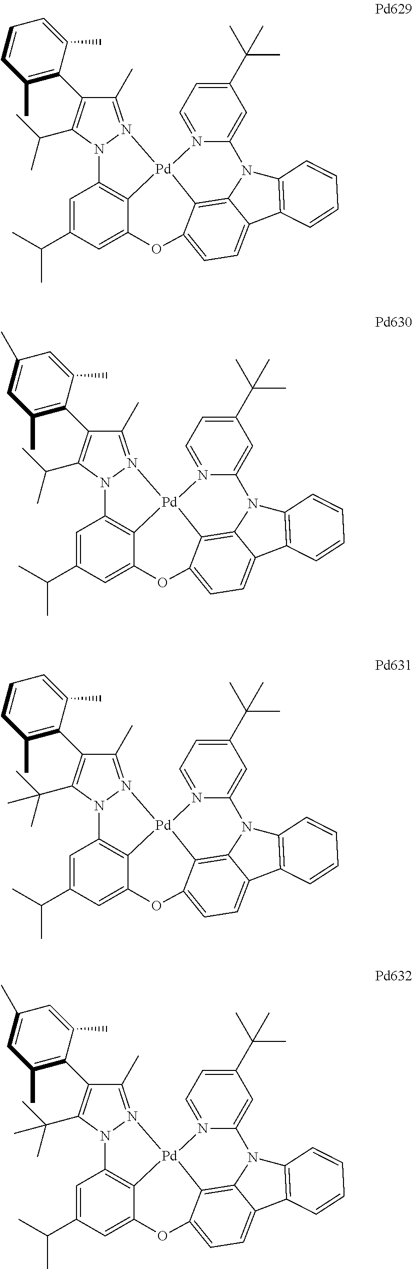

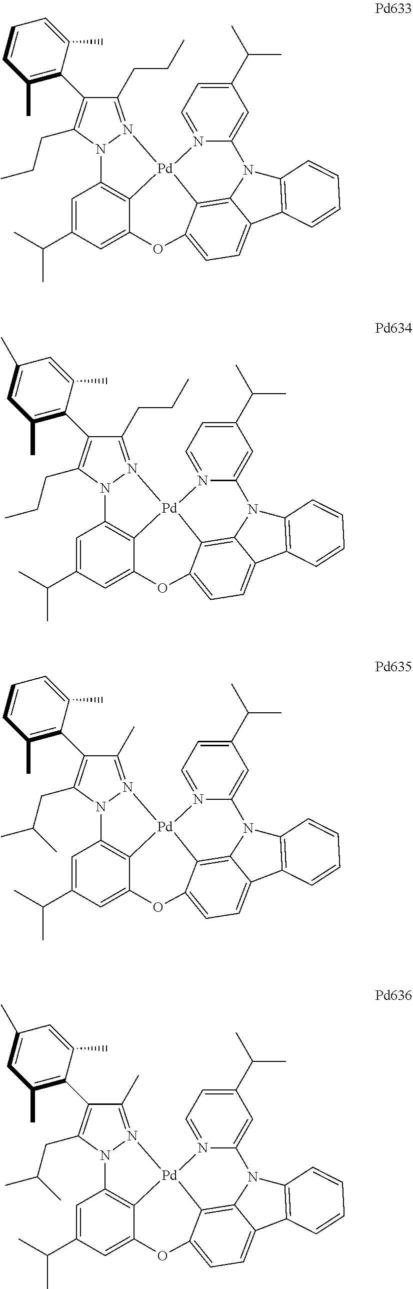

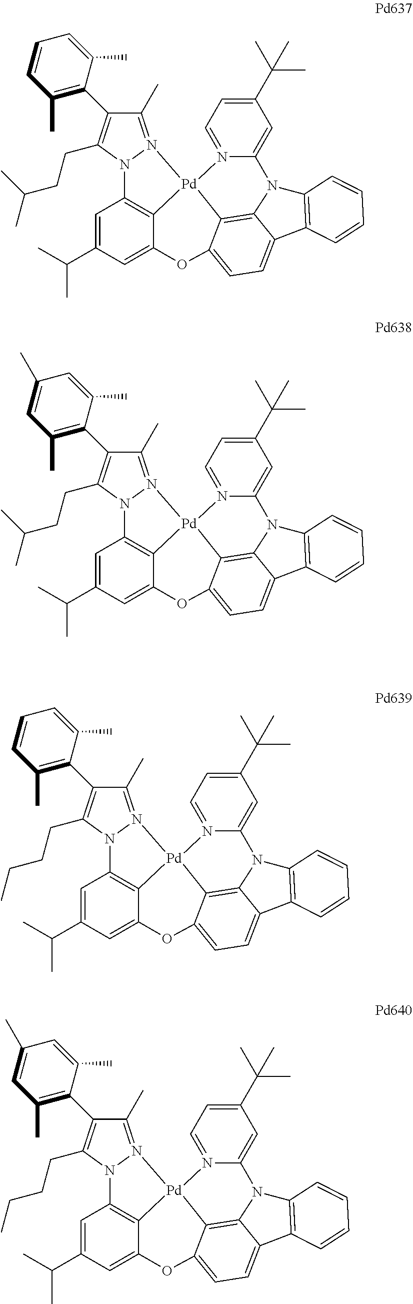

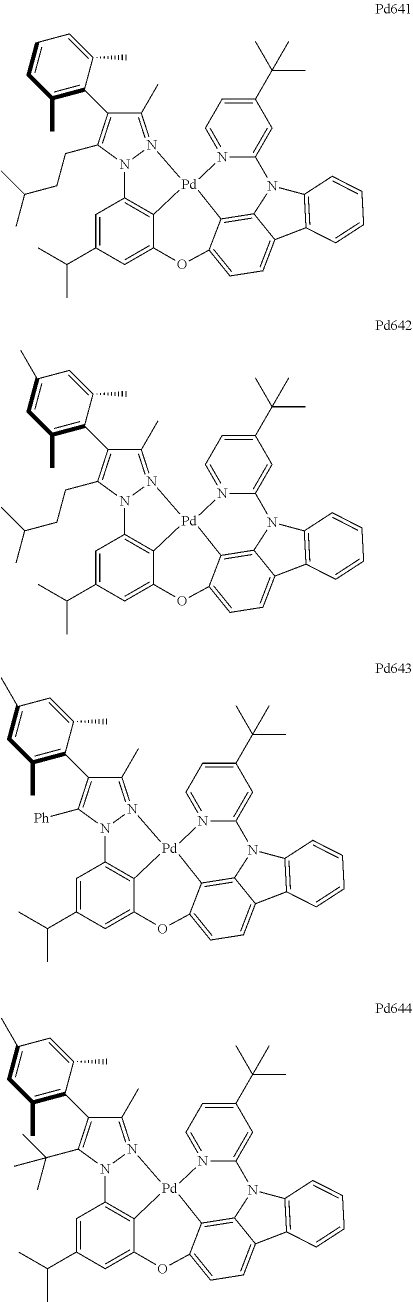

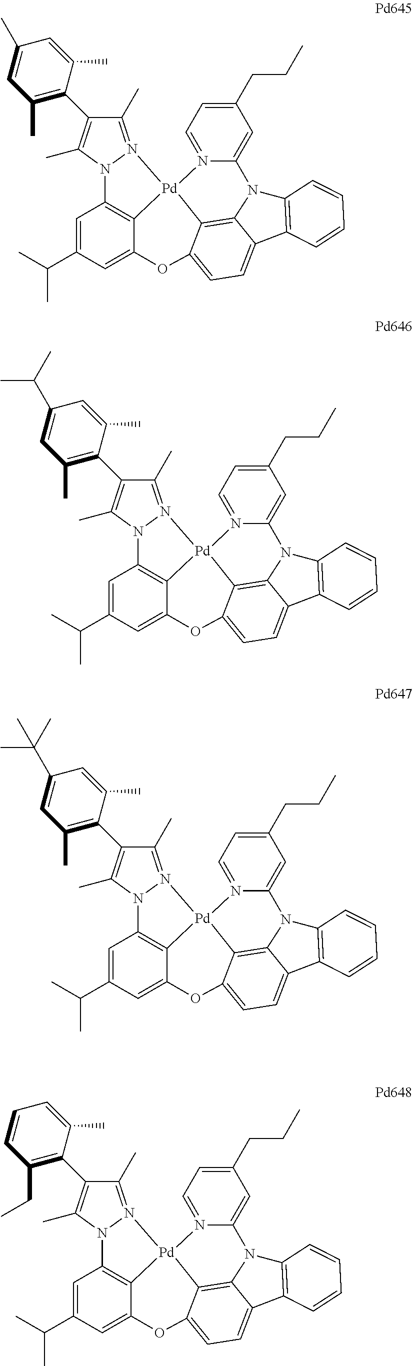

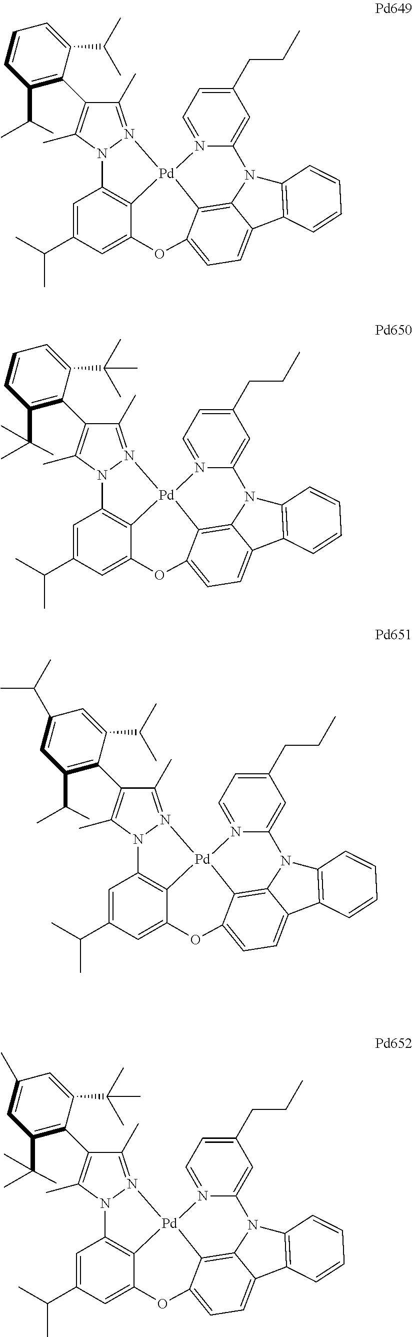

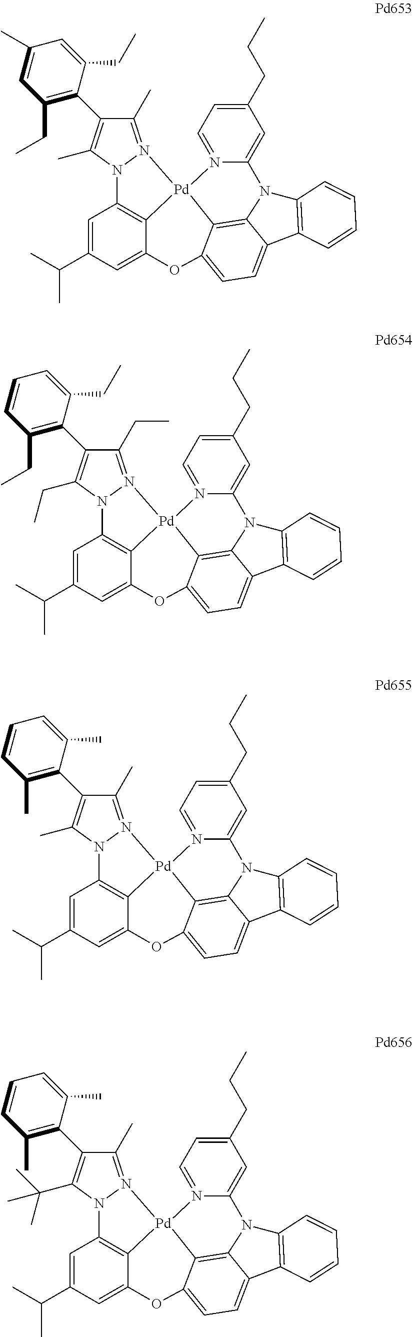

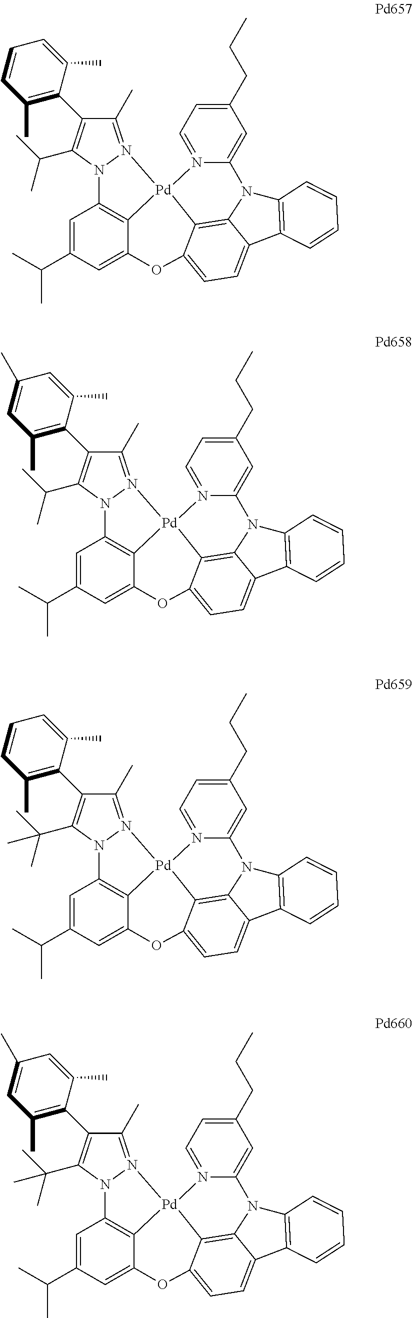

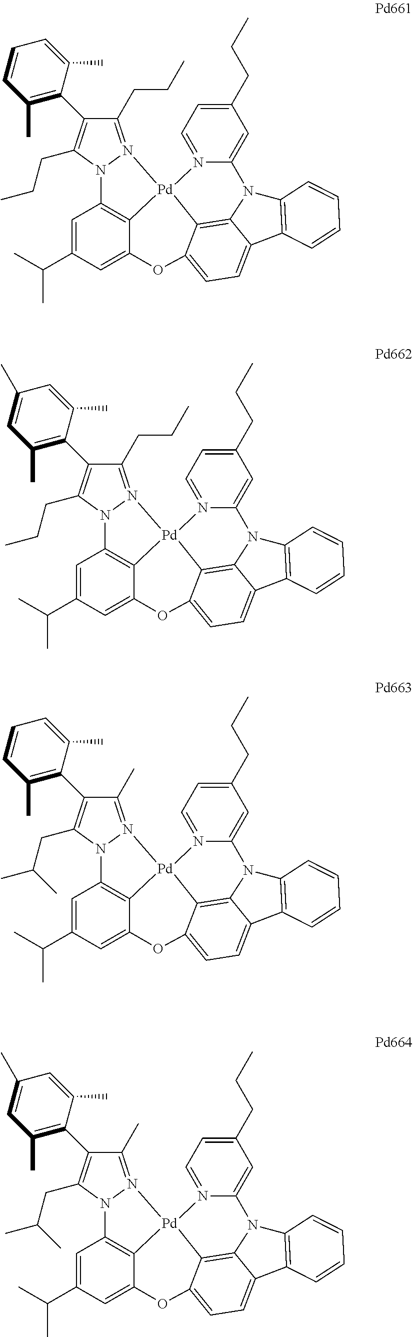

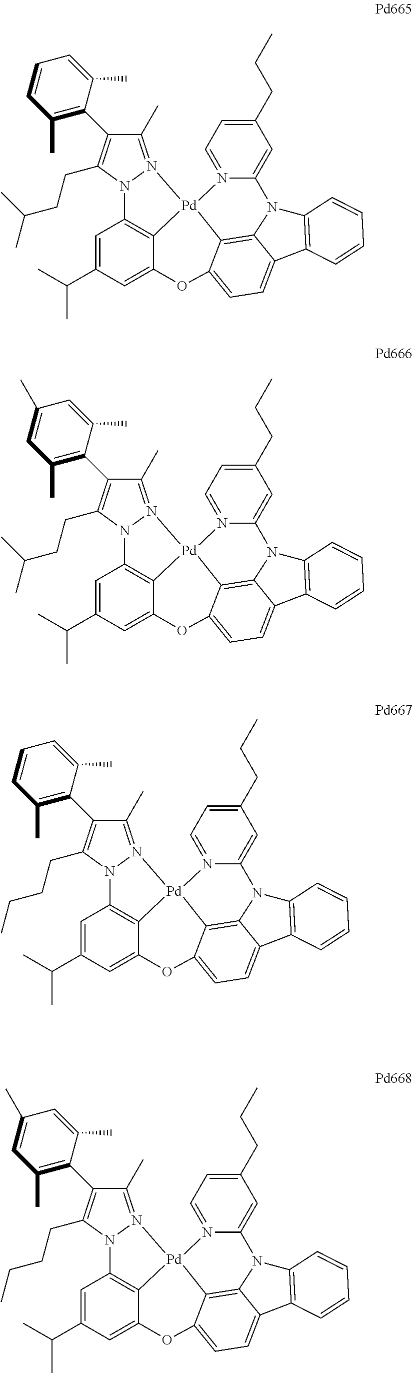

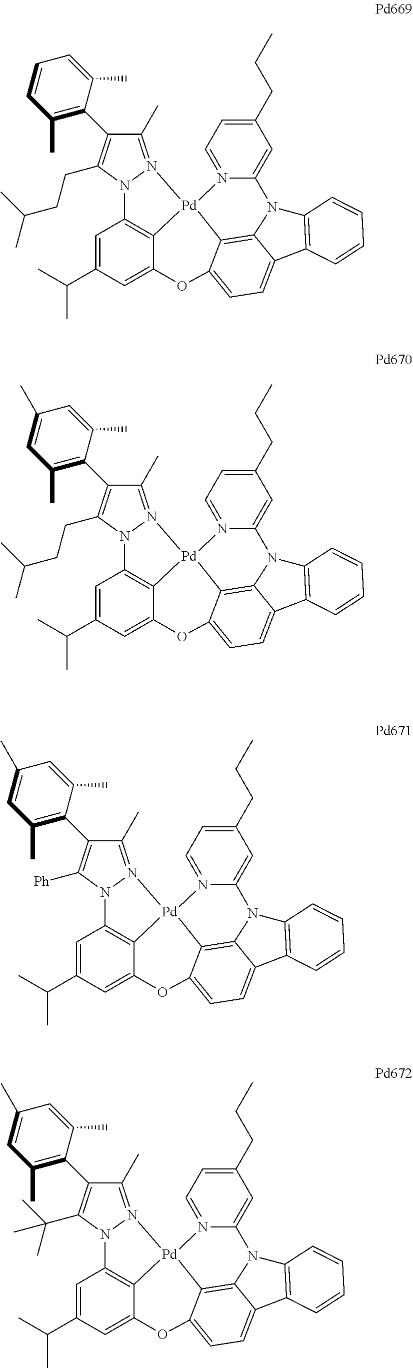

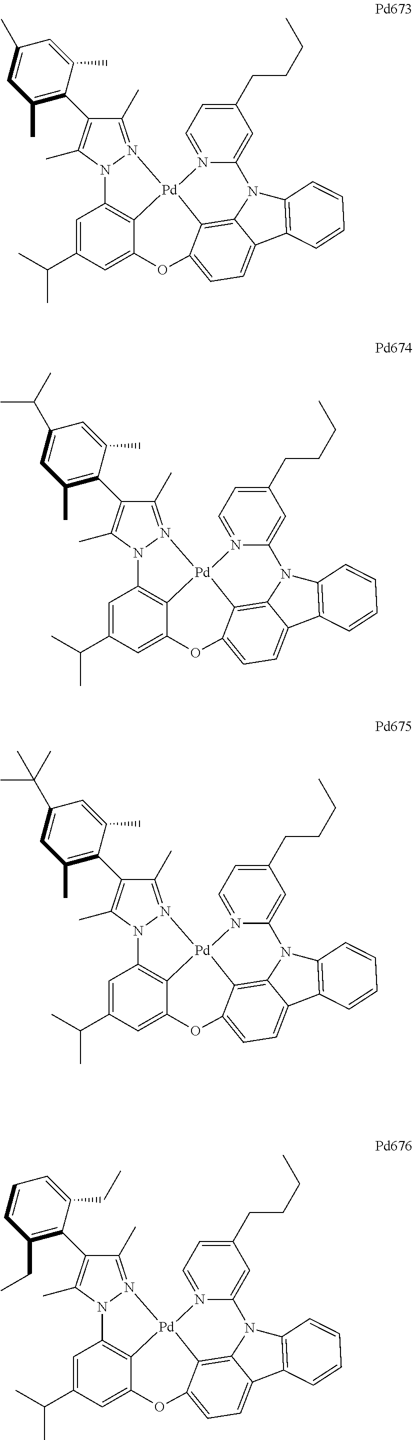

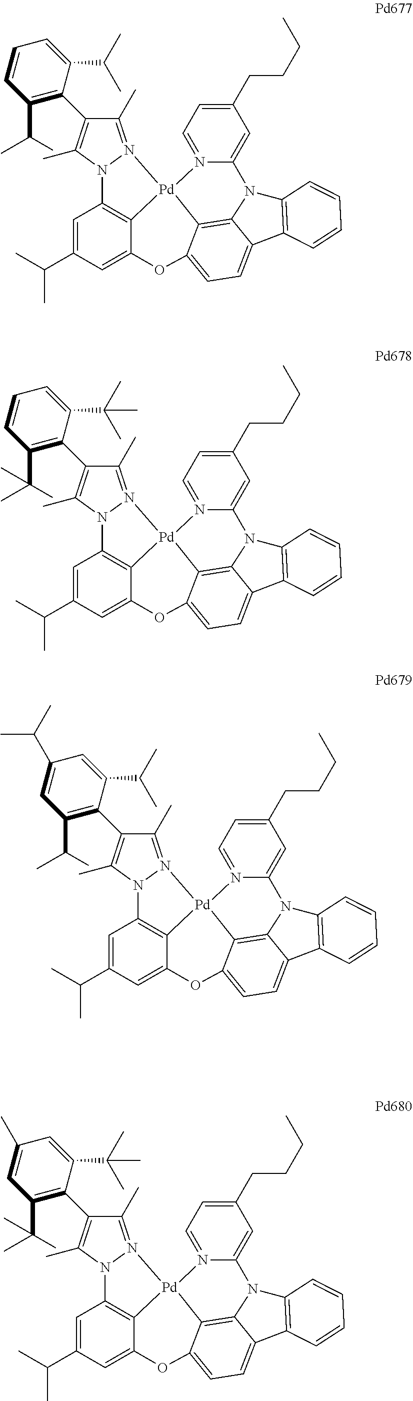

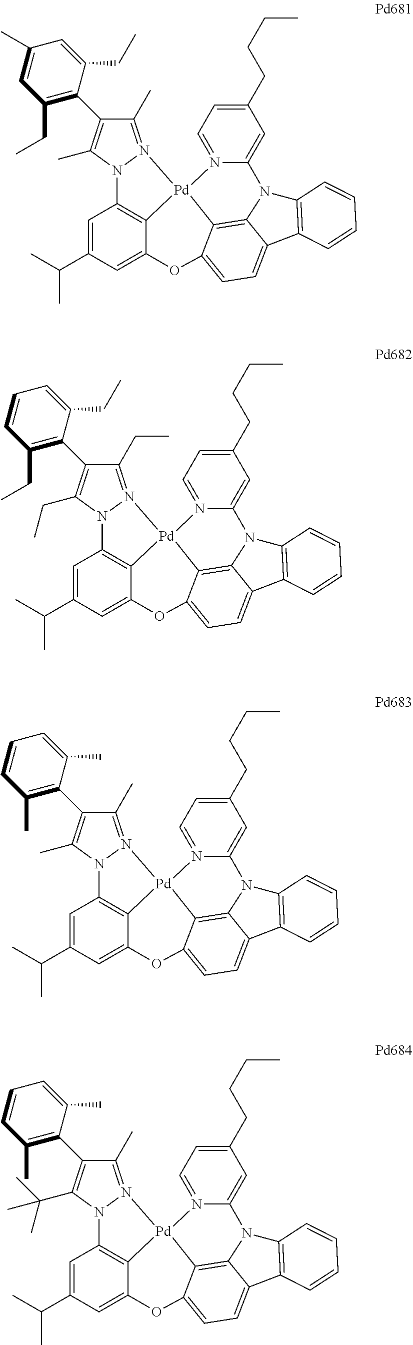

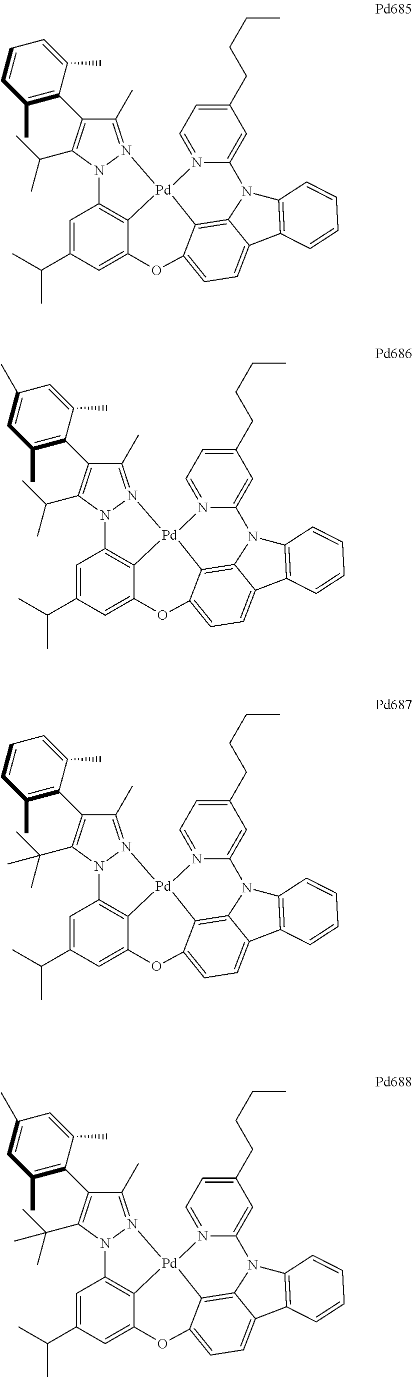

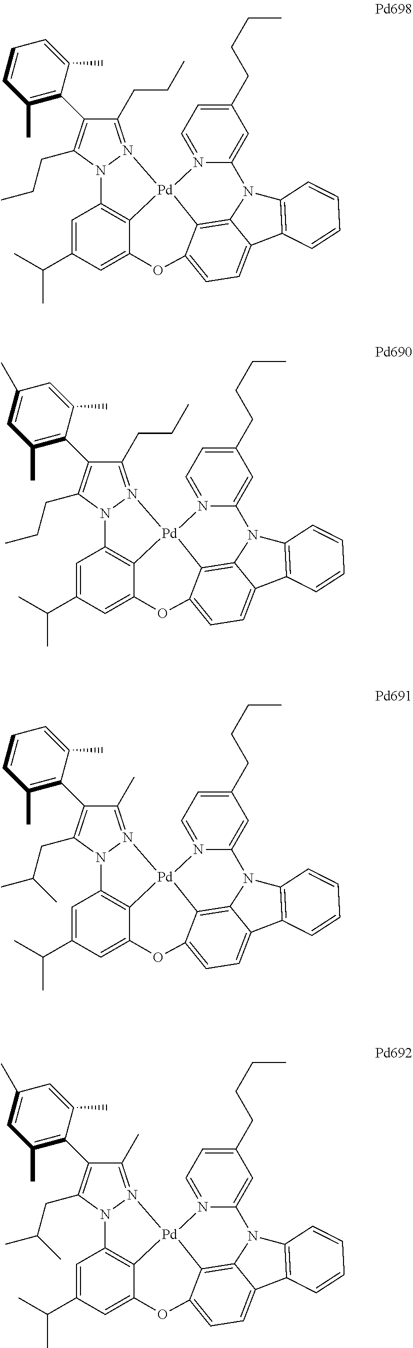

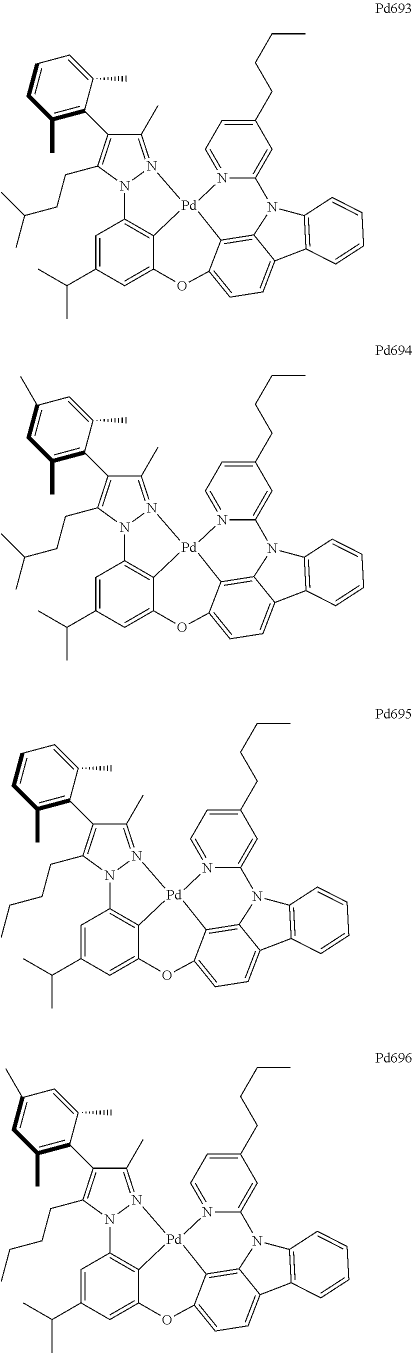

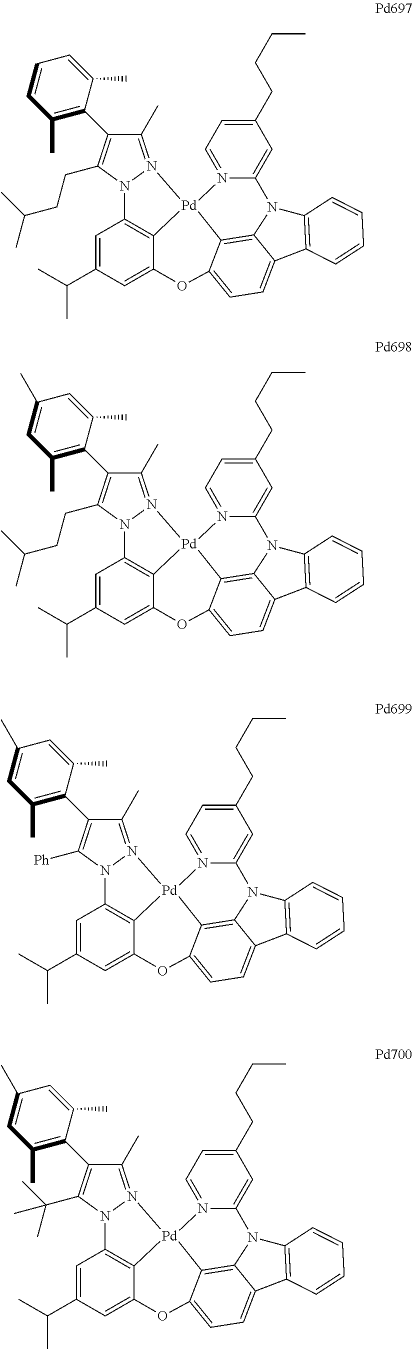

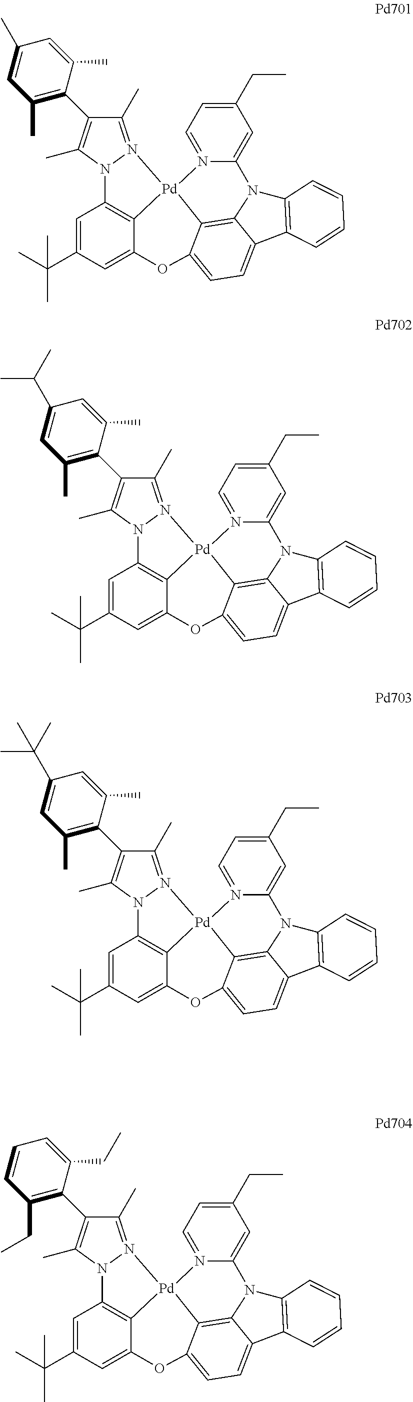

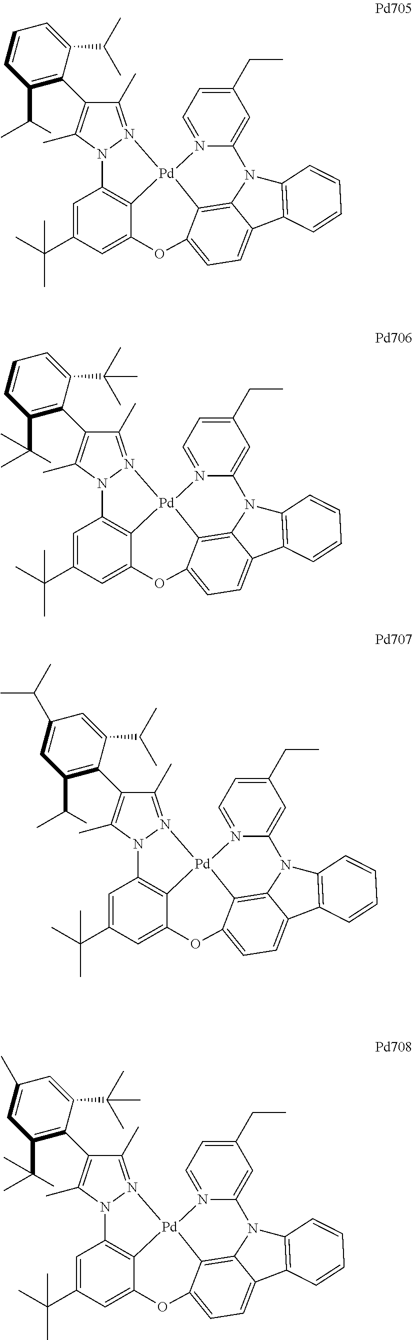

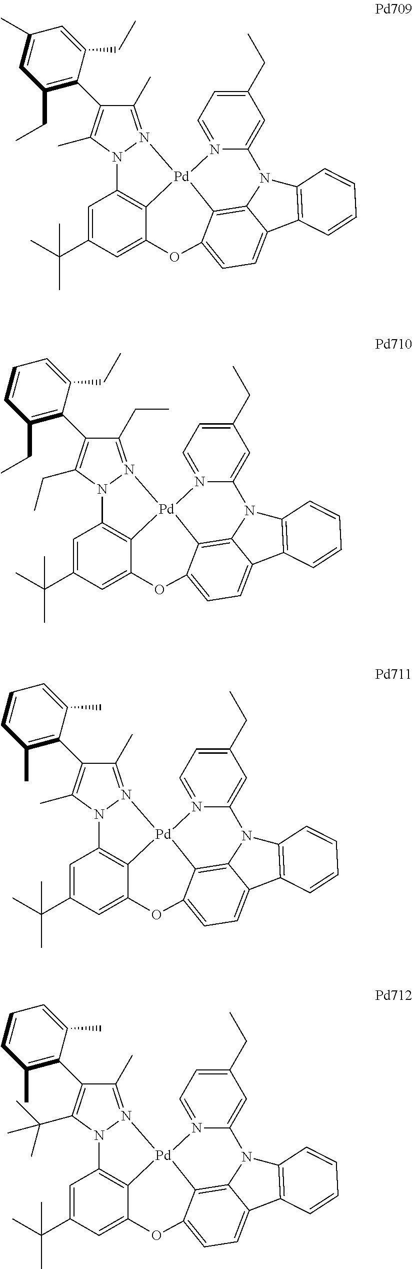

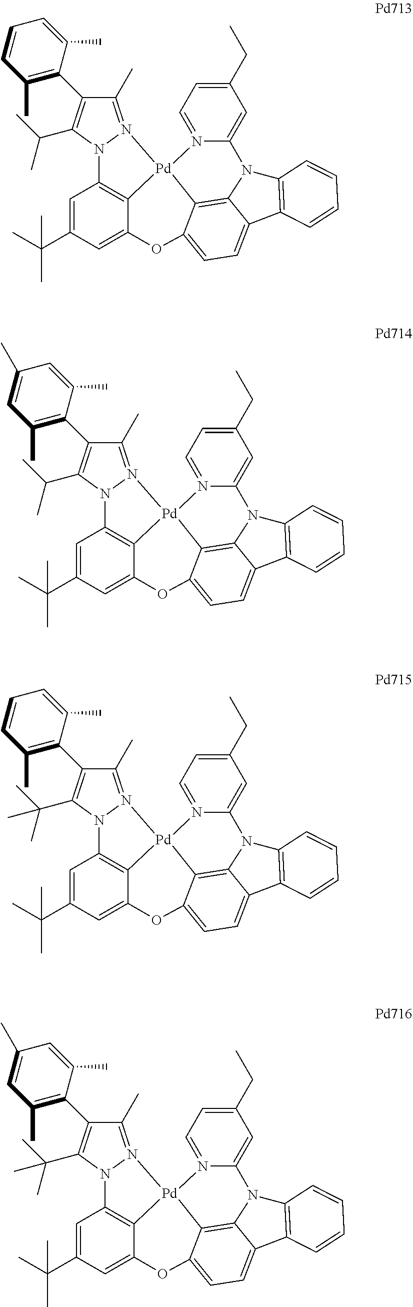

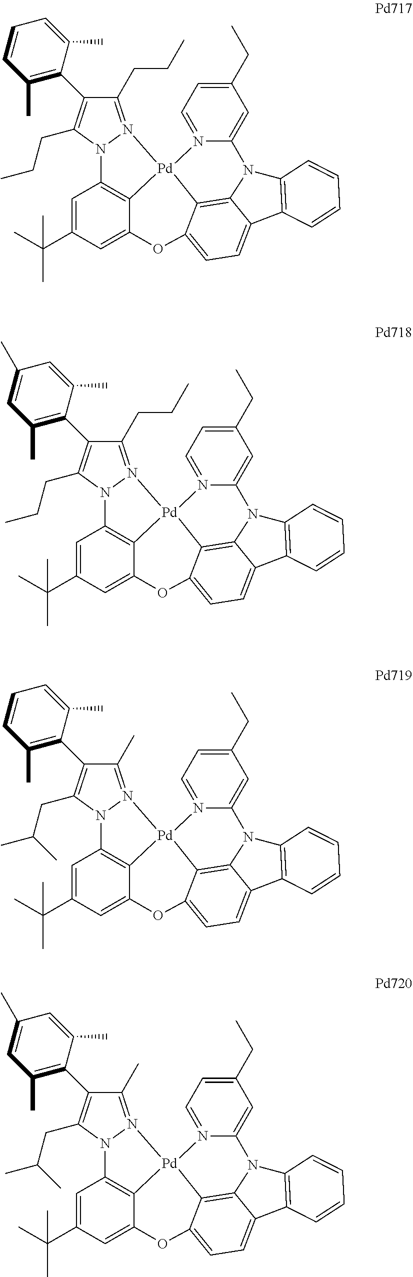

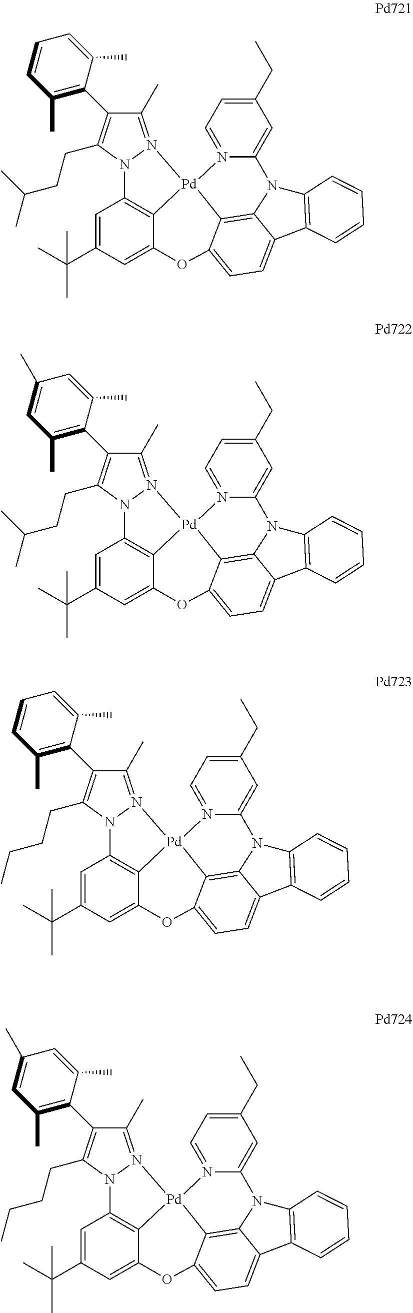

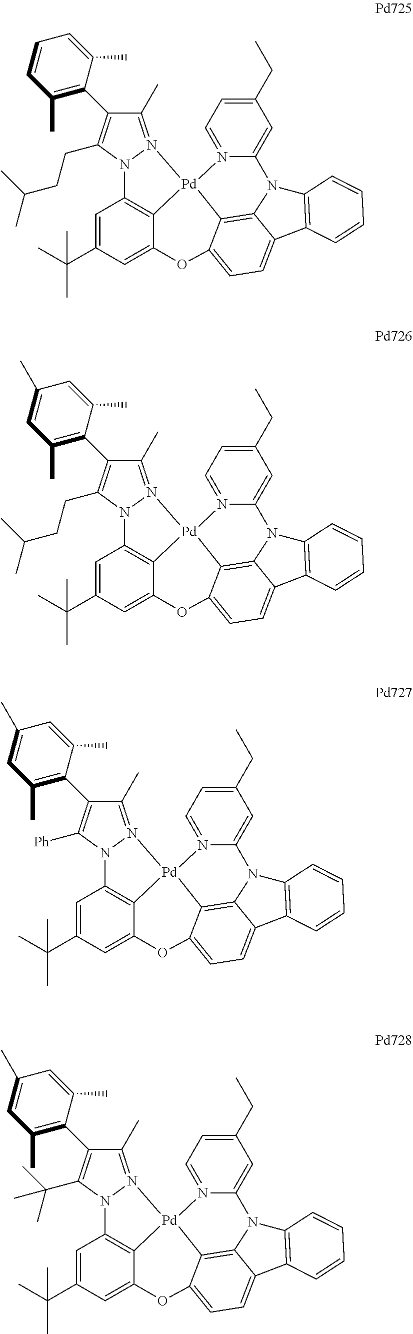

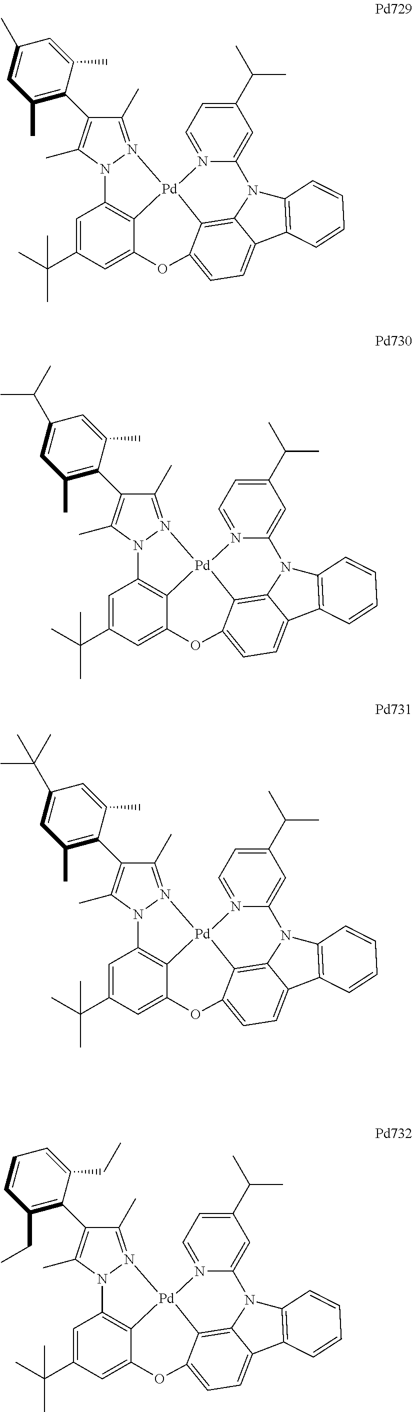

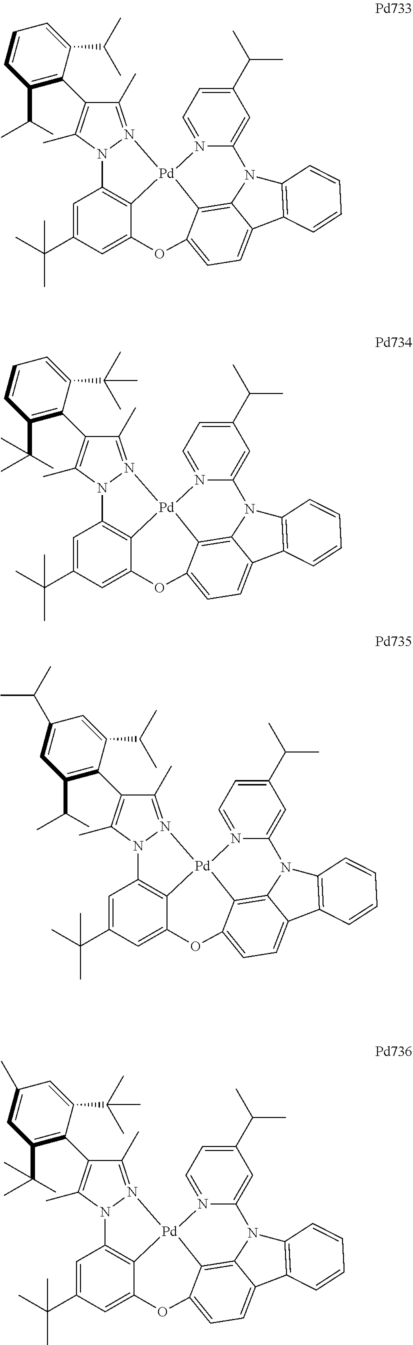

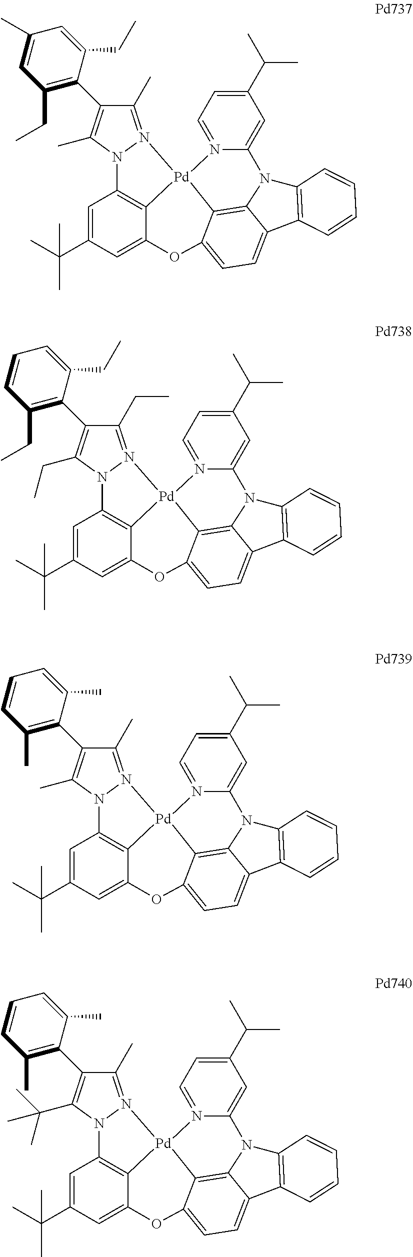

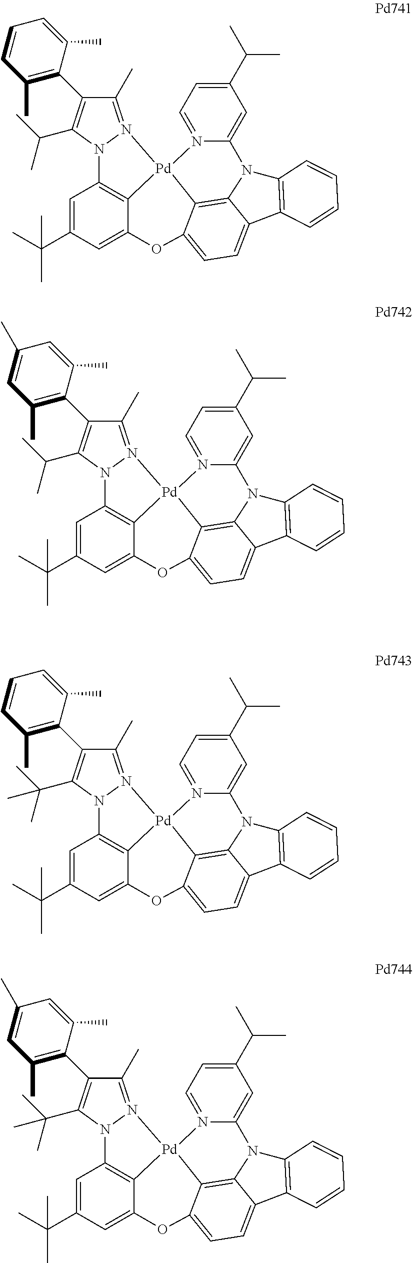

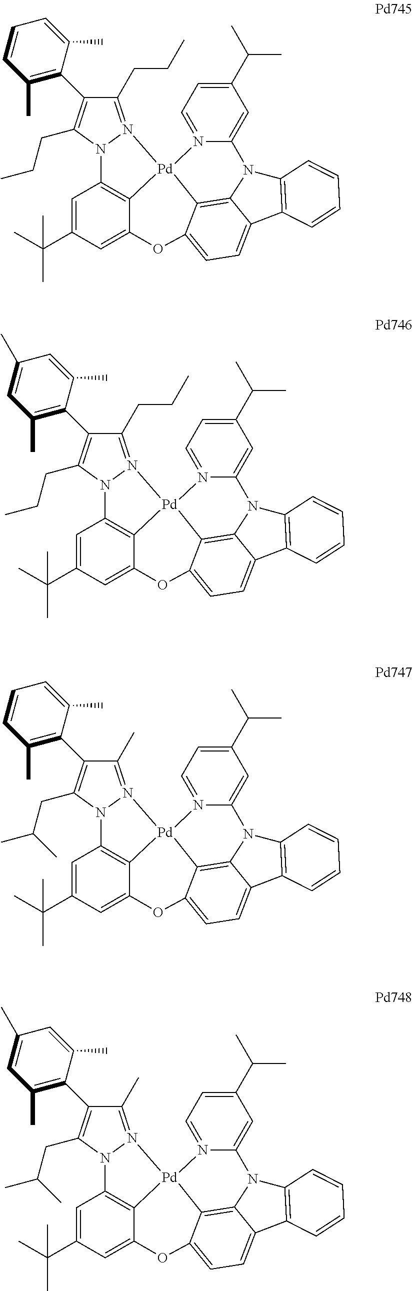

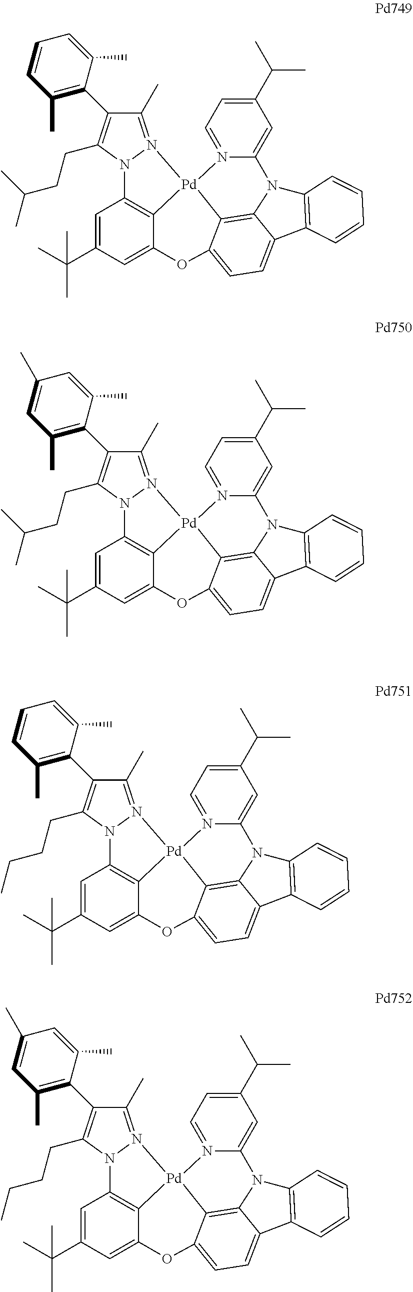

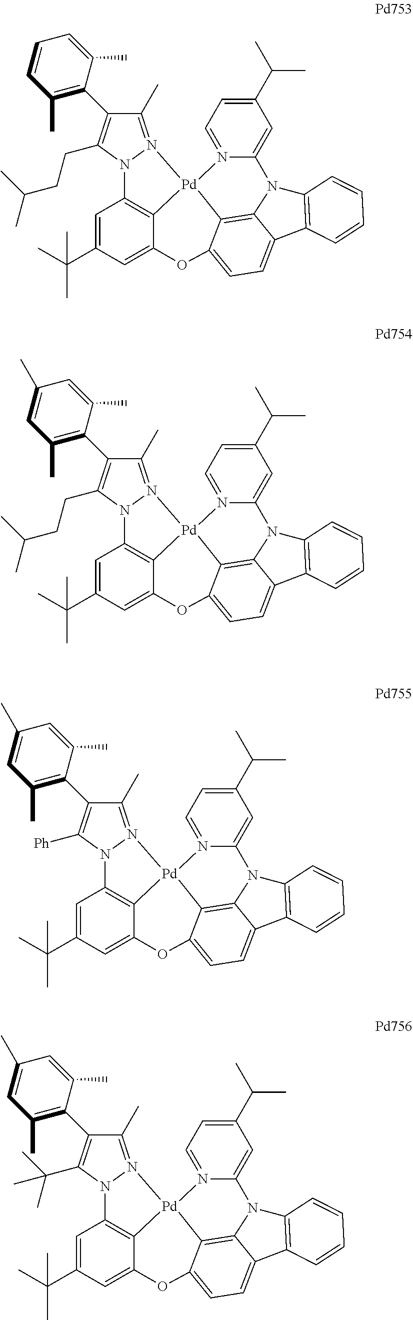

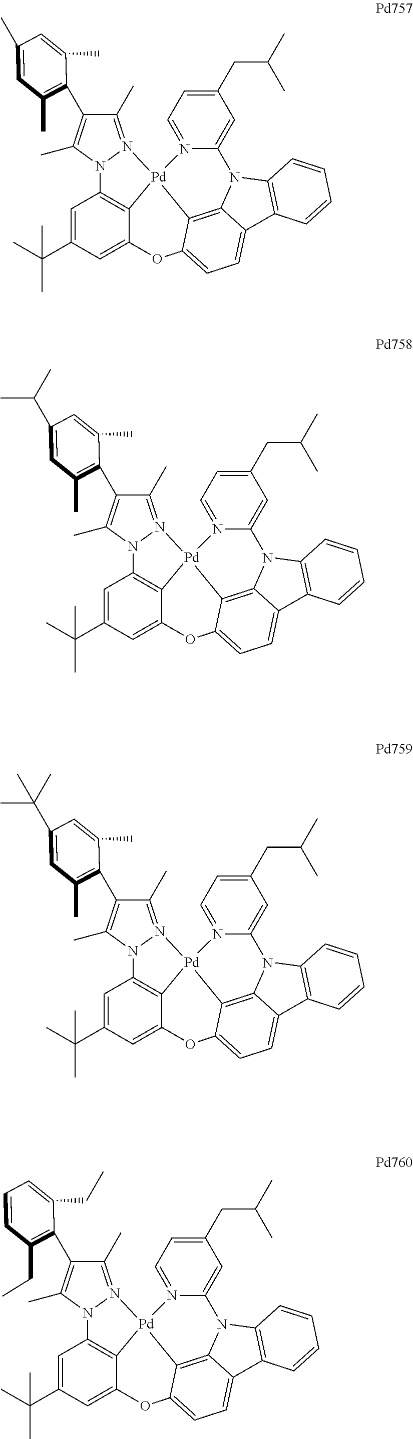

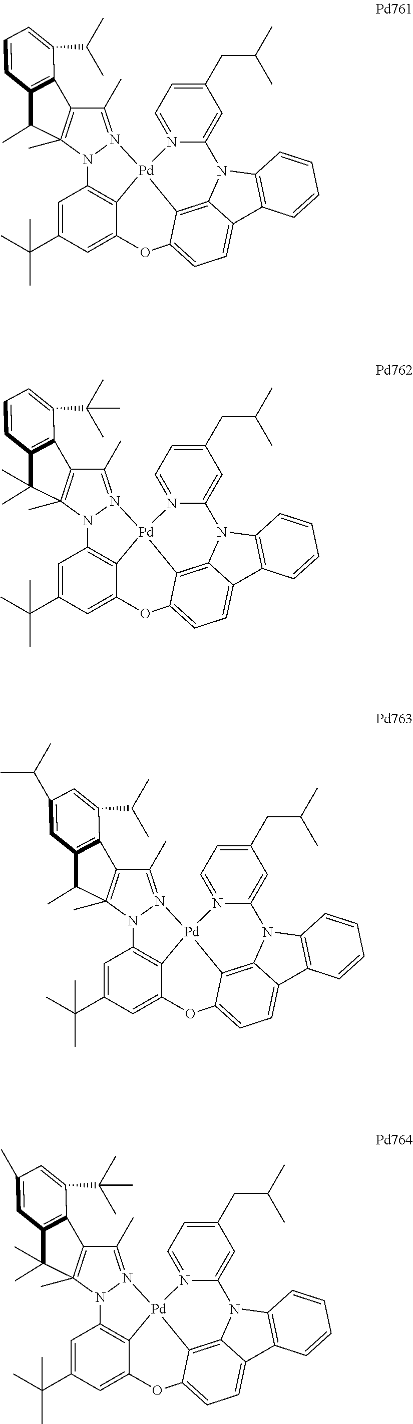

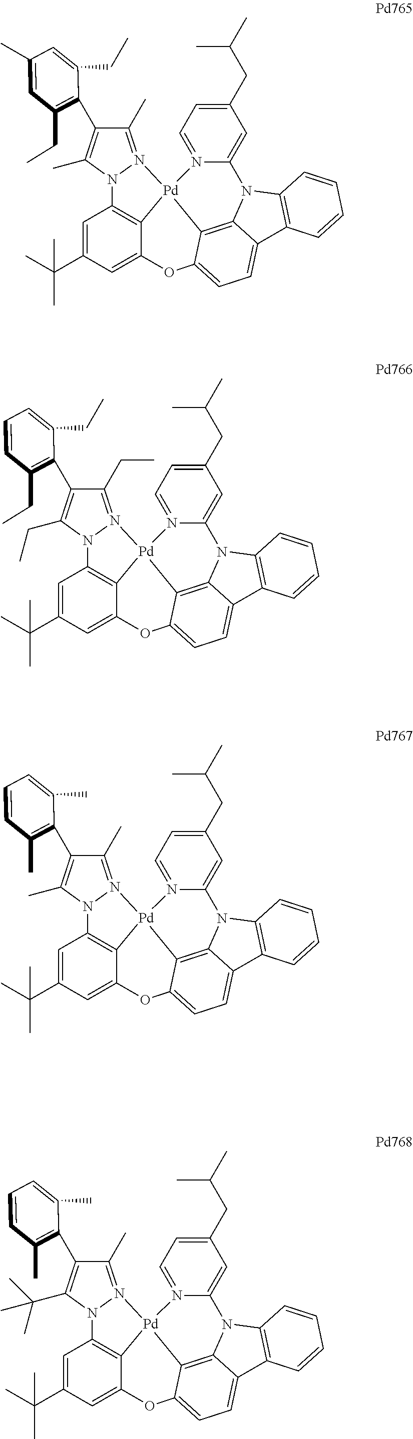

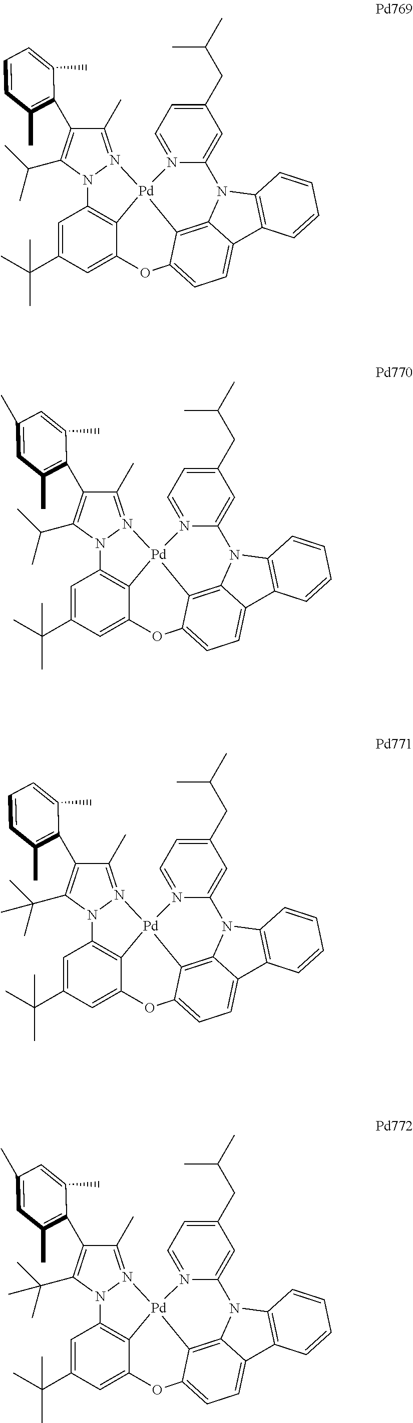

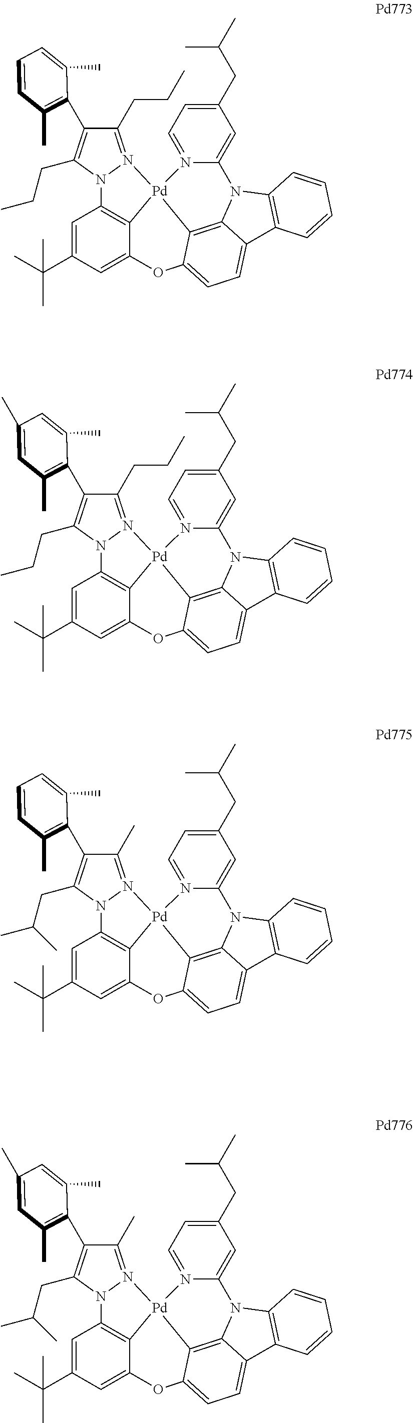

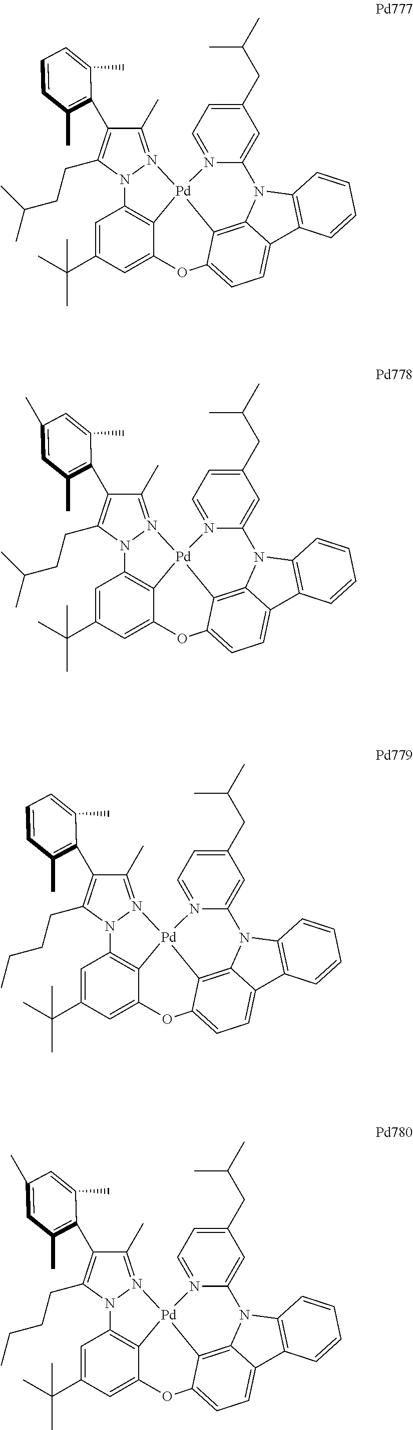

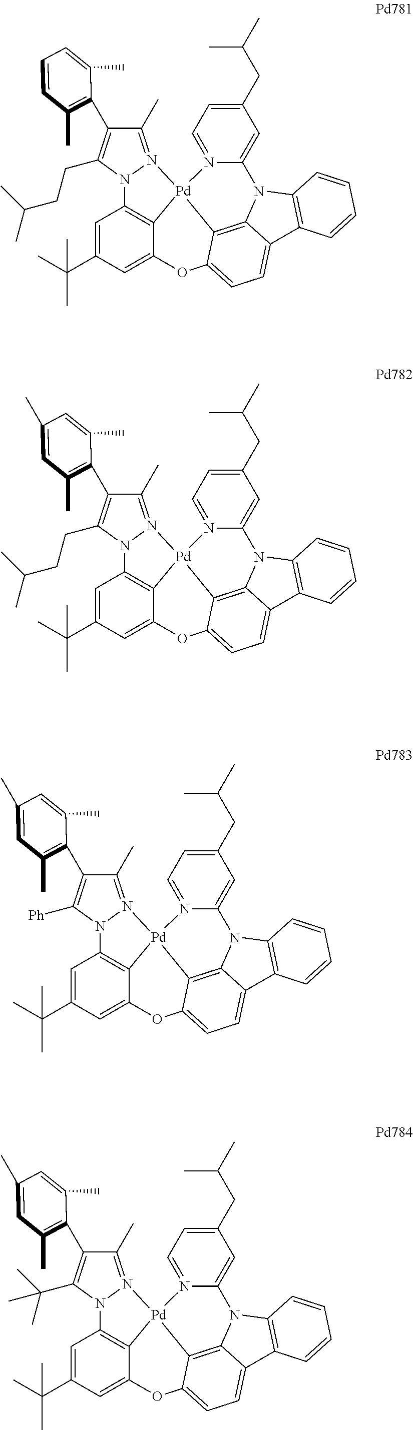

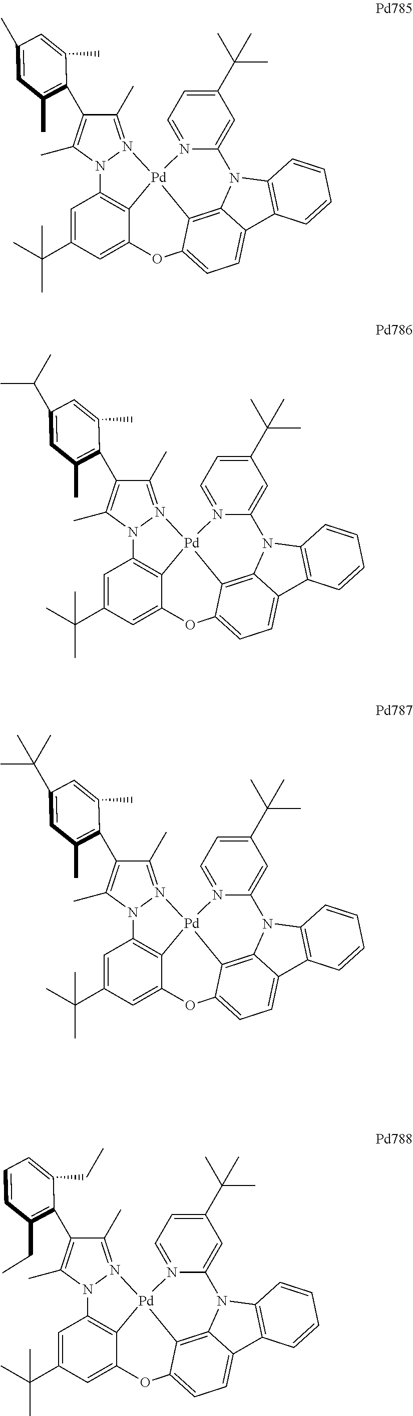

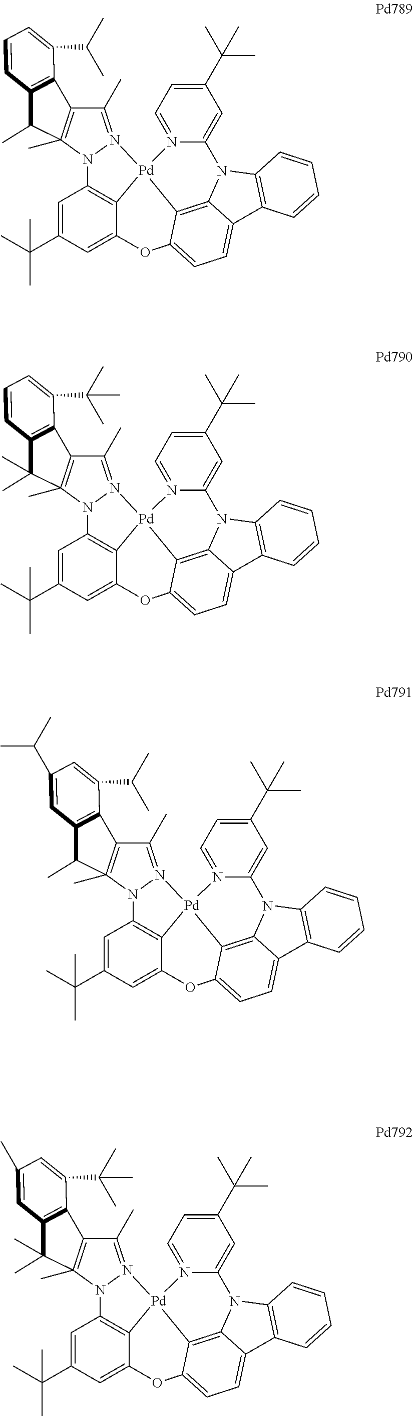

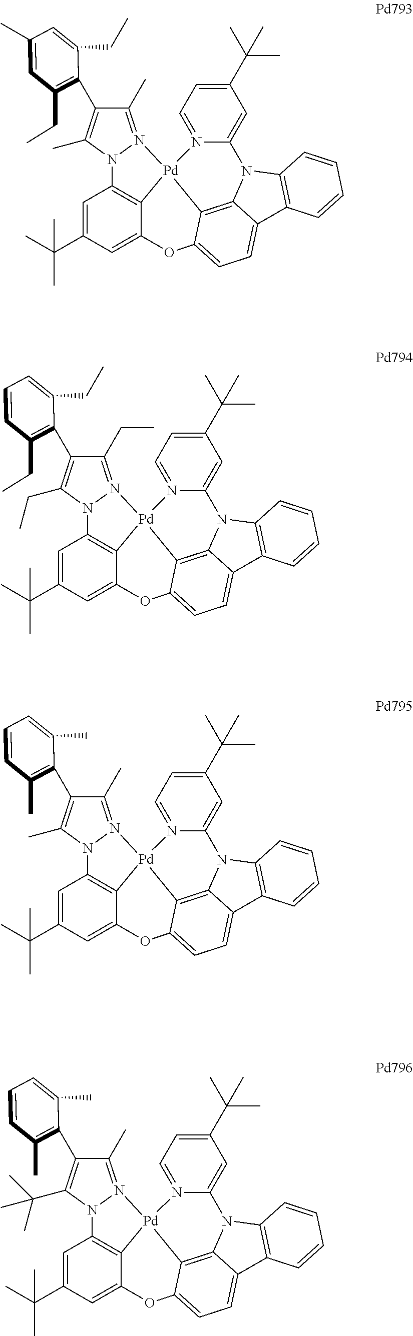

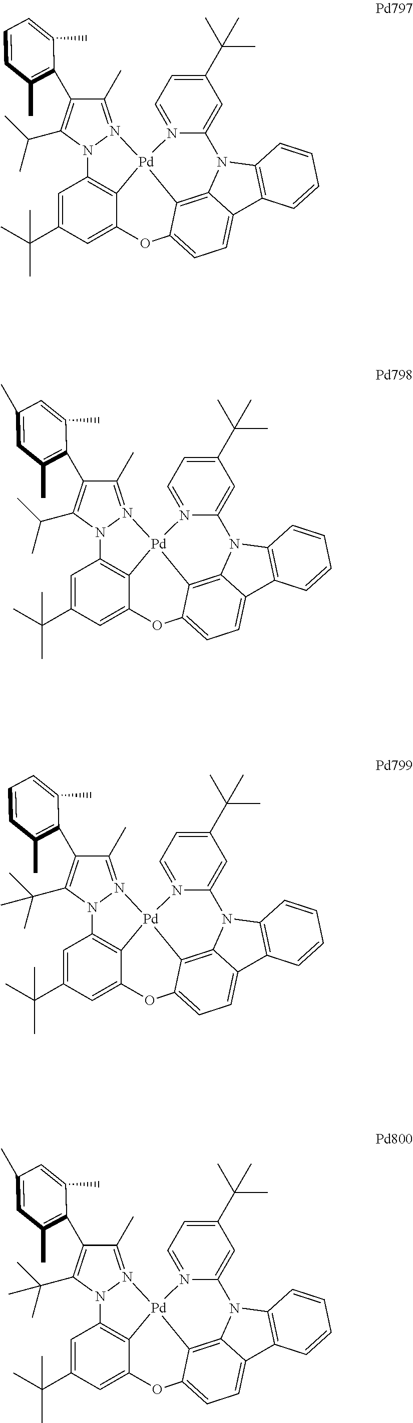

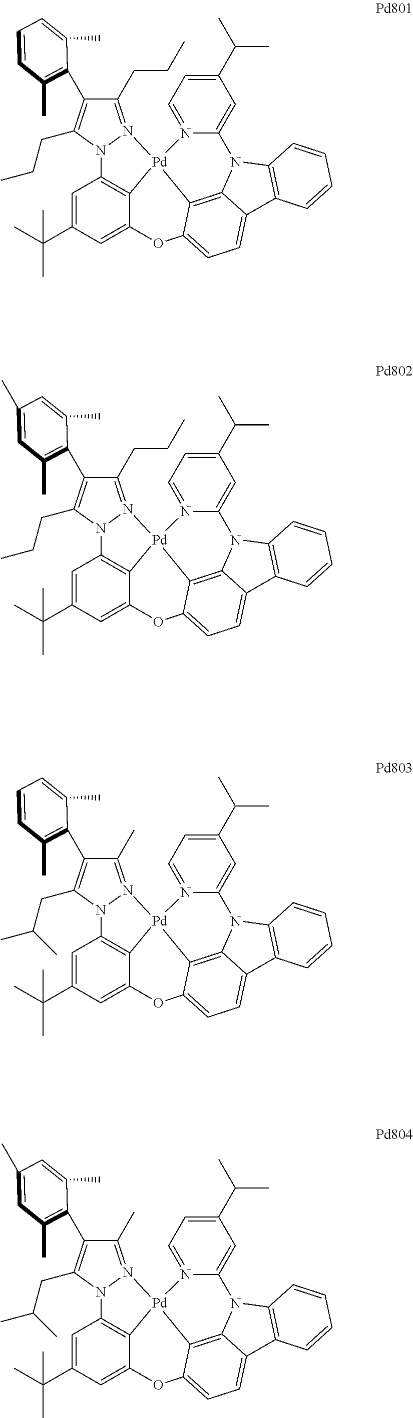

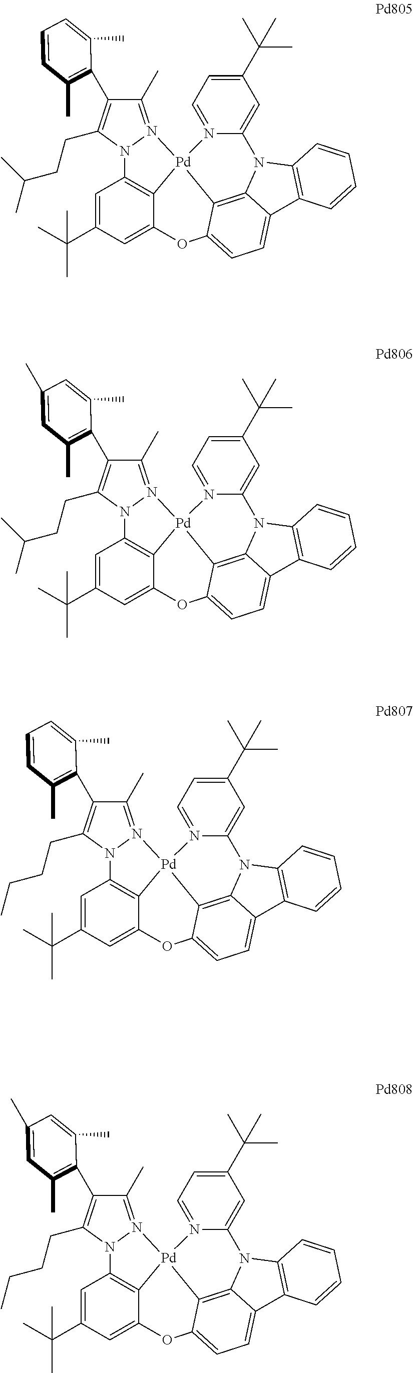

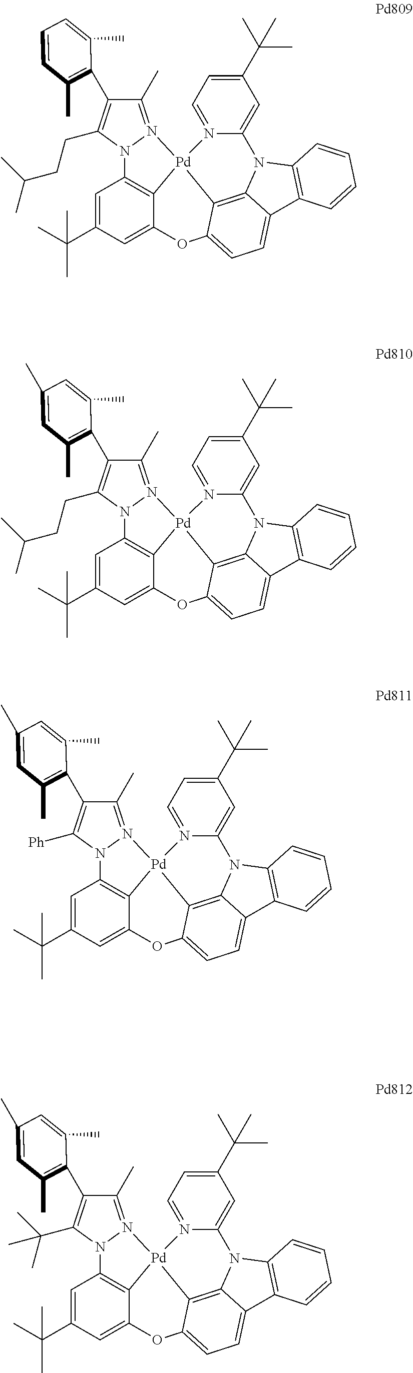

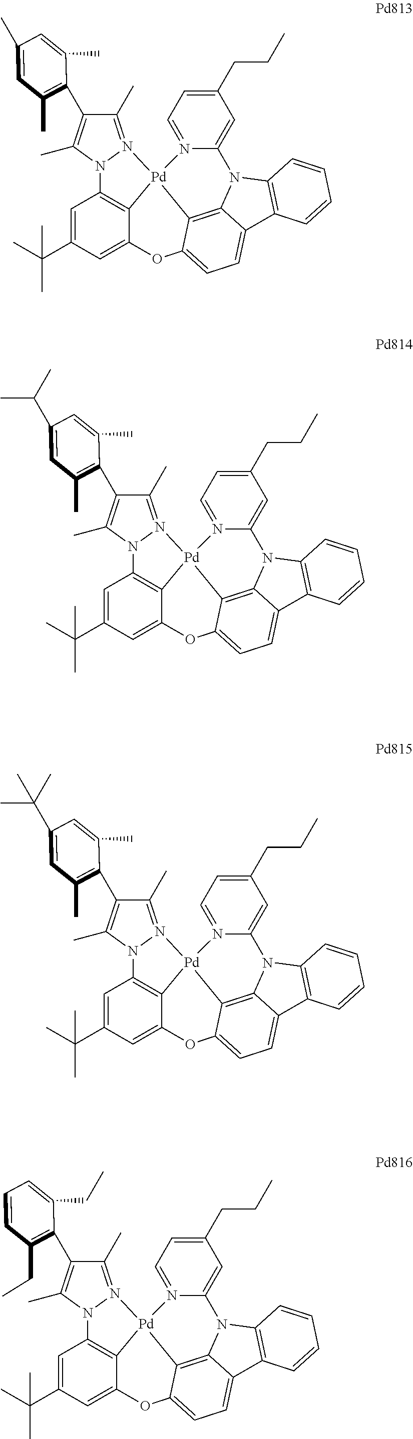

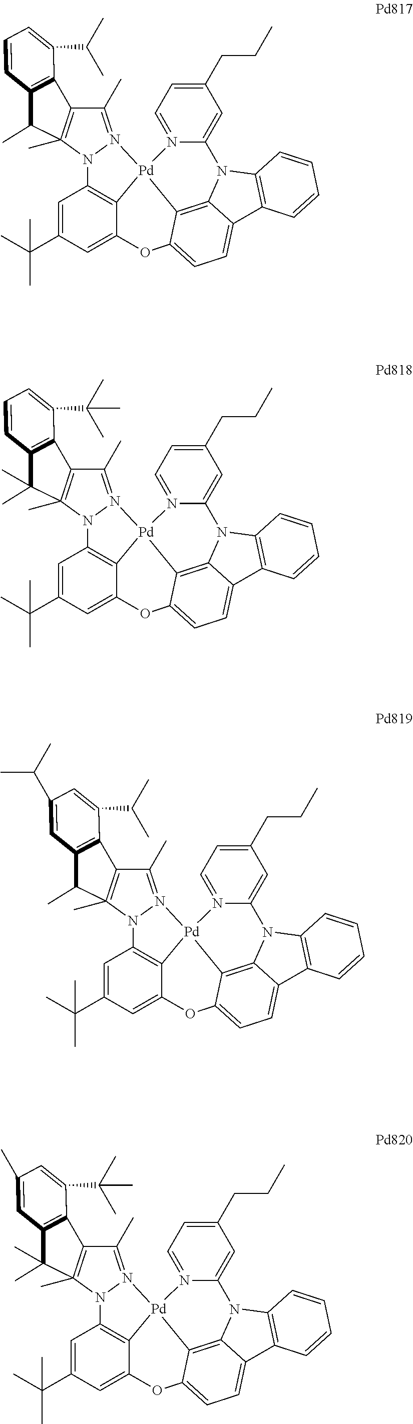

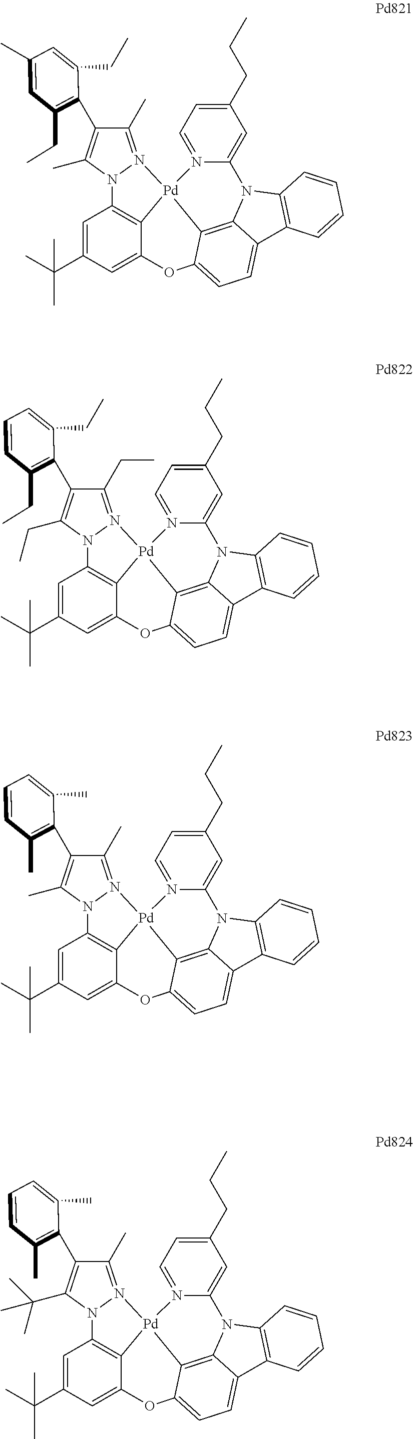

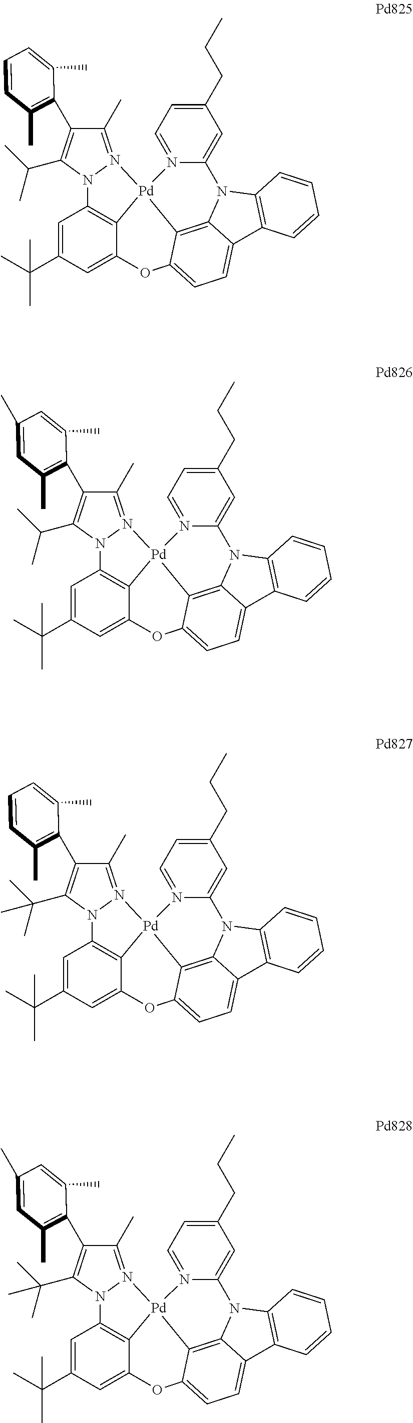

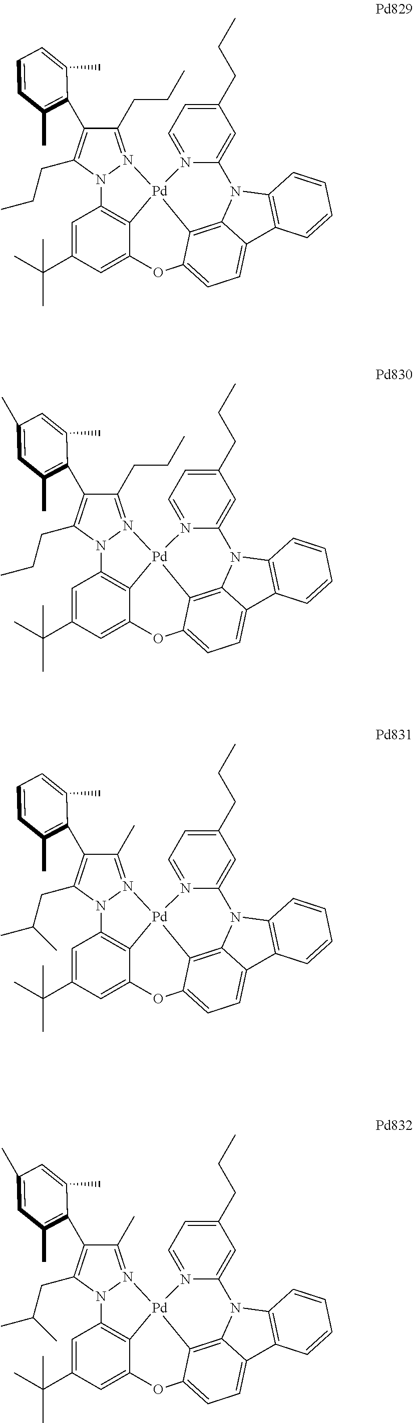

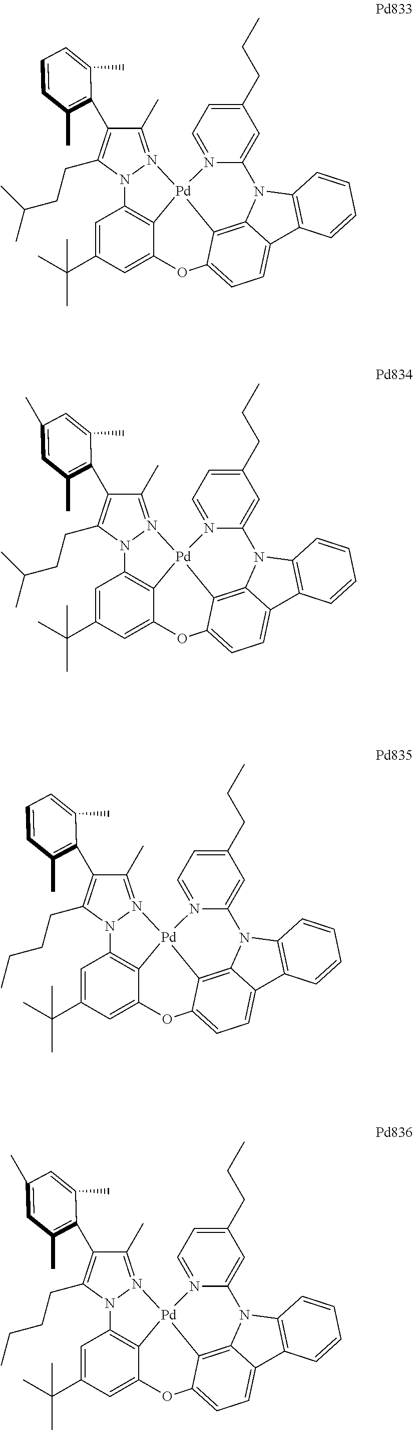

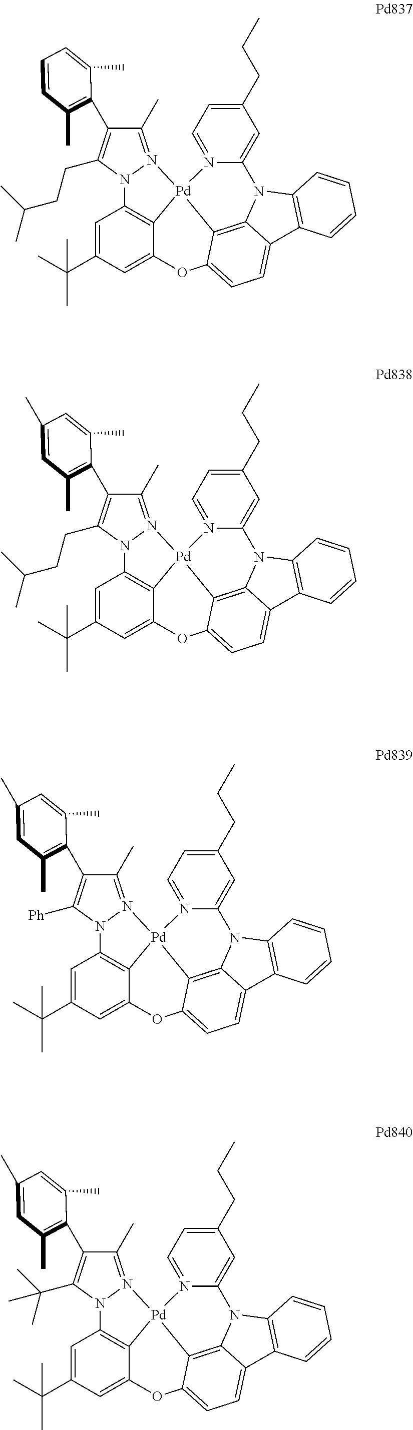

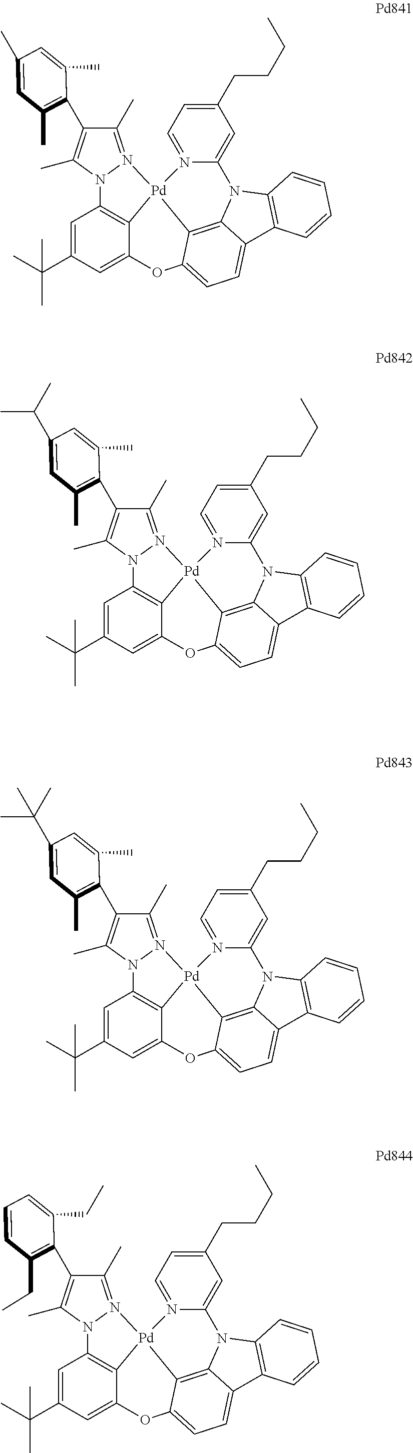

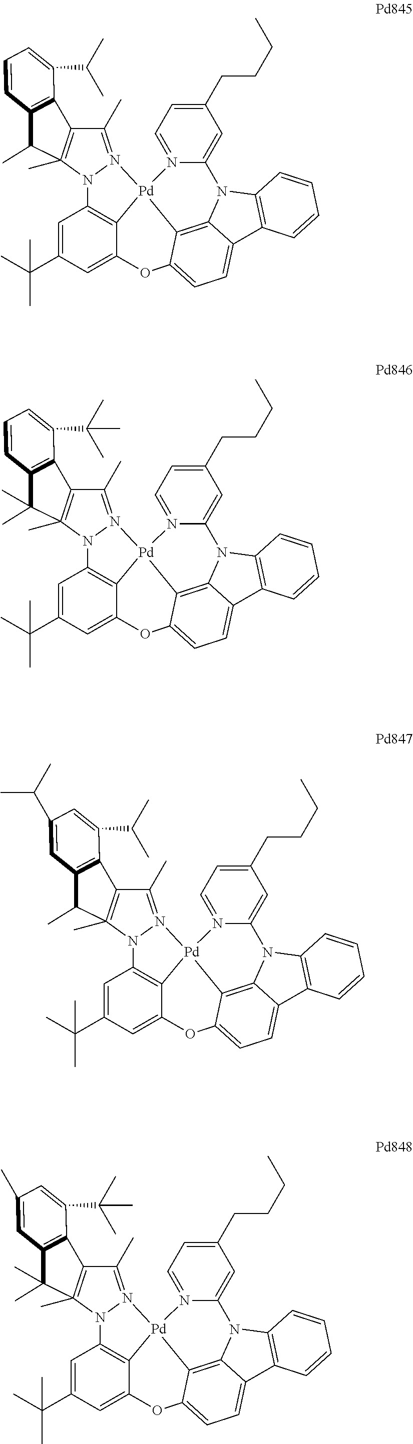

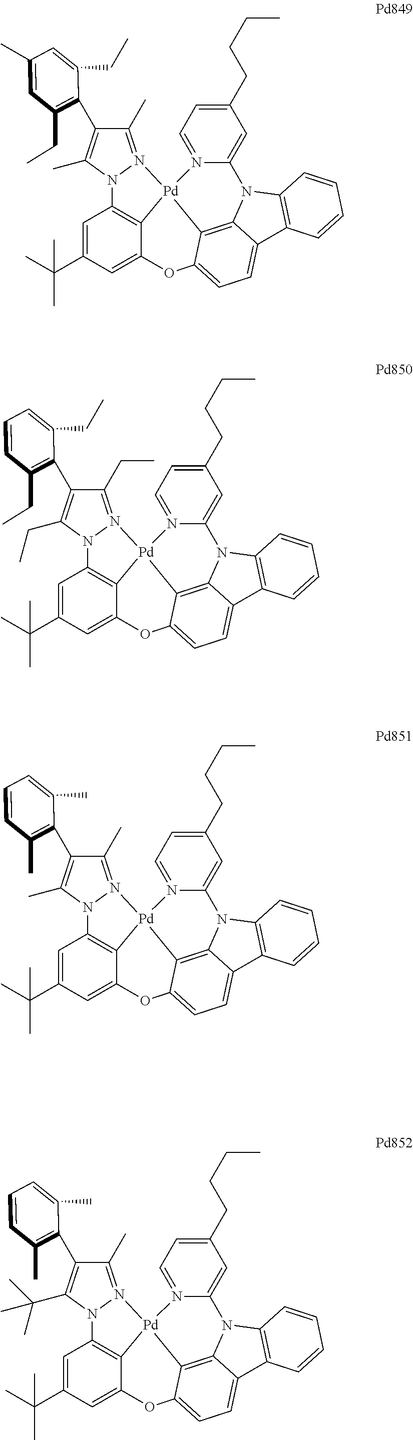

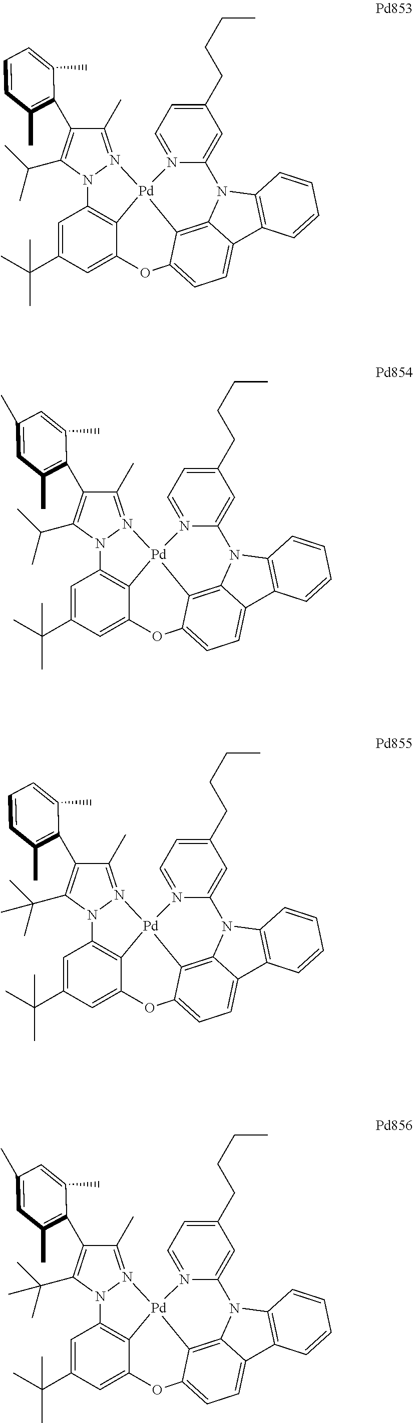

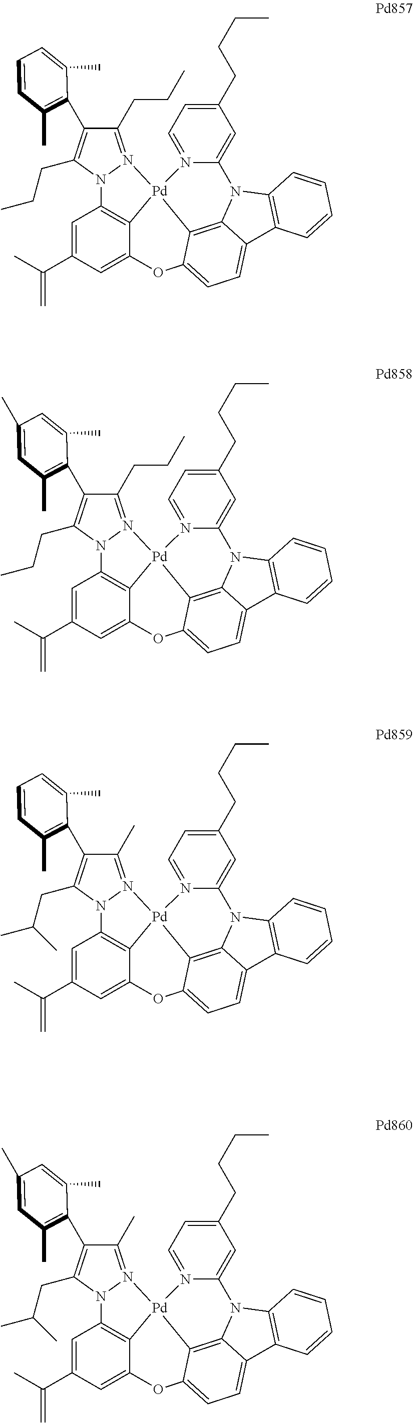

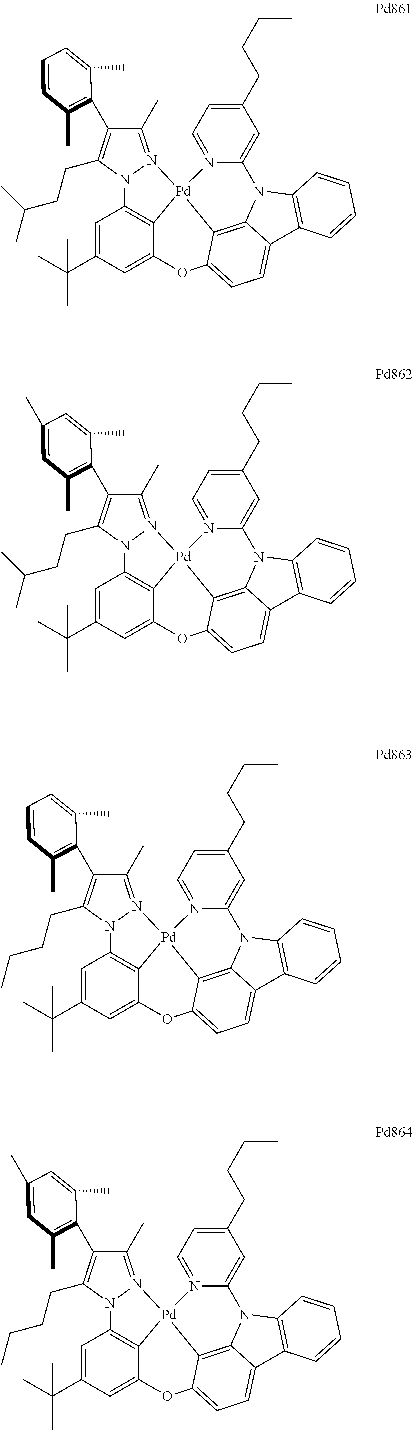

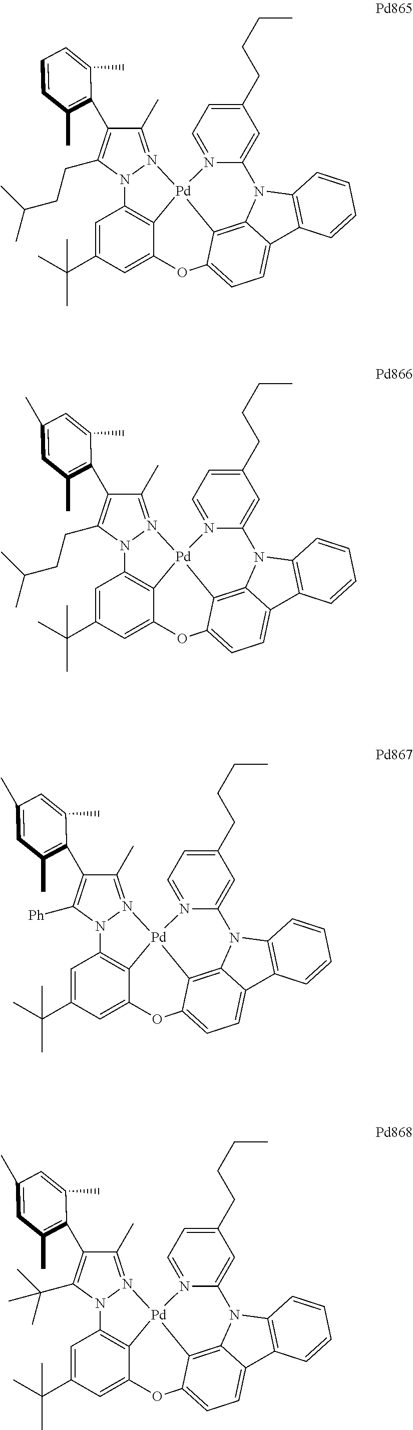

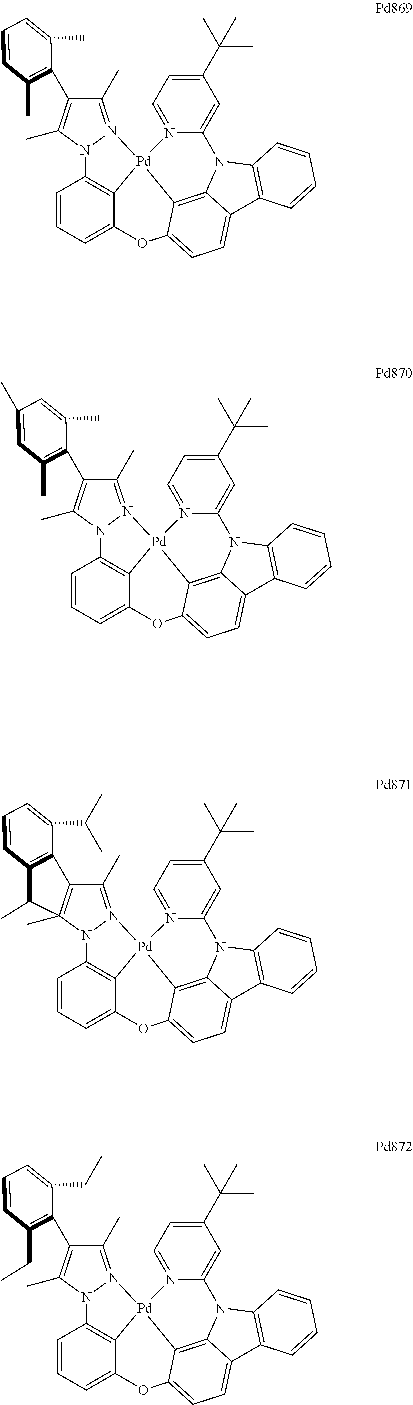

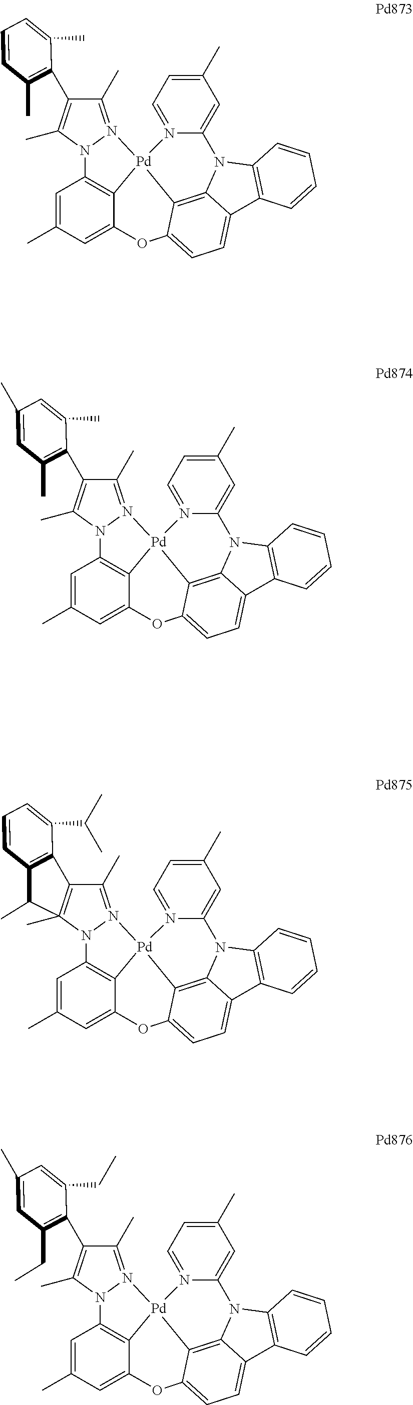

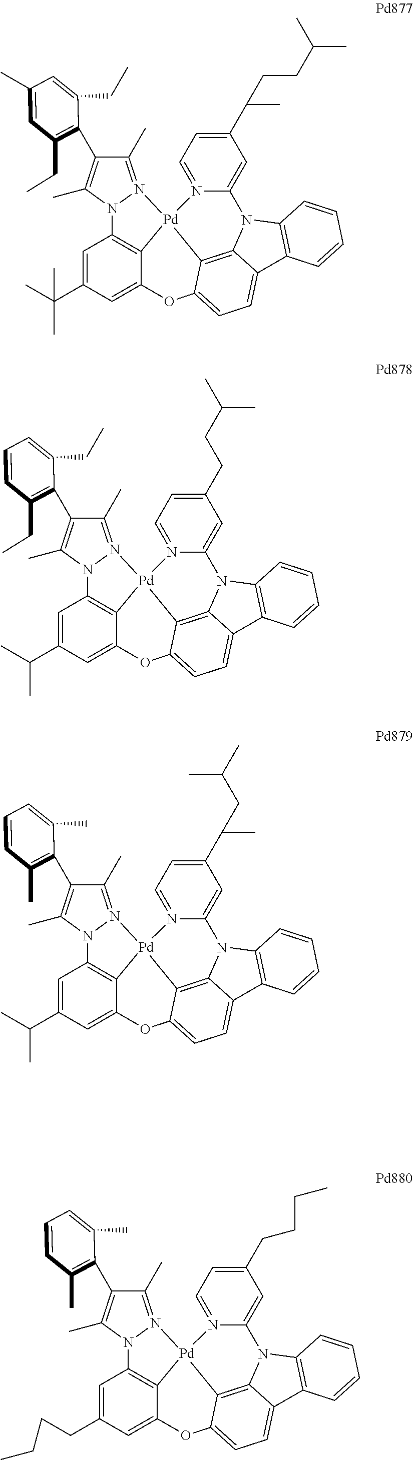

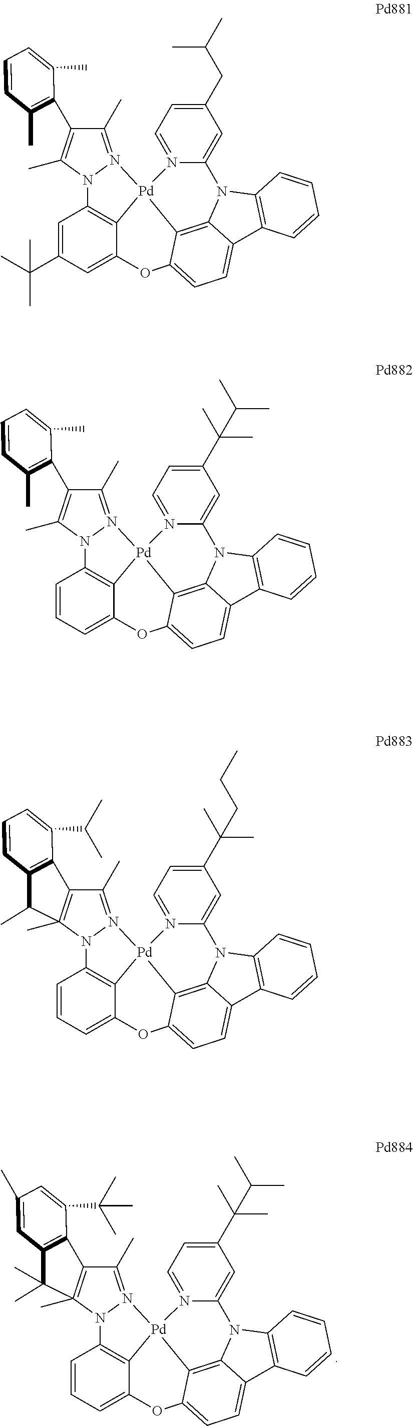

4. The complex according to claim 1, wherein the complex is electrically neutral.

5. A method for preparing the tetradentate cyclic-metal palladium complex comprising 4-aryl-3,5-disubstituted pyrazole according to claim 1, wherein the complex is synthesized by using the following chemical reaction steps:

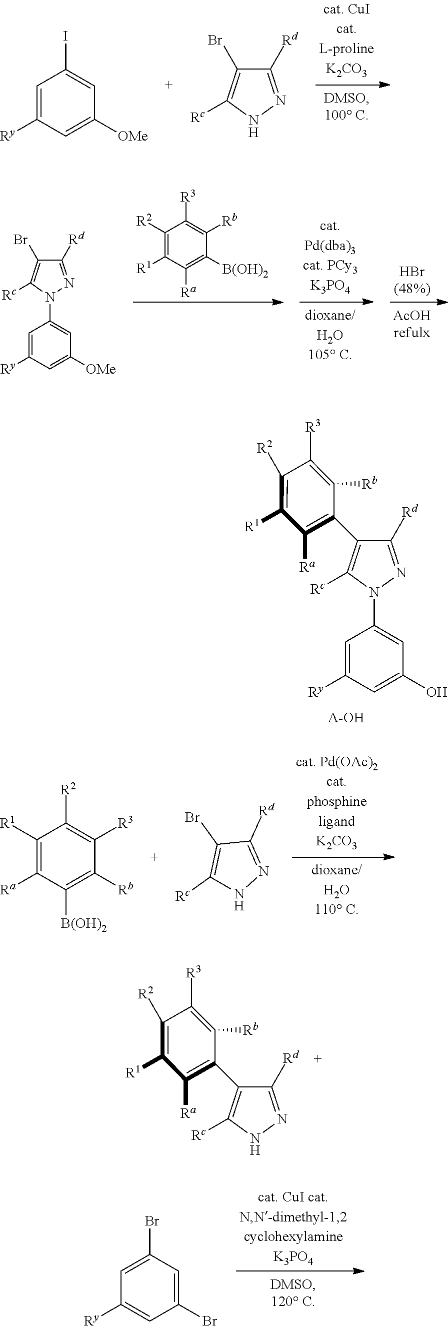

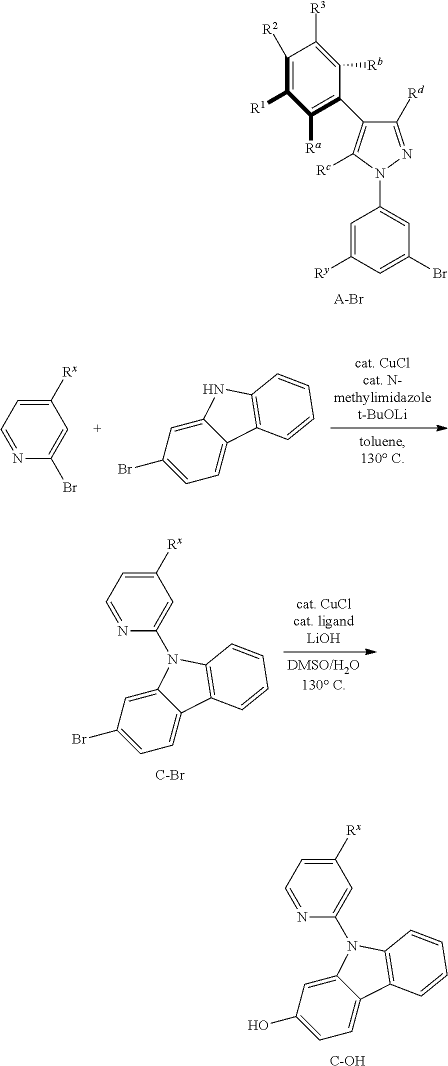

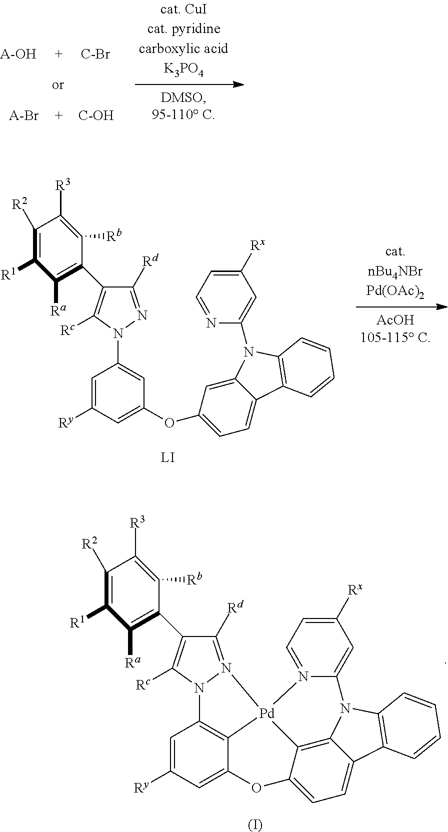

6. Use of the tetradentate cyclic-metal palladium complex comprising 4-aryl-3,5-disubstituted pyrazole according to claim 1 in organic electroluminescent material.

7. An optical or electro-optical device, wherein the device comprises one or more of the tetradentate cyclic-metal palladium complex comprising 4-aryl-3,5-disubstituted pyrazole according to claim 1.

8. The optical or electrical-optical device according to claim 7, wherein the device comprises a light absorbing unit, an organic light emitting diode, a light emitting device or a device that is capable of light-absorbing and light-emitting.

9. The optical or electro-optical device according to claim 7, wherein the tetradentate cyclic-metal palladium complex comprising 4-aryl-3,5-disubstituted pyrazole has 100% of internal quantum efficiency in the device.

10. A OLED device, wherein luminescent material or host material in the OLED device comprises one or more of the tetradentate cyclic-metal palladium complex comprising 4-aryl-3,5-disubstituted pyrazol according to claim 1.
